(19) United States
(12) Patent Application Publication
(10) Pub. No.: US 2025/0194415 A1
(43) Pub. Date: Jun. 12, 2025

(54) COMPOSITION, ORGANIC ELECTROLUMINESCENT ELEMENT, AND ELECTRONIC DEVICE

(71) Applicant: IDEMITSU KOSAN CO.,LTD., Tokyo (JP)

(72) Inventors: Masato NAKAMURA, Tokyo (JP); Emiko KAMBE, Tokyo (JP); Yongguk LEE, Tokyo (JP); Tetsuya MASUDA, Tokyo (JP); Yusuke TAKAHASHI, Tokyo (JP)

(73) Assignee: IDEMITSU KOSAN CO.,LTD., Tokyo (JP)

(21) Appl. No.: 18/845,539

(22) PCT Filed: Mar. 9, 2023
(86) PCT No.: PCT/JP2023/009167

§ 371 Date: Sep. 10, 2024

(30) Foreign Application Priority Data
Mar. 11, 2022 (JP) 2022-038607

(51) Int. Cl. H10K 85/60; H10K 50/15; H10K 50/17

(52) U.S. Cl. CPC H10K 85/633; H10K 85/636; H10K 50/156; H10K 50/17; H10K 85/626; H10K 85/6574

(57) ABSTRACT

A composition includes a first compound and a second compound. The first compound and the second compound are mutually different compounds and are each independently an amine compound having a refractive index of 1.80 or less.

### TECHNICAL FIELD

The present invention relates to an organic electroluminescence device and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

The performance of the organic EL device is evaluable in terms of, for instance, luminance, emission wavelength, chromaticity, luminous efficiency, drive voltage, and lifetime. In Patent Literatures 1 to 4, for instance, studies have been made to improve performance of an organic EL device. Patent Literatures 1 to 4 each disclose an organic EL device including a hole transporting zone formed of a plurality of layers.

### CITATION LIST

### Patent Literature(s)

Patent Literature 1: US Patent Application Publication No. 2021/0159418
Patent Literature 2: International Publication No. WO 2014/044344
Patent Literature 3: International Publication No. WO 2020/225071
Patent Literature 4: International Publication No. WO 2016/064110

### SUMMARY OF THE INVENTION

### Problem(s) to be Solved by the Invention

An object of the invention is to provide a composition capable of improving a luminous efficiency of an organic electroluminescence device. Another object of the invention is to provide an organic electroluminescence device having an improved luminous efficiency and an electronic device including the organic electroluminescence device.

### Means for Solving the Problem(s)

According to an aspect of the invention, there is provided a composition containing a first compound and a second compound, in which the first compound and the second compound are mutually different compounds and the first compound and the second compound are each independently an amine compound having a refractive index of 1.80 or less.

According to another aspect of the invention, there is provided an organic electroluminescence device including an anode, a cathode, and an organic layer disposed between the anode and the cathode, in which at least one layer included in the organic layer contains the composition according to the aspect of the invention.

According to still another aspect of the invention, there is provided an organic electroluminescence device including an anode, a cathode, and an organic layer disposed between the anode and the cathode, in which at least one layer included in the organic layer contains a first compound and a second compound, in which the first compound and the second compound are mutually different compounds, the first compound and the second compound are each independently an amine compound having a refractive index of 1.85 or less, the first compound and the second compound are contained in the same layer, and a film thickness of the layer containing the first compound and the second compound is 25 nm or more.

According to a further aspect of the invention, there is provided an electronic device including the organic electroluminescence device according to the above aspect of the invention.

According to the above aspect of the invention, there can be provided a composition capable of improving a luminous efficiency of an organic electroluminescence device. According to the above aspect of the invention, there can be provided an organic electroluminescence device having an improved luminous efficiency and an electronic device including the organic electroluminescence device.

### BRIEF EXPLANATION OF DRAWING(S)

FIG. 1 schematically depicts an exemplary arrangement of an organic electroluminescence device according to a second exemplary embodiment.

FIG. 2 schematically depicts another exemplary arrangement of the organic electroluminescence device according to the second exemplary embodiment.

FIG. 3 schematically depicts another exemplary arrangement of the organic electroluminescence device according to the second exemplary embodiment.

FIG. 4 schematically depicts another exemplary arrangement of the organic electroluminescence device according to the second exemplary embodiment.

### DESCRIPTION OF EMBODIMENT(S)

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring 4 ring carbon atoms. For instance, a 9,9-diphenylfluorenyl group has 13 ring carbon atoms and 9,9′-spirobifluorenyl group has 25 ring carbon atoms.

When a benzene ring is substituted by, for instance, an alkyl group as a substituent, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted in the number of the ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Mentioned Herein

Substituents mentioned herein will be described below.

An “unsubstituted aryl group” mentioned herein has, unless otherwise specified herein, 6 to 50, preferably 6 to 30, and more preferably 6 to 18 ring carbon atoms.

An “unsubstituted heterocyclic group” mentioned herein has, unless otherwise specified herein, 5 to 50, preferably 5 to 30, and more preferably 5 to 18 ring atoms.

An “unsubstituted alkyl group” mentioned herein has, unless otherwise specified herein, 1 to 50, preferably 1 to 20, and more preferably 1 to 6 carbon atoms.

An “unsubstituted alkenyl group” mentioned herein has, unless otherwise specified herein, 2 to 50, preferably 2 to 20, and more preferably 2 to 6 carbon atoms.

An “unsubstituted alkynyl group” mentioned herein has, unless otherwise specified herein, 2 to 50, preferably 2 to 20, and more preferably 2 to 6 carbon atoms.

An “unsubstituted cycloalkyl group” mentioned herein has, unless otherwise specified herein, 3 to 50, preferably 3 to 20, and more preferably 3 to 6 ring carbon atoms.

An “unsubstituted arylene group” mentioned herein has, unless otherwise specified herein, 6 to 50, preferably 6 to 30, and more preferably 6 to 18 ring carbon atoms.

An “unsubstituted divalent heterocyclic group” mentioned herein has, unless otherwise specified herein, 5 to 50, preferably 5 to 30, and more preferably 5 to 18 ring atoms.

An “unsubstituted alkylene group” mentioned herein has, unless otherwise specified herein, 1 to 50, preferably 1 to 20, and more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

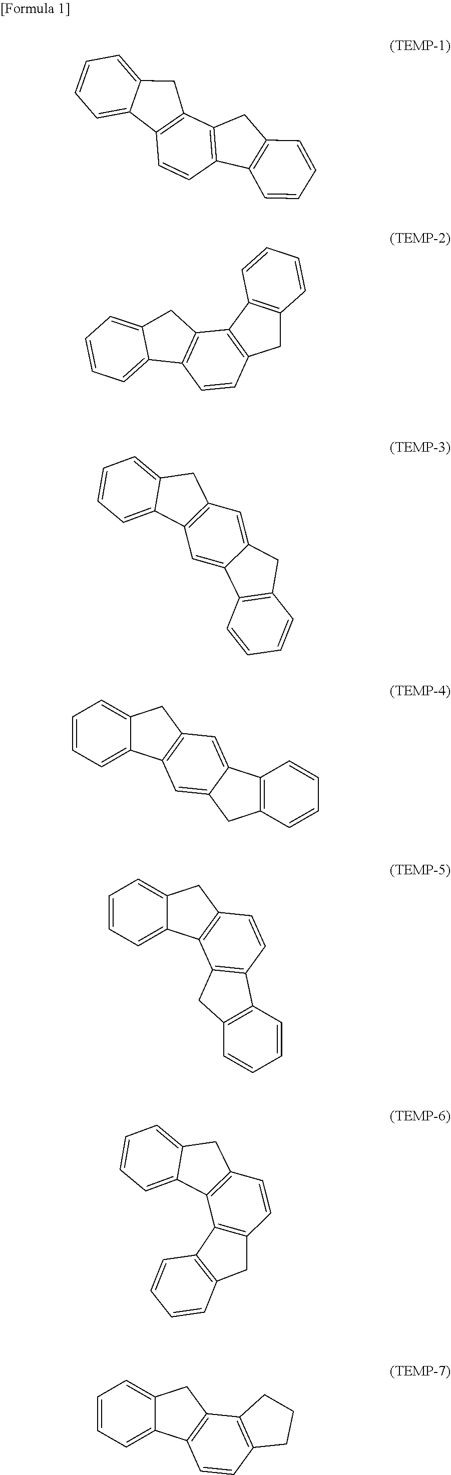

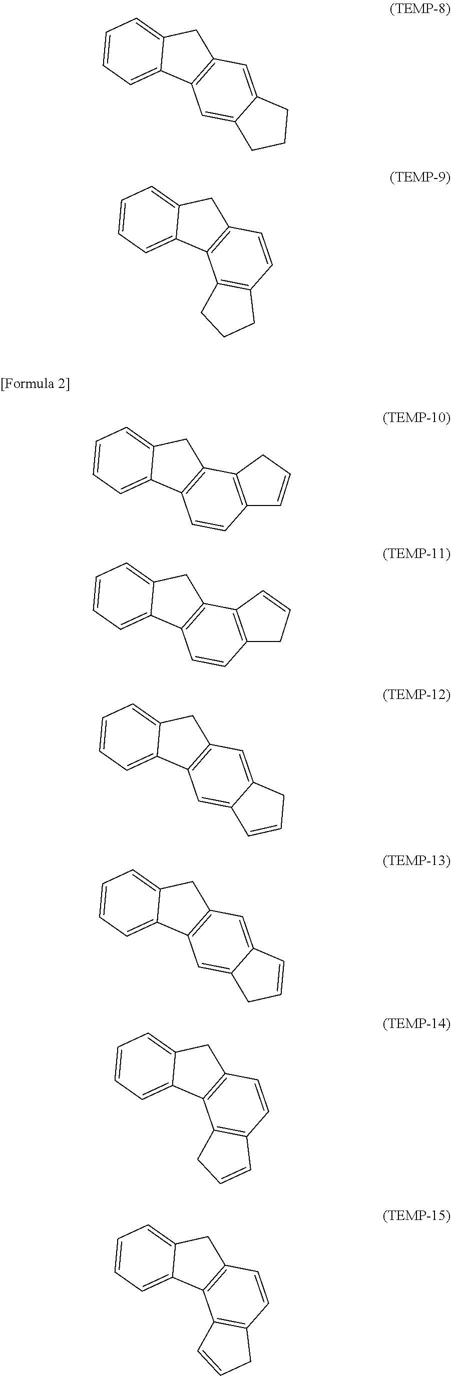

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

Unsubstituted Heterocyclic Groups Including Nitrogen Atom (Specific Example Group G2A1):
a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

Unsubstituted Heterocyclic Groups Including Oxygen Atom (Specific Example Group G2A2):
a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

Unsubstituted Heterocyclic Groups Including Sulfur Atom (Specific Example Group G2A3):
a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).

Monovalent Heterocyclic Groups Derived by Removing One Hydrogen Atom from Cyclic Structures Represented by Formulae (TEMP-16) to (TEMP-33) (Specific Example Group G2A4):

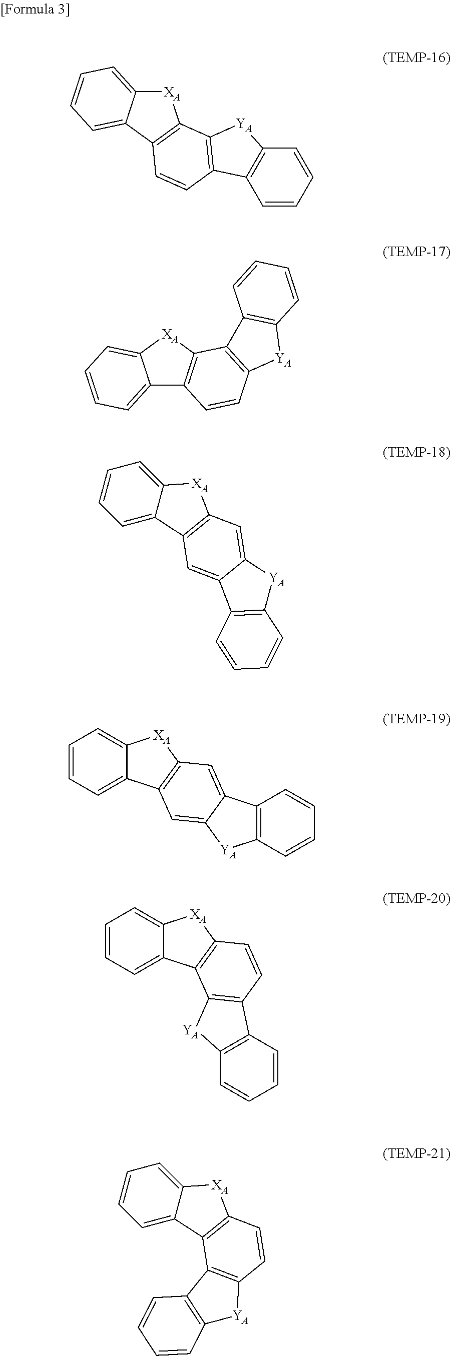

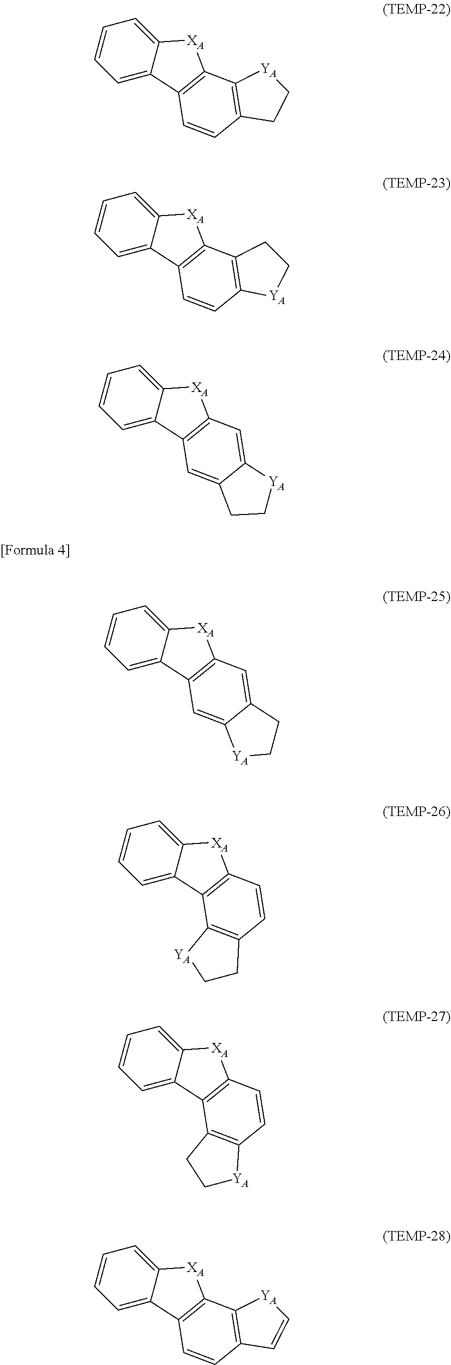

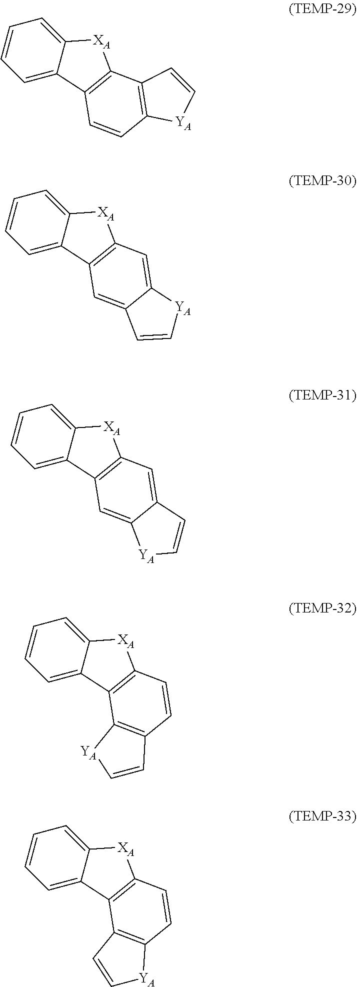

In the formulae (TEMP-16) to (TEMP-33), X_{A} and Y_{A} are each independently an oxygen atom, a sulfur atom, NH or CH₂, and at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

a phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].
   Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of XA or YA in a form of NH, and a hydrogen atom of one of XA and YA in a form of a methylene group (CH2).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.
   Group Represented by —Si(R₉₀₁)(R₉₀₂)(R₉₀₃)

Specific examples (specific example group G7) of the group represented herein by —Si(R₉₀₁)(R₉₀₂)(R₉₀₃) include:
—Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);
where:
   G1 represents a “substituted or unsubstituted aryl group” in the specific example group G1;
   G2 represents a “substituted or unsubstituted heterocyclic group” in the specific example group G2;
   G3 represents a “substituted or unsubstituted alkyl group” in the specific example group G3;
   G6 represents a “substituted or unsubstituted cycloalkyl group” in the specific example group G6;
   a plurality of G1 in —Si(G1)(G1)(G1) are mutually the same or different;
   a plurality of G2 in —Si(G1)(G2)(G2) are mutually the same or different;
   a plurality of G1 in —Si(G1)(G1)(G2) are mutually the same or different;
   a plurality of G2 in —Si(G2)(G2)(G2) are mutually the same or different;
   a plurality of G3 in —Si(G3)(G3)(G3) are mutually the same or different; and
   a plurality of G6 in —Si(G6)(G6)(G6) are mutually the same or different.

### Group Represented by —O—(R₉₀₄)

Specific examples (specific example group G8) of a group represented by —O—(R₉₀₄) herein include: —O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6),
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

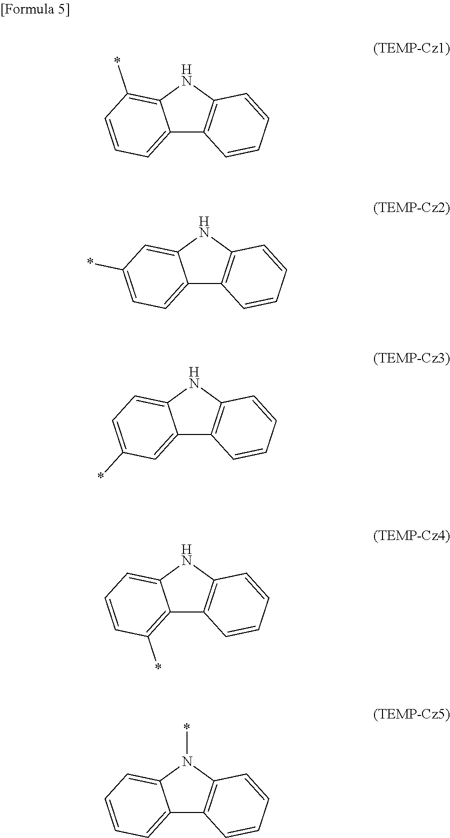 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

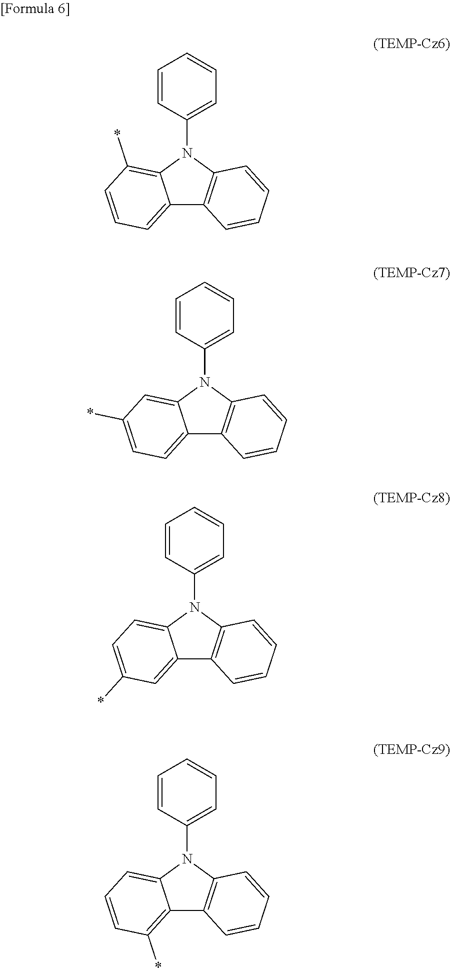 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

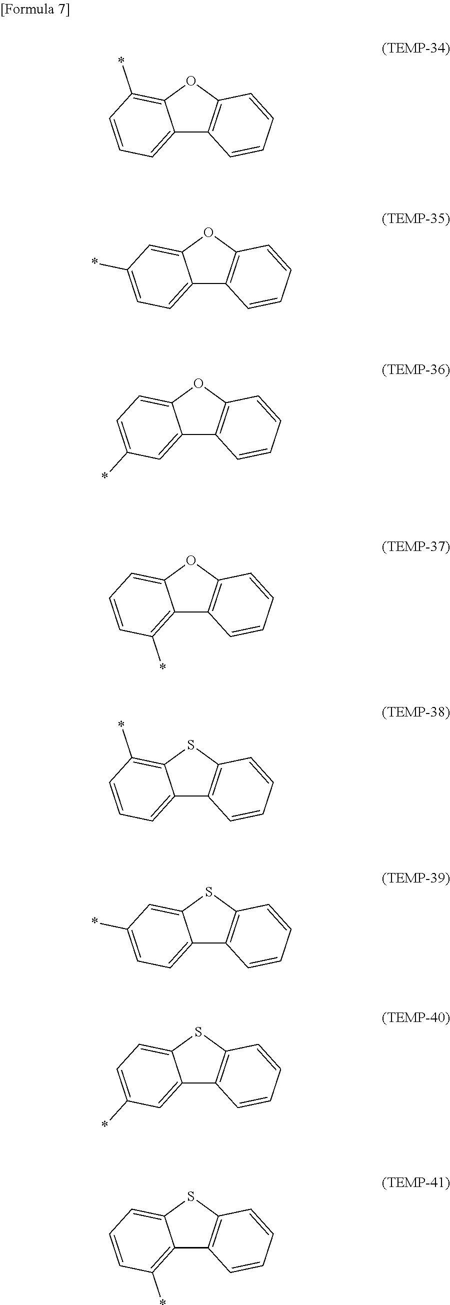

In the formulae (TEMP-34) to (TEMP-41), each * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocyclic ring of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

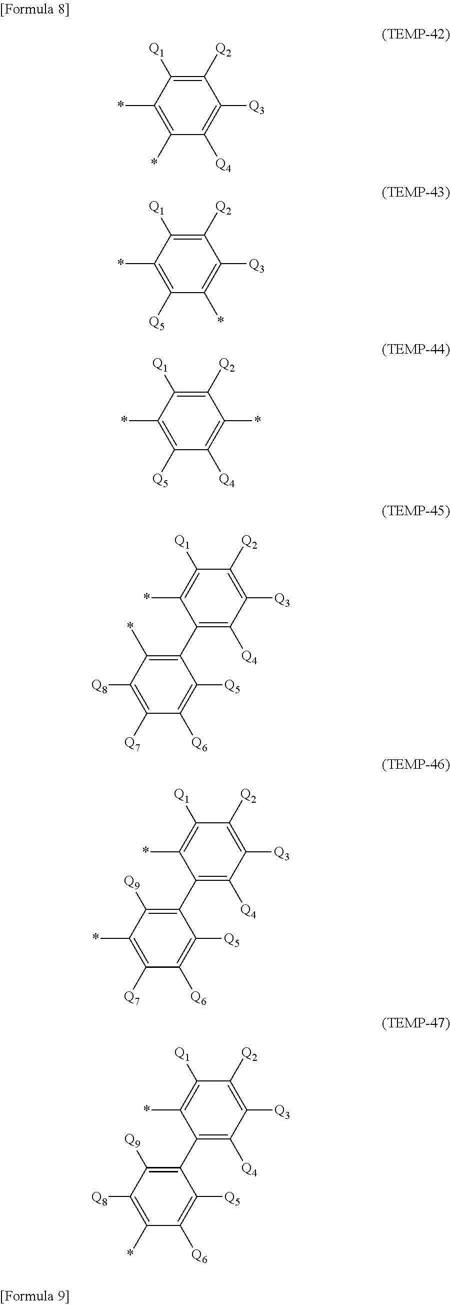

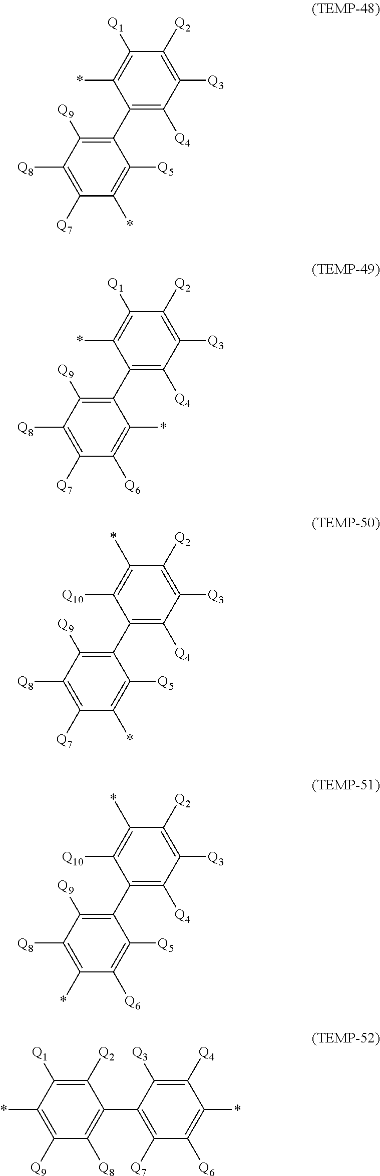

In the formulae (TEMP-42) to (TEMP-52), Q₁ to Q₁₀ are each independently a hydrogen atom or a substituent.

In the formulae (TEMP-42) to (TEMP-52), each * represents a bonding position.

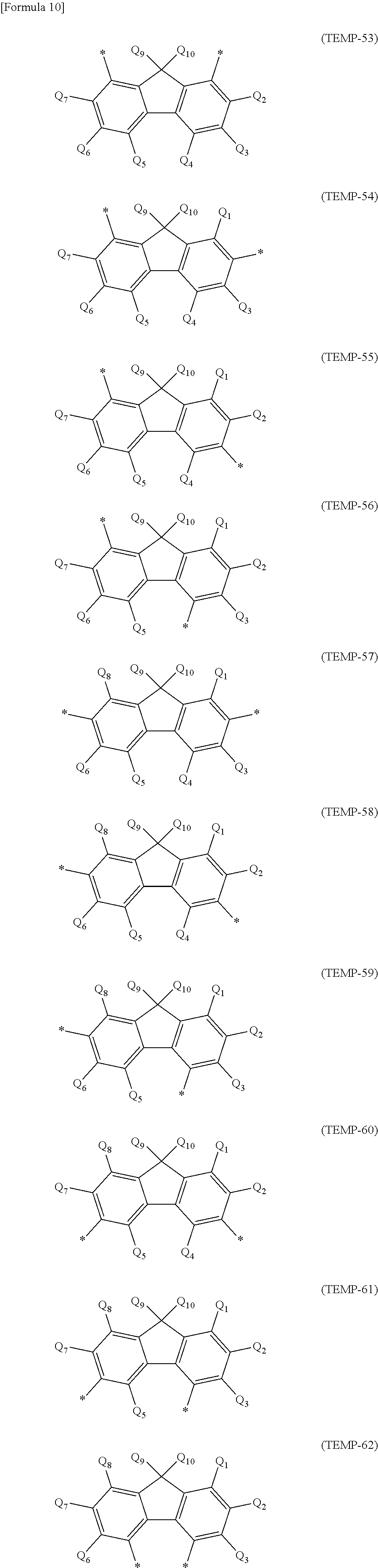

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), each * represents a bonding position.

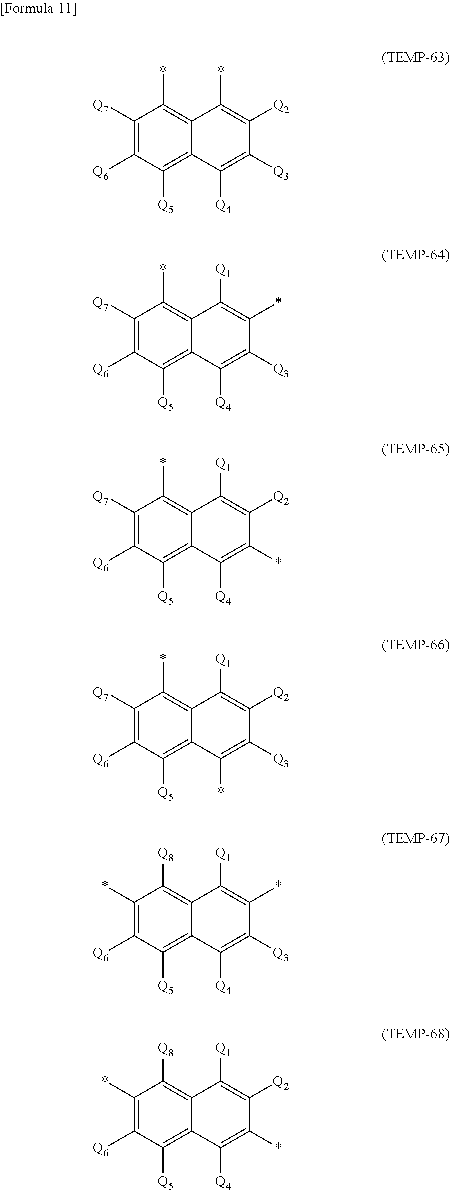

In the formulae (TEMP-63) to (TEMP-68), Q₁ to Q₈ are each independently a hydrogen atom or a substituent.

In the formulae (TEMP-63) to (TEMP-68), each * represents a bonding position.

The substituted or unsubstituted divalent heterocyclic group mentioned herein is, unless otherwise specified herein, preferably a group represented by any one of formulae (TEMP-69) to (TEMP-102) below.

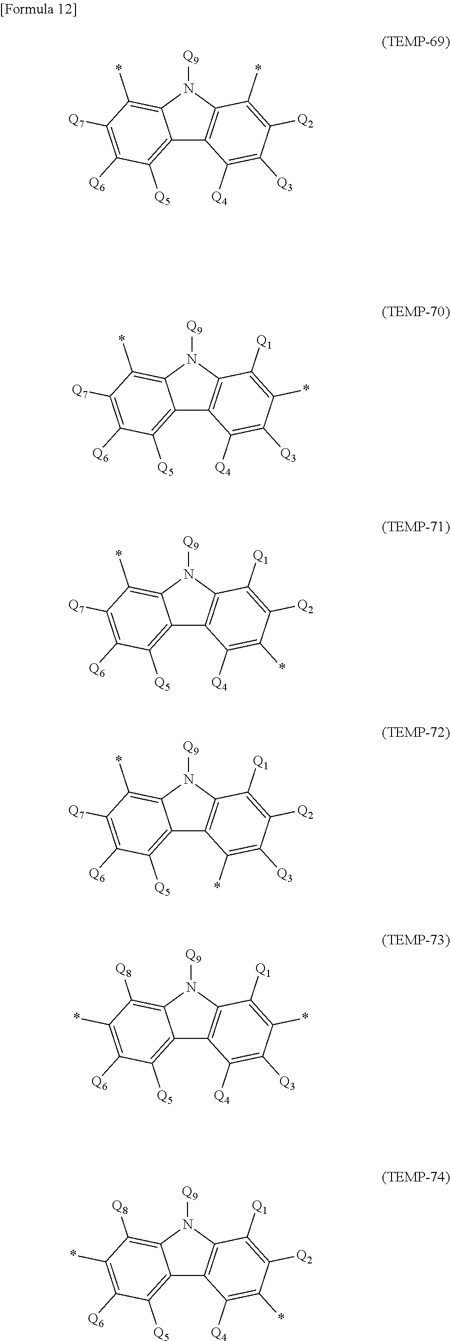

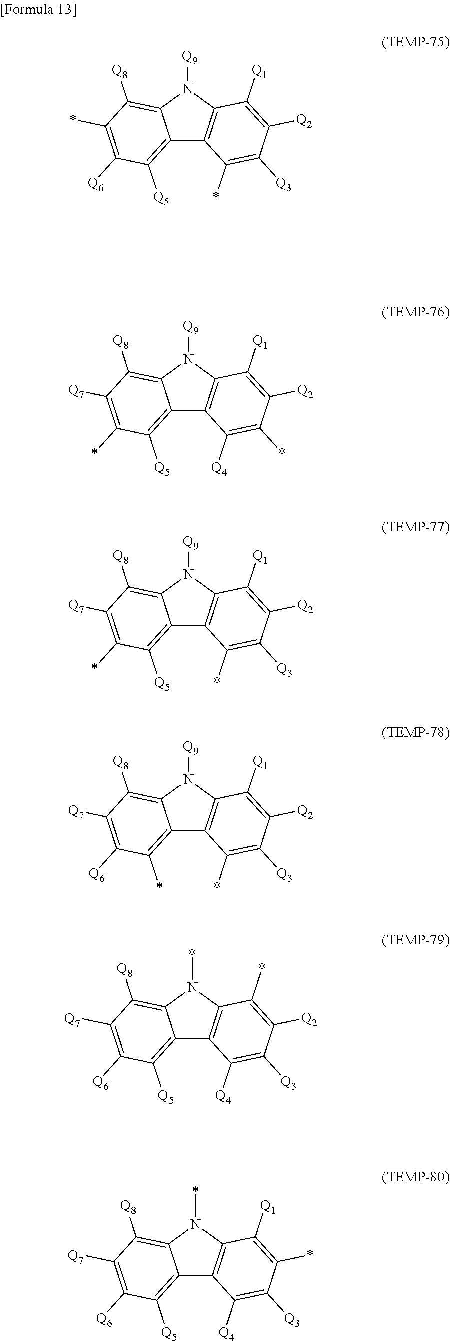

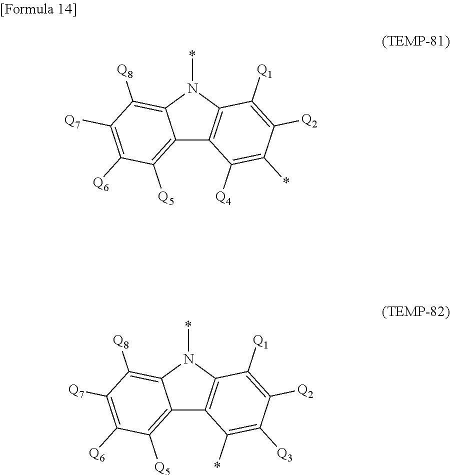

In the formulae (TEMP-69) to (TEMP-82), Q₁ to Q₉ are each independently a hydrogen atom or a substituent.

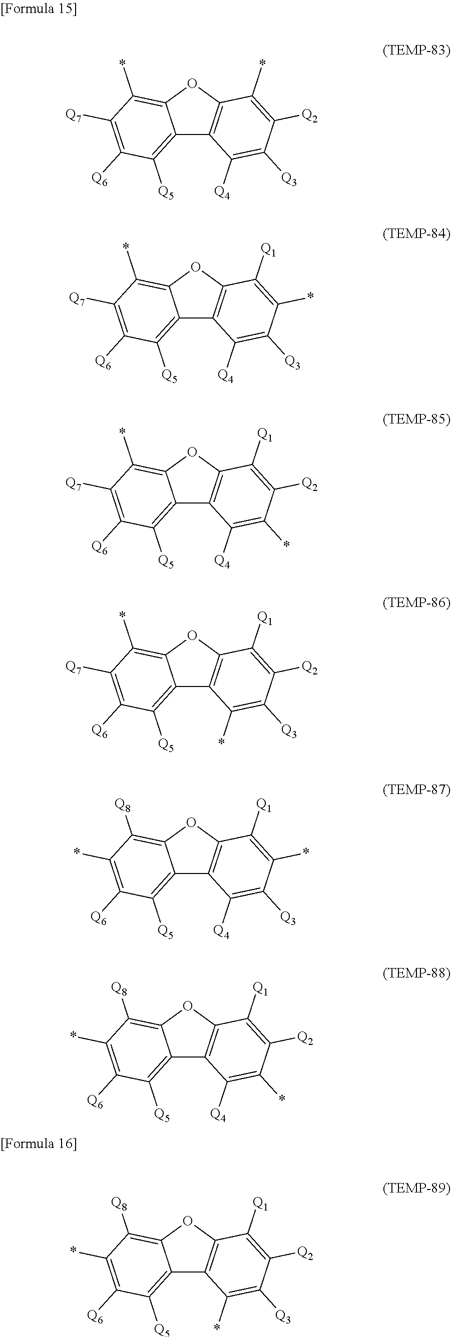

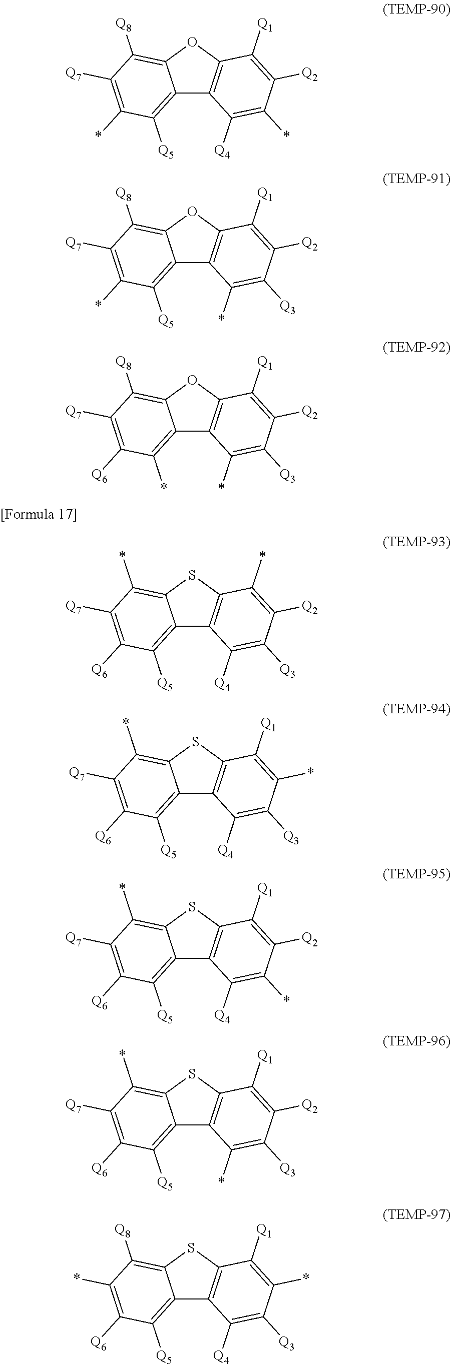

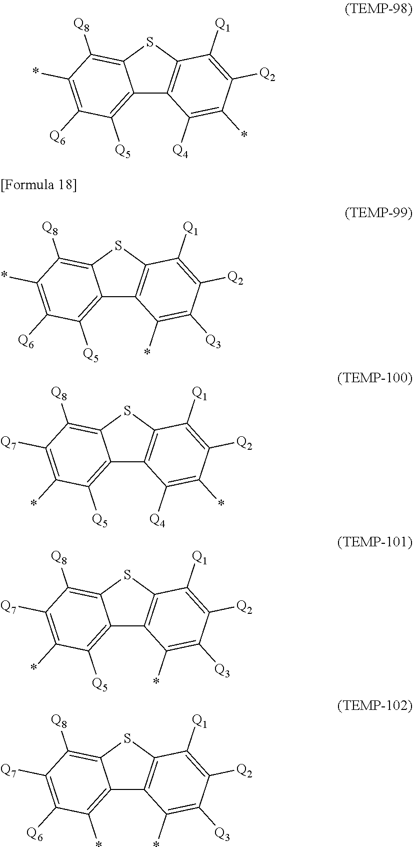

In the formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

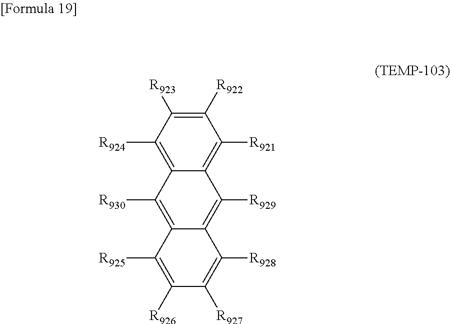

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring QA and R₉₂₅ and R₉₂₆ are simultaneously mutually bonded to form a ring Q_{B}, the anthracene compound represented by the formula (TEMP-103) is represented by a formula (TEMP-104) below.

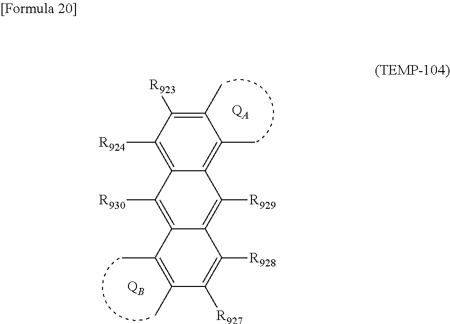

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring QA and R₉₂₂ and R₉₂₃ are mutually bonded to form a ring Qc, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring QA and the ring Qc share R₉₂₂.

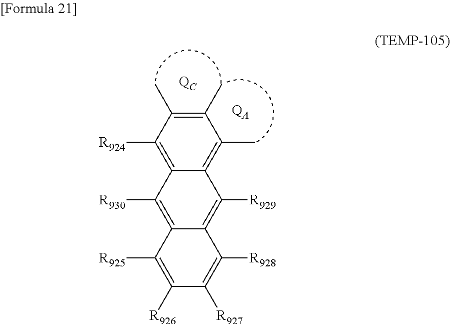

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring QA and the ring Q_{B} formed in the formula (TEMP-104) are each independently a “monocyclic ring” or a “fused ring.” Further, the ring QA and the ring Qoc formed in the formula (TEMP-105) are each a “fused ring.” The ring QA and the ring Qoc in the formula (TEMP-105) are fused to form a fused ring. When the ring QA in the formula (TEMP-104) is a benzene ring, the ring QA is a monocyclic ring. When the ring QA in the formula (TEMP-104) is a naphthalene ring, the ring QA is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocyclic ring include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring QA formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring QA is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.”

When the “monocyclic ring” or the “fused ring” has a substituent, specific examples of the substituent are the substituents described in the above under the subtitle “Substituent Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;

R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

Herein, a numerical formula represented by “A≥B” means that the value A is equal to the value B, or the value A is larger than the value B.

Herein, a numerical formula represented by “A≤B” means that the value A is equal to the value B, or the value A is smaller than the value B.

### First Exemplary Embodiment

### Composition

A composition according to the exemplary embodiment contains a first compound and a second compound. The first compound and the second compound are mutually different compounds, and the first compound and the second compound are each independently an amine compound having a refractive index of 1.80 or less.

The refractive index of the amine compound is typically about 1.95. Since an amine compound having a low refractive index that is 1.80 or less has an excessively high or low hole injectability, the hole injectability has a large deviation. Therefore, when an amine compound having a low refractive index is used in, for instance, a hole transporting layer, hole injectability from the hole transporting layer to the electron blocking layer or the emitting layer has a large deviation, whereby deviation of the device performance also tends to occur. In the composition according to the exemplary embodiment, the first compound and the second compound, both of which have a refractive index of 1.80 or less, can be mixed so as to compensate mutual characteristics. Using the composition according to the exemplary embodiment in an organic layer of the organic EL device leads to a decrease in the refractive index of the organic layer to improve light extraction efficiency, and also keeps a carrier balance in the organic layer optimal to improve luminous efficiency of the organic EL device.

The refractive index can be measured by a measurement method described in Examples below. Herein, a value of the refractive index at 2.7 eV in the substrate parallel direction (Ordinary direction) measured by multi-incidence angle spectroscopic ellipsometry measurement is defined as a refractive index of the measurement target material. The refractive index at 2.7 eV corresponds to a refractive index at 460 nm.

In an exemplary arrangement of the composition according to the exemplary embodiment, at least one of the first compound or the second compound is an amine compound having a refractive index of 1.78 or less.

In an exemplary arrangement of the composition of the exemplary embodiment, the refractive index of one of the first compound and the second compound is 1.80 or less and the refractive index of the other of the first compound and the second compound is 1.78 or less.

In an exemplary arrangement of the composition according to the exemplary embodiment, the refractive index of the first compound n₁ and the refractive index of the second compound n₂ are 1.78 or less.

In an exemplary arrangement of the composition according to the exemplary embodiment, an absolute value |n₁−n₂| of a difference between a refractive index of the first compound n₁ and a refractive index of the second compound n₂ is 0.05 or less.

In an exemplary arrangement of the composition according to the exemplary embodiment, an absolute value |n₁−n₂| of a difference between a refractive index of the first compound n₁ and a refractive index of the second compound n₂ is 0.03 or less.

In the composition according to the exemplary embodiment, the molecular structure of each of the first and second compounds is not particularly limited as long as the above refractive index range is satisfied. For instance, the following compounds are usable as the first compound and the second compound.

In an exemplary arrangement of the composition according to the exemplary embodiment, the first compound and the second compound are each independently a compound represented by a formula (C1) below or a compound represented by a formula (C3) below.

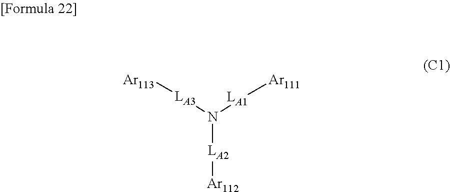

In the formula (C1):

L_{A1}, L_{A2}, and L_{A3} are each independently a single bond, a substituted or unsubstituted arylene group having 6 to 50 ring carbon atoms, or a substituted or unsubstituted divalent heterocyclic group having 5 to 50 ring atoms;
Ar₁₁₁, Ar₁₁₂, and Ar₁₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3}); R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

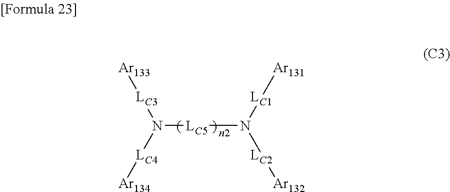

In the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n₂ is 1, 2, 3, or 4;
when n₂ is 1, L_{C5} is a substituted or unsubstituted arylene group having 6 to 50 ring carbon atoms, or a substituted or unsubstituted divalent heterocyclic group having 5 to 50 ring atoms;
when n₂ is 2, 3, or 4, a plurality of L_{C5} are mutually the same or different;
when n₂ is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

In an exemplary arrangement of the composition according to the exemplary embodiment, in the compound represented by the formula (C3), a first amino group represented by a formula (C3-1) below and a second amino group represented by a formula (C3-2) below are an identical group,

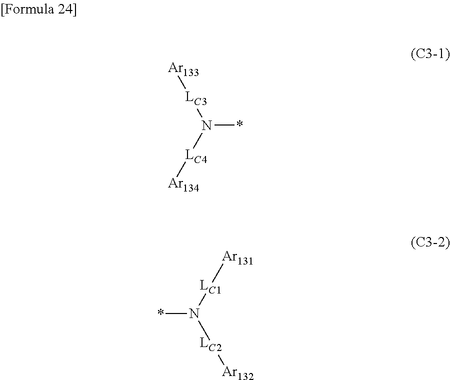

In the formulae (C3-1) and (C3-2), each * represents a bonding position to L_{C5.}

In an exemplary arrangement of the composition according to the exemplary embodiment, the first amino group represented by the formula (C3-1) and the second amino group represented by the formula (C3-2) may be mutually different groups.

In an exemplary arrangement of the composition according to the exemplary embodiment, the first compound and the second compound are each independently a compound represented by the formula (C1) below.

In an exemplary arrangement of the composition according to the exemplary embodiment, at least one of an aryl group or a heterocyclic group contained by a compound represented by the formula (C1) and a compound represented by the formula (C3) is substituted by a substituted or unsubstituted alkyl group having 1 to 50 carbon atoms. The alkyl group preferably has 1 to 30 carbon atoms, more preferably 1 to 20 carbon atoms, and still more preferably 1 to 6 carbon atoms.

In an exemplary arrangement of the composition according to the exemplary embodiment, two or more of an aryl group or a heterocyclic group contained by a compound represented by the formula (C1) and a compound represented by the formula (C3) are substituted by a substituted or unsubstituted alkyl group having 1 to 30 carbon atoms. The alkyl group preferably has 1 to 20 carbon atoms, more preferably 1 to 6 carbon atoms.

In an exemplary arrangement of the composition according to the exemplary embodiment, at least one of Ar₁₁₁, Ar₁₁₂, or Ar₁₁₃ in a compound represented by the formula (C1) is a group represented by a formula (C4) below, or at least one of Ar₁₃₁, Ar₁₃₂, Ar₁₃₃, or Ar₁₃₄ in a compound represented by the formula (C3) is a group represented by the formula (C4) below.

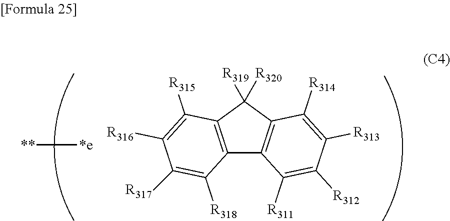

In the formula (C4):
one of R₃₁₁ to R₃₁₈ is a single bond with *e.
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, a substituted or unsubstituted alkyl group having 1 to 30 carbon atoms, a substituted or unsubstituted aryl group having 6 to 30 ring carbon atoms, or a substituted or unsubstituted heterocyclic group having 5 to 30 ring atoms;
a combination of R₃₁₉ and R₃₂₀ are mutually bonded to form a substituted or unsubstituted monocyclic ring, mutually bonded to form a substituted or unsubstituted fused ring, or not mutually bonded;
R₃₁₉ and R₃₂₀ forming neither the substituted or unsubstituted monocyclic ring nor the substituted or unsubstituted fused ring are each independently a hydrogen atom, a substituted or unsubstituted alkyl group having 1 to 30 carbon atoms, or a substituted or unsubstituted aryl group having 6 to 12 ring carbon atoms; and
** represents a bonding position to L_{A1}, L_{A2}, L_{A3}, L_{C1}, L_{C2}, L_{C3}, or L_{C4.}

In an exemplary arrangement of the composition according to the exemplary embodiment, one of R₃₁₁ to R₃₂₀ in the formula (C4) is a single bond with *e;
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, a substituted or unsubstituted alkyl group having 1 to 30 carbon atoms, a substituted or unsubstituted aryl group having 6 to 30 ring carbon atoms, or a substituted or unsubstituted heterocyclic group having 5 to 30 ring atoms;
a combination of R₃₁₉ and R₃₂₀ not being the single bond with *e are mutually bonded to form a substituted or unsubstituted monocyclic ring, mutually bonded to form a substituted or unsubstituted fused ring, or not mutually bonded;
R₃₁₉ and R₃₂₀ neither being the single bond with *e, nor forming the substituted or unsubstituted monocyclic ring, nor forming the substituted or unsubstituted fused ring are each independently a hydrogen atom, a substituted or unsubstituted alkyl group having 1 to 30 carbon atoms, or a substituted or unsubstituted aryl group having 6 to 12 ring carbon atoms; and
** represents a bonding position to L_{A1}, L_{A2}, L_{A3}, L_{C1}, L_{C2}, L_{C3}, or L_{C4.}

In an exemplary arrangement of the composition according to the exemplary embodiment, at least one of Ar₁₁₁, Ar₁₁₂, or Ar₁₁₃ in a compound represented by the formula (C1) is a group represented by the formula (C4), or at least one of Ar₁₃₁, Ar₁₃₂, Ar₁₃₃, or Ar₁₃₄ in a compound represented by the formula (C3) is a group represented by the formula (C4).

In an exemplary arrangement of the composition according to the exemplary embodiment, R₃₁₉ and R₃₂₀ in the formula (C4) are each independently a substituted or unsubstituted alkyl group having 1 to 30 carbon atoms. The alkyl group preferably has 1 to 20 carbon atoms, more preferably 1 to 6 carbon atoms.

In an exemplary arrangement of the composition according to the exemplary embodiment, at least one of R₃₁₉ or R₃₂₀ in the formula (C4) is a substituted or unsubstituted aryl group having 6 to 12 ring carbon atoms.

In an exemplary arrangement of the composition according to the exemplary embodiment, at least one of R₃₁₉ or R₃₂₀ in the formula (C4) is a phenyl group substituted by a substituted or unsubstituted alkyl group having 1 to 30 carbon atoms. The alkyl group preferably has 1 to 20 carbon atoms, more preferably 1 to 6 carbon atoms.

In an exemplary arrangement of the composition according to the exemplary embodiment, R₃₁₉ and R₃₂₀ in the formula (C4) are each a substituted or unsubstituted phenyl group.

In an exemplary arrangement of the composition according to the exemplary embodiment, R₃₁₉ and R₃₂₀ in the formula (C4) are each a phenyl group substituted by a substituted or unsubstituted alkyl group having 1 to 30 carbon atoms. The alkyl group preferably has 1 to 20 carbon atoms, more preferably 1 to 6 carbon atoms.

In an exemplary arrangement of the composition according to the exemplary embodiment, a combination of R₃₁₉ and R₃₂₀ in the formula (C4) are mutually bonded to form a substituted or unsubstituted monocyclic ring or a substituted or unsubstituted fused ring.

In an exemplary arrangement of the composition according to the exemplary embodiment, a combination of R₃₁₉ and R₃₂₀ in the formula (C4) are mutually bonded to form a substituted monocyclic ring (monocyclic ring having a substituent) or a substituted fused ring (fused ring having a substituent).

In an exemplary arrangement of the composition according to the exemplary embodiment, a combination of R₃₁₉ and R₃₂₀ in the formula (C4) are mutually bonded to form a monocyclic ring substituted by a substituted or unsubstituted alkyl group having 1 to 30 carbon atoms, or form a fused ring substituted by a substituted or unsubstituted alkyl group having 1 to 30 carbon atoms. The alkyl group preferably has 1 to 20 carbon atoms, more preferably 1 to 6 carbon atoms.

In an exemplary arrangement of the composition according to the exemplary embodiment, the group represented by the formula (C4) is represented by a formula (C41) below.

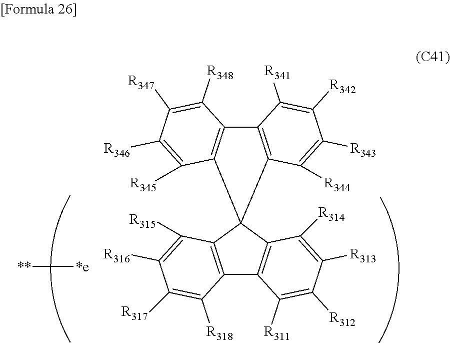

In the formula (C41):
one of R₃₁₁ to R₃₁₈ is a single bond with *e;
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ neither being the single bond with *e nor forming the substituted or unsubstituted benzene ring are each independently as defined in the formula (C4);
R₃₄₁ to R₃₄₈ are each independently a hydrogen atom, a substituted or unsubstituted alkyl group having 1 to 30 carbon atoms, a substituted or unsubstituted aryl group having 6 to 30 ring carbon atoms, or a substituted or unsubstituted heterocyclic group having 5 to 30 ring atoms; and
** represents a bonding position to L_{A1}, L_{A2}, L_{A3}, L_{C1}, L_{C2}, L_{C3}, or L_{C4.}

In an exemplary arrangement of the composition according to the exemplary embodiment, at least one of R₃₄₁ to R₃₄₄ is a substituted or unsubstituted alkyl group having 1 to 30 carbon atoms, and at least one of R₃₄₅ to R₃₄₈ is a substituted or unsubstituted alkyl group having 1 to 30 carbon atoms. The alkyl group preferably has 1 to 20 carbon atoms, more preferably 1 to 6 carbon atoms.

In an exemplary arrangement of the composition according to the exemplary embodiment, a combination of of R₃₁₉ and R₃₂₀ in the formula (C4) are not mutually bonded.

In an exemplary arrangement of the composition according to the exemplary embodiment, at least one of R₃₁₁ to R₃₁₈ in the formula (C4) is a substituted or unsubstituted alkyl group having 1 to 30 ring carbon atoms.

In an exemplary arrangement of the composition according to the exemplary embodiment, one of R₃₁₃ to R₃₁₆ in the formula (C4) is a single bond with *e.

In an exemplary arrangement of the composition according to the exemplary embodiment, Ar₁₁₁, Ar₁₁₂, and Ar₁₁₃ in a compound represented by the formula (C1) and Ar₁₃₁, Ar₁₃₂, Ar₁₃₃, and Ar₁₃₄ in a compound represented by the formula (C3) are each independently a group represented by a formula (2-a), (2-b), (2-c), (2-d), (2-e), or (2-f).

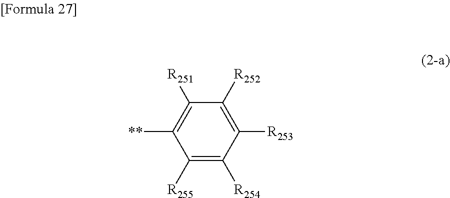

In the formula (2-a):
none of a combination(s) of adjacent two or more of R₂₅₁ to R₂₅₅ are bonded to each other;
R₂₅₁ to R₂₅₅ are each independently a hydrogen atom, a substituted or unsubstituted alkyl group having 1 to 30 carbon atoms, or a substituted or unsubstituted cycloalkyl group having 3 to 30 ring atoms; and
** represents a bonding position.

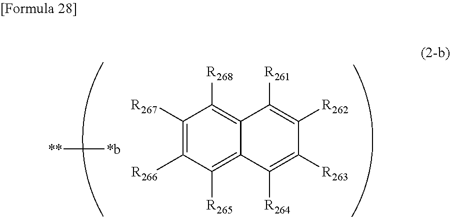

In the formula (2-b):
one of R₂₆₁ to R₂₆₈ is a single bond with *b;
none of a combination(s) of adjacent two or more of R₂₆₁ to R₂₆₈ not being the single bond with *b are bonded to each other;
R₂₆₁ to R₂₆₈ not being the single bond with *b are each independently a hydrogen atom, a substituted or unsubstituted alkyl group having 1 to 30 carbon atoms, a substituted or unsubstituted cycloalkyl group having 3 to 30 ring atoms; or a substituted or unsubstituted aryl group having 6 to 12 ring carbon atoms; and
** represents a bonding position.

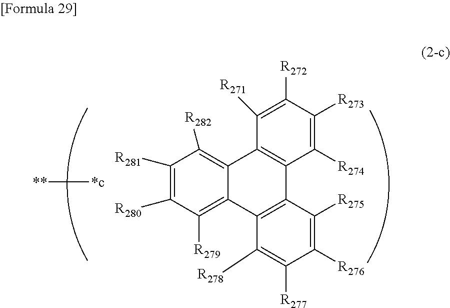

In the formula (2-c):
one of R₂₇₁ to R₂₈₂ is a single bond with *c;
none of a combination(s) of adjacent two or more of R₂₇₁ to R₂₈₂ not being the single bond with *c are bonded to each other;
R₂₇₁ to R₂₈₂ not being the single bond with *c are each independently a hydrogen atom, a substituted or unsubstituted alkyl group having 1 to 30 carbon atoms, a substituted or unsubstituted cycloalkyl group having 3 to 30 ring atoms; or a substituted or unsubstituted aryl group having 6 to 12 ring carbon atoms; and
** represents a bonding position.

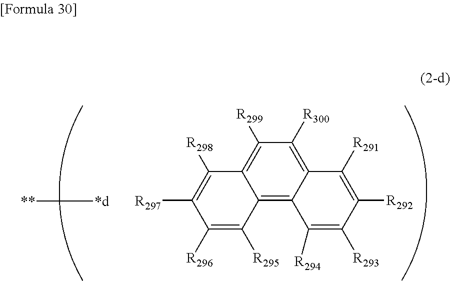

In the formula (2-d):
one of R₂₉₁ to R₃₀₀ is a single bond with *d;
none of a combination(s) of adjacent two or more of R₂₉₁ to R₃₀₀ not being the single bond with *d are bonded to each other;
R₂₉₁ to R₃₀₀ not being the single bond with *d are each independently a hydrogen atom, a substituted or unsubstituted alkyl group having 1 to 30 carbon atoms, a substituted or unsubstituted cycloalkyl group having 3 to 30 ring atoms; or a substituted or unsubstituted aryl group having 6 to 12 ring carbon atoms; and
** represents a bonding position.

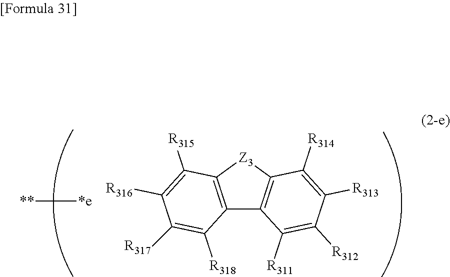

In the formula (2-e):
Z₃ is an oxygen atom, a sulfur atom, NR₃₁₉, or C(R₃₂₀)(R₃₂₁);
one of R₃₁₁ to R₃₂₁ is a single bond with *e, or one of carbon atoms of a substituted or unsubstituted benzene ring, described below, formed by mutually bonding a combination of adjacent two or more of R₃₁₁ to R₃₁₈ is bonded to *e by a single bond;
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, a substituted or unsubstituted alkyl group having 1 to 30 carbon atoms, a substituted or unsubstituted cycloalkyl group having 3 to 30 ring atoms, a substituted or unsubstituted aryl group having 6 to 12 ring carbon atoms, or a substituted or unsubstituted heterocyclic group having 5 to 10 ring atoms;
R₃₁₉ not being the single bond with *e is a hydrogen atom, a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e are mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position.

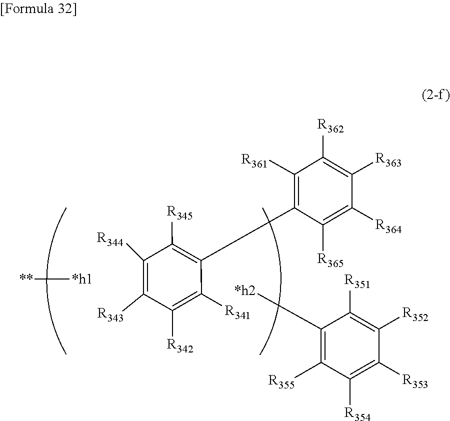

In the formula (2-f):
one of R₃₄₁ to R₃₄₅ is a single bond with *h1 and another one of R₃₄₁ to R₃₄₅ is a single bond with *h2;
none of a combination(s) of adjacent two or more of R₃₄₁ to R₃₄₅ not being the single bond with *h1 and not being the single bond with *h2 are bonded to each other;
at least one combination of adjacent two or more of R₃₅₁ to R₃₅₅ are mutually bonded to form a substituted or unsubstituted monocyclic ring, mutually bonded to form a substituted or unsubstituted fused ring, or not mutually bonded;
at least one combination of adjacent two or more of R₃₆₁ to R₃₆₅ are mutually bonded to form a substituted or unsubstituted monocyclic ring, mutually bonded to form a substituted or unsubstituted fused ring, or not mutually bonded;
R₃₄₁ to R₃₄₅ not being the single bond with *h1 and not being the single bond with *h2 as well as R₃₅₁ to R₃₅₅ and R₃₆₁ to R₃₆₅ forming neither the substituted or unsubstituted monocyclic ring nor the substituted or unsubstituted fused ring are each independently a hydrogen atom, a substituted or unsubstituted alkyl group having 1 to 30 carbon atoms, a substituted or unsubstituted cycloalkyl group having 3 to 30 ring atoms; or a substituted or unsubstituted aryl group having 6 to 12 ring carbon atoms; and
** represents a bonding position.

** in the formulae (2-a), (2-b), (2-c), (2-d), (2-e), and (2-f) are each independently a bonding position to L_{A1}, L_{A2}, L_{A3}, L_{C1}, L_{C2}, L_{C3}, or L_{C4}, or a bonding position to a nitrogen atom of an amino group.

In an exemplary arrangement of the composition according to the exemplary embodiment, L_{A1}, L_{A2}, L_{A3}, L_{C1}, L_{C2}, L_{C3}, and L_{C4} are each independently a single bond, a substituted or unsubstituted o-phenylene group, a substituted or unsubstituted m-phenylene group, or a substituted or unsubstituted p-phenylene group.

In an exemplary arrangement of the composition according to the exemplary embodiment, L_{A1}, L_{A2}, L_{A3}, L_{C1}, L_{C2}, L_{C3}, and L_{C4} are each independently a single bond, a substituted or unsubstituted o-phenylene group, or a substituted or unsubstituted m-phenylene group.

In an exemplary arrangement of the organic EL device according to the exemplary embodiment, the first and second compounds are each independently a monoamine compound having one substituted or unsubstituted amino group in a molecule, or a diamine compound having two substituted or unsubstituted amino groups in a molecule.

In an exemplary arrangement of the organic EL device according to the exemplary embodiment, the first and second compounds are each independently a monoamine compound.

In the monoamine compound and the diamine compound, a nitrogen atom of an amino group is not a ring atom. When a nitrogen atom is a ring atom in a carbazole ring, an azine ring, and the like, the nitrogen atom is not a nitrogen atom as an amino group.

For instance, a compound HT-X below has two nitrogen atoms in a molecule: one nitrogen atom in the compound HT-X is a ring atom of a carbazole ring and the other nitrogen atom is not a ring atom but a nitrogen atom as an amino group. The compound HT-X is a compound having a structure in which 9-phenyl-3-carbazolyl group is bonded to a nitrogen atom of an amino group via a linking group, that is, a monoamine compound.

A compound HT-Y below is also a compound having a structure in which 9-carbazolyl group is bonded to a nitrogen atom of an amino group via a linking group, that is, a monoamine compound.

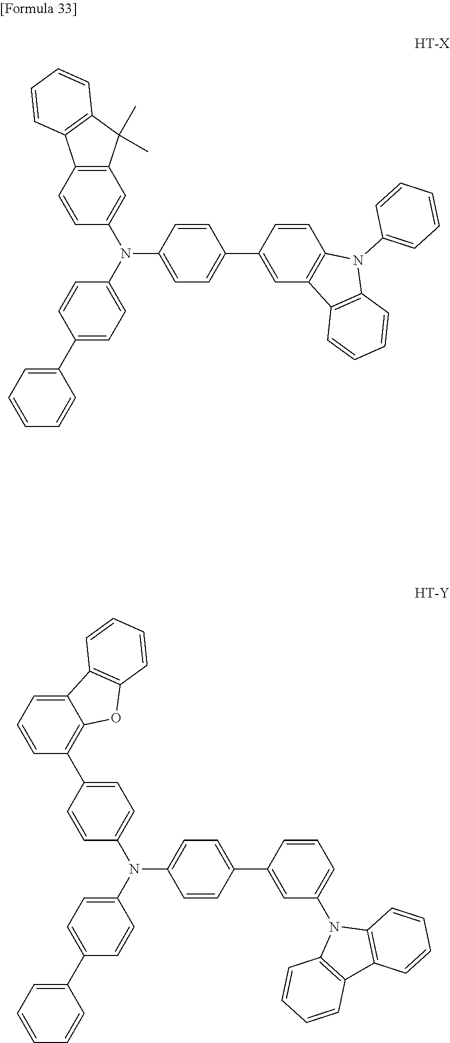 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

### Ratio of Compounds in Composition

In an exemplary arrangement of the composition according to the exemplary embodiment, a ratio (mass ratio) of the first and second compounds in the composition is in a range from 1:99 to 99:1, from 10:90 to 90:10, from 30:70 to 70:30, from 40:60 to 60:40, or from 45:55 to 55:45.

In an exemplary arrangement of the composition according to the exemplary embodiment, a mass percentage of the first compound M_{C1} to the sum M_{C1}+M_{C2} of the mass of the first compound M_{C1} and the mass of the second compound M_{C2} in the composition is in a range from 1 mass % to 99 mass %.

In an exemplary arrangement of the composition of the exemplary embodiment, the mass percentage of the second compound M_{C2} to the sum M_{C1}+M_{C2} is 10 mass % or more, 30 mass % or more, 40 mass % or more, or 45 mass % or more.

In an exemplary arrangement of the composition of the exemplary embodiment, the mass percentage of the first compound M_{C1} to the sum M_{C1}+M_{C2} is 90 mass % or less, 70 mass % or less, 60 mass % or less, or 55 mass % or less.

In an exemplary arrangement of the composition of the exemplary embodiment, the composition is in a form of mixed powder.

In an exemplary arrangement of the composition of the exemplary embodiment, the composition is not in a form of a film or layer.

In an exemplary arrangement of the composition of the exemplary embodiment, the composition may be in a form of a film or layer as described later in a second exemplary embodiment.

### Production Method of First Compound and Second Compound

The first compound and the second compound contained in the composition according to the exemplary embodiment is producible by a known method or through a known alternative reaction using a known material(s) tailored for the target compound in accordance with the known method.

### Specific Examples of First Compound and Second Compound

Specific examples of the first compound and the second compound according to the exemplary embodiment include the following compounds. However, the invention is by no means limited to these specific examples.

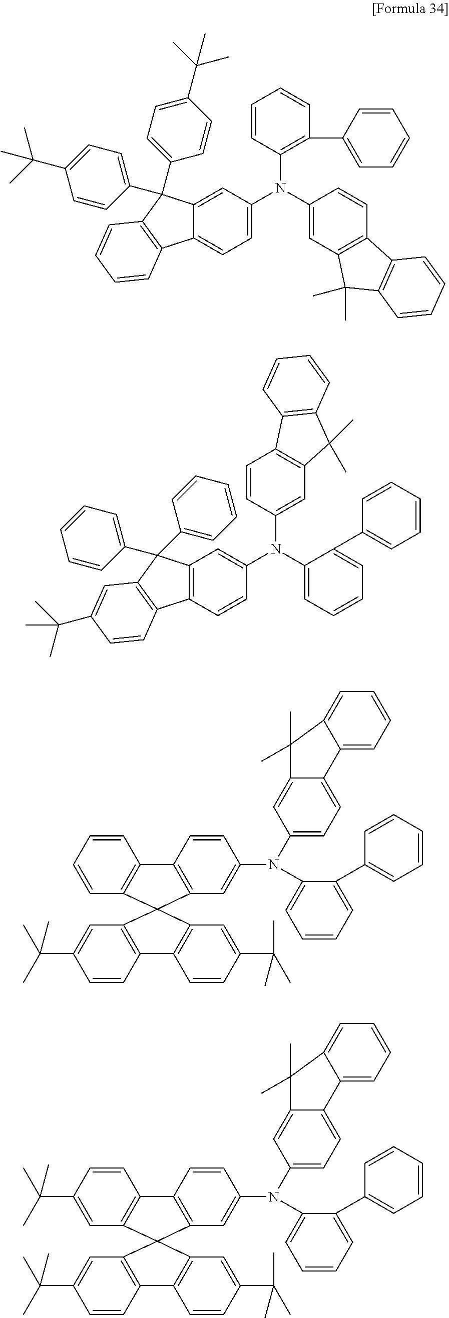 [SMILES: CC(C)(C)c1ccc(C2(c3ccc(C(C)(C)C)cc3)c3ccccc3-c3ccc(N(c4ccc5c(c4)C(C)(C)c4ccccc4-5)c4ccccc4-c4ccccc4)cc32)cc1 ; CC(C)(C)c1ccc2c(c1)C(c1ccccc1)(c1ccccc1)c1cc(N(c3ccc4c(c3)C(C)(C)c3ccccc3-4)c3ccccc3-c3ccccc3)ccc1-2 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC(C)(C)c1ccc2c(c1)C1(c3cc(N(c4ccc5c(c4)C(C)(C)c4ccccc4-5)c4ccccc4-c4ccccc4)ccc3-2)c2cc(C(C)(C)C)ccc2-c2ccc(C(C)(C)C)cc21]

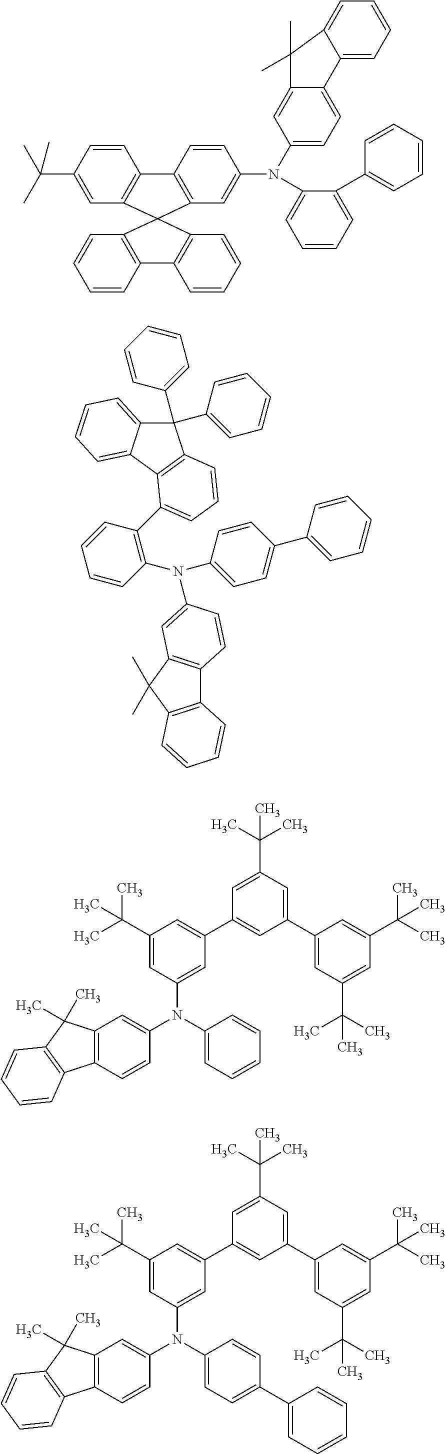

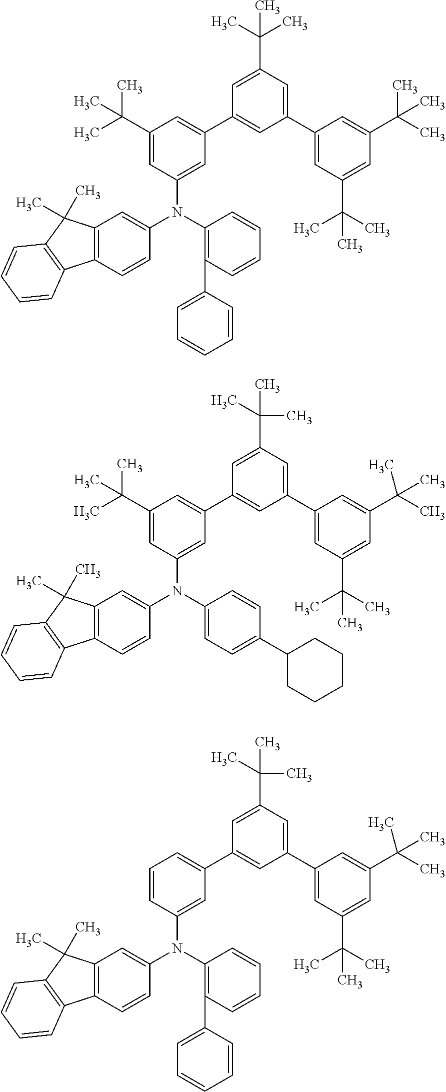 [SMILES: CC(C)(C)c1cc(-c2cc(N(c3ccc4c(c3)C(C)(C)c3ccccc3-4)c3ccccc3-c3ccccc3)cc(C(C)(C)C)c2)cc(-c2cc(C(C)(C)C)cc(C(C)(C)C)c2)c1 ; CC(C)(C)c1cc(-c2cc(N(c3ccc(C4CCCCC4)cc3)c3ccc4c(c3)C(C)(C)c3ccccc3-4)cc(C(C)(C)C)c2)cc(-c2cc(C(C)(C)C)cc(C(C)(C)C)c2)c1 ; CC(C)(C)c1cc(-c2cccc(N(c3ccc4c(c3)C(C)(C)c3ccccc3-4)c3ccccc3-c3ccccc3)c2)cc(-c2cc(C(C)(C)C)cc(C(C)(C)C)c2)c1]

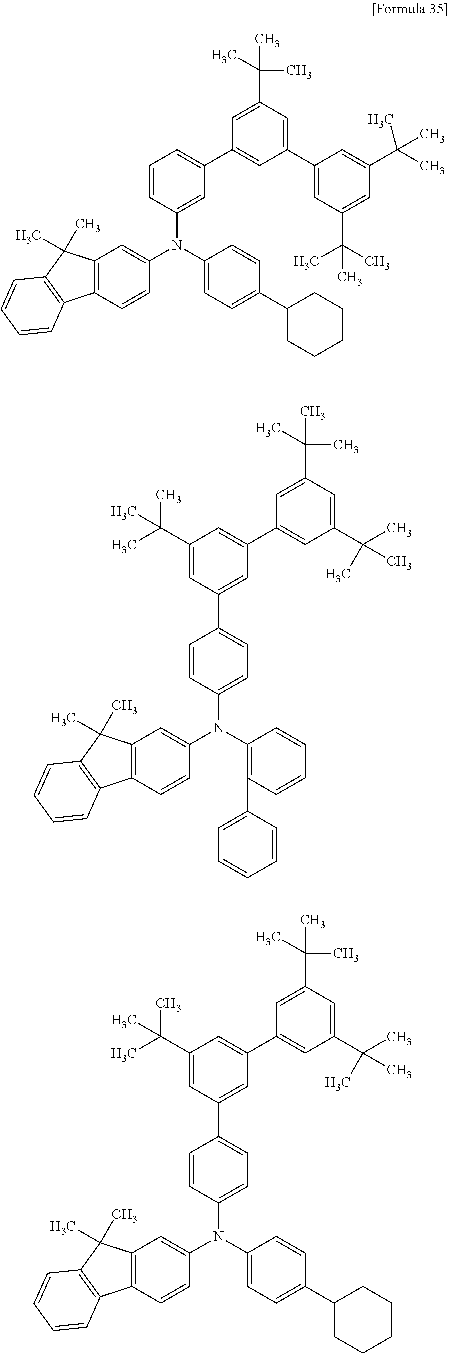 [SMILES: CC(C)(C)c1cc(-c2cccc(N(c3ccc(C4CCCCC4)cc3)c3ccc4c(c3)C(C)(C)c3ccccc3-4)c2)cc(-c2cc(C(C)(C)C)cc(C(C)(C)C)c2)c1 ; CC(C)(C)c1cc(-c2ccc(N(c3ccc4c(c3)C(C)(C)c3ccccc3-4)c3ccccc3-c3ccccc3)cc2)cc(-c2cc(C(C)(C)C)cc(C(C)(C)C)c2)c1 ; CC(C)(C)c1cc(-c2ccc(N(c3ccc(C4CCCCC4)cc3)c3ccc4c(c3)C(C)(C)c3ccccc3-4)cc2)cc(-c2cc(C(C)(C)C)cc(C(C)(C)C)c2)c1]

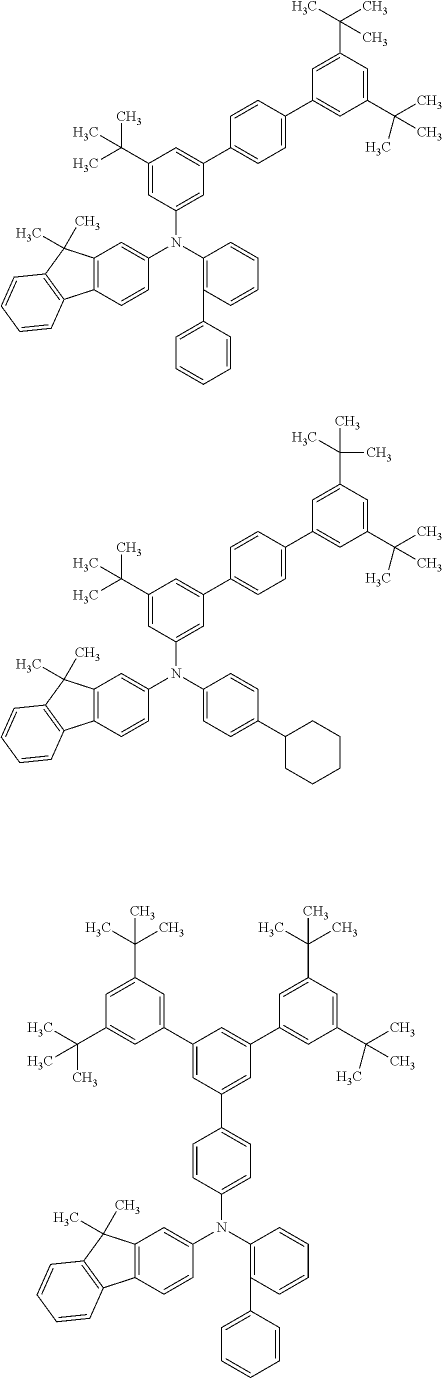 [SMILES: CC(C)(C)c1cc(-c2ccc(-c3cc(C(C)(C)C)cc(C(C)(C)C)c3)cc2)cc(N(c2ccc3c(c2)C(C)(C)c2ccccc2-3)c2ccccc2-c2ccccc2)c1 ; CC(C)(C)c1cc(-c2ccc(-c3cc(C(C)(C)C)cc(C(C)(C)C)c3)cc2)cc(N(c2ccc(C3CCCCC3)cc2)c2ccc3c(c2)C(C)(C)c2ccccc2-3)c1 ; CC(C)(C)c1cc(-c2cc(-c3ccc(N(c4ccc5c(c4)C(C)(C)c4ccccc4-5)c4ccccc4-c4ccccc4)cc3)cc(-c3cc(C(C)(C)C)cc(C(C)(C)C)c3)c2)cc(C(C)(C)C)c1]

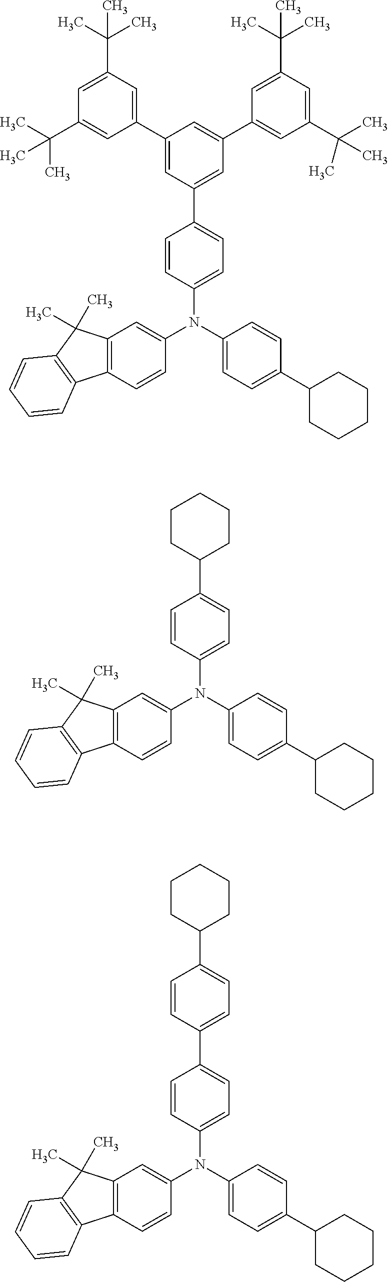 [SMILES: CC(C)(C)c1cc(-c2cc(-c3ccc(N(c4ccc(C5CCCCC5)cc4)c4ccc5c(c4)C(C)(C)c4ccccc4-5)cc3)cc(-c3cc(C(C)(C)C)cc(C(C)(C)C)c3)c2)cc(C(C)(C)C)c1 ; CC1(C)c2ccccc2-c2ccc(N(c3ccc(C4CCCCC4)cc3)c3ccc(C4CCCCC4)cc3)cc21 ; CC1(C)c2ccccc2-c2ccc(N(c3ccc(-c4ccc(C5CCCCC5)cc4)cc3)c3ccc(C4CCCCC4)cc3)cc21]

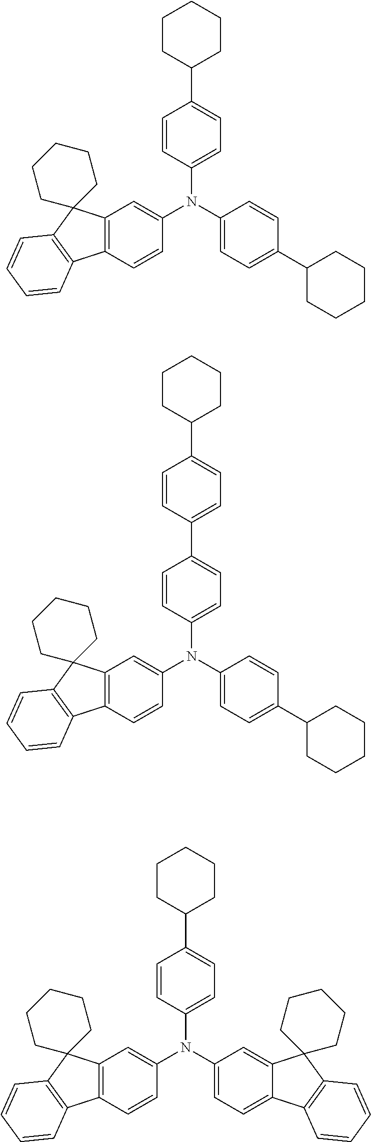 [SMILES: c1ccc2c(c1)-c1ccc(N(c3ccc(C4CCCCC4)cc3)c3ccc(C4CCCCC4)cc3)cc1C21CCCCC1 ; c1ccc2c(c1)-c1ccc(N(c3ccc(-c4ccc(C5CCCCC5)cc4)cc3)c3ccc(C4CCCCC4)cc3)cc1C21CCCCC1 ; c1ccc2c(c1)-c1ccc(N(c3ccc(C4CCCCC4)cc3)c3ccc4c(c3)C3(CCCCC3)c3ccccc3-4)cc1C21CCCCC1]

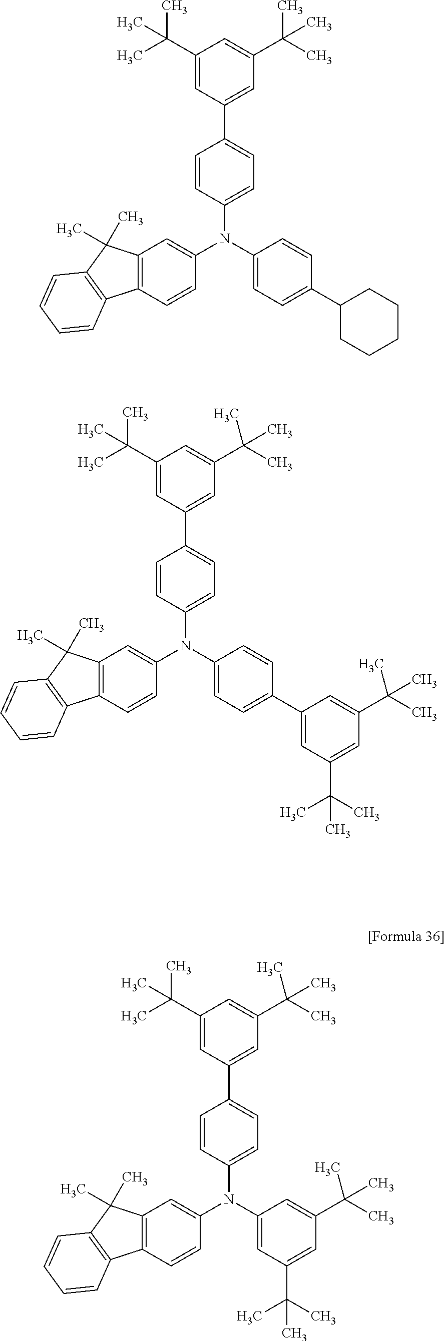 [SMILES: CC(C)(C)c1cc(-c2ccc(N(c3ccc(C4CCCCC4)cc3)c3ccc4c(c3)C(C)(C)c3ccccc3-4)cc2)cc(C(C)(C)C)c1 ; CC(C)(C)c1cc(-c2ccc(N(c3ccc(-c4cc(C(C)(C)C)cc(C(C)(C)C)c4)cc3)c3ccc4c(c3)C(C)(C)c3ccccc3-4)cc2)cc(C(C)(C)C)c1 ; CC(C)(C)c1cc(-c2ccc(N(c3cc(C(C)(C)C)cc(C(C)(C)C)c3)c3ccc4c(c3)C(C)(C)c3ccccc3-4)cc2)cc(C(C)(C)C)c1]

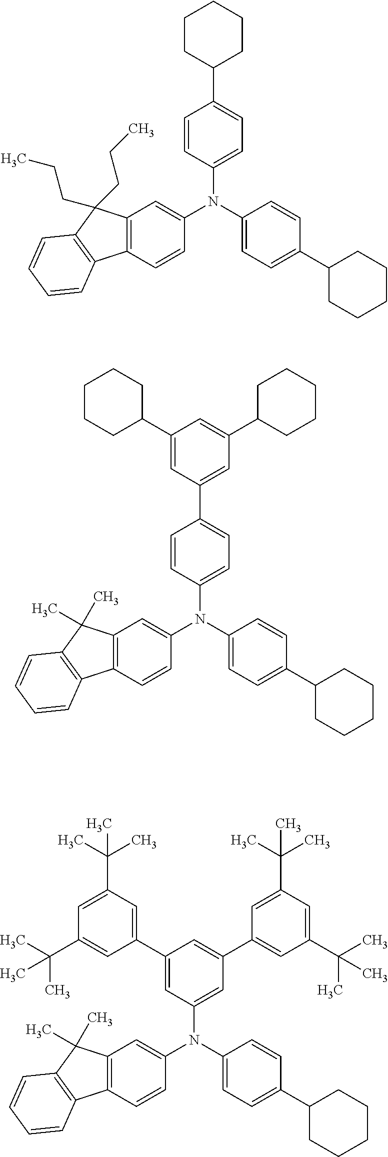 [SMILES: CCCC1(CCC)c2ccccc2-c2ccc(N(c3ccc(C4CCCCC4)cc3)c3ccc(C4CCCCC4)cc3)cc21 ; CC1(C)c2ccccc2-c2ccc(N(c3ccc(-c4cc(C5CCCCC5)cc(C5CCCCC5)c4)cc3)c3ccc(C4CCCCC4)cc3)cc21 ; CC(C)(C)c1cc(-c2cc(-c3cc(C(C)(C)C)cc(C(C)(C)C)c3)cc(N(c3ccc(C4CCCCC4)cc3)c3ccc4c(c3)C(C)(C)c3ccccc3-4)c2)cc(C(C)(C)C)c1]

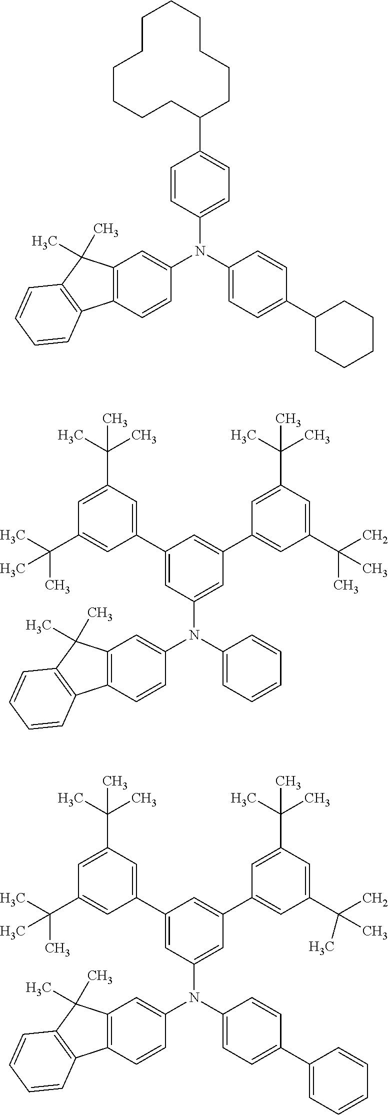 [SMILES: CC1(C)c2ccccc2-c2ccc(N(c3ccc(C4CCCCCCCCCCC4)cc3)c3ccc(C4CCCCC4)cc3)cc21 ; CC(C)(C)c1cc(-c2cc(-c3cc(C(C)(C)C)cc(C(C)(C)C)c3)cc(N(c3ccccc3)c3ccc4c(c3)C(C)(C)c3ccccc3-4)c2)cc(C(C)(C)C)c1 ; CC(C)(C)c1cc(-c2cc(-c3cc(C(C)(C)C)cc(C(C)(C)C)c3)cc(N(c3ccc(-c4ccccc4)cc3)c3ccc4c(c3)C(C)(C)c3ccccc3-4)c2)cc(C(C)(C)C)c1]

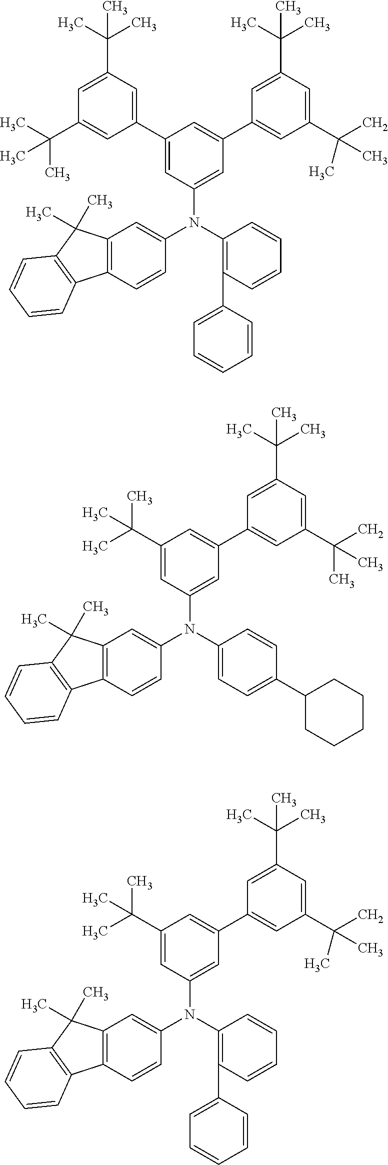 [SMILES: CC(C)(C)c1cc(-c2cc(-c3cc(C(C)(C)C)cc(C(C)(C)C)c3)cc(N(c3ccc4c(c3)C(C)(C)c3ccccc3-4)c3ccccc3-c3ccccc3)c2)cc(C(C)(C)C)c1 ; CC(C)(C)c1cc(-c2cc(C(C)(C)C)cc(C(C)(C)C)c2)cc(N(c2ccc(C3CCCCC3)cc2)c2ccc3c(c2)C(C)(C)c2ccccc2-3)c1 ; CC(C)(C)c1cc(-c2cc(C(C)(C)C)cc(C(C)(C)C)c2)cc(N(c2ccc3c(c2)C(C)(C)c2ccccc2-3)c2ccccc2-c2ccccc2)c1]

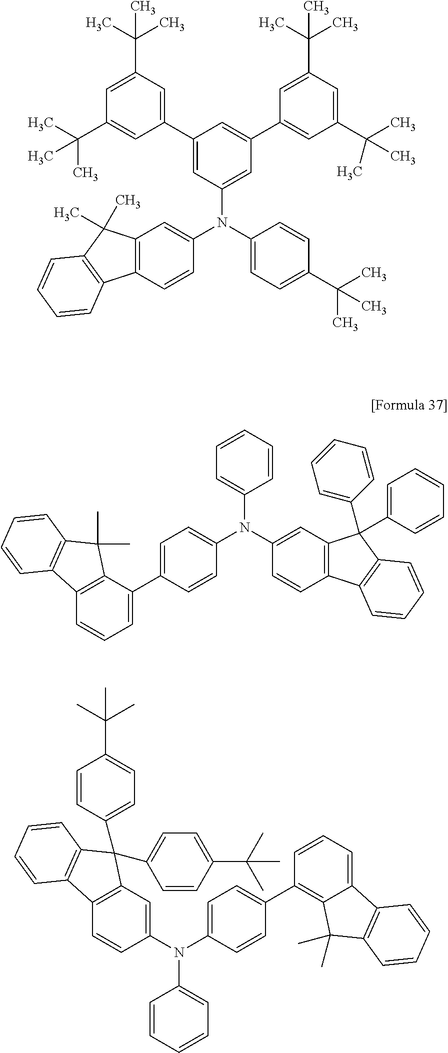 [SMILES: CC(C)(C)c1ccc(N(c2cc(-c3cc(C(C)(C)C)cc(C(C)(C)C)c3)cc(-c3cc(C(C)(C)C)cc(C(C)(C)C)c3)c2)c2ccc3c(c2)C(C)(C)c2ccccc2-3)cc1 ; CC1(C)c2ccccc2-c2cccc(-c3ccc(N(c4ccccc4)c4ccc5c(c4)C(c4ccccc4)(c4ccccc4)c4ccccc4-5)cc3)c21 ; CC(C)(C)c1ccc(C2(c3ccc(C(C)(C)C)cc3)c3ccccc3-c3ccc(N(c4ccccc4)c4ccc(-c5cccc6c5C(C)(C)c5ccccc5-6)cc4)cc32)cc1]

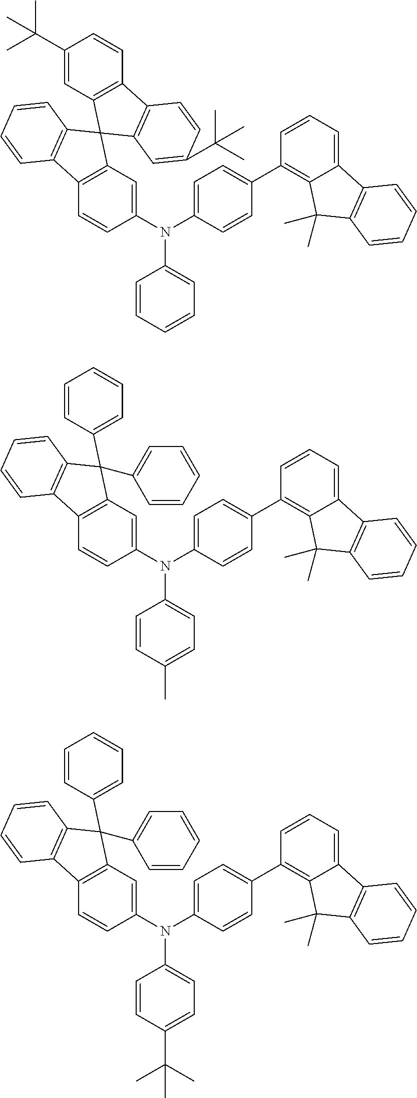 [SMILES: CC(C)(C)c1ccc2c(c1)C1(c3ccccc3-c3ccc(N(c4ccccc4)c4ccc(-c5cccc6c5C(C)(C)c5ccccc5-6)cc4)cc31)c1cc(C(C)(C)C)ccc1-2 ; Cc1ccc(N(c2ccc(-c3cccc4c3C(C)(C)c3ccccc3-4)cc2)c2ccc3c(c2)C(c2ccccc2)(c2ccccc2)c2ccccc2-3)cc1 ; CC(C)(C)c1ccc(N(c2ccc(-c3cccc4c3C(C)(C)c3ccccc3-4)cc2)c2ccc3c(c2)C(c2ccccc2)(c2ccccc2)c2ccccc2-3)cc1]

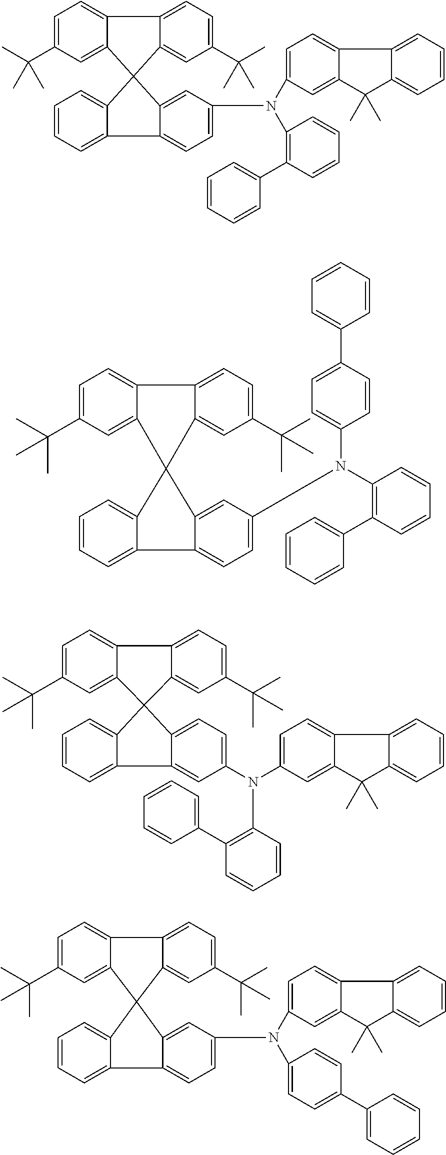 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccccc5)cc4)c4ccccc4-c4ccccc4)cc31)c1cc(C(C)(C)C)ccc1-2 ; CC(C)(C)c1ccc2c(c1)C1(c3ccccc3-c3cc(N(c4ccc5c(c4)C(C)(C)c4ccccc4-5)c4ccccc4-c4ccccc4)ccc31)c1cc(C(C)(C)C)ccc1-2 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

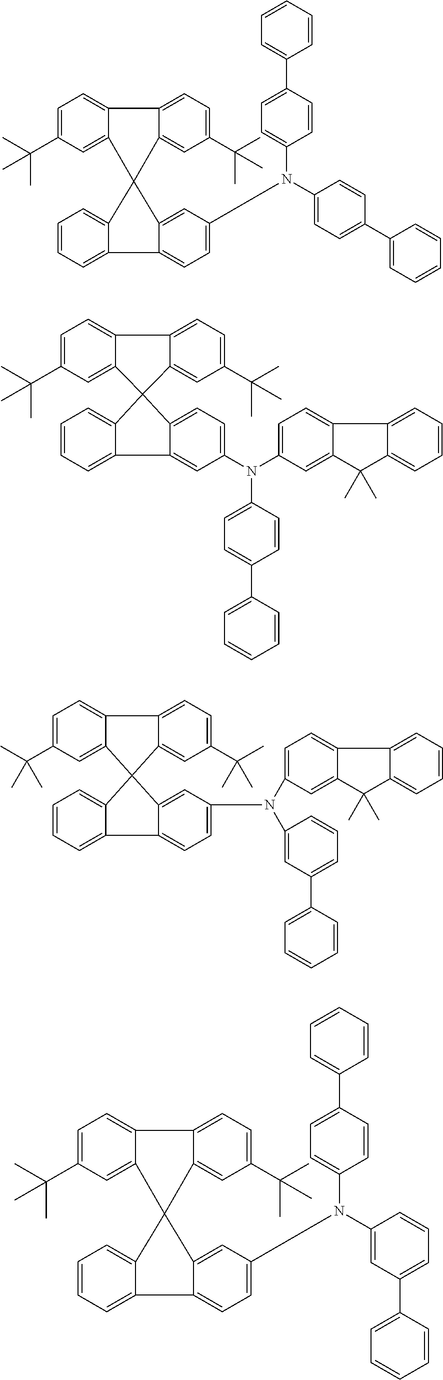 [SMILES: CC(C)(C)c1ccc2c(c1)C1(c3ccccc3-c3ccc(N(c4ccc(-c5ccccc5)cc4)c4ccc(-c5ccccc5)cc4)cc31)c1cc(C(C)(C)C)ccc1-2 ; CC(C)(C)c1ccc2c(c1)C1(c3ccccc3-c3cc(N(c4ccc(-c5ccccc5)cc4)c4ccc5c(c4)C(C)(C)c4ccccc4-5)ccc31)c1cc(C(C)(C)C)ccc1-2 ; CC(C)(C)c1ccc2c(c1)C1(c3ccccc3-c3ccc(N(c4cccc(-c5ccccc5)c4)c4ccc5c(c4)C(C)(C)c4ccccc4-5)cc31)c1cc(C(C)(C)C)ccc1-2 ; CC(C)(C)c1ccc2c(c1)C1(c3ccccc3-c3ccc(N(c4ccc(-c5ccccc5)cc4)c4cccc(-c5ccccc5)c4)cc31)c1cc(C(C)(C)C)ccc1-2]

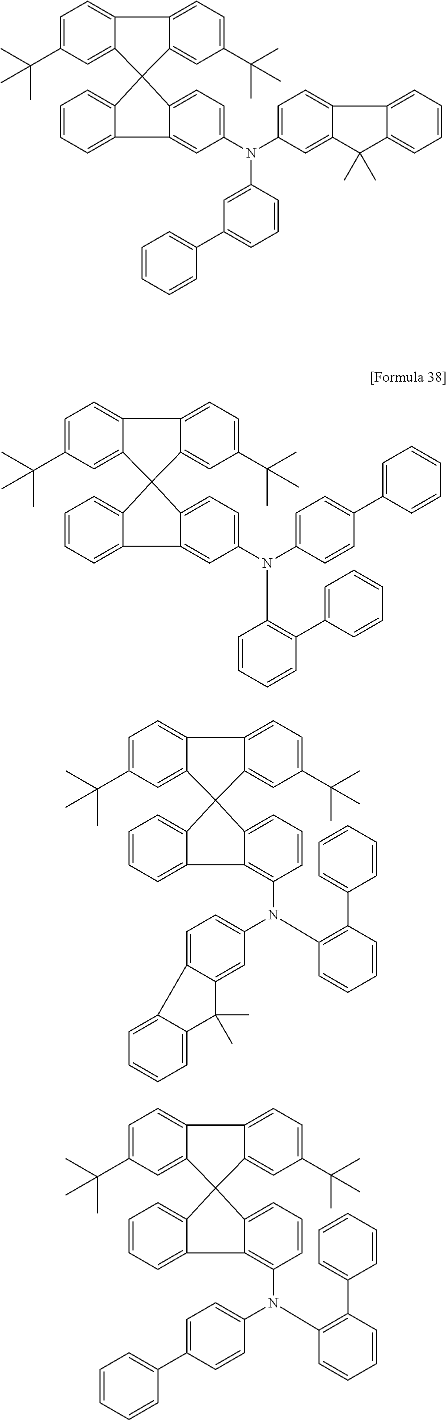

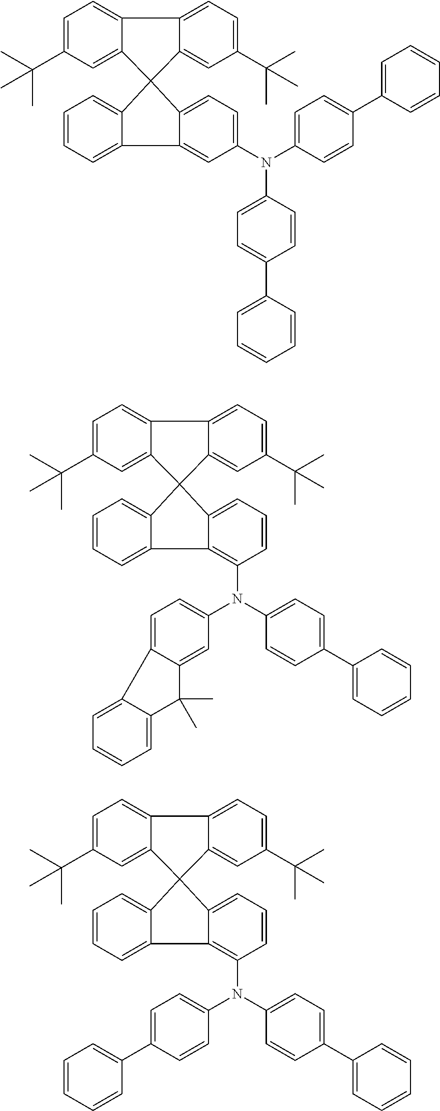

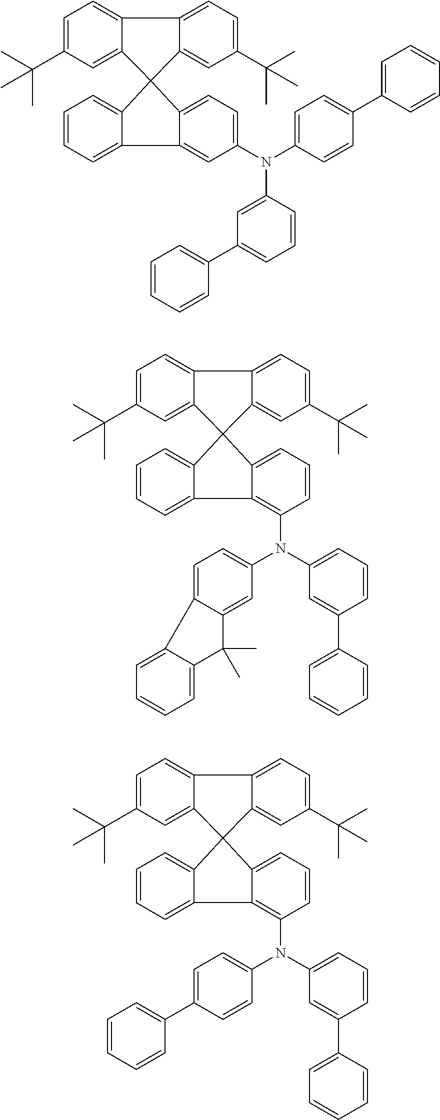

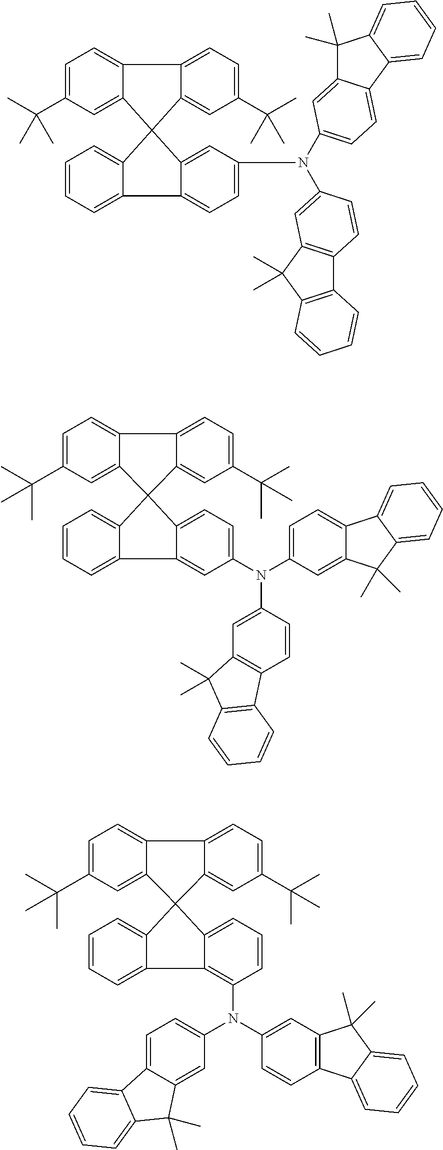 [SMILES: CC(C)(C)c1ccc2c(c1)C1(c3ccccc3-c3ccc(N(c4ccc5c(c4)C(C)(C)c4ccccc4-5)c4ccc5c(c4)C(C)(C)c4ccccc4-5)cc31)c1cc(C(C)(C)C)ccc1-2 ; CC(C)(C)c1ccc2c(c1)C1(c3ccccc3-c3cc(N(c4ccc5c(c4)C(C)(C)c4ccccc4-5)c4ccc5c(c4)C(C)(C)c4ccccc4-5)ccc31)c1cc(C(C)(C)C)ccc1-2 ; CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21]

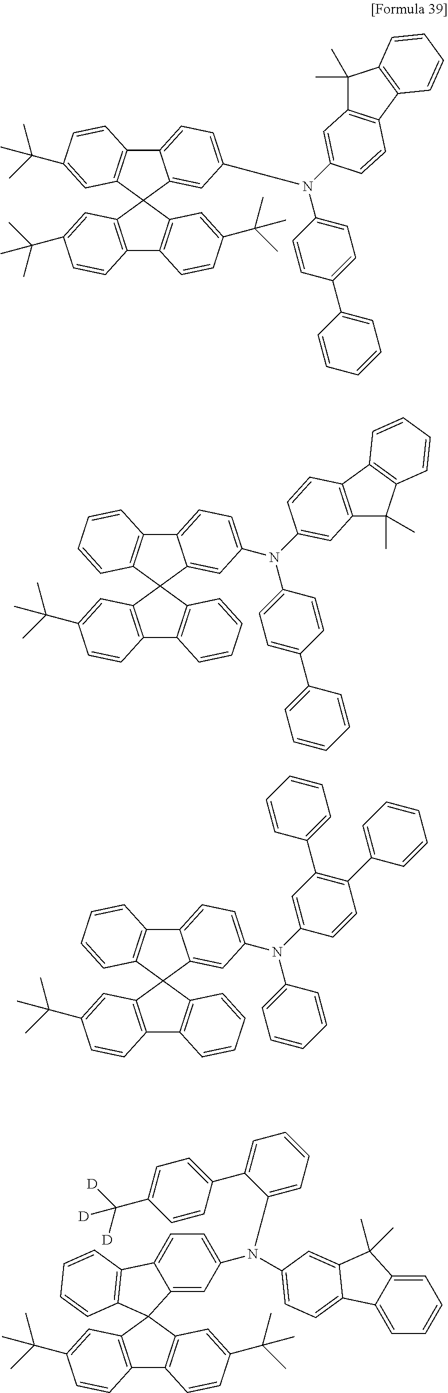

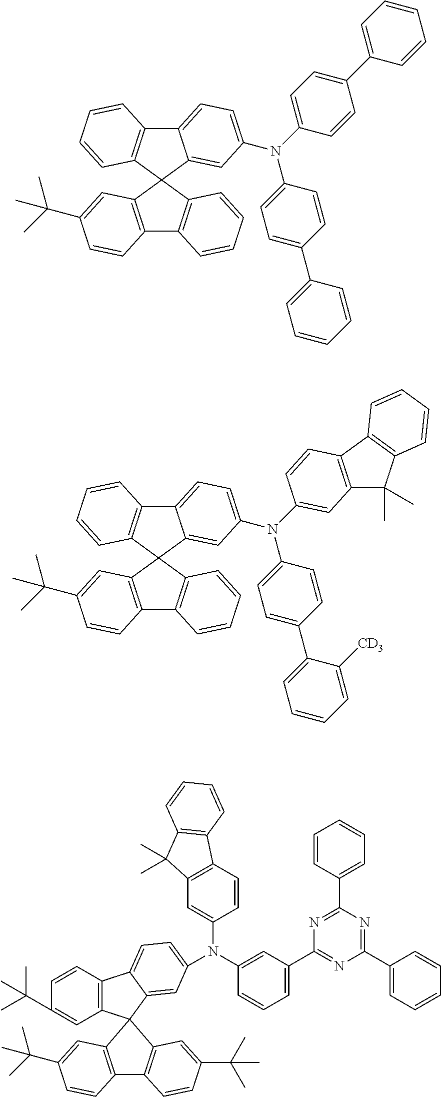 [SMILES: CC(C)(C)c1ccc2c(c1)C1(c3ccccc3-c3ccc(N(c4ccc(-c5ccccc5)cc4)c4ccc(-c5ccccc5)cc4)cc31)c1ccccc1-2 ; [2H]C([2H])([2H])c1ccccc1-c1ccc(N(c2ccc3c(c2)C(C)(C)c2ccccc2-3)c2ccc3c(c2)C2(c4ccccc4-3)c3ccccc3-c3ccc(C(C)(C)C)cc32)cc1 ; CC(C)(C)c1ccc2c(c1)C1(c3cc(N(c4cccc(-c5nc(-c6ccccc6)nc(-c6ccccc6)n5)c4)c4ccc5c(c4)C(C)(C)c4ccccc4-5)ccc3-2)c2cc(C(C)(C)C)ccc2-c2ccc(C(C)(C)C)cc21]

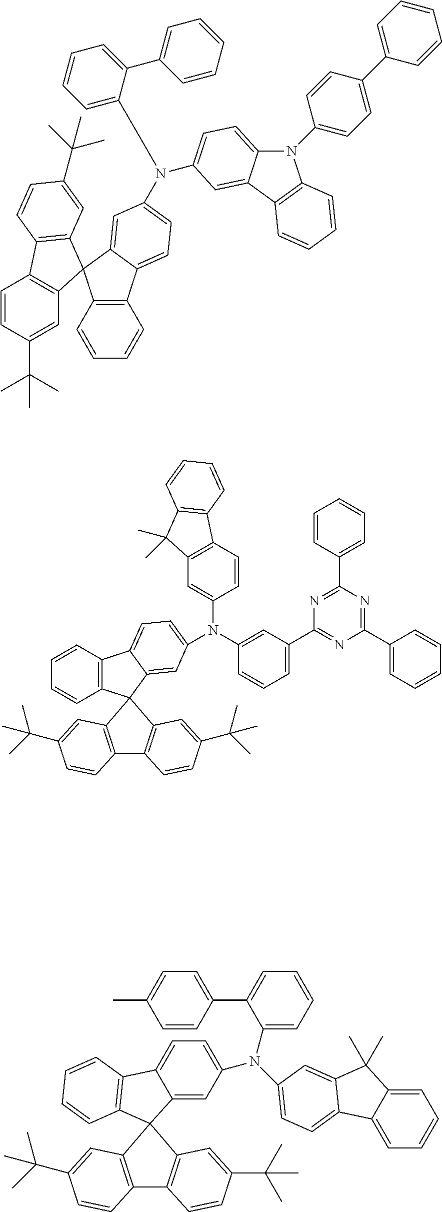 [SMILES: CC(C)(C)c1ccc2c(c1)C1(c3ccccc3-c3ccc(N(c4ccc5c(c4)c4ccccc4n5-c4ccc(-c5ccccc5)cc4)c4ccccc4-c4ccccc4)cc31)c1cc(C(C)(C)C)ccc1-2 ; CC(C)(C)c1ccc2c(c1)C1(c3ccccc3-c3ccc(N(c4cccc(-c5nc(-c6ccccc6)nc(-c6ccccc6)n5)c4)c4ccc5c(c4)C(C)(C)c4ccccc4-5)cc31)c1cc(C(C)(C)C)ccc1-2 ; Cc1ccc(-c2ccccc2N(c2ccc3c(c2)C(C)(C)c2ccccc2-3)c2ccc3c(c2)C2(c4ccccc4-3)c3cc(C(C)(C)C)ccc3-c3ccc(C(C)(C)C)cc32)cc1]

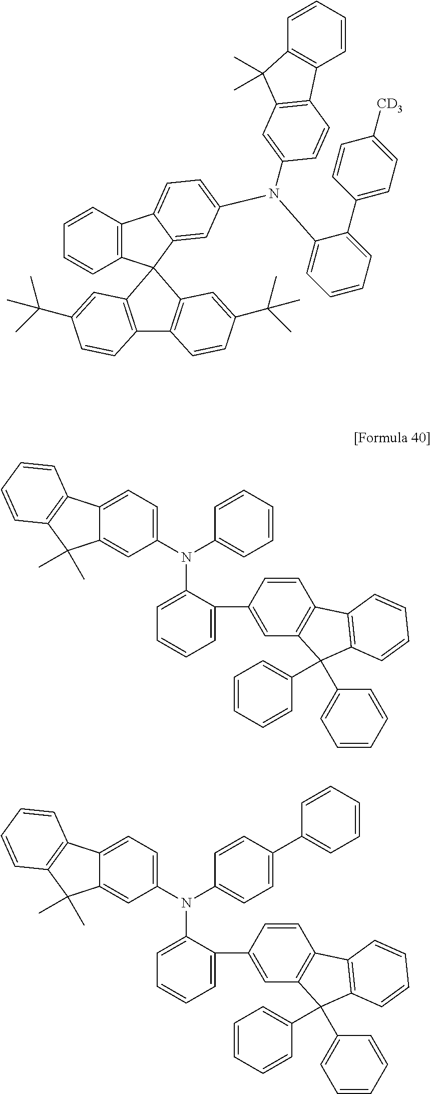

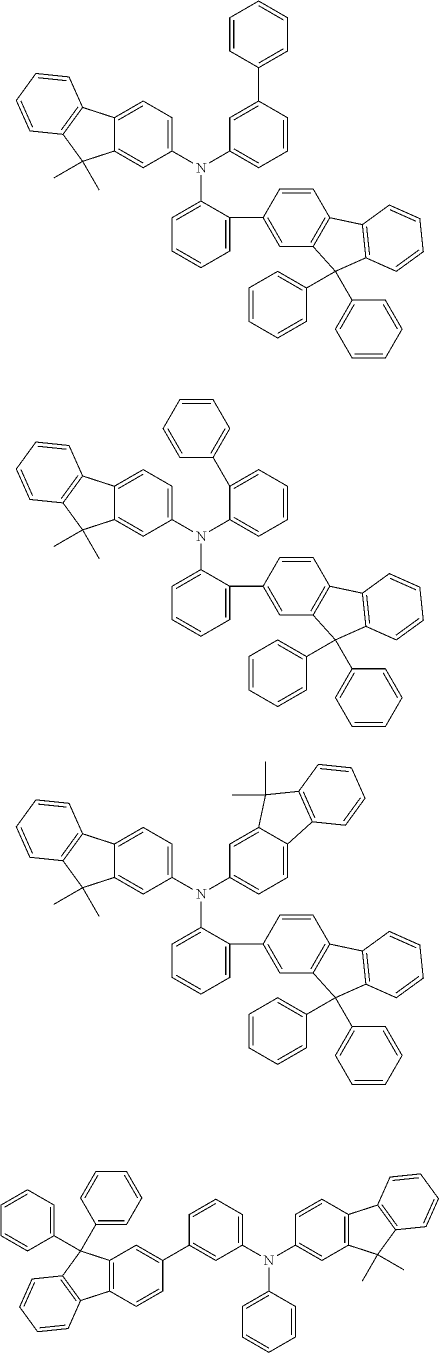

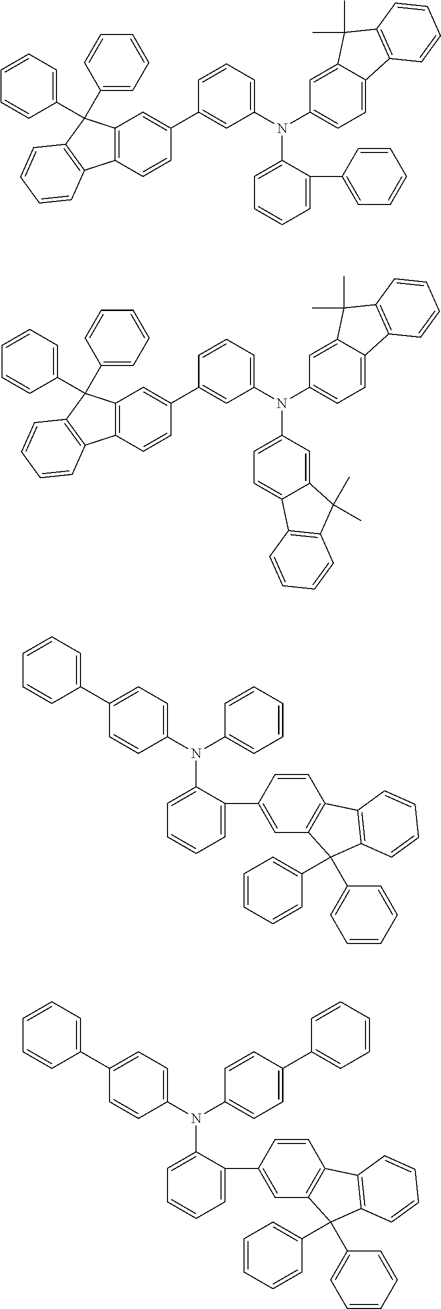 [SMILES: CC1(C)c2ccccc2-c2ccc(N(c3cccc(-c4ccc5c(c4)C(c4ccccc4)(c4ccccc4)c4ccccc4-5)c3)c3ccccc3-c3ccccc3)cc21 ; CC1(C)c2ccccc2-c2ccc(N(c3cccc(-c4ccc5c(c4)C(c4ccccc4)(c4ccccc4)c4ccccc4-5)c3)c3ccc4c(c3)C(C)(C)c3ccccc3-4)cc21 ; c1ccc(-c2ccc(N(c3ccccc3)c3ccccc3-c3ccc4c(c3)C(c3ccccc3)(c3ccccc3)c3ccccc3-4)cc2)cc1 ; c1ccc(-c2ccc(N(c3ccc(-c4ccccc4)cc3)c3ccccc3-c3ccc4c(c3)C(c3ccccc3)(c3ccccc3)c3ccccc3-4)cc2)cc1]

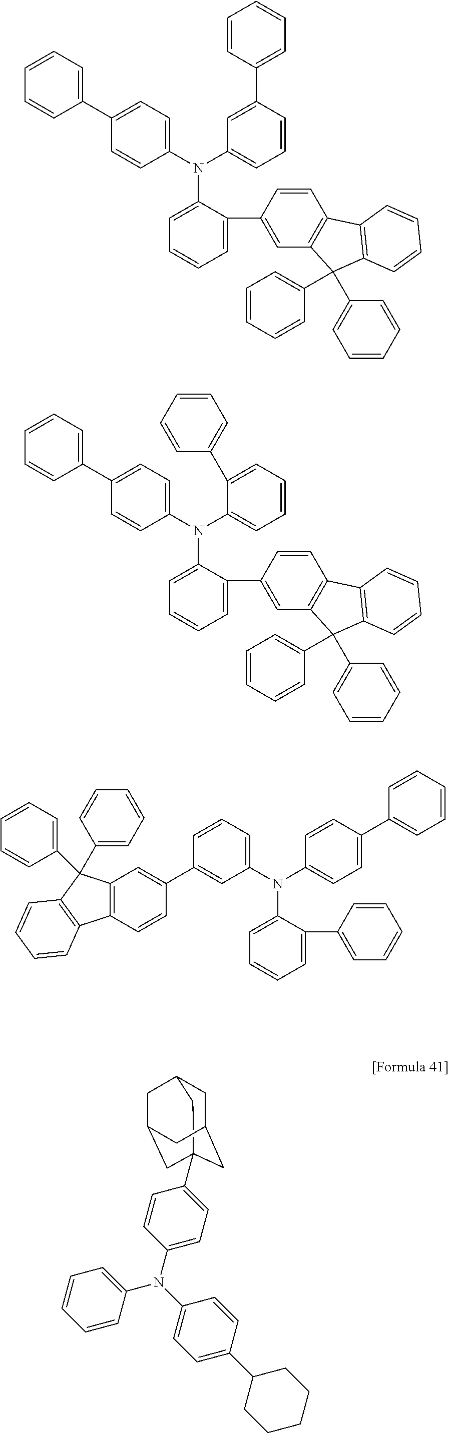 [SMILES: c1ccc(-c2ccc(N(c3cccc(-c4ccccc4)c3)c3ccccc3-c3ccc4c(c3)C(c3ccccc3)(c3ccccc3)c3ccccc3-4)cc2)cc1 ; c1ccc(-c2ccc(N(c3ccccc3-c3ccccc3)c3ccccc3-c3ccc4c(c3)C(c3ccccc3)(c3ccccc3)c3ccccc3-4)cc2)cc1 ; c1ccc(-c2ccc(N(c3cccc(-c4ccc5c(c4)C(c4ccccc4)(c4ccccc4)c4ccccc4-5)c3)c3ccccc3-c3ccccc3)cc2)cc1 ; c1ccc(N(c2ccc(C3CCCCC3)cc2)c2ccc(C34CC5CC(CC(C5)C3)C4)cc2)cc1]

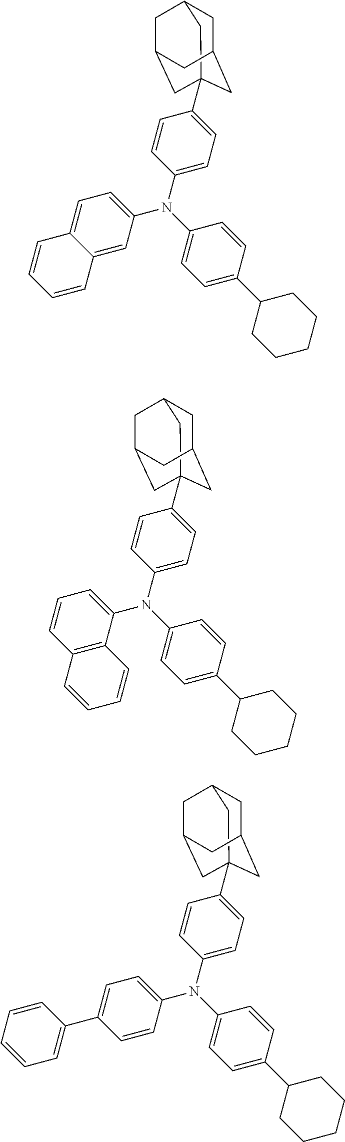 [SMILES: c1ccc2cc(N(c3ccc(C4CCCCC4)cc3)c3ccc(C45CC6CC(CC(C6)C4)C5)cc3)ccc2c1 ; c1ccc2c(N(c3ccc(C4CCCCC4)cc3)c3ccc(C45CC6CC(CC(C6)C4)C5)cc3)cccc2c1 ; c1ccc(-c2ccc(N(c3ccc(C4CCCCC4)cc3)c3ccc(C45CC6CC(CC(C6)C4)C5)cc3)cc2)cc1]

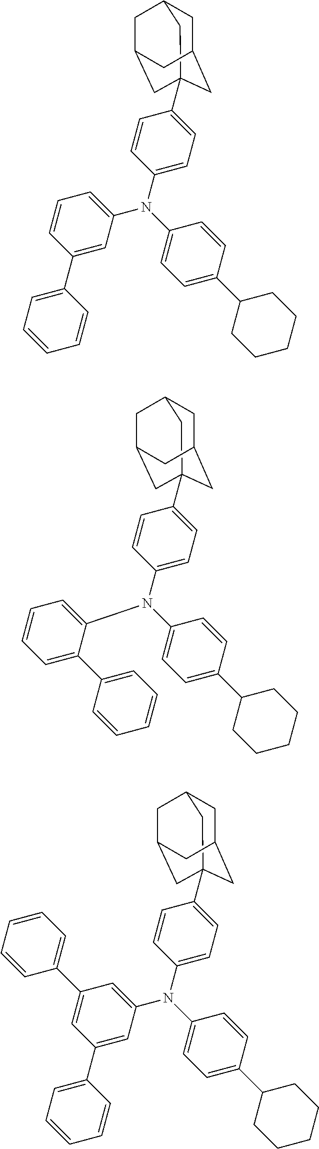 [SMILES: c1ccc(-c2cccc(N(c3ccc(C4CCCCC4)cc3)c3ccc(C45CC6CC(CC(C6)C4)C5)cc3)c2)cc1 ; c1ccc(-c2ccccc2N(c2ccc(C3CCCCC3)cc2)c2ccc(C34CC5CC(CC(C5)C3)C4)cc2)cc1 ; c1ccc(-c2cc(-c3ccccc3)cc(N(c3ccc(C4CCCCC4)cc3)c3ccc(C45CC6CC(CC(C6)C4)C5)cc3)c2)cc1]

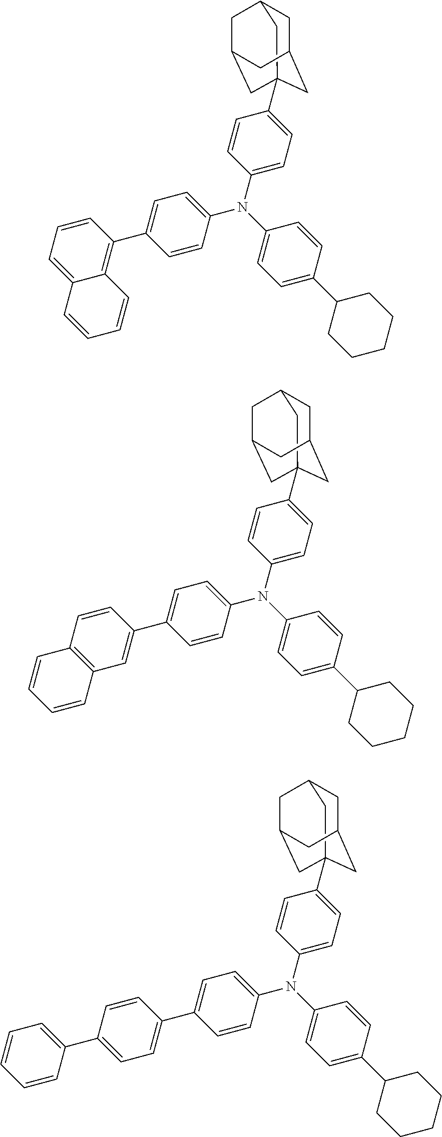 [SMILES: c1ccc2c(-c3ccc(N(c4ccc(C5CCCCC5)cc4)c4ccc(C56CC7CC(CC(C7)C5)C6)cc4)cc3)cccc2c1 ; c1ccc2cc(-c3ccc(N(c4ccc(C5CCCCC5)cc4)c4ccc(C56CC7CC(CC(C7)C5)C6)cc4)cc3)ccc2c1 ; c1ccc(-c2ccc(-c3ccc(N(c4ccc(C5CCCCC5)cc4)c4ccc(C56CC7CC(CC(C7)C5)C6)cc4)cc3)cc2)cc1]

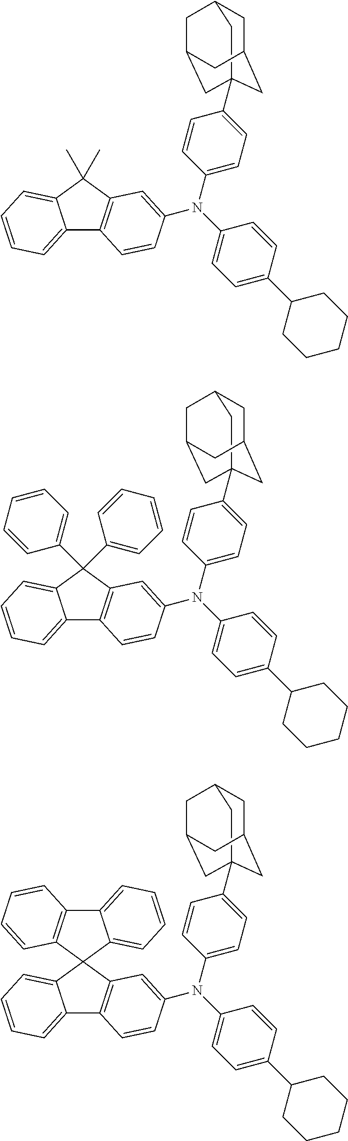 [SMILES: CC1(C)c2ccccc2-c2ccc(N(c3ccc(C4CCCCC4)cc3)c3ccc(C45CC6CC(CC(C6)C4)C5)cc3)cc21 ; c1ccc(C2(c3ccccc3)c3ccccc3-c3ccc(N(c4ccc(C5CCCCC5)cc4)c4ccc(C56CC7CC(CC(C7)C5)C6)cc4)cc32)cc1 ; c1ccc2c(c1)-c1ccccc1C21c2ccccc2-c2ccc(N(c3ccc(C4CCCCC4)cc3)c3ccc(C45CC6CC(CC(C6)C4)C5)cc3)cc21]

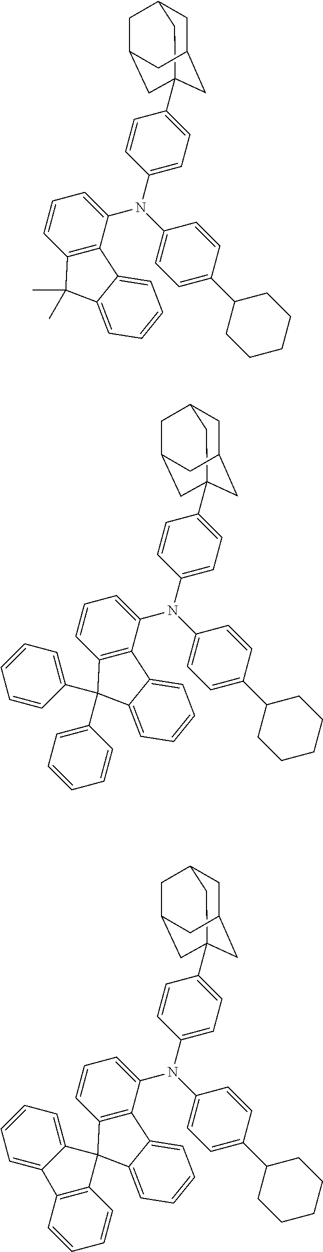 [SMILES: CC1(C)c2ccccc2-c2c(N(c3ccc(C4CCCCC4)cc3)c3ccc(C45CC6CC(CC(C6)C4)C5)cc3)cccc21 ; c1ccc(C2(c3ccccc3)c3ccccc3-c3c(N(c4ccc(C5CCCCC5)cc4)c4ccc(C56CC7CC(CC(C7)C5)C6)cc4)cccc32)cc1 ; c1ccc2c(c1)-c1ccccc1C21c2ccccc2-c2c(N(c3ccc(C4CCCCC4)cc3)c3ccc(C45CC6CC(CC(C6)C4)C5)cc3)cccc21]

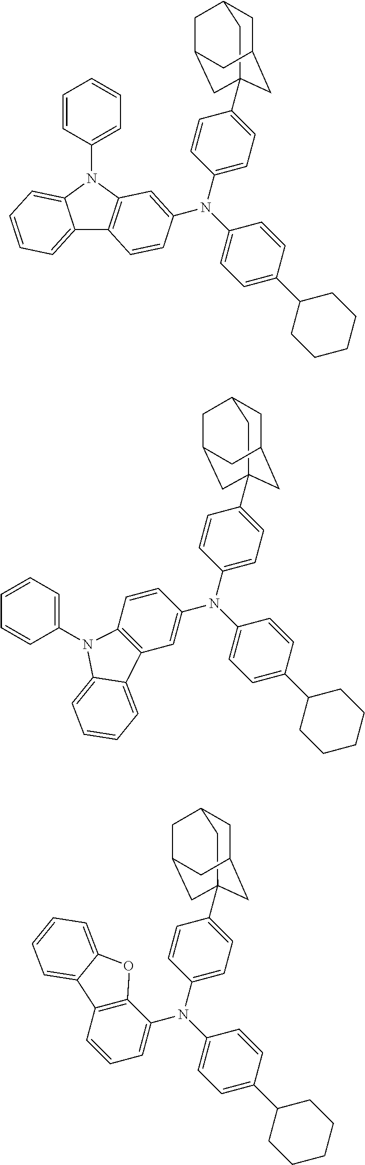 [SMILES: c1ccc(-n2c3ccccc3c3ccc(N(c4ccc(C5CCCCC5)cc4)c4ccc(C56CC7CC(CC(C7)C5)C6)cc4)cc32)cc1 ; c1ccc(-n2c3ccccc3c3cc(N(c4ccc(C5CCCCC5)cc4)c4ccc(C56CC7CC(CC(C7)C5)C6)cc4)ccc32)cc1 ; c1ccc2c(c1)oc1c(N(c3ccc(C4CCCCC4)cc3)c3ccc(C45CC6CC(CC(C6)C4)C5)cc3)cccc12]

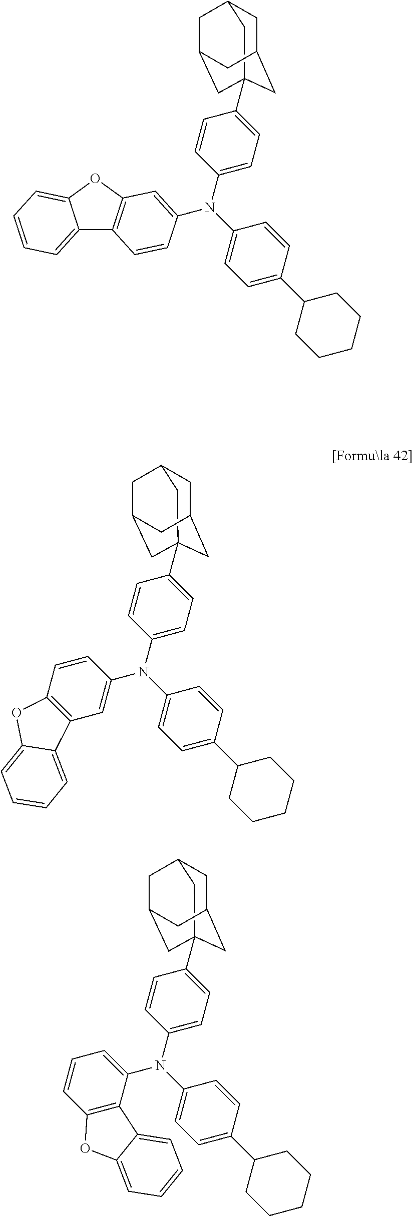 [SMILES: c1ccc2c(c1)oc1cc(N(c3ccc(C4CCCCC4)cc3)c3ccc(C45CC6CC(CC(C6)C4)C5)cc3)ccc12 ; c1ccc2c(c1)oc1ccc(N(c3ccc(C4CCCCC4)cc3)c3ccc(C45CC6CC(CC(C6)C4)C5)cc3)cc12 ; c1ccc2c(c1)oc1cccc(N(c3ccc(C4CCCCC4)cc3)c3ccc(C45CC6CC(CC(C6)C4)C5)cc3)c12]

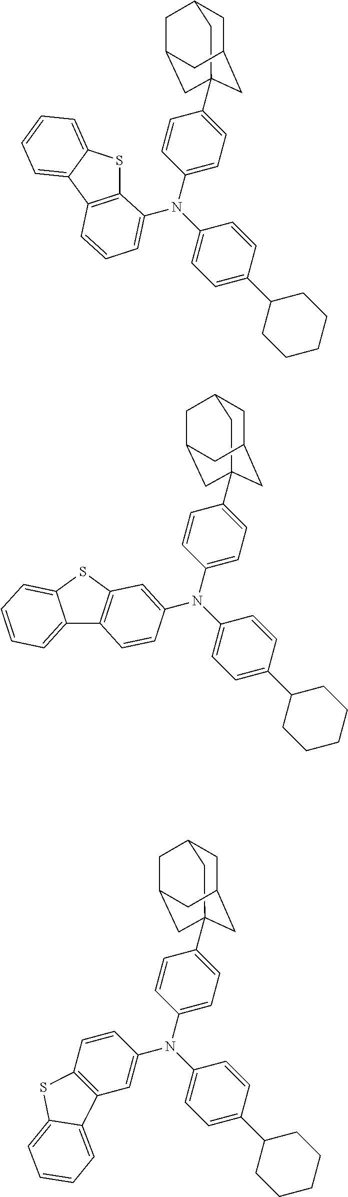 [SMILES: c1ccc2c(c1)sc1c(N(c3ccc(C4CCCCC4)cc3)c3ccc(C45CC6CC(CC(C6)C4)C5)cc3)cccc12 ; c1ccc2c(c1)sc1cc(N(c3ccc(C4CCCCC4)cc3)c3ccc(C45CC6CC(CC(C6)C4)C5)cc3)ccc12 ; c1ccc2c(c1)sc1ccc(N(c3ccc(C4CCCCC4)cc3)c3ccc(C45CC6CC(CC(C6)C4)C5)cc3)cc12]

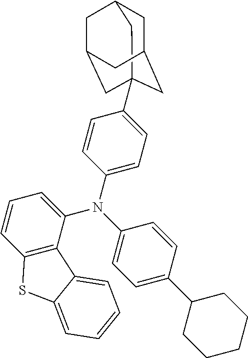 [SMILES: c1ccc2c(c1)sc1cccc(N(c3ccc(C4CCCCC4)cc3)c3ccc(C45CC6CC(CC(C6)C4)C5)cc3)c12]

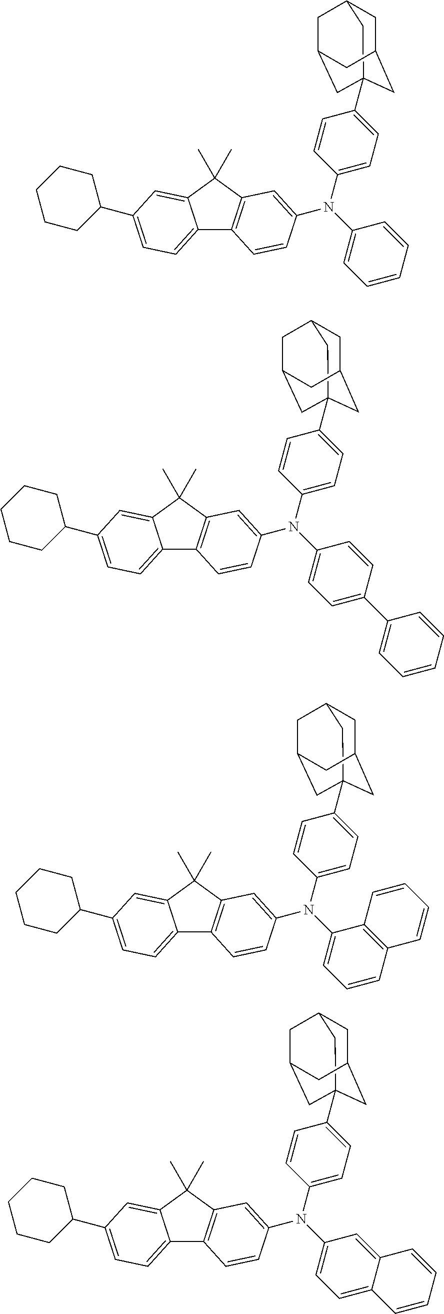

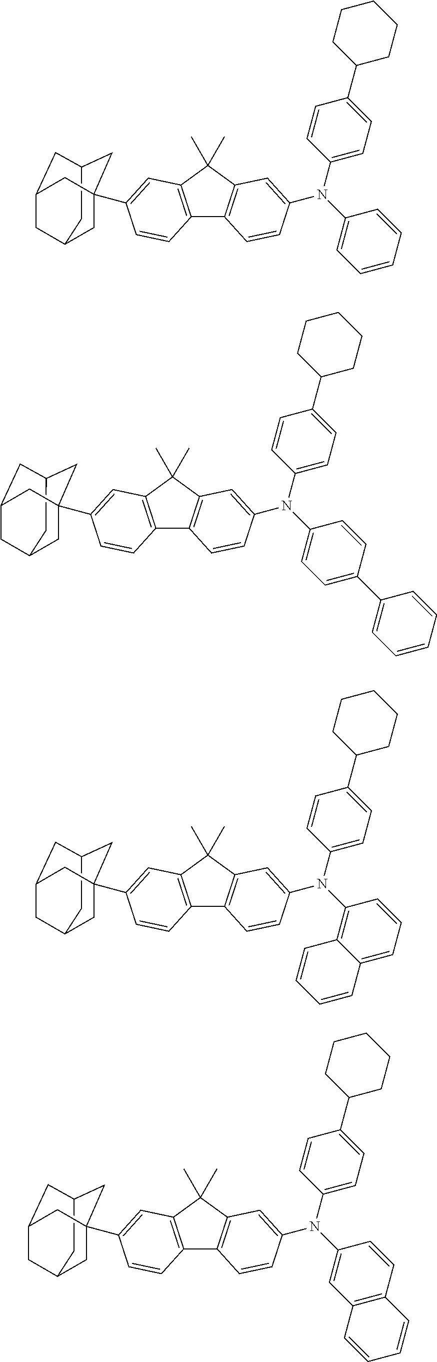

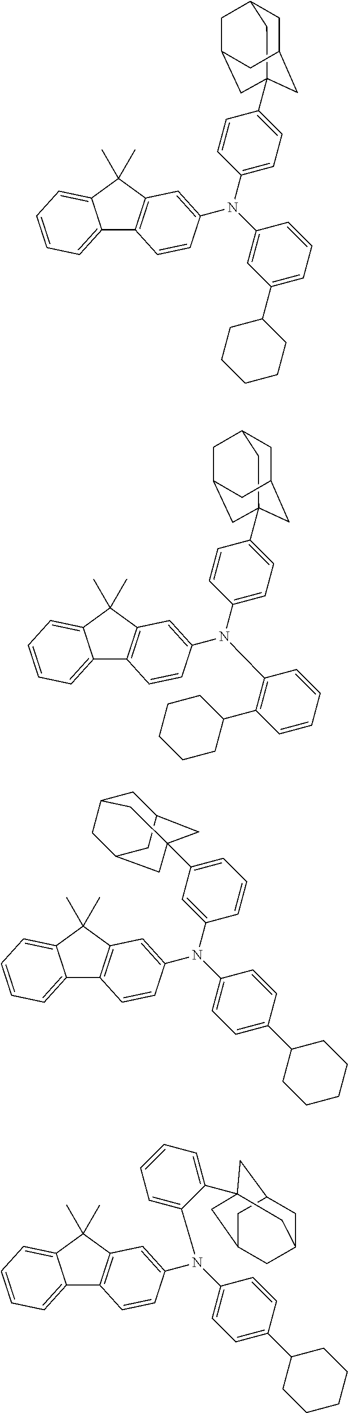 [SMILES: CC1(C)c2ccccc2-c2ccc(N(c3ccc(C45CC6CC(CC(C6)C4)C5)cc3)c3cccc(C4CCCCC4)c3)cc21 ; CC1(C)c2ccccc2-c2ccc(N(c3ccc(C45CC6CC(CC(C6)C4)C5)cc3)c3ccccc3C3CCCCC3)cc21 ; CC1(C)c2ccccc2-c2ccc(N(c3ccc(C4CCCCC4)cc3)c3cccc(C45CC6CC(CC(C6)C4)C5)c3)cc21 ; CC1(C)c2ccccc2-c2ccc(N(c3ccc(C4CCCCC4)cc3)c3ccccc3C34CC5CC(CC(C5)C3)C4)cc21]

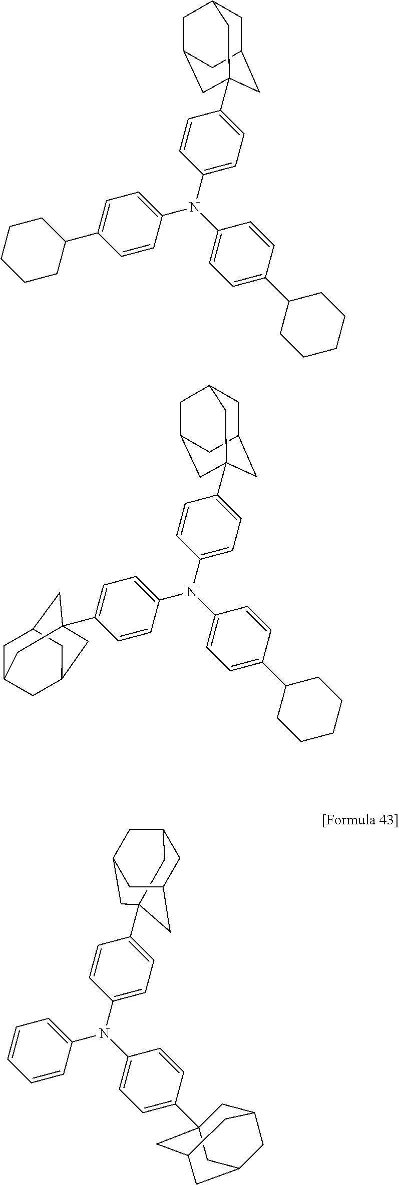 [SMILES: c1cc(N(c2ccc(C3CCCCC3)cc2)c2ccc(C34CC5CC(CC(C5)C3)C4)cc2)ccc1C1CCCCC1 ; c1cc(N(c2ccc(C34CC5CC(CC(C5)C3)C4)cc2)c2ccc(C34CC5CC(CC(C5)C3)C4)cc2)ccc1C1CCCCC1 ; c1ccc(N(c2ccc(C34CC5CC(CC(C5)C3)C4)cc2)c2ccc(C34CC5CC(CC(C5)C3)C4)cc2)cc1]

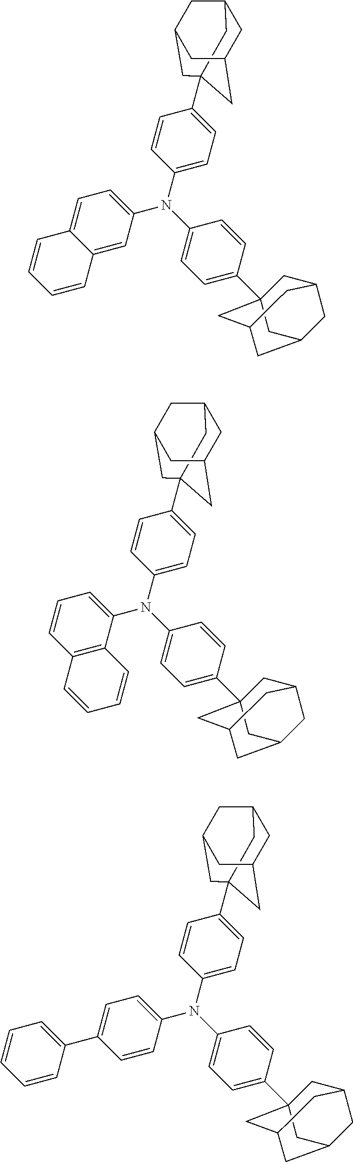 [SMILES: c1ccc2cc(N(c3ccc(C45CC6CC(CC(C6)C4)C5)cc3)c3ccc(C45CC6CC(CC(C6)C4)C5)cc3)ccc2c1 ; c1ccc2c(N(c3ccc(C45CC6CC(CC(C6)C4)C5)cc3)c3ccc(C45CC6CC(CC(C6)C4)C5)cc3)cccc2c1 ; c1ccc(-c2ccc(N(c3ccc(C45CC6CC(CC(C6)C4)C5)cc3)c3ccc(C45CC6CC(CC(C6)C4)C5)cc3)cc2)cc1]

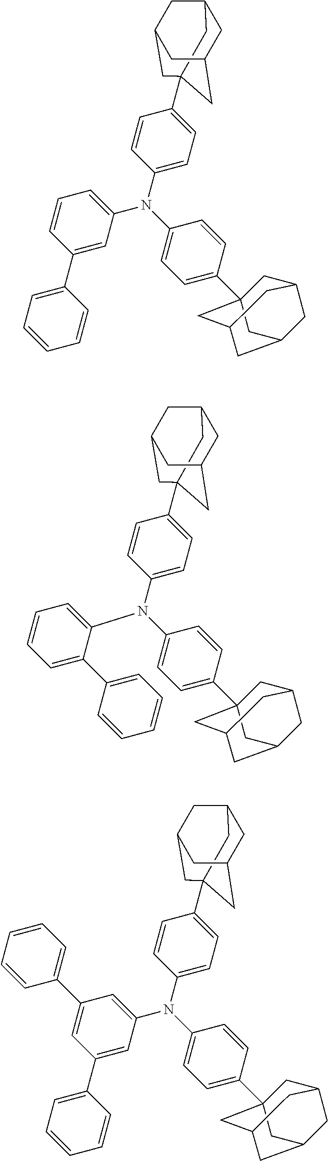

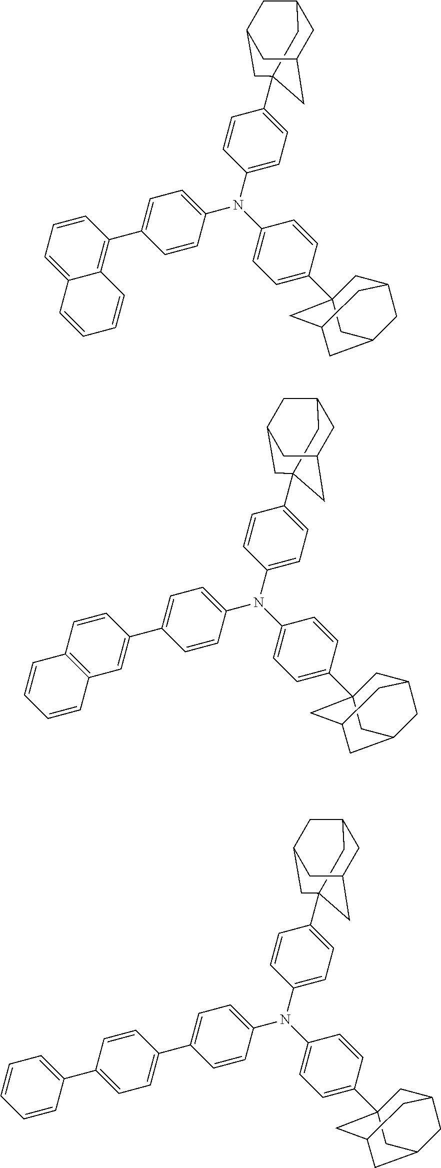

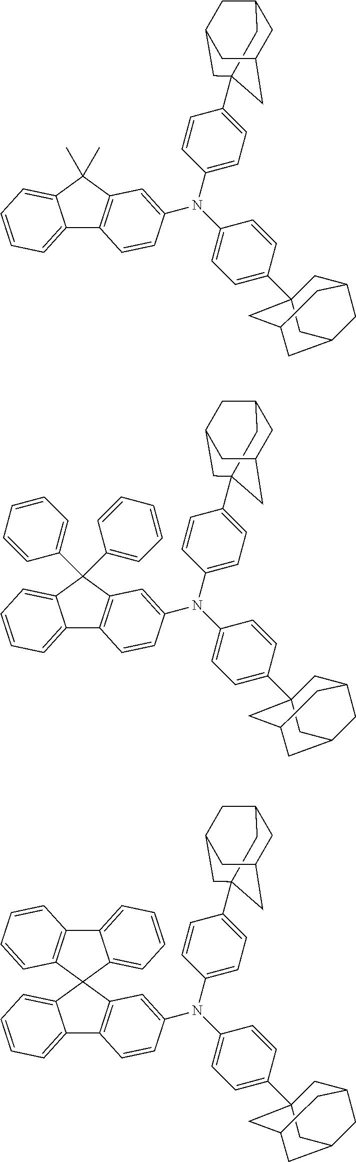 [SMILES: CC1(C)c2ccccc2-c2ccc(N(c3ccc(C45CC6CC(CC(C6)C4)C5)cc3)c3ccc(C45CC6CC(CC(C6)C4)C5)cc3)cc21 ; c1ccc(C2(c3ccccc3)c3ccccc3-c3ccc(N(c4ccc(C56CC7CC(CC(C7)C5)C6)cc4)c4ccc(C56CC7CC(CC(C7)C5)C6)cc4)cc32)cc1 ; c1ccc2c(c1)-c1ccccc1C21c2ccccc2-c2ccc(N(c3ccc(C45CC6CC(CC(C6)C4)C5)cc3)c3ccc(C45CC6CC(CC(C6)C4)C5)cc3)cc21]

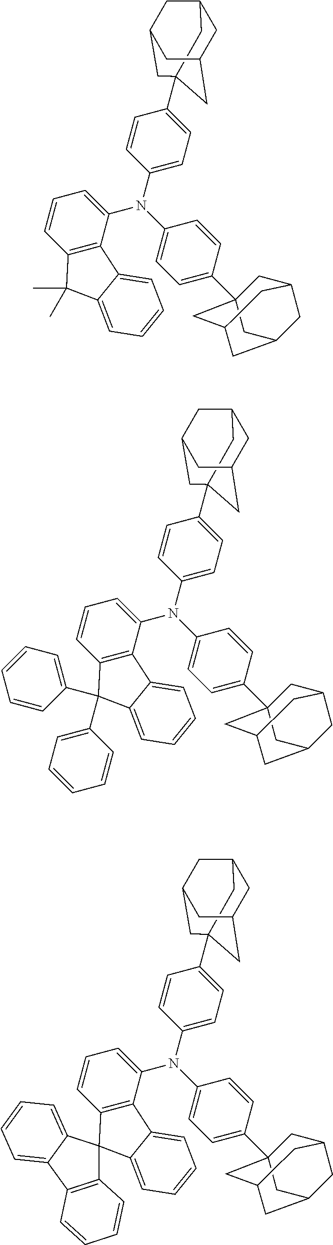 [SMILES: CC1(C)c2ccccc2-c2c(N(c3ccc(C45CC6CC(CC(C6)C4)C5)cc3)c3ccc(C45CC6CC(CC(C6)C4)C5)cc3)cccc21 ; c1ccc(C2(c3ccccc3)c3ccccc3-c3c(N(c4ccc(C56CC7CC(CC(C7)C5)C6)cc4)c4ccc(C56CC7CC(CC(C7)C5)C6)cc4)cccc32)cc1 ; c1ccc2c(c1)-c1ccccc1C21c2ccccc2-c2c(N(c3ccc(C45CC6CC(CC(C6)C4)C5)cc3)c3ccc(C45CC6CC(CC(C6)C4)C5)cc3)cccc21]

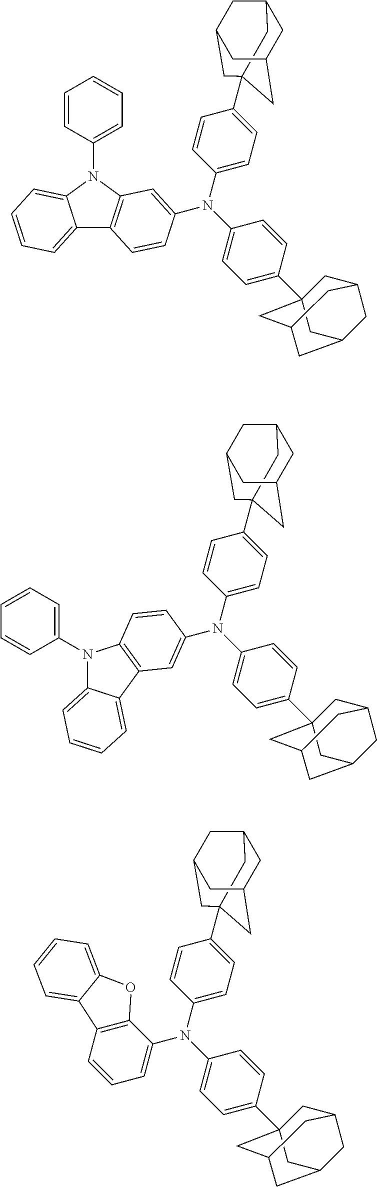 [SMILES: c1ccc(-n2c3ccccc3c3ccc(N(c4ccc(C56CC7CC(CC(C7)C5)C6)cc4)c4ccc(C56CC7CC(CC(C7)C5)C6)cc4)cc32)cc1 ; c1ccc(-n2c3ccccc3c3cc(N(c4ccc(C56CC7CC(CC(C7)C5)C6)cc4)c4ccc(C56CC7CC(CC(C7)C5)C6)cc4)ccc32)cc1 ; c1ccc2c(c1)oc1c(N(c3ccc(C45CC6CC(CC(C6)C4)C5)cc3)c3ccc(C45CC6CC(CC(C6)C4)C5)cc3)cccc12]

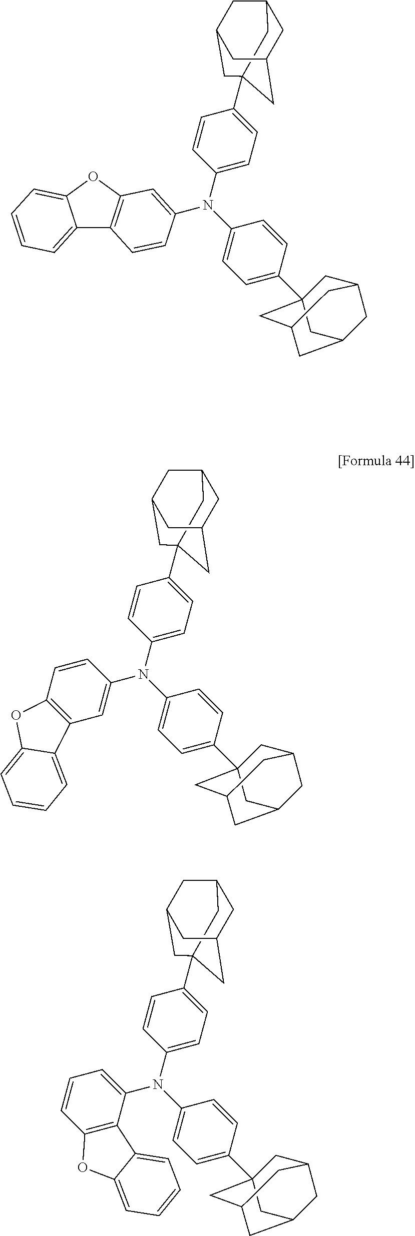 [SMILES: c1ccc2c(c1)oc1cc(N(c3ccc(C45CC6CC(CC(C6)C4)C5)cc3)c3ccc(C45CC6CC(CC(C6)C4)C5)cc3)ccc12 ; c1ccc2c(c1)oc1ccc(N(c3ccc(C45CC6CC(CC(C6)C4)C5)cc3)c3ccc(C45CC6CC(CC(C6)C4)C5)cc3)cc12 ; c1ccc2c(c1)oc1cccc(N(c3ccc(C45CC6CC(CC(C6)C4)C5)cc3)c3ccc(C45CC6CC(CC(C6)C4)C5)cc3)c12]

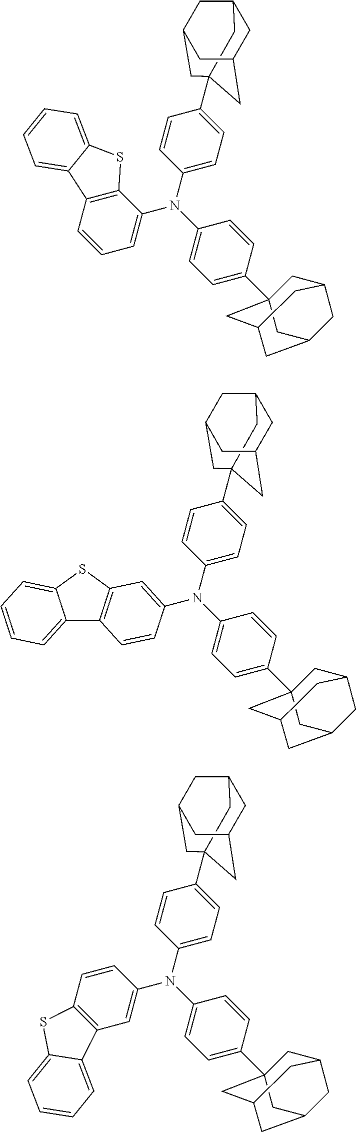

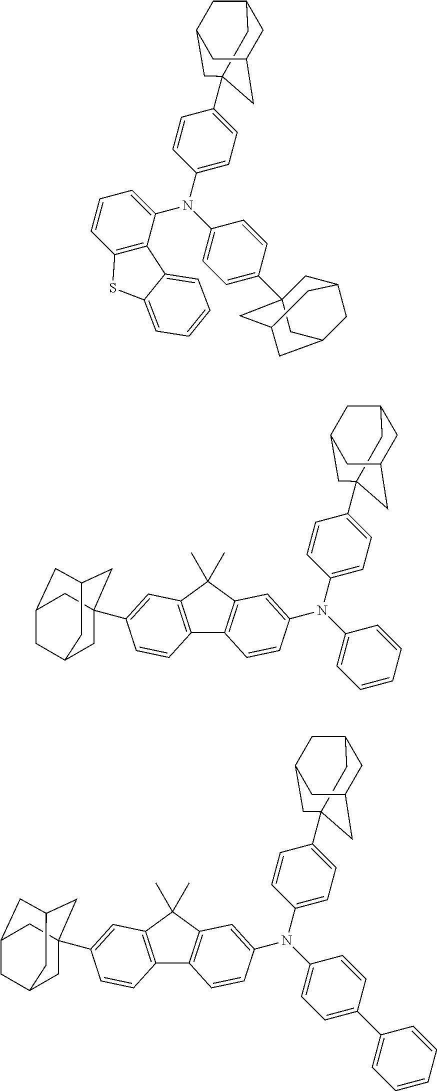 [SMILES: c1ccc2c(c1)sc1cccc(N(c3ccc(C45CC6CC(CC(C6)C4)C5)cc3)c3ccc(C45CC6CC(CC(C6)C4)C5)cc3)c12 ; CC1(C)c2cc(N(c3ccccc3)c3ccc(C45CC6CC(CC(C6)C4)C5)cc3)ccc2-c2ccc(C34CC5CC(CC(C5)C3)C4)cc21 ; CC1(C)c2cc(N(c3ccc(-c4ccccc4)cc3)c3ccc(C45CC6CC(CC(C6)C4)C5)cc3)ccc2-c2ccc(C34CC5CC(CC(C5)C3)C4)cc21]

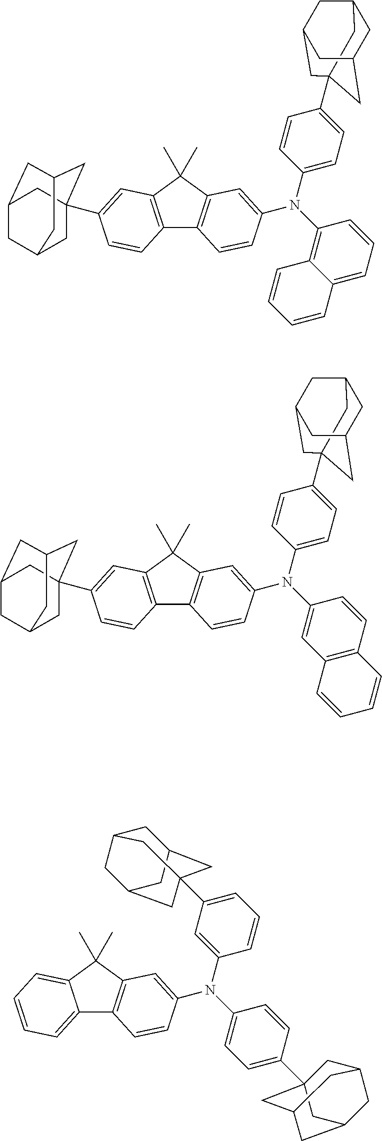 [SMILES: CC1(C)c2cc(N(c3ccc(C45CC6CC(CC(C6)C4)C5)cc3)c3cccc4ccccc34)ccc2-c2ccc(C34CC5CC(CC(C5)C3)C4)cc21 ; CC1(C)c2cc(N(c3ccc(C45CC6CC(CC(C6)C4)C5)cc3)c3ccc4ccccc4c3)ccc2-c2ccc(C34CC5CC(CC(C5)C3)C4)cc21 ; CC1(C)c2ccccc2-c2ccc(N(c3ccc(C45CC6CC(CC(C6)C4)C5)cc3)c3cccc(C45CC6CC(CC(C6)C4)C5)c3)cc21]

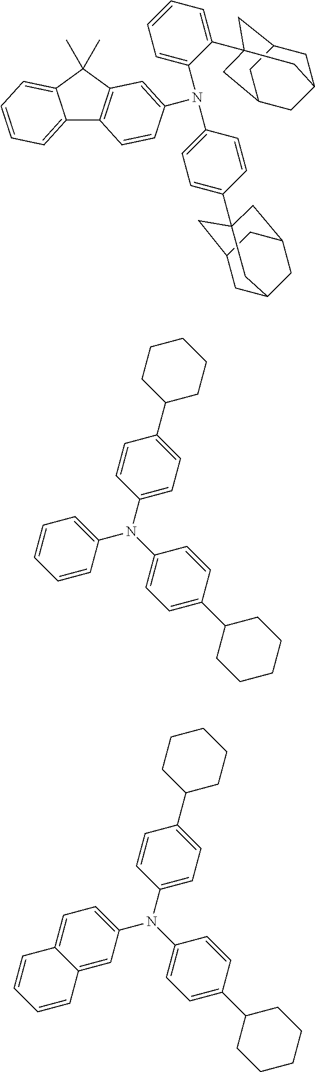 [SMILES: CC1(C)c2ccccc2-c2ccc(N(c3ccc(C45CC6CC(CC(C6)C4)C5)cc3)c3ccccc3C34CC5CC(CC(C5)C3)C4)cc21 ; c1ccc(N(c2ccc(C3CCCCC3)cc2)c2ccc(C3CCCCC3)cc2)cc1 ; c1ccc2cc(N(c3ccc(C4CCCCC4)cc3)c3ccc(C4CCCCC4)cc3)ccc2c1]

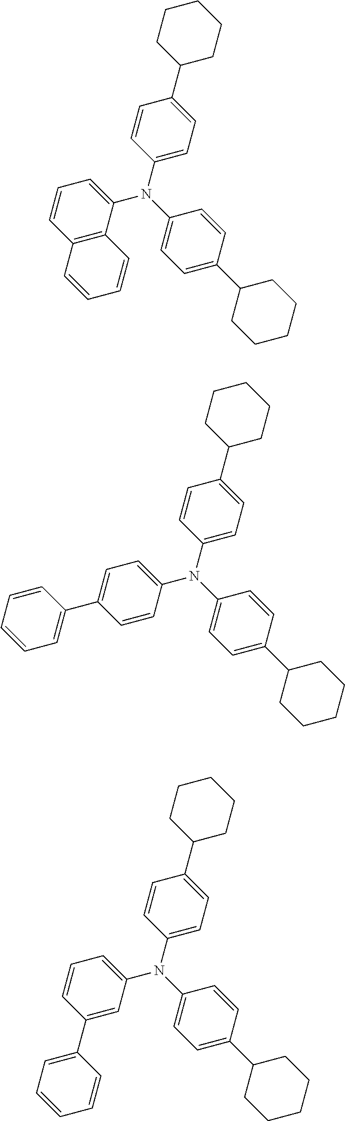

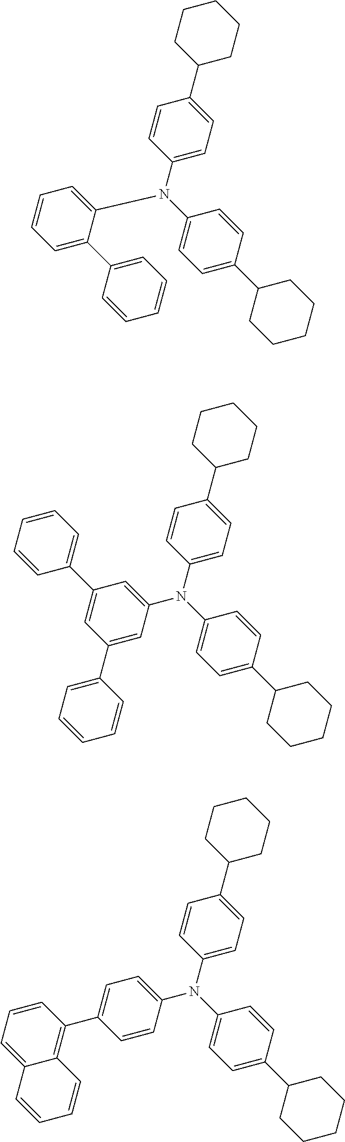 [SMILES: c1ccc(-c2ccccc2N(c2ccc(C3CCCCC3)cc2)c2ccc(C3CCCCC3)cc2)cc1 ; c1ccc(-c2cc(-c3ccccc3)cc(N(c3ccc(C4CCCCC4)cc3)c3ccc(C4CCCCC4)cc3)c2)cc1 ; c1ccc2c(-c3ccc(N(c4ccc(C5CCCCC5)cc4)c4ccc(C5CCCCC5)cc4)cc3)cccc2c1]

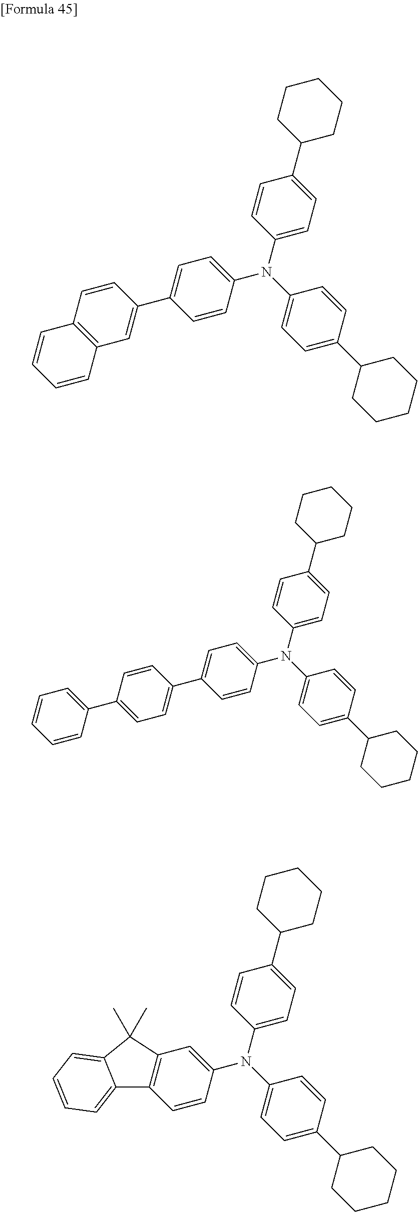 [SMILES: c1ccc2cc(-c3ccc(N(c4ccc(C5CCCCC5)cc4)c4ccc(C5CCCCC5)cc4)cc3)ccc2c1 ; c1ccc(-c2ccc(-c3ccc(N(c4ccc(C5CCCCC5)cc4)c4ccc(C5CCCCC5)cc4)cc3)cc2)cc1 ; CC1(C)c2ccccc2-c2ccc(N(c3ccc(C4CCCCC4)cc3)c3ccc(C4CCCCC4)cc3)cc21]

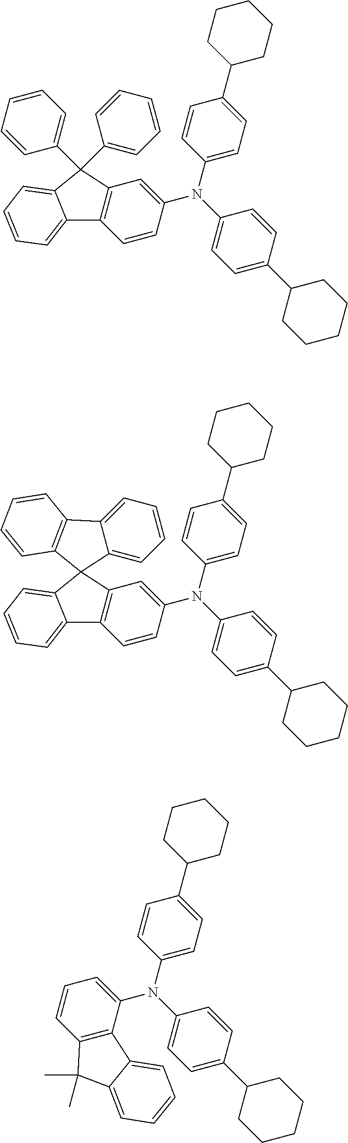 [SMILES: c1ccc(C2(c3ccccc3)c3ccccc3-c3ccc(N(c4ccc(C5CCCCC5)cc4)c4ccc(C5CCCCC5)cc4)cc32)cc1 ; c1ccc2c(c1)-c1ccccc1C21c2ccccc2-c2ccc(N(c3ccc(C4CCCCC4)cc3)c3ccc(C4CCCCC4)cc3)cc21 ; CC1(C)c2ccccc2-c2c(N(c3ccc(C4CCCCC4)cc3)c3ccc(C4CCCCC4)cc3)cccc21]

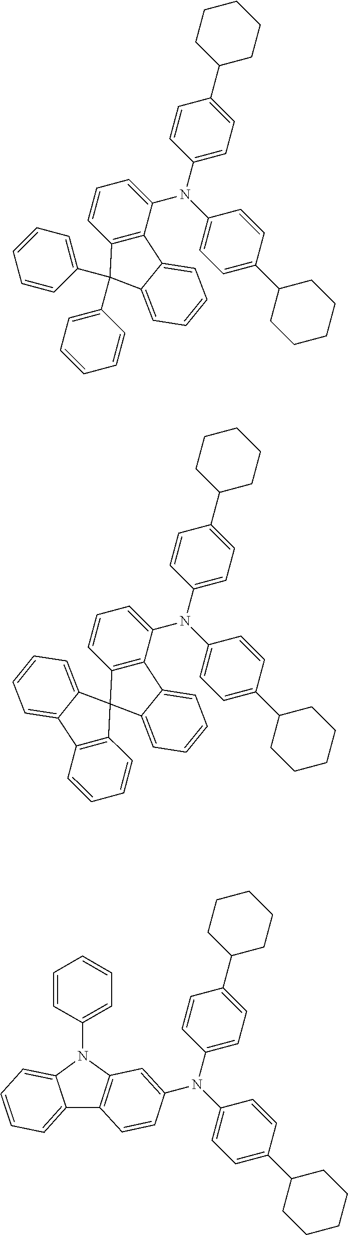 [SMILES: c1ccc(C2(c3ccccc3)c3ccccc3-c3c(N(c4ccc(C5CCCCC5)cc4)c4ccc(C5CCCCC5)cc4)cccc32)cc1 ; c1ccc2c(c1)-c1ccccc1C21c2ccccc2-c2c(N(c3ccc(C4CCCCC4)cc3)c3ccc(C4CCCCC4)cc3)cccc21 ; c1ccc(-n2c3ccccc3c3ccc(N(c4ccc(C5CCCCC5)cc4)c4ccc(C5CCCCC5)cc4)cc32)cc1]

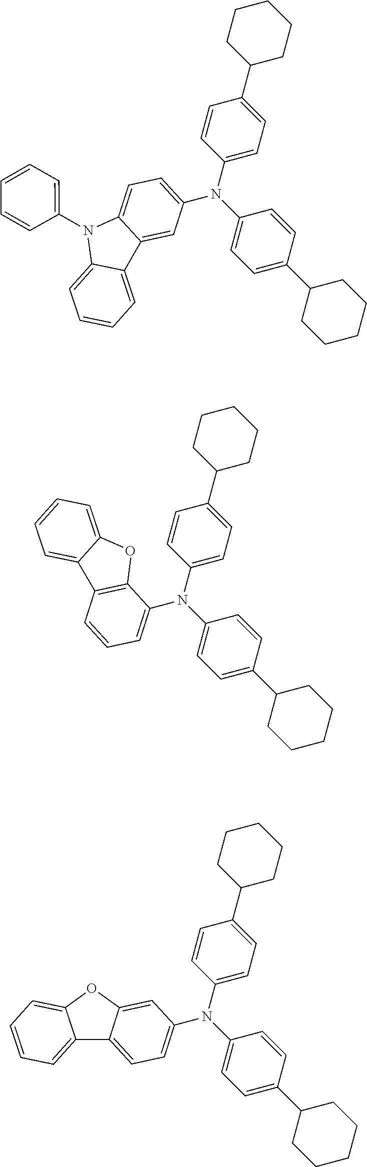 [SMILES: c1ccc(-n2c3ccccc3c3cc(N(c4ccc(C5CCCCC5)cc4)c4ccc(C5CCCCC5)cc4)ccc32)cc1 ; c1ccc2c(c1)oc1c(N(c3ccc(C4CCCCC4)cc3)c3ccc(C4CCCCC4)cc3)cccc12 ; c1ccc2c(c1)oc1cc(N(c3ccc(C4CCCCC4)cc3)c3ccc(C4CCCCC4)cc3)ccc12]

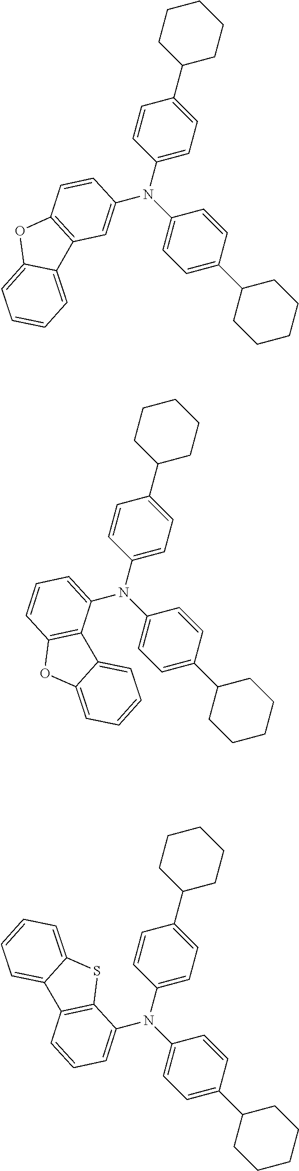 [SMILES: c1ccc2c(c1)oc1ccc(N(c3ccc(C4CCCCC4)cc3)c3ccc(C4CCCCC4)cc3)cc12 ; c1ccc2c(c1)oc1cccc(N(c3ccc(C4CCCCC4)cc3)c3ccc(C4CCCCC4)cc3)c12 ; c1ccc2c(c1)sc1c(N(c3ccc(C4CCCCC4)cc3)c3ccc(C4CCCCC4)cc3)cccc12]

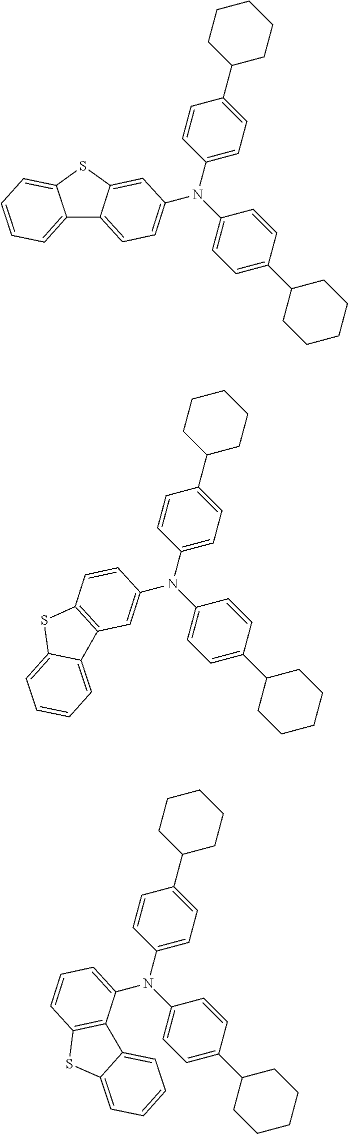 [SMILES: c1ccc2c(c1)sc1cc(N(c3ccc(C4CCCCC4)cc3)c3ccc(C4CCCCC4)cc3)ccc12 ; c1ccc2c(c1)sc1ccc(N(c3ccc(C4CCCCC4)cc3)c3ccc(C4CCCCC4)cc3)cc12 ; c1ccc2c(c1)sc1cccc(N(c3ccc(C4CCCCC4)cc3)c3ccc(C4CCCCC4)cc3)c12]

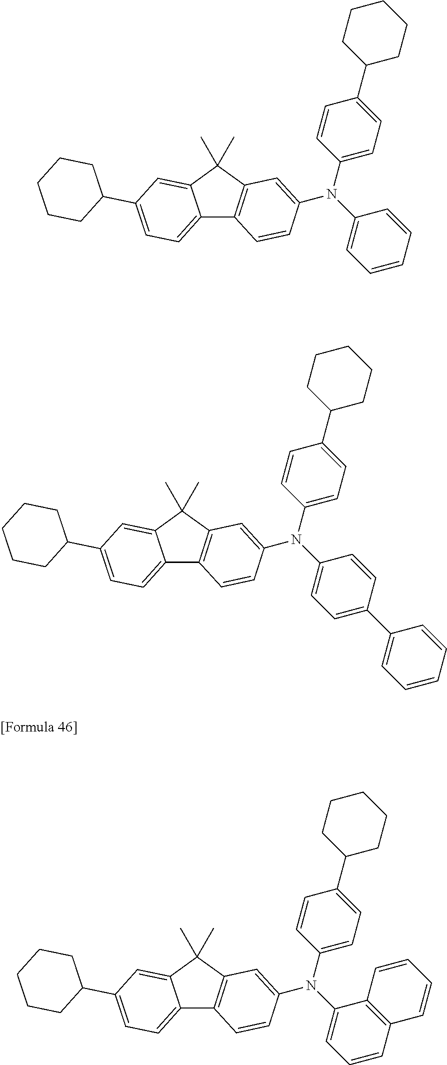 [SMILES: CC1(C)c2cc(C3CCCCC3)ccc2-c2ccc(N(c3ccccc3)c3ccc(C4CCCCC4)cc3)cc21 ; CC1(C)c2cc(C3CCCCC3)ccc2-c2ccc(N(c3ccc(-c4ccccc4)cc3)c3ccc(C4CCCCC4)cc3)cc21 ; CC1(C)c2cc(C3CCCCC3)ccc2-c2ccc(N(c3ccc(C4CCCCC4)cc3)c3cccc4ccccc34)cc21]

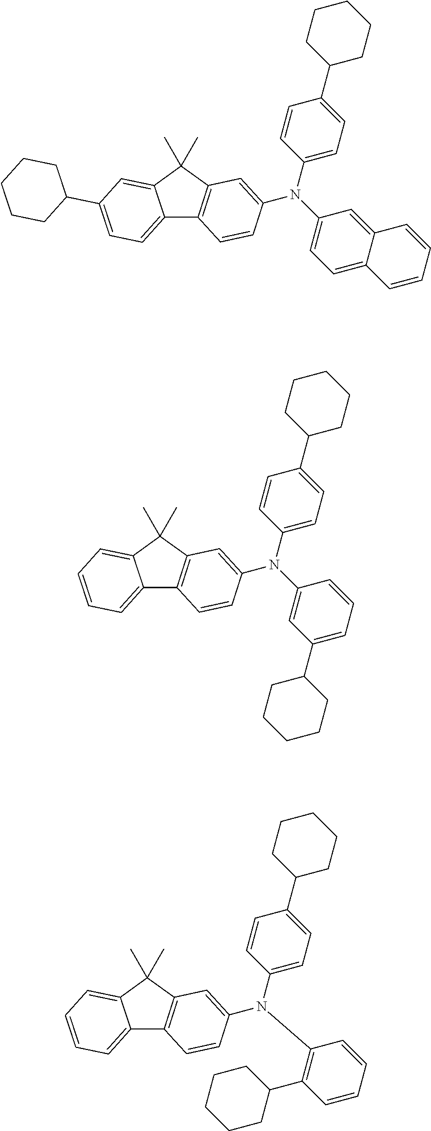 [SMILES: CC1(C)c2cc(C3CCCCC3)ccc2-c2ccc(N(c3ccc(C4CCCCC4)cc3)c3ccc4ccccc4c3)cc21 ; CC1(C)c2ccccc2-c2ccc(N(c3ccc(C4CCCCC4)cc3)c3cccc(C4CCCCC4)c3)cc21 ; CC1(C)c2ccccc2-c2ccc(N(c3ccc(C4CCCCC4)cc3)c3ccccc3C3CCCCC3)cc21]

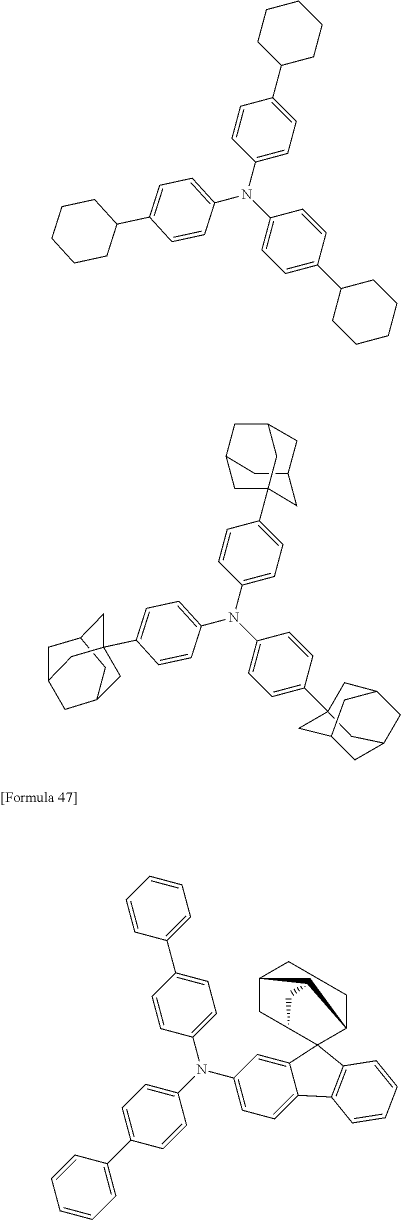 [SMILES: c1cc(N(c2ccc(C3CCCCC3)cc2)c2ccc(C3CCCCC3)cc2)ccc1C1CCCCC1 ; c1cc(C23CC4CC(CC(C4)C2)C3)ccc1N(c1ccc(C23CC4CC(CC(C4)C2)C3)cc1)c1ccc(C23CC4CC(CC(C4)C2)C3)cc1 ; c1ccc(-c2ccc(N(c3ccc(-c4ccccc4)cc3)c3ccc4c(c3)C3(c5ccccc5-4)[C@H]4C[C@@H]5C[C@@H](C[C@H]3C5)C4)cc2)cc1]

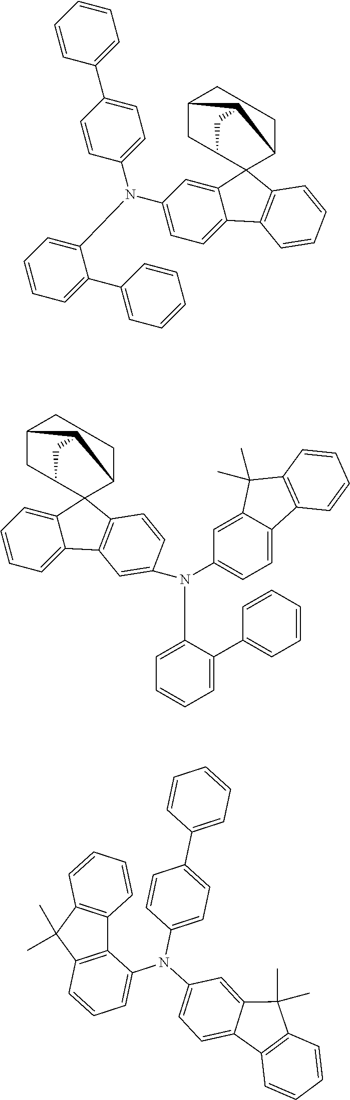 [SMILES: c1ccc(-c2ccc(N(c3ccc4c(c3)C3(c5ccccc5-4)[C@H]4C[C@@H]5C[C@@H](C[C@H]3C5)C4)c3ccccc3-c3ccccc3)cc2)cc1 ; CC1(C)c2ccccc2-c2ccc(N(c3ccc4c(c3)-c3ccccc3C43[C@H]4C[C@@H]5C[C@@H](C[C@H]3C5)C4)c3ccccc3-c3ccccc3)cc21 ; CC1(C)c2ccccc2-c2ccc(N(c3ccc(-c4ccccc4)cc3)c3cccc4c3-c3ccccc3C4(C)C)cc21]

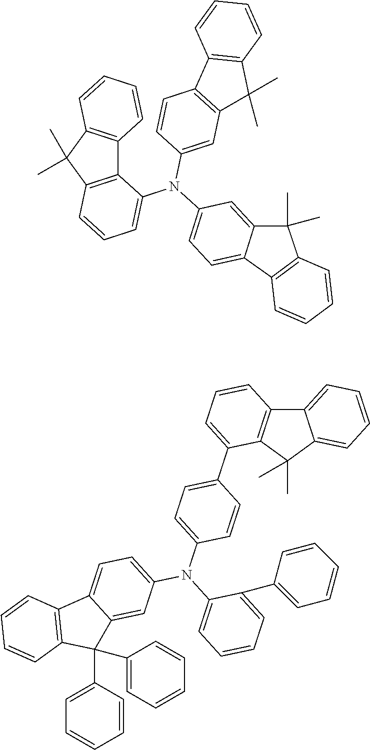 [SMILES: CC1(C)c2ccccc2-c2ccc(N(c3ccc4c(c3)C(C)(C)c3ccccc3-4)c3cccc4c3-c3ccccc3C4(C)C)cc21 ; CC1(C)c2ccccc2-c2cccc(-c3ccc(N(c4ccc5c(c4)C(c4ccccc4)(c4ccccc4)c4ccccc4-5)c4ccccc4-c4ccccc4)cc3)c21]

### Second Exemplary Embodiment

### Organic Electroluminescence Device

An organic electroluminescence device according to the exemplary embodiment includes an anode, a cathode, and an organic layer disposed between the anode and the cathode, in which at least one layer included in the organic layer contains the composition according to the first exemplary embodiment. Specifically, in the organic EL device according to the exemplary embodiment, at least one layer included in the organic layer contains the first compound and the second compound according to the first exemplary embodiment. Also in this exemplary embodiment, the first compound and the second compound are mutually different compounds and the first compound and the second compound are each independently an amine compound having a refractive index of 1.80 or less.

In an exemplary arrangement of the organic EL device of the exemplary embodiment, the composition according to the first exemplary embodiment exists in a form of a film or a layer in the organic layer.

The organic layer of the organic EL device according to the exemplary embodiment preferably includes a plurality of layers, among which at least one layer preferably contains the composition according to the first exemplary embodiment.

In an exemplary arrangement of the organic EL device according to the exemplary embodiment, the first and second compounds are contained in the same layer.

In an exemplary arrangement of the organic EL device according to the exemplary embodiment, the organic layer includes an emitting zone and a hole transporting zone, in which the emitting zone includes at least one emitting layer, the hole transporting zone is disposed between the anode and the emitting zone, and at least one layer included in the hole transporting zone contains the first compound and the second compound.

### Hole Transporting Zone

A region including one or more layers provided between the anode and the emitting zone herein is referred to as the hole transporting zone.

In an exemplary arrangement of the organic EL device according to the exemplary embodiment, the hole transporting zone includes a hole injecting layer and a hole transporting layer.

### Hole Transporting Layer

In an exemplary arrangement of the organic EL device according to the exemplary embodiment, the hole transporting layer contains the first compound and the second compound.

In an exemplary arrangement of the organic EL device according to the exemplary embodiment, a refractive index of the hole injecting layer is larger than a refractive index of the hole transporting layer.

In an exemplary arrangement of the organic EL device according to the exemplary embodiment, the hole transporting layer includes a first hole transporting layer and the first hole transporting layer is disposed between the hole injecting layer and the emitting zone.

In an exemplary arrangement of the organic EL device according to the exemplary embodiment, the first hole transporting layer contains the first compound and the second compound. In this exemplary arrangement, a refractive index of the hole injecting layer n_{HA} is preferably larger than a refractive index of the first hole transporting layer n_{HT1.}

In an exemplary arrangement of the organic EL device according to the exemplary embodiment, the hole transporting layer consists of the first hole transporting layer and the second hole transporting layer, and the second hole transporting layer is disposed between the first hole transporting layer and the emitting zone. In an exemplary arrangement of the organic EL device according to the exemplary embodiment, the first hole transporting layer and the second hole transporting layer are in direct contact with each other.

In an exemplary arrangement of the organic EL device according to the exemplary embodiment, the refractive index of the first hole transporting layer n_{HT1} is larger than a refractive index of the second hole transporting layer n_{HT2.}

In a case where a layer contains a plurality of compounds, a refractive index of the layer corresponds to a refractive index of a mixture (composition) containing the plurality of compounds.

In an exemplary arrangement of the organic EL device of the exemplary embodiment, a film thickness of the second hole transporting layer is 20 nm or more.

In an exemplary arrangement of the organic EL device of the exemplary embodiment, a film thickness of the second hole transporting layer is 25 nm or more, 30 nm or more, or 35 nm or more.

In an exemplary arrangement of the organic EL device of the exemplary embodiment, a film thickness of a layer containing the first compound and the second compound is 20 nm or more, 25 nm or more, 30 nm or more, or 35 nm or more.

In an exemplary arrangement of the organic EL device of the exemplary embodiment, a film thickness of the layer containing the first and second compounds is 160 nm or less or 130 nm or less.

In an exemplary arrangement of the organic EL device according to the exemplary embodiment, the second hole transporting layer contains the first compound and the second compound.

In an exemplary arrangement of the organic EL device according to the exemplary embodiment, the second hole transporting layer contains the first compound and the second compound and the first hole transporting layer does not contain the first compound and the second compound. In this exemplary arrangement, the refractive index of the first hole transporting layer n_{HT1} is preferably larger than the refractive index of the second hole transporting layer n_{HT2.}

In an exemplary arrangement of the organic EL device according to the exemplary embodiment, the first hole transporting layer contains the first compound and the second compound and the second hole transporting layer does not contain the first compound and the second compound. In this exemplary arrangement, the refractive index of the hole injecting layer n_{HA} and the refractive index of the second hole transporting layer n_{HT2} are preferably larger than the refractive index of the first hole transporting layer n_{HT1.}

In an exemplary arrangement of the organic EL device according to the exemplary embodiment, the hole transporting layer further includes a third hole transporting layer, in which the third hole transporting layer is disposed between the hole injecting layer and the first hole transporting layer, and the hole injecting layer, the third hole transporting layer, the first hole transporting layer, and the second hole transporting layer are disposed in this order from a side close to the anode. In an exemplary arrangement of the organic EL device according to the exemplary embodiment, the first hole transporting layer and the third hole transporting layer are in direct contact with each other.

In an exemplary arrangement of the organic EL device according to the exemplary embodiment, the refractive index of the first hole transporting layer n_{HT1} is preferably larger than a refractive index of the third hole transporting layer n_{HT3.}

In an exemplary arrangement of the organic EL device according to the exemplary embodiment, it is preferable that the refractive index of the first hole transporting layer n_{HT1} is larger than the refractive index of the second hole transporting layer n_{HT2} and larger than the refractive index of the third hole transporting layer n_{HT3.}

In an exemplary arrangement of the organic EL device of the exemplary embodiment, a ratio between a total film thickness of the hole injecting layer and the third hole transporting layer and the film thickness of the second hole transporting layer is in a range from 1:1.5 to 1.5:1.

In an exemplary arrangement of the organic EL device of the exemplary embodiment, a ratio between the total film thickness of the hole injecting layer and the third hole transporting layer, a film thickness of the first hole transporting layer, and the film thickness of the second hole transporting layer is in a range from 1:1.5:1 to 1:2.5:1.

In an exemplary arrangement of the organic EL device according to the exemplary embodiment, the hole transporting layer further includes a fourth hole transporting layer, in which the fourth hole transporting layer is disposed between the second hole transporting layer and the emitting zone, and the first hole transporting layer, the second hole transporting layer, and the fourth hole transporting layer are disposed in this order from a side close to the anode. In an exemplary arrangement of the organic EL device according to the exemplary embodiment, the second hole transporting layer and the fourth hole transporting layer are in direct contact with each other. In an exemplary arrangement of the organic EL device according to the exemplary embodiment, the fourth hole transporting layer and the emitting zone are in direct contact with each other.

In an exemplary arrangement of the organic EL device according to the exemplary embodiment, in a case where the hole transporting layer includes the first, second, third, and fourth hole transporting layers, the hole injecting layer, the third hole transporting layer, the first hole transporting layer, the second hole transporting layer, and the fourth hole transporting layer are disposed in this order from a side close to the anode.

In an exemplary arrangement of the organic EL device according to the exemplary embodiment, the first, second, third, and fourth hole transporting layers are each a single layer.

In an exemplary arrangement of the organic EL device according to the exemplary embodiment, a refractive index of the fourth hole transporting layer n_{HT4} is larger than the refractive index of the first hole transporting layer n_{HT1} and the refractive index of the second hole transporting layer n_{HT2.}

In an exemplary arrangement of the organic EL device of the exemplary embodiment, the fourth hole transporting layer is an electron blocking layer. The electron blocking layer is preferably a layer that transports holes and blocks electrons from reaching a layer close to the anode (e.g., hole transporting layer) beyond the electron blocking layer. In an exemplary arrangement of the organic EL device of the exemplary embodiment, the fourth hole transporting layer may block excitons generated in the emitting layer from being transferred to a layer(s) (e.g., the hole transporting layer and the hole injecting layer) close to the anode beyond the fourth hole transporting layer in order that excited energy does not leak from the emitting layer to the neighboring layers.

In an exemplary arrangement of the organic EL device according to the exemplary embodiment, the hole transporting zone includes a first mixture layer between the first hole transporting layer and the second hole transporting layer. The first mixture layer contains a first hole transporting zone material and a second hole transporting zone material described later.

In an exemplary arrangement of the organic EL device of the exemplary embodiment, a film thickness of the first mixture layer may be 10 nm or more. In an exemplary arrangement of the organic EL device of the exemplary embodiment, the film thickness of the first mixture layer is 50 nm or less. In an exemplary arrangement of the organic EL device according to the exemplary embodiment, the film thickness of the first mixture layer is thinner than the film thickness of the first hole transporting layer and thinner than the film thickness of the second hole transporting layer.

In an exemplary arrangement of the organic EL device according to the exemplary embodiment, when the first hole transporting layer and the second hole transporting layer are continuously formed in the same film-forming chamber, the first mixture layer may be formed between the first hole transporting layer and the second hole transporting layer.

In an exemplary arrangement of the organic EL device according to the exemplary embodiment, the hole transporting zone includes a second mixture layer between the first hole transporting layer and the third hole transporting layer. The second mixture layer contains the first hole transporting zone material and a third hole transporting zone material described later.

In an exemplary arrangement of the organic EL device of the exemplary embodiment, a film thickness of the second mixture layer may be 10 nm or more. In an exemplary arrangement of the organic EL device of the exemplary embodiment, the film thickness of the second mixture layer is 50 nm or less. In an exemplary arrangement of the organic EL device according to the exemplary embodiment, the refractive index of the second mixture layer is thinner than the film thickness of the first hole transporting layer and thinner than the film thickness of the third hole transporting layer.

In an exemplary arrangement of the organic EL device according to the exemplary embodiment, when the first hole transporting layer and the third hole transporting layer are continuously formed in the same film-forming chamber, the second mixture layer may be formed between the first hole transporting layer and the third hole transporting layer.

### Hole Transporting Zone Material

In an exemplary arrangement of the organic EL device according to the exemplary embodiment, the first hole transporting layer contains the first hole transporting zone material, the second hole transporting layer contains the second hole transporting zone material, the third hole transporting layer contains the third hole transporting zone material, and the fourth hole transporting layer contains a fourth hole transporting zone material.

The first hole transporting zone material is a constituent material contained in the first hole transporting layer and may be formed using a single compound or two or more compounds.

The second hole transporting zone material is a constituent material contained in the second hole transporting layer and may be formed using a single compound or two or more compounds.

The third hole transporting zone material is a constituent material contained in the third hole transporting layer and may be formed using a single compound or two or more compounds.

The fourth hole transporting zone material is a constituent material contained in the fourth hole transporting layer and may be formed using a single compound or two or more compounds.

In an exemplary arrangement of the organic EL device according to the exemplary embodiment, the second hole transporting layer and the third hole transporting layer preferably contain at least one same compound. An arrangement satisfying the above condition is, for instance, as follows: when a compound AA and a compound AB are different compounds, the second hole transporting layer contains a composition including two types of compounds that are the compound AA and the compound AB and the third hole transporting layer contains a single type of compound that is the compound AA. Regarding the compound AA in this arrangement, since the second hole transporting layer and the third hole transporting layer contain the same material, the above condition is satisfied. The above condition is also satisfied when both of the second hole transporting layer and the third hole transporting layer contain only the compound AA. Further, the above condition is also satisfied when the second hole transporting layer contains a composition including two types of compounds that are the compound AA and the compound AB and the third hole transporting layer contains the composition including the two types of compounds that are the compound AA and the compound AB.

In an exemplary arrangement of the organic EL device according to the exemplary embodiment, the second hole transporting zone material and the third hole transporting layer material are preferably the same.

In an exemplary arrangement of the organic EL device of according to exemplary embodiment, all the compounds contained in the second hole transporting layer and the third hole transporting layer are different from the compound(s) contained in the first hole transporting layer.

An arrangement satisfying the above condition is, for instance, as follows: when a compound CA, a compound CB, the compound AA and the compound AB are mutually different compounds, the first hole transporting layer contains a single type of compound that is the compound AA and the second hole transporting layer contains a composition containing two types of compounds that are the compound CA and the compound CB. Further, the above condition is also satisfied when the first hole transporting layer contains the composition including two types of compounds that are the compound AA and the compound AB and the second hole transporting layer contains the composition including the two types of compounds that are the compound AA and the compound AB. On the other hand, the above condition is not satisfied, for instance, when the first hole transporting layer contains a single type of compound that is the compound AA and the second hole transporting layer contains a composition containing two types of compounds that are the compound CA and the compound AA, because the first hole transporting layer and the second hole transporting layer contain the same compound that is the compound AA. The above examples of the compounds contained in the first hole transporting layer and the second hole transporting layer are also applied to compounds contained in the first hole transporting layer and the third hole transporting layer.

In an exemplary arrangement of the organic EL device of the exemplary embodiment, the hole transporting zone materials are also preferably each independently at least one compound selected from the group consisting of a compound represented by the formula (C1) and a compound represented by the formula (C3).

In an exemplary arrangement of the organic EL device of the exemplary embodiment, the hole transporting zone materials are also preferably each independently at least one compound selected from the group consisting of a compound represented by a formula (cHT3-1) below, a compound represented by a formula (cHT3-2) below, a compound represented by a formula (cHT3-3) below, and a compound represented by a formula (cHT3-4) below.

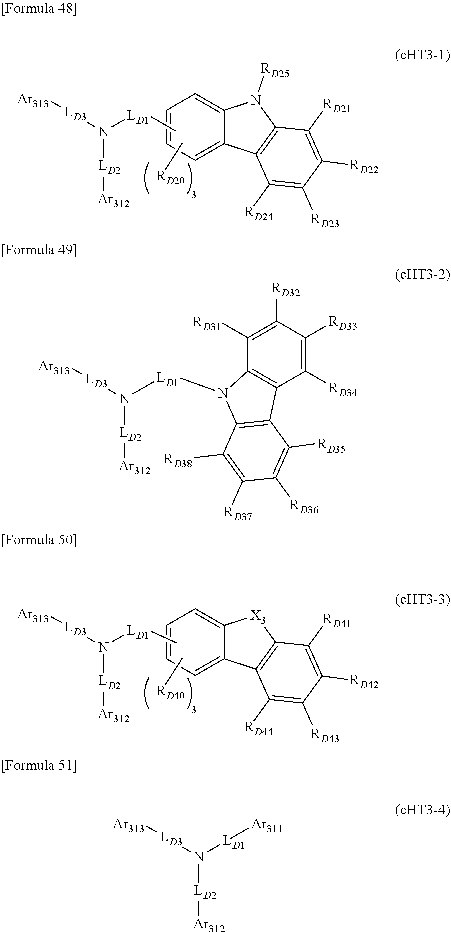

In the formulae (cHT3-1), (cHT3-2), (cHT3-3), and (cHT3-4):
Ar₃₁₁ is a group represented by one of a formula (1-a), a formula (1-b), a formula (1-c), and a formula (1-d) below;
Ar₃₁₂ and Ar₃₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different;
when a plurality of R_{C3} are present, the plurality of R_{C3} are mutually the same or different;
L_{D1}, L_{D2}, and L_{D3} are each independently a single bond, a substituted or unsubstituted arylene group having 6 to 50 ring carbon atoms, or a substituted or unsubstituted divalent heterocyclic group having 5 to 50 ring atoms;
at least one combination of adjacent two or more of R_{D20} to R_{D24} are mutually bonded to form a substituted or unsubstituted monocyclic ring, mutually bonded to form a substituted or unsubstituted fused ring, or not mutually bonded;
at least one combination of adjacent two or more of R_{D31} to R_{D38} are mutually bonded to form a substituted or unsubstituted monocyclic ring, mutually bonded to form a substituted or unsubstituted fused ring, or not mutually bonded;
at least one combination of adjacent two or more of R_{D40} to R_{D44} are mutually bonded to form a substituted or unsubstituted monocyclic ring, mutually bonded to form a substituted or unsubstituted fused ring, or not mutually bonded;
X₃ is an oxygen atom, a sulfur atom, or C(R_{D45})(R_{D46});
a combination of R_{D45} and R_{D46} are mutually bonded to form a substituted or unsubstituted monocyclic ring, mutually bonded to form a substituted or unsubstituted fused ring, or not mutually bonded; R_{D25}, and R_{D20} to R_{D24}, R_{D31} to R_{D38}, R_{D40} to R_{D44}, R_{D45} and R_{D46} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a plurality of R_{D20} are mutually the same or different;
a plurality of R_{D40} are mutually the same or different;
R₉₀₁ to R₉₀₄ in the compounds represented by the formulae (cHT3-1), (cHT3-2), (cHT3-3), and (cHT3-4) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

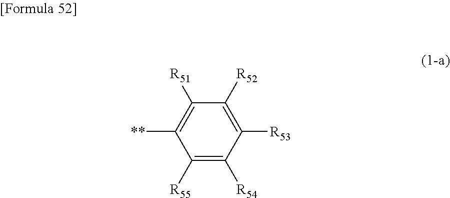

In the formula (1-a):
none of a combination(s) of adjacent two or more of R₅₁ to R₅₅ are bonded to each other;
R₅₁ to R₅₅ are each independently a hydrogen atom, or a substituted or unsubstituted alkyl group having 1 to 6 carbon atoms; and
** represents a bonding position to L_{D1}.

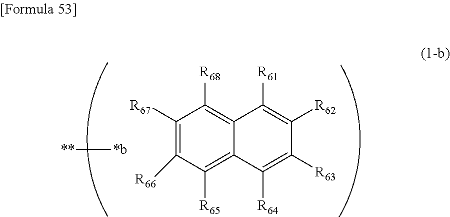

In the formula (1-b):
one of R₆₁ to R₆₈ is a single bond with *b;
none of a combination(s) of adjacent two or more of R₆₁ to R₆₈ not being the single bond with *b are bonded to each other;
R₆₁ to R₆₈ not being the single bond with *b are each independently a hydrogen atom, a substituted or unsubstituted alkyl group having 1 to 6 carbon atoms or a substituted or unsubstituted aryl group having 6 to 12 ring carbon atoms; and
** represents a bonding position to L_{D1}.

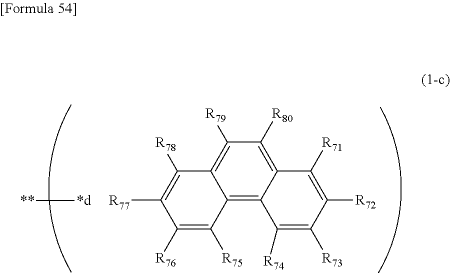

In the formula (1-c):
one of R₇₁ to R₈₀ is a single bond with *d;
none of a combination(s) of adjacent two or more of R₇₁ to Rao not being the single bond with *d are bonded to each other;
R₇₁ to Rao not being the single bond with *d are each independently a hydrogen atom, a substituted or unsubstituted alkyl group having 1 to 6 carbon atoms or a substituted or unsubstituted aryl group having 6 to 12 ring carbon atoms; and
** represents a bonding position to L_{D1}.

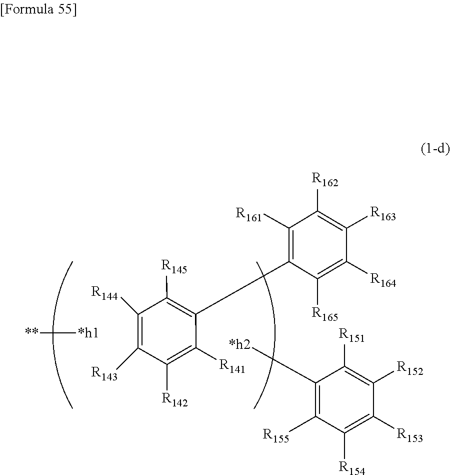

In the formula (1-d):
one of R₁₄₁ to R₁₄₅ is a single bond with *h1 and another one of R₁₄₁ to R₁₄₅ is a single bond with *h2;
none of a combination(s) of adjacent two or more of R₁₄₁ to R₁₄₅ not being the single bond with *h1 and not being the single bond with *h2 are bonded to each other;
at least one combination of adjacent two or more of R₁₅₁ to R₁₅₅ are mutually bonded to form a substituted or unsubstituted monocyclic ring, mutually bonded to form a substituted or unsubstituted fused ring, or not mutually bonded;
at least one combination of adjacent two or more of R₁₆₁ to R₁₆₅ are mutually bonded to form a substituted or unsubstituted monocyclic ring, mutually bonded to form a substituted or unsubstituted fused ring, or not mutually bonded;
R₁₄₁ to R₁₄₅ not being the single bond with *h1 and not being the single bond with *h2 as well as R₁₅₁ to R₁₅₅ and R₁₆₁ to R₁₆₅ forming neither the substituted or unsubstituted monocyclic ring nor the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position to L_{D1.}

The compound represented by the formula (cHT3-1) may be a compound represented by a formula (cHT3-11).

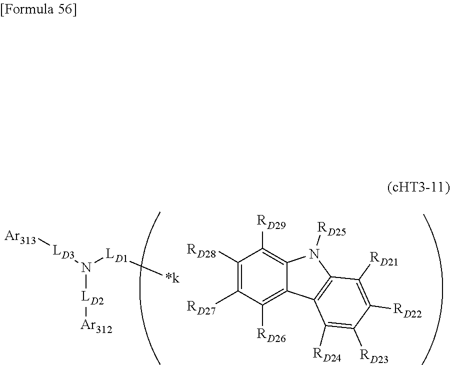

In the formula (cHT3-11):
Ar₃₁₂, Ar₃₁₃, L_{D1}, L_{D2}, L_{D3}, and R_{D25} respectively represent the same as Ar₃₁₂, Ar₃₁₃, L_{D1}, L_{D2}, L_{D3}, and R_{D25} in the formula (cHT3-1);
one of R_{D26} to R_{D29} is a single bond with L_{D1} and *k represents a bonding position;
at least one combination of adjacent two or more of R_{D21} to R_{D24}, and R_{D26} to R_{D29} not being the single bond with L_{D1} are mutually bonded to form a substituted or unsubstituted monocyclic ring, mutually bonded to form a substituted or unsubstituted fused ring, or not mutually bonded; and
R_{D21} to R_{D24} and R_{D26} to R_{D29} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms.

In an exemplary arrangement of the organic EL device according to the exemplary embodiment, R_{D26}, R_{D28}, or R_{D29} in the formula (cHT3-11) is a single bond with L_{D1}.

In a case where R_{D26} in the formula (cHT3-11) is a single bond with L_{D1}, the compound represented by the formula (cHT3-11) is a compound represented by a formula (cHT3-12) below.

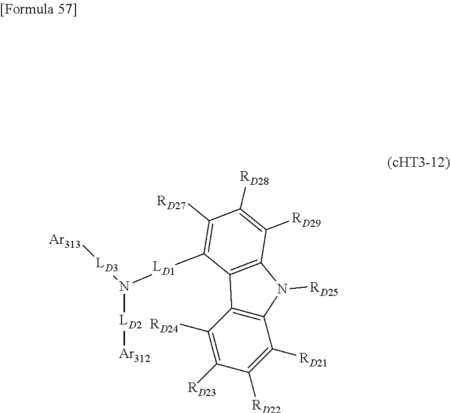

In a case where R_{D28} in the formula (cHT3-11) is a single bond with L_{D1}, the compound represented by the formula (cHT3-11) is a compound represented by a formula (cHT3-13) below.

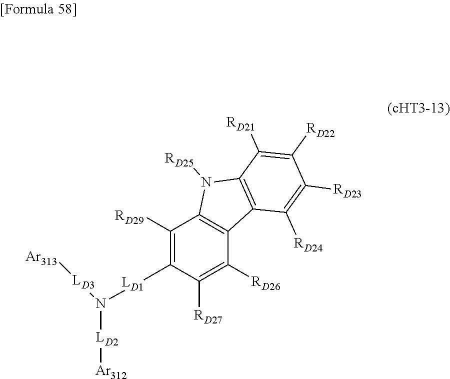

In a case where R_{D29} in the formula (cHT3-11) is a single bond with L_{D1}, the compound represented by the formula (cHT3-11) is a compound represented by a formula (cHT3-14) below.

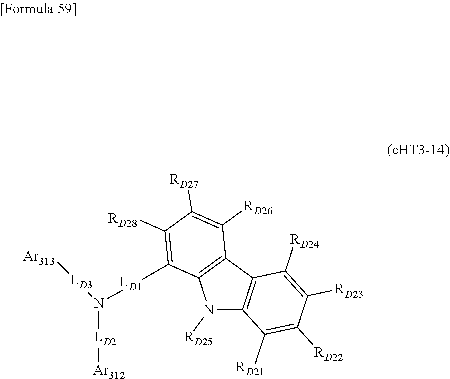

In the formulae (cHT3-12), (cHT3-13), and (cHT3-14), Ar₃₁₂, Ar₃₁₃, L_{D1}, L_{D2,} Los, and R_{D21} to R_{D29} respectively represent the same as Ar₃₁₂, Ar₃₁₃, L_{D1}, L_{D2}, L_{D3}, and R_{D21} to R_{D29} in the formula (cHT3-11).

The compound represented by the formula (cHT3-3) may be a compound represented by a formula (cHT3-31).

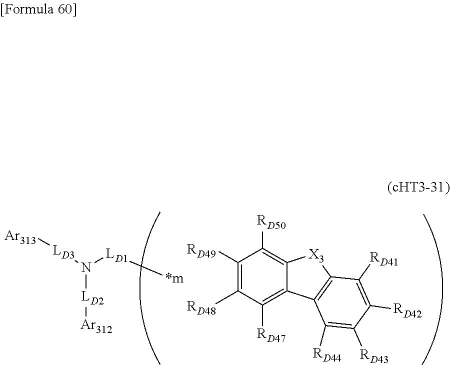

In the formula (cHT3-31), Ar₃₁₂, Ar₃₁₃, L_{D1}, L_{D2}, L_{D3}, and X₃ respectively represent the same as Ar₃₁₂, Ar₃₁₃, L_{D1}, L_{D2}, L_{D3}, and X₃ in the formula (cHT3-3);
one of R_{D47} to R_{D50} is a single bond with L_{D1} and *m represents a bonding position;
at least one combination of adjacent two or more of R_{D41} to R_{D44}, and R_{D47} to R_{D50} not being the single bond with L_{D1} are mutually bonded to form a substituted or unsubstituted monocyclic ring, mutually bonded to form a substituted or unsubstituted fused ring, or not mutually bonded;
R_{D41} to R_{D50} forming neither the substituted or unsubstituted monocyclic ring nor the substituted or unsubstituted fused ring are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms.

In an exemplary arrangement of the organic EL device of the exemplary embodiment, L_{D1} is a single bond and a substituted or unsubstituted phenylene group.

In an exemplary arrangement of the organic EL device of the exemplary embodiment, a substituent for a “substituted or unsubstituted” group in the compounds represented by the formulae (cHT3-1) to (cHT3-14), (cHT3-11) to (cHT3-14), and (cHT3-31) is not a group represented by —N(R_{C6})(R_{C7}).

In the exemplary embodiment, R_{C6} and R_{C7} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms. A plurality of R_{C6} are mutually the same or different, and a plurality of R_{C7} are mutually the same or different.

When a substituent for a “substituted or unsubstituted” group is not a group represented by —N(R_{C6})(R_{C7}), the compounds represented by the formulae (cHT3-1) to (cHT3-4), (cHT3-11) to (cHT3-14), and (cHT3-31) are each a monoamine compound.

In the organic EL device according to the exemplary embodiment, R₉₀₁, R₉₀₂, R₉₀₃, and R₉₀₄ in a compound contained in each layer of the hole transporting zone are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different; and
when a plurality of R₉₀₄ are present, the plurality of R₉₀₄ are mutually the same or different.

In an exemplary arrangement of the organic EL device of the exemplary embodiment, the groups specified to be “substituted or unsubstituted” are each preferably an “unsubstituted” group.

In an exemplary arrangement of the organic EL device according to the exemplary embodiment, the first hole transporting zone material, the second hole transporting zone material, the third hole transporting zone material, and the fourth hole transporting zone material are each independently a monoamine compound having one substituted or unsubstituted amino group in a molecule, a diamine compound having two substituted or unsubstituted amino groups in a molecule, a triamine compound having three substituted or unsubstituted amino groups in a molecule, or a tetraamine compound having four substituted or unsubstituted amino groups in a molecule.

In an exemplary arrangement of the organic EL device according to the exemplary embodiment, the first hole transporting zone material, the second hole transporting zone material, the third hole transporting zone material, and the fourth hole transporting zone material are each independently a monoamine compound having one substituted or unsubstituted amino group in a molecule or a diamine compound having two substituted or unsubstituted amino groups in a molecule.

In an exemplary arrangement of the organic EL device according to the exemplary embodiment, the first hole transporting zone material, the second hole transporting zone material, the third hole transporting zone material, and the fourth hole transporting zone material are each independently a monoamine compound having one substituted or unsubstituted amino group in a molecule.

### Method of Producing Hole Transporting Zone Material

The hole transporting zone materials according to the exemplary embodiment can be produced by a known method or through a known alternative reaction using a known material(s) tailored for the target compound in accordance with the known method.

### Specific Examples of Hole Transporting Zone Material

Specific examples of the hole transporting zone material according to the exemplary embodiment include the following compounds and the specific examples of the first compound and the second compound. However, the invention is by no means limited to these specific examples.

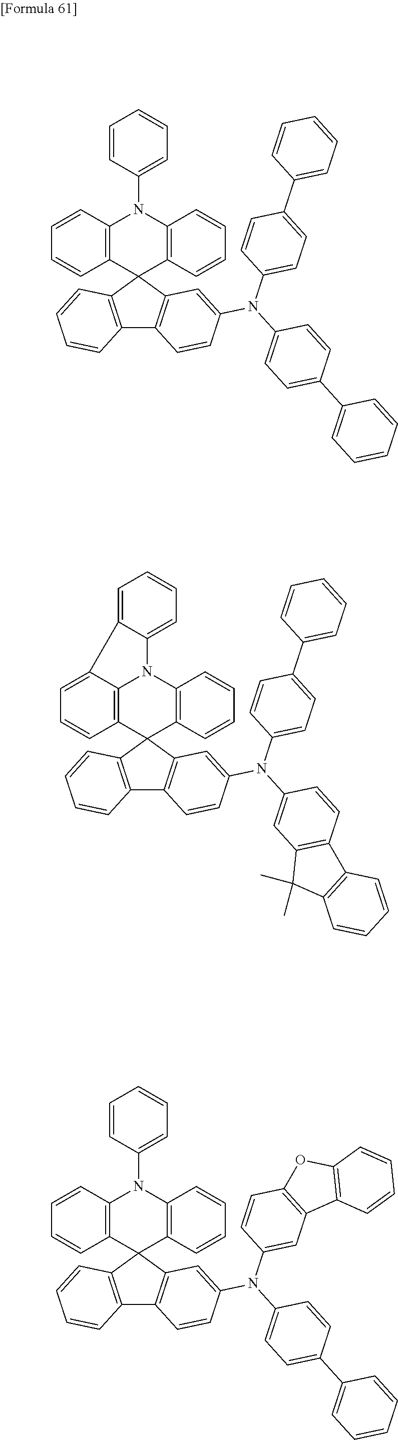 [SMILES: c1ccc(-c2ccc(N(c3ccc(-c4ccccc4)cc3)c3ccc4c(c3)C3(c5ccccc5-4)c4ccccc4N(c4ccccc4)c4ccccc43)cc2)cc1 ; CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; c1ccc(-c2ccc(N(c3ccc4c(c3)C3(c5ccccc5-4)c4ccccc4N(c4ccccc4)c4ccccc43)c3ccc4oc5ccccc5c4c3)cc2)cc1]

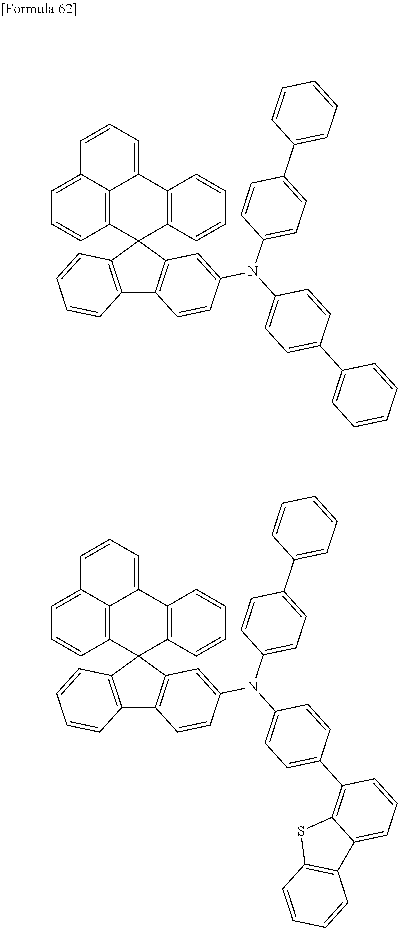 [SMILES: c1ccc(-c2ccc(N(c3ccc(-c4ccccc4)cc3)c3ccc4c(c3)C3(c5ccccc5-4)c4ccccc4-c4cccc5cccc3c45)cc2)cc1 ; c1ccc(-c2ccc(N(c3ccc(-c4cccc5c4sc4ccccc45)cc3)c3ccc4c(c3)C3(c5ccccc5-4)c4ccccc4-c4cccc5cccc3c45)cc2)cc1]

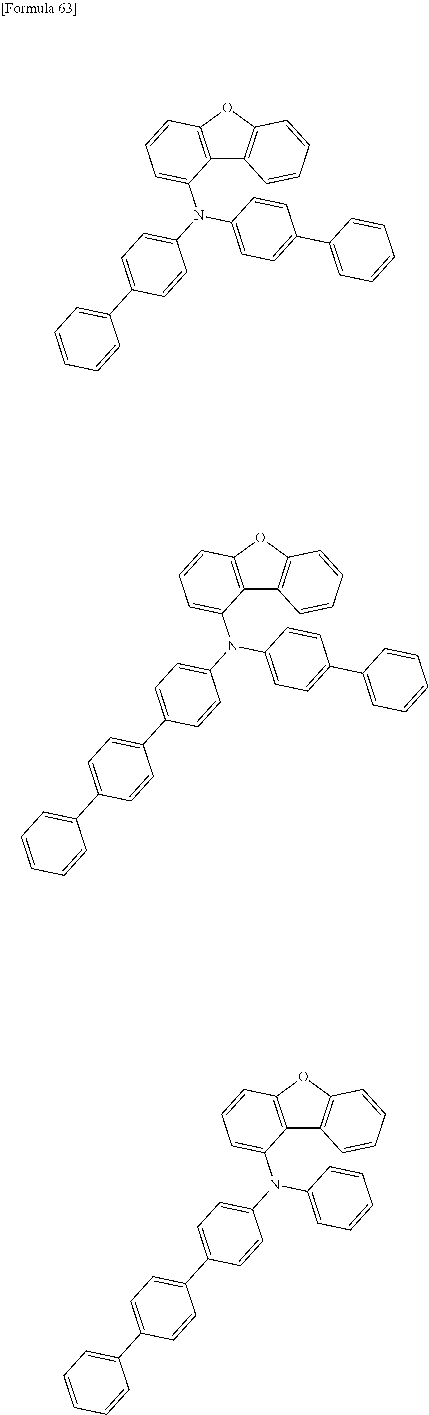 [SMILES: c1ccc(-c2ccc(N(c3ccc(-c4ccccc4)cc3)c3cccc4oc5ccccc5c34)cc2)cc1 ; c1ccc(-c2ccc(-c3ccc(N(c4ccc(-c5ccccc5)cc4)c4cccc5oc6ccccc6c45)cc3)cc2)cc1 ; c1ccc(-c2ccc(-c3ccc(N(c4ccccc4)c4cccc5oc6ccccc6c45)cc3)cc2)cc1]

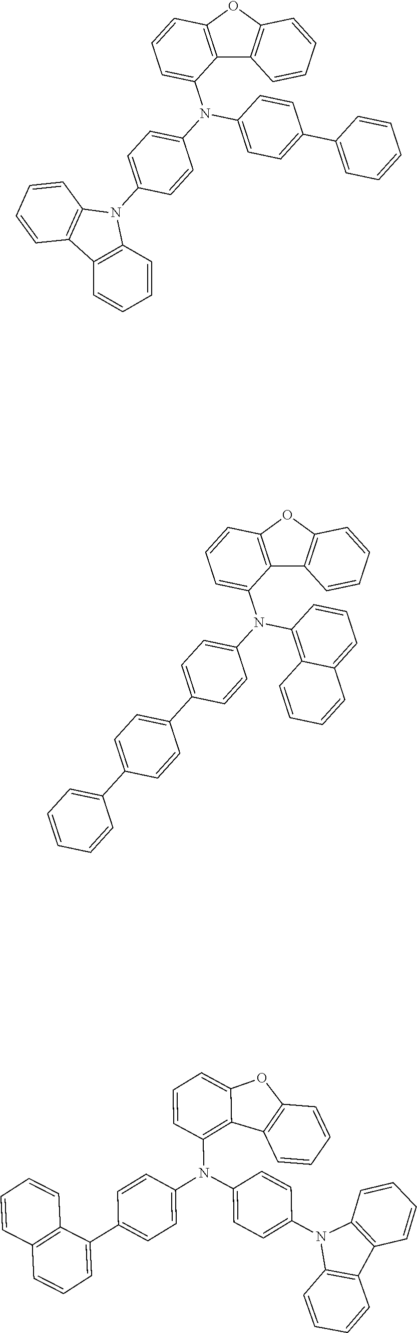 [SMILES: c1ccc(-c2ccc(N(c3ccc(-n4c5ccccc5c5ccccc54)cc3)c3cccc4oc5ccccc5c34)cc2)cc1 ; c1ccc(-c2ccc(-c3ccc(N(c4cccc5ccccc45)c4cccc5oc6ccccc6c45)cc3)cc2)cc1 ; c1ccc2c(-c3ccc(N(c4ccc(-n5c6ccccc6c6ccccc65)cc4)c4cccc5oc6ccccc6c45)cc3)cccc2c1]

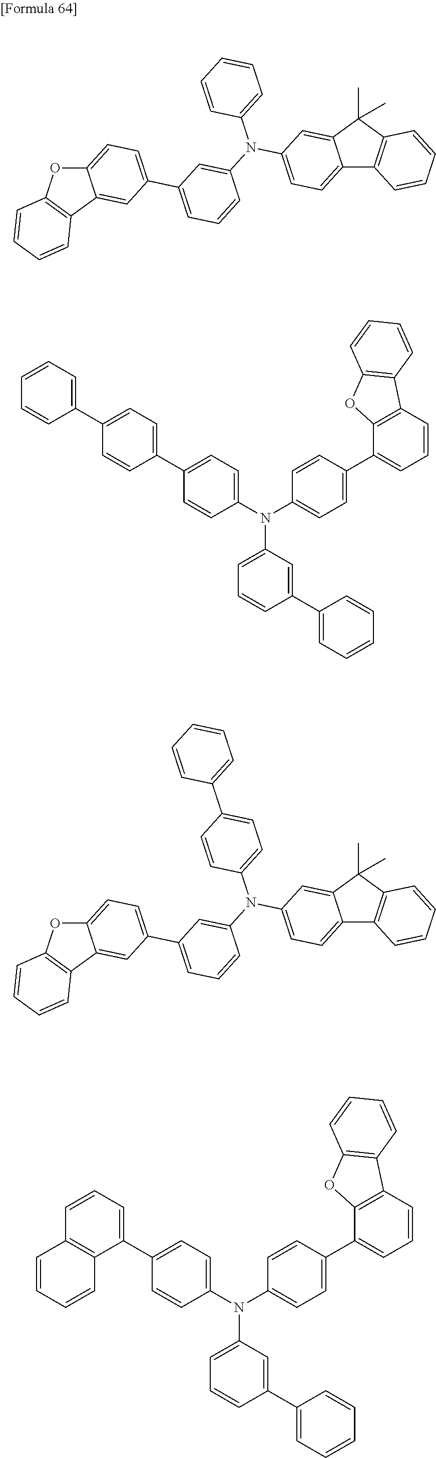 [SMILES: CC1(C)c2ccccc2-c2ccc(N(c3ccccc3)c3cccc(-c4ccc5oc6ccccc6c5c4)c3)cc21 ; c1ccc(-c2ccc(-c3ccc(N(c4ccc(-c5cccc6c5oc5ccccc56)cc4)c4cccc(-c5ccccc5)c4)cc3)cc2)cc1 ; CC1(C)c2ccccc2-c2ccc(N(c3ccc(-c4ccccc4)cc3)c3cccc(-c4ccc5oc6ccccc6c5c4)c3)cc21 ; c1ccc(-c2cccc(N(c3ccc(-c4cccc5ccccc45)cc3)c3ccc(-c4cccc5c4oc4ccccc45)cc3)c2)cc1]

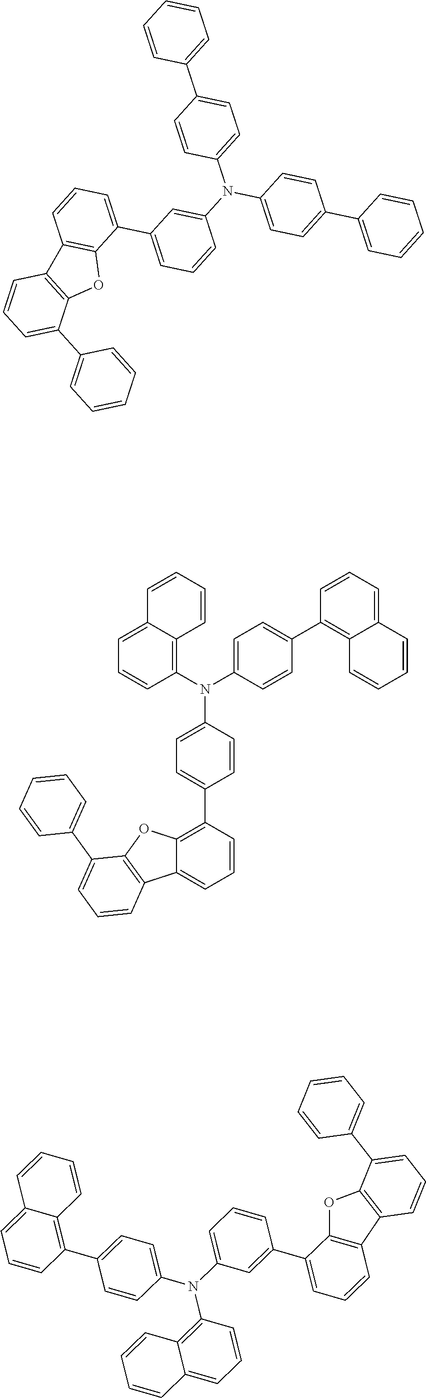 [SMILES: c1ccc(-c2ccc(N(c3ccc(-c4ccccc4)cc3)c3cccc(-c4cccc5c4oc4c(-c6ccccc6)cccc45)c3)cc2)cc1 ; c1ccc(-c2cccc3c2oc2c(-c4ccc(N(c5ccc(-c6cccc7ccccc67)cc5)c5cccc6ccccc56)cc4)cccc23)cc1 ; c1ccc(-c2cccc3c2oc2c(-c4cccc(N(c5ccc(-c6cccc7ccccc67)cc5)c5cccc6ccccc56)c4)cccc23)cc1]

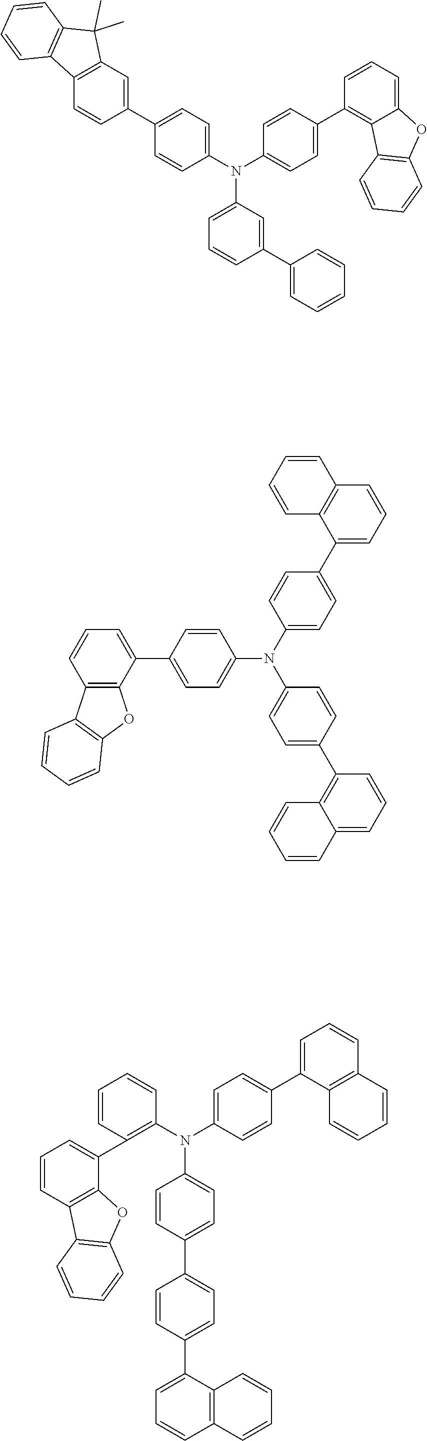 [SMILES: CC1(C)c2ccccc2-c2ccc(-c3ccc(N(c4ccc(-c5cccc6oc7ccccc7c56)cc4)c4cccc(-c5ccccc5)c4)cc3)cc21 ; c1ccc2c(-c3ccc(N(c4ccc(-c5cccc6ccccc56)cc4)c4ccc(-c5cccc6c5oc5ccccc56)cc4)cc3)cccc2c1 ; c1ccc(N(c2ccc(-c3ccc(-c4cccc5ccccc45)cc3)cc2)c2ccc(-c3cccc4ccccc34)cc2)c(-c2cccc3c2oc2ccccc23)c1]

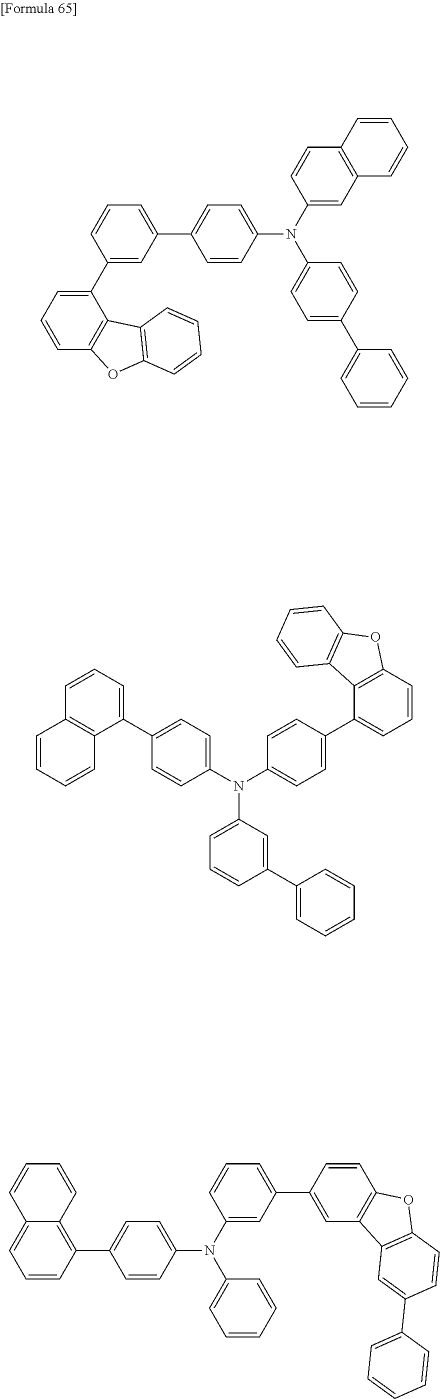 [SMILES: c1ccc(-c2ccc(N(c3ccc(-c4cccc(-c5cccc6oc7ccccc7c56)c4)cc3)c3ccc4ccccc4c3)cc2)cc1 ; c1ccc(-c2cccc(N(c3ccc(-c4cccc5ccccc45)cc3)c3ccc(-c4cccc5oc6ccccc6c45)cc3)c2)cc1 ; c1ccc(-c2ccc3oc4ccc(-c5cccc(N(c6ccccc6)c6ccc(-c7cccc8ccccc78)cc6)c5)cc4c3c2)cc1]

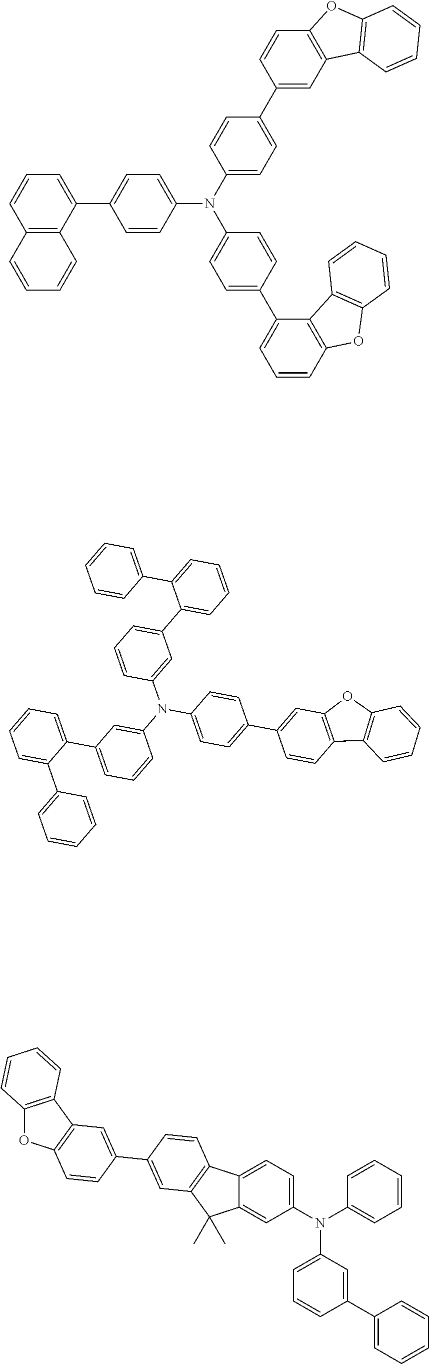 [SMILES: c1ccc2c(-c3ccc(N(c4ccc(-c5ccc6oc7ccccc7c6c5)cc4)c4ccc(-c5cccc6oc7ccccc7c56)cc4)cc3)cccc2c1 ; c1ccc(-c2ccccc2-c2cccc(N(c3ccc(-c4ccc5c(c4)oc4ccccc45)cc3)c3cccc(-c4ccccc4-c4ccccc4)c3)c2)cc1 ; CC1(C)c2cc(-c3ccc4oc5ccccc5c4c3)ccc2-c2ccc(N(c3ccccc3)c3cccc(-c4ccccc4)c3)cc21]

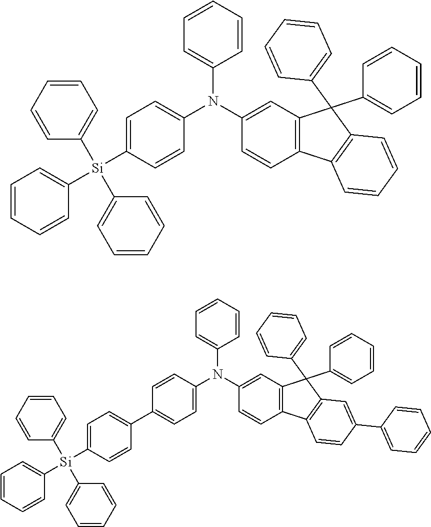

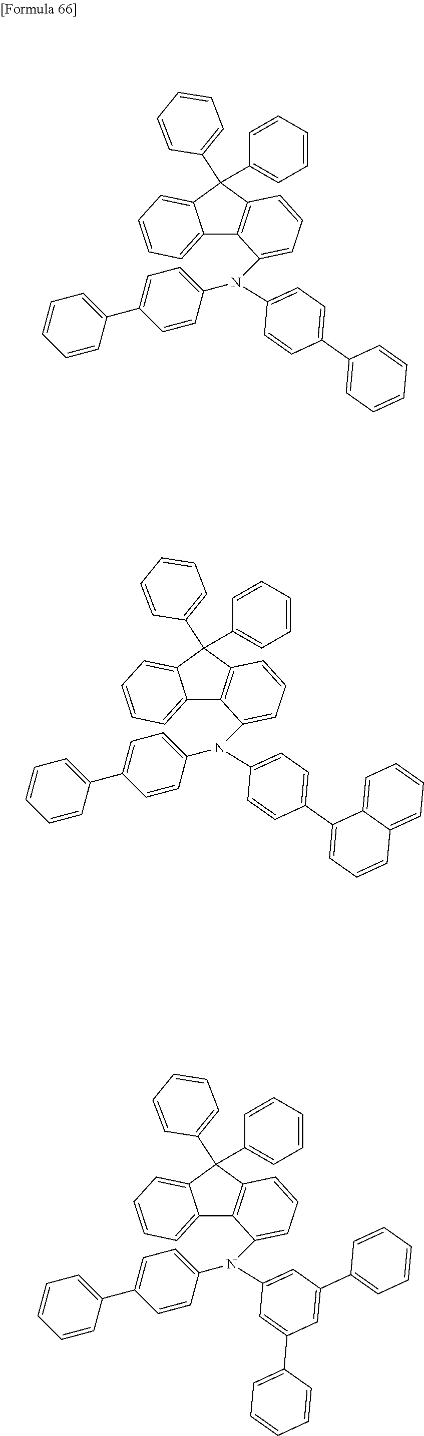 [SMILES: c1ccc(-c2ccc(N(c3ccc(-c4ccccc4)cc3)c3cccc4c3-c3ccccc3C4(c3ccccc3)c3ccccc3)cc2)cc1 ; c1ccc(-c2ccc(N(c3ccc(-c4cccc5ccccc45)cc3)c3cccc4c3-c3ccccc3C4(c3ccccc3)c3ccccc3)cc2)cc1 ; c1ccc(-c2ccc(N(c3cc(-c4ccccc4)cc(-c4ccccc4)c3)c3cccc4c3-c3ccccc3C4(c3ccccc3)c3ccccc3)cc2)cc1]

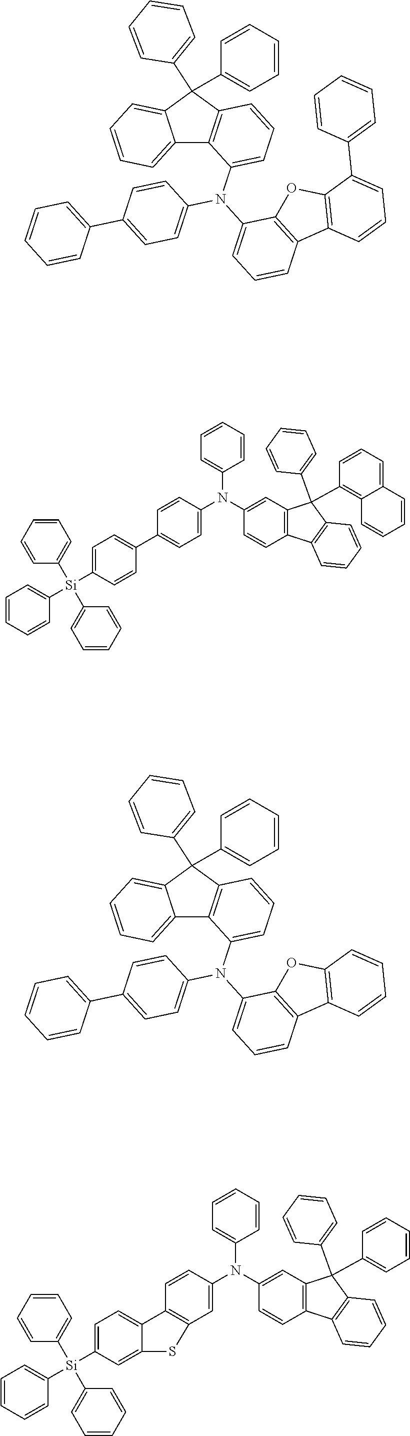 [SMILES: c1ccc(-c2ccc(N(c3cccc4c3-c3ccccc3C4(c3ccccc3)c3ccccc3)c3cccc4c3oc3c(-c5ccccc5)cccc34)cc2)cc1 ; c1ccc(N(c2ccc(-c3ccc([Si](c4ccccc4)(c4ccccc4)c4ccccc4)cc3)cc2)c2ccc3c(c2)C(c2ccccc2)(c2cccc4ccccc24)c2ccccc2-3)cc1 ; c1ccc(-c2ccc(N(c3cccc4c3-c3ccccc3C4(c3ccccc3)c3ccccc3)c3cccc4c3oc3ccccc34)cc2)cc1 ; c1ccc(N(c2ccc3c(c2)C(c2ccccc2)(c2ccccc2)c2ccccc2-3)c2ccc3c(c2)sc2cc([Si](c4ccccc4)(c4ccccc4)c4ccccc4)ccc23)cc1]

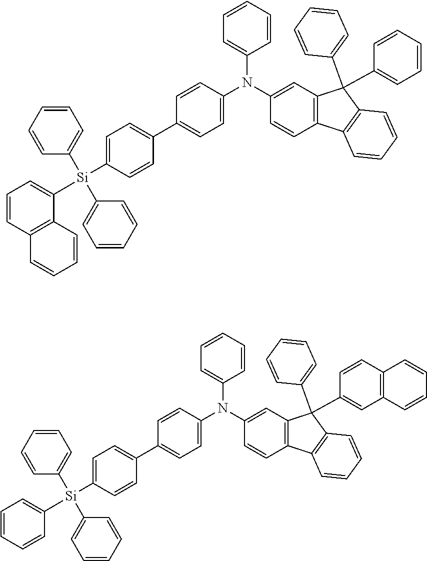 [SMILES: c1ccc(N(c2ccc(-c3ccc([Si](c4ccccc4)(c4ccccc4)c4cccc5ccccc45)cc3)cc2)c2ccc3c(c2)C(c2ccccc2)(c2ccccc2)c2ccccc2-3)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccc4ccccc4c2)c2ccccc2-3)cc1]

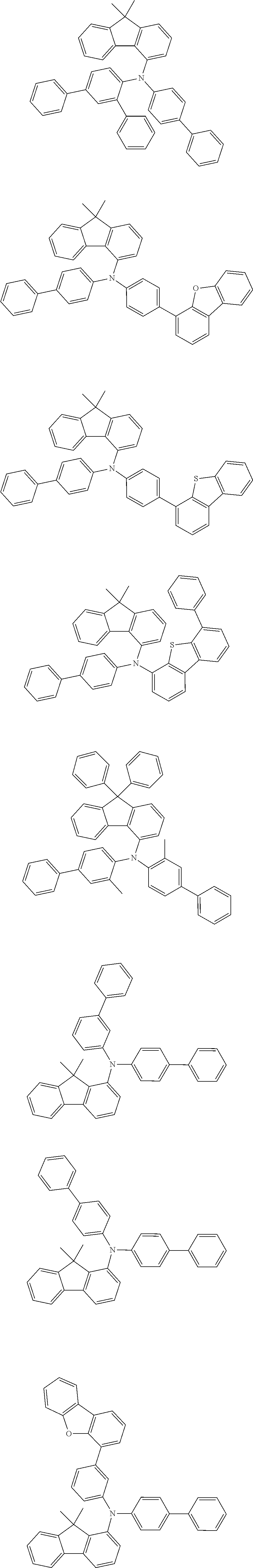

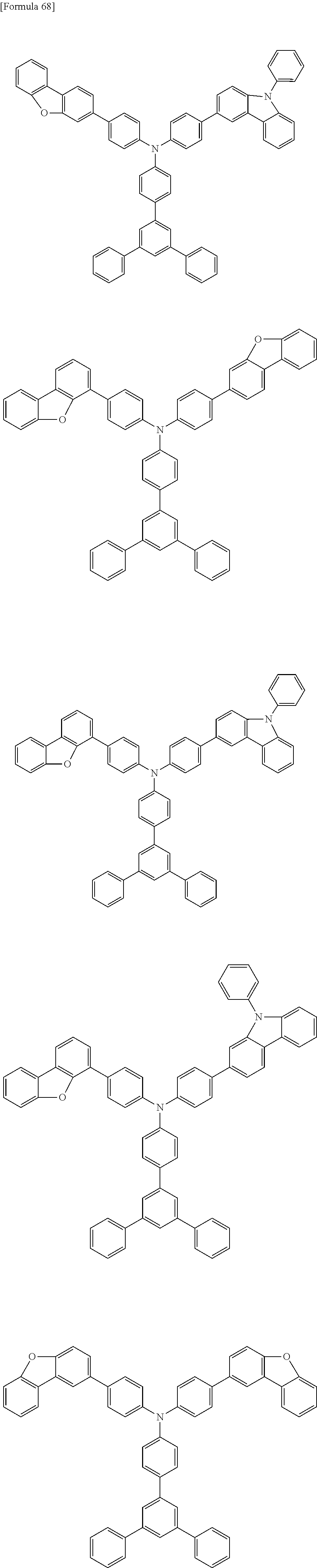

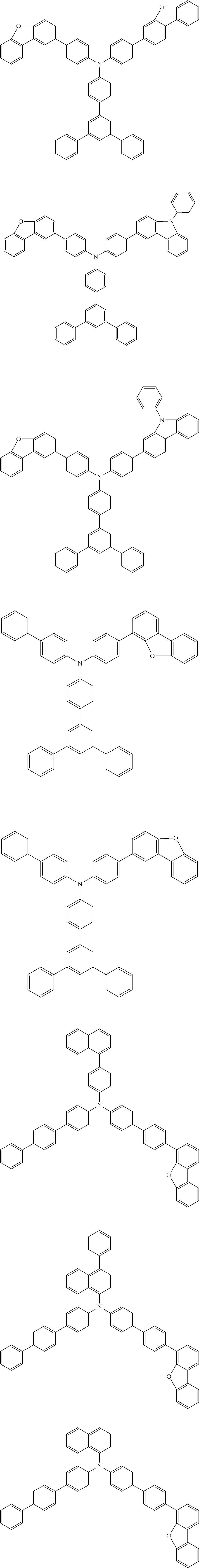

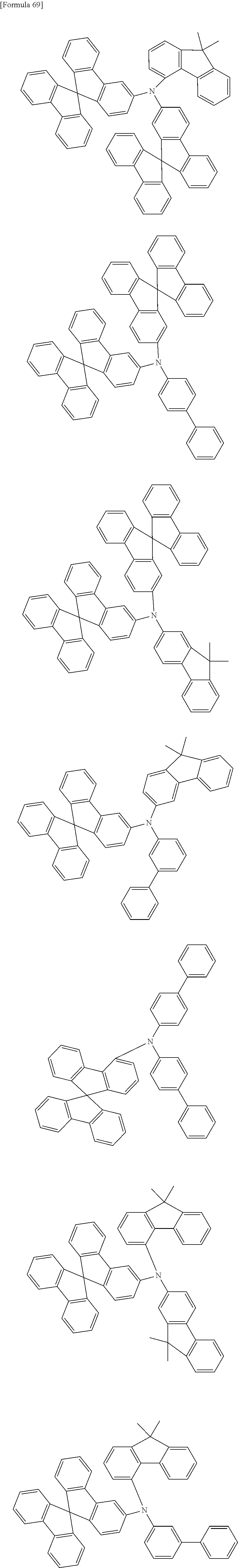

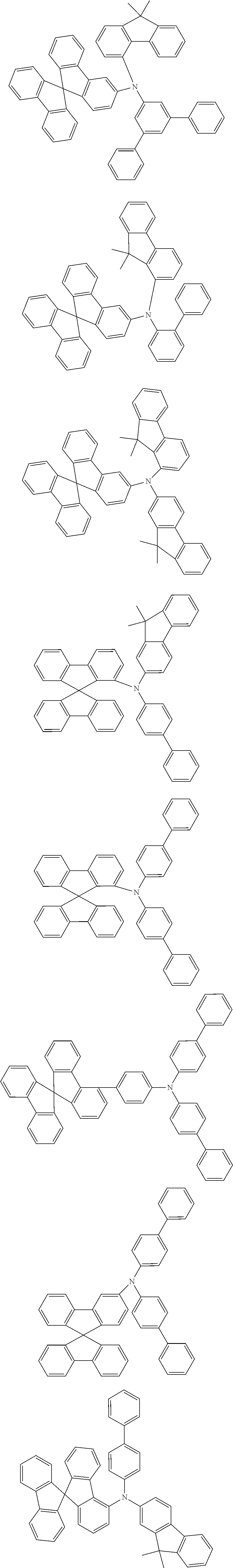

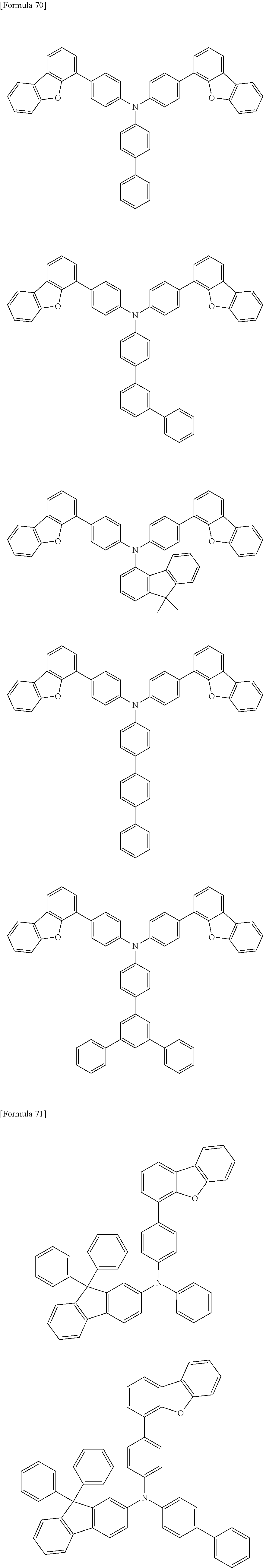

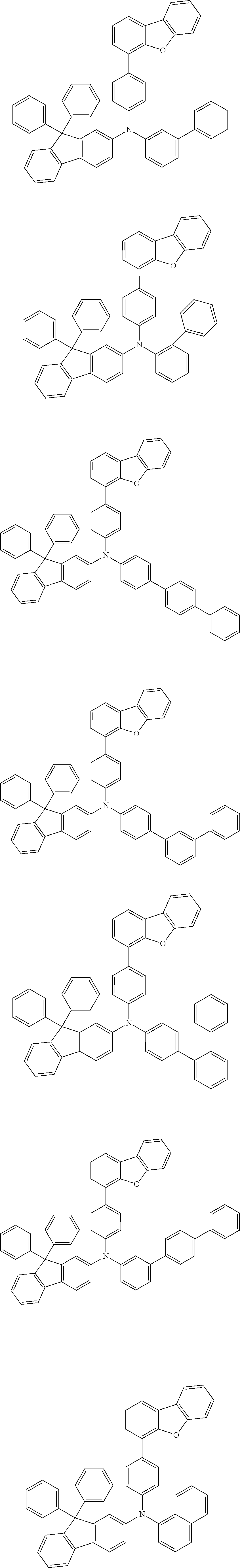

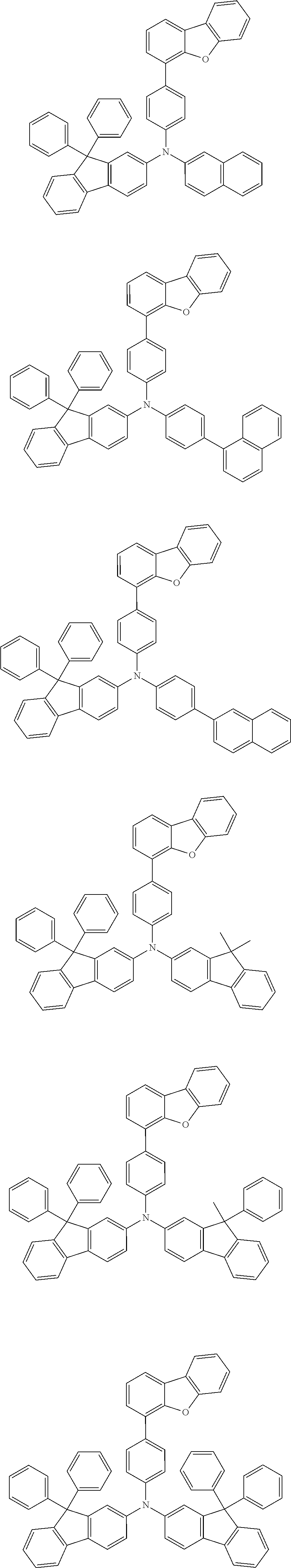

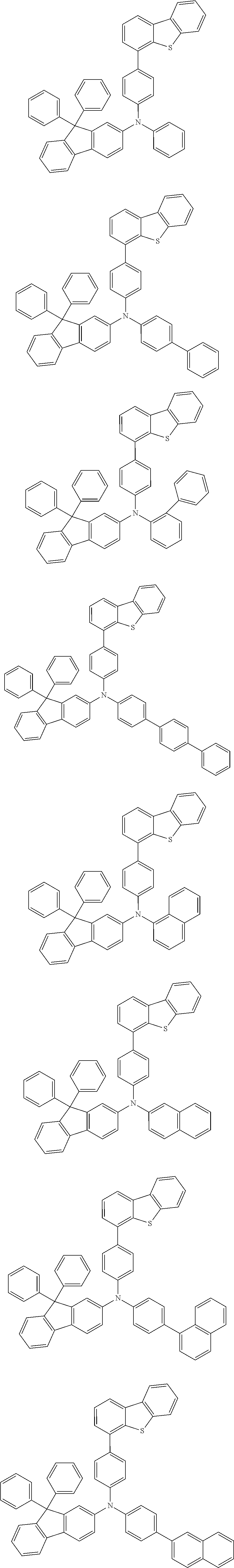

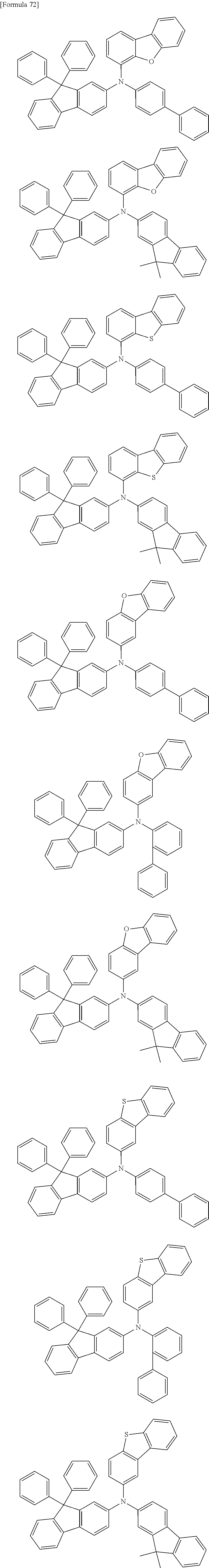

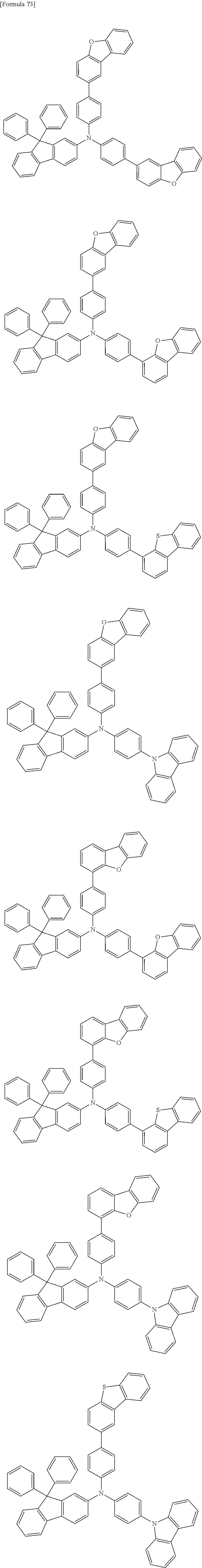

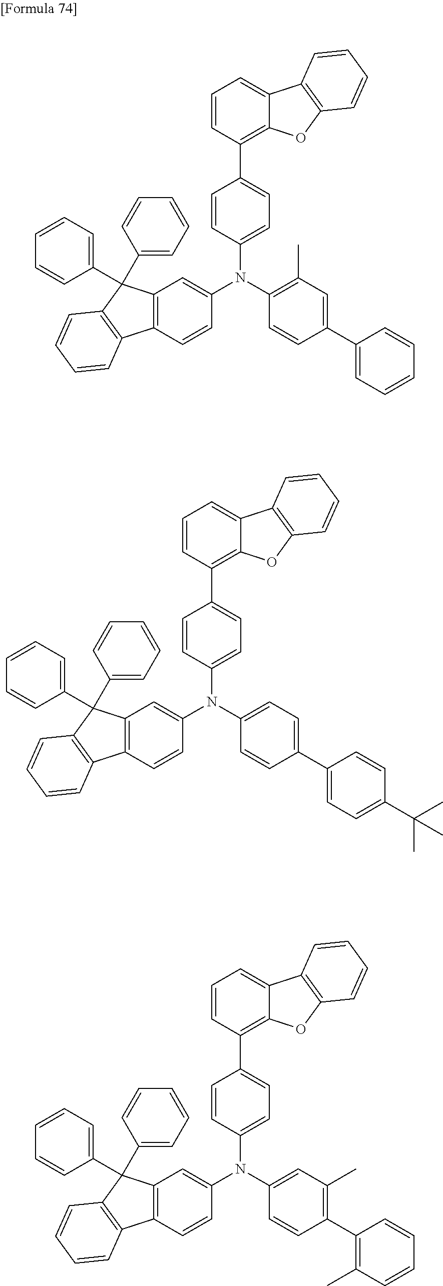 [SMILES: Cc1cc(-c2ccccc2)ccc1N(c1ccc(-c2cccc3c2oc2ccccc23)cc1)c1ccc2c(c1)C(c1ccccc1)(c1ccccc1)c1ccccc1-2 ; CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; Cc1ccccc1-c1ccc(N(c2ccc(-c3cccc4c3oc3ccccc34)cc2)c2ccc3c(c2)C(c2ccccc2)(c2ccccc2)c2ccccc2-3)cc1C]

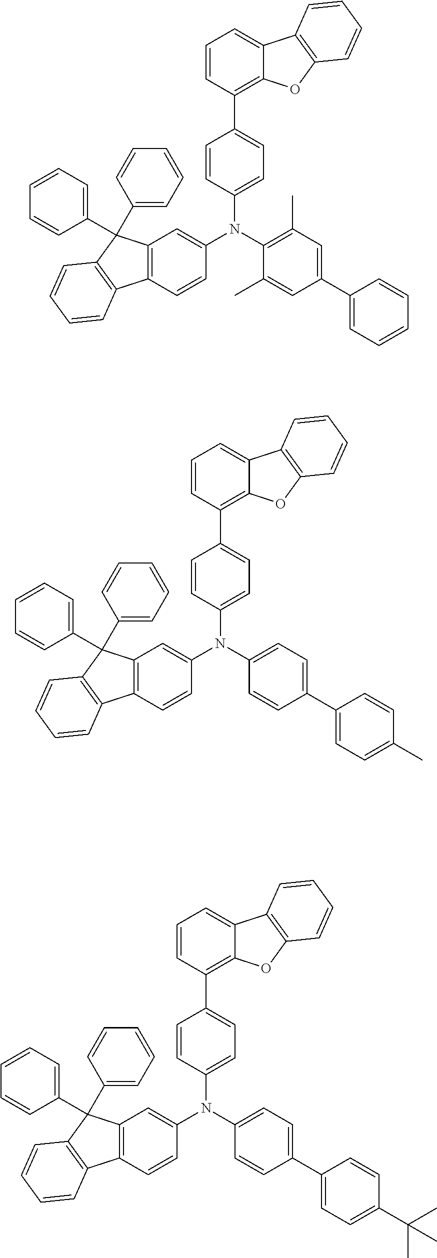 [SMILES: Cc1cc(-c2ccccc2)cc(C)c1N(c1ccc(-c2cccc3c2oc2ccccc23)cc1)c1ccc2c(c1)C(c1ccccc1)(c1ccccc1)c1ccccc1-2 ; Cc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; CC(C)(C)c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1]

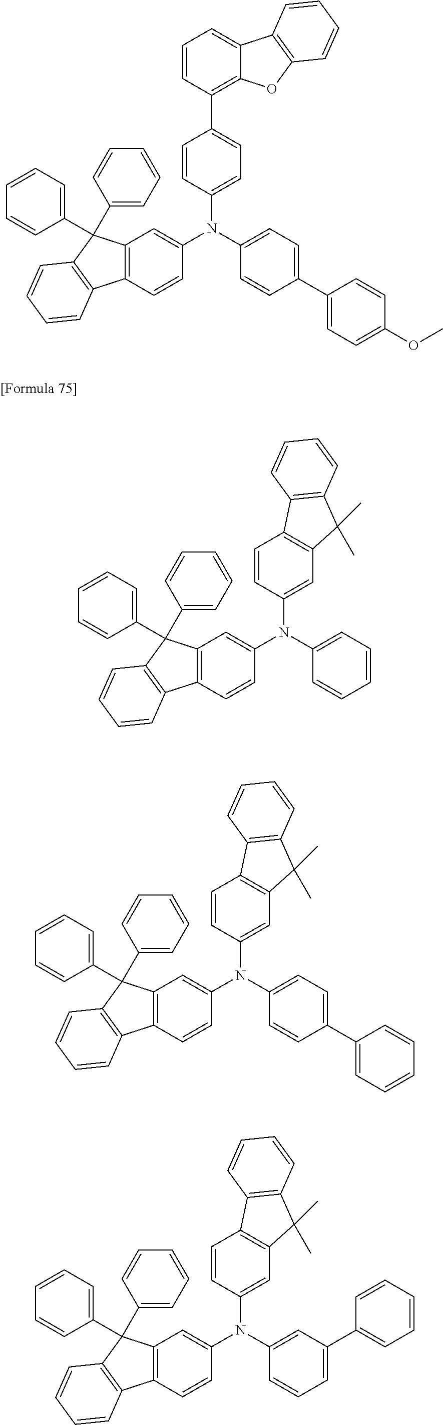 [SMILES: COc1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; CC1(C)c2ccccc2-c2ccc(N(c3ccccc3)c3ccc4c(c3)C(c3ccccc3)(c3ccccc3)c3ccccc3-4)cc21 ; CC1(C)c2ccccc2-c2ccc(N(c3ccc(-c4ccccc4)cc3)c3ccc4c(c3)C(c3ccccc3)(c3ccccc3)c3ccccc3-4)cc21 ; CC1(C)c2ccccc2-c2ccc(N(c3cccc(-c4ccccc4)c3)c3ccc4c(c3)C(c3ccccc3)(c3ccccc3)c3ccccc3-4)cc21]

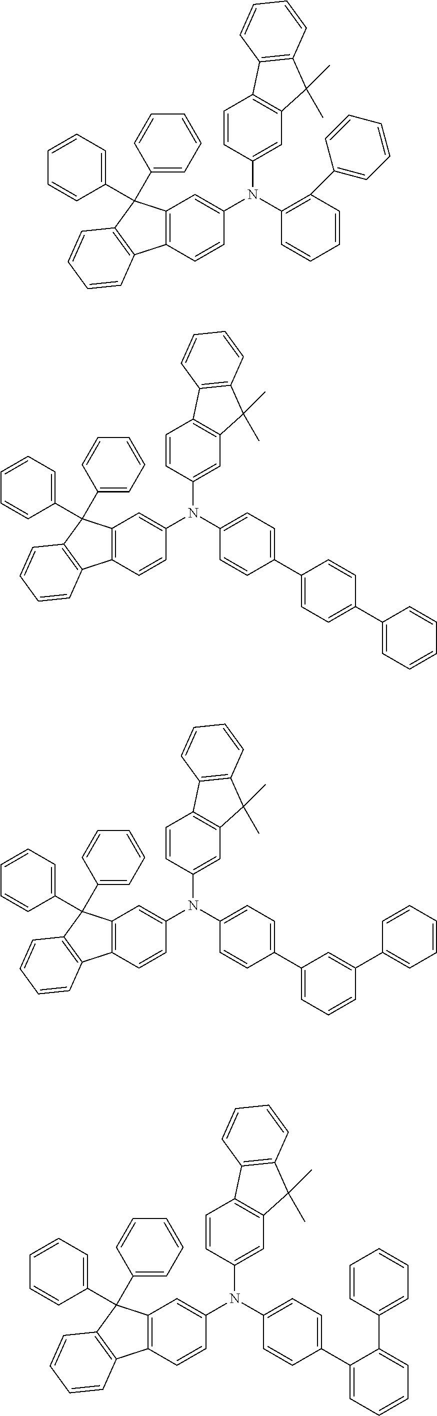 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(N(c3ccc(-c4ccc(-c5ccccc5)cc4)cc3)c3ccc4c(c3)C(c3ccccc3)(c3ccccc3)c3ccccc3-4)cc21 ; CC1(C)c2ccccc2-c2ccc(N(c3ccc(-c4cccc(-c5ccccc5)c4)cc3)c3ccc4c(c3)C(c3ccccc3)(c3ccccc3)c3ccccc3-4)cc21 ; CC1(C)c2ccccc2-c2ccc(N(c3ccc(-c4ccccc4-c4ccccc4)cc3)c3ccc4c(c3)C(c3ccccc3)(c3ccccc3)c3ccccc3-4)cc21]

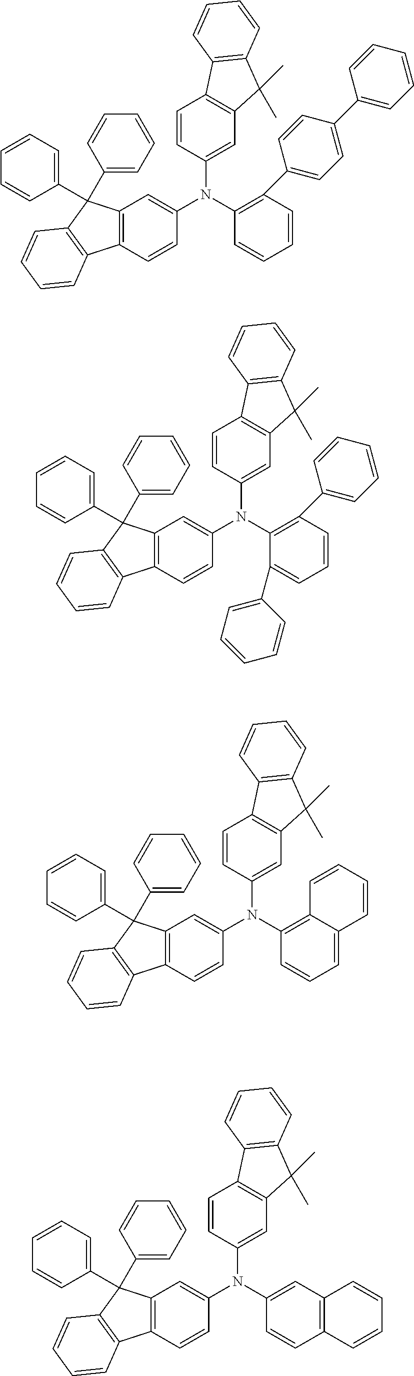 [SMILES: CC1(C)c2ccccc2-c2ccc(N(c3ccc4c(c3)C(c3ccccc3)(c3ccccc3)c3ccccc3-4)c3ccccc3-c3ccc(-c4ccccc4)cc3)cc21 ; CC1(C)c2ccccc2-c2ccc(N(c3ccc4c(c3)C(c3ccccc3)(c3ccccc3)c3ccccc3-4)c3c(-c4ccccc4)cccc3-c3ccccc3)cc21 ; CC1(C)c2ccccc2-c2ccc(N(c3ccc4c(c3)C(c3ccccc3)(c3ccccc3)c3ccccc3-4)c3cccc4ccccc34)cc21 ; CC1(C)c2ccccc2-c2ccc(N(c3ccc4c(c3)C(c3ccccc3)(c3ccccc3)c3ccccc3-4)c3ccc4ccccc4c3)cc21]

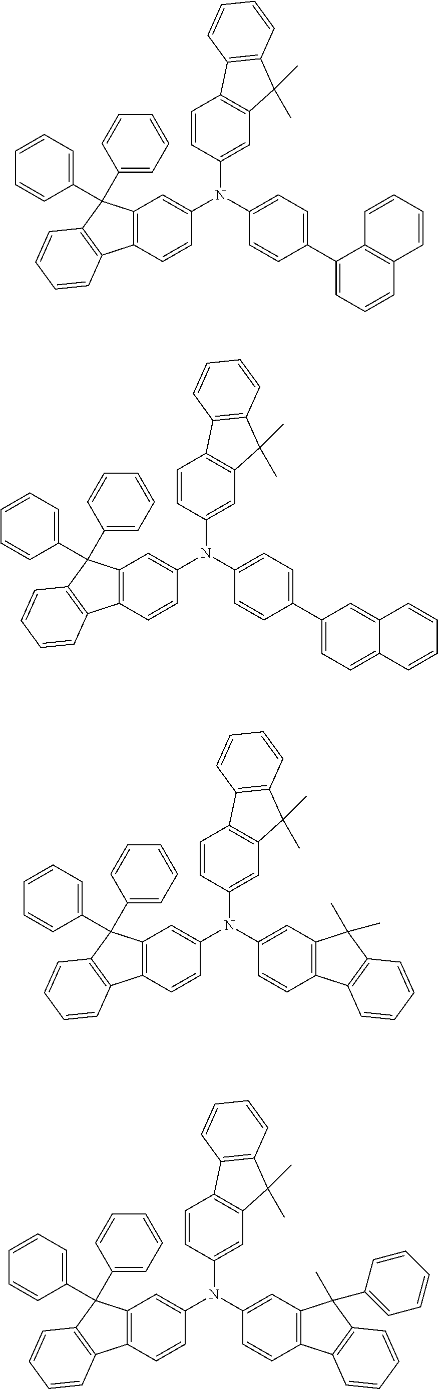 [SMILES: CC1(C)c2ccccc2-c2ccc(N(c3ccc(-c4cccc5ccccc45)cc3)c3ccc4c(c3)C(c3ccccc3)(c3ccccc3)c3ccccc3-4)cc21 ; CC1(C)c2ccccc2-c2ccc(N(c3ccc(-c4ccc5ccccc5c4)cc3)c3ccc4c(c3)C(c3ccccc3)(c3ccccc3)c3ccccc3-4)cc21 ; CC1(C)c2ccccc2-c2ccc(N(c3ccc4c(c3)C(C)(C)c3ccccc3-4)c3ccc4c(c3)C(c3ccccc3)(c3ccccc3)c3ccccc3-4)cc21 ; CC1(C)c2ccccc2-c2ccc(N(c3ccc4c(c3)C(C)(c3ccccc3)c3ccccc3-4)c3ccc4c(c3)C(c3ccccc3)(c3ccccc3)c3ccccc3-4)cc21]

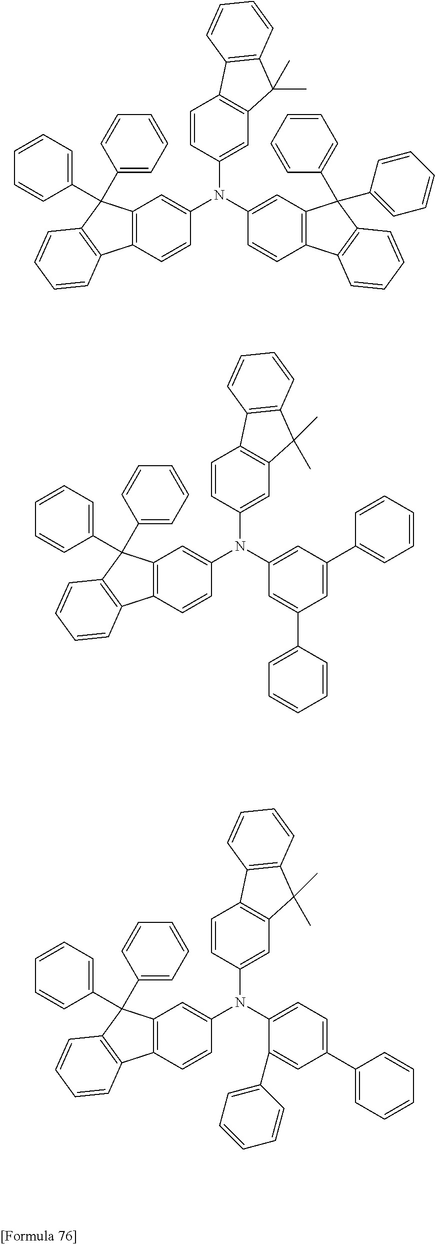 [SMILES: CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21 ; CC1(C)c2ccccc2-c2ccc(N(c3cc(-c4ccccc4)cc(-c4ccccc4)c3)c3ccc4c(c3)C(c3ccccc3)(c3ccccc3)c3ccccc3-4)cc21 ; CC1(C)c2ccccc2-c2ccc(N(c3ccc4c(c3)C(c3ccccc3)(c3ccccc3)c3ccccc3-4)c3ccc(-c4ccccc4)cc3-c3ccccc3)cc21]

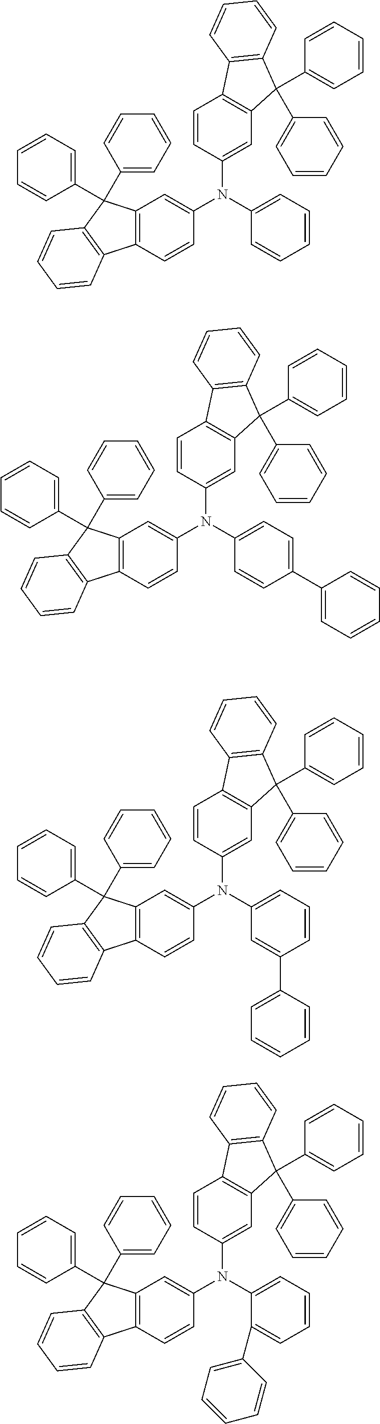

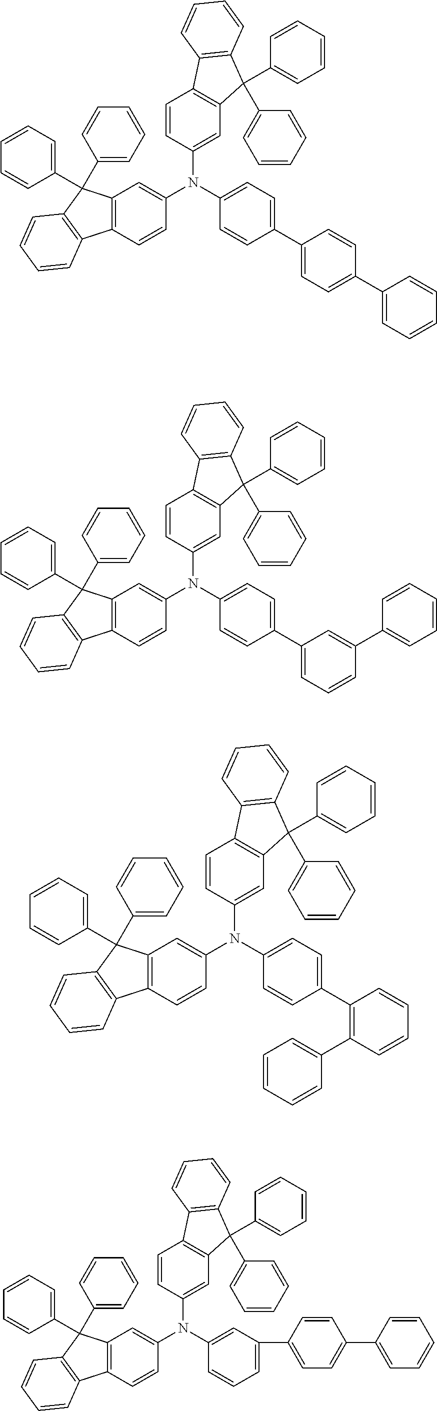 [SMILES: c1ccc(-c2ccc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)cc2)cc1 ; c1ccc(-c2cccc(-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3)c2)cc1 ; c1ccc(-c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; c1ccc(-c2ccc(-c3cccc(N(c4ccc5c(c4)C(c4ccccc4)(c4ccccc4)c4ccccc4-5)c4ccc5c(c4)C(c4ccccc4)(c4ccccc4)c4ccccc4-5)c3)cc2)cc1]

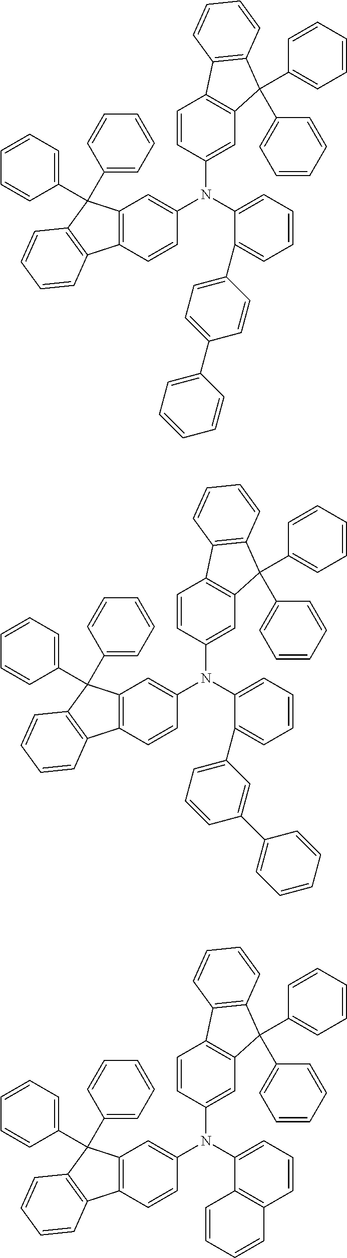 [SMILES: c1ccc(-c2ccc(-c3ccccc3N(c3ccc4c(c3)C(c3ccccc3)(c3ccccc3)c3ccccc3-4)c3ccc4c(c3)C(c3ccccc3)(c3ccccc3)c3ccccc3-4)cc2)cc1 ; c1ccc(-c2cccc(-c3ccccc3N(c3ccc4c(c3)C(c3ccccc3)(c3ccccc3)c3ccccc3-4)c3ccc4c(c3)C(c3ccccc3)(c3ccccc3)c3ccccc3-4)c2)cc1 ; c1ccc(C2(c3ccccc3)c3ccccc3-c3ccc(N(c4ccc5c(c4)C(c4ccccc4)(c4ccccc4)c4ccccc4-5)c4cccc5ccccc45)cc32)cc1]

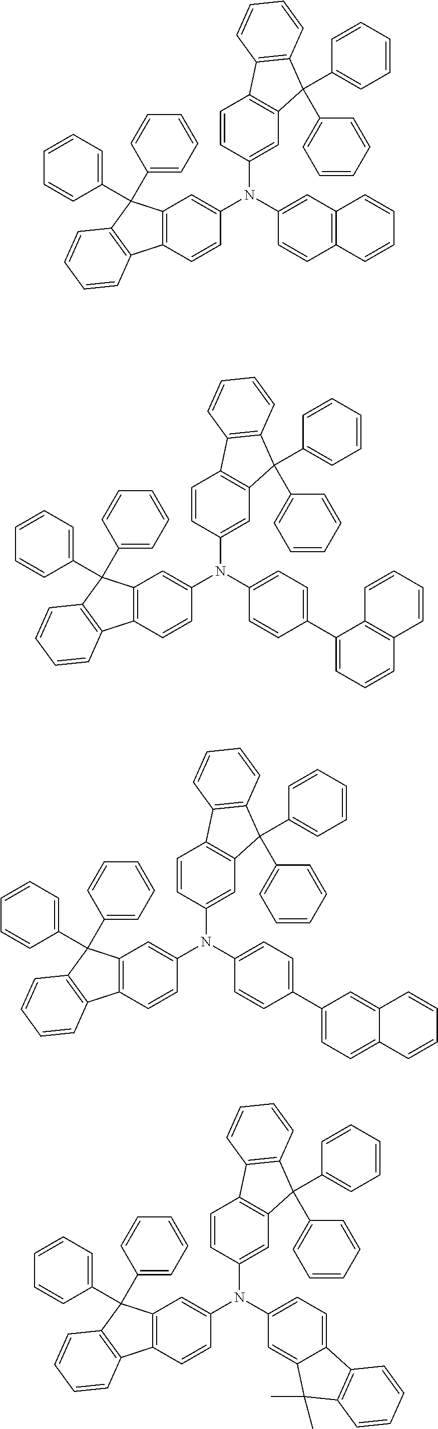 [SMILES: c1ccc(C2(c3ccccc3)c3ccccc3-c3ccc(N(c4ccc5c(c4)C(c4ccccc4)(c4ccccc4)c4ccccc4-5)c4ccc5ccccc5c4)cc32)cc1 ; c1ccc(C2(c3ccccc3)c3ccccc3-c3ccc(N(c4ccc(-c5cccc6ccccc56)cc4)c4ccc5c(c4)C(c4ccccc4)(c4ccccc4)c4ccccc4-5)cc32)cc1 ; c1ccc(C2(c3ccccc3)c3ccccc3-c3ccc(N(c4ccc(-c5ccc6ccccc6c5)cc4)c4ccc5c(c4)C(c4ccccc4)(c4ccccc4)c4ccccc4-5)cc32)cc1 ; CC1(C)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21]

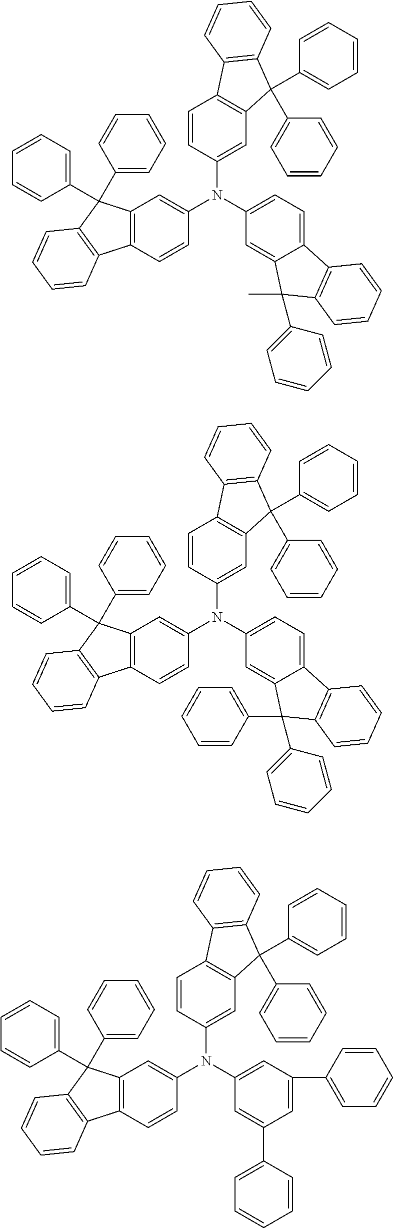 [SMILES: CC1(c2ccccc2)c2ccccc2-c2ccc(N(c3ccc4c(c3)C(c3ccccc3)(c3ccccc3)c3ccccc3-4)c3ccc4c(c3)C(c3ccccc3)(c3ccccc3)c3ccccc3-4)cc21 ; c1ccc(C2(c3ccccc3)c3ccccc3-c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc32)cc1 ; c1ccc(-c2cc(-c3ccccc3)cc(N(c3ccc4c(c3)C(c3ccccc3)(c3ccccc3)c3ccccc3-4)c3ccc4c(c3)C(c3ccccc3)(c3ccccc3)c3ccccc3-4)c2)cc1]

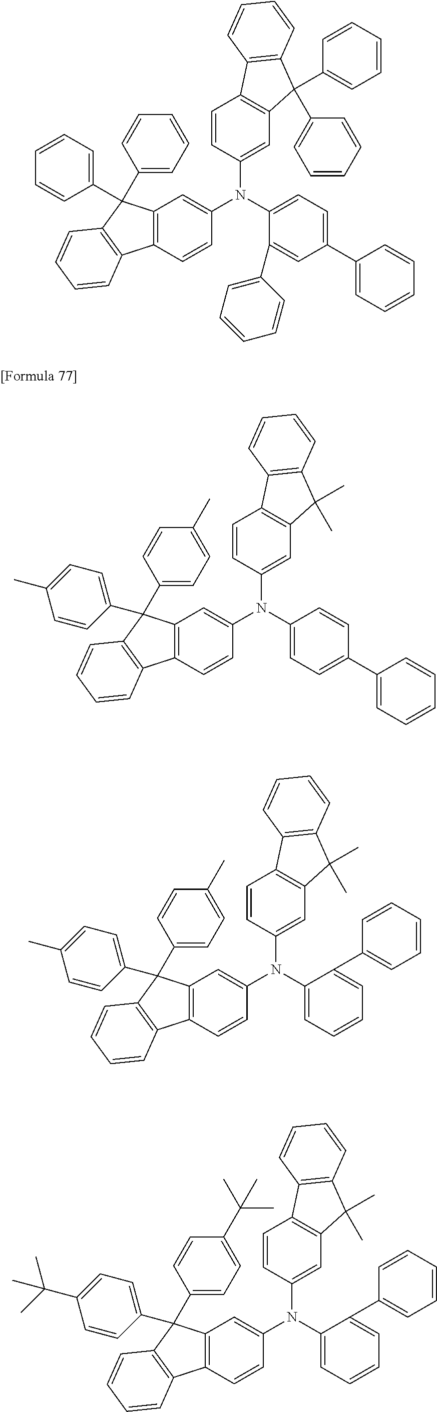 [SMILES: c1ccc(-c2ccc(N(c3ccc4c(c3)C(c3ccccc3)(c3ccccc3)c3ccccc3-4)c3ccc4c(c3)C(c3ccccc3)(c3ccccc3)c3ccccc3-4)c(-c3ccccc3)c2)cc1 ; Cc1ccc(C2(c3ccc(C)cc3)c3ccccc3-c3ccc(N(c4ccc(-c5ccccc5)cc4)c4ccc5c(c4)C(C)(C)c4ccccc4-5)cc32)cc1 ; Cc1ccc(C2(c3ccc(C)cc3)c3ccccc3-c3ccc(N(c4ccc5c(c4)C(C)(C)c4ccccc4-5)c4ccccc4-c4ccccc4)cc32)cc1 ; CC(C)(C)c1ccc(C2(c3ccc(C(C)(C)C)cc3)c3ccccc3-c3ccc(N(c4ccc5c(c4)C(C)(C)c4ccccc4-5)c4ccccc4-c4ccccc4)cc32)cc1]

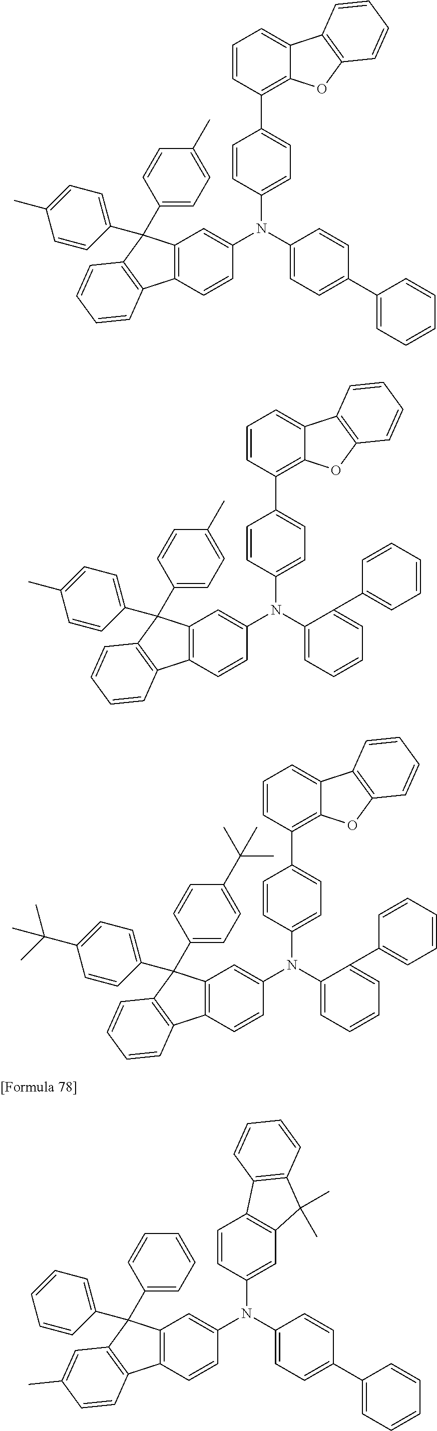

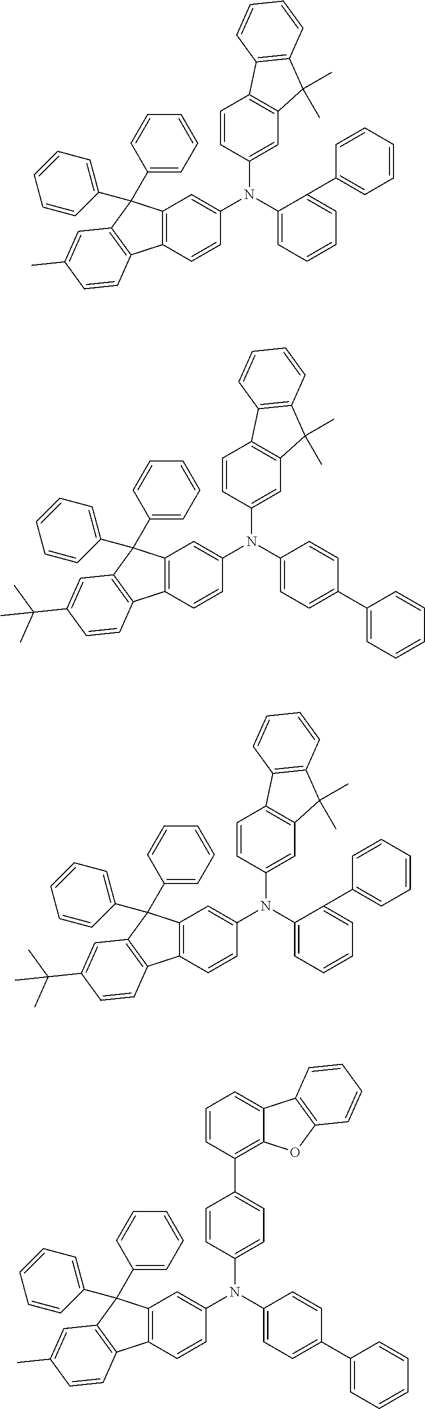 [SMILES: Cc1ccc2c(c1)C(c1ccccc1)(c1ccccc1)c1cc(N(c3ccc4c(c3)C(C)(C)c3ccccc3-4)c3ccccc3-c3ccccc3)ccc1-2 ; CC(C)(C)c1ccc2c(c1)C(c1ccccc1)(c1ccccc1)c1cc(N(c3ccc(-c4ccccc4)cc3)c3ccc4c(c3)C(C)(C)c3ccccc3-4)ccc1-2 ; CC(C)(C)c1ccc2c(c1)C(c1ccccc1)(c1ccccc1)c1cc(N(c3ccc4c(c3)C(C)(C)c3ccccc3-4)c3ccccc3-c3ccccc3)ccc1-2 ; Cc1ccc2c(c1)C(c1ccccc1)(c1ccccc1)c1cc(N(c3ccc(-c4ccccc4)cc3)c3ccc(-c4cccc5c4oc4ccccc45)cc3)ccc1-2]

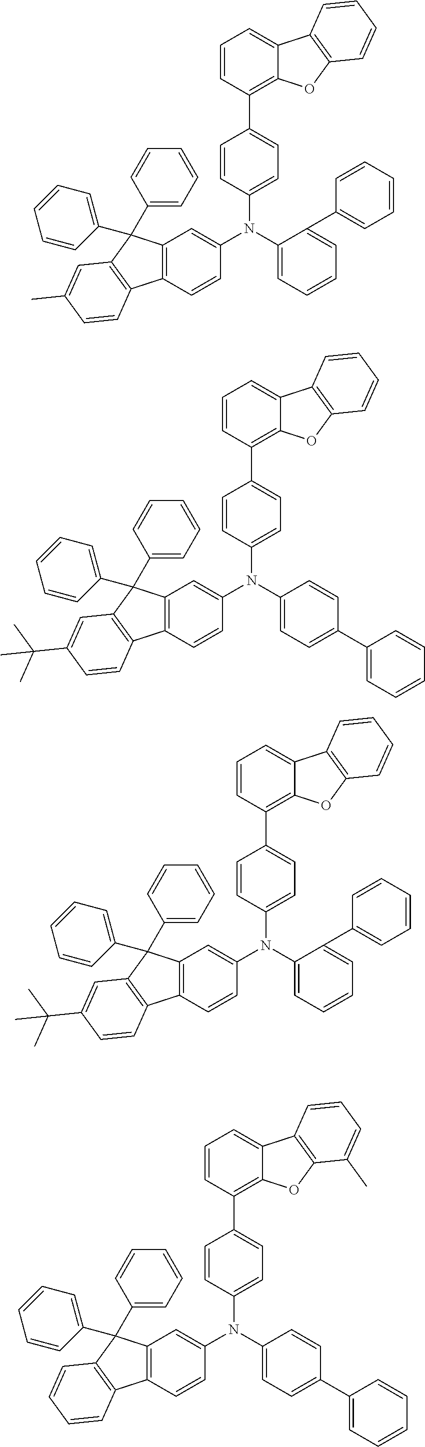

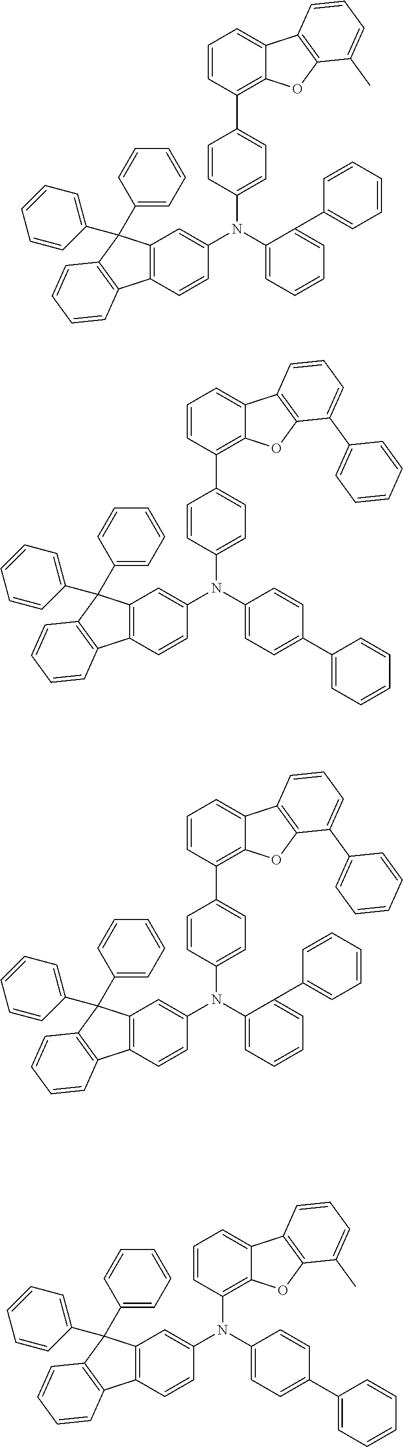 [SMILES: Cc1cccc2c1oc1c(-c3ccc(N(c4ccc5c(c4)C(c4ccccc4)(c4ccccc4)c4ccccc4-5)c4ccccc4-c4ccccc4)cc3)cccc12 ; c1ccc(-c2ccc(N(c3ccc(-c4cccc5c4oc4c(-c6ccccc6)cccc45)cc3)c3ccc4c(c3)C(c3ccccc3)(c3ccccc3)c3ccccc3-4)cc2)cc1 ; c1ccc(-c2ccccc2N(c2ccc(-c3cccc4c3oc3c(-c5ccccc5)cccc34)cc2)c2ccc3c(c2)C(c2ccccc2)(c2ccccc2)c2ccccc2-3)cc1 ; Cc1cccc2c1oc1c(N(c3ccc(-c4ccccc4)cc3)c3ccc4c(c3)C(c3ccccc3)(c3ccccc3)c3ccccc3-4)cccc12]

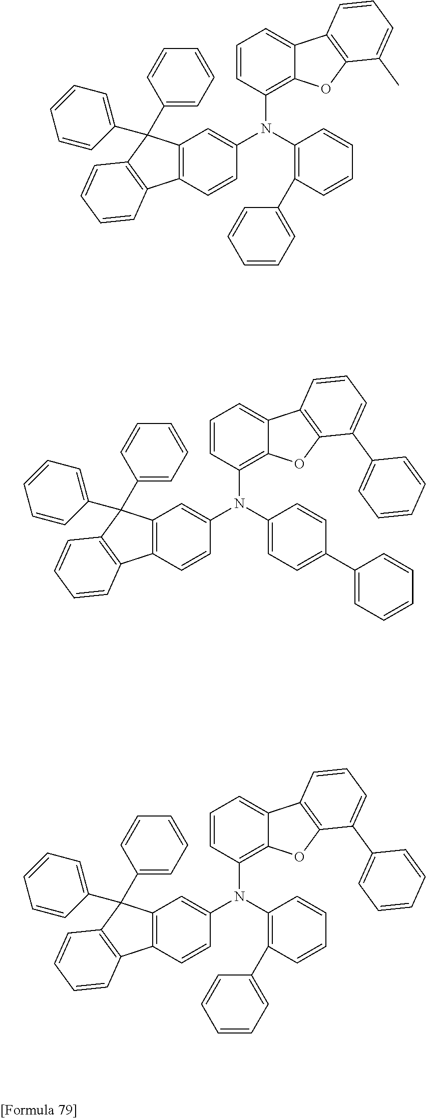 [SMILES: Cc1cccc2c1oc1c(N(c3ccc4c(c3)C(c3ccccc3)(c3ccccc3)c3ccccc3-4)c3ccccc3-c3ccccc3)cccc12 ; c1ccc(-c2ccc(N(c3ccc4c(c3)C(c3ccccc3)(c3ccccc3)c3ccccc3-4)c3cccc4c3oc3c(-c5ccccc5)cccc34)cc2)cc1 ; c1ccc(-c2ccccc2N(c2ccc3c(c2)C(c2ccccc2)(c2ccccc2)c2ccccc2-3)c2cccc3c2oc2c(-c4ccccc4)cccc23)cc1]

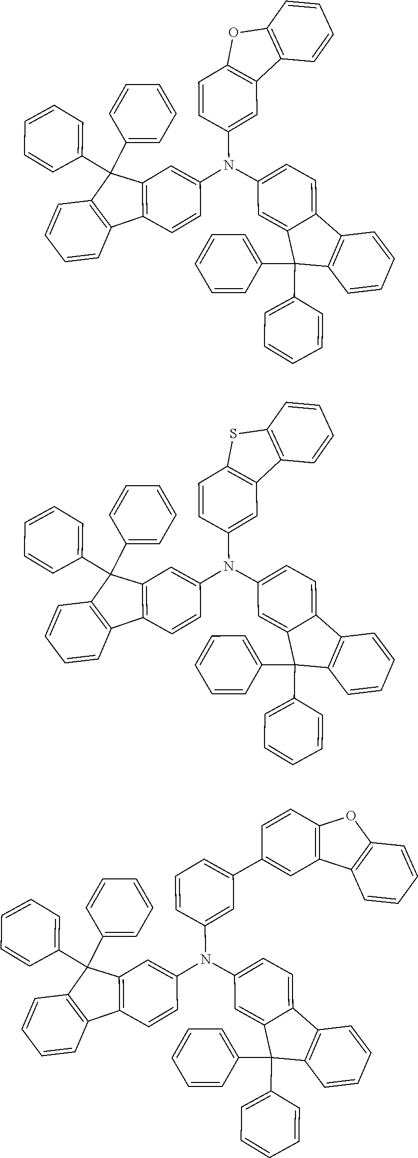

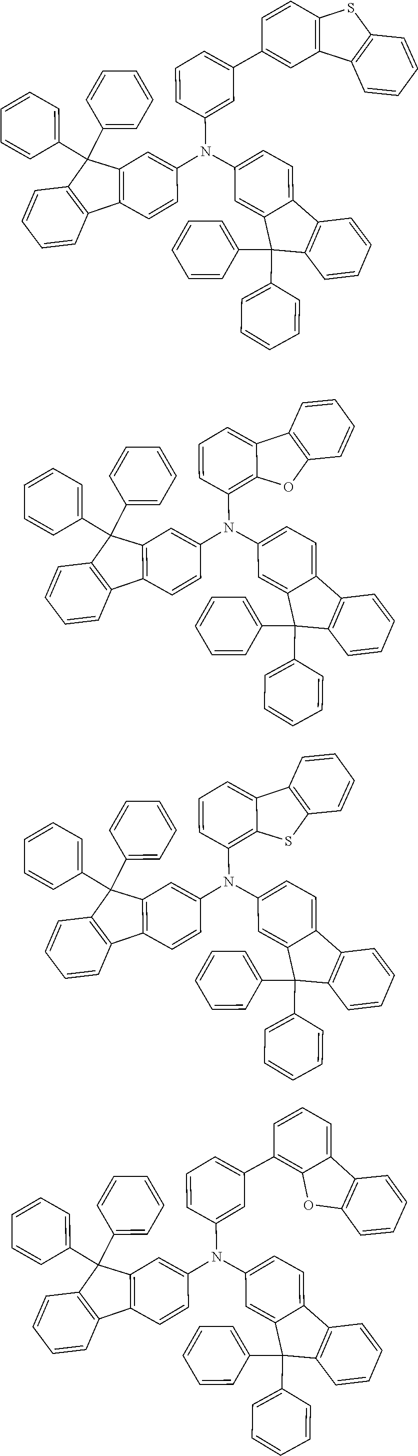

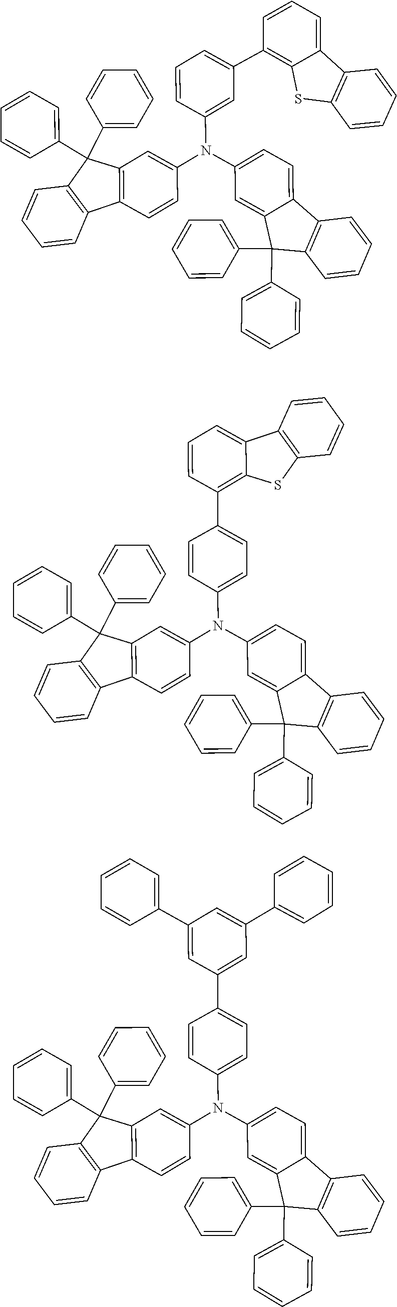

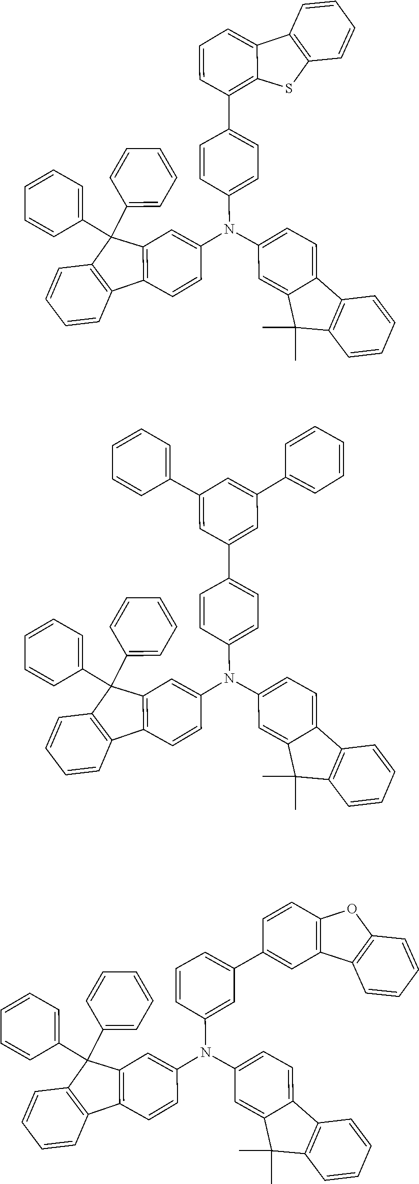 [SMILES: CC1(C)c2ccccc2-c2ccc(N(c3ccc(-c4cccc5c4sc4ccccc45)cc3)c3ccc4c(c3)C(c3ccccc3)(c3ccccc3)c3ccccc3-4)cc21 ; CC1(C)c2ccccc2-c2ccc(N(c3ccc(-c4cc(-c5ccccc5)cc(-c5ccccc5)c4)cc3)c3ccc4c(c3)C(c3ccccc3)(c3ccccc3)c3ccccc3-4)cc21 ; CC1(C)c2ccccc2-c2ccc(N(c3cccc(-c4ccc5oc6ccccc6c5c4)c3)c3ccc4c(c3)C(c3ccccc3)(c3ccccc3)c3ccccc3-4)cc21]

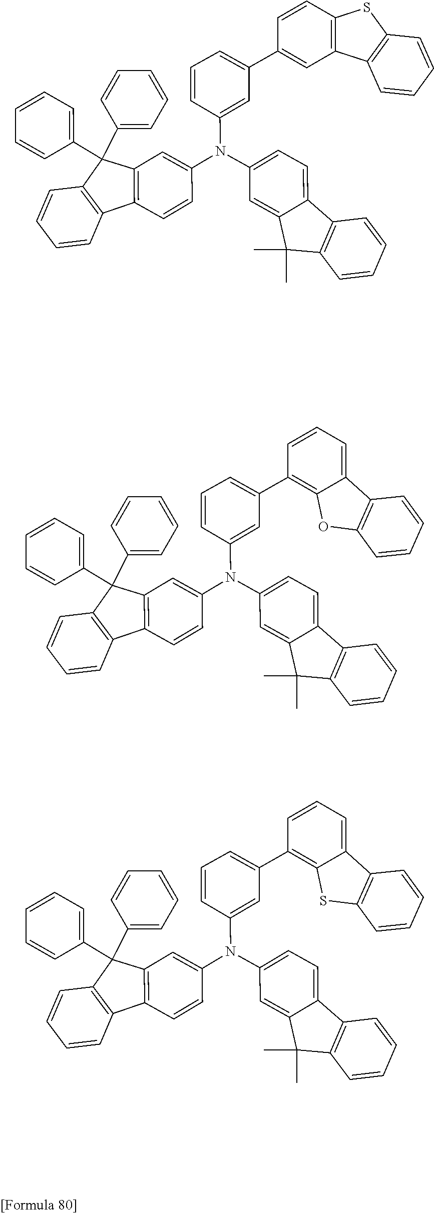 [SMILES: CC1(C)c2ccccc2-c2ccc(N(c3cccc(-c4ccc5sc6ccccc6c5c4)c3)c3ccc4c(c3)C(c3ccccc3)(c3ccccc3)c3ccccc3-4)cc21 ; CC1(C)c2ccccc2-c2ccc(N(c3cccc(-c4cccc5c4oc4ccccc45)c3)c3ccc4c(c3)C(c3ccccc3)(c3ccccc3)c3ccccc3-4)cc21 ; CC1(C)c2ccccc2-c2ccc(N(c3cccc(-c4cccc5c4sc4ccccc45)c3)c3ccc4c(c3)C(c3ccccc3)(c3ccccc3)c3ccccc3-4)cc21]

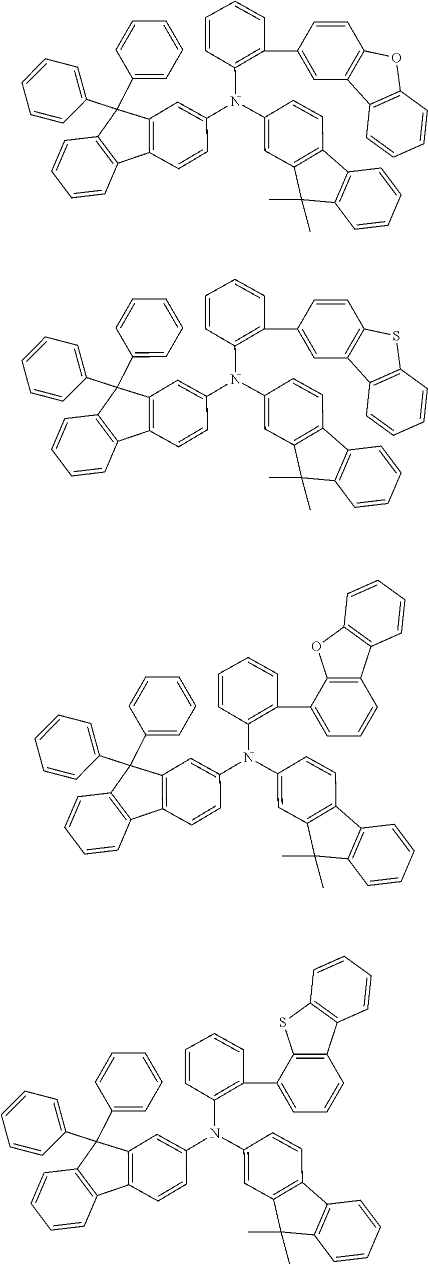 [SMILES: CC1(C)c2ccccc2-c2ccc(N(c3ccc4c(c3)C(c3ccccc3)(c3ccccc3)c3ccccc3-4)c3ccccc3-c3ccc4oc5ccccc5c4c3)cc21 ; CC1(C)c2ccccc2-c2ccc(N(c3ccc4c(c3)C(c3ccccc3)(c3ccccc3)c3ccccc3-4)c3ccccc3-c3ccc4sc5ccccc5c4c3)cc21 ; CC1(C)c2ccccc2-c2ccc(N(c3ccc4c(c3)C(c3ccccc3)(c3ccccc3)c3ccccc3-4)c3ccccc3-c3cccc4c3oc3ccccc34)cc21 ; CC1(C)c2ccccc2-c2ccc(N(c3ccc4c(c3)C(c3ccccc3)(c3ccccc3)c3ccccc3-4)c3ccccc3-c3cccc4c3sc3ccccc34)cc21]

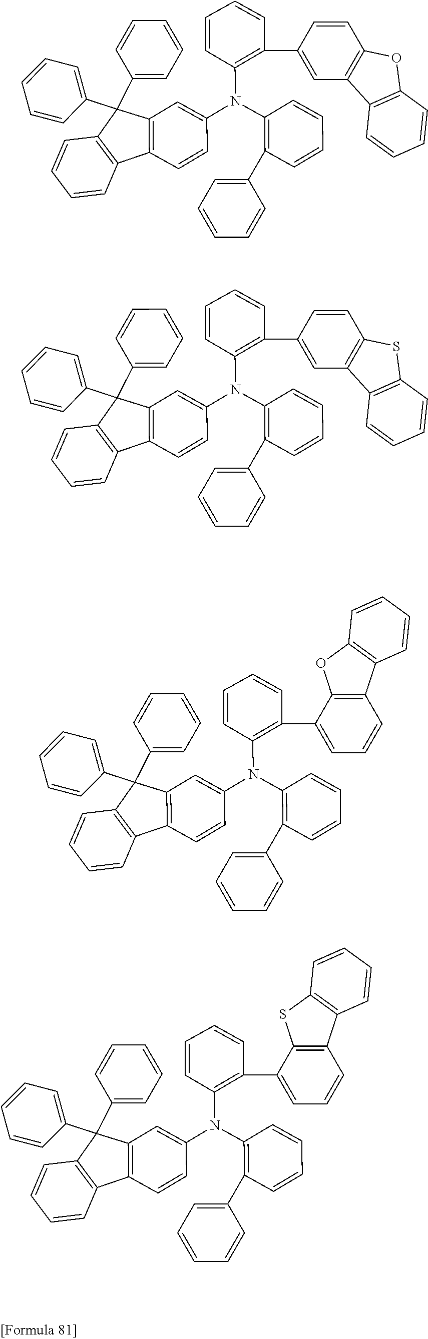 [SMILES: c1ccc(-c2ccccc2N(c2ccc3c(c2)C(c2ccccc2)(c2ccccc2)c2ccccc2-3)c2ccccc2-c2ccc3oc4ccccc4c3c2)cc1 ; c1ccc(-c2ccccc2N(c2ccc3c(c2)C(c2ccccc2)(c2ccccc2)c2ccccc2-3)c2ccccc2-c2ccc3sc4ccccc4c3c2)cc1 ; c1ccc(-c2ccccc2N(c2ccc3c(c2)C(c2ccccc2)(c2ccccc2)c2ccccc2-3)c2ccccc2-c2cccc3c2oc2ccccc23)cc1 ; c1ccc(-c2ccccc2N(c2ccc3c(c2)C(c2ccccc2)(c2ccccc2)c2ccccc2-3)c2ccccc2-c2cccc3c2sc2ccccc23)cc1]

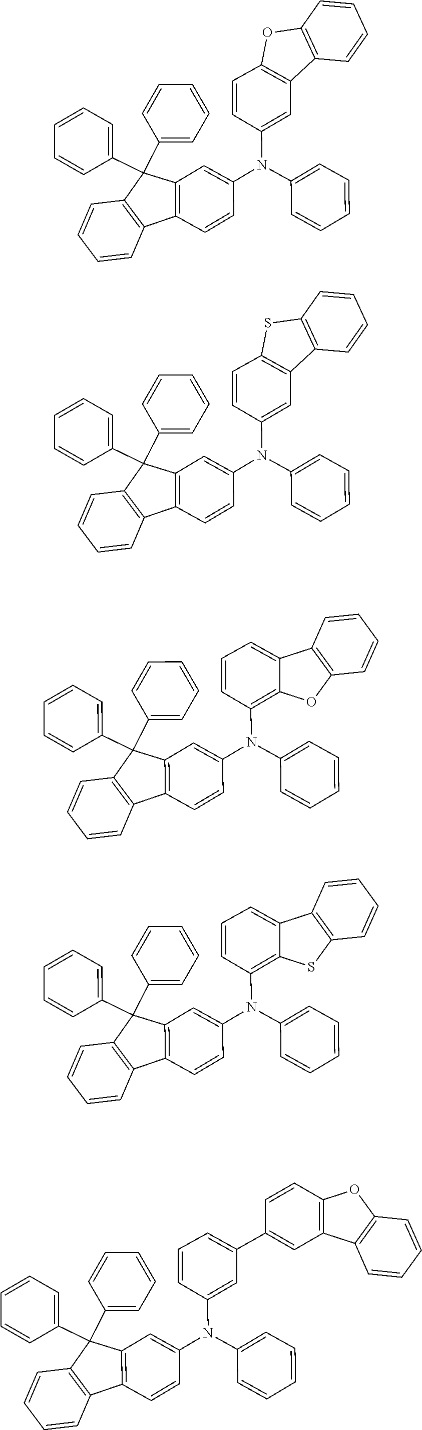 [SMILES: c1ccc(N(c2ccc3c(c2)C(c2ccccc2)(c2ccccc2)c2ccccc2-3)c2ccc3oc4ccccc4c3c2)cc1 ; c1ccc(N(c2ccc3c(c2)C(c2ccccc2)(c2ccccc2)c2ccccc2-3)c2ccc3sc4ccccc4c3c2)cc1 ; c1ccc(N(c2ccc3c(c2)C(c2ccccc2)(c2ccccc2)c2ccccc2-3)c2cccc3c2oc2ccccc23)cc1 ; c1ccc(N(c2ccc3c(c2)C(c2ccccc2)(c2ccccc2)c2ccccc2-3)c2cccc3c2sc2ccccc23)cc1 ; c1ccc(N(c2cccc(-c3ccc4oc5ccccc5c4c3)c2)c2ccc3c(c2)C(c2ccccc2)(c2ccccc2)c2ccccc2-3)cc1]

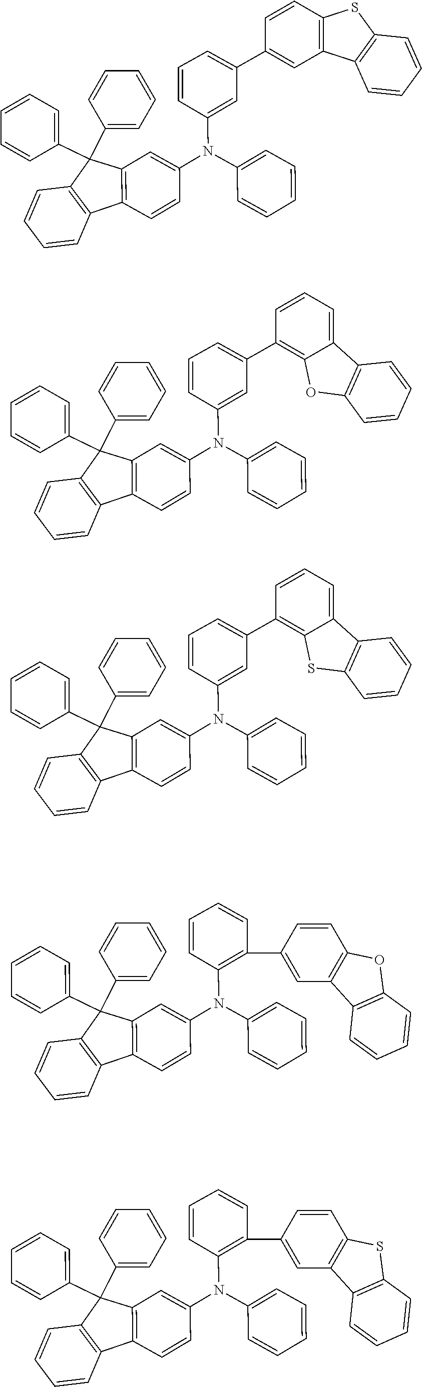 [SMILES: c1ccc(N(c2cccc(-c3ccc4sc5ccccc5c4c3)c2)c2ccc3c(c2)C(c2ccccc2)(c2ccccc2)c2ccccc2-3)cc1 ; c1ccc(N(c2cccc(-c3cccc4c3oc3ccccc34)c2)c2ccc3c(c2)C(c2ccccc2)(c2ccccc2)c2ccccc2-3)cc1 ; c1ccc(N(c2cccc(-c3cccc4c3sc3ccccc34)c2)c2ccc3c(c2)C(c2ccccc2)(c2ccccc2)c2ccccc2-3)cc1 ; c1ccc(N(c2ccc3c(c2)C(c2ccccc2)(c2ccccc2)c2ccccc2-3)c2ccccc2-c2ccc3oc4ccccc4c3c2)cc1 ; c1ccc(N(c2ccc3c(c2)C(c2ccccc2)(c2ccccc2)c2ccccc2-3)c2ccccc2-c2ccc3sc4ccccc4c3c2)cc1]

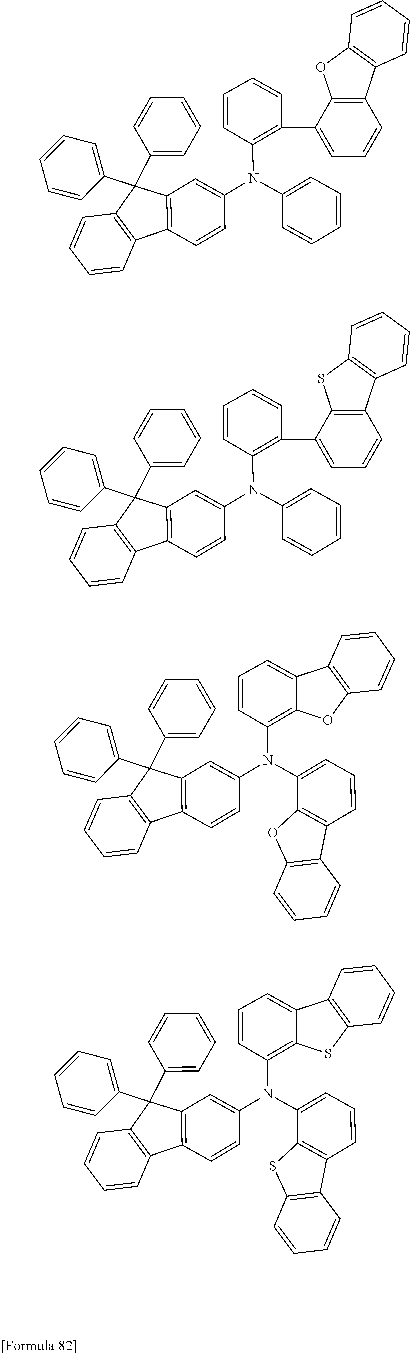 [SMILES: c1ccc(N(c2ccc3c(c2)C(c2ccccc2)(c2ccccc2)c2ccccc2-3)c2ccccc2-c2cccc3c2oc2ccccc23)cc1 ; c1ccc(N(c2ccc3c(c2)C(c2ccccc2)(c2ccccc2)c2ccccc2-3)c2ccccc2-c2cccc3c2sc2ccccc23)cc1 ; c1ccc(C2(c3ccccc3)c3ccccc3-c3ccc(N(c4cccc5c4oc4ccccc45)c4cccc5c4oc4ccccc45)cc32)cc1 ; c1ccc(C2(c3ccccc3)c3ccccc3-c3ccc(N(c4cccc5c4sc4ccccc45)c4cccc5c4sc4ccccc45)cc32)cc1]

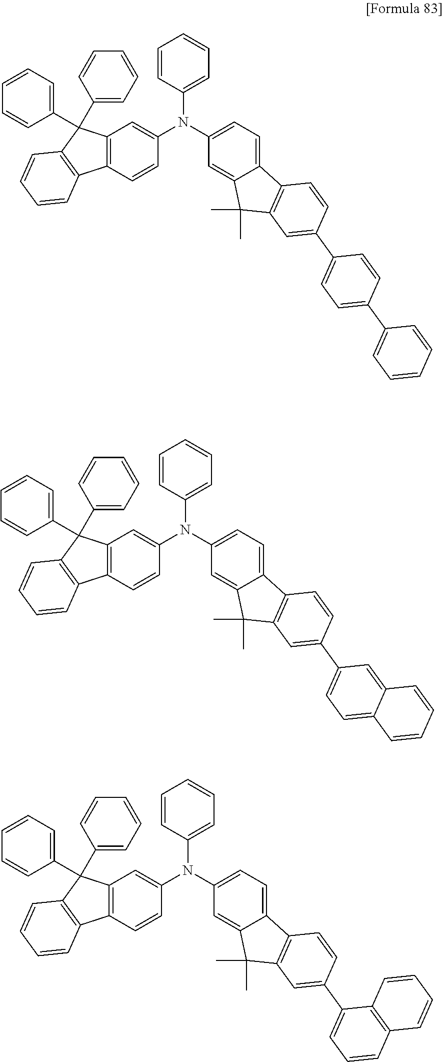 [SMILES: CC1(C)c2cc(-c3ccc(-c4ccccc4)cc3)ccc2-c2ccc(N(c3ccccc3)c3ccc4c(c3)C(c3ccccc3)(c3ccccc3)c3ccccc3-4)cc21 ; CC1(C)c2cc(-c3ccc4ccccc4c3)ccc2-c2ccc(N(c3ccccc3)c3ccc4c(c3)C(c3ccccc3)(c3ccccc3)c3ccccc3-4)cc21 ; CC1(C)c2cc(-c3cccc4ccccc34)ccc2-c2ccc(N(c3ccccc3)c3ccc4c(c3)C(c3ccccc3)(c3ccccc3)c3ccccc3-4)cc21]

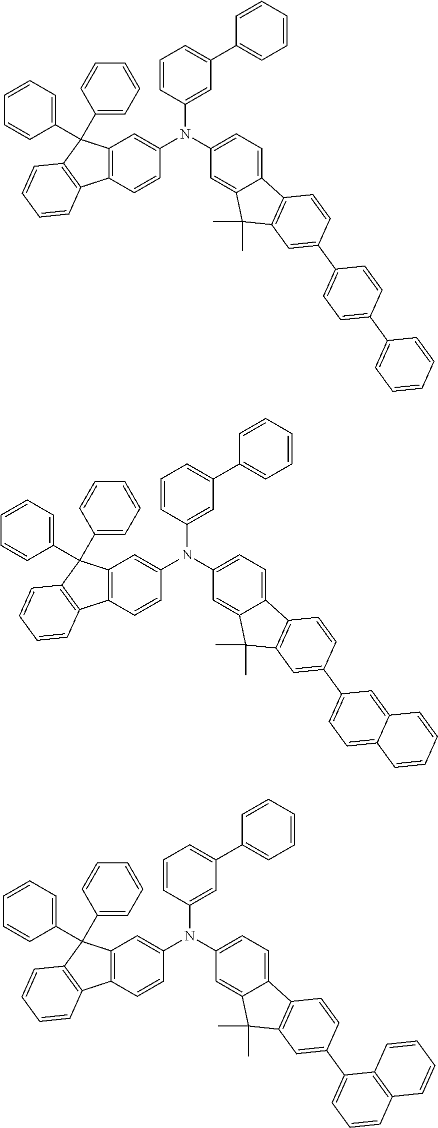 [SMILES: CC1(C)c2cc(-c3ccc(-c4ccccc4)cc3)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3ccc4ccccc4c3)ccc2-c2ccc(N(c3cccc(-c4ccccc4)c3)c3ccc4c(c3)C(c3ccccc3)(c3ccccc3)c3ccccc3-4)cc21 ; CC1(C)c2cc(-c3cccc4ccccc34)ccc2-c2ccc(N(c3cccc(-c4ccccc4)c3)c3ccc4c(c3)C(c3ccccc3)(c3ccccc3)c3ccccc3-4)cc21]

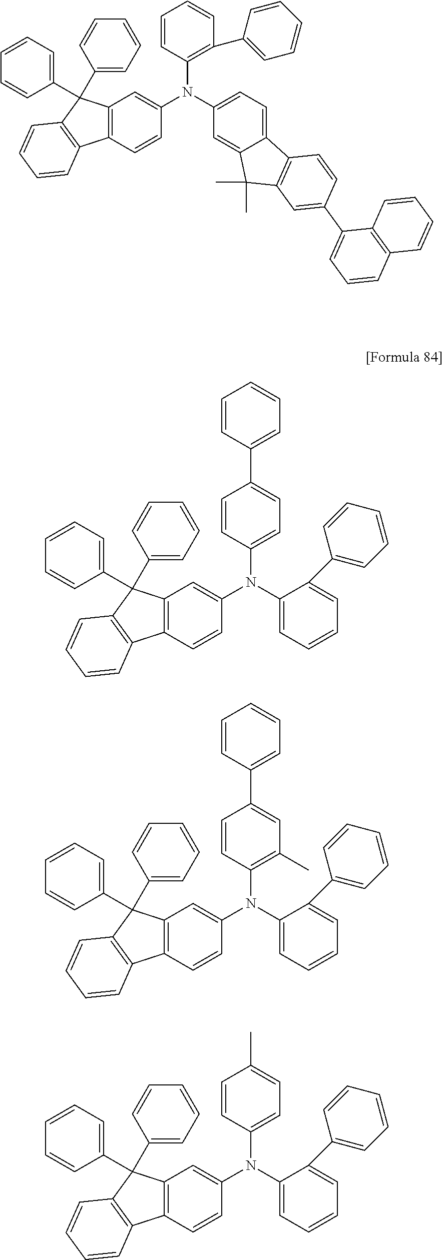 [SMILES: CC1(C)c2cc(-c3cccc4ccccc34)ccc2-c2ccc(N(c3ccc4c(c3)C(c3ccccc3)(c3ccccc3)c3ccccc3-4)c3ccccc3-c3ccccc3)cc21 ; c1ccc(-c2ccc(N(c3ccc4c(c3)C(c3ccccc3)(c3ccccc3)c3ccccc3-4)c3ccccc3-c3ccccc3)cc2)cc1 ; Cc1cc(-c2ccccc2)ccc1N(c1ccc2c(c1)C(c1ccccc1)(c1ccccc1)c1ccccc1-2)c1ccccc1-c1ccccc1 ; Cc1ccc(N(c2ccc3c(c2)C(c2ccccc2)(c2ccccc2)c2ccccc2-3)c2ccccc2-c2ccccc2)cc1]

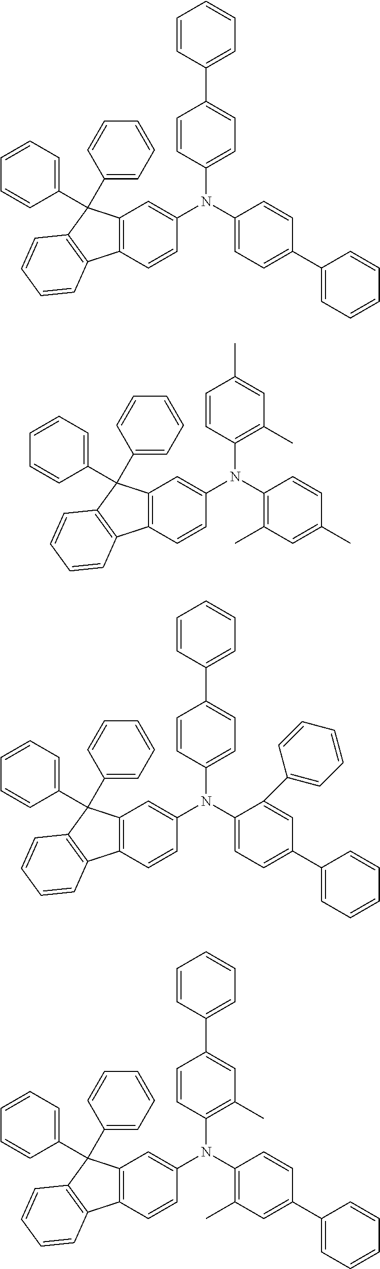 [SMILES: c1ccc(-c2ccc(N(c3ccc(-c4ccccc4)cc3)c3ccc4c(c3)C(c3ccccc3)(c3ccccc3)c3ccccc3-4)cc2)cc1 ; Cc1ccc(N(c2ccc3c(c2)C(c2ccccc2)(c2ccccc2)c2ccccc2-3)c2ccc(C)cc2C)c(C)c1 ; c1ccc(-c2ccc(N(c3ccc4c(c3)C(c3ccccc3)(c3ccccc3)c3ccccc3-4)c3ccc(-c4ccccc4)cc3-c3ccccc3)cc2)cc1 ; Cc1cc(-c2ccccc2)ccc1N(c1ccc2c(c1)C(c1ccccc1)(c1ccccc1)c1ccccc1-2)c1ccc(-c2ccccc2)cc1C]

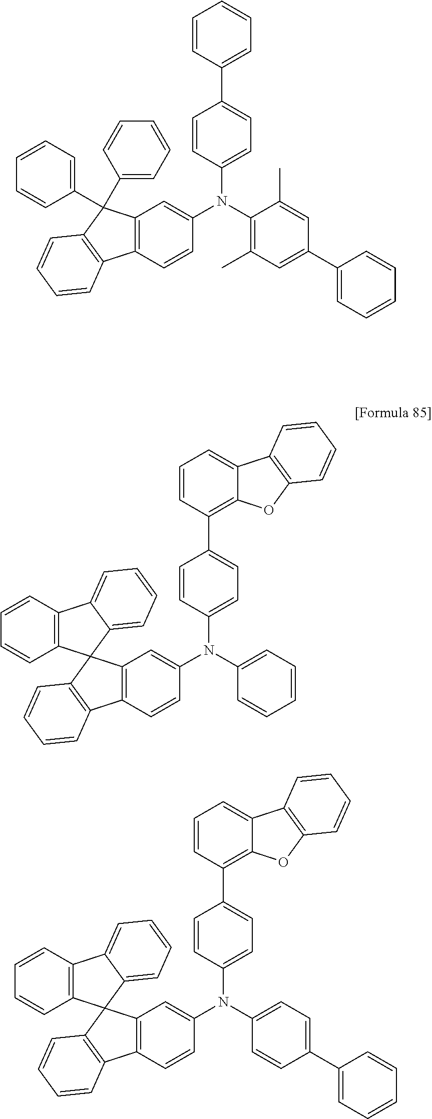 [SMILES: Cc1cc(-c2ccccc2)cc(C)c1N(c1ccc(-c2ccccc2)cc1)c1ccc2c(c1)C(c1ccccc1)(c1ccccc1)c1ccccc1-2 ; c1ccc(N(c2ccc(-c3cccc4c3oc3ccccc34)cc2)c2ccc3c(c2)C2(c4ccccc4-c4ccccc42)c2ccccc2-3)cc1 ; c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1]

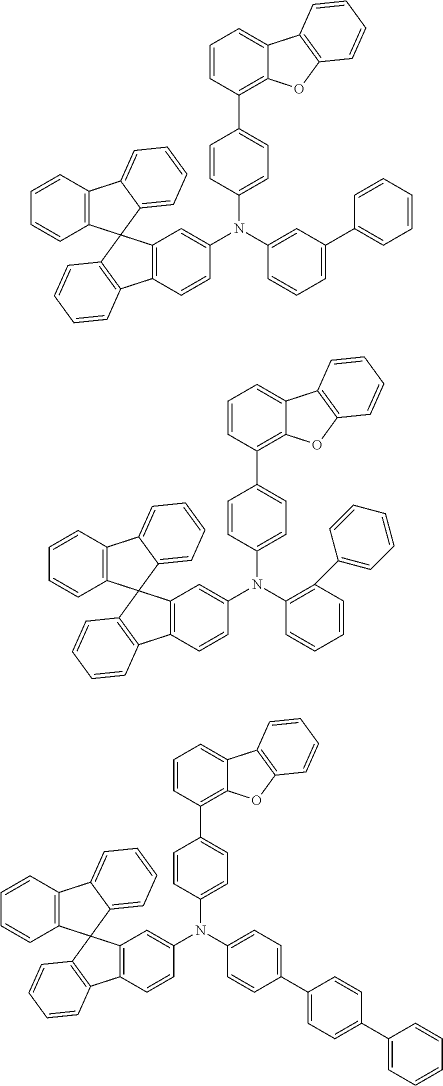 [SMILES: c1ccc(-c2cccc(N(c3ccc(-c4cccc5c4oc4ccccc45)cc3)c3ccc4c(c3)C3(c5ccccc5-c5ccccc53)c3ccccc3-4)c2)cc1 ; c1ccc(-c2ccccc2N(c2ccc(-c3cccc4c3oc3ccccc34)cc2)c2ccc3c(c2)C2(c4ccccc4-c4ccccc42)c2ccccc2-3)cc1 ; c1ccc(-c2ccc(-c3ccc(N(c4ccc(-c5cccc6c5oc5ccccc56)cc4)c4ccc5c(c4)C4(c6ccccc6-c6ccccc64)c4ccccc4-5)cc3)cc2)cc1]

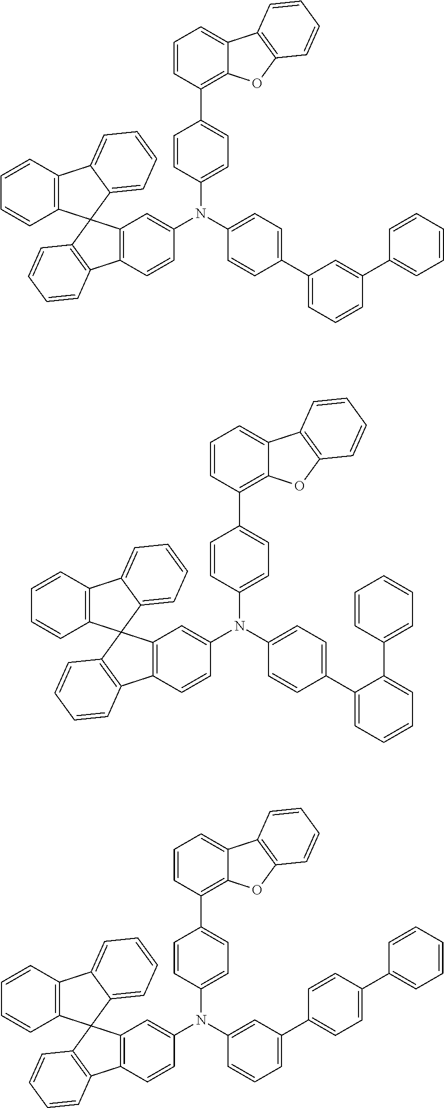 [SMILES: c1ccc(-c2cccc(-c3ccc(N(c4ccc(-c5cccc6c5oc5ccccc56)cc4)c4ccc5c(c4)C4(c6ccccc6-c6ccccc64)c4ccccc4-5)cc3)c2)cc1 ; c1ccc(-c2ccccc2-c2ccc(N(c3ccc(-c4cccc5c4oc4ccccc45)cc3)c3ccc4c(c3)C3(c5ccccc5-c5ccccc53)c3ccccc3-4)cc2)cc1 ; c1ccc(-c2ccc(-c3cccc(N(c4ccc(-c5cccc6c5oc5ccccc56)cc4)c4ccc5c(c4)C4(c6ccccc6-c6ccccc64)c4ccccc4-5)c3)cc2)cc1]

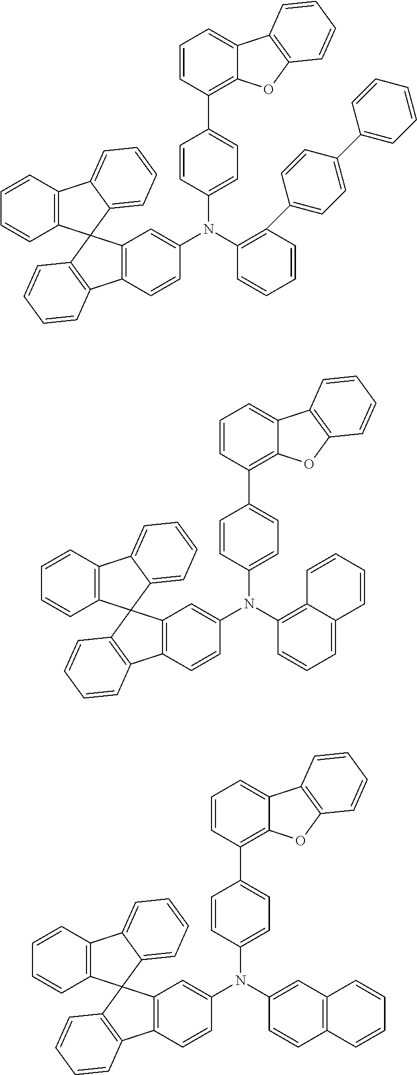 [SMILES: c1ccc(-c2ccc(-c3ccccc3N(c3ccc(-c4cccc5c4oc4ccccc45)cc3)c3ccc4c(c3)C3(c5ccccc5-c5ccccc53)c3ccccc3-4)cc2)cc1 ; c1ccc2c(c1)-c1ccccc1C21c2ccccc2-c2ccc(N(c3ccc(-c4cccc5c4oc4ccccc45)cc3)c3cccc4ccccc34)cc21 ; c1ccc2c(c1)-c1ccccc1C21c2ccccc2-c2ccc(N(c3ccc(-c4cccc5c4oc4ccccc45)cc3)c3ccc4ccccc4c3)cc21]

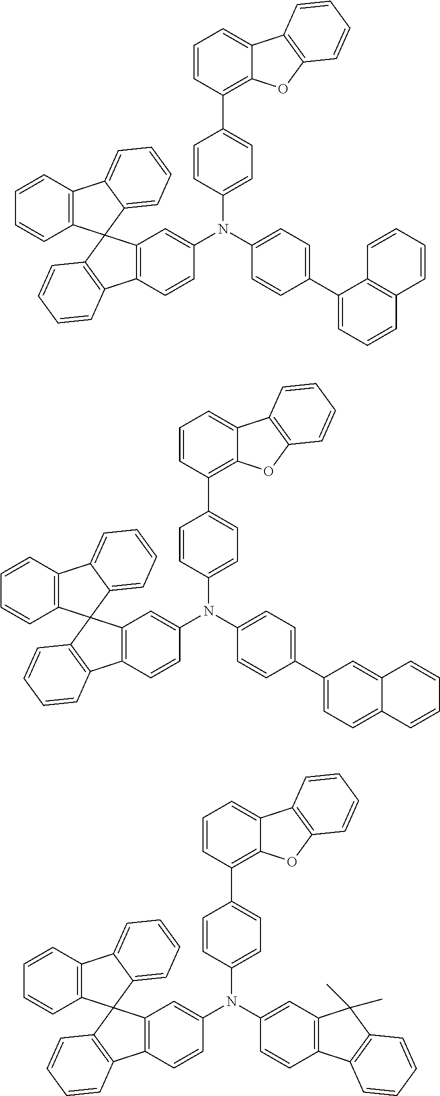 [SMILES: c1ccc2c(c1)-c1ccccc1C21c2ccccc2-c2ccc(N(c3ccc(-c4cccc5ccccc45)cc3)c3ccc(-c4cccc5c4oc4ccccc45)cc3)cc21 ; c1ccc2c(c1)-c1ccccc1C21c2ccccc2-c2ccc(N(c3ccc(-c4ccc5ccccc5c4)cc3)c3ccc(-c4cccc5c4oc4ccccc45)cc3)cc21 ; CC1(C)c2ccccc2-c2ccc(N(c3ccc(-c4cccc5c4oc4ccccc45)cc3)c3ccc4c(c3)C3(c5ccccc5-c5ccccc53)c3ccccc3-4)cc21]

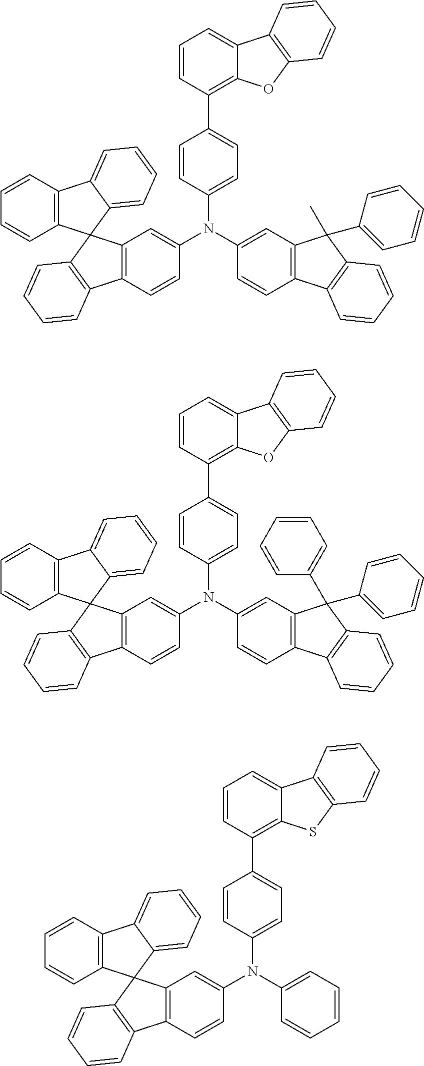 [SMILES: CC1(c2ccccc2)c2ccccc2-c2ccc(N(c3ccc(-c4cccc5c4oc4ccccc45)cc3)c3ccc4c(c3)C3(c5ccccc5-c5ccccc53)c3ccccc3-4)cc21 ; c1ccc(C2(c3ccccc3)c3ccccc3-c3ccc(N(c4ccc(-c5cccc6c5oc5ccccc56)cc4)c4ccc5c(c4)C4(c6ccccc6-c6ccccc64)c4ccccc4-5)cc32)cc1 ; c1ccc(N(c2ccc(-c3cccc4c3sc3ccccc34)cc2)c2ccc3c(c2)C2(c4ccccc4-c4ccccc42)c2ccccc2-3)cc1]

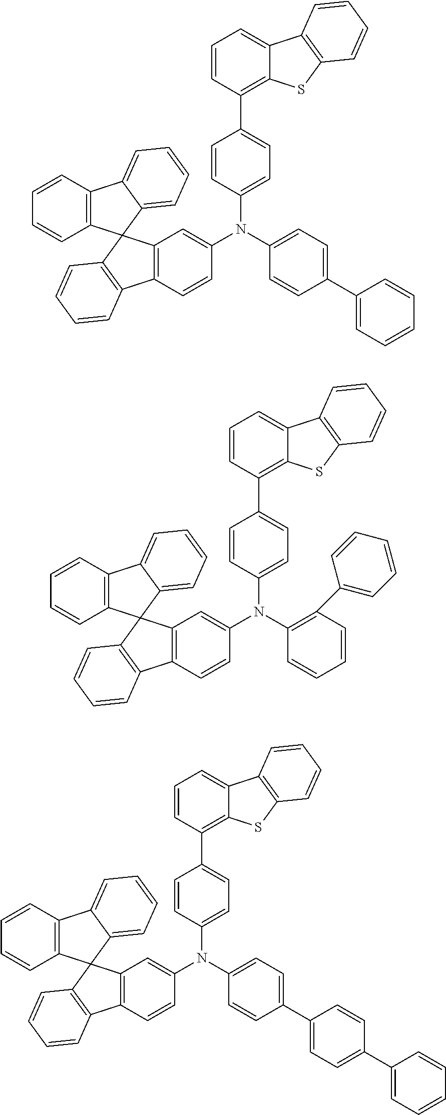

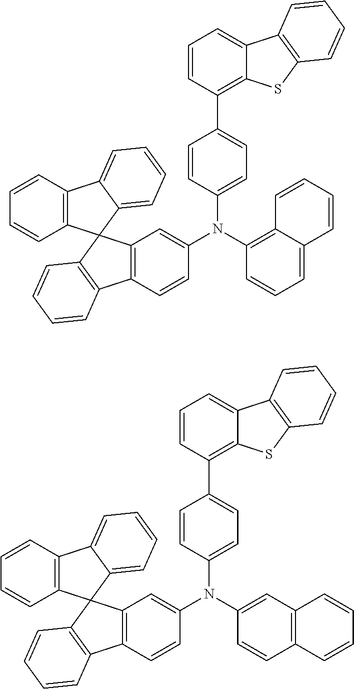 [SMILES: c1ccc2c(c1)-c1ccccc1C21c2ccccc2-c2ccc(N(c3ccc(-c4cccc5c4sc4ccccc45)cc3)c3cccc4ccccc34)cc21 ; c1ccc2c(c1)-c1ccccc1C21c2ccccc2-c2ccc(N(c3ccc(-c4cccc5c4sc4ccccc45)cc3)c3ccc4ccccc4c3)cc21]

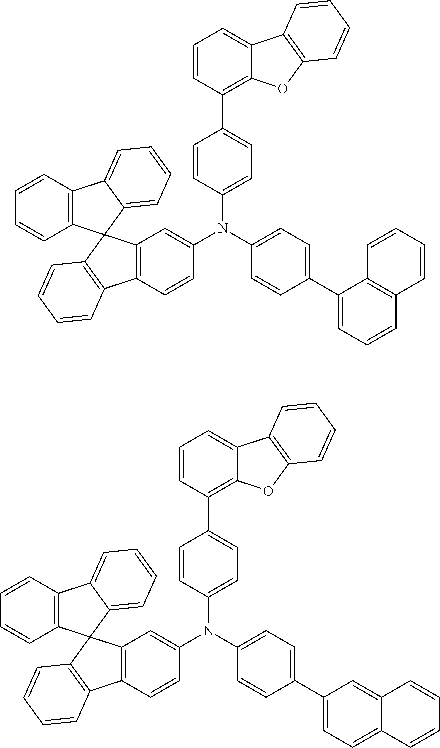 [SMILES: c1ccc2c(c1)-c1ccccc1C21c2ccccc2-c2ccc(N(c3ccc(-c4cccc5ccccc45)cc3)c3ccc(-c4cccc5c4oc4ccccc45)cc3)cc21 ; c1ccc2c(c1)-c1ccccc1C21c2ccccc2-c2ccc(N(c3ccc(-c4ccc5ccccc5c4)cc3)c3ccc(-c4cccc5c4oc4ccccc45)cc3)cc21]

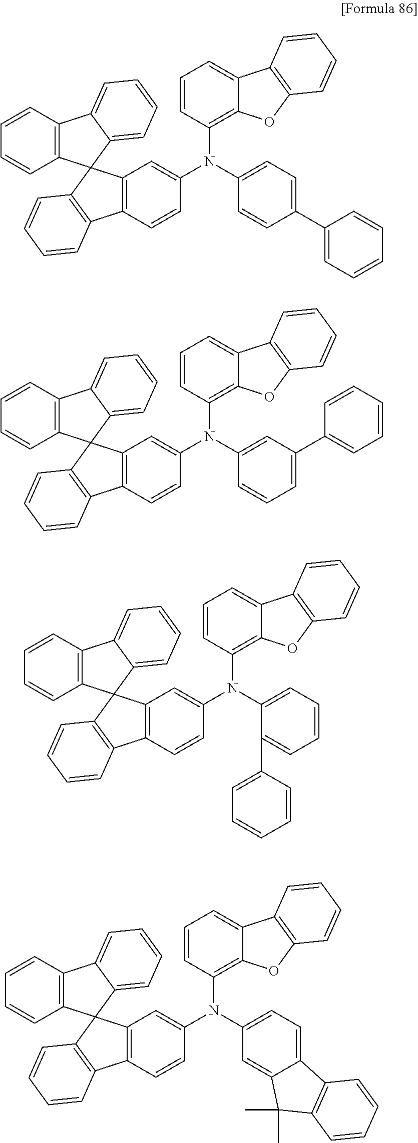 [SMILES: c1ccc(-c2ccc(N(c3ccc4c(c3)C3(c5ccccc5-c5ccccc53)c3ccccc3-4)c3cccc4c3oc3ccccc34)cc2)cc1 ; c1ccc(-c2cccc(N(c3ccc4c(c3)C3(c5ccccc5-c5ccccc53)c3ccccc3-4)c3cccc4c3oc3ccccc34)c2)cc1 ; c1ccc(-c2ccccc2N(c2ccc3c(c2)C2(c4ccccc4-c4ccccc42)c2ccccc2-3)c2cccc3c2oc2ccccc23)cc1 ; CC1(C)c2ccccc2-c2ccc(N(c3ccc4c(c3)C3(c5ccccc5-c5ccccc53)c3ccccc3-4)c3cccc4c3oc3ccccc34)cc21]

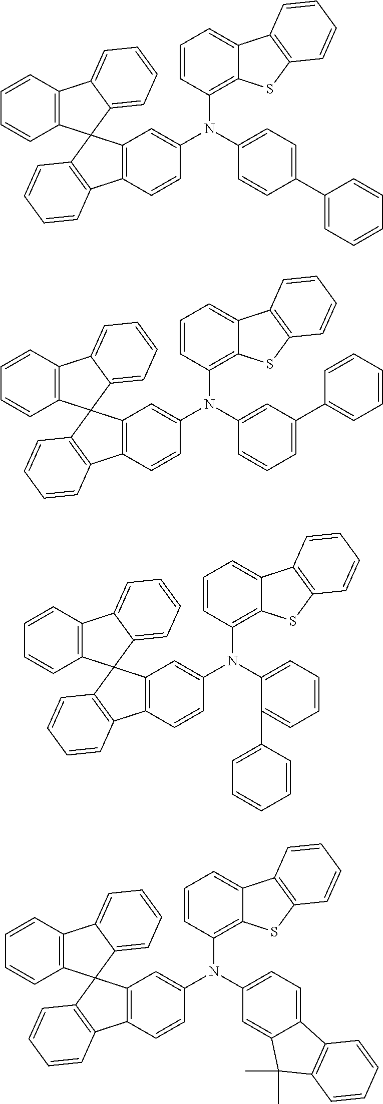

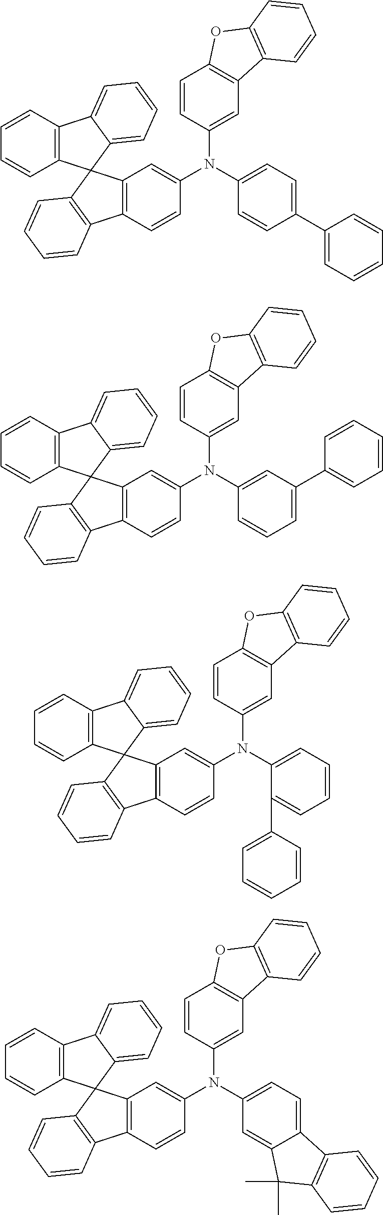

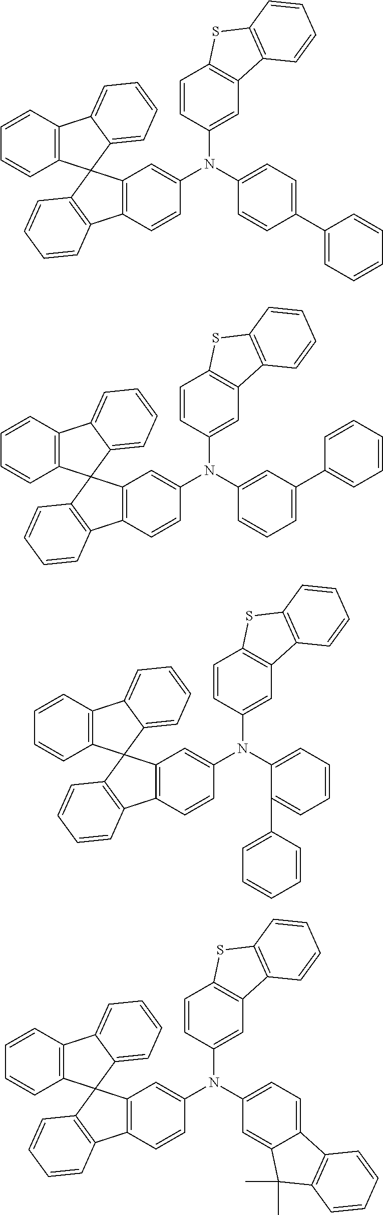

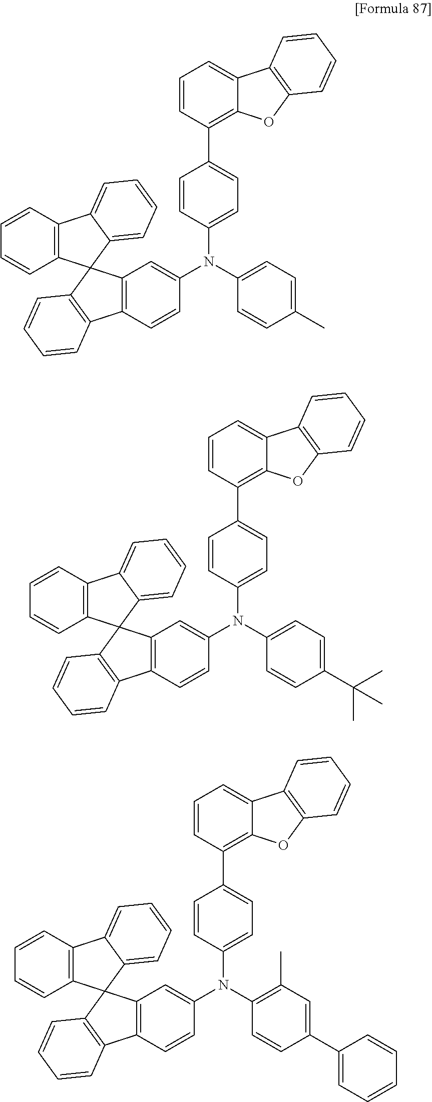

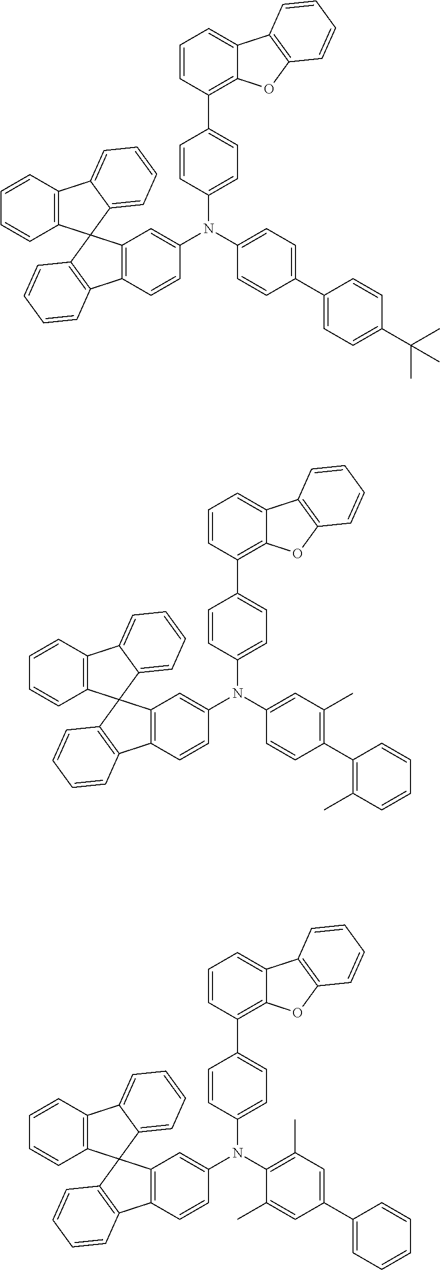 [SMILES: CC(C)(C)c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; Cc1ccccc1-c1ccc(N(c2ccc(-c3cccc4c3oc3ccccc34)cc2)c2ccc3c(c2)C2(c4ccccc4-c4ccccc42)c2ccccc2-3)cc1C ; Cc1cc(-c2ccccc2)cc(C)c1N(c1ccc(-c2cccc3c2oc2ccccc23)cc1)c1ccc2c(c1)C1(c3ccccc3-c3ccccc31)c1ccccc1-2]

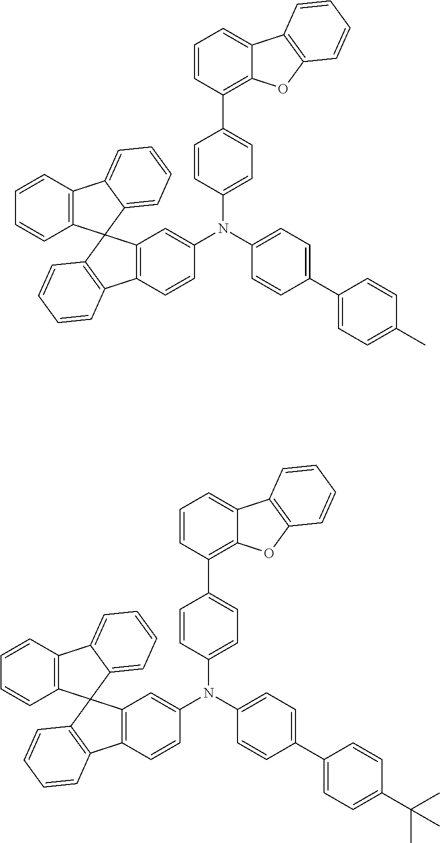 [SMILES: Cc1ccc(-c2ccc(N(c3ccc(-c4cccc5c4oc4ccccc45)cc3)c3ccc4c(c3)C3(c5ccccc5-c5ccccc53)c3ccccc3-4)cc2)cc1 ; CC(C)(C)c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1]

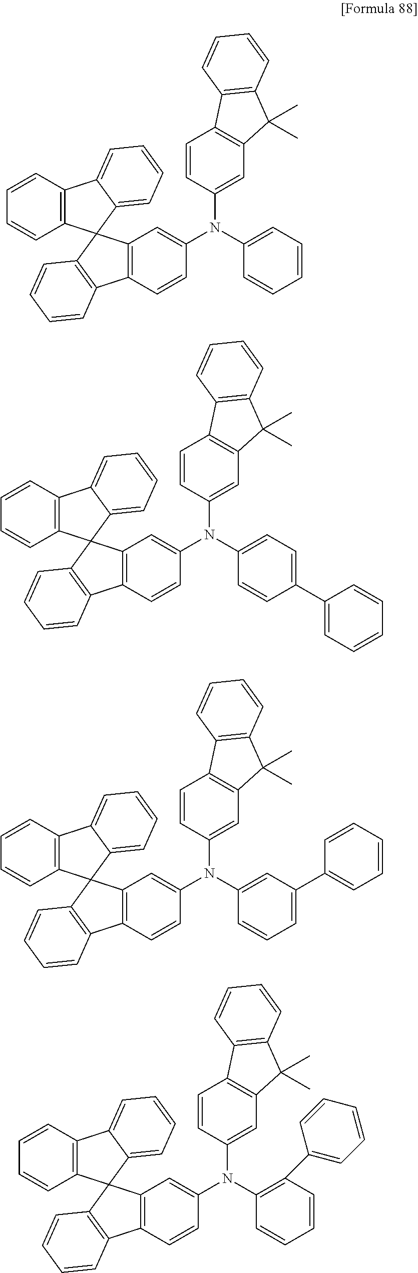

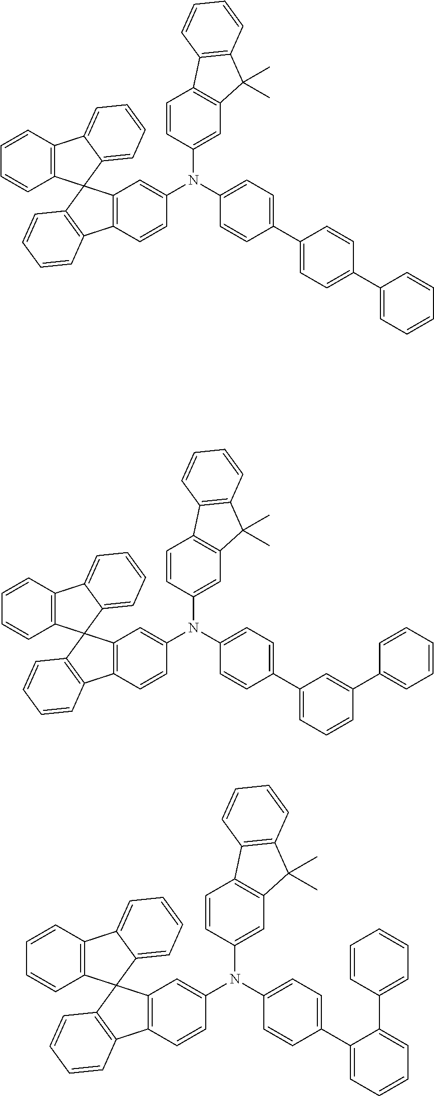 [SMILES: CC1(C)c2ccccc2-c2ccc(N(c3ccc(-c4ccc(-c5ccccc5)cc4)cc3)c3ccc4c(c3)C3(c5ccccc5-c5ccccc53)c3ccccc3-4)cc21 ; CC1(C)c2ccccc2-c2ccc(N(c3ccc(-c4cccc(-c5ccccc5)c4)cc3)c3ccc4c(c3)C3(c5ccccc5-c5ccccc53)c3ccccc3-4)cc21 ; CC1(C)c2ccccc2-c2ccc(N(c3ccc(-c4ccccc4-c4ccccc4)cc3)c3ccc4c(c3)C3(c5ccccc5-c5ccccc53)c3ccccc3-4)cc21]

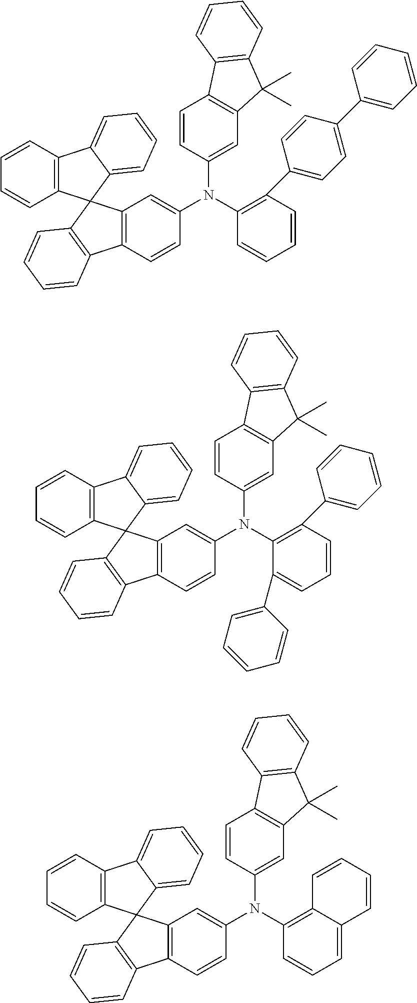 [SMILES: CC1(C)c2ccccc2-c2ccc(N(c3ccc4c(c3)C3(c5ccccc5-c5ccccc53)c3ccccc3-4)c3ccccc3-c3ccc(-c4ccccc4)cc3)cc21 ; CC1(C)c2ccccc2-c2ccc(N(c3ccc4c(c3)C3(c5ccccc5-c5ccccc53)c3ccccc3-4)c3c(-c4ccccc4)cccc3-c3ccccc3)cc21 ; CC1(C)c2ccccc2-c2ccc(N(c3ccc4c(c3)C3(c5ccccc5-c5ccccc53)c3ccccc3-4)c3cccc4ccccc34)cc21]

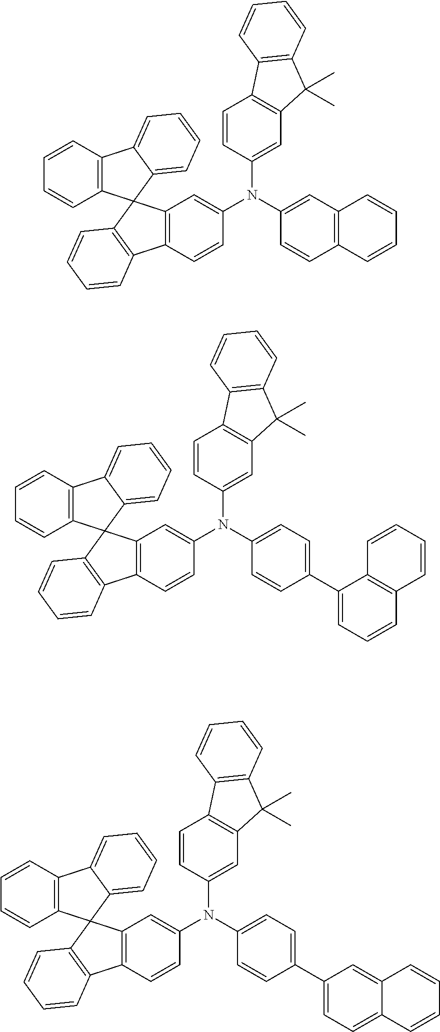 [SMILES: CC1(C)c2ccccc2-c2ccc(N(c3ccc4c(c3)C3(c5ccccc5-c5ccccc53)c3ccccc3-4)c3ccc4ccccc4c3)cc21 ; CC1(C)c2ccccc2-c2ccc(N(c3ccc(-c4cccc5ccccc45)cc3)c3ccc4c(c3)C3(c5ccccc5-c5ccccc53)c3ccccc3-4)cc21 ; CC1(C)c2ccccc2-c2ccc(N(c3ccc(-c4ccc5ccccc5c4)cc3)c3ccc4c(c3)C3(c5ccccc5-c5ccccc53)c3ccccc3-4)cc21]

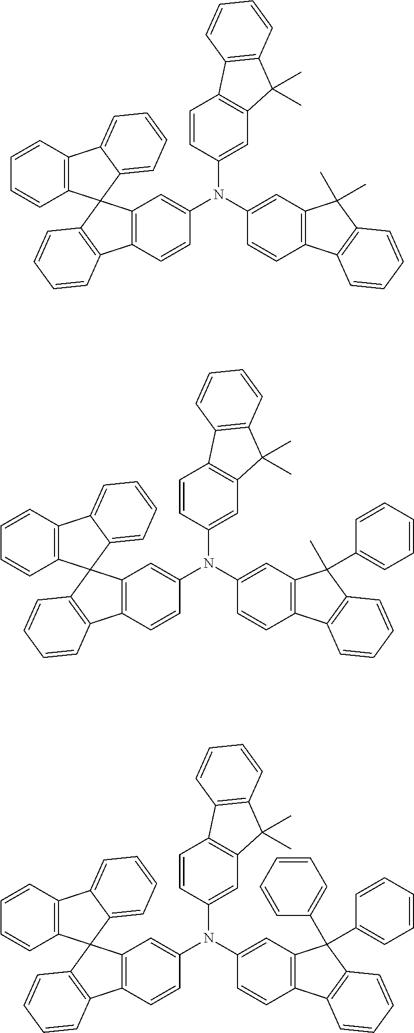 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(c3ccccc3)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc21]

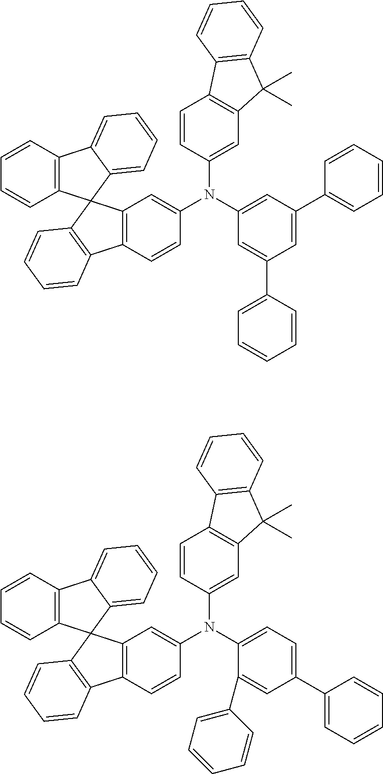 [SMILES: CC1(C)c2ccccc2-c2ccc(N(c3cc(-c4ccccc4)cc(-c4ccccc4)c3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21]

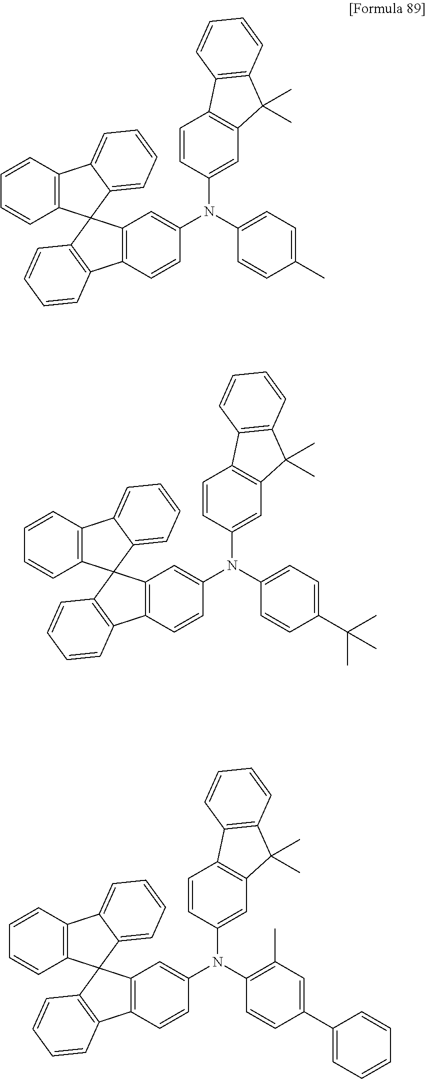 [SMILES: Cc1ccc(N(c2ccc3c(c2)C(C)(C)c2ccccc2-3)c2ccc3c(c2)C2(c4ccccc4-c4ccccc42)c2ccccc2-3)cc1 ; CC(C)(C)c1ccc(N(c2ccc3c(c2)C(C)(C)c2ccccc2-3)c2ccc3c(c2)C2(c4ccccc4-c4ccccc42)c2ccccc2-3)cc1 ; Cc1cc(-c2ccccc2)ccc1N(c1ccc2c(c1)C(C)(C)c1ccccc1-2)c1ccc2c(c1)C1(c3ccccc3-c3ccccc31)c1ccccc1-2]

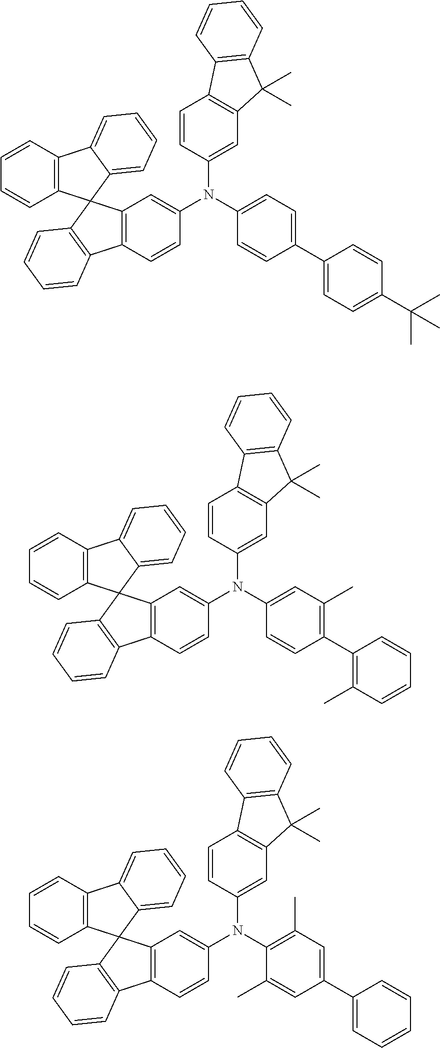 [SMILES: CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; Cc1ccccc1-c1ccc(N(c2ccc3c(c2)C(C)(C)c2ccccc2-3)c2ccc3c(c2)C2(c4ccccc4-c4ccccc42)c2ccccc2-3)cc1C ; Cc1cc(-c2ccccc2)cc(C)c1N(c1ccc2c(c1)C(C)(C)c1ccccc1-2)c1ccc2c(c1)C1(c3ccccc3-c3ccccc31)c1ccccc1-2]

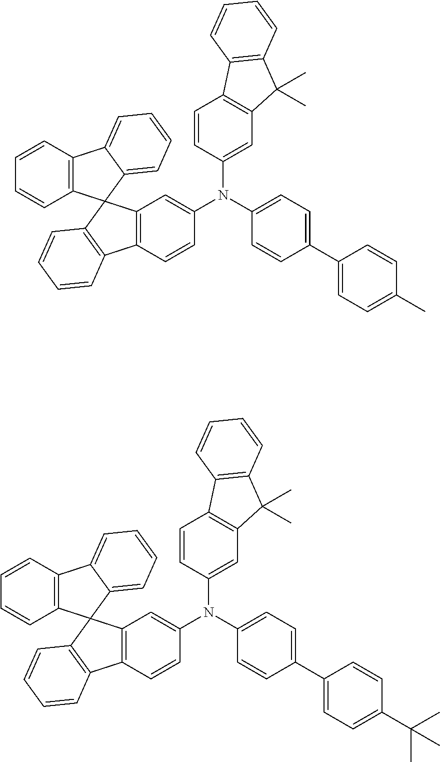 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; CC(C)(C)c1ccc(-c2ccc(N(c3ccc4c(c3)C(C)(C)c3ccccc3-4)c3ccc4c(c3)C3(c5ccccc5-c5ccccc53)c3ccccc3-4)cc2)cc1]

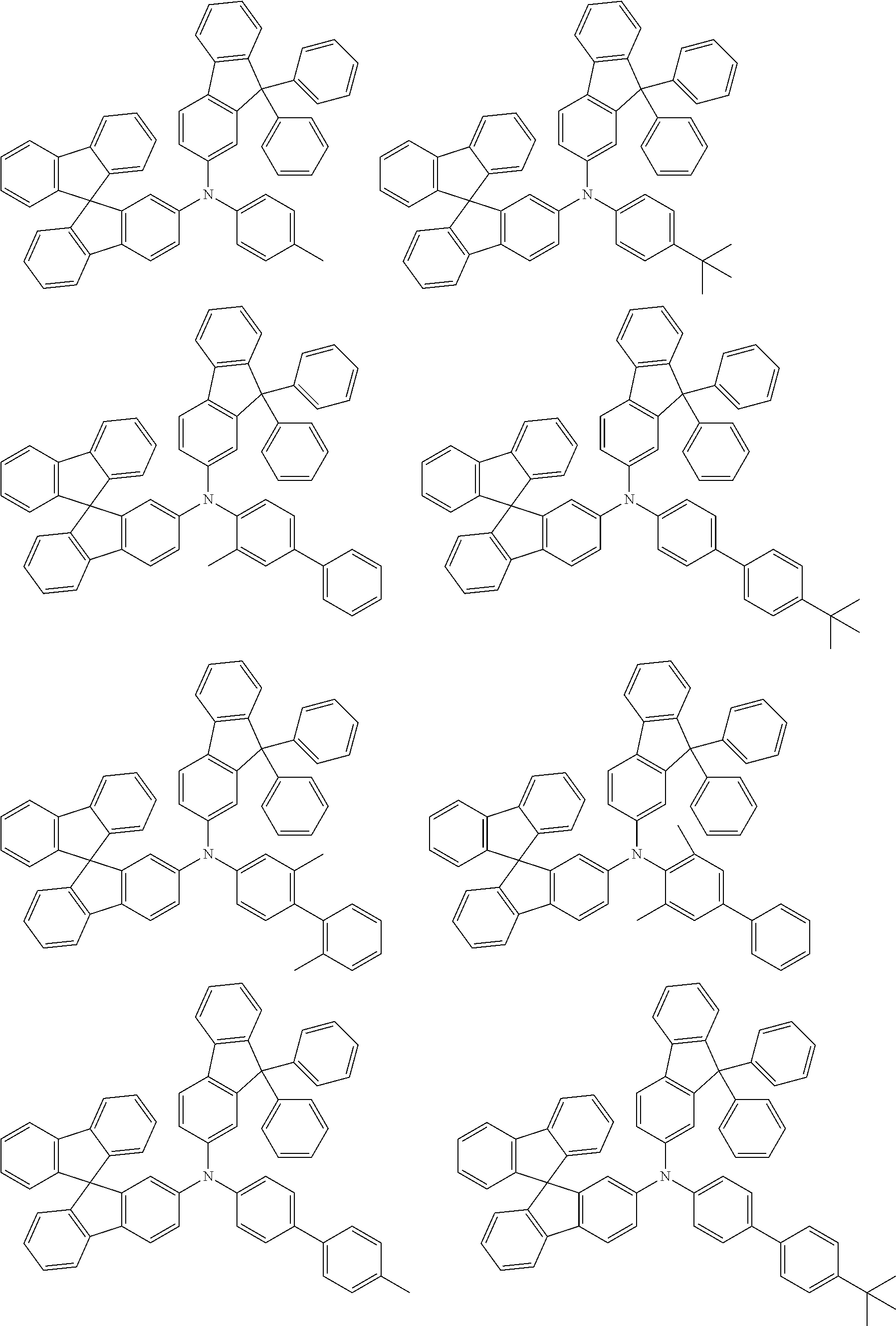

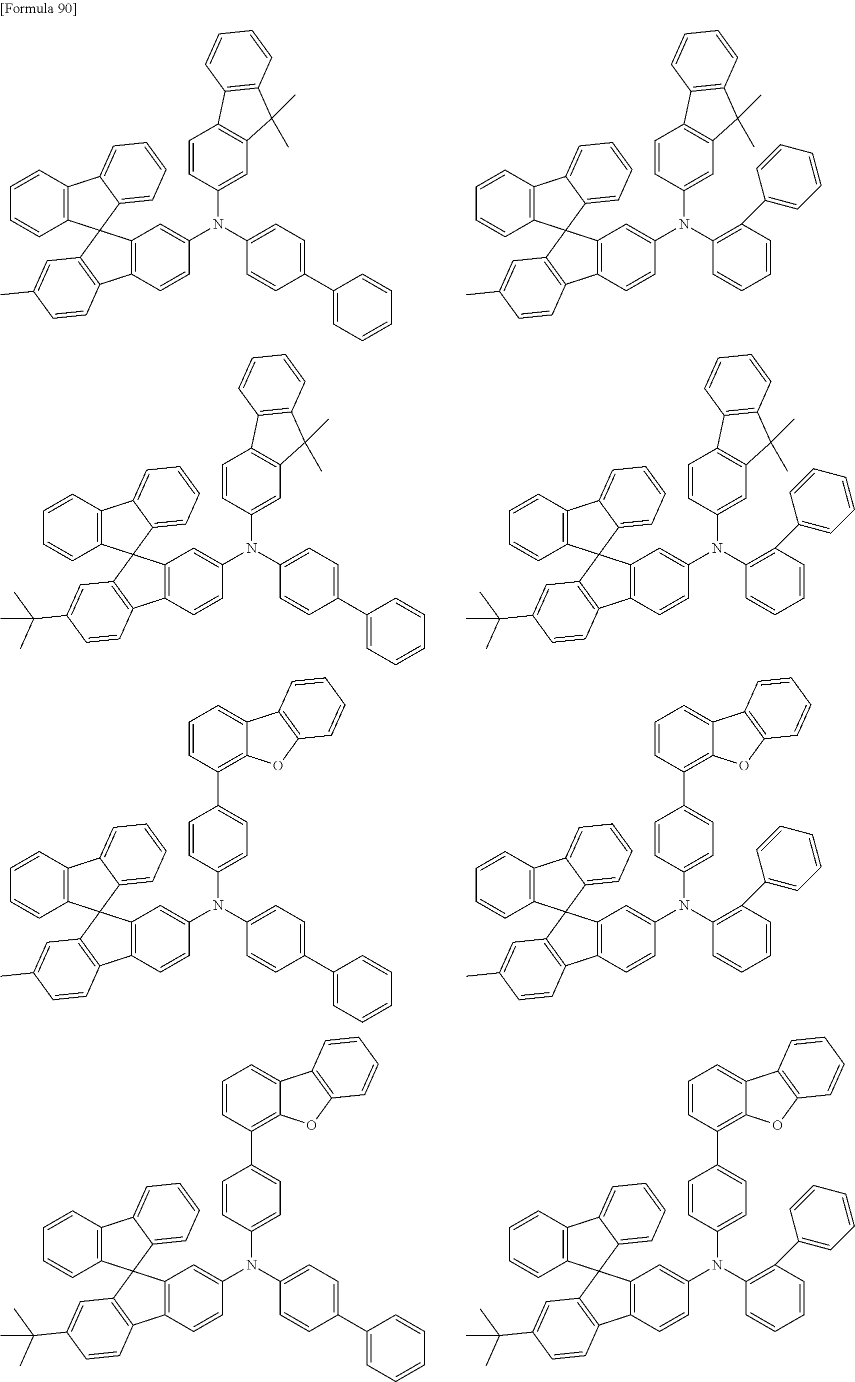

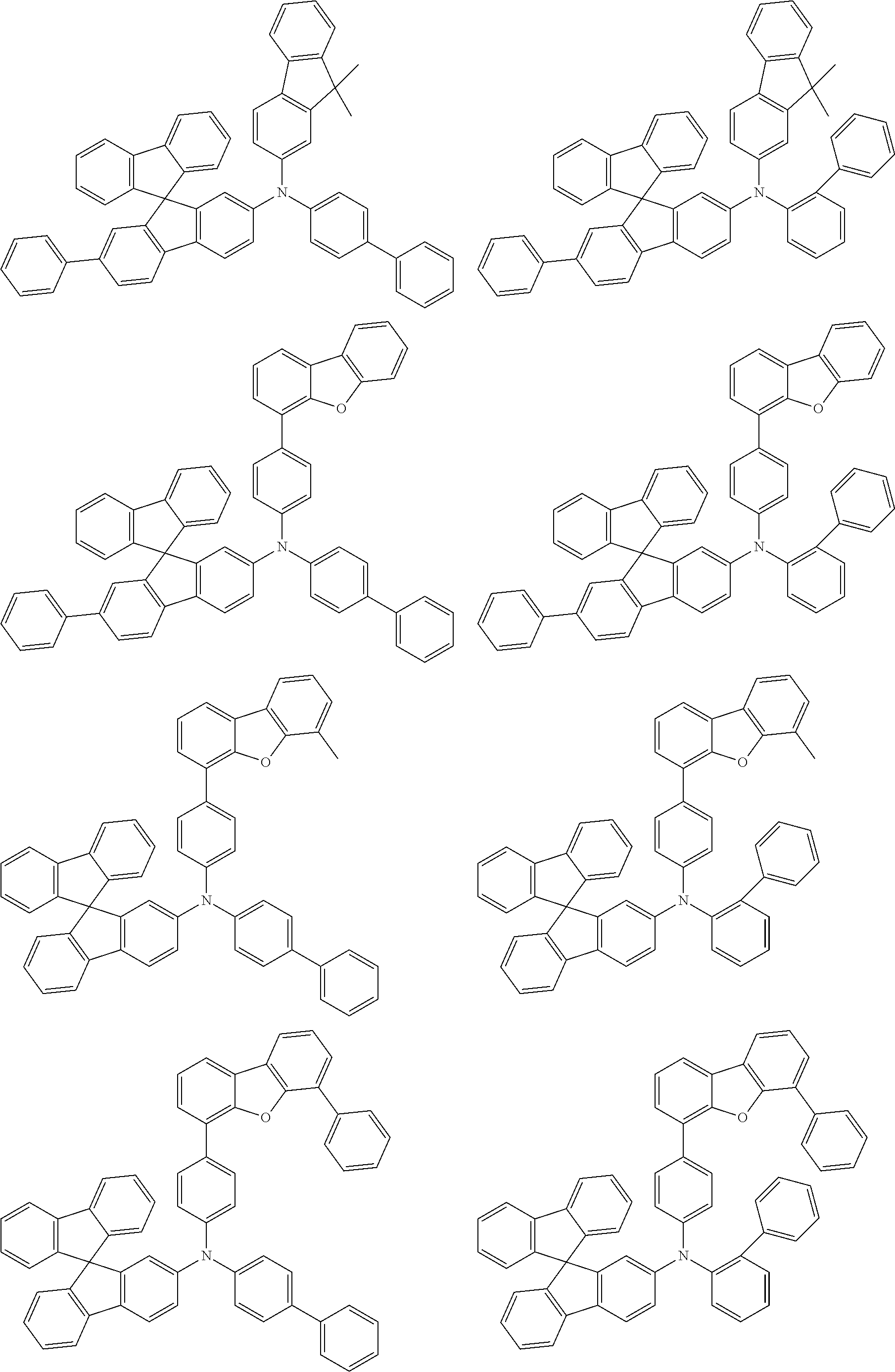

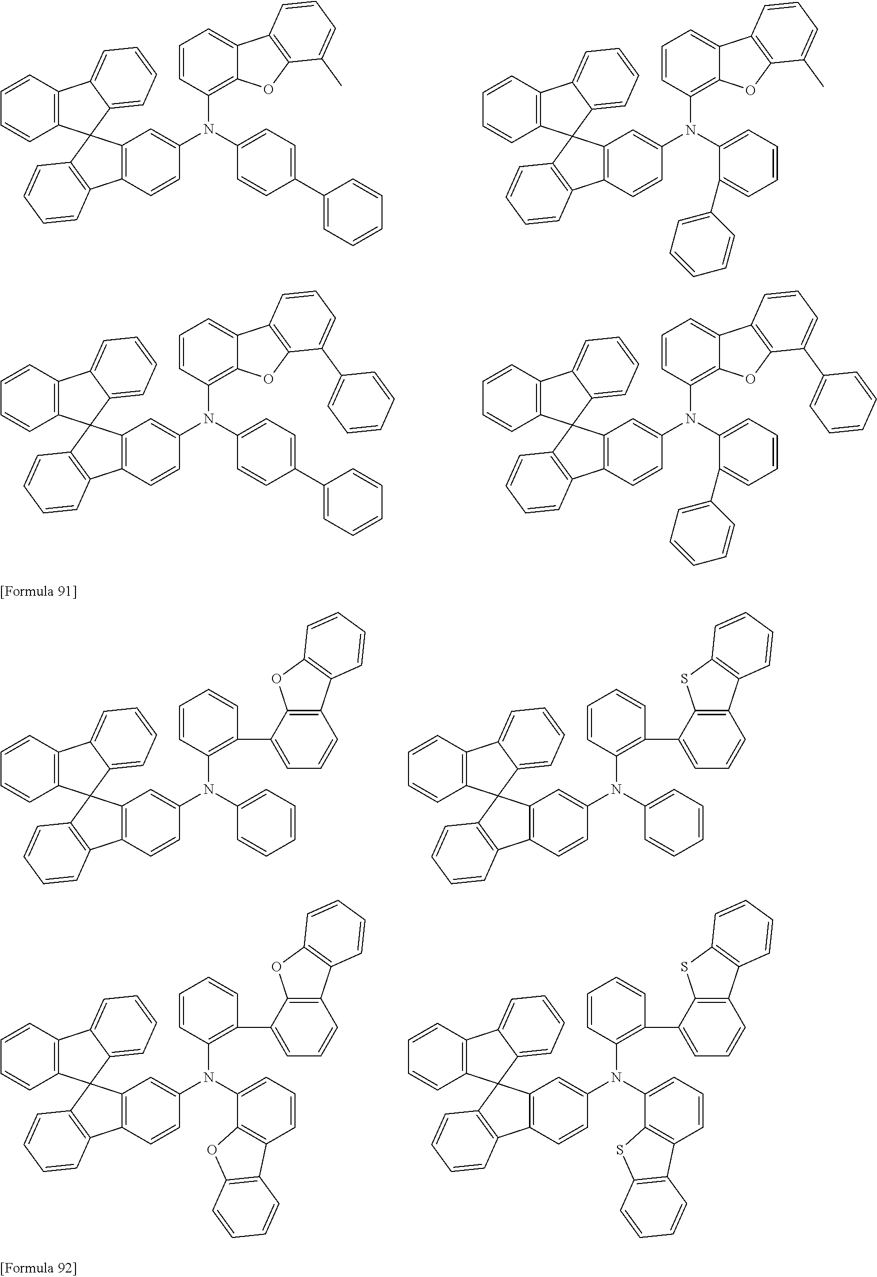

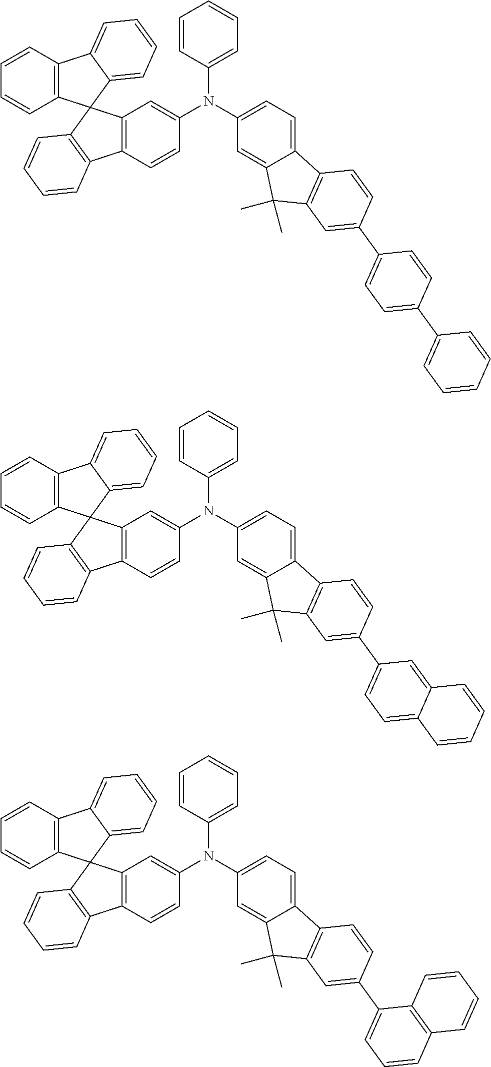 [SMILES: CC1(C)c2cc(-c3ccc(-c4ccccc4)cc3)ccc2-c2ccc(N(c3ccccc3)c3ccc4c(c3)C3(c5ccccc5-c5ccccc53)c3ccccc3-4)cc21 ; CC1(C)c2cc(-c3ccc4ccccc4c3)ccc2-c2ccc(N(c3ccccc3)c3ccc4c(c3)C3(c5ccccc5-c5ccccc53)c3ccccc3-4)cc21 ; CC1(C)c2cc(-c3cccc4ccccc34)ccc2-c2ccc(N(c3ccccc3)c3ccc4c(c3)C3(c5ccccc5-c5ccccc53)c3ccccc3-4)cc21]

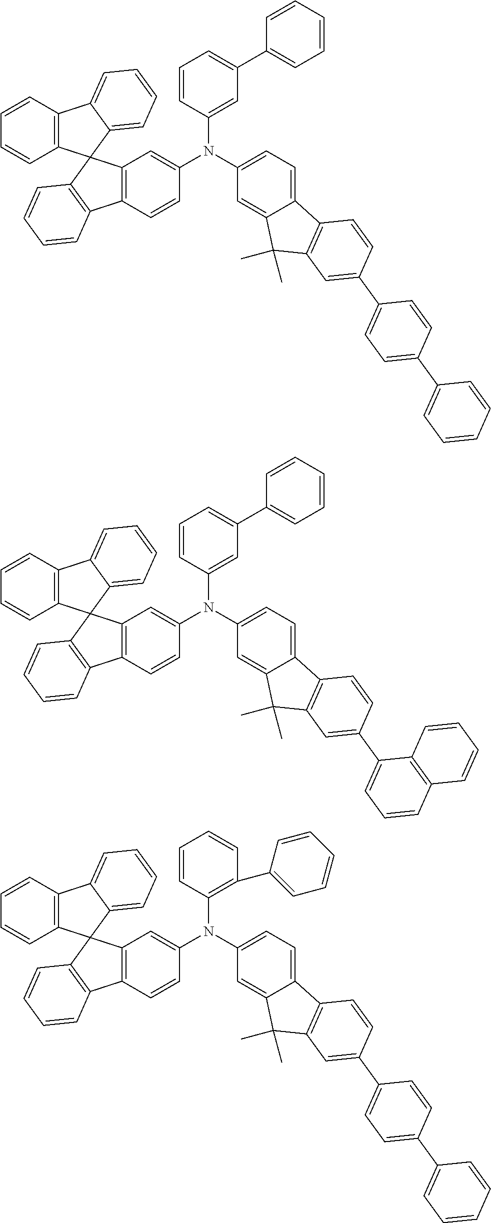 [SMILES: CC1(C)c2cc(-c3ccc(-c4ccccc4)cc3)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3cccc4ccccc34)ccc2-c2ccc(N(c3cccc(-c4ccccc4)c3)c3ccc4c(c3)C3(c5ccccc5-c5ccccc53)c3ccccc3-4)cc21 ; CC1(C)c2cc(-c3ccc(-c4ccccc4)cc3)ccc2-c2ccc(N(c3ccc4c(c3)C3(c5ccccc5-c5ccccc53)c3ccccc3-4)c3ccccc3-c3ccccc3)cc21]

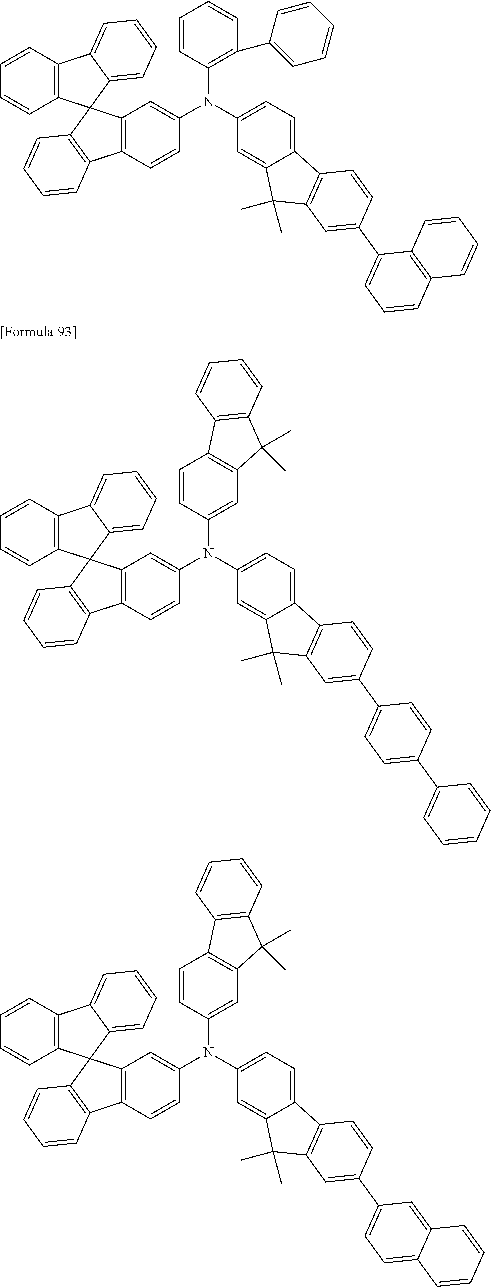 [SMILES: CC1(C)c2cc(-c3cccc4ccccc34)ccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc4c(c3)C(C)(C)c3cc(-c5ccc(-c6ccccc6)cc5)ccc3-4)c3ccc4c(c3)C3(c5ccccc5-c5ccccc53)c3ccccc3-4)cc21 ; CC1(C)c2ccccc2-c2ccc(N(c3ccc4c(c3)C(C)(C)c3cc(-c5ccc6ccccc6c5)ccc3-4)c3ccc4c(c3)C3(c5ccccc5-c5ccccc53)c3ccccc3-4)cc21]

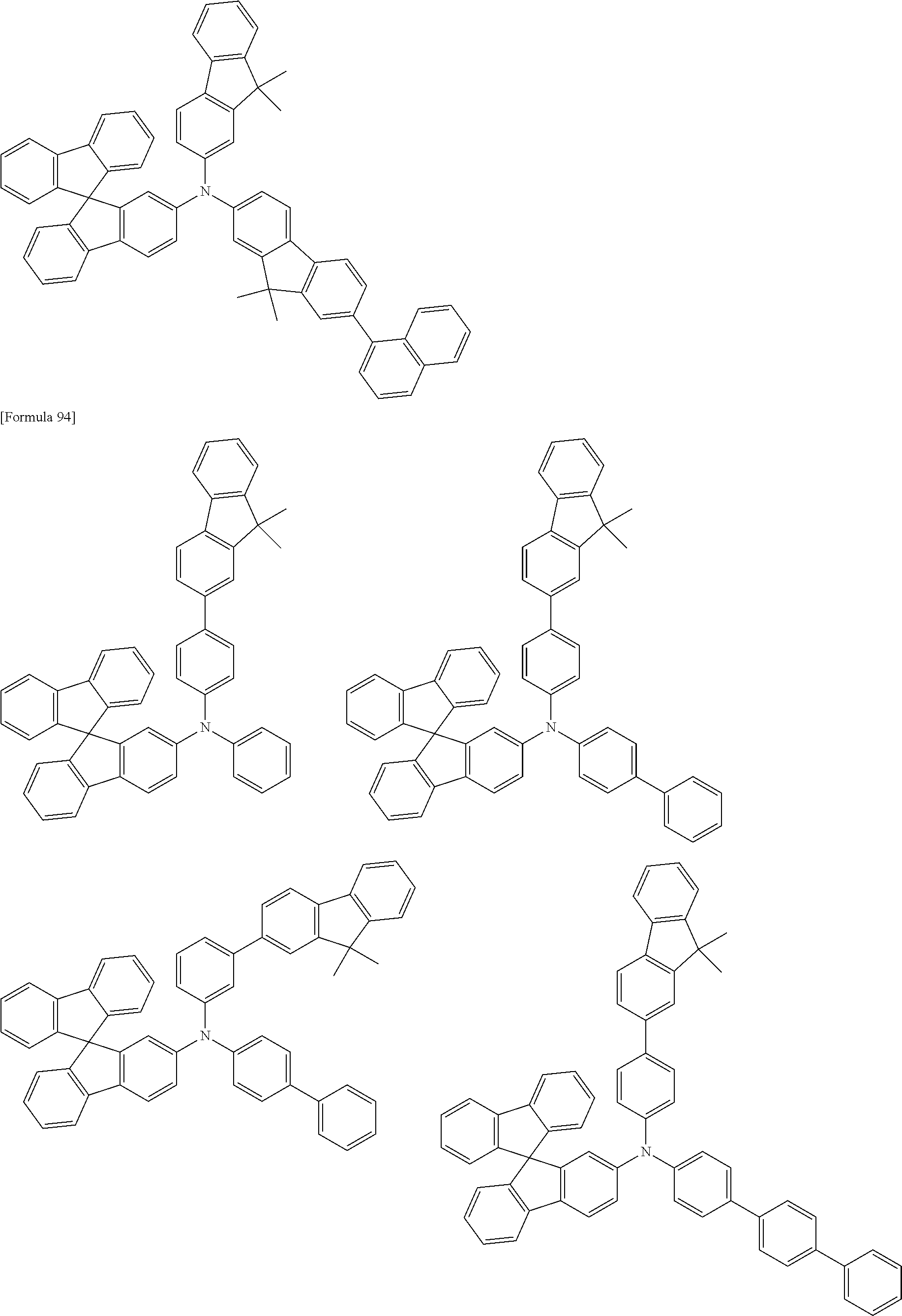

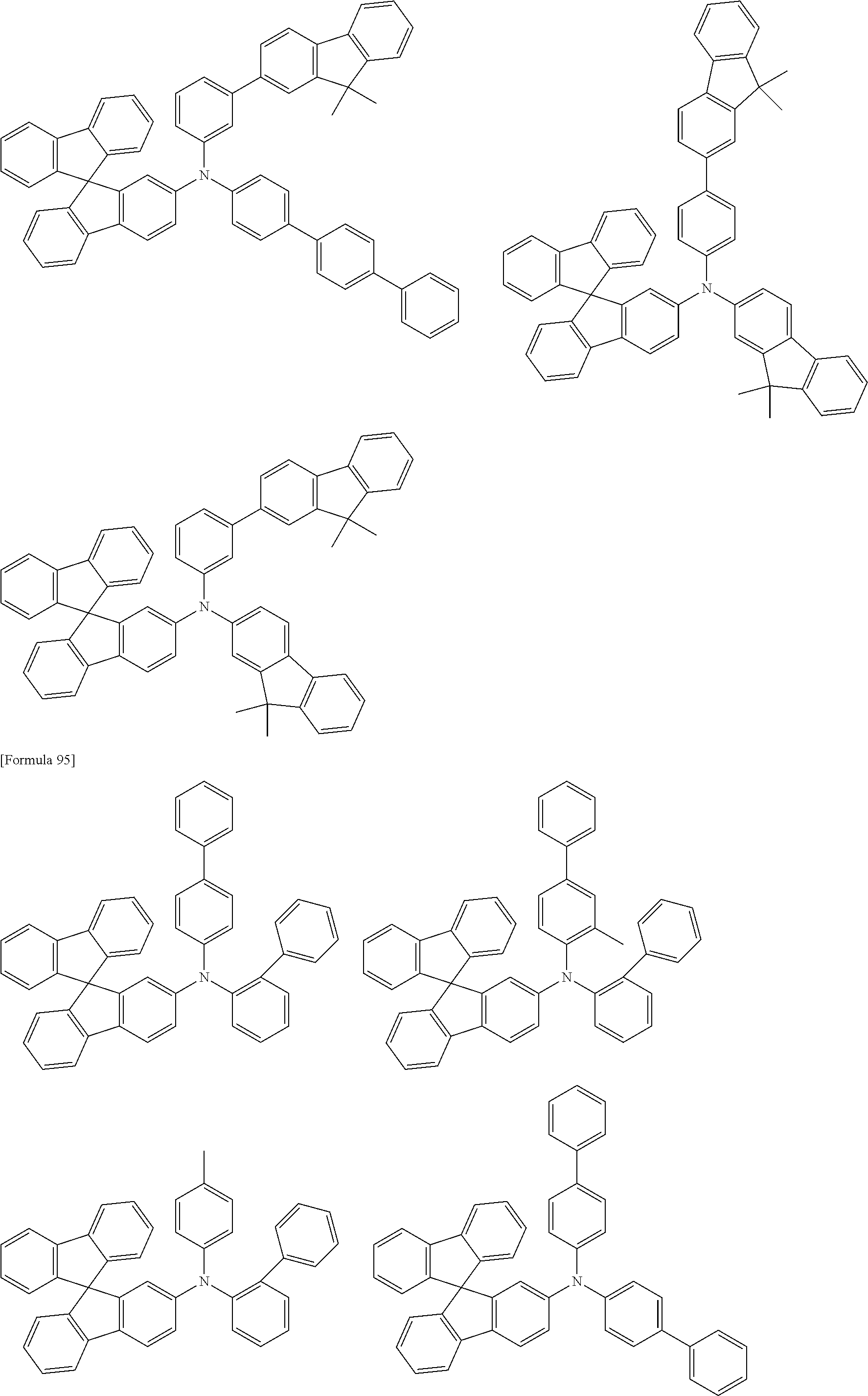

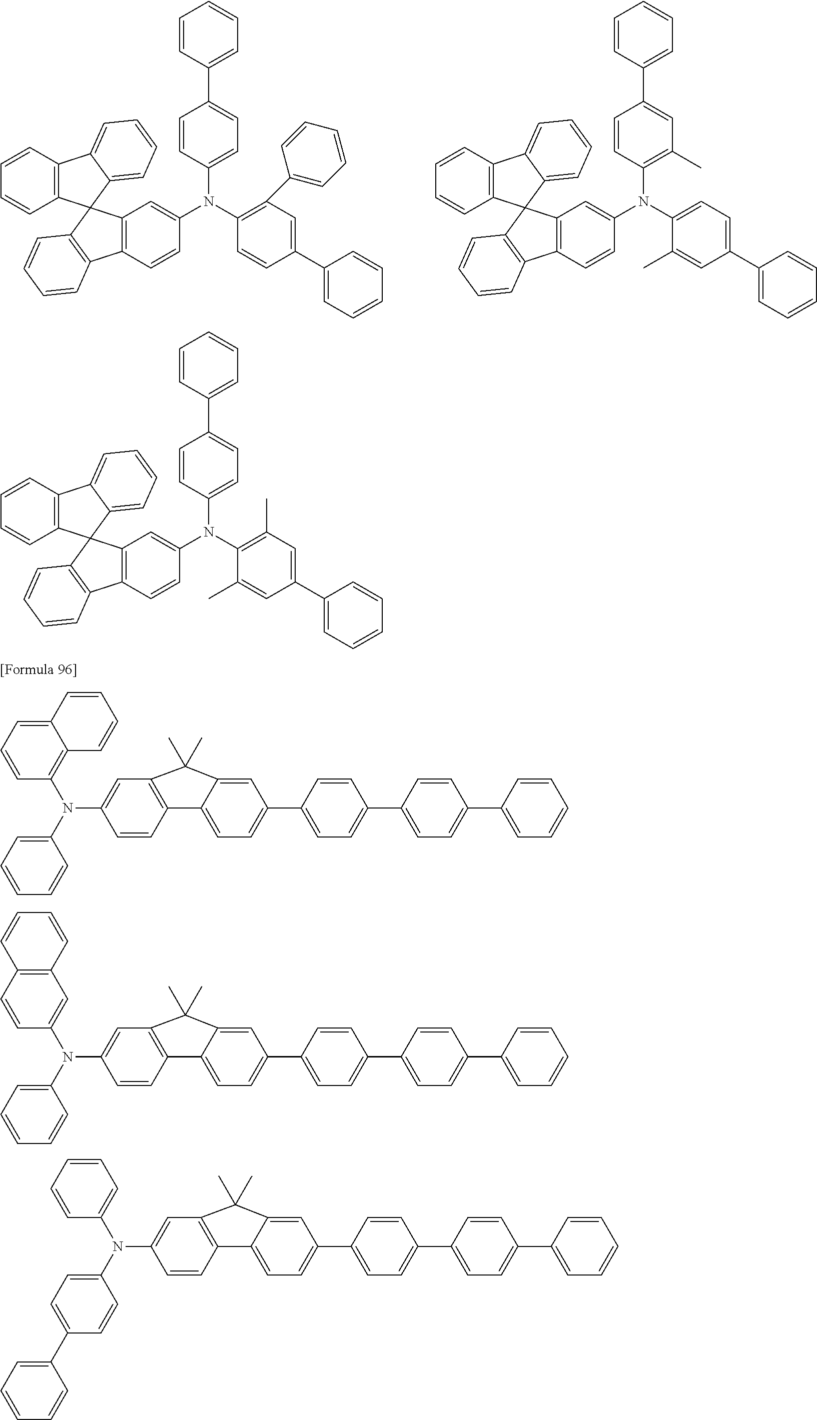

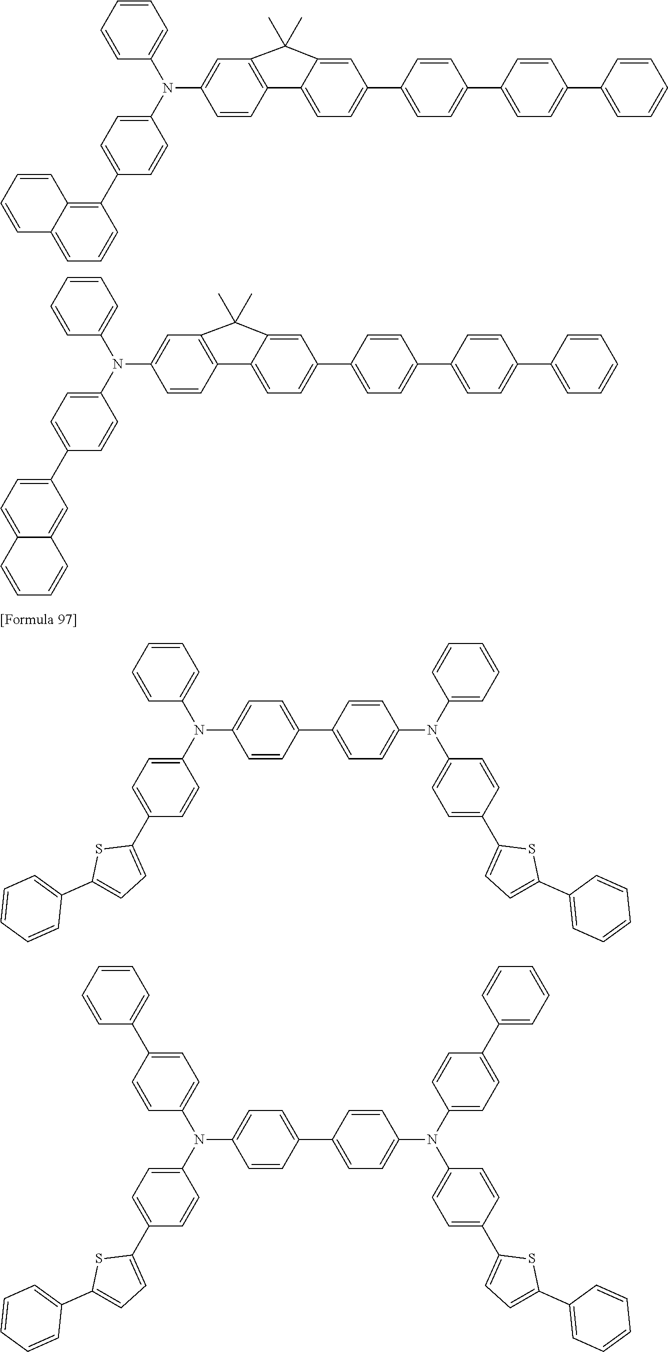

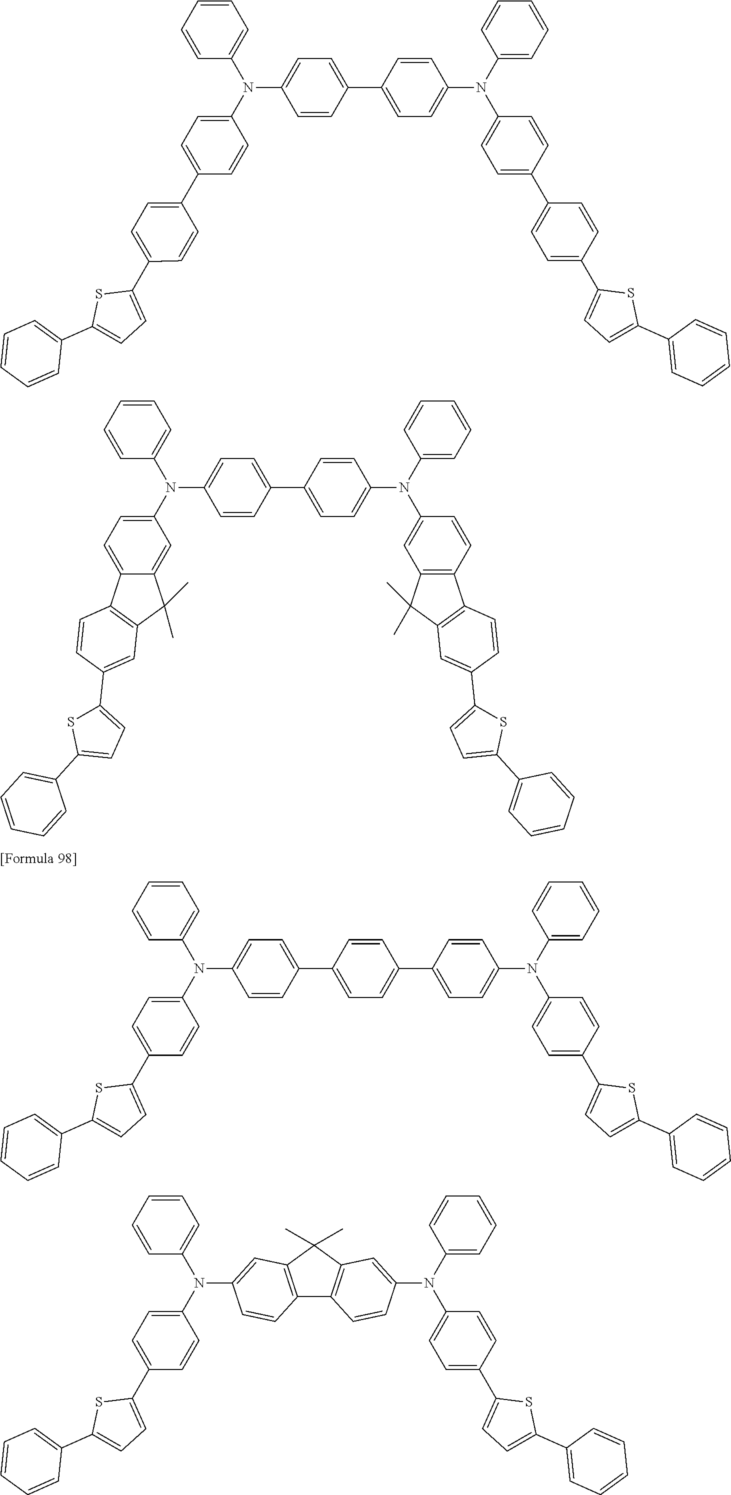 [SMILES: c1ccc(-c2ccc(-c3ccc(-c4ccc(N(c5ccccc5)c5ccc(-c6ccc(N(c7ccccc7)c7ccc(-c8ccc(-c9ccc(-c%10ccccc%10)s9)cc8)cc7)cc6)cc5)cc4)cc3)s2)cc1 ; CC1(C)c2cc(-c3ccc(-c4ccccc4)s3)ccc2-c2ccc(N(c3ccccc3)c3ccc(-c4ccc(N(c5ccccc5)c5ccc6c(c5)C(C)(C)c5cc(-c7ccc(-c8ccccc8)s7)ccc5-6)cc4)cc3)cc21 ; c1ccc(-c2ccc(-c3ccc(N(c4ccccc4)c4ccc(-c5ccc(-c6ccc(N(c7ccccc7)c7ccc(-c8ccc(-c9ccccc9)s8)cc7)cc6)cc5)cc4)cc3)s2)cc1 ; CC1(C)c2cc(N(c3ccccc3)c3ccc(-c4ccc(-c5ccccc5)s4)cc3)ccc2-c2ccc(N(c3ccccc3)c3ccc(-c4ccc(-c5ccccc5)s4)cc3)cc21]

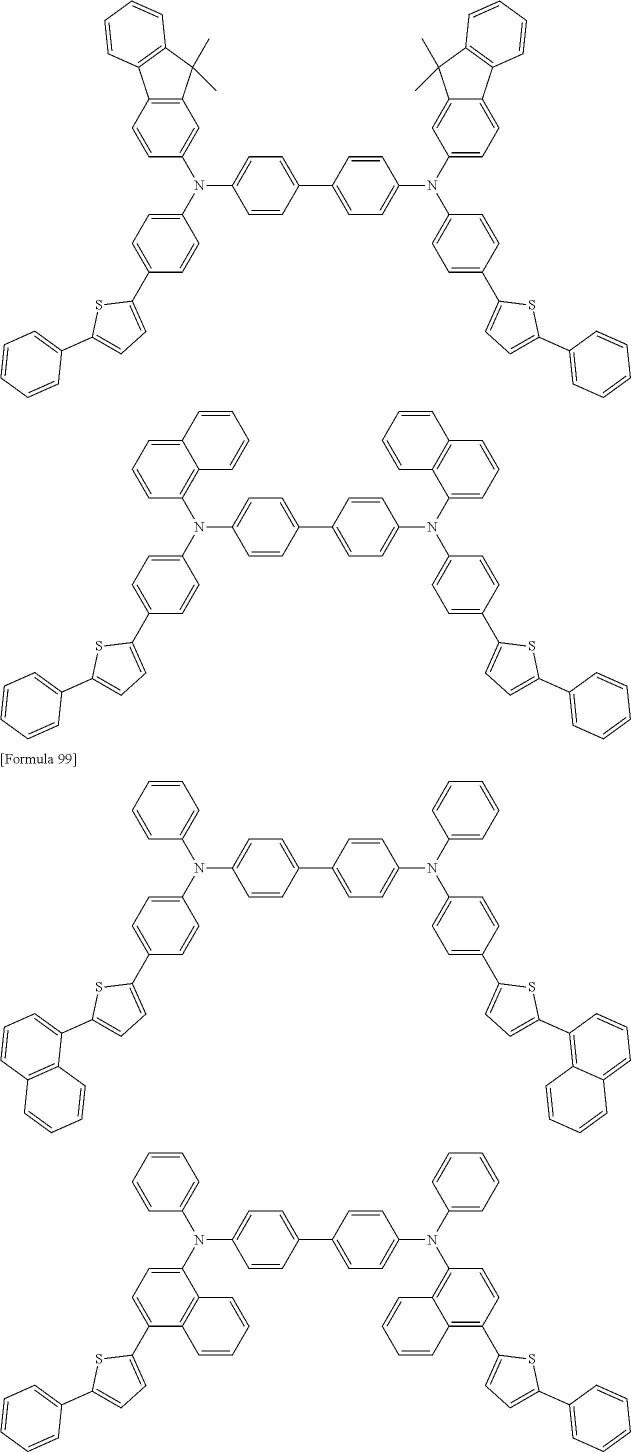 [SMILES: CC1(C)c2ccccc2-c2ccc(N(c3ccc(-c4ccc(N(c5ccc(-c6ccc(-c7ccccc7)s6)cc5)c5ccc6c(c5)C(C)(C)c5ccccc5-6)cc4)cc3)c3ccc(-c4ccc(-c5ccccc5)s4)cc3)cc21 ; c1ccc(-c2ccc(-c3ccc(N(c4ccc(-c5ccc(N(c6ccc(-c7ccc(-c8ccccc8)s7)cc6)c6cccc7ccccc67)cc5)cc4)c4cccc5ccccc45)cc3)s2)cc1 ; c1ccc(N(c2ccc(-c3ccc(N(c4ccccc4)c4ccc(-c5ccc(-c6cccc7ccccc67)s5)cc4)cc3)cc2)c2ccc(-c3ccc(-c4cccc5ccccc45)s3)cc2)cc1 ; c1ccc(-c2ccc(-c3ccc(N(c4ccccc4)c4ccc(-c5ccc(N(c6ccccc6)c6ccc(-c7ccc(-c8ccccc8)s7)c7ccccc67)cc5)cc4)c4ccccc34)s2)cc1]

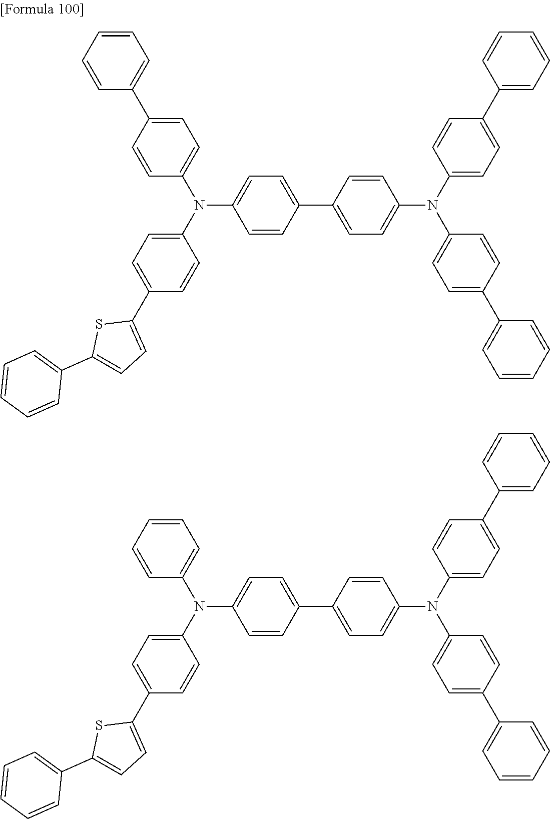 [SMILES: c1ccc(-c2ccc(N(c3ccc(-c4ccccc4)cc3)c3ccc(-c4ccc(N(c5ccc(-c6ccccc6)cc5)c5ccc(-c6ccc(-c7ccccc7)s6)cc5)cc4)cc3)cc2)cc1 ; c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1]

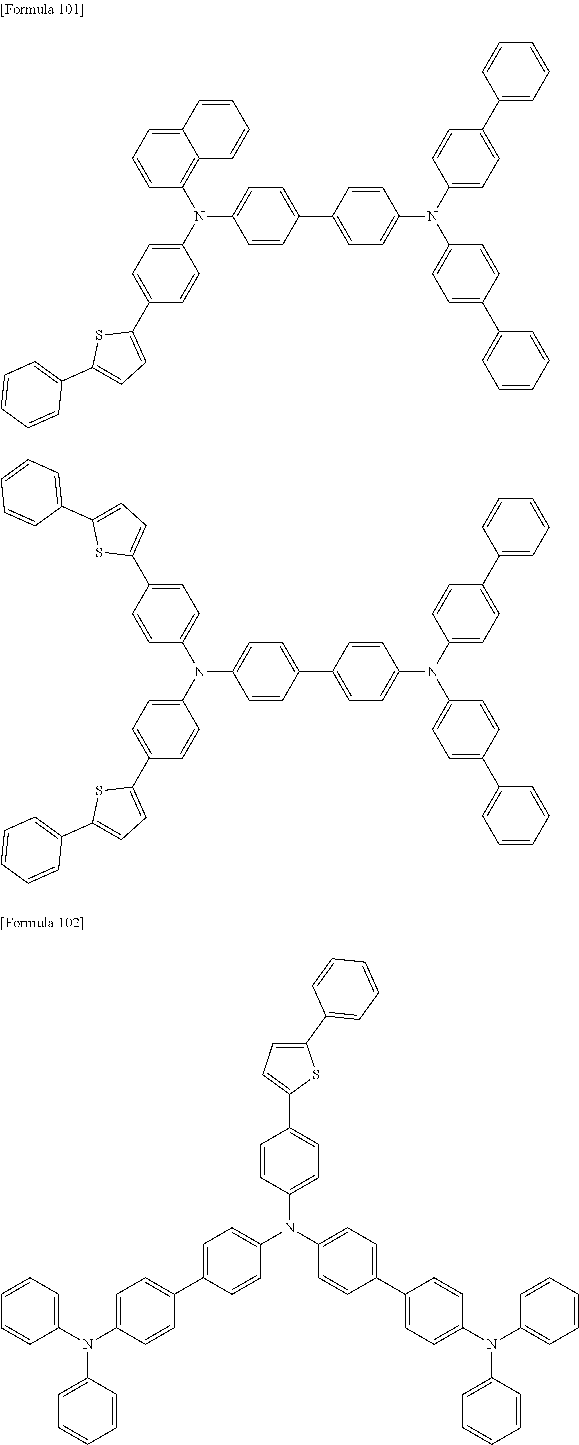

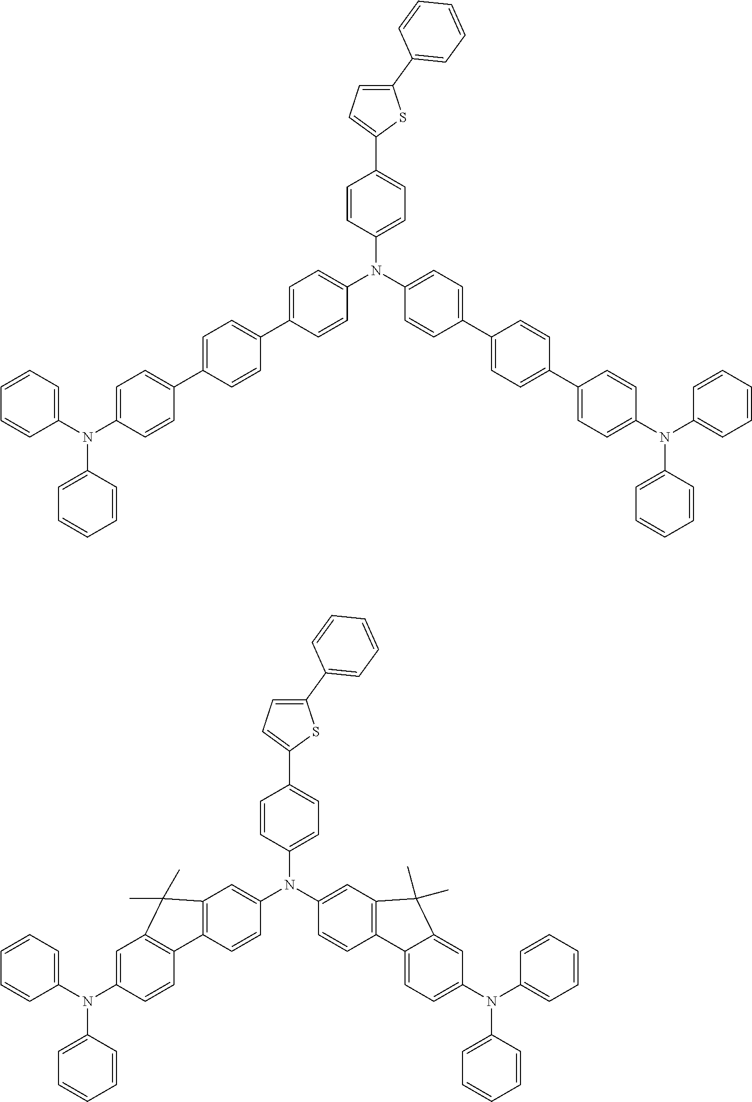 [SMILES: c1ccc(-c2ccc(-c3ccc(N(c4ccc(-c5ccc(-c6ccc(N(c7ccccc7)c7ccccc7)cc6)cc5)cc4)c4ccc(-c5ccc(-c6ccc(N(c7ccccc7)c7ccccc7)cc6)cc5)cc4)cc3)s2)cc1 ; CC1(C)c2cc(N(c3ccccc3)c3ccccc3)ccc2-c2ccc(N(c3ccc(-c4ccc(-c5ccccc5)s4)cc3)c3ccc4c(c3)C(C)(C)c3cc(N(c5ccccc5)c5ccccc5)ccc3-4)cc21]

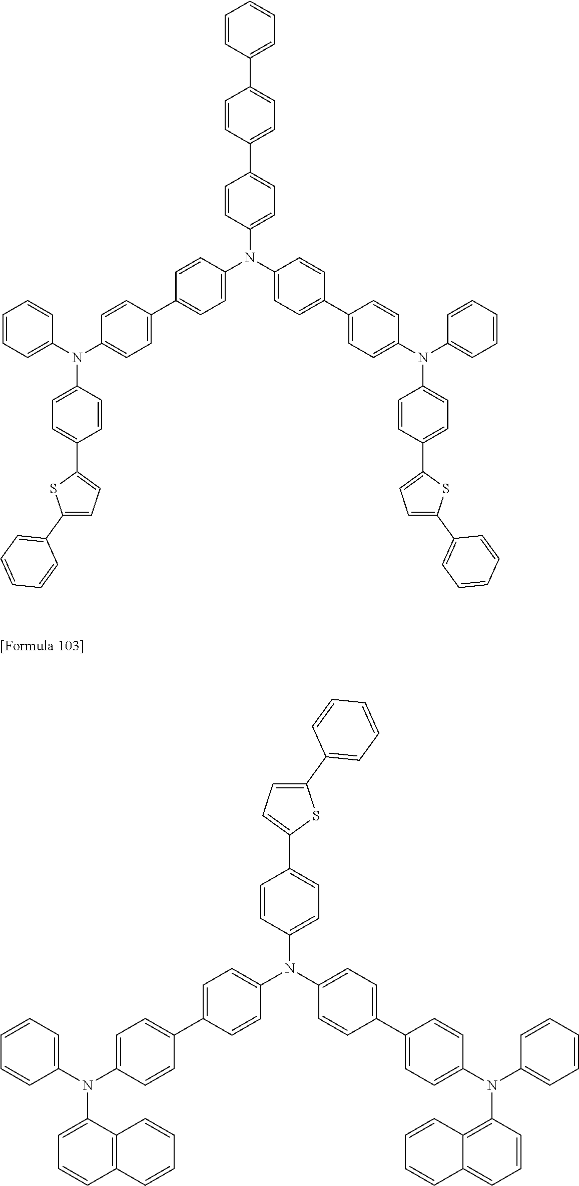 [SMILES: c1ccc(-c2ccc(-c3ccc(N(c4ccc(-c5ccc(N(c6ccccc6)c6ccc(-c7ccc(-c8ccccc8)s7)cc6)cc5)cc4)c4ccc(-c5ccc(N(c6ccccc6)c6ccc(-c7ccc(-c8ccccc8)s7)cc6)cc5)cc4)cc3)cc2)cc1 ; c1ccc(-c2ccc(-c3ccc(N(c4ccc(-c5ccc(N(c6ccccc6)c6cccc7ccccc67)cc5)cc4)c4ccc(-c5ccc(N(c6ccccc6)c6cccc7ccccc67)cc5)cc4)cc3)s2)cc1]

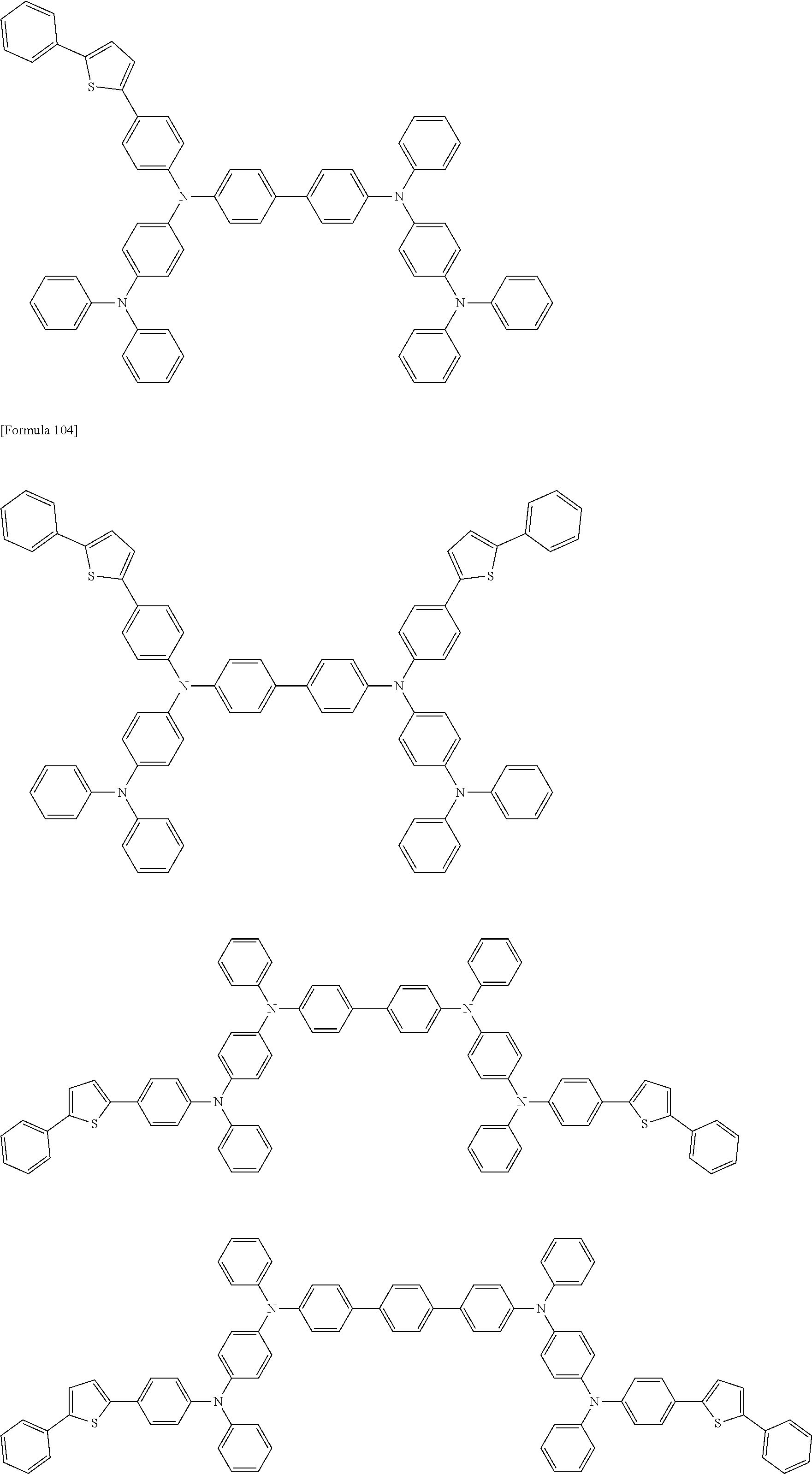

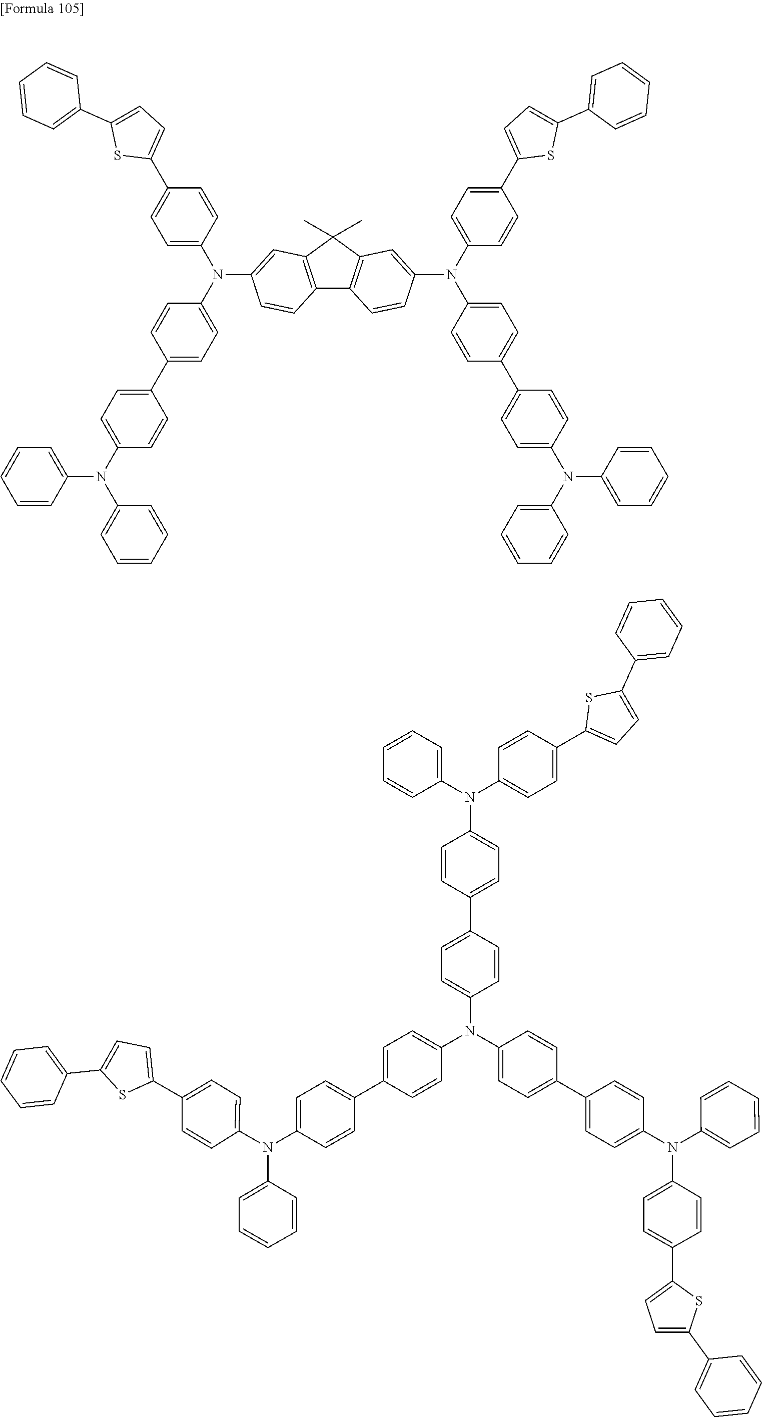 [SMILES: CC1(C)c2cc(N(c3ccc(-c4ccc(N(c5ccccc5)c5ccccc5)cc4)cc3)c3ccc(-c4ccc(-c5ccccc5)s4)cc3)ccc2-c2ccc(N(c3ccc(-c4ccc(N(c5ccccc5)c5ccccc5)cc4)cc3)c3ccc(-c4ccc(-c5ccccc5)s4)cc3)cc21 ; c1ccc(-c2ccc(-c3ccc(N(c4ccccc4)c4ccc(-c5ccc(N(c6ccc(-c7ccc(N(c8ccccc8)c8ccc(-c9ccc(-c%10ccccc%10)s9)cc8)cc7)cc6)c6ccc(-c7ccc(N(c8ccccc8)c8ccc(-c9ccc(-c%10ccccc%10)s9)cc8)cc7)cc6)cc5)cc4)cc3)s2)cc1]

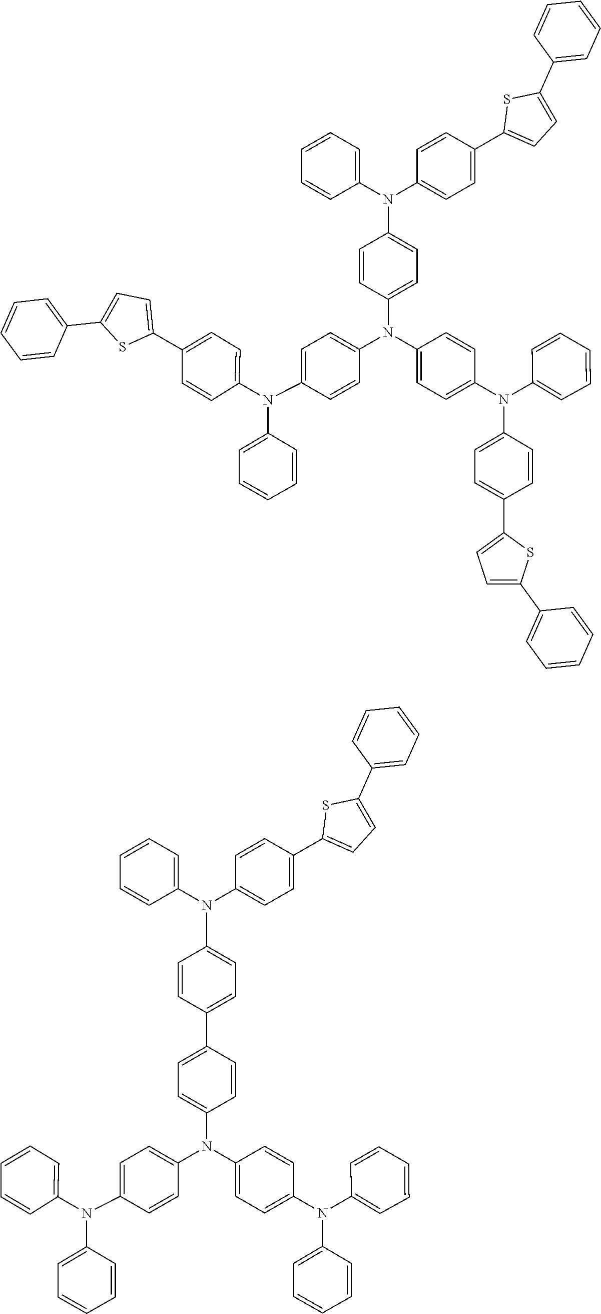 [SMILES: c1ccc(-c2ccc(-c3ccc(N(c4ccccc4)c4ccc(N(c5ccc(N(c6ccccc6)c6ccc(-c7ccc(-c8ccccc8)s7)cc6)cc5)c5ccc(N(c6ccccc6)c6ccc(-c7ccc(-c8ccccc8)s7)cc6)cc5)cc4)cc3)s2)cc1 ; c1ccc(-c2ccc(-c3ccc(N(c4ccccc4)c4ccc(-c5ccc(N(c6ccc(N(c7ccccc7)c7ccccc7)cc6)c6ccc(N(c7ccccc7)c7ccccc7)cc6)cc5)cc4)cc3)s2)cc1]

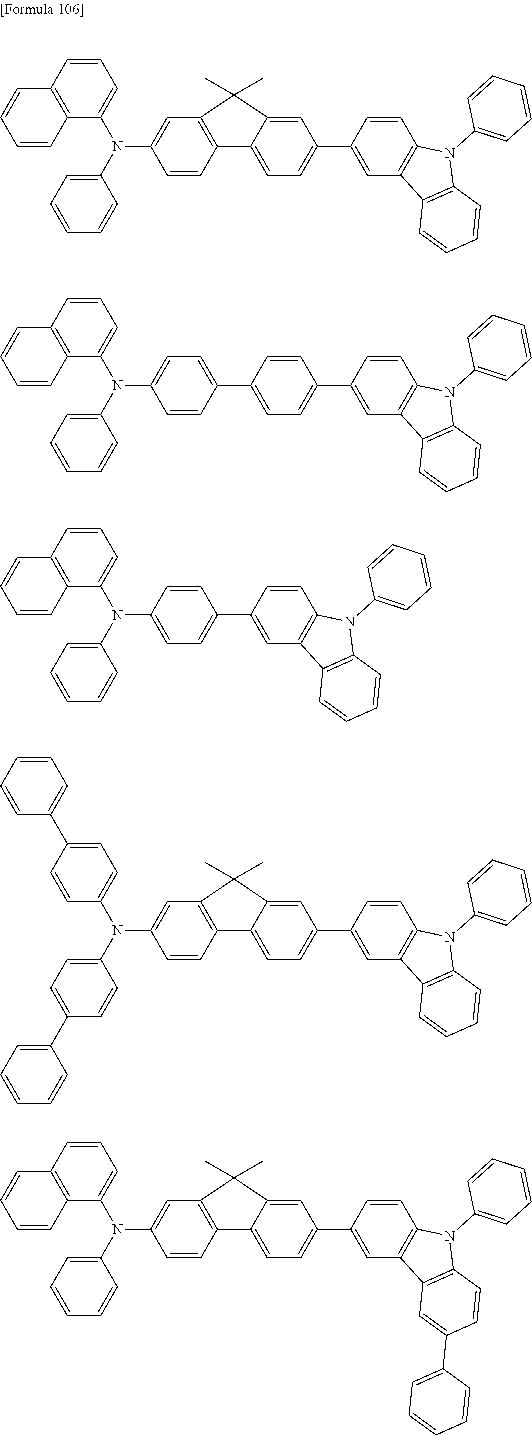

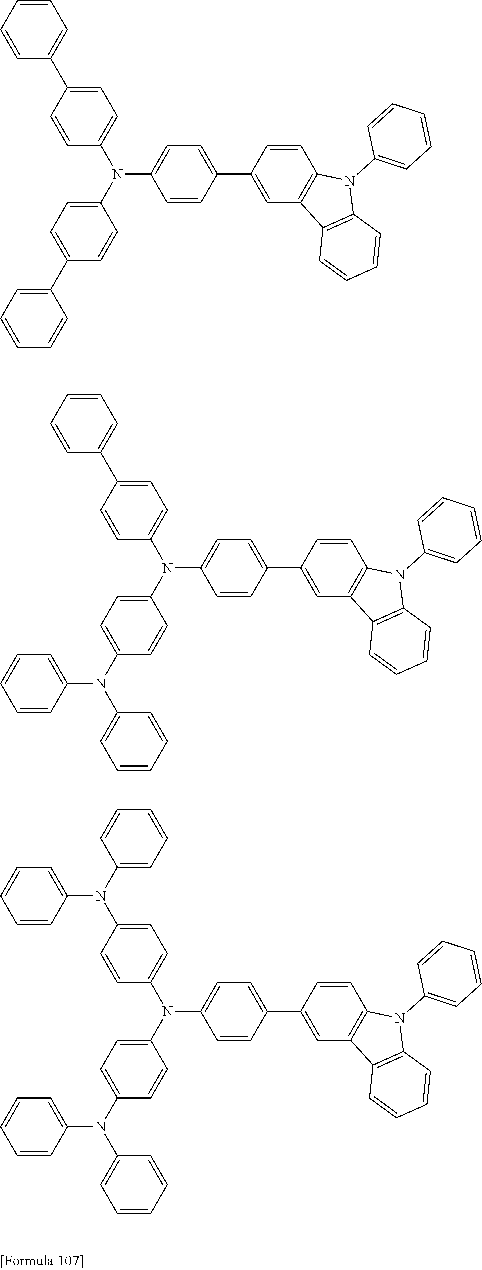

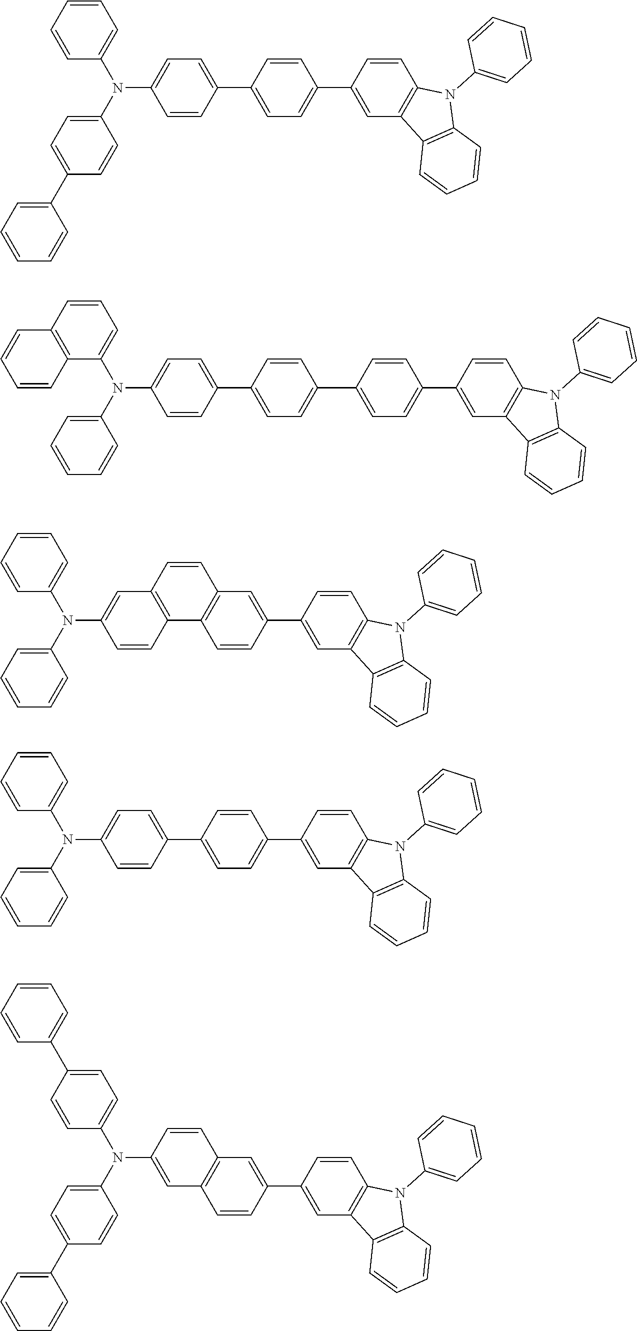

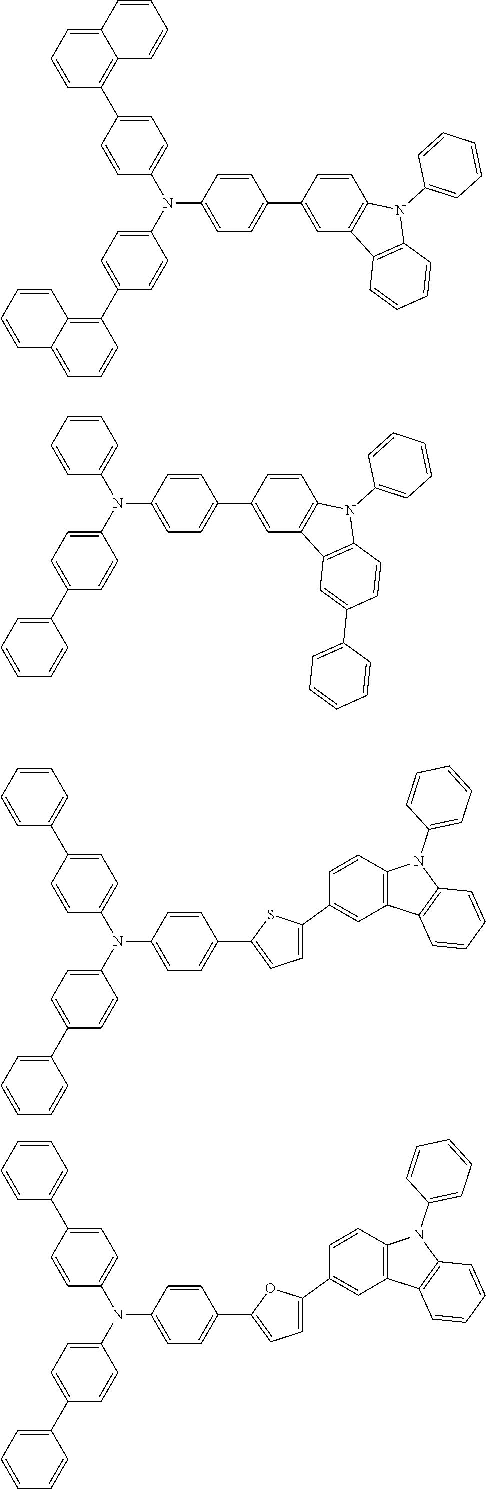

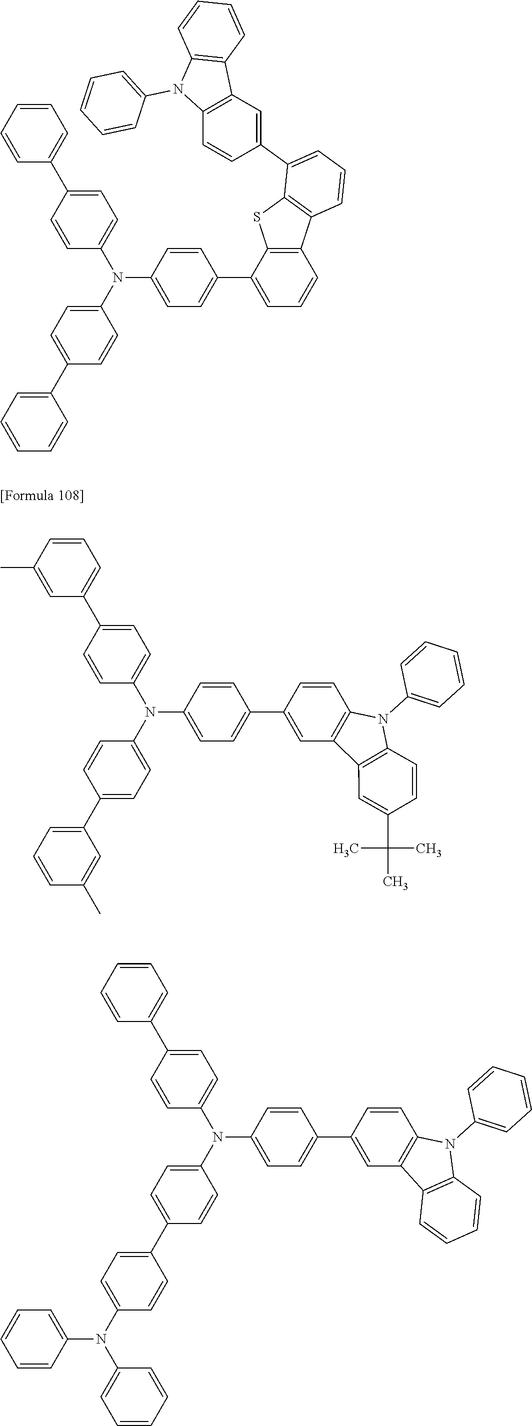 [SMILES: c1ccc(-c2ccc(N(c3ccc(-c4ccccc4)cc3)c3ccc(-c4cccc5c4sc4c(-c6ccc7c(c6)c6ccccc6n7-c6ccccc6)cccc45)cc3)cc2)cc1 ; Cc1cccc(-c2ccc(N(c3ccc(-c4cccc(C)c4)cc3)c3ccc(-c4ccc5c(c4)c4cc(C(C)(C)C)ccc4n5-c4ccccc4)cc3)cc2)c1 ; c1ccc(-c2ccc(N(c3ccc(-c4ccc(N(c5ccccc5)c5ccccc5)cc4)cc3)c3ccc(-c4ccc5c(c4)c4ccccc4n5-c4ccccc4)cc3)cc2)cc1]

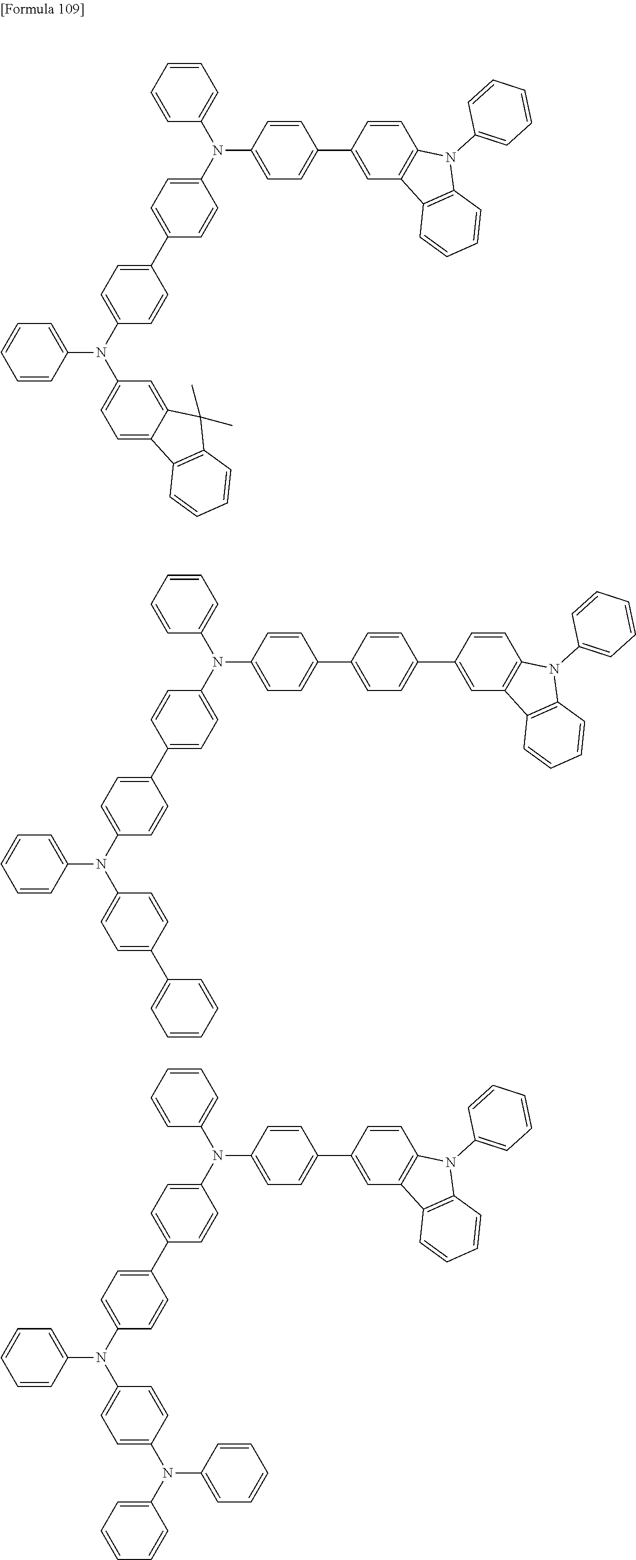

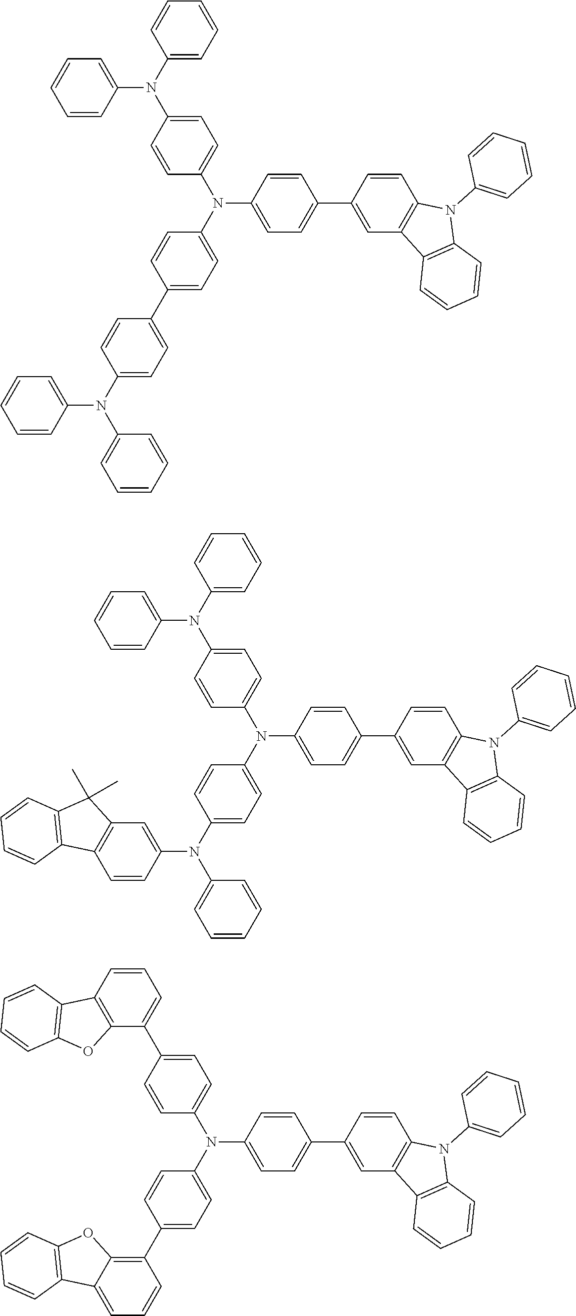 [SMILES: c1ccc(N(c2ccccc2)c2ccc(-c3ccc(N(c4ccc(-c5ccc6c(c5)c5ccccc5n6-c5ccccc5)cc4)c4ccc(N(c5ccccc5)c5ccccc5)cc4)cc3)cc2)cc1 ; CC1(C)c2ccccc2-c2ccc(N(c3ccccc3)c3ccc(N(c4ccc(-c5ccc6c(c5)c5ccccc5n6-c5ccccc5)cc4)c4ccc(N(c5ccccc5)c5ccccc5)cc4)cc3)cc21 ; c1ccc(-n2c3ccccc3c3cc(-c4ccc(N(c5ccc(-c6cccc7c6oc6ccccc67)cc5)c5ccc(-c6cccc7c6oc6ccccc67)cc5)cc4)ccc32)cc1]

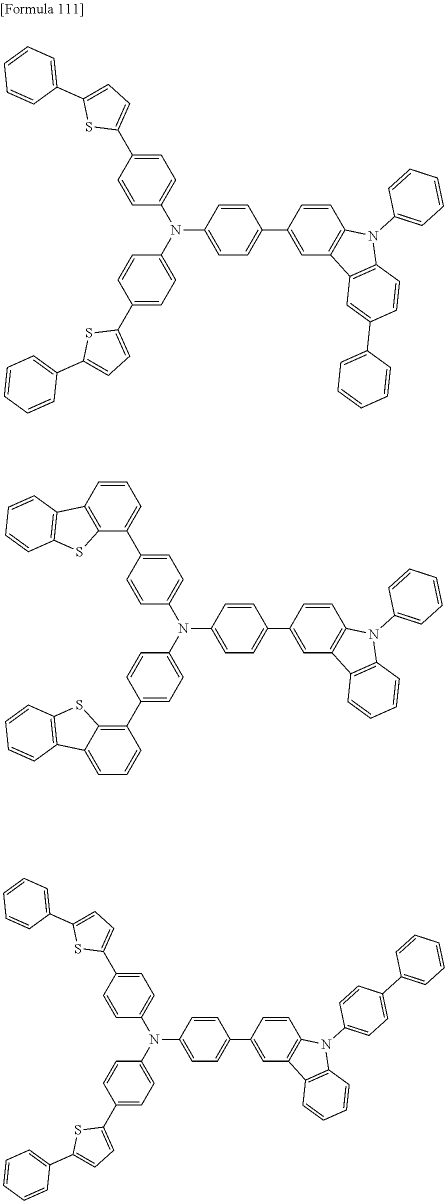 [SMILES: c1ccc(-c2ccc3c(c2)c2cc(-c4ccc(N(c5ccc(-c6ccc(-c7ccccc7)s6)cc5)c5ccc(-c6ccc(-c7ccccc7)s6)cc5)cc4)ccc2n3-c2ccccc2)cc1 ; c1ccc(-n2c3ccccc3c3cc(-c4ccc(N(c5ccc(-c6cccc7c6sc6ccccc67)cc5)c5ccc(-c6cccc7c6sc6ccccc67)cc5)cc4)ccc32)cc1 ; c1ccc(-c2ccc(-n3c4ccccc4c4cc(-c5ccc(N(c6ccc(-c7ccc(-c8ccccc8)s7)cc6)c6ccc(-c7ccc(-c8ccccc8)s7)cc6)cc5)ccc43)cc2)cc1]

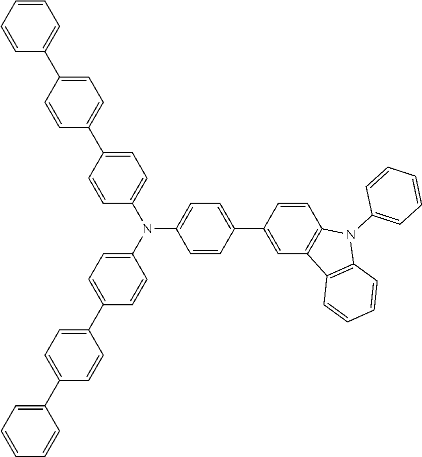 [SMILES: c1ccc(-c2ccc(-c3ccc(N(c4ccc(-c5ccc(-c6ccccc6)cc5)cc4)c4ccc(-c5ccc6c(c5)c5ccccc5n6-c5ccccc5)cc4)cc3)cc2)cc1]

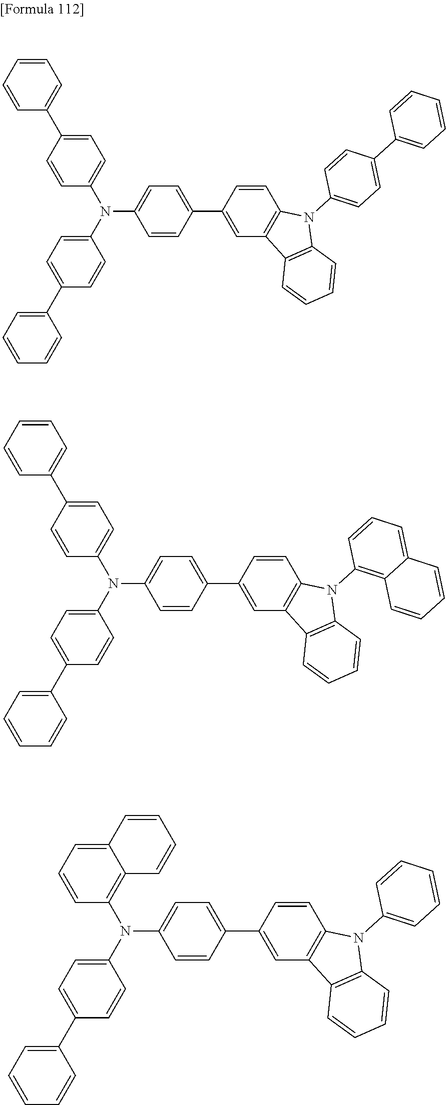 [SMILES: c1ccc(-c2ccc(N(c3ccc(-c4ccccc4)cc3)c3ccc(-c4ccc5c(c4)c4ccccc4n5-c4ccc(-c5ccccc5)cc4)cc3)cc2)cc1 ; c1ccc(-c2ccc(N(c3ccc(-c4ccccc4)cc3)c3ccc(-c4ccc5c(c4)c4ccccc4n5-c4cccc5ccccc45)cc3)cc2)cc1 ; c1ccc(-c2ccc(N(c3ccc(-c4ccc5c(c4)c4ccccc4n5-c4ccccc4)cc3)c3cccc4ccccc34)cc2)cc1]

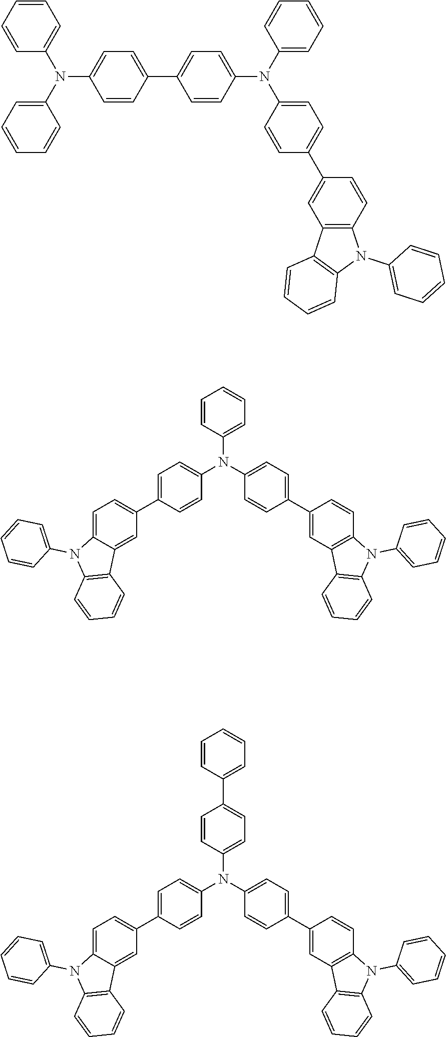 [SMILES: c1ccc(N(c2ccccc2)c2ccc(-c3ccc(N(c4ccccc4)c4ccc(-c5ccc6c(c5)c5ccccc5n6-c5ccccc5)cc4)cc3)cc2)cc1 ; c1ccc(N(c2ccc(-c3ccc4c(c3)c3ccccc3n4-c3ccccc3)cc2)c2ccc(-c3ccc4c(c3)c3ccccc3n4-c3ccccc3)cc2)cc1 ; c1ccc(-c2ccc(N(c3ccc(-c4ccc5c(c4)c4ccccc4n5-c4ccccc4)cc3)c3ccc(-c4ccc5c(c4)c4ccccc4n5-c4ccccc4)cc3)cc2)cc1]

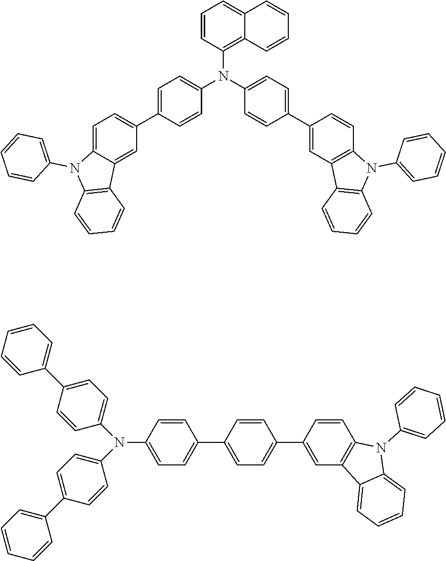 [SMILES: c1ccc(-n2c3ccccc3c3cc(-c4ccc(N(c5ccc(-c6ccc7c(c6)c6ccccc6n7-c6ccccc6)cc5)c5cccc6ccccc56)cc4)ccc32)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

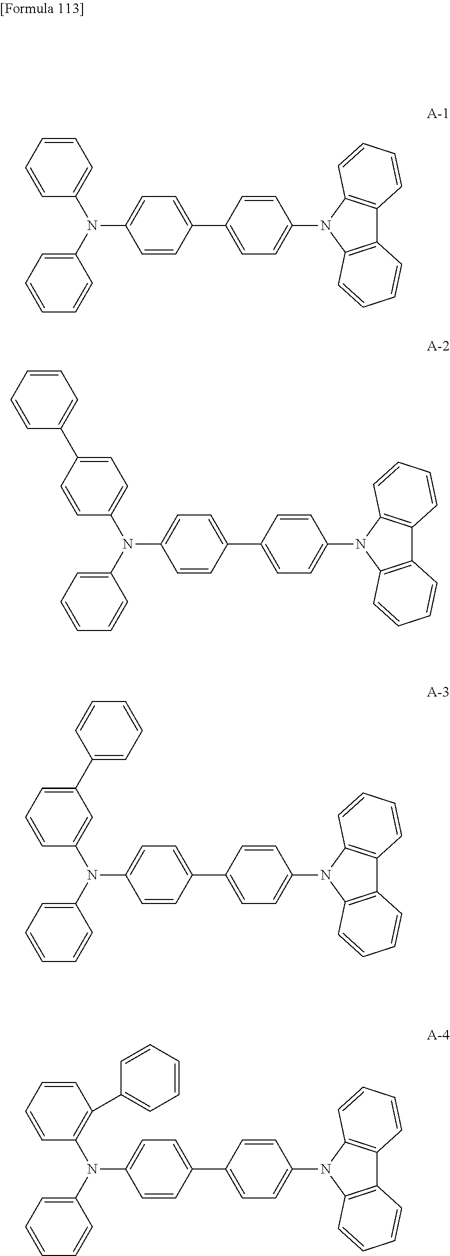 [SMILES: c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2cccc(N(c3ccccc3)c3ccc(-c4ccc(-n5c6ccccc6c6ccccc65)cc4)cc3)c2)cc1 ; c1ccc(-c2ccccc2N(c2ccccc2)c2ccc(-c3ccc(-n4c5ccccc5c5ccccc54)cc3)cc2)cc1]

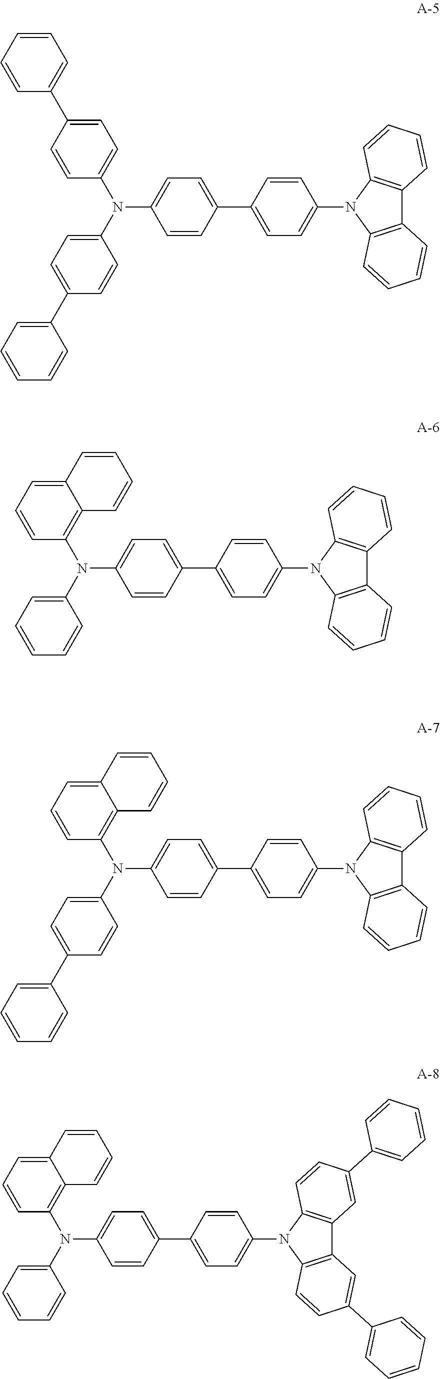 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(-n4c5ccccc5c5ccccc54)cc3)cc2)c2cccc3ccccc23)cc1 ; c1ccc(-c2ccc(N(c3ccc(-c4ccc(-n5c6ccccc6c6ccccc65)cc4)cc3)c3cccc4ccccc34)cc2)cc1 ; c1ccc(-c2ccc3c(c2)c2cc(-c4ccccc4)ccc2n3-c2ccc(-c3ccc(N(c4ccccc4)c4cccc5ccccc45)cc3)cc2)cc1]

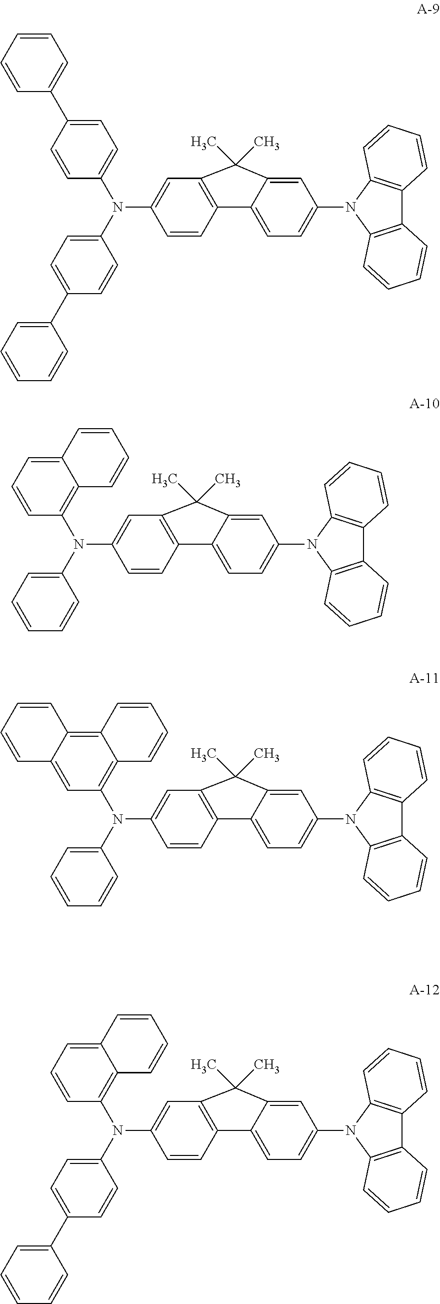 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2cc(N(c3ccccc3)c3cccc4ccccc34)ccc2-c2ccc(-n3c4ccccc4c4ccccc43)cc21 ; CC1(C)c2cc(N(c3ccccc3)c3cc4ccccc4c4ccccc34)ccc2-c2ccc(-n3c4ccccc4c4ccccc43)cc21 ; CC1(C)c2cc(N(c3ccc(-c4ccccc4)cc3)c3cccc4ccccc34)ccc2-c2ccc(-n3c4ccccc4c4ccccc43)cc21]

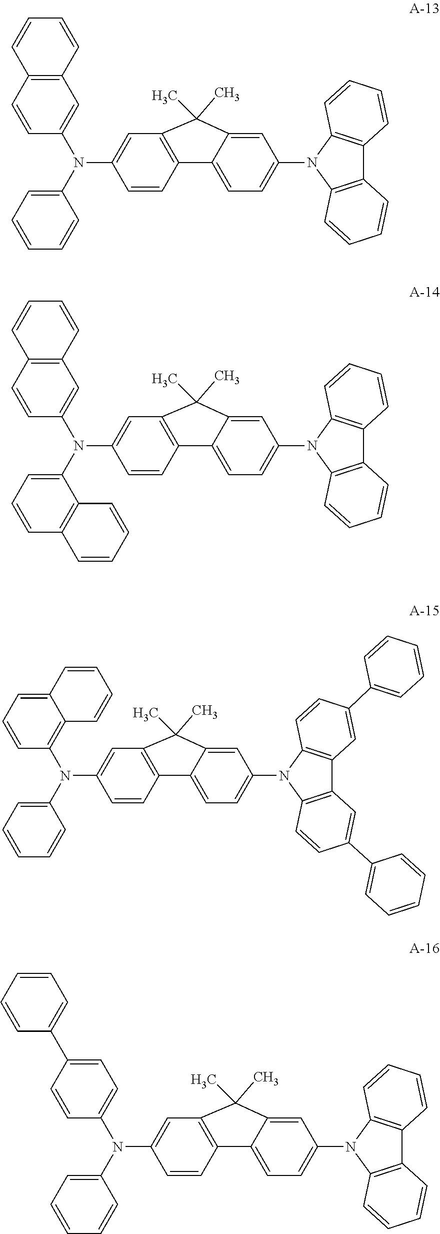 [SMILES: CC1(C)c2cc(N(c3ccccc3)c3ccc4ccccc4c3)ccc2-c2ccc(-n3c4ccccc4c4ccccc43)cc21 ; CC1(C)c2cc(N(c3ccc4ccccc4c3)c3cccc4ccccc34)ccc2-c2ccc(-n3c4ccccc4c4ccccc43)cc21 ; CC1(C)c2cc(N(c3ccccc3)c3cccc4ccccc34)ccc2-c2ccc(-n3c4ccc(-c5ccccc5)cc4c4cc(-c5ccccc5)ccc43)cc21 ; CC1(C)c2cc(N(c3ccccc3)c3ccc(-c4ccccc4)cc3)ccc2-c2ccc(-n3c4ccccc4c4ccccc43)cc21]

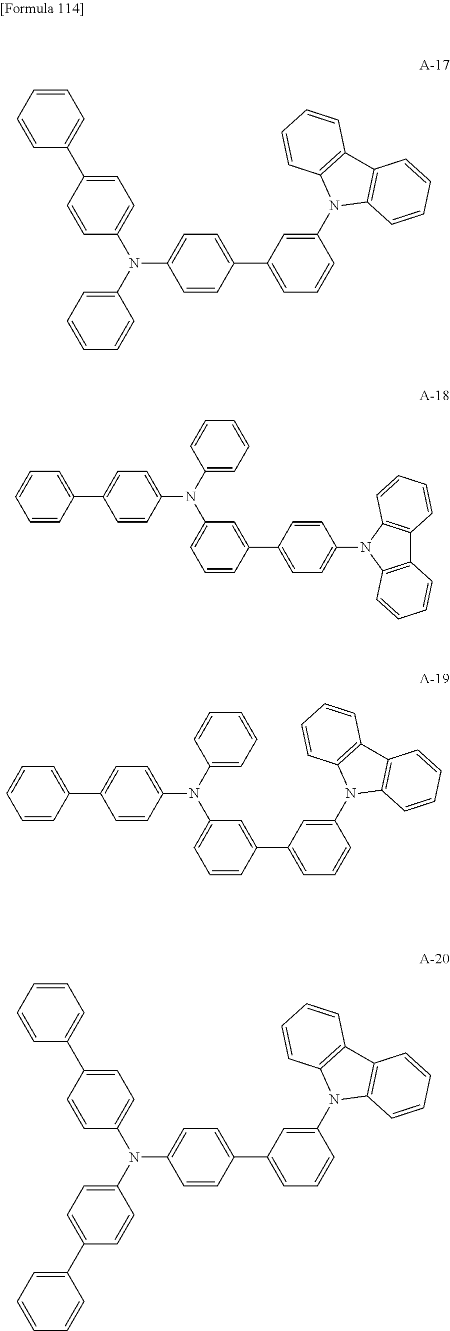 [SMILES: c1ccc(-c2ccc(N(c3ccccc3)c3ccc(-c4cccc(-n5c6ccccc6c6ccccc65)c4)cc3)cc2)cc1 ; c1ccc(-c2ccc(N(c3ccccc3)c3cccc(-c4ccc(-n5c6ccccc6c6ccccc65)cc4)c3)cc2)cc1 ; c1ccc(-c2ccc(N(c3ccccc3)c3cccc(-c4cccc(-n5c6ccccc6c6ccccc65)c4)c3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

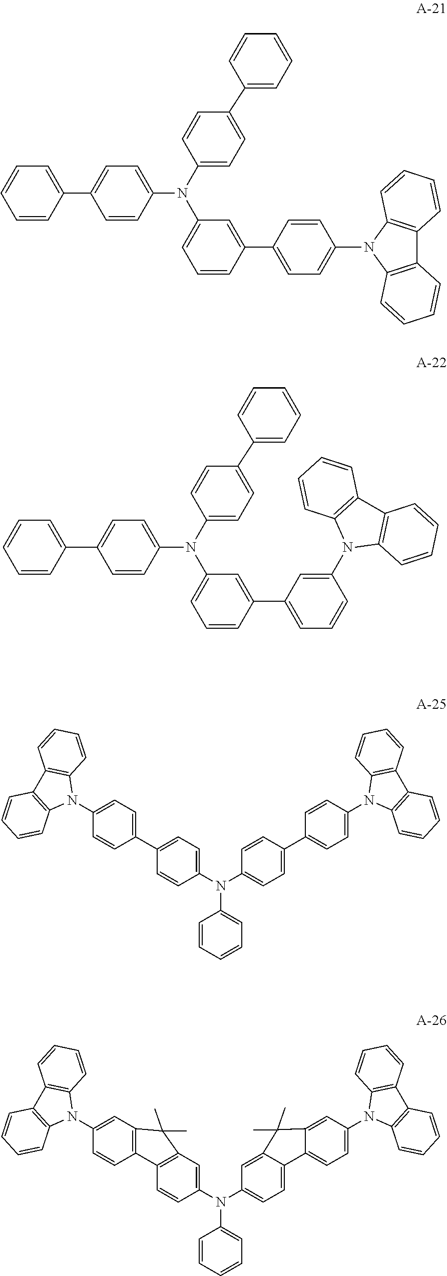 [SMILES: c1ccc(-c2ccc(N(c3ccc(-c4ccccc4)cc3)c3cccc(-c4ccc(-n5c6ccccc6c6ccccc65)cc4)c3)cc2)cc1 ; c1ccc(-c2ccc(N(c3ccc(-c4ccccc4)cc3)c3cccc(-c4cccc(-n5c6ccccc6c6ccccc65)c4)c3)cc2)cc1 ; c1ccc(N(c2ccc(-c3ccc(-n4c5ccccc5c5ccccc54)cc3)cc2)c2ccc(-c3ccc(-n4c5ccccc5c5ccccc54)cc3)cc2)cc1 ; CC1(C)c2cc(N(c3ccccc3)c3ccc4c(c3)C(C)(C)c3cc(-n5c6ccccc6c6ccccc65)ccc3-4)ccc2-c2ccc(-n3c4ccccc4c4ccccc43)cc21]

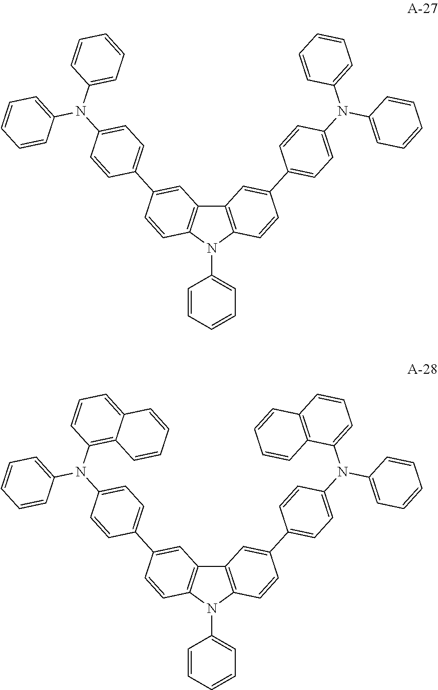 [SMILES: c1ccc(N(c2ccccc2)c2ccc(-c3ccc4c(c3)c3cc(-c5ccc(N(c6ccccc6)c6ccccc6)cc5)ccc3n4-c3ccccc3)cc2)cc1 ; c1ccc(N(c2ccc(-c3ccc4c(c3)c3cc(-c5ccc(N(c6ccccc6)c6cccc7ccccc67)cc5)ccc3n4-c3ccccc3)cc2)c2cccc3ccccc23)cc1]

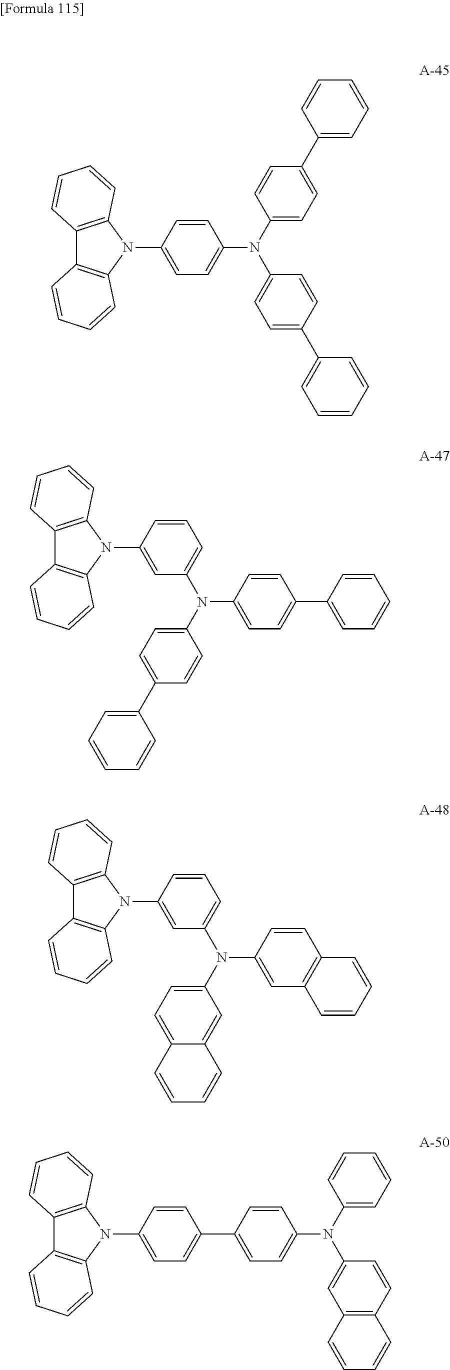 [SMILES: c1ccc(-c2ccc(N(c3ccc(-c4ccccc4)cc3)c3ccc(-n4c5ccccc5c5ccccc54)cc3)cc2)cc1 ; c1ccc(-c2ccc(N(c3ccc(-c4ccccc4)cc3)c3cccc(-n4c5ccccc5c5ccccc54)c3)cc2)cc1 ; c1cc(N(c2ccc3ccccc3c2)c2ccc3ccccc3c2)cc(-n2c3ccccc3c3ccccc32)c1 ; c1ccc(N(c2ccc(-c3ccc(-n4c5ccccc5c5ccccc54)cc3)cc2)c2ccc3ccccc3c2)cc1]

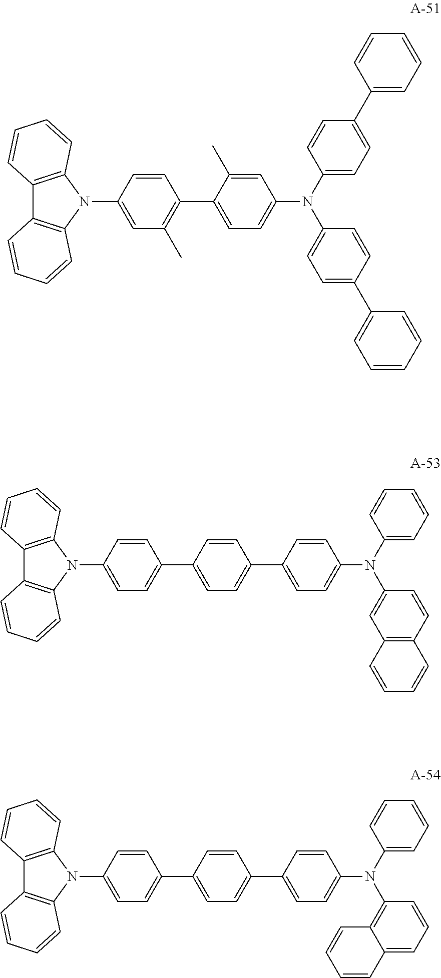 [SMILES: Cc1cc(N(c2ccc(-c3ccccc3)cc2)c2ccc(-c3ccccc3)cc2)ccc1-c1ccc(-n2c3ccccc3c3ccccc32)cc1C ; c1ccc(N(c2ccc(-c3ccc(-c4ccc(-n5c6ccccc6c6ccccc65)cc4)cc3)cc2)c2ccc3ccccc3c2)cc1 ; c1ccc(N(c2ccc(-c3ccc(-c4ccc(-n5c6ccccc6c6ccccc65)cc4)cc3)cc2)c2cccc3ccccc23)cc1]

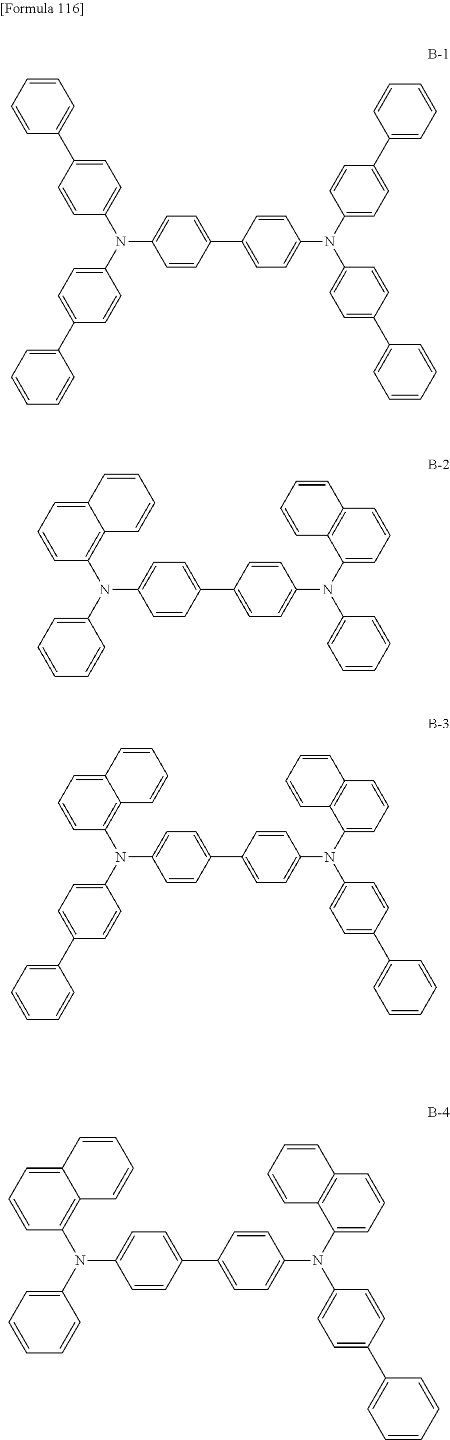 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccc(N(c5ccc(-c6ccccc6)cc5)c5cccc6ccccc56)cc4)cc3)c3cccc4ccccc34)cc2)cc1 ; c1ccc(-c2ccc(N(c3ccc(-c4ccc(N(c5ccccc5)c5cccc6ccccc56)cc4)cc3)c3cccc4ccccc34)cc2)cc1]

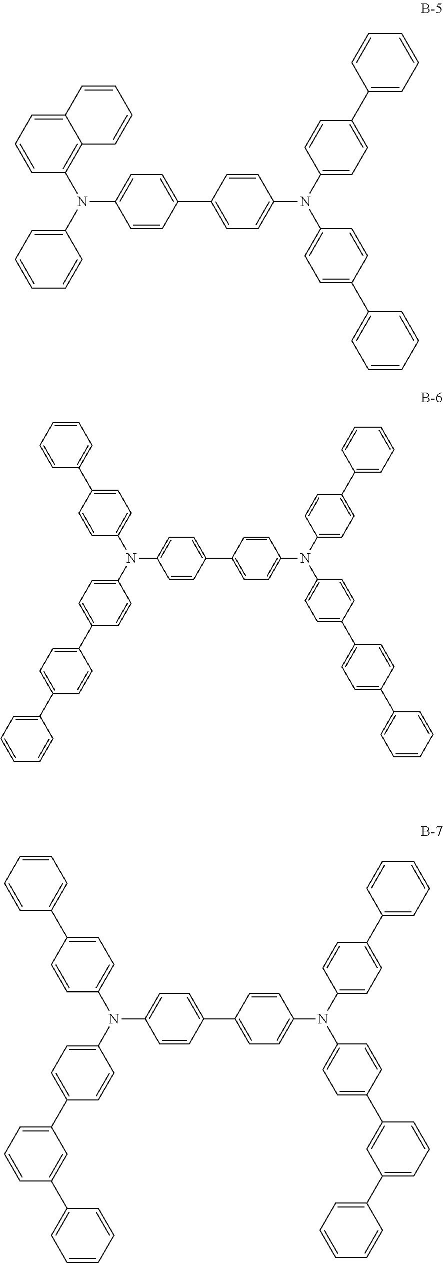 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(-c3ccc(N(c4ccc(-c5ccccc5)cc4)c4ccc(-c5ccc(N(c6ccc(-c7ccccc7)cc6)c6ccc(-c7ccc(-c8ccccc8)cc7)cc6)cc5)cc4)cc3)cc2)cc1 ; c1ccc(-c2ccc(N(c3ccc(-c4ccc(N(c5ccc(-c6ccccc6)cc5)c5ccc(-c6cccc(-c7ccccc7)c6)cc5)cc4)cc3)c3ccc(-c4cccc(-c5ccccc5)c4)cc3)cc2)cc1]

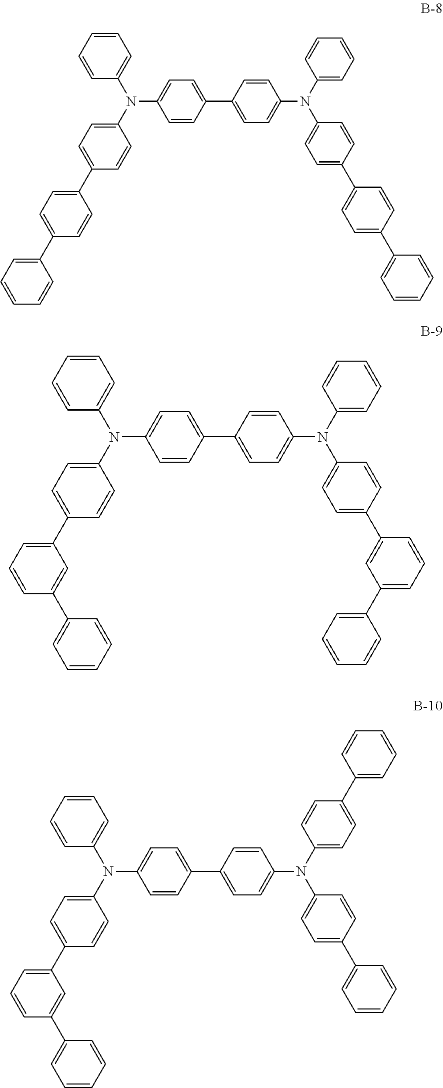 [SMILES: c1ccc(-c2ccc(-c3ccc(N(c4ccccc4)c4ccc(-c5ccc(N(c6ccccc6)c6ccc(-c7ccc(-c8ccccc8)cc7)cc6)cc5)cc4)cc3)cc2)cc1 ; c1ccc(-c2cccc(-c3ccc(N(c4ccccc4)c4ccc(-c5ccc(N(c6ccccc6)c6ccc(-c7cccc(-c8ccccc8)c7)cc6)cc5)cc4)cc3)c2)cc1 ; c1ccc(-c2ccc(N(c3ccc(-c4ccccc4)cc3)c3ccc(-c4ccc(N(c5ccccc5)c5ccc(-c6cccc(-c7ccccc7)c6)cc5)cc4)cc3)cc2)cc1]

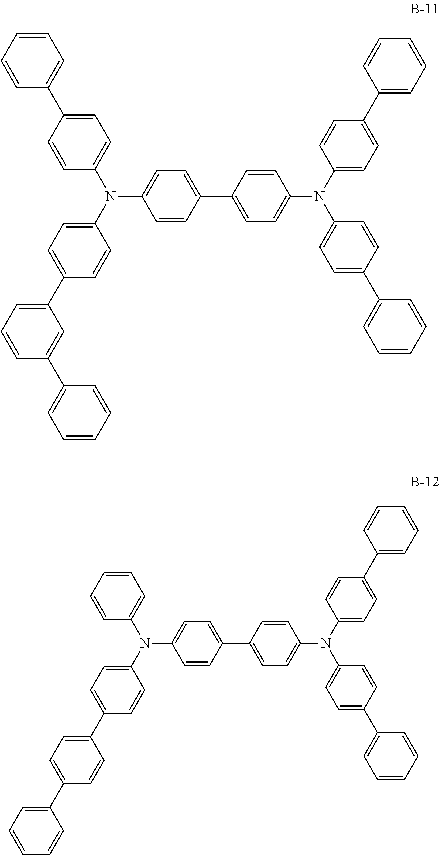 [SMILES: c1ccc(-c2ccc(N(c3ccc(-c4ccccc4)cc3)c3ccc(-c4ccc(N(c5ccc(-c6ccccc6)cc5)c5ccc(-c6cccc(-c7ccccc7)c6)cc5)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

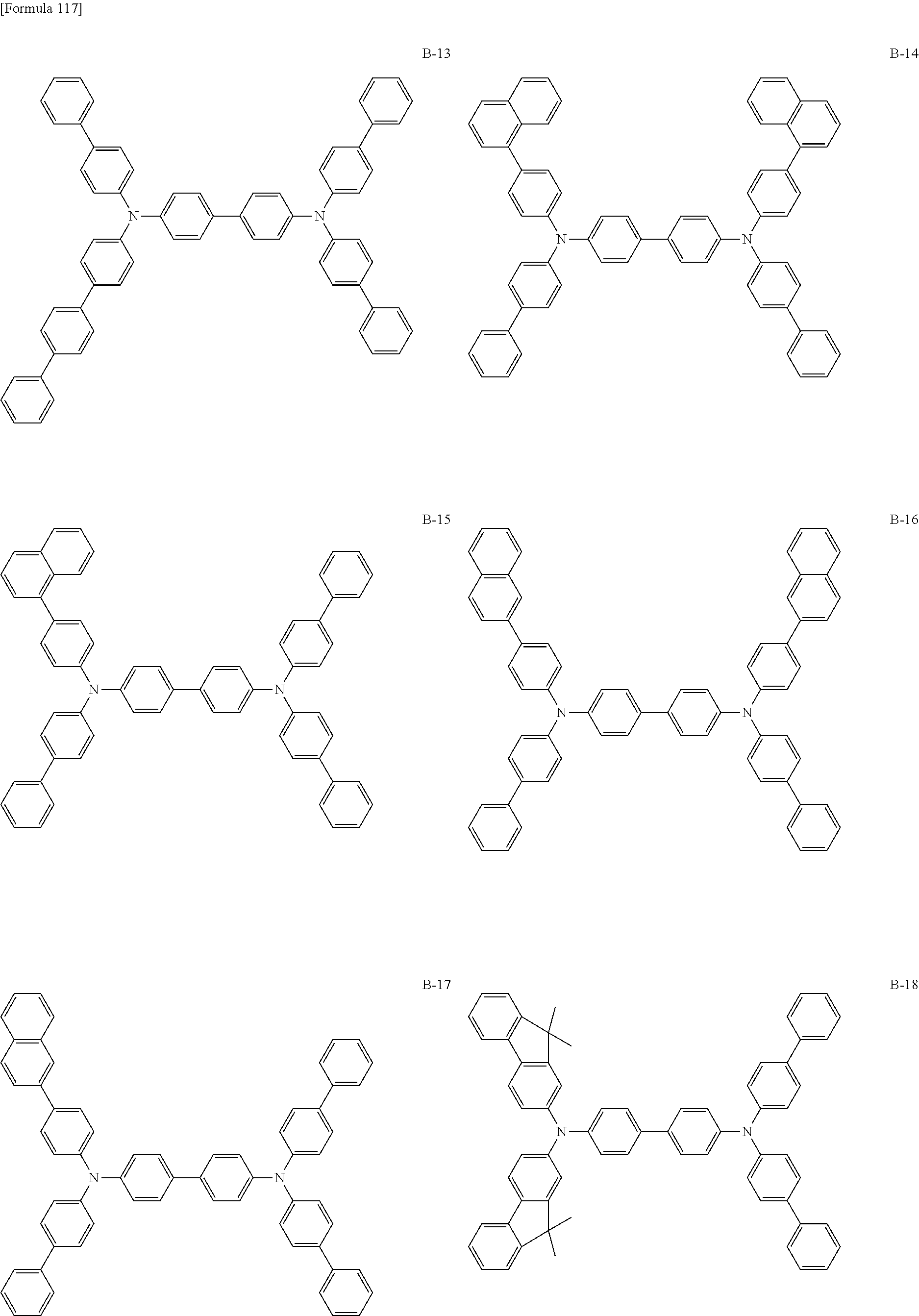

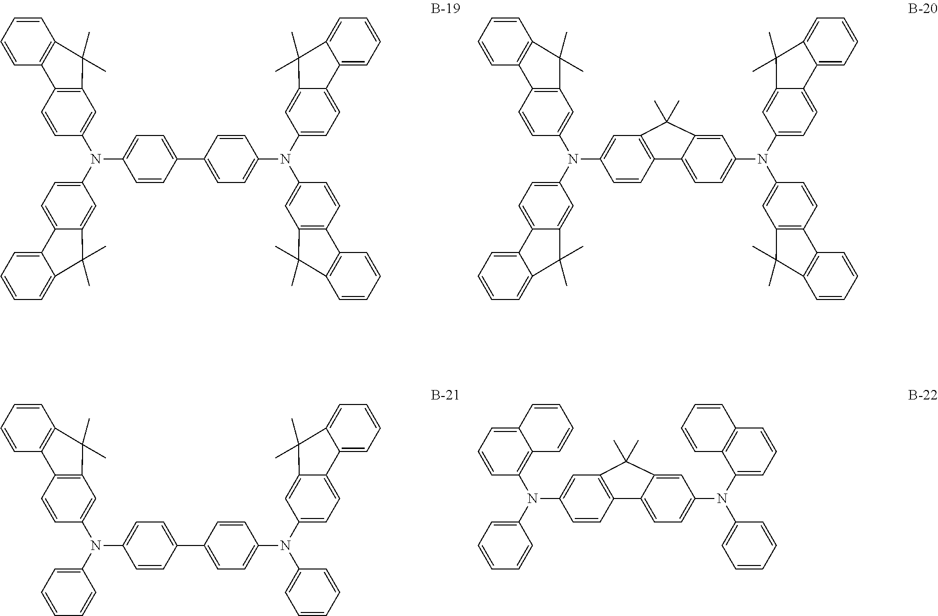 [SMILES: CC1(C)c2ccccc2-c2ccc(N(c3ccc(-c4ccc(N(c5ccc6c(c5)C(C)(C)c5ccccc5-6)c5ccc6c(c5)C(C)(C)c5ccccc5-6)cc4)cc3)c3ccc4c(c3)C(C)(C)c3ccccc3-4)cc21 ; CC1(C)c2ccccc2-c2ccc(N(c3ccc4c(c3)C(C)(C)c3ccccc3-4)c3ccc4c(c3)C(C)(C)c3cc(N(c5ccc6c(c5)C(C)(C)c5ccccc5-6)c5ccc6c(c5)C(C)(C)c5ccccc5-6)ccc3-4)cc21 ; CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21 ; CC1(C)c2cc(N(c3ccccc3)c3cccc4ccccc34)ccc2-c2ccc(N(c3ccccc3)c3cccc4ccccc34)cc21]

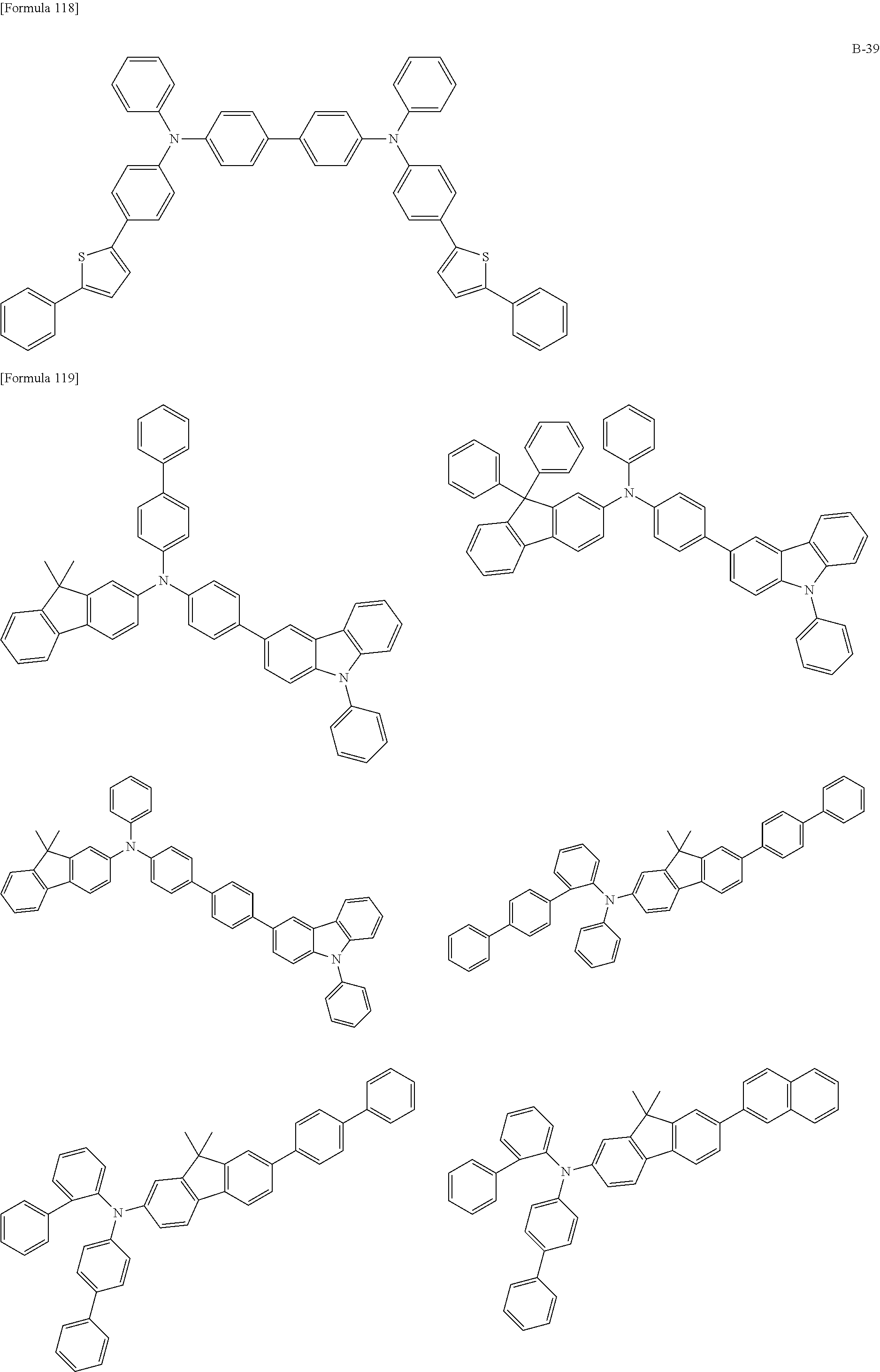

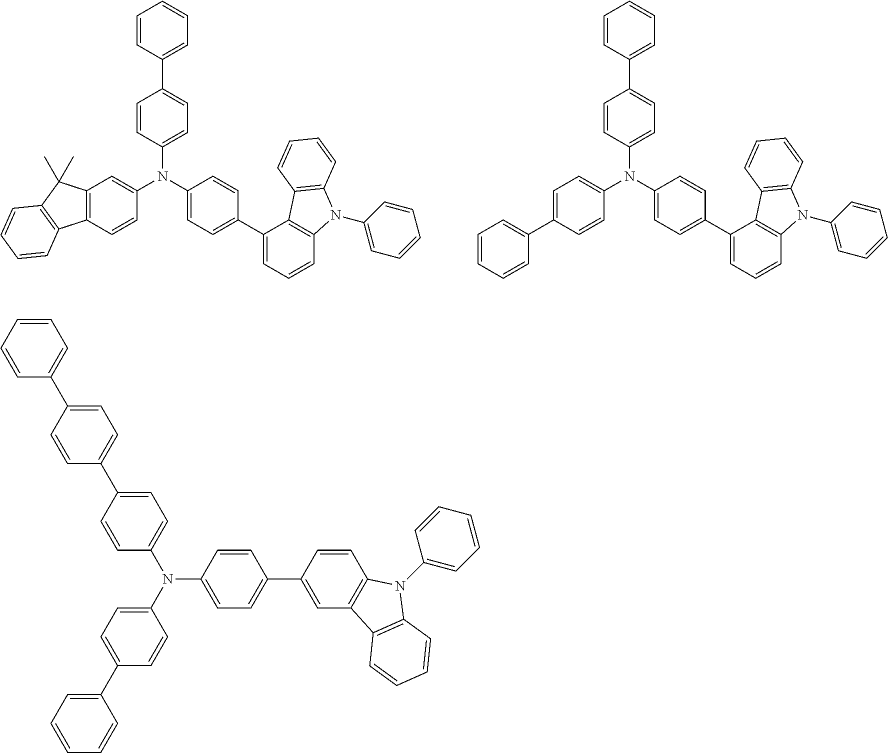 [SMILES: CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc(-c4cccc5c4c4ccccc4n5-c4ccccc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

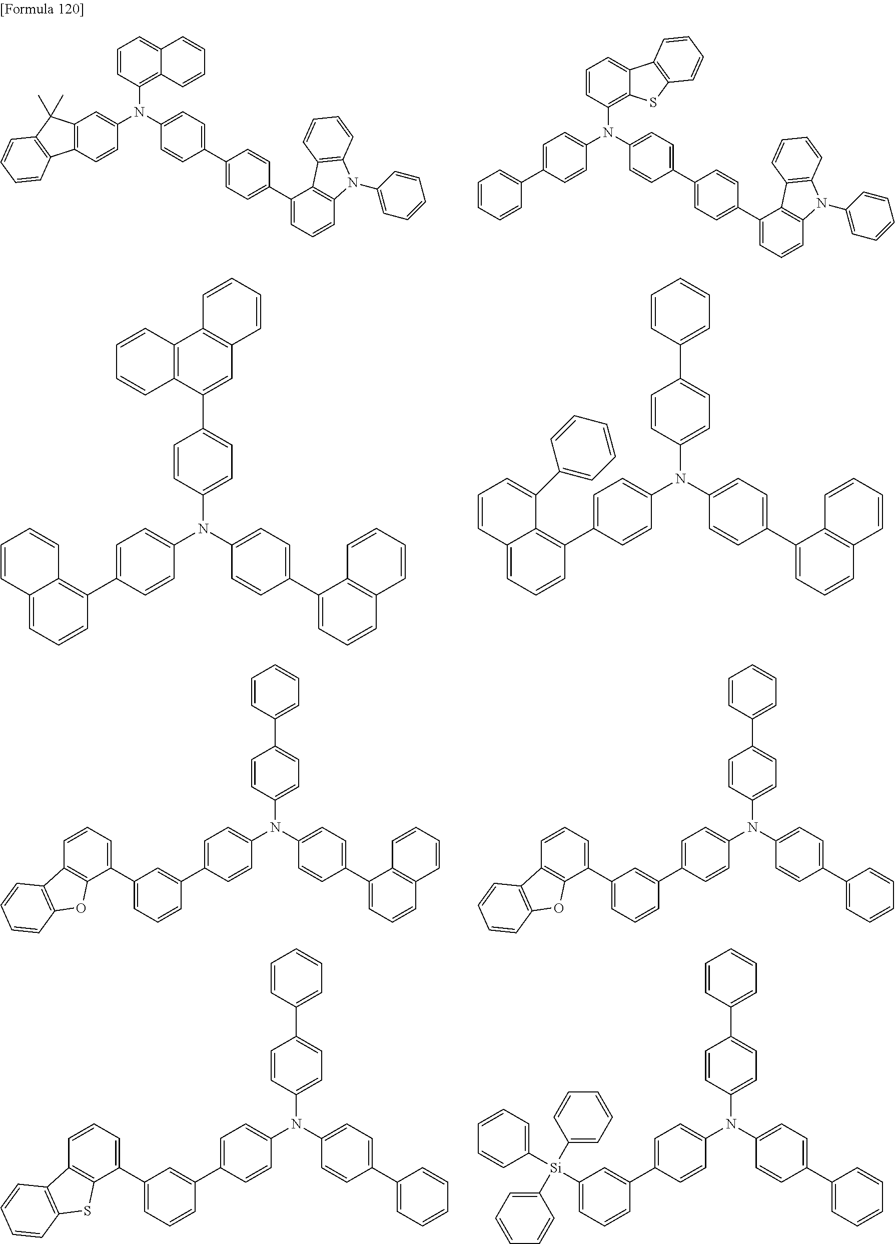

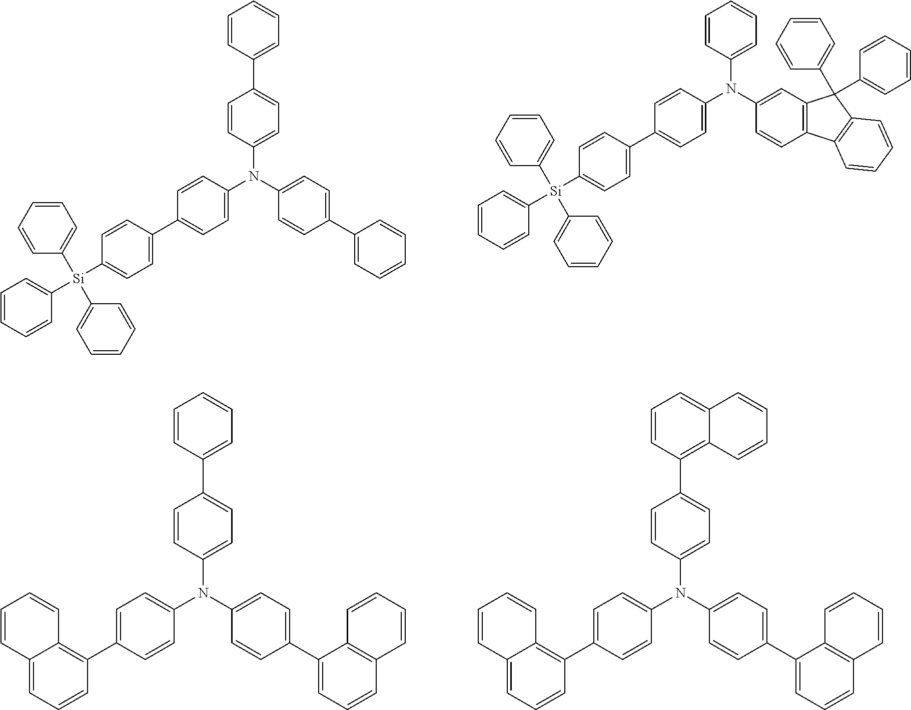 [SMILES: c1ccc(-c2ccc(N(c3ccc(-c4ccccc4)cc3)c3ccc(-c4ccc([Si](c5ccccc5)(c5ccccc5)c5ccccc5)cc4)cc3)cc2)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1 ; c1ccc(-c2ccc(N(c3ccc(-c4cccc5ccccc45)cc3)c3ccc(-c4cccc5ccccc45)cc3)cc2)cc1 ; c1ccc2c(-c3ccc(N(c4ccc(-c5cccc6ccccc56)cc4)c4ccc(-c5cccc6ccccc56)cc4)cc3)cccc2c1]

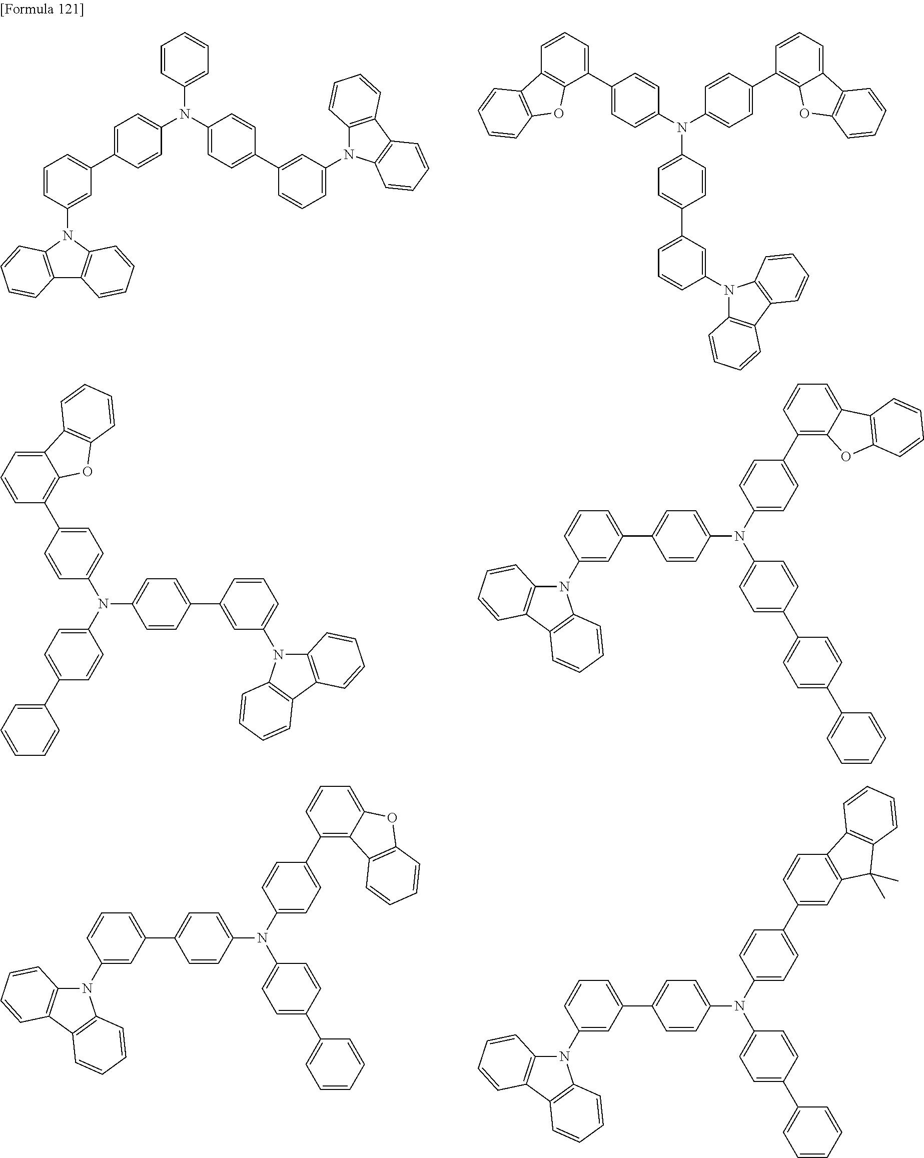

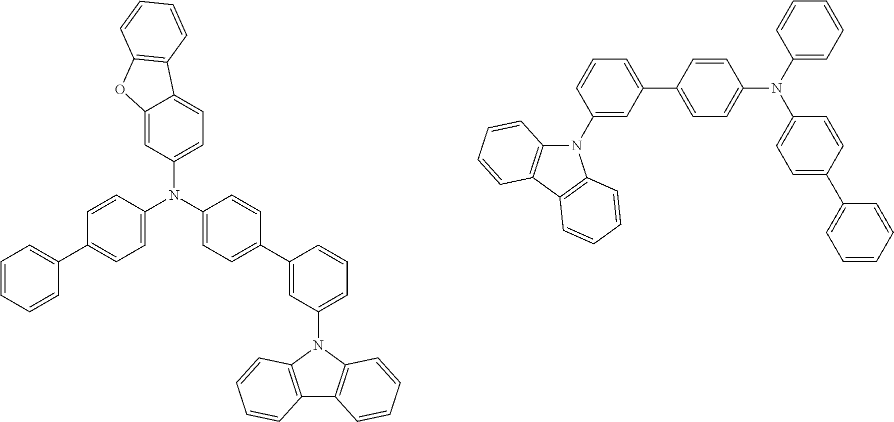 [SMILES: c1ccc(-c2ccc(N(c3ccc(-c4cccc(-n5c6ccccc6c6ccccc65)c4)cc3)c3ccc4c(c3)oc3ccccc34)cc2)cc1 ; c1ccc(-c2ccc(N(c3ccccc3)c3ccc(-c4cccc(-n5c6ccccc6c6ccccc65)c4)cc3)cc2)cc1]

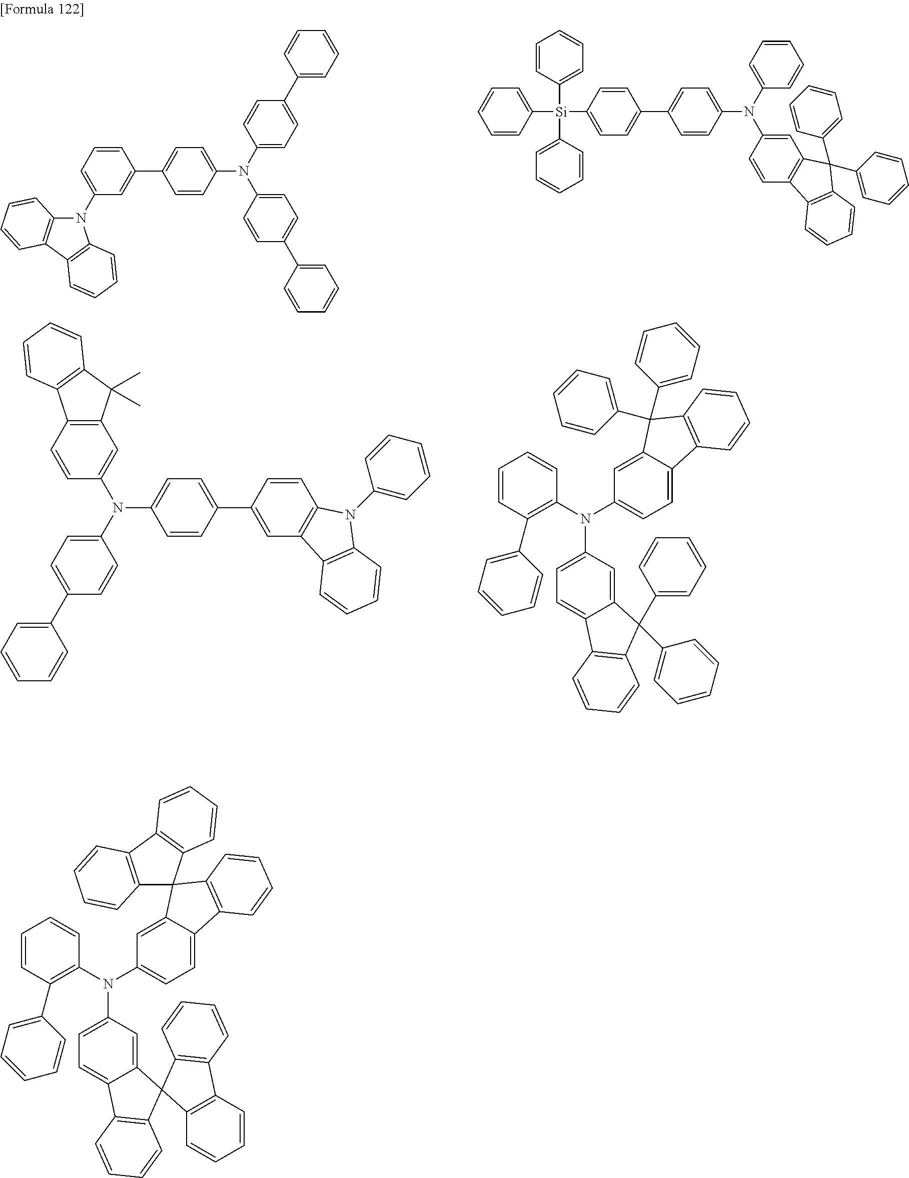

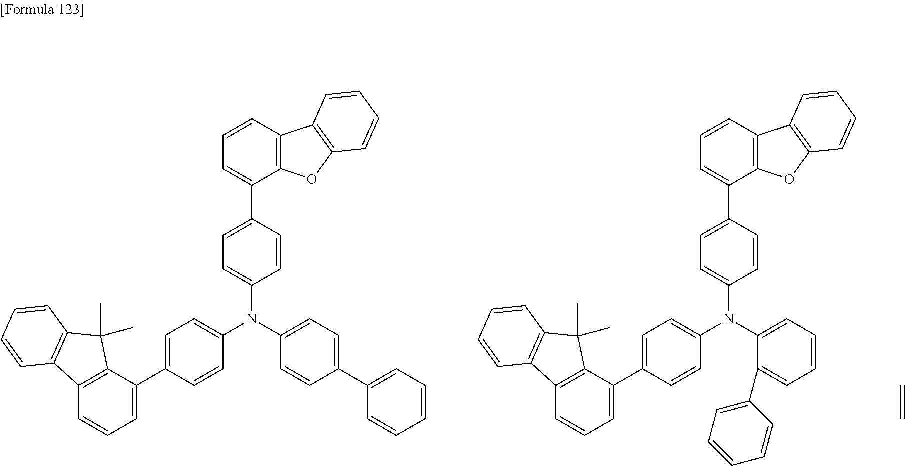

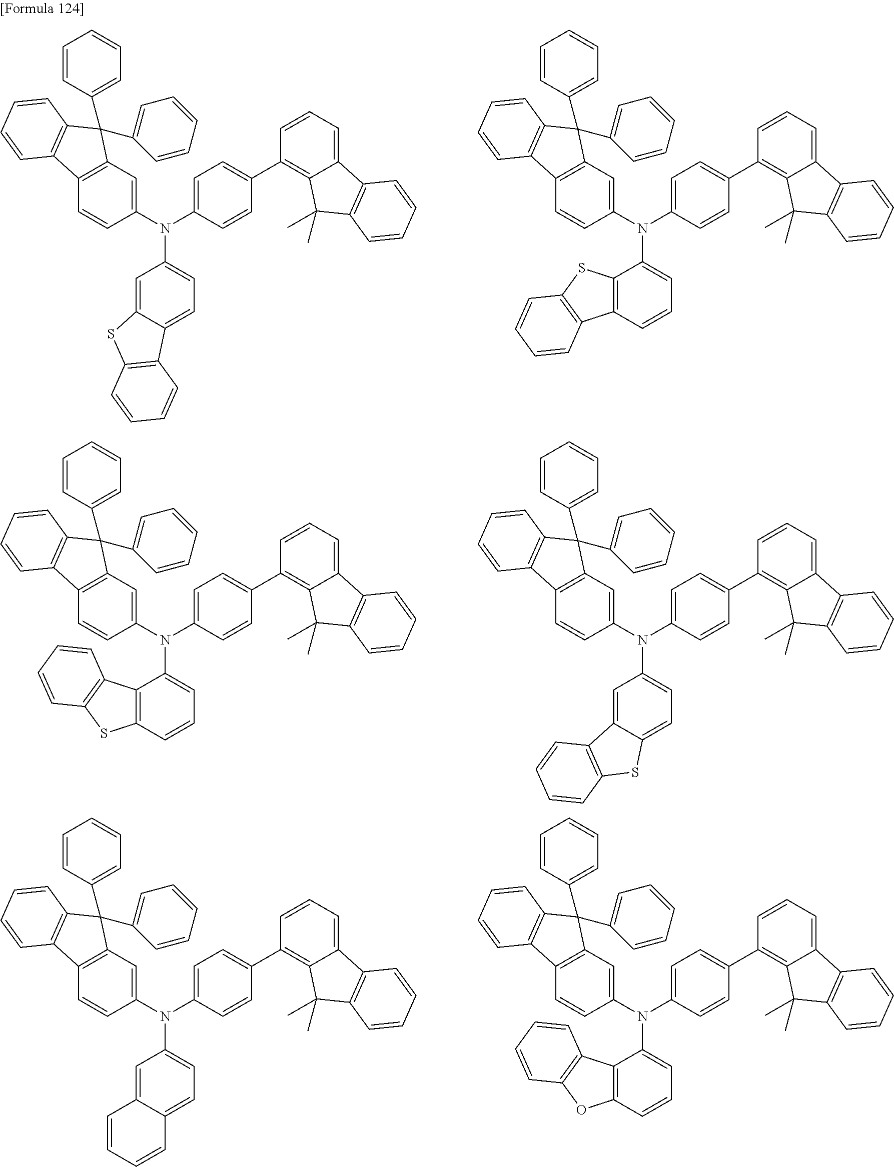

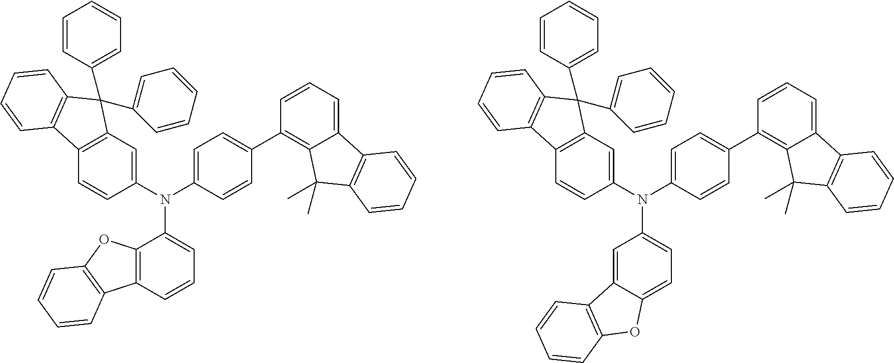 [SMILES: CC1(C)c2ccccc2-c2cccc(-c3ccc(N(c4ccc5c(c4)C(c4ccccc4)(c4ccccc4)c4ccccc4-5)c4cccc5c4oc4ccccc45)cc3)c21 ; CC1(C)c2ccccc2-c2cccc(-c3ccc(N(c4ccc5c(c4)C(c4ccccc4)(c4ccccc4)c4ccccc4-5)c4ccc5oc6ccccc6c5c4)cc3)c21]

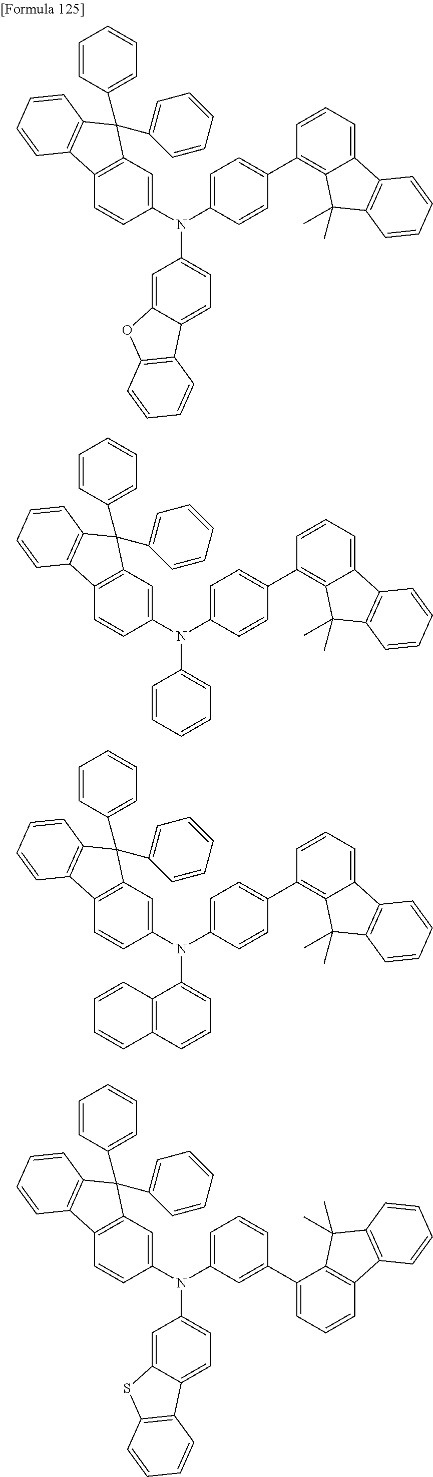

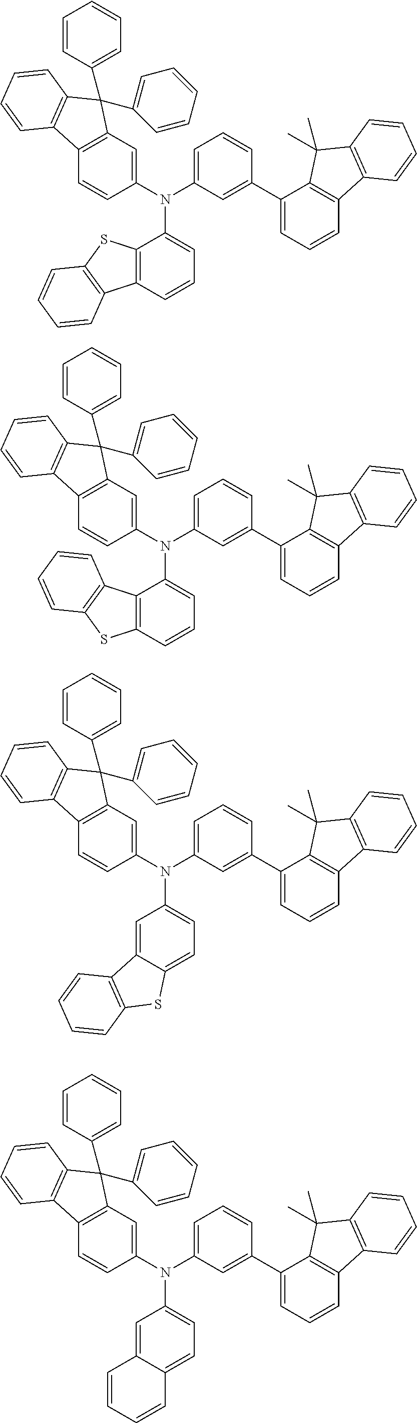

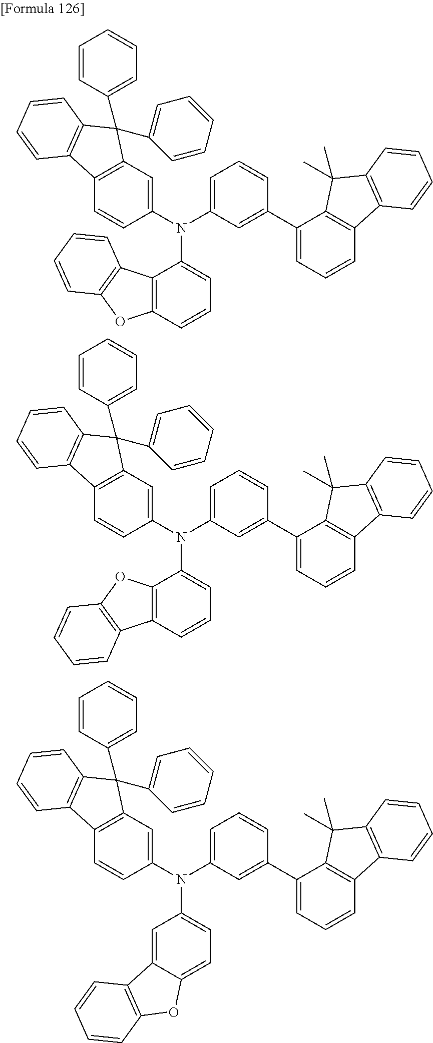

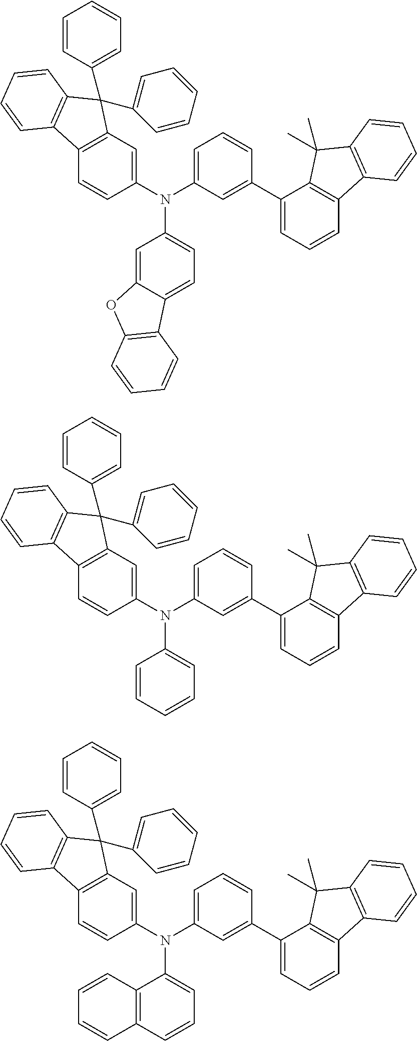

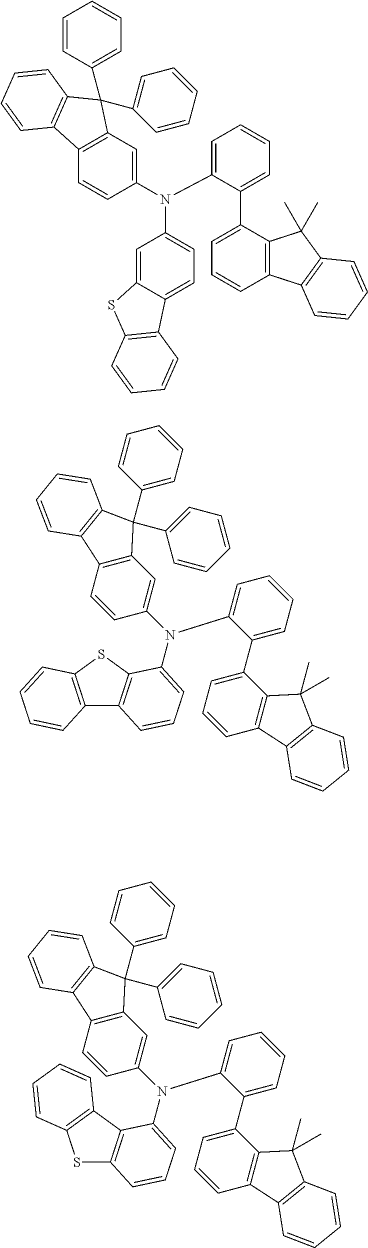

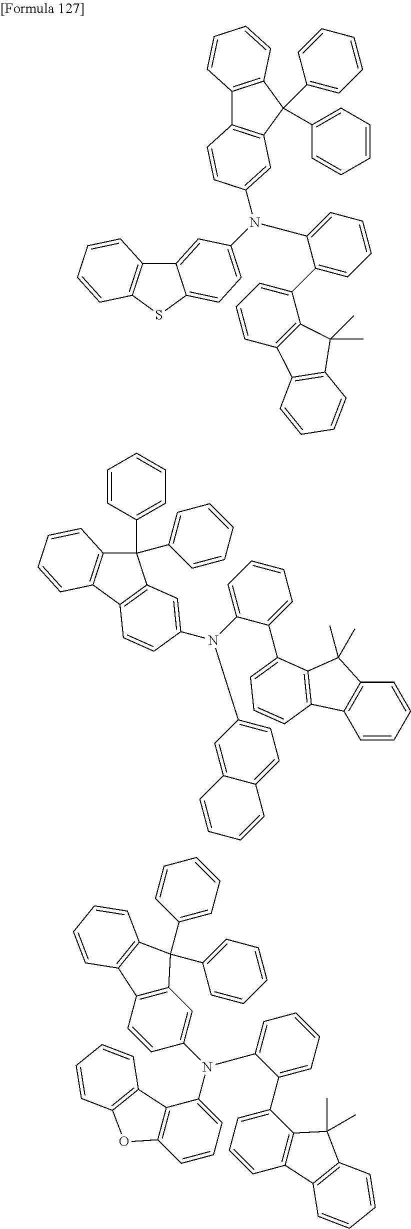

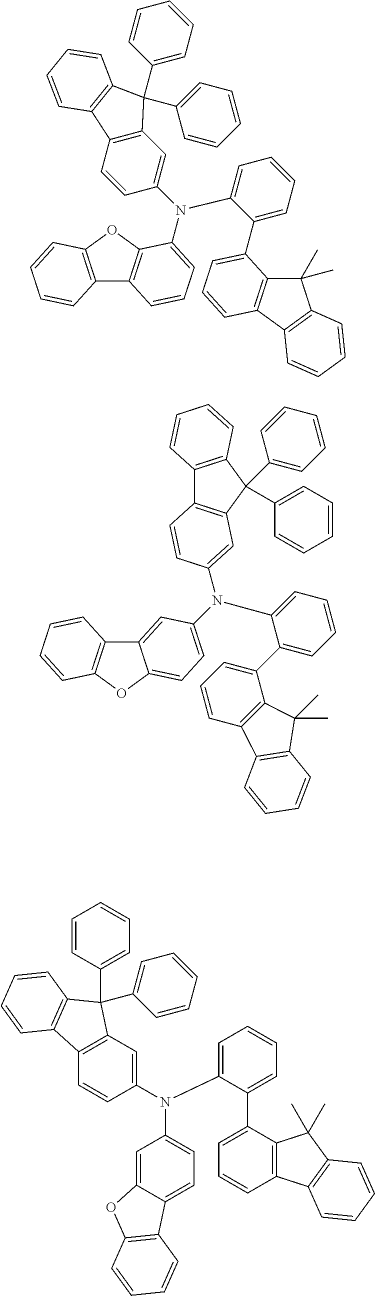

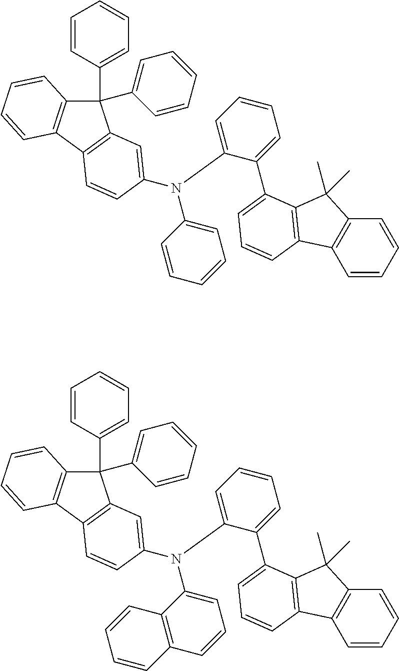 [SMILES: CC1(C)c2ccccc2-c2cccc(-c3ccccc3N(c3ccccc3)c3ccc4c(c3)C(c3ccccc3)(c3ccccc3)c3ccccc3-4)c21 ; CC1(C)c2ccccc2-c2cccc(-c3ccccc3N(c3ccc4c(c3)C(c3ccccc3)(c3ccccc3)c3ccccc3-4)c3cccc4ccccc34)c21]

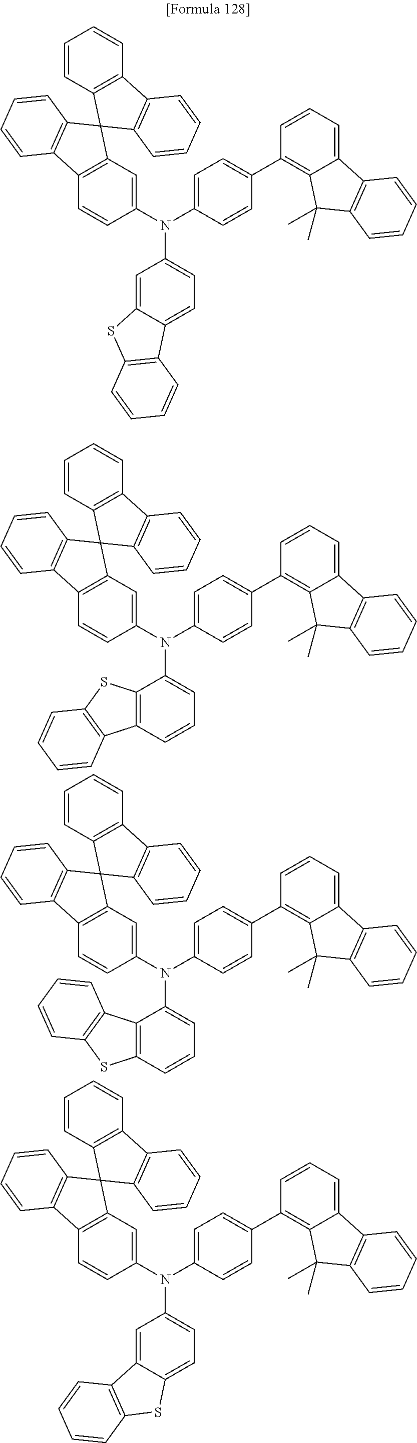

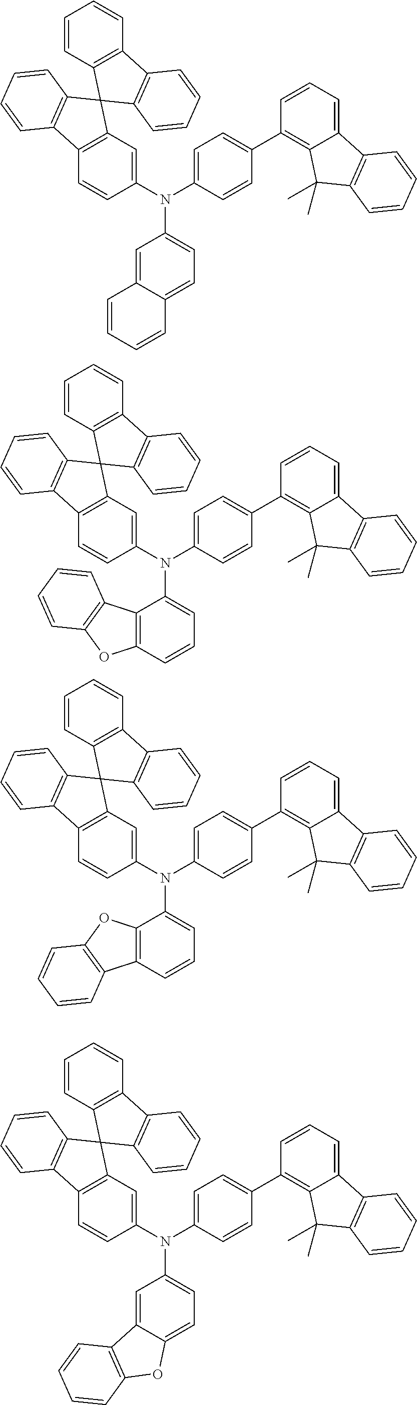

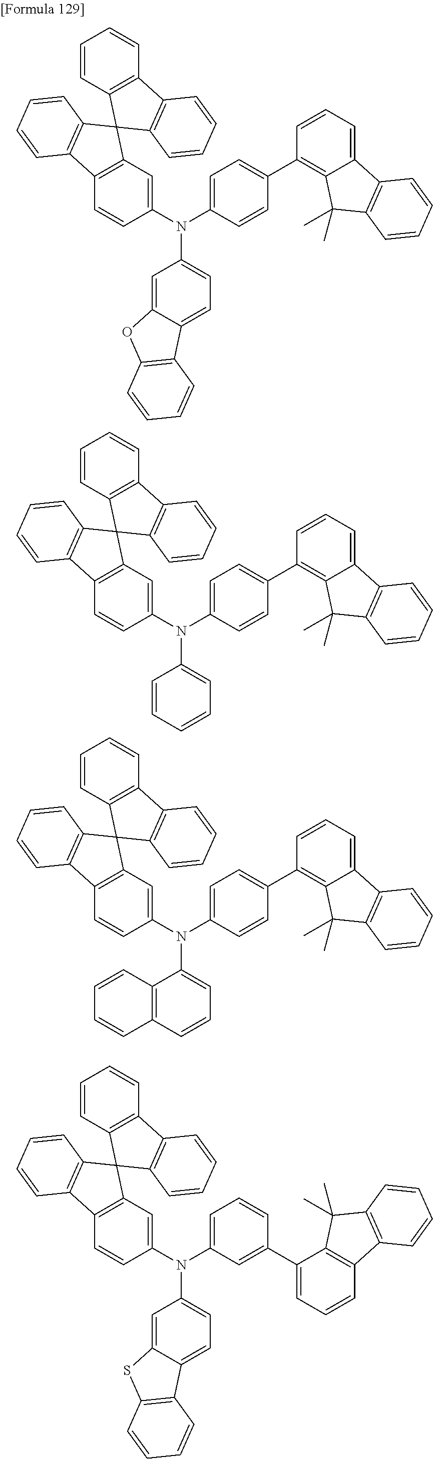

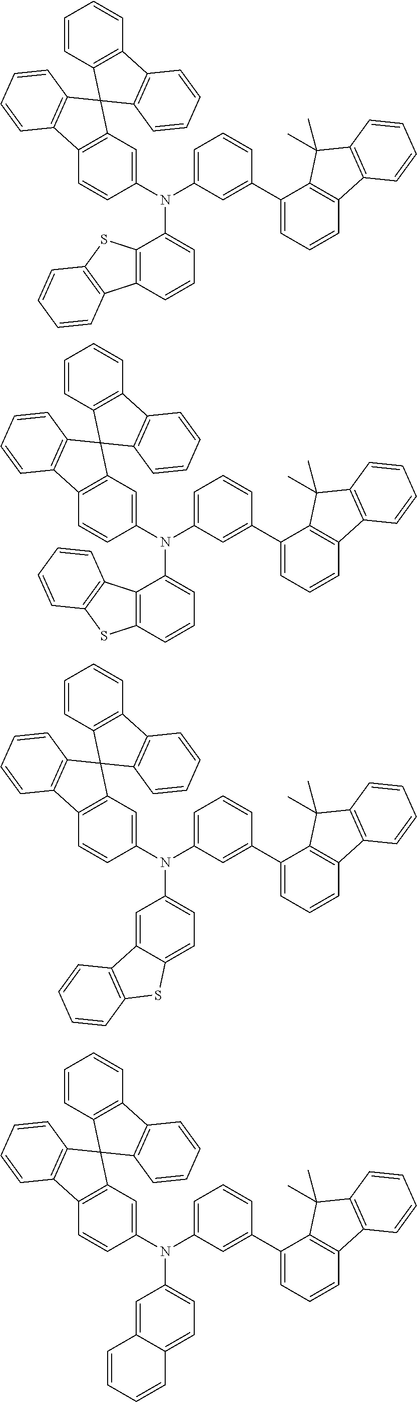

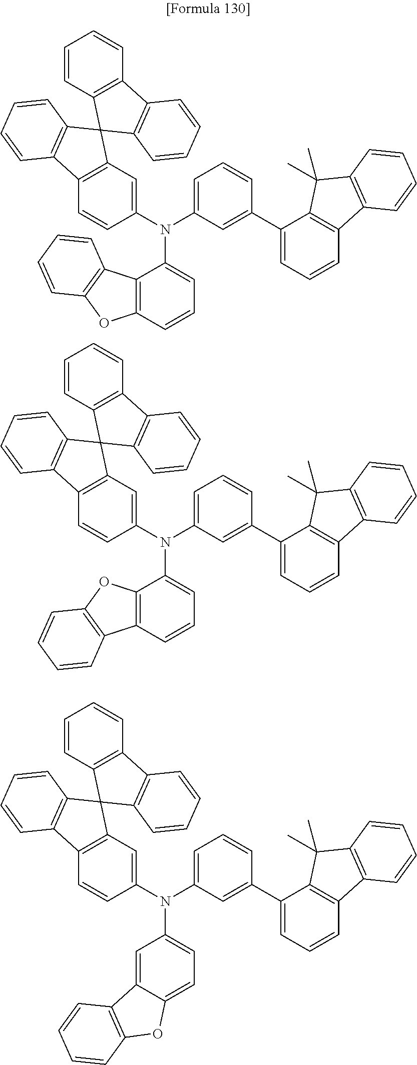

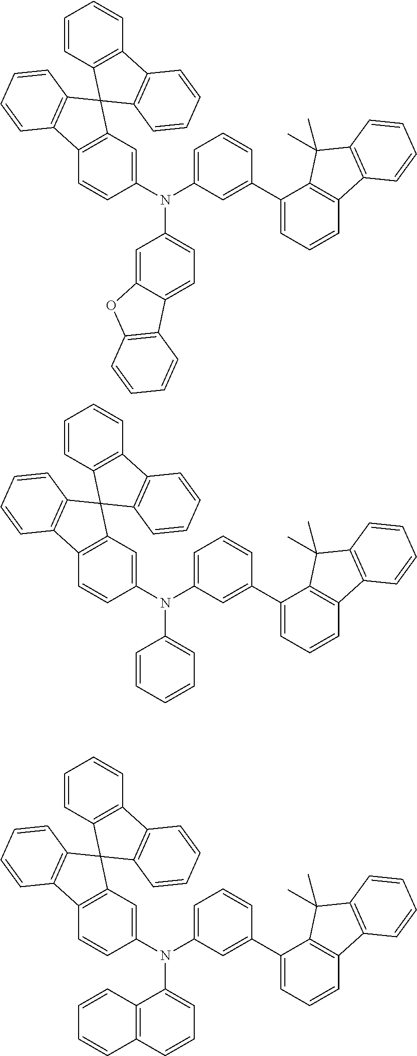

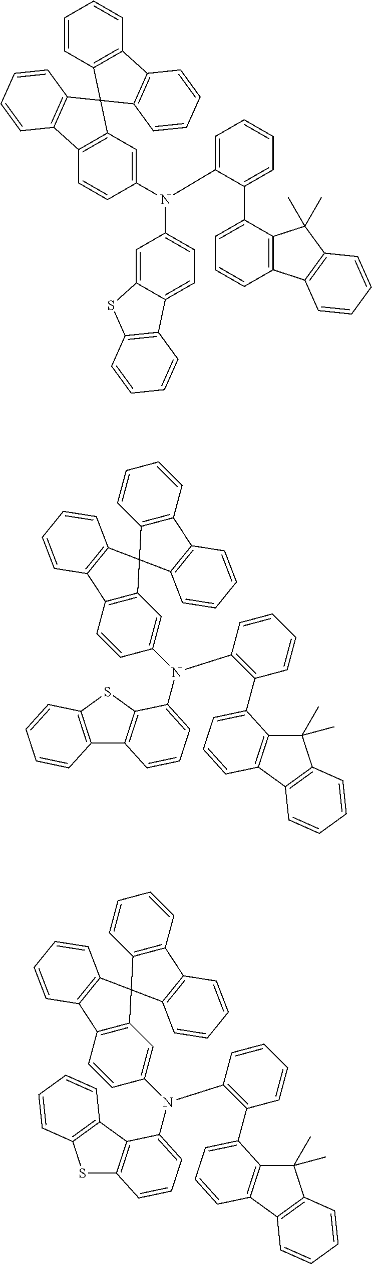 [SMILES: CC1(C)c2ccccc2-c2cccc(-c3ccccc3N(c3ccc4c(c3)C3(c5ccccc5-c5ccccc53)c3ccccc3-4)c3ccc4c(c3)sc3ccccc34)c21 ; CC1(C)c2ccccc2-c2cccc(-c3ccccc3N(c3ccc4c(c3)C3(c5ccccc5-c5ccccc53)c3ccccc3-4)c3cccc4c3sc3ccccc34)c21 ; CC1(C)c2ccccc2-c2cccc(-c3ccccc3N(c3ccc4c(c3)C3(c5ccccc5-c5ccccc53)c3ccccc3-4)c3cccc4sc5ccccc5c34)c21]

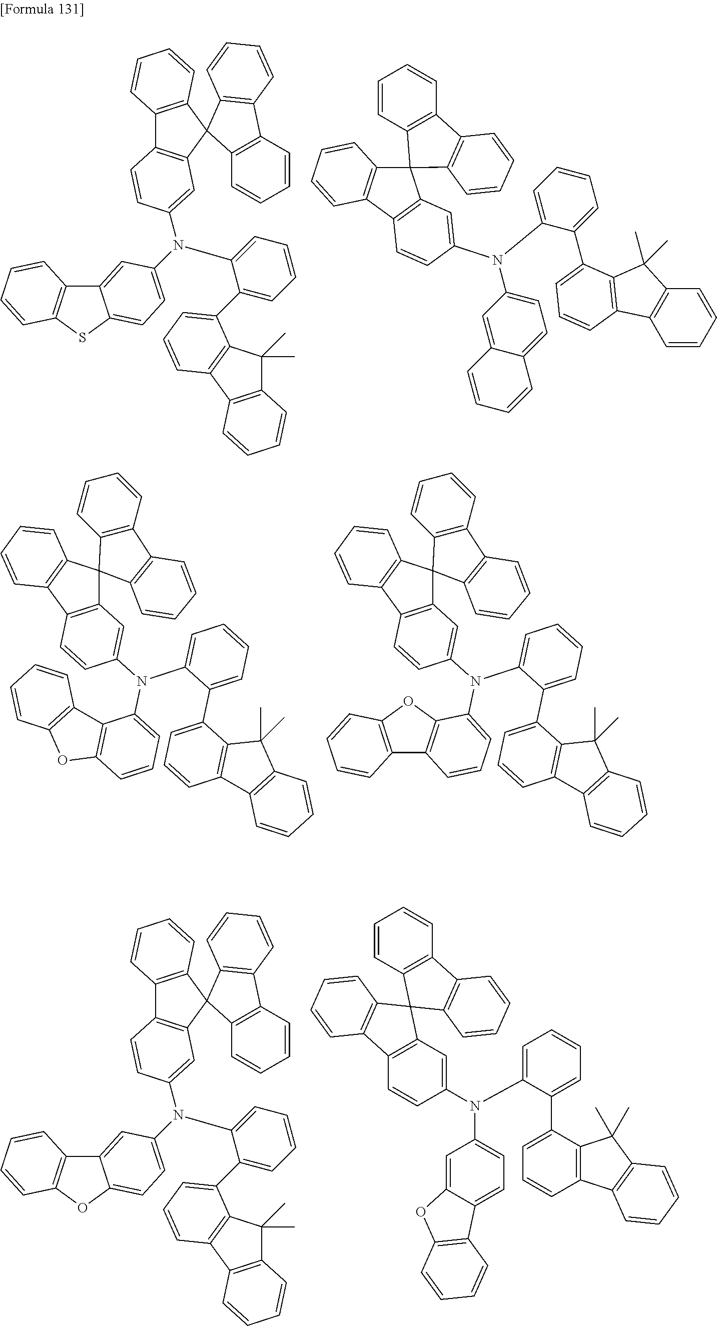

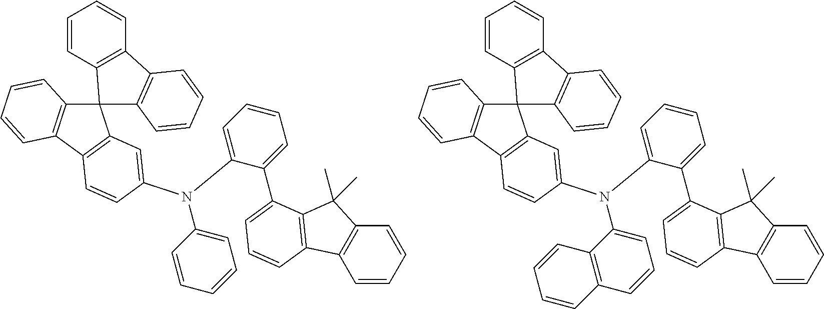 [SMILES: CC1(C)c2ccccc2-c2cccc(-c3ccccc3N(c3ccccc3)c3ccc4c(c3)C3(c5ccccc5-c5ccccc53)c3ccccc3-4)c21 ; CC1(C)c2ccccc2-c2cccc(-c3ccccc3N(c3ccc4c(c3)C3(c5ccccc5-c5ccccc53)c3ccccc3-4)c3cccc4ccccc34)c21]

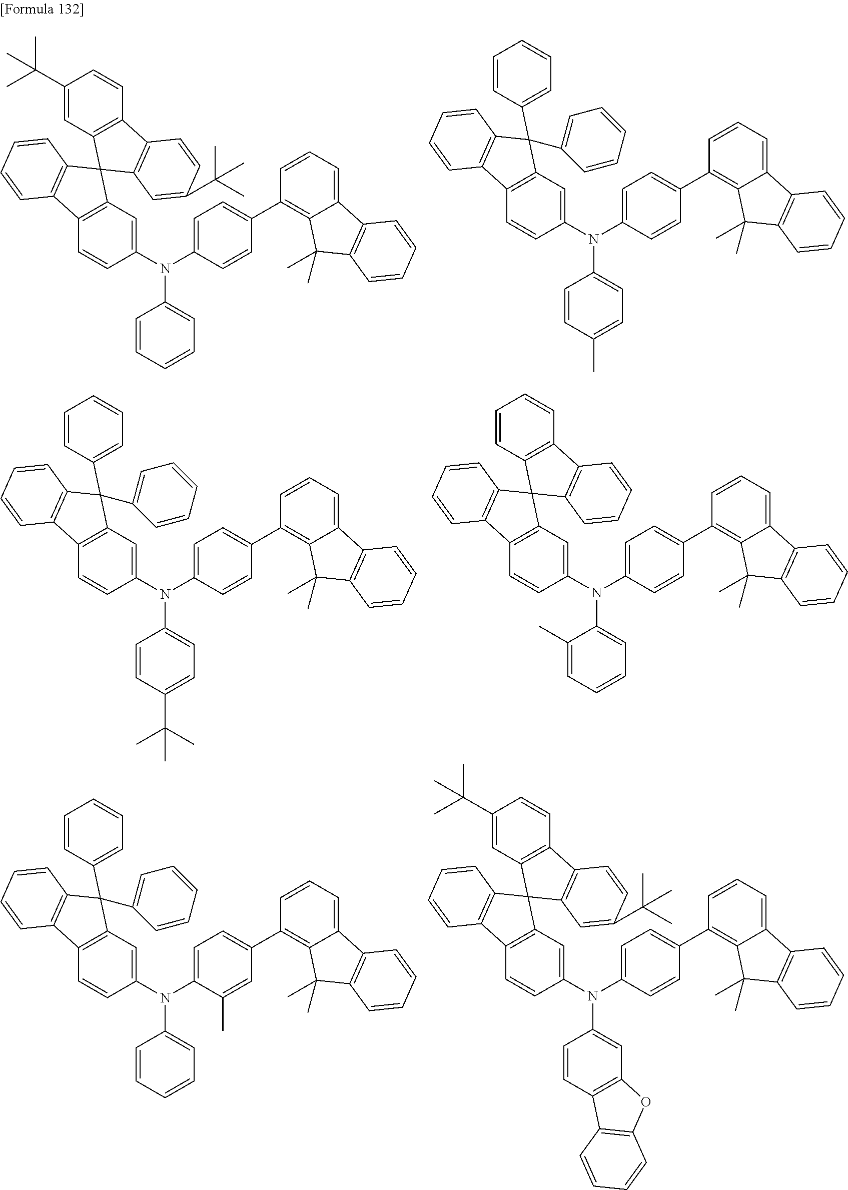

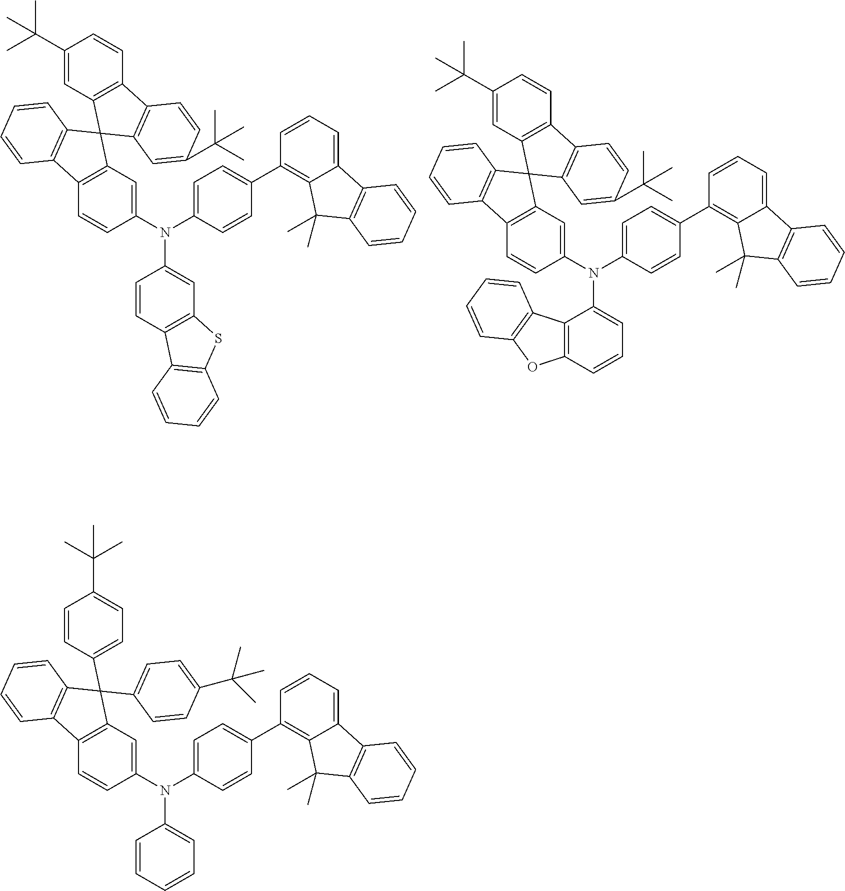

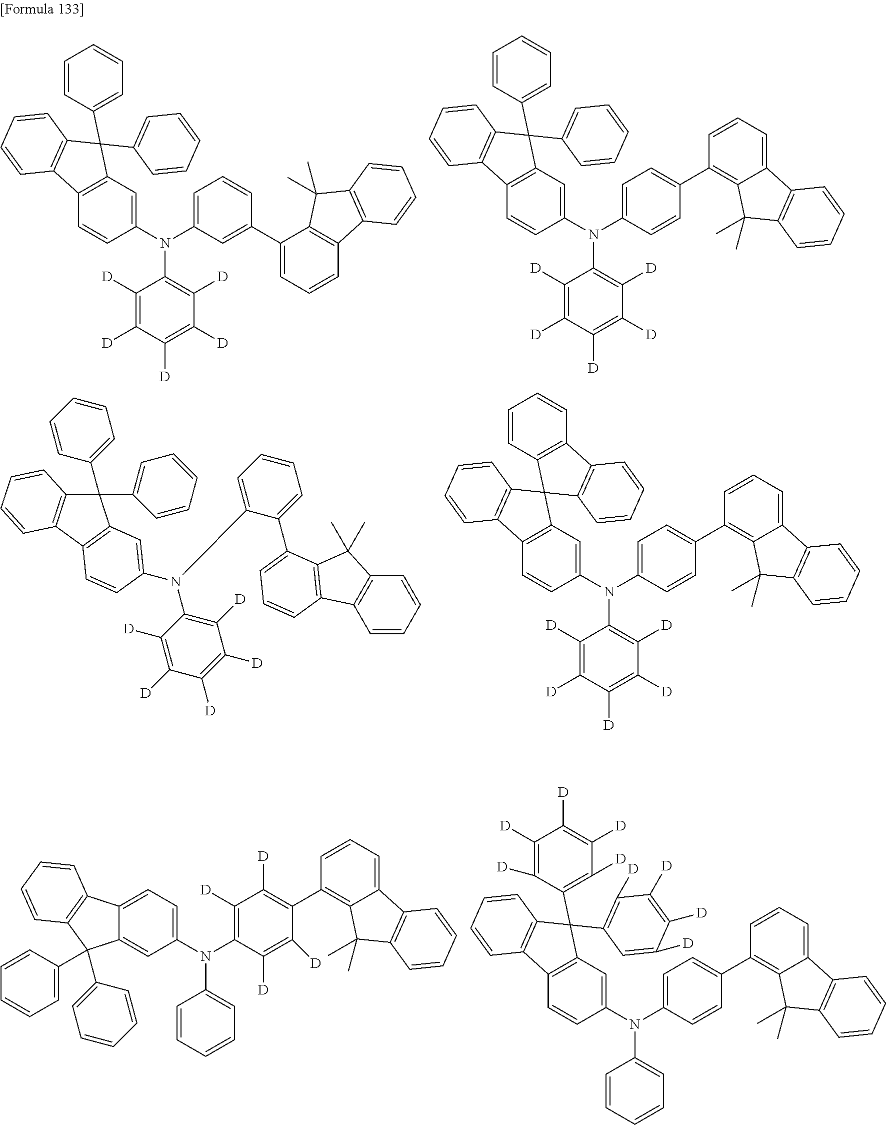

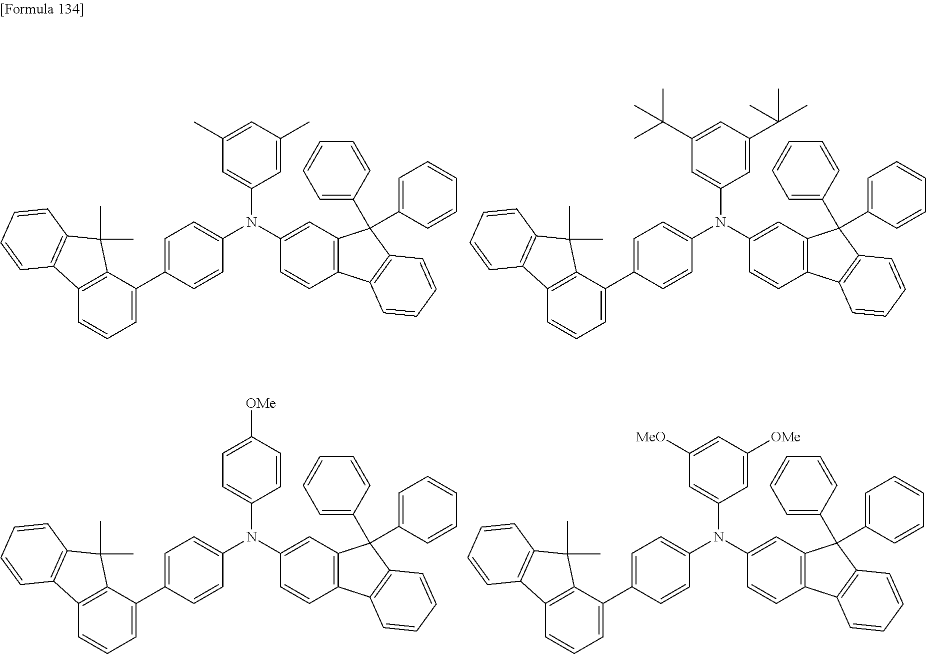

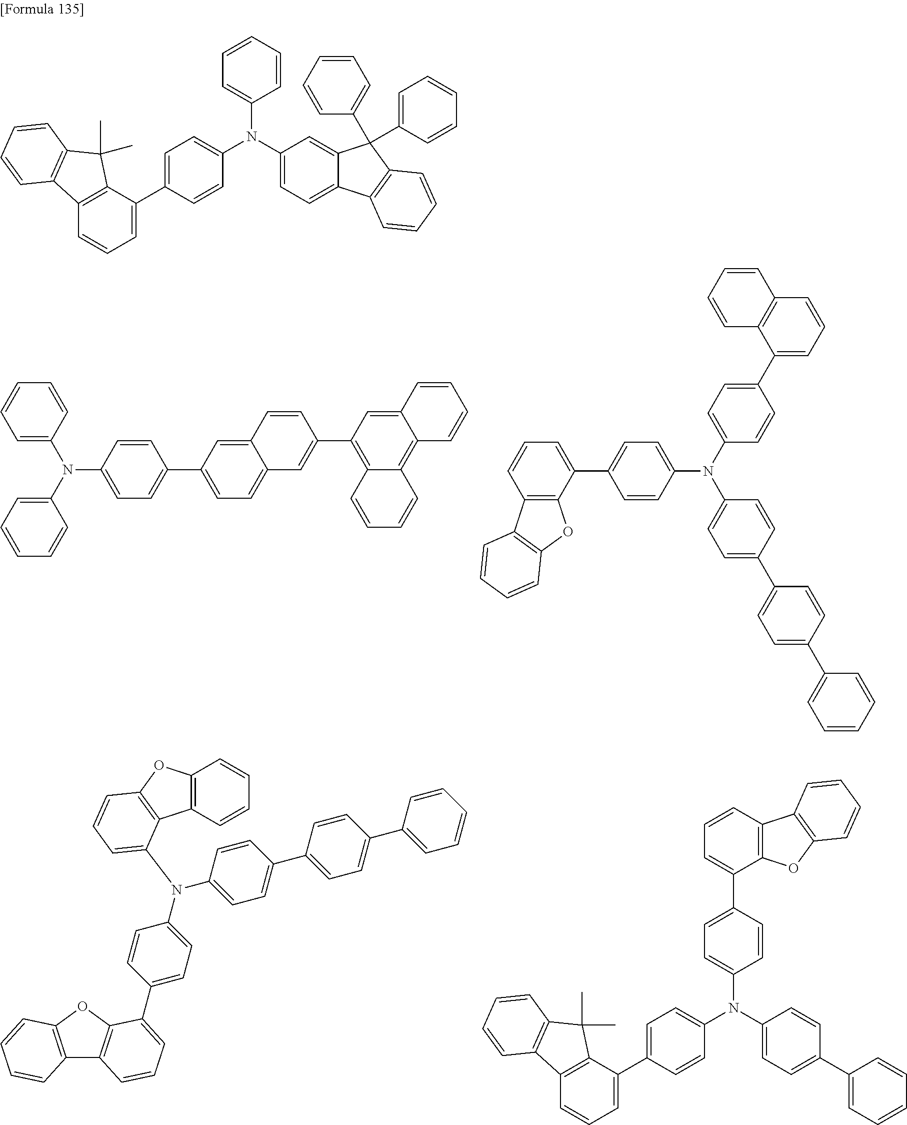 [SMILES: CC1(C)c2ccccc2-c2cccc(-c3ccc(N(c4ccccc4)c4ccc5c(c4)C(c4ccccc4)(c4ccccc4)c4ccccc4-5)cc3)c21 ; c1ccc(N(c2ccccc2)c2ccc(-c3ccc4cc(-c5cc6ccccc6c6ccccc56)ccc4c3)cc2)cc1 ; c1ccc(-c2ccc(-c3ccc(N(c4ccc(-c5cccc6ccccc56)cc4)c4ccc(-c5cccc6c5oc5ccccc56)cc4)cc3)cc2)cc1 ; c1ccc(-c2ccc(-c3ccc(N(c4ccc(-c5cccc6c5oc5ccccc56)cc4)c4cccc5oc6ccccc6c45)cc3)cc2)cc1 ; CC1(C)c2ccccc2-c2cccc(-c3ccc(N(c4ccc(-c5ccccc5)cc4)c4ccc(-c5cccc6c5oc5ccccc56)cc4)cc3)c21]

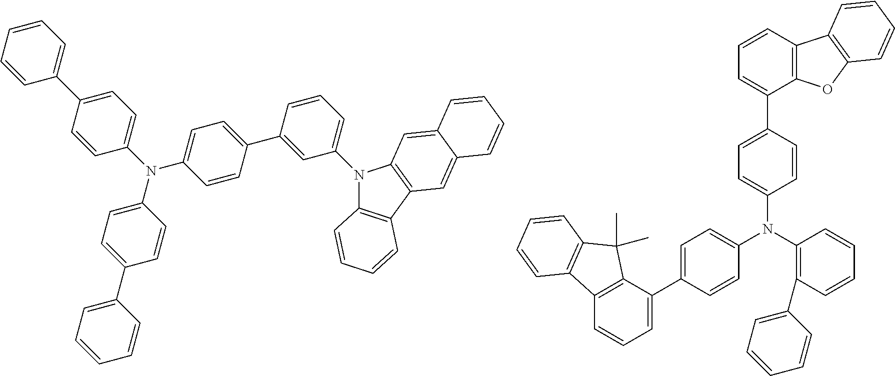 [SMILES: c1ccc(-c2ccc(N(c3ccc(-c4ccccc4)cc3)c3ccc(-c4cccc(-n5c6ccccc6c6cc7ccccc7cc65)c4)cc3)cc2)cc1 ; CC1(C)c2ccccc2-c2cccc(-c3ccc(N(c4ccc(-c5cccc6c5oc5ccccc56)cc4)c4ccccc4-c4ccccc4)cc3)c21]

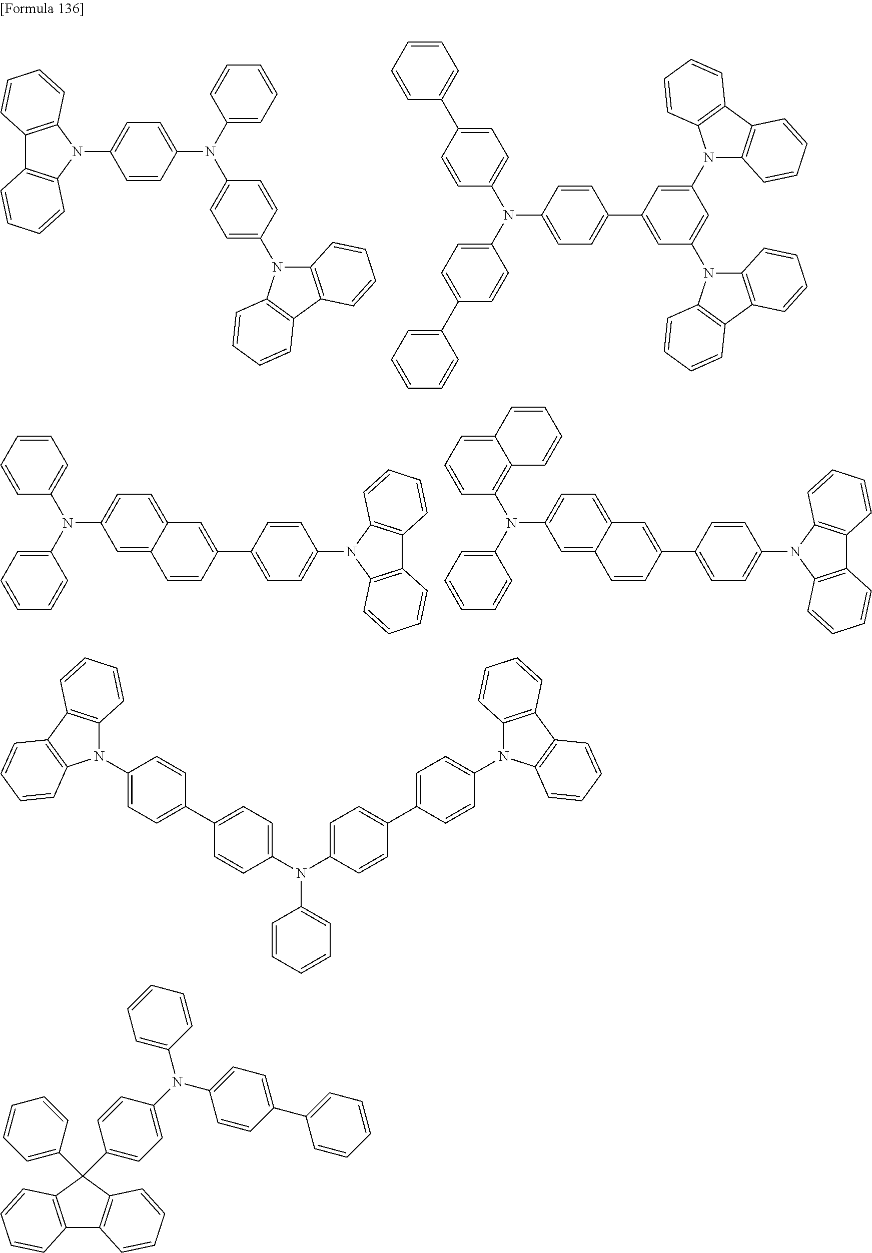

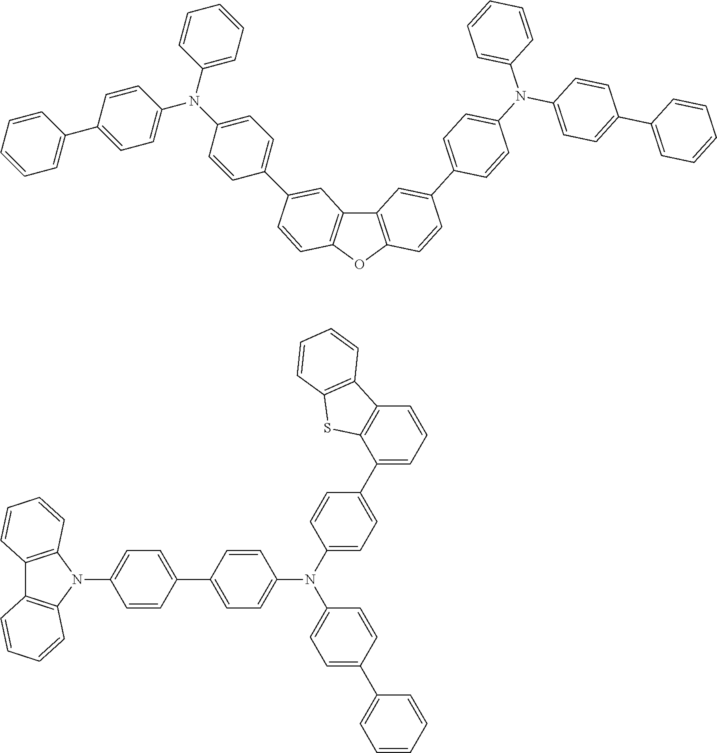 [SMILES: c1ccc(-c2ccc(N(c3ccccc3)c3ccc(-c4ccc5oc6ccc(-c7ccc(N(c8ccccc8)c8ccc(-c9ccccc9)cc8)cc7)cc6c5c4)cc3)cc2)cc1 ; c1ccc(-c2ccc(N(c3ccc(-c4ccc(-n5c6ccccc6c6ccccc65)cc4)cc3)c3ccc(-c4cccc5c4sc4ccccc45)cc3)cc2)cc1]

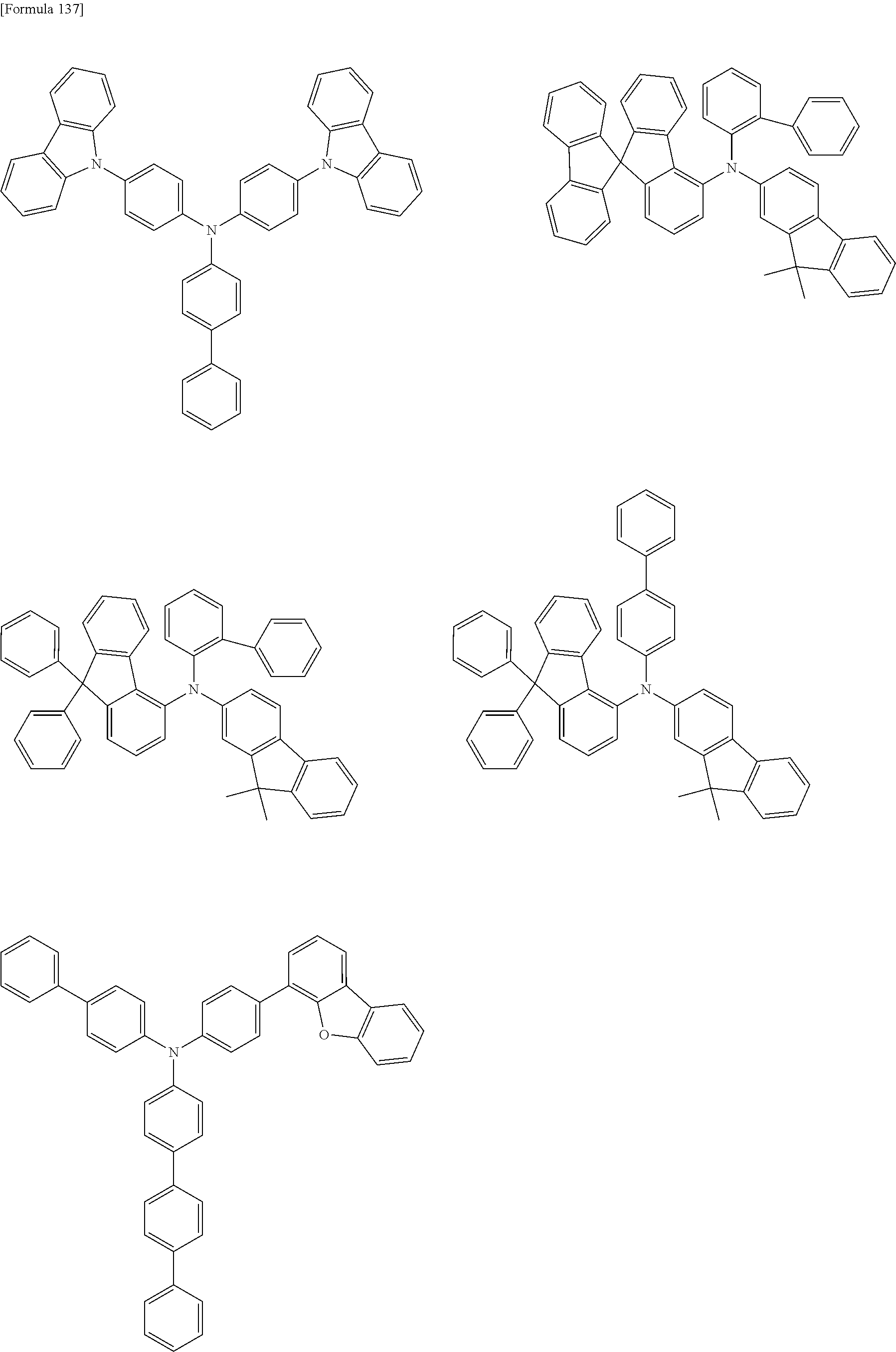 [SMILES: c1ccc(-c2ccc(N(c3ccc(-n4c5ccccc5c5ccccc54)cc3)c3ccc(-n4c5ccccc5c5ccccc54)cc3)cc2)cc1 ; CC1(C)c2ccccc2-c2ccc(N(c3ccccc3-c3ccccc3)c3cccc4c3-c3ccccc3C43c4ccccc4-c4ccccc43)cc21 ; CC1(C)c2ccccc2-c2ccc(N(c3ccccc3-c3ccccc3)c3cccc4c3-c3ccccc3C4(c3ccccc3)c3ccccc3)cc21 ; CC1(C)c2ccccc2-c2ccc(N(c3ccc(-c4ccccc4)cc3)c3cccc4c3-c3ccccc3C4(c3ccccc3)c3ccccc3)cc21 ; c1ccc(-c2ccc(-c3ccc(N(c4ccc(-c5ccccc5)cc4)c4ccc(-c5cccc6c5oc5ccccc56)cc4)cc3)cc2)cc1]

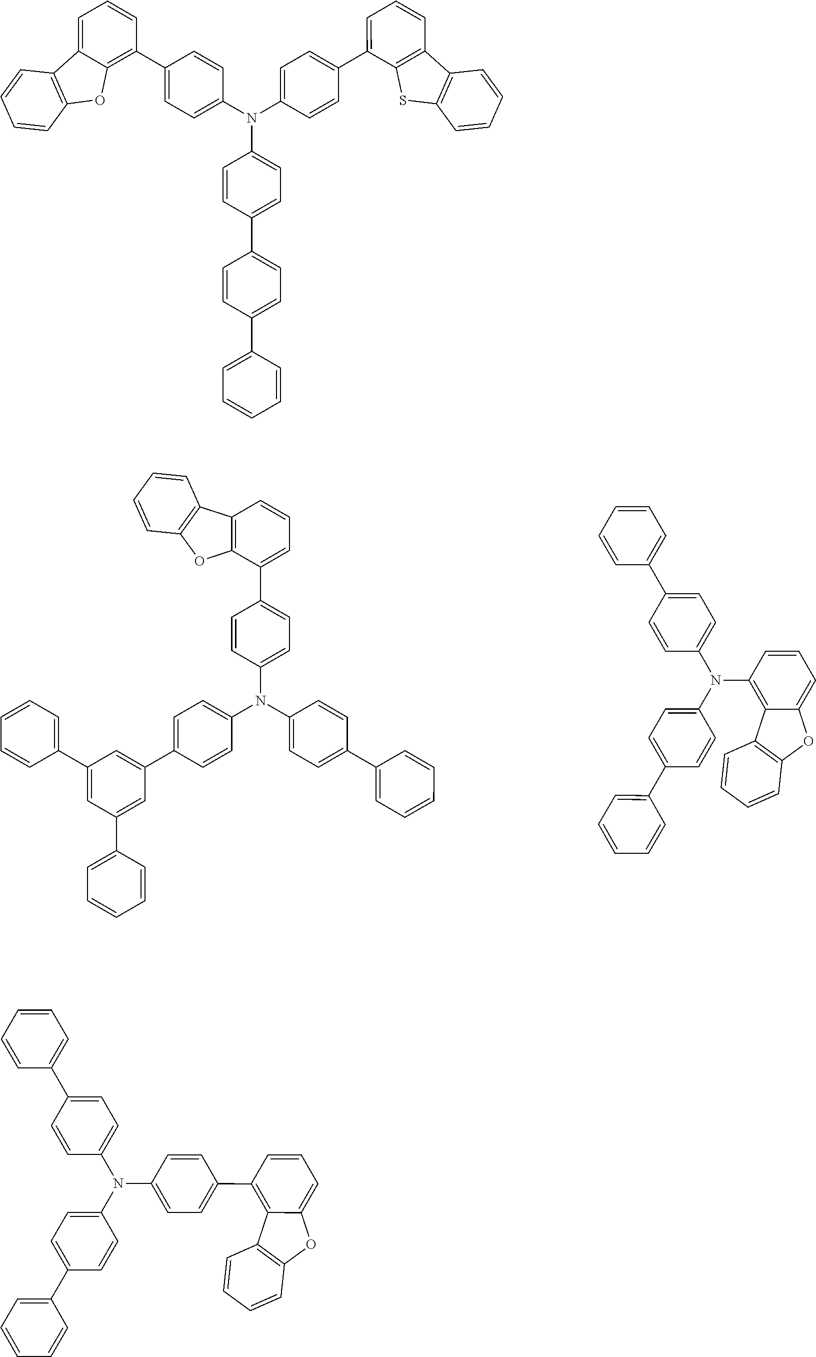 [SMILES: c1ccc(-c2ccc(-c3ccc(N(c4ccc(-c5cccc6c5oc5ccccc56)cc4)c4ccc(-c5cccc6c5sc5ccccc56)cc4)cc3)cc2)cc1 ; c1ccc(-c2ccc(N(c3ccc(-c4cc(-c5ccccc5)cc(-c5ccccc5)c4)cc3)c3ccc(-c4cccc5c4oc4ccccc45)cc3)cc2)cc1 ; c1ccc(-c2ccc(N(c3ccc(-c4ccccc4)cc3)c3cccc4oc5ccccc5c34)cc2)cc1 ; c1ccc(-c2ccc(N(c3ccc(-c4ccccc4)cc3)c3ccc(-c4cccc5oc6ccccc6c45)cc3)cc2)cc1]

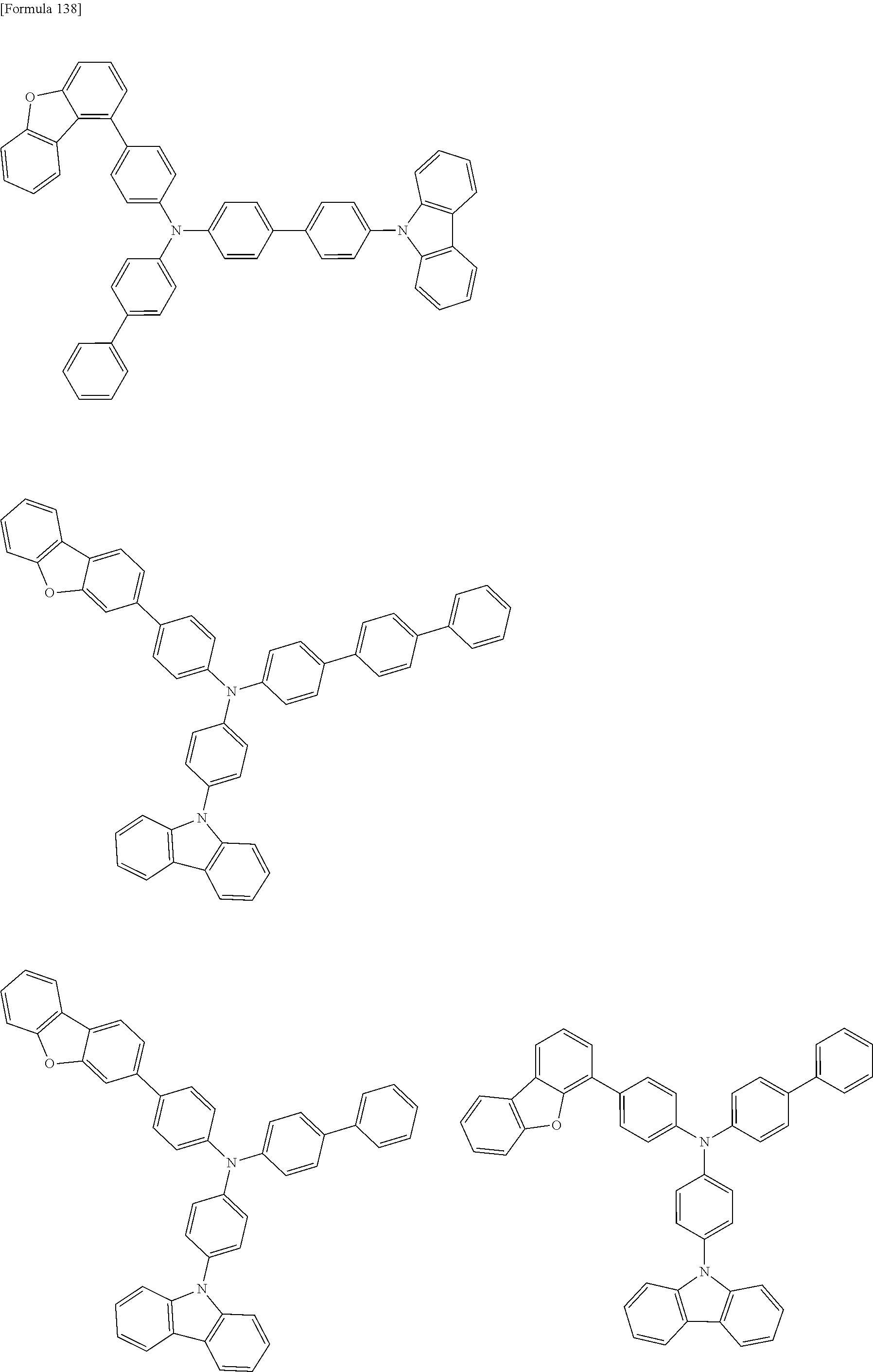 [SMILES: c1ccc(-c2ccc(N(c3ccc(-c4ccc(-n5c6ccccc6c6ccccc65)cc4)cc3)c3ccc(-c4cccc5oc6ccccc6c45)cc3)cc2)cc1 ; c1ccc(-c2ccc(-c3ccc(N(c4ccc(-c5ccc6c(c5)oc5ccccc56)cc4)c4ccc(-n5c6ccccc6c6ccccc65)cc4)cc3)cc2)cc1 ; c1ccc(-c2ccc(N(c3ccc(-c4ccc5c(c4)oc4ccccc45)cc3)c3ccc(-n4c5ccccc5c5ccccc54)cc3)cc2)cc1 ; c1ccc(-c2ccc(N(c3ccc(-c4cccc5c4oc4ccccc45)cc3)c3ccc(-n4c5ccccc5c5ccccc54)cc3)cc2)cc1]

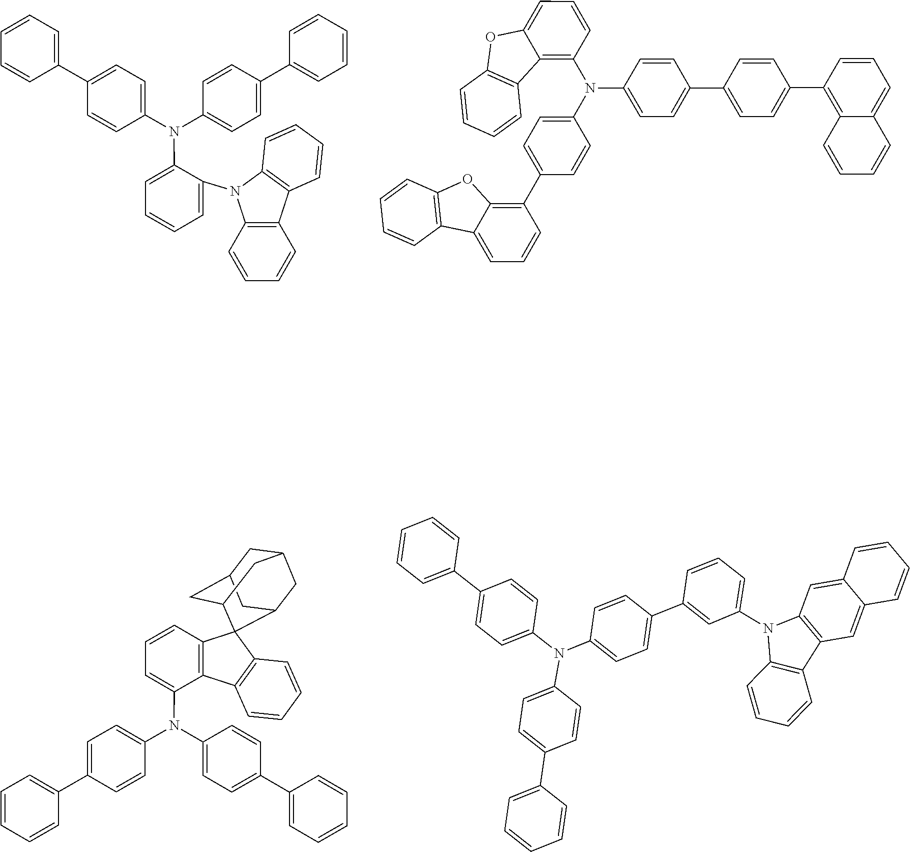 [SMILES: c1ccc(-c2ccc(N(c3ccc(-c4ccccc4)cc3)c3ccccc3-n3c4ccccc4c4ccccc43)cc2)cc1 ; c1ccc2c(-c3ccc(-c4ccc(N(c5ccc(-c6cccc7c6oc6ccccc67)cc5)c5cccc6oc7ccccc7c56)cc4)cc3)cccc2c1 ; c1ccc(-c2ccc(N(c3ccc(-c4ccccc4)cc3)c3cccc4c3-c3ccccc3C43C4CC5CC(C4)CC3C5)cc2)cc1 ; c1ccc(-c2ccc(N(c3ccc(-c4ccccc4)cc3)c3ccc(-c4cccc(-n5c6ccccc6c6cc7ccccc7cc65)c4)cc3)cc2)cc1]

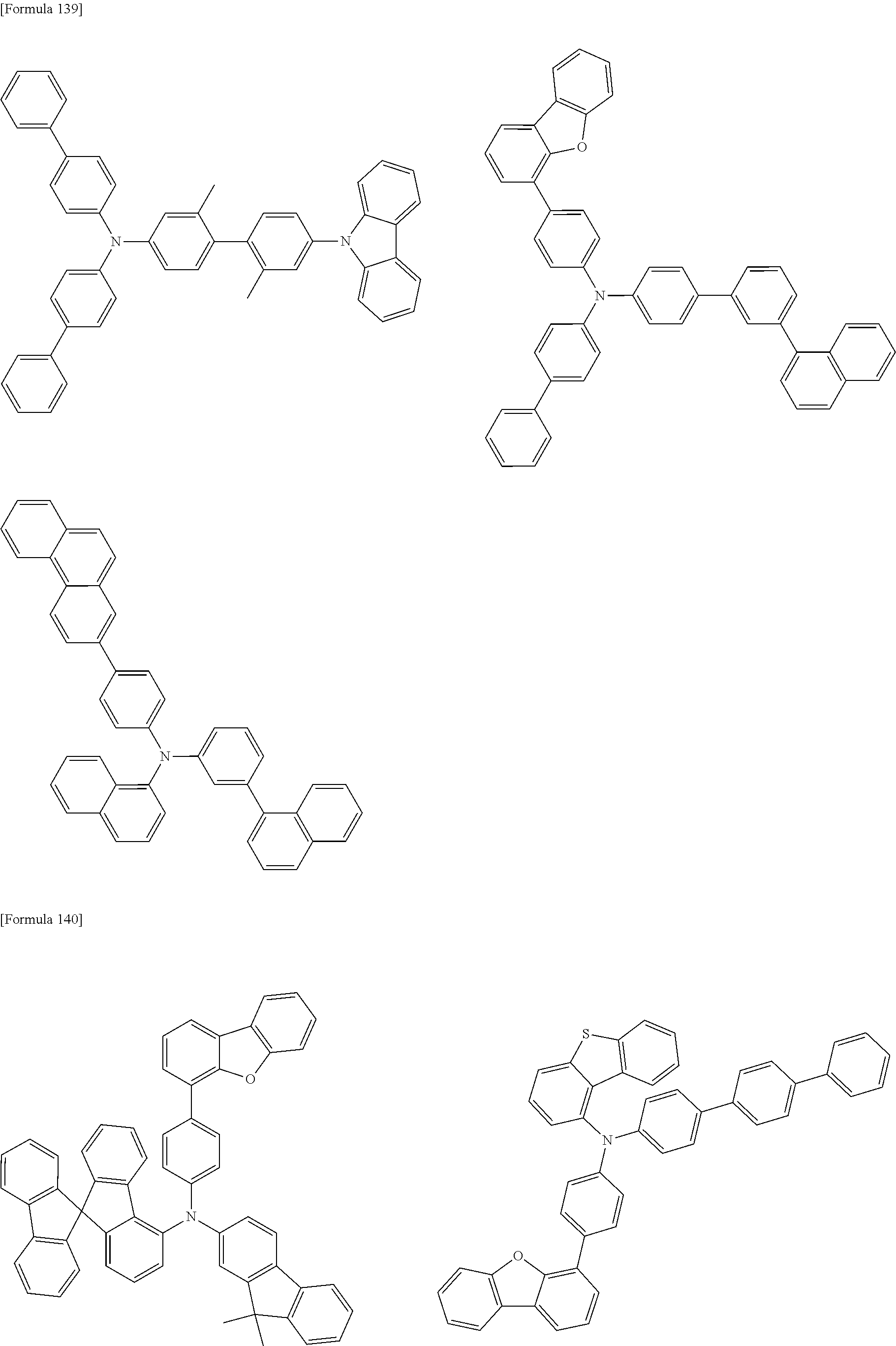 [SMILES: Cc1cc(N(c2ccc(-c3ccccc3)cc2)c2ccc(-c3ccccc3)cc2)ccc1-c1ccc(-n2c3ccccc3c3ccccc32)cc1C ; c1ccc(-c2ccc(N(c3ccc(-c4cccc(-c5cccc6ccccc56)c4)cc3)c3ccc(-c4cccc5c4oc4ccccc45)cc3)cc2)cc1 ; c1cc(-c2cccc3ccccc23)cc(N(c2ccc(-c3ccc4c(ccc5ccccc54)c3)cc2)c2cccc3ccccc23)c1 ; CC1(C)c2ccccc2-c2ccc(N(c3ccc(-c4cccc5c4oc4ccccc45)cc3)c3cccc4c3-c3ccccc3C43c4ccccc4-c4ccccc43)cc21 ; c1ccc(-c2ccc(-c3ccc(N(c4ccc(-c5cccc6c5oc5ccccc56)cc4)c4cccc5sc6ccccc6c45)cc3)cc2)cc1]

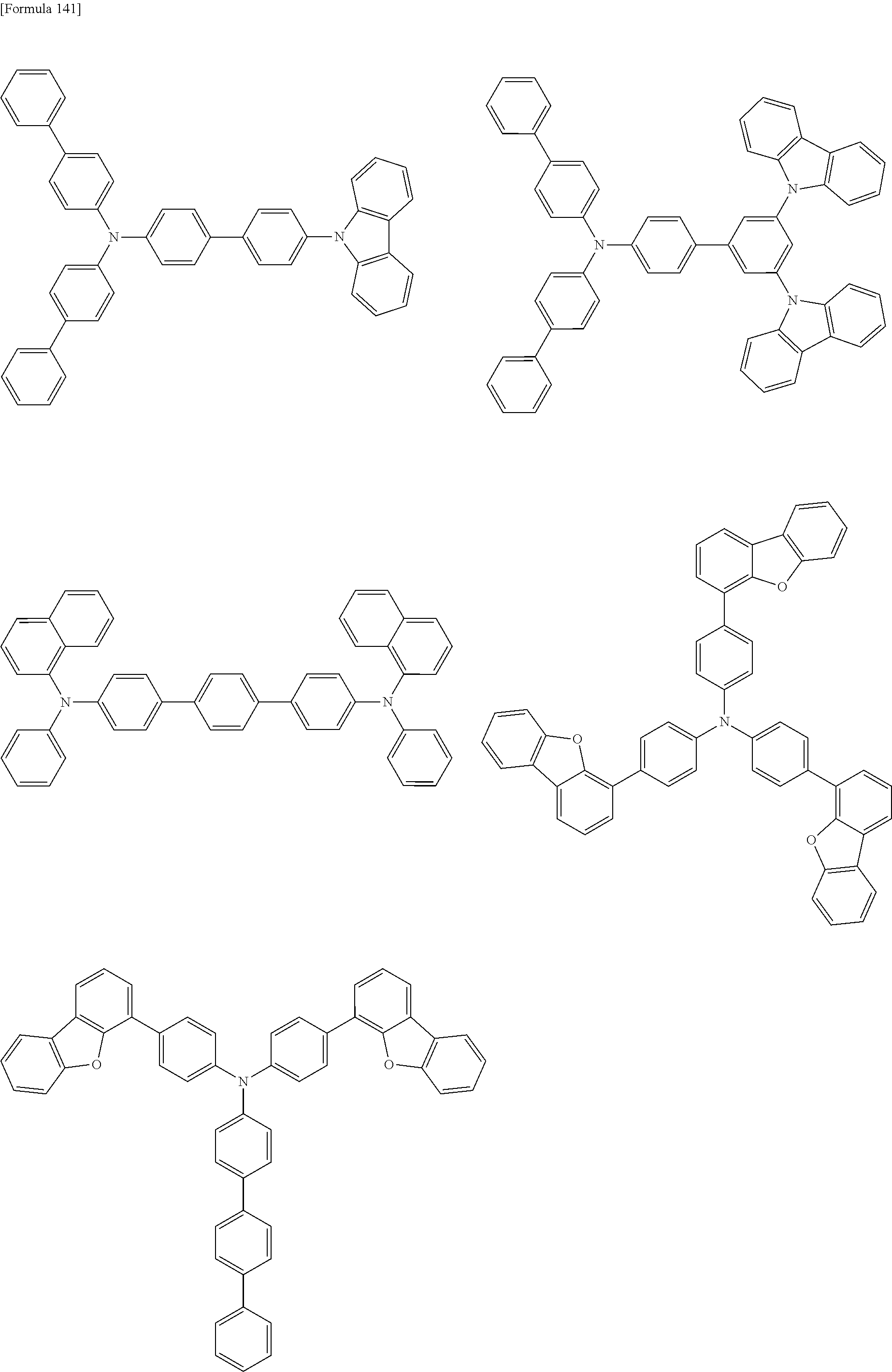

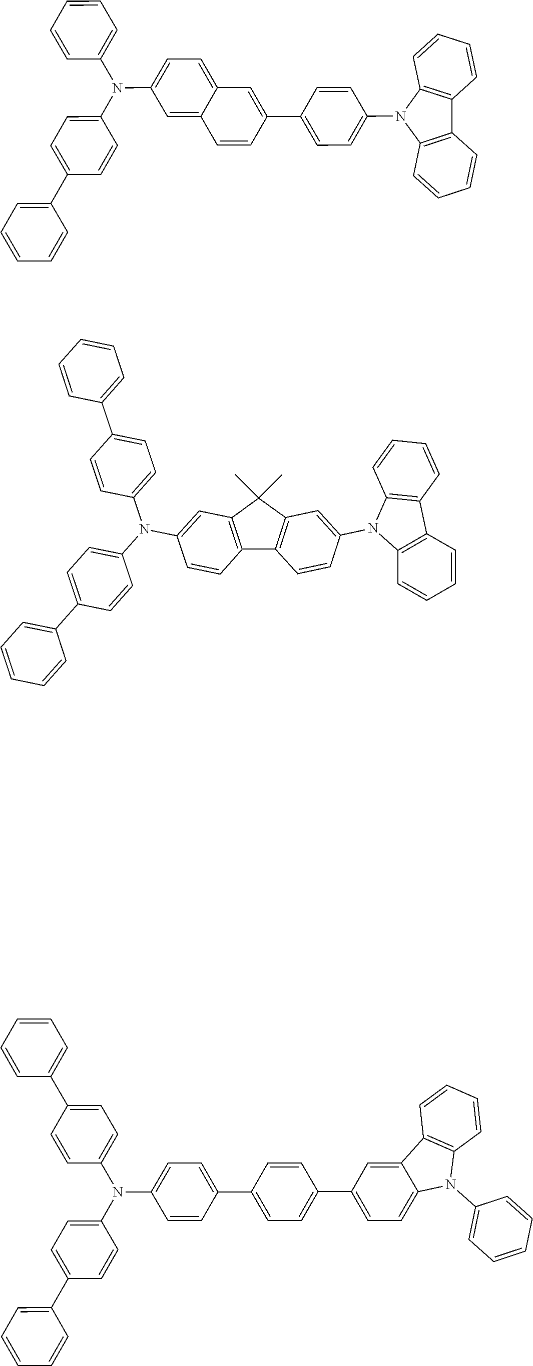 [SMILES: c1ccc(-c2ccc(N(c3ccccc3)c3ccc4cc(-c5ccc(-n6c7ccccc7c7ccccc76)cc5)ccc4c3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

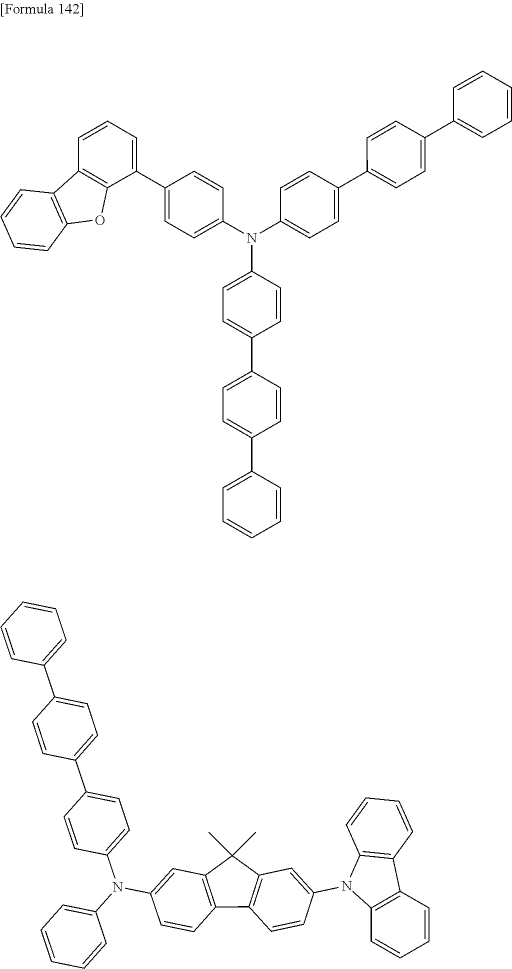 [SMILES: c1ccc(-c2ccc(-c3ccc(N(c4ccc(-c5ccc(-c6ccccc6)cc5)cc4)c4ccc(-c5cccc6c5oc5ccccc56)cc4)cc3)cc2)cc1 ; CC1(C)c2cc(N(c3ccccc3)c3ccc(-c4ccc(-c5ccccc5)cc4)cc3)ccc2-c2ccc(-n3c4ccccc4c4ccccc43)cc21]

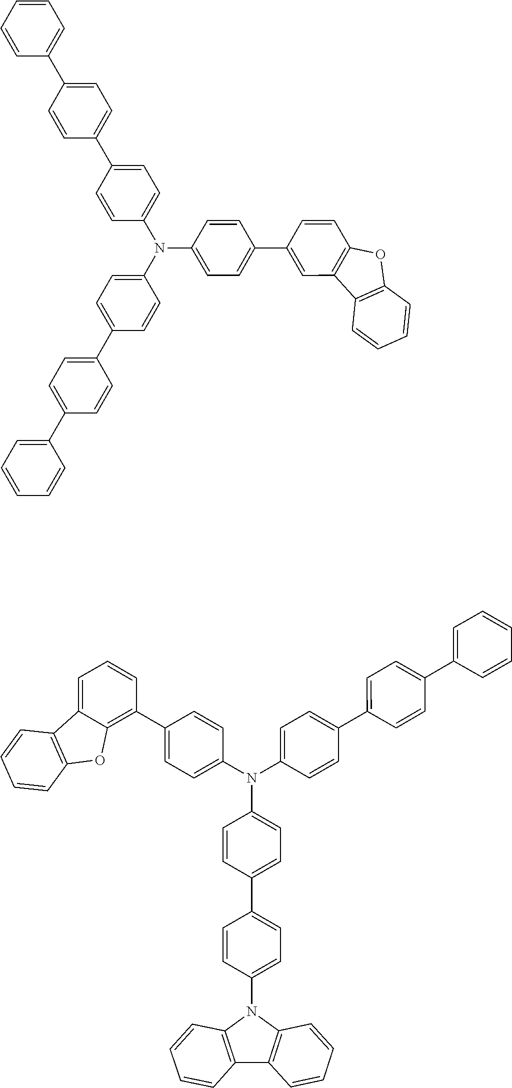 [SMILES: c1ccc(-c2ccc(-c3ccc(N(c4ccc(-c5ccc(-c6ccccc6)cc5)cc4)c4ccc(-c5ccc6oc7ccccc7c6c5)cc4)cc3)cc2)cc1 ; c1ccc(-c2ccc(-c3ccc(N(c4ccc(-c5ccc(-n6c7ccccc7c7ccccc76)cc5)cc4)c4ccc(-c5cccc6c5oc5ccccc56)cc4)cc3)cc2)cc1]

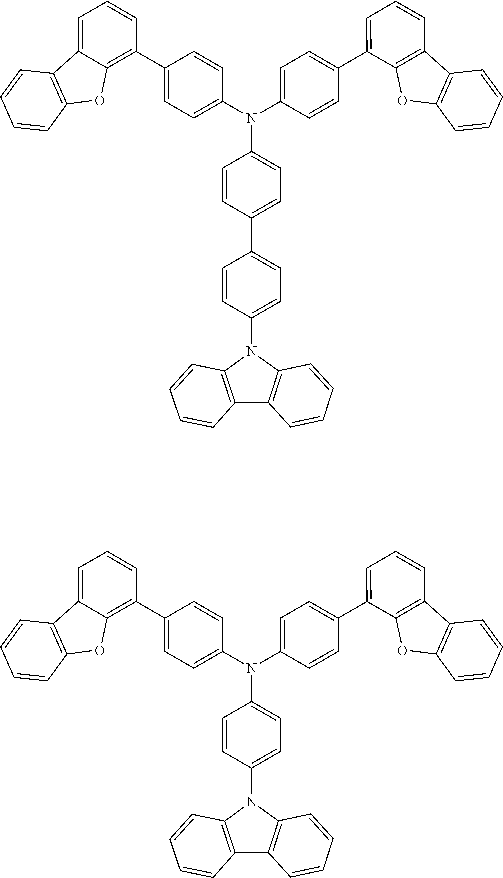 [SMILES: c1ccc2c(c1)oc1c(-c3ccc(N(c4ccc(-c5ccc(-n6c7ccccc7c7ccccc76)cc5)cc4)c4ccc(-c5cccc6c5oc5ccccc56)cc4)cc3)cccc12 ; c1ccc2c(c1)oc1c(-c3ccc(N(c4ccc(-c5cccc6c5oc5ccccc56)cc4)c4ccc(-n5c6ccccc6c6ccccc65)cc4)cc3)cccc12]

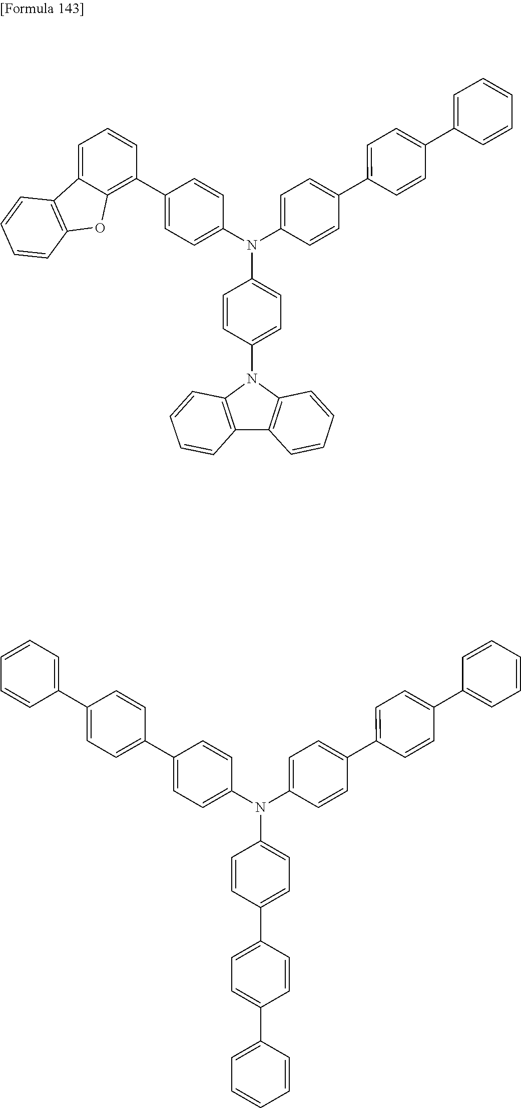 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1]

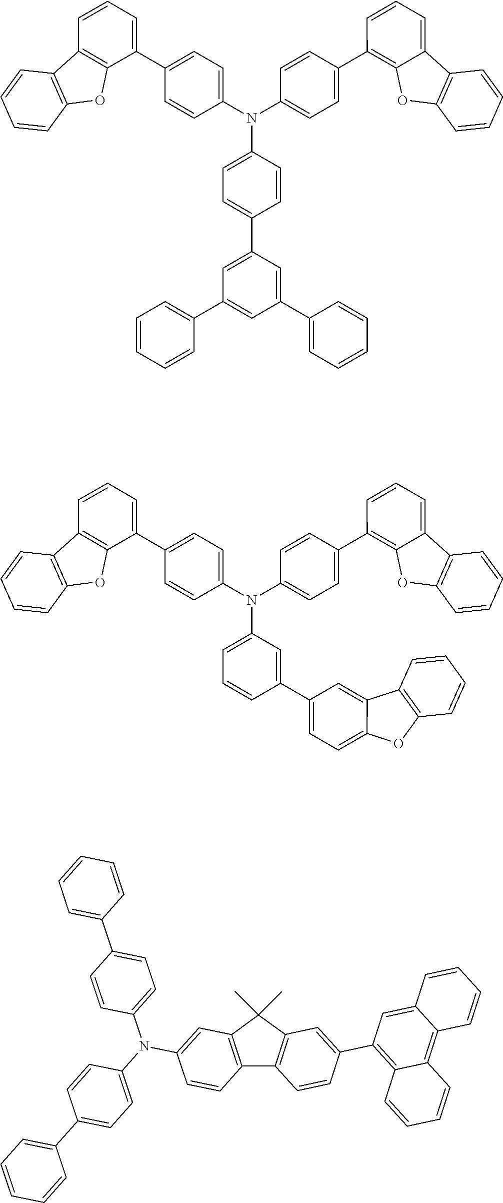 [SMILES: c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1 ; c1cc(-c2ccc3oc4ccccc4c3c2)cc(N(c2ccc(-c3cccc4c3oc3ccccc34)cc2)c2ccc(-c3cccc4c3oc3ccccc34)cc2)c1 ; CC1(C)c2cc(-c3cc4ccccc4c4ccccc34)ccc2-c2ccc(N(c3ccc(-c4ccccc4)cc3)c3ccc(-c4ccccc4)cc3)cc21]

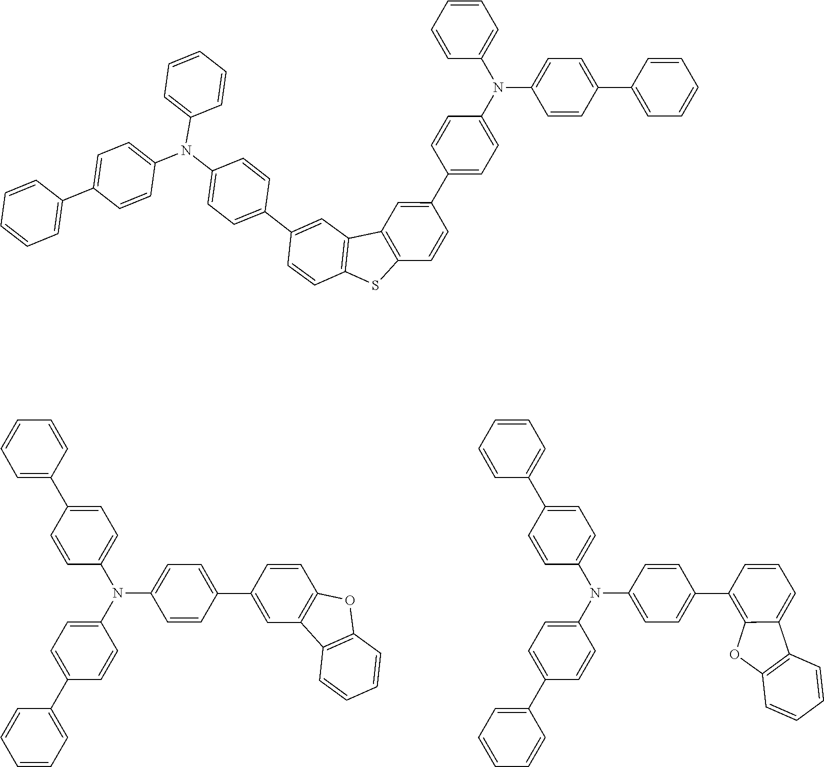 [SMILES: c1ccc(-c2ccc(N(c3ccccc3)c3ccc(-c4ccc5sc6ccc(-c7ccc(N(c8ccccc8)c8ccc(-c9ccccc9)cc8)cc7)cc6c5c4)cc3)cc2)cc1 ; c1ccc(-c2ccc(N(c3ccc(-c4ccccc4)cc3)c3ccc(-c4ccc5oc6ccccc6c5c4)cc3)cc2)cc1 ; c1ccc(-c2ccc(N(c3ccc(-c4ccccc4)cc3)c3ccc(-c4cccc5c4oc4ccccc45)cc3)cc2)cc1]

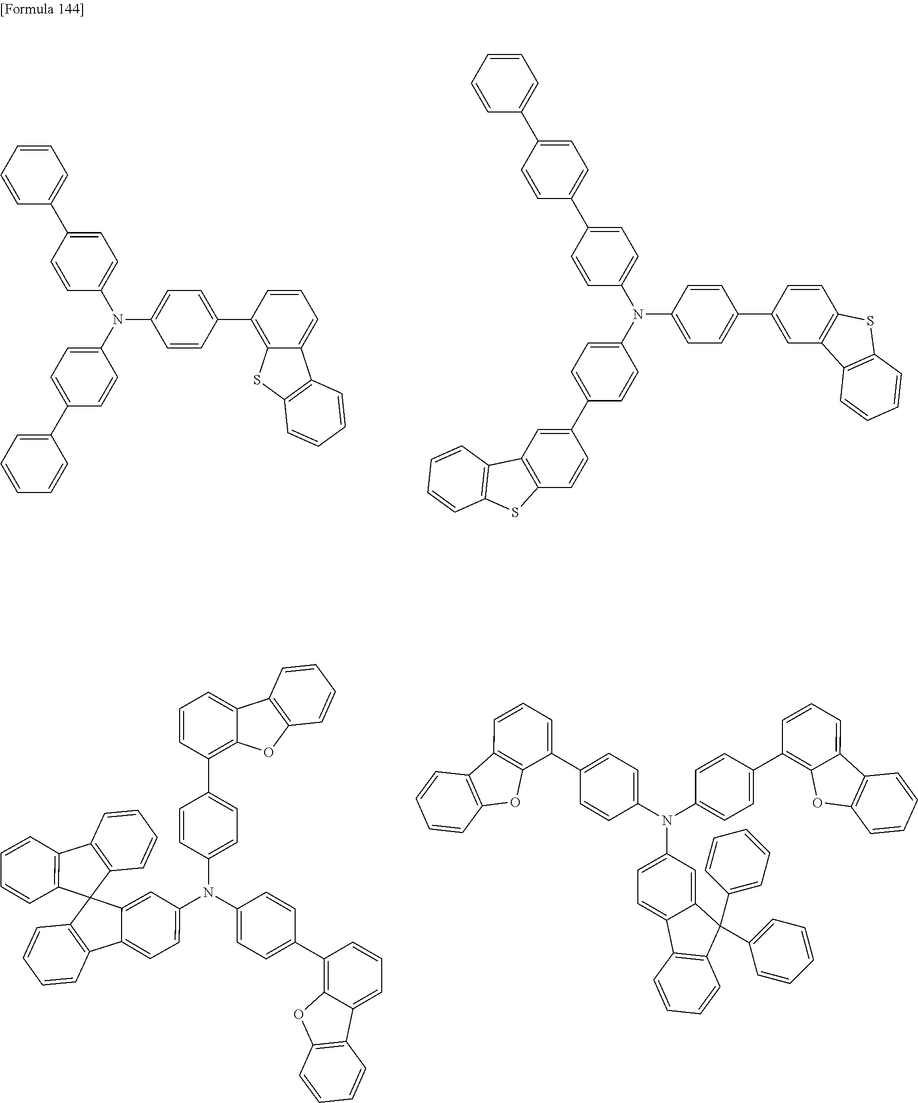 [SMILES: c1ccc(-c2ccc(N(c3ccc(-c4ccccc4)cc3)c3ccc(-c4cccc5c4sc4ccccc45)cc3)cc2)cc1 ; c1ccc(-c2ccc(-c3ccc(N(c4ccc(-c5ccc6sc7ccccc7c6c5)cc4)c4ccc(-c5ccc6sc7ccccc7c6c5)cc4)cc3)cc2)cc1 ; c1ccc2c(c1)-c1ccccc1C21c2ccccc2-c2ccc(N(c3ccc(-c4cccc5c4oc4ccccc45)cc3)c3ccc(-c4cccc5c4oc4ccccc45)cc3)cc21 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1]

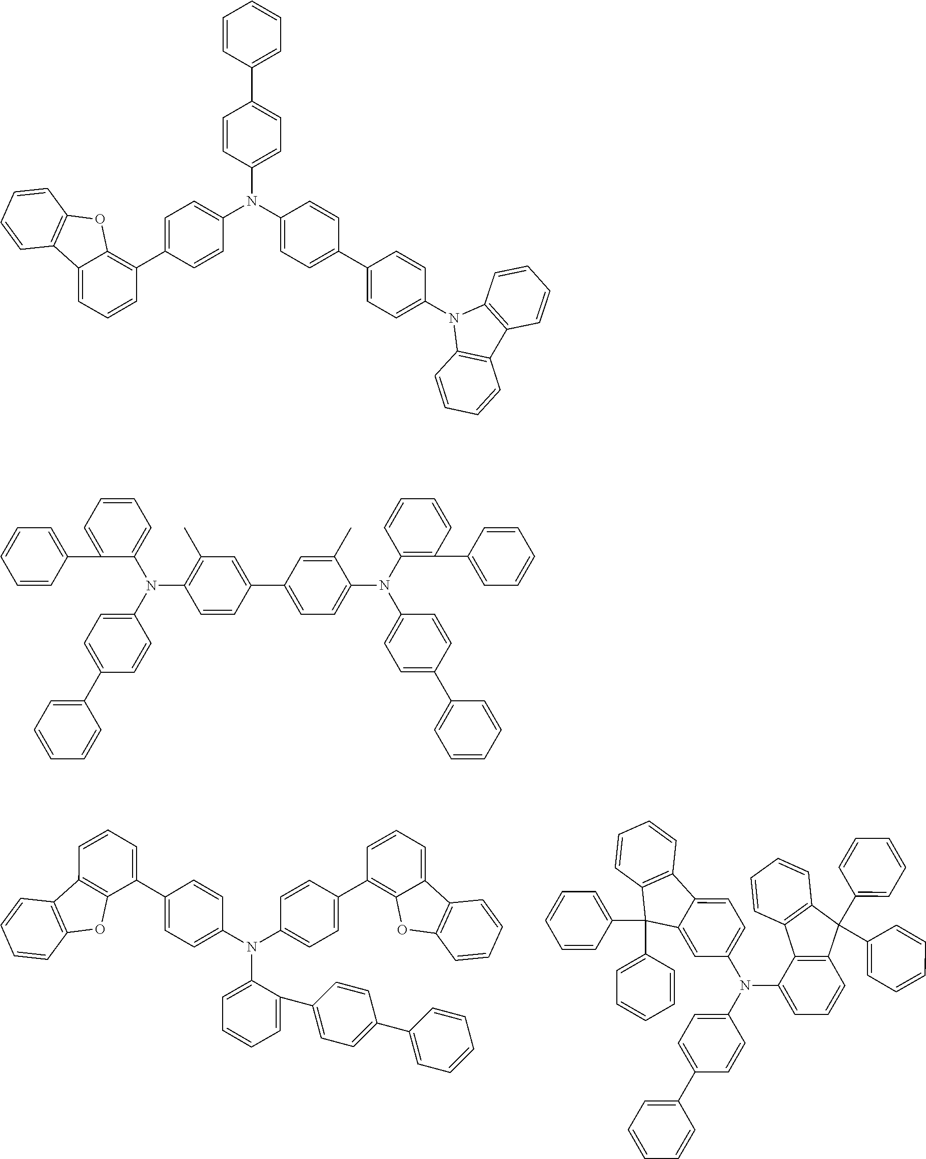

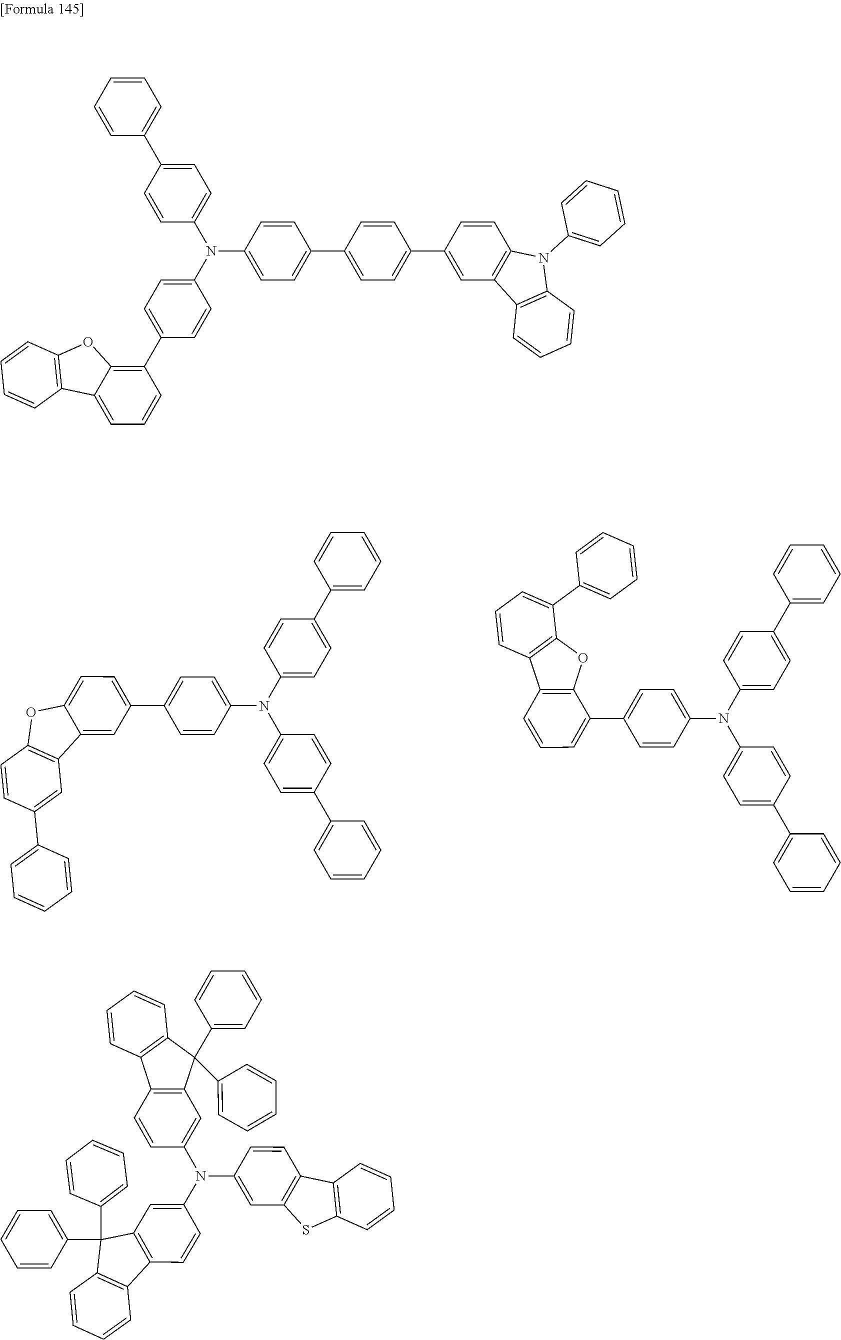 [SMILES: c1ccc(-c2ccc(N(c3ccc(-c4ccc(-c5ccc6c(c5)c5ccccc5n6-c5ccccc5)cc4)cc3)c3ccc(-c4cccc5c4oc4ccccc45)cc3)cc2)cc1 ; c1ccc(-c2ccc(N(c3ccc(-c4ccccc4)cc3)c3ccc(-c4ccc5oc6ccc(-c7ccccc7)cc6c5c4)cc3)cc2)cc1 ; c1ccc(-c2ccc(N(c3ccc(-c4ccccc4)cc3)c3ccc(-c4cccc5c4oc4c(-c6ccccc6)cccc45)cc3)cc2)cc1 ; c1ccc(C2(c3ccccc3)c3ccccc3-c3ccc(N(c4ccc5c(c4)C(c4ccccc4)(c4ccccc4)c4ccccc4-5)c4ccc5c(c4)sc4ccccc45)cc32)cc1]

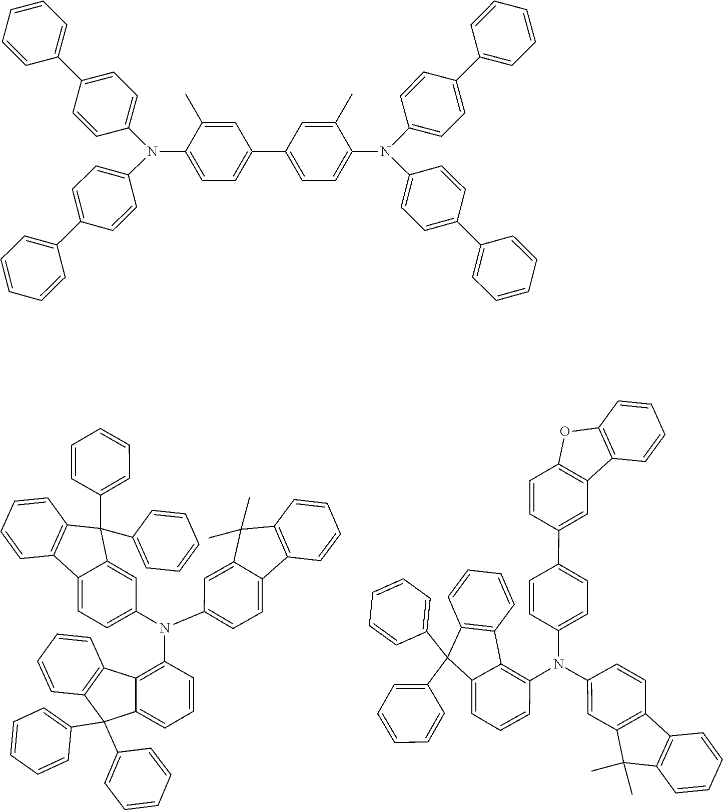 [SMILES: Cc1cc(-c2ccc(N(c3ccc(-c4ccccc4)cc3)c3ccc(-c4ccccc4)cc3)c(C)c2)ccc1N(c1ccc(-c2ccccc2)cc1)c1ccc(-c2ccccc2)cc1 ; CC1(C)c2ccccc2-c2ccc(N(c3ccc4c(c3)C(c3ccccc3)(c3ccccc3)c3ccccc3-4)c3cccc4c3-c3ccccc3C4(c3ccccc3)c3ccccc3)cc21 ; CC1(C)c2ccccc2-c2ccc(N(c3ccc(-c4ccc5oc6ccccc6c5c4)cc3)c3cccc4c3-c3ccccc3C4(c3ccccc3)c3ccccc3)cc21]

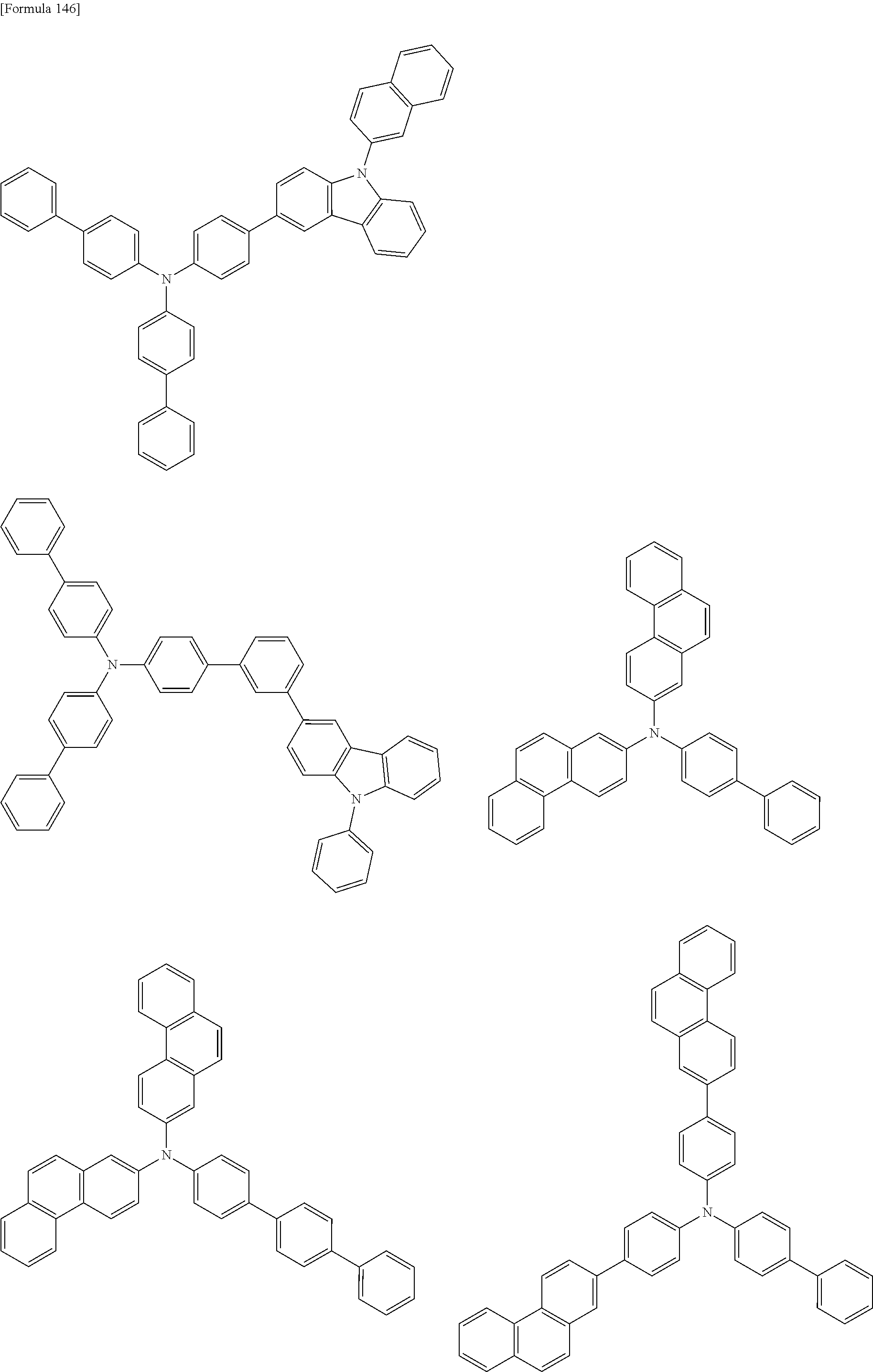 [SMILES: c1ccc(-c2ccc(N(c3ccc(-c4ccccc4)cc3)c3ccc(-c4ccc5c(c4)c4ccccc4n5-c4ccc5ccccc5c4)cc3)cc2)cc1 ; c1ccc(-c2ccc(N(c3ccc(-c4ccccc4)cc3)c3ccc(-c4cccc(-c5ccc6c(c5)c5ccccc5n6-c5ccccc5)c4)cc3)cc2)cc1 ; c1ccc(-c2ccc(N(c3ccc4c(ccc5ccccc54)c3)c3ccc4c(ccc5ccccc54)c3)cc2)cc1 ; c1ccc(-c2ccc(-c3ccc(N(c4ccc5c(ccc6ccccc65)c4)c4ccc5c(ccc6ccccc65)c4)cc3)cc2)cc1 ; c1ccc(-c2ccc(N(c3ccc(-c4ccc5c(ccc6ccccc65)c4)cc3)c3ccc(-c4ccc5c(ccc6ccccc65)c4)cc3)cc2)cc1]

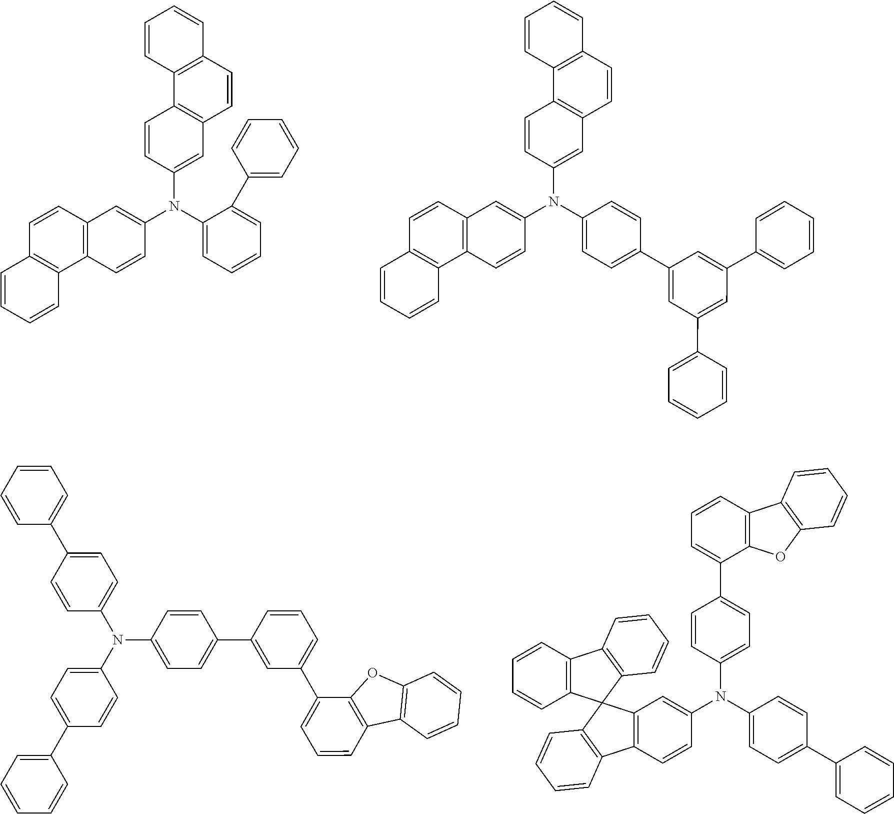 [SMILES: c1ccc(-c2ccccc2N(c2ccc3c(ccc4ccccc43)c2)c2ccc3c(ccc4ccccc43)c2)cc1 ; c1ccc(-c2cc(-c3ccccc3)cc(-c3ccc(N(c4ccc5c(ccc6ccccc65)c4)c4ccc5c(ccc6ccccc65)c4)cc3)c2)cc1 ; c1ccc(-c2ccc(N(c3ccc(-c4ccccc4)cc3)c3ccc(-c4cccc(-c5cccc6c5oc5ccccc56)c4)cc3)cc2)cc1 ; c1ccc(-c2ccc(N(c3ccc(-c4cccc5c4oc4ccccc45)cc3)c3ccc4c(c3)C3(c5ccccc5-c5ccccc53)c3ccccc3-4)cc2)cc1]

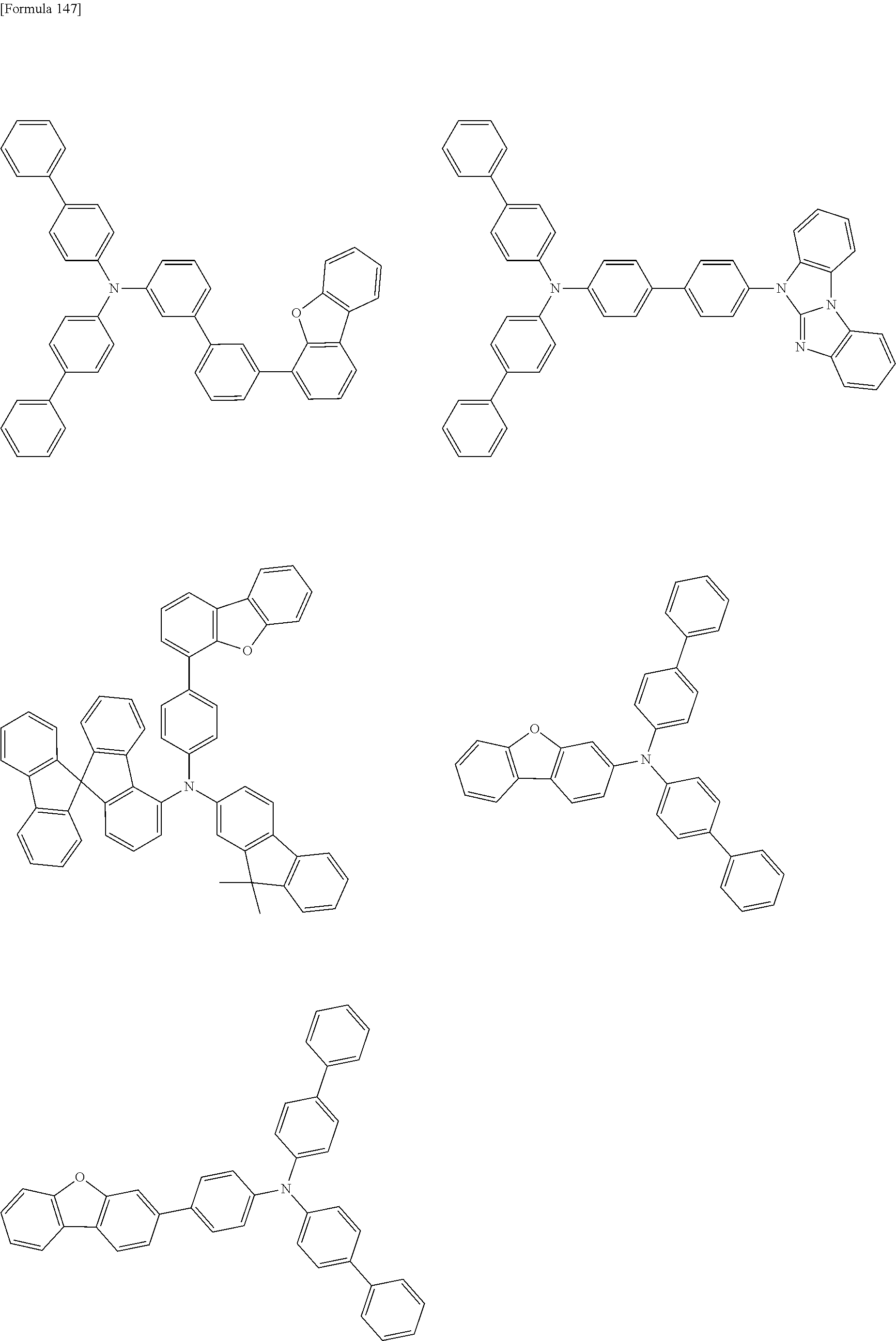 [SMILES: c1ccc(-c2ccc(N(c3ccc(-c4ccccc4)cc3)c3cccc(-c4cccc(-c5cccc6c5oc5ccccc56)c4)c3)cc2)cc1 ; c1ccc(-c2ccc(N(c3ccc(-c4ccccc4)cc3)c3ccc(-c4ccc(-n5c6ccccc6n6c7ccccc7nc56)cc4)cc3)cc2)cc1 ; CC1(C)c2ccccc2-c2ccc(N(c3ccc(-c4cccc5c4oc4ccccc45)cc3)c3cccc4c3-c3ccccc3C43c4ccccc4-c4ccccc43)cc21 ; c1ccc(-c2ccc(N(c3ccc(-c4ccccc4)cc3)c3ccc4c(c3)oc3ccccc34)cc2)cc1 ; c1ccc(-c2ccc(N(c3ccc(-c4ccccc4)cc3)c3ccc(-c4ccc5c(c4)oc4ccccc45)cc3)cc2)cc1]

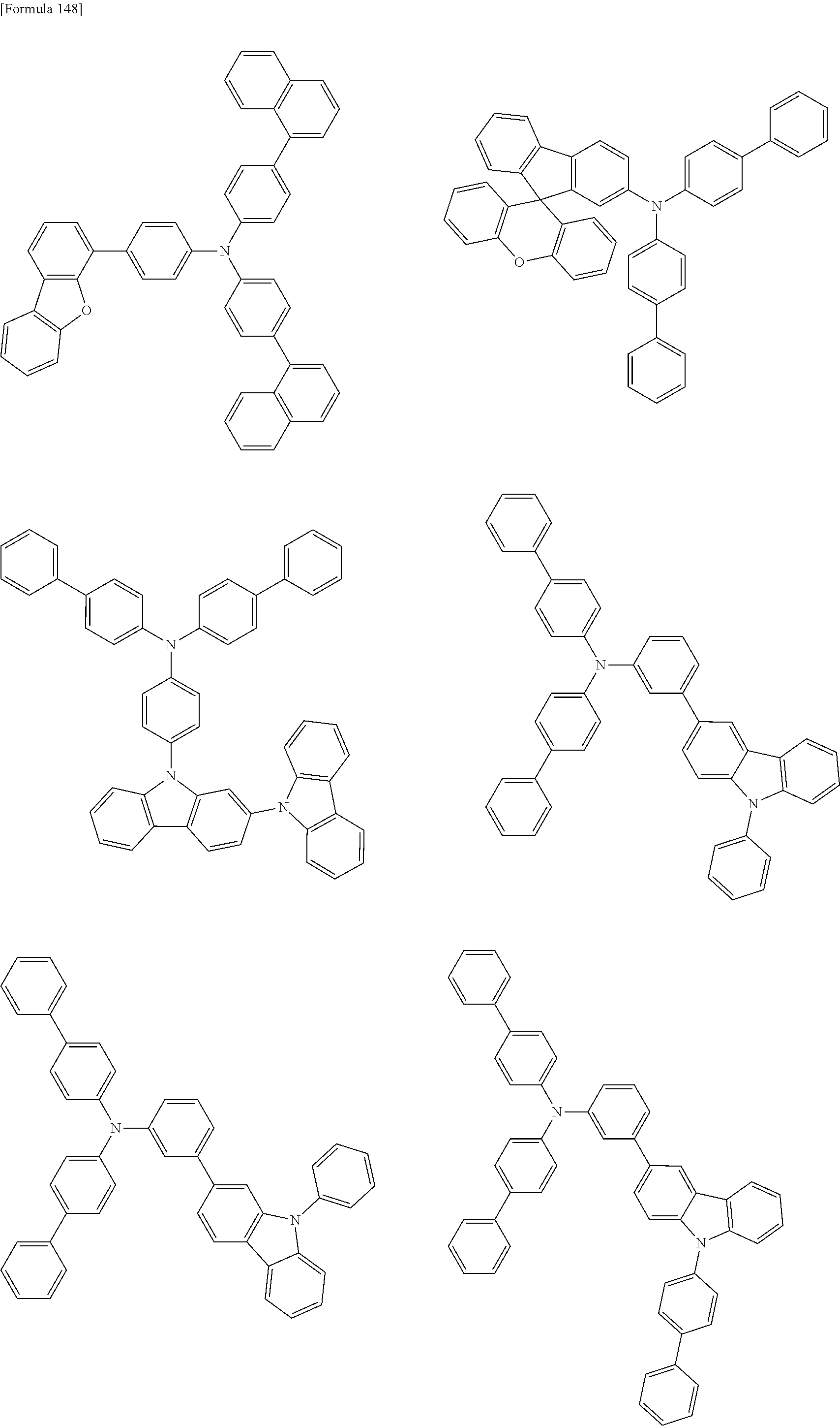

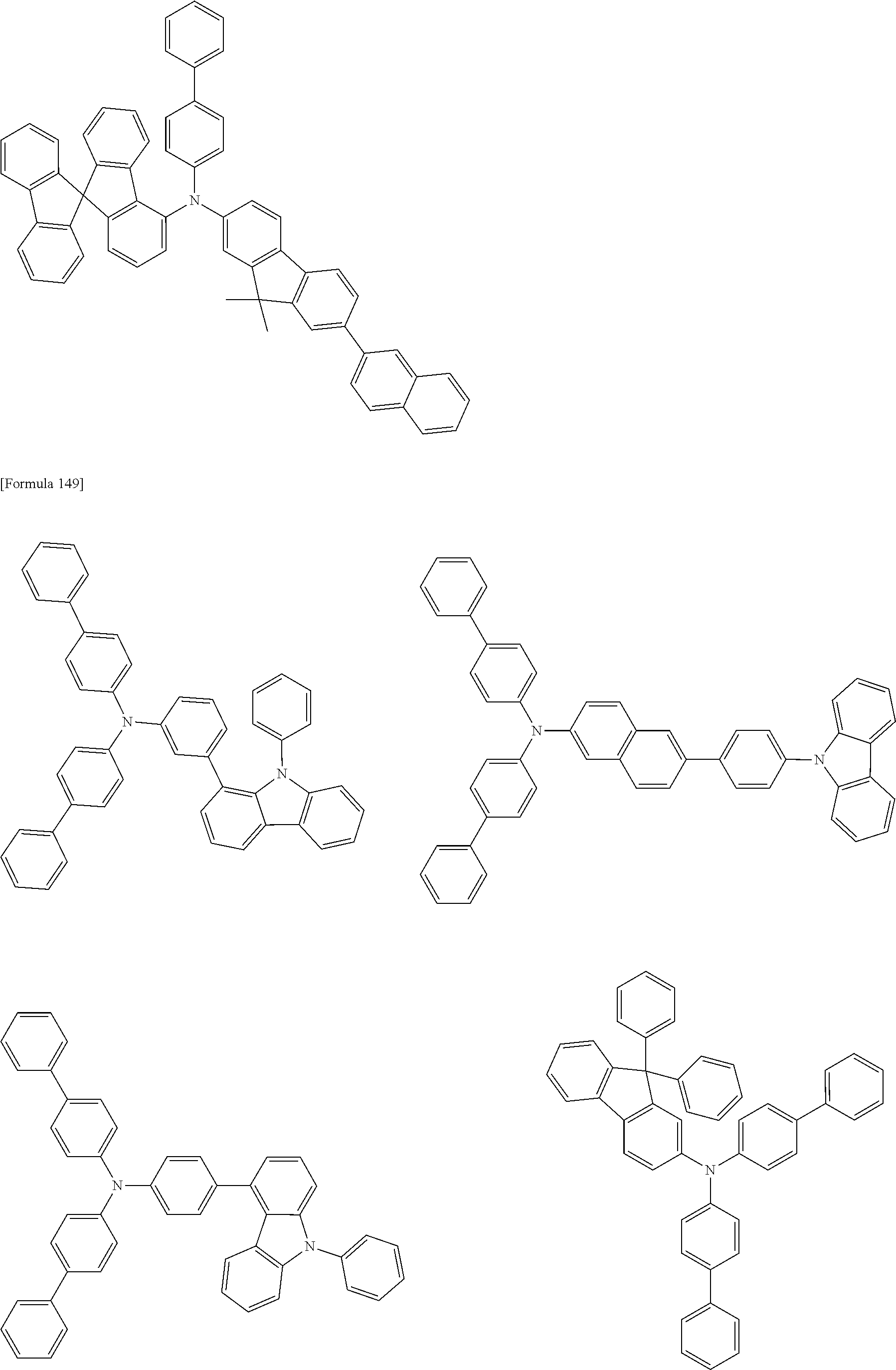 [SMILES: CC1(C)c2cc(-c3ccc4ccccc4c3)ccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3cccc(-c4cccc5c6ccccc6n(-c6ccccc6)c45)c3)cc2)cc1 ; c1ccc(-c2ccc(N(c3ccc(-c4ccccc4)cc3)c3ccc4cc(-c5ccc(-n6c7ccccc7c7ccccc76)cc5)ccc4c3)cc2)cc1 ; c1ccc(-c2ccc(N(c3ccc(-c4ccccc4)cc3)c3ccc(-c4cccc5c4c4ccccc4n5-c4ccccc4)cc3)cc2)cc1 ; c1ccc(-c2ccc(N(c3ccc(-c4ccccc4)cc3)c3ccc4c(c3)C(c3ccccc3)(c3ccccc3)c3ccccc3-4)cc2)cc1]

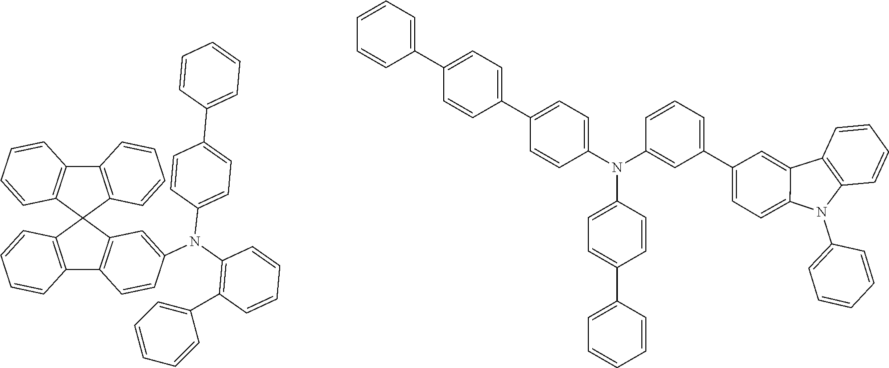 [SMILES: c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccc(-c3ccc(N(c4ccc(-c5ccccc5)cc4)c4cccc(-c5ccc6c(c5)c5ccccc5n6-c5ccccc5)c4)cc3)cc2)cc1]

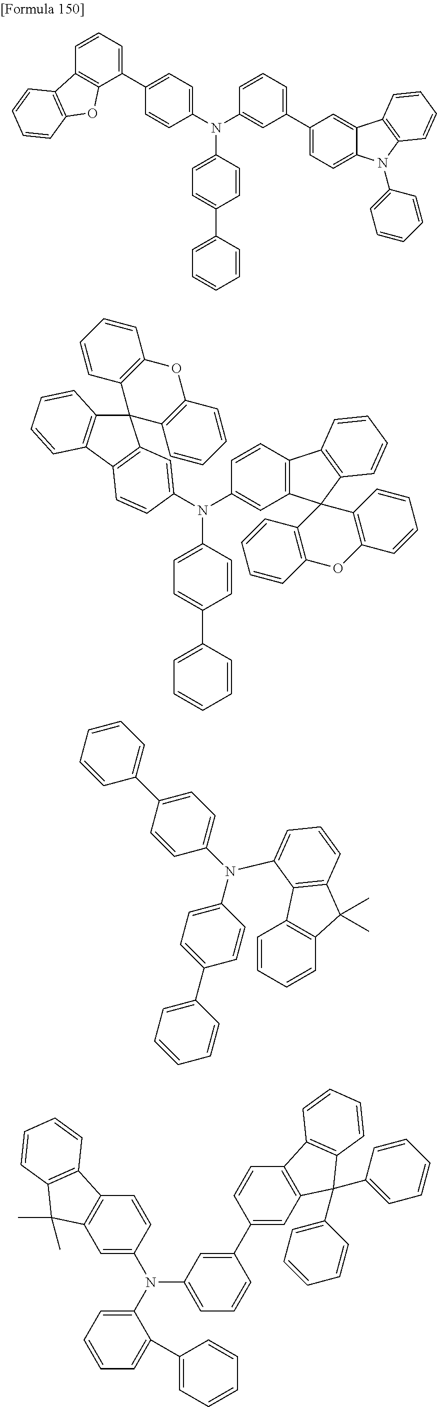

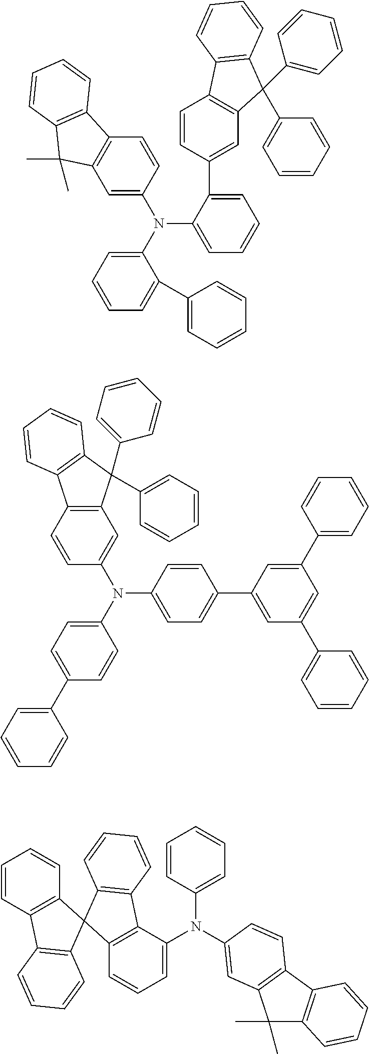 [SMILES: CC1(C)c2ccccc2-c2ccc(N(c3ccccc3-c3ccccc3)c3ccccc3-c3ccc4c(c3)C(c3ccccc3)(c3ccccc3)c3ccccc3-4)cc21 ; c1ccc(-c2ccc(N(c3ccc(-c4cc(-c5ccccc5)cc(-c5ccccc5)c4)cc3)c3ccc4c(c3)C(c3ccccc3)(c3ccccc3)c3ccccc3-4)cc2)cc1 ; CC1(C)c2ccccc2-c2ccc(N(c3ccccc3)c3cccc4c3-c3ccccc3C43c4ccccc4-c4ccccc43)cc21]

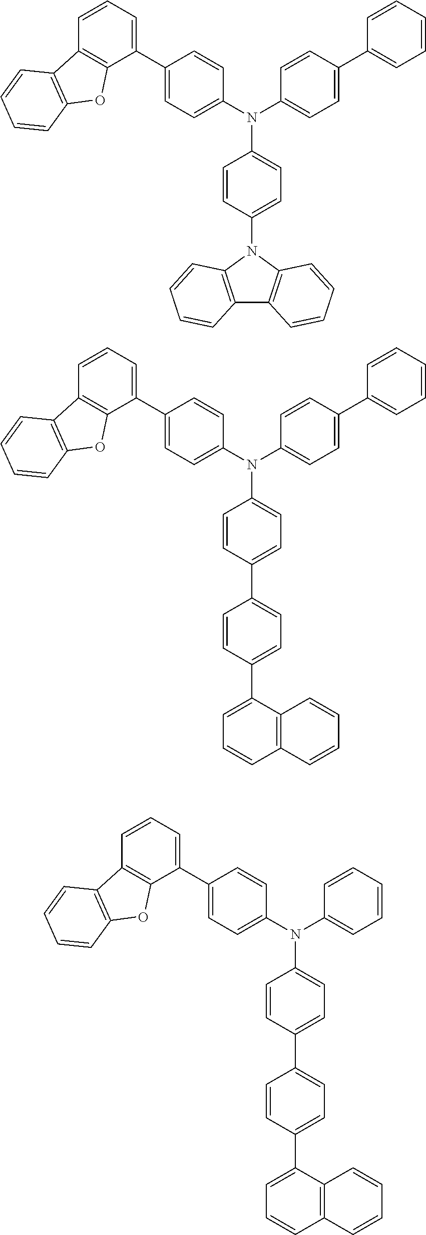 [SMILES: c1ccc(-c2ccc(N(c3ccc(-c4cccc5c4oc4ccccc45)cc3)c3ccc(-n4c5ccccc5c5ccccc54)cc3)cc2)cc1 ; c1ccc(-c2ccc(N(c3ccc(-c4ccc(-c5cccc6ccccc56)cc4)cc3)c3ccc(-c4cccc5c4oc4ccccc45)cc3)cc2)cc1 ; c1ccc(N(c2ccc(-c3ccc(-c4cccc5ccccc45)cc3)cc2)c2ccc(-c3cccc4c3oc3ccccc34)cc2)cc1]

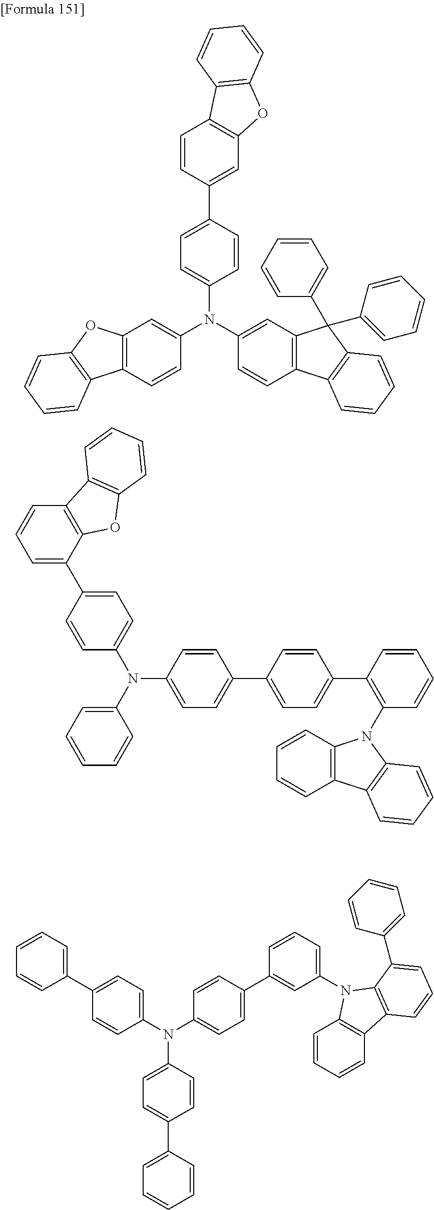

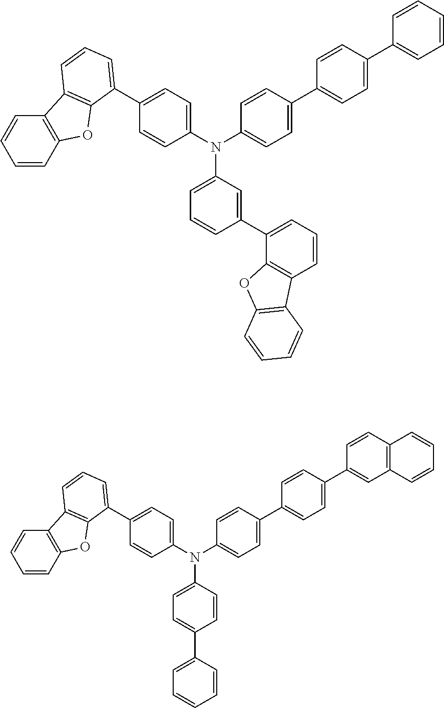 [SMILES: c1ccc(-c2ccc(-c3ccc(N(c4ccc(-c5cccc6c5oc5ccccc56)cc4)c4cccc(-c5cccc6c5oc5ccccc56)c4)cc3)cc2)cc1 ; c1ccc(-c2ccc(N(c3ccc(-c4ccc(-c5ccc6ccccc6c5)cc4)cc3)c3ccc(-c4cccc5c4oc4ccccc45)cc3)cc2)cc1]

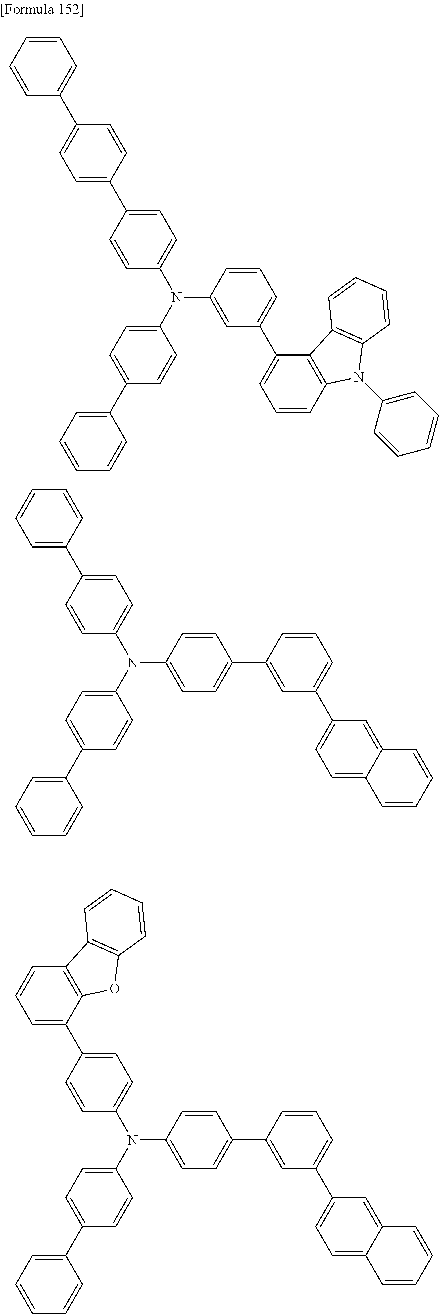

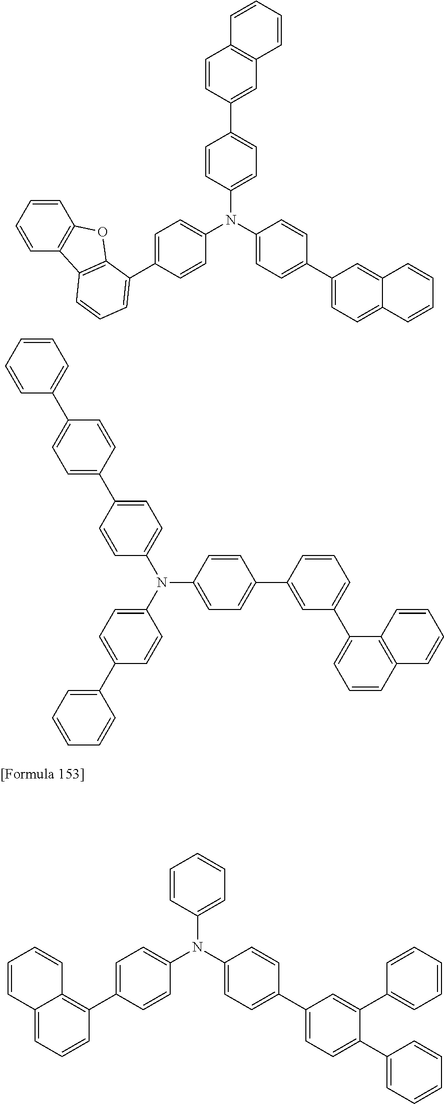 [SMILES: c1ccc2cc(-c3ccc(N(c4ccc(-c5ccc6ccccc6c5)cc4)c4ccc(-c5cccc6c5oc5ccccc56)cc4)cc3)ccc2c1 ; c1ccc(-c2ccc(-c3ccc(N(c4ccc(-c5ccccc5)cc4)c4ccc(-c5cccc(-c6cccc7ccccc67)c5)cc4)cc3)cc2)cc1 ; c1ccc(-c2ccc(-c3ccc(N(c4ccccc4)c4ccc(-c5cccc6ccccc56)cc4)cc3)cc2-c2ccccc2)cc1]

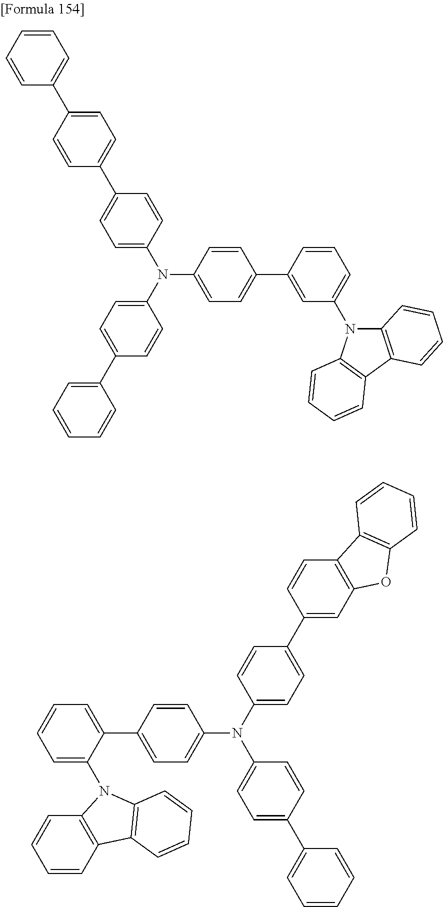 [SMILES: c1ccc(-c2ccc(-c3ccc(N(c4ccc(-c5ccccc5)cc4)c4ccc(-c5cccc(-n6c7ccccc7c7ccccc76)c5)cc4)cc3)cc2)cc1 ; c1ccc(-c2ccc(N(c3ccc(-c4ccc5c(c4)oc4ccccc45)cc3)c3ccc(-c4ccccc4-n4c5ccccc5c5ccccc54)cc3)cc2)cc1]

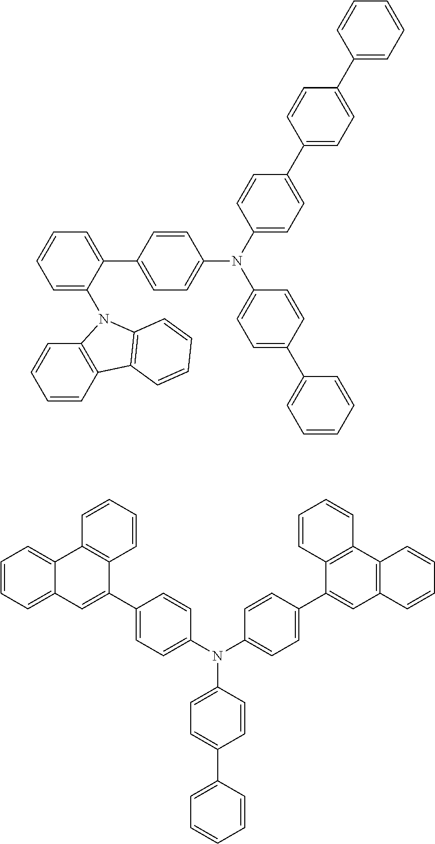 [SMILES: c1ccc(-c2ccc(-c3ccc(N(c4ccc(-c5ccccc5)cc4)c4ccc(-c5ccccc5-n5c6ccccc6c6ccccc65)cc4)cc3)cc2)cc1 ; c1ccc(-c2ccc(N(c3ccc(-c4cc5ccccc5c5ccccc45)cc3)c3ccc(-c4cc5ccccc5c5ccccc45)cc3)cc2)cc1]

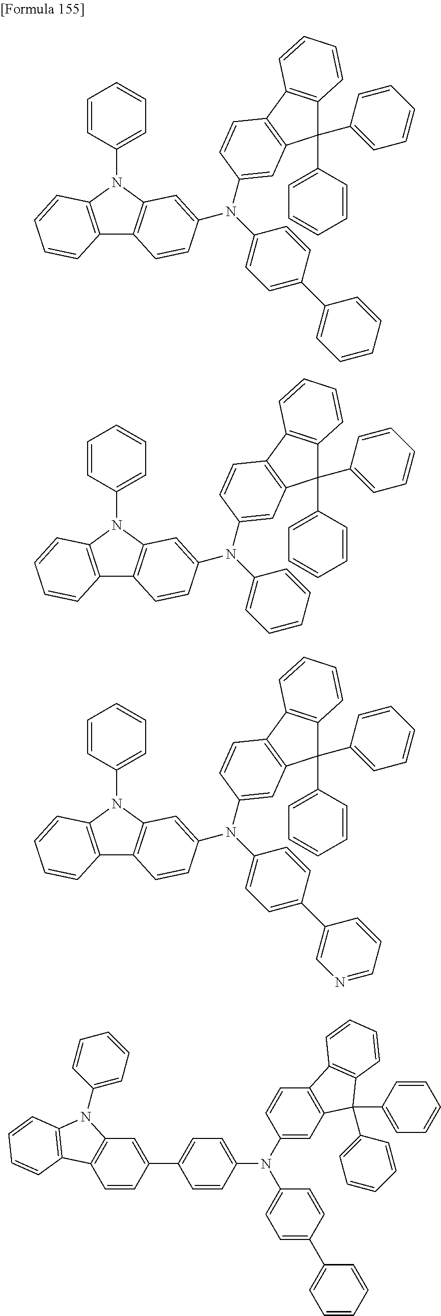

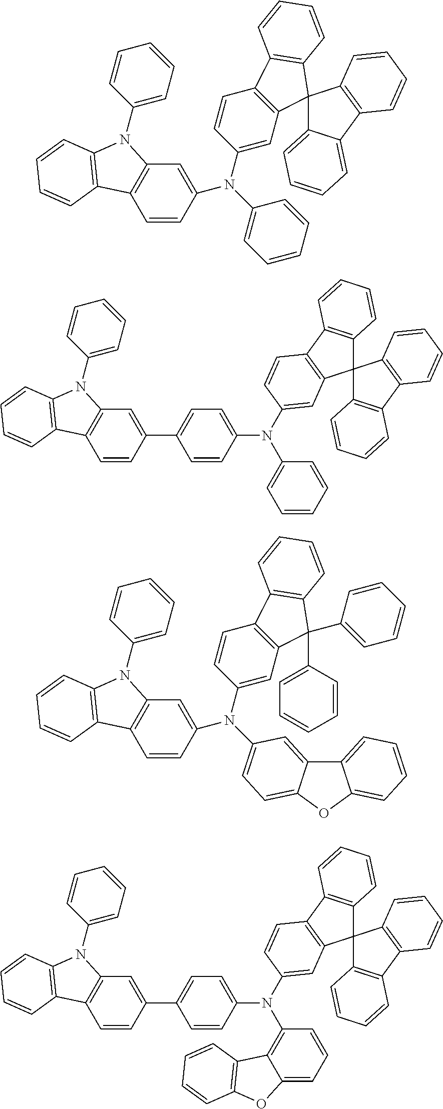

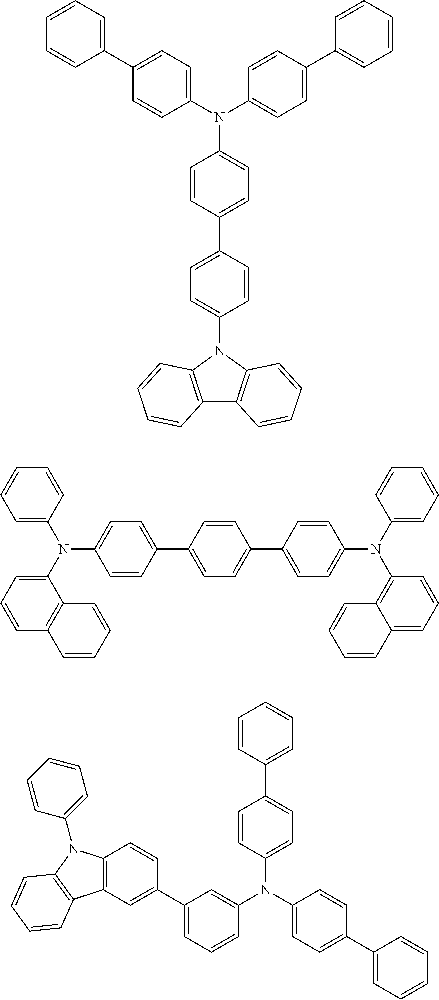 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(-c4ccc(N(c5ccccc5)c5cccc6ccccc56)cc4)cc3)cc2)c2cccc3ccccc23)cc1 ; c1ccc(-c2ccc(N(c3ccc(-c4ccccc4)cc3)c3cccc(-c4ccc5c(c4)c4ccccc4n5-c4ccccc4)c3)cc2)cc1]

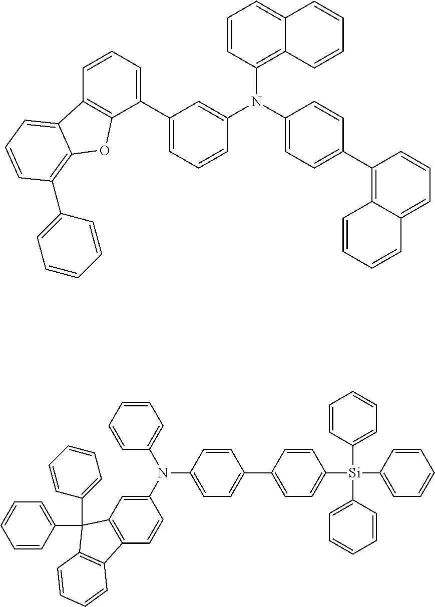 [SMILES: c1ccc(-c2cccc3c2oc2c(-c4cccc(N(c5ccc(-c6cccc7ccccc67)cc5)c5cccc6ccccc56)c4)cccc23)cc1 ; c1ccc(N(c2ccc(-c3ccc([Si](c4ccccc4)(c4ccccc4)c4ccccc4)cc3)cc2)c2ccc3c(c2)C(c2ccccc2)(c2ccccc2)c2ccccc2-3)cc1]

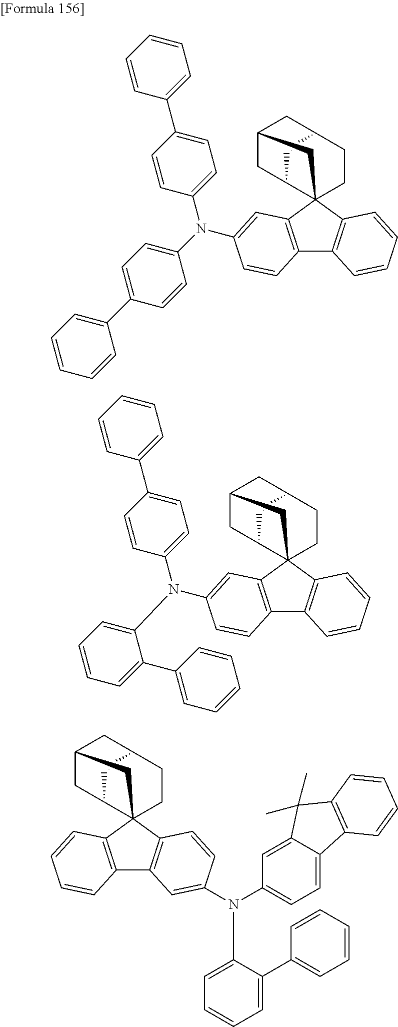

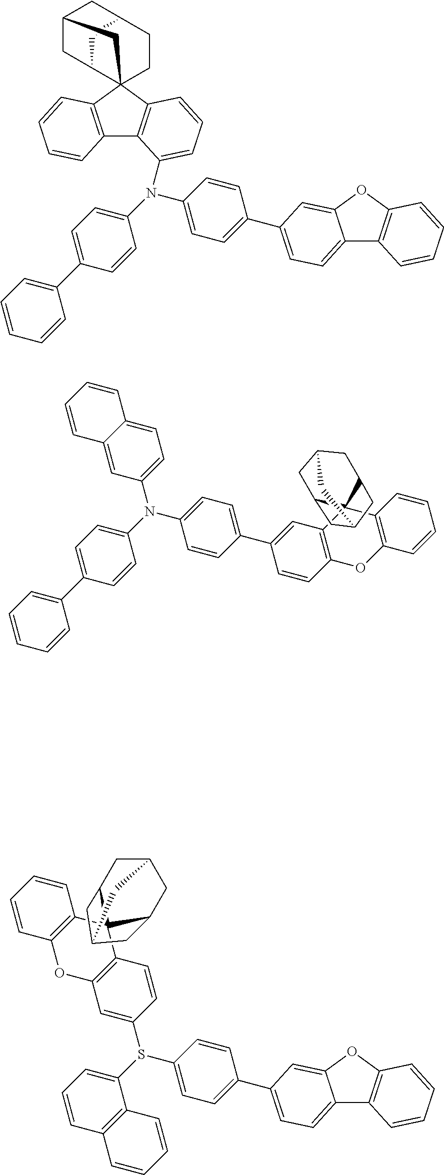

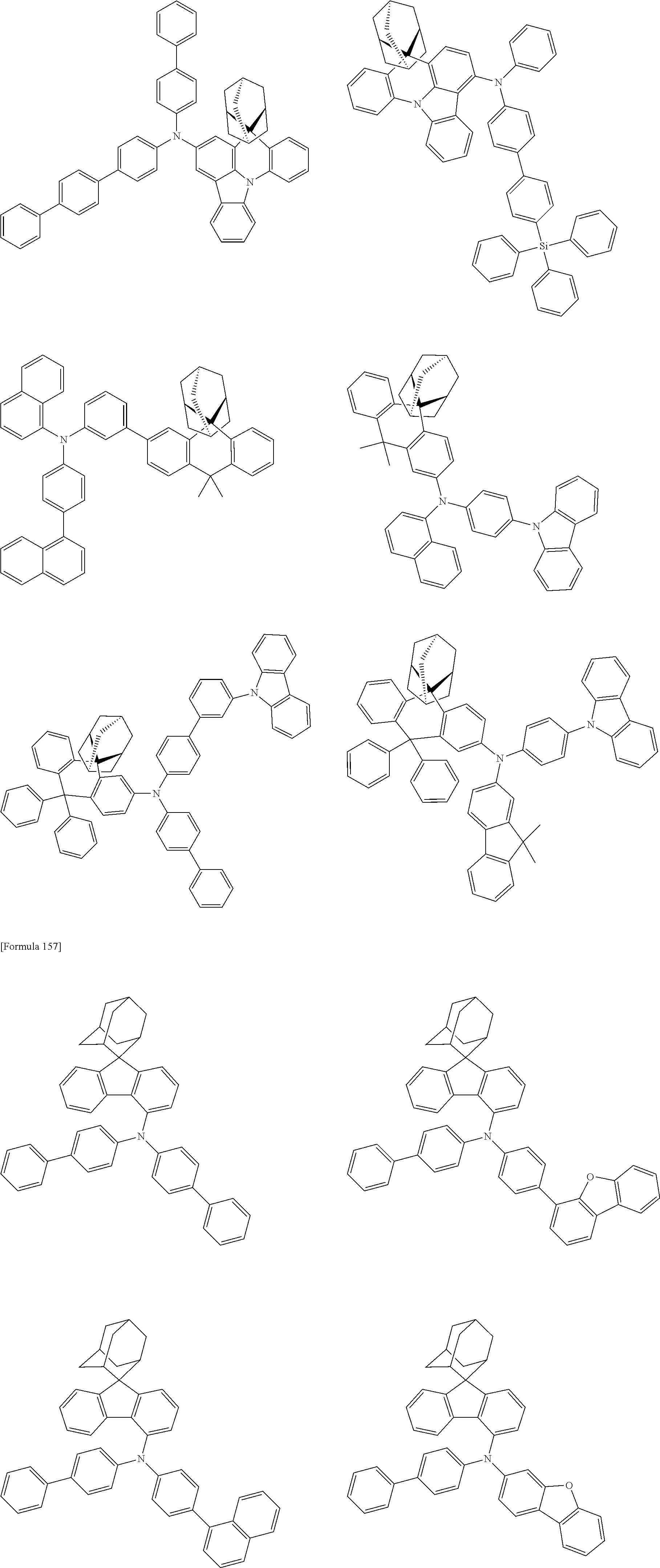

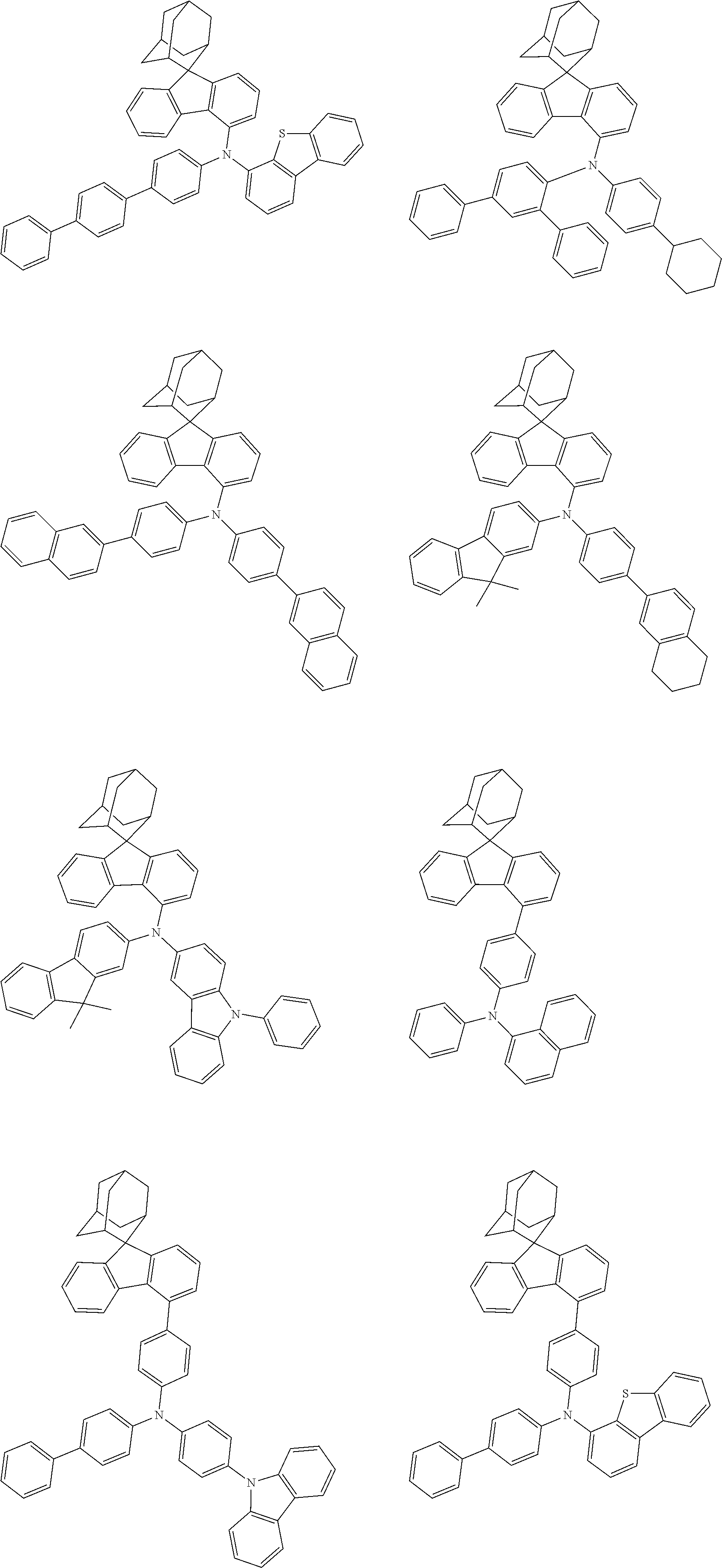

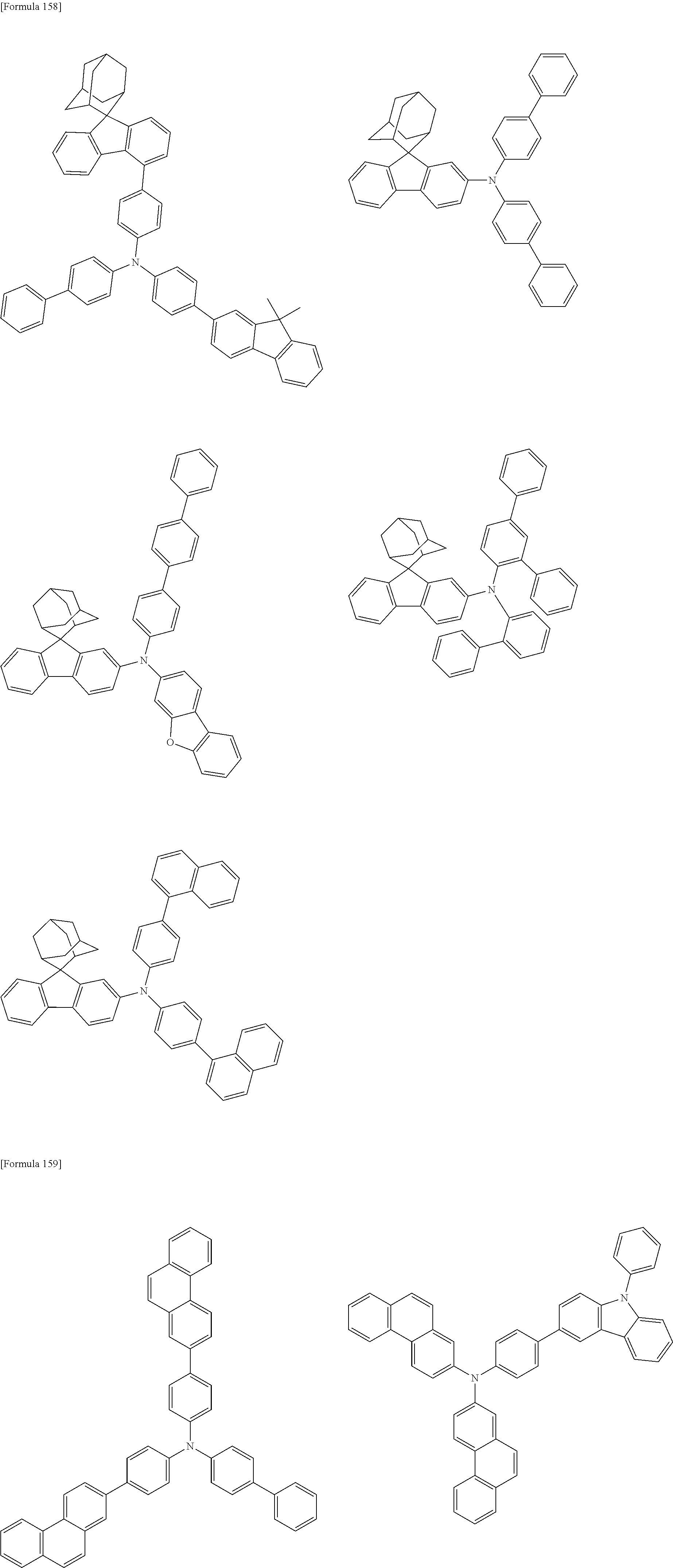

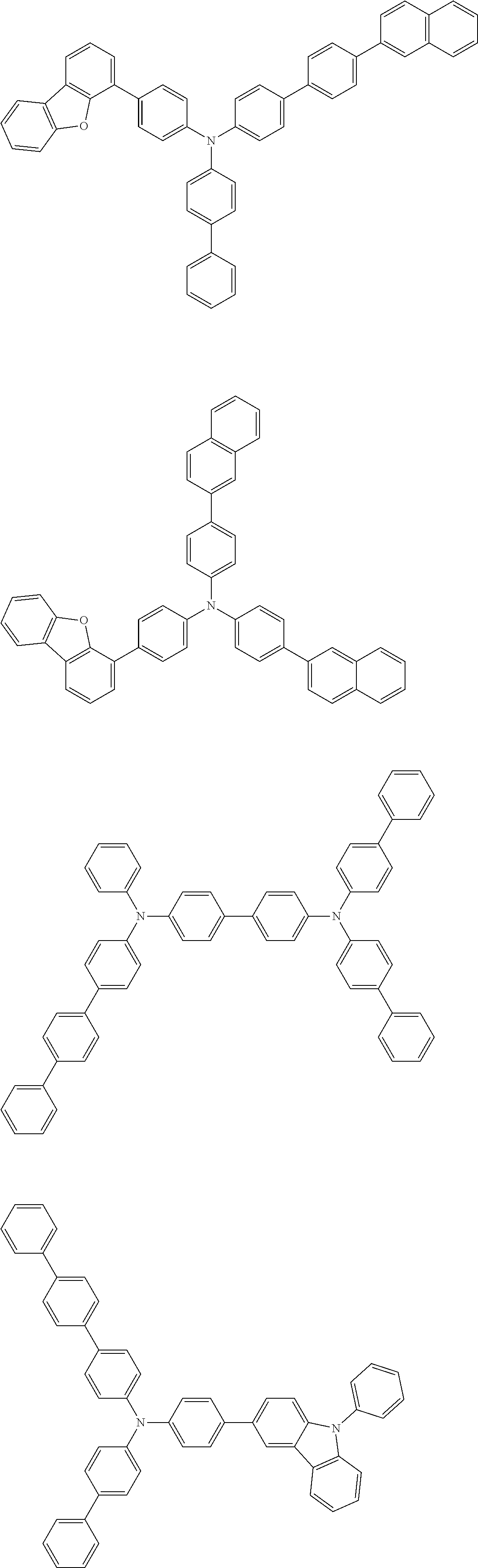 [SMILES: c1ccc(-c2ccc(N(c3ccc(-c4ccc(-c5ccc6ccccc6c5)cc4)cc3)c3ccc(-c4cccc5c4oc4ccccc45)cc3)cc2)cc1 ; c1ccc2cc(-c3ccc(N(c4ccc(-c5ccc6ccccc6c5)cc4)c4ccc(-c5cccc6c5oc5ccccc56)cc4)cc3)ccc2c1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

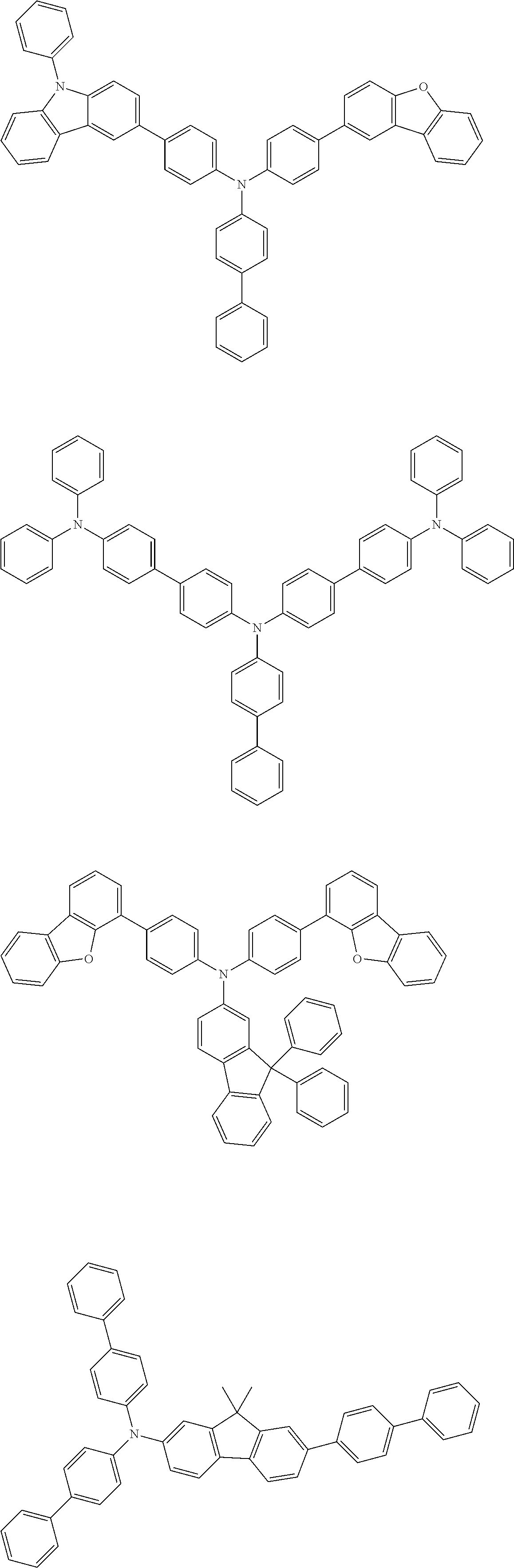 [SMILES: c1ccc(-c2ccc(N(c3ccc(-c4ccc5oc6ccccc6c5c4)cc3)c3ccc(-c4ccc5c(c4)c4ccccc4n5-c4ccccc4)cc3)cc2)cc1 ; c1ccc(-c2ccc(N(c3ccc(-c4ccc(N(c5ccccc5)c5ccccc5)cc4)cc3)c3ccc(-c4ccc(N(c5ccccc5)c5ccccc5)cc4)cc3)cc2)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; CC1(C)c2cc(-c3ccc(-c4ccccc4)cc3)ccc2-c2ccc(N(c3ccc(-c4ccccc4)cc3)c3ccc(-c4ccccc4)cc3)cc21]

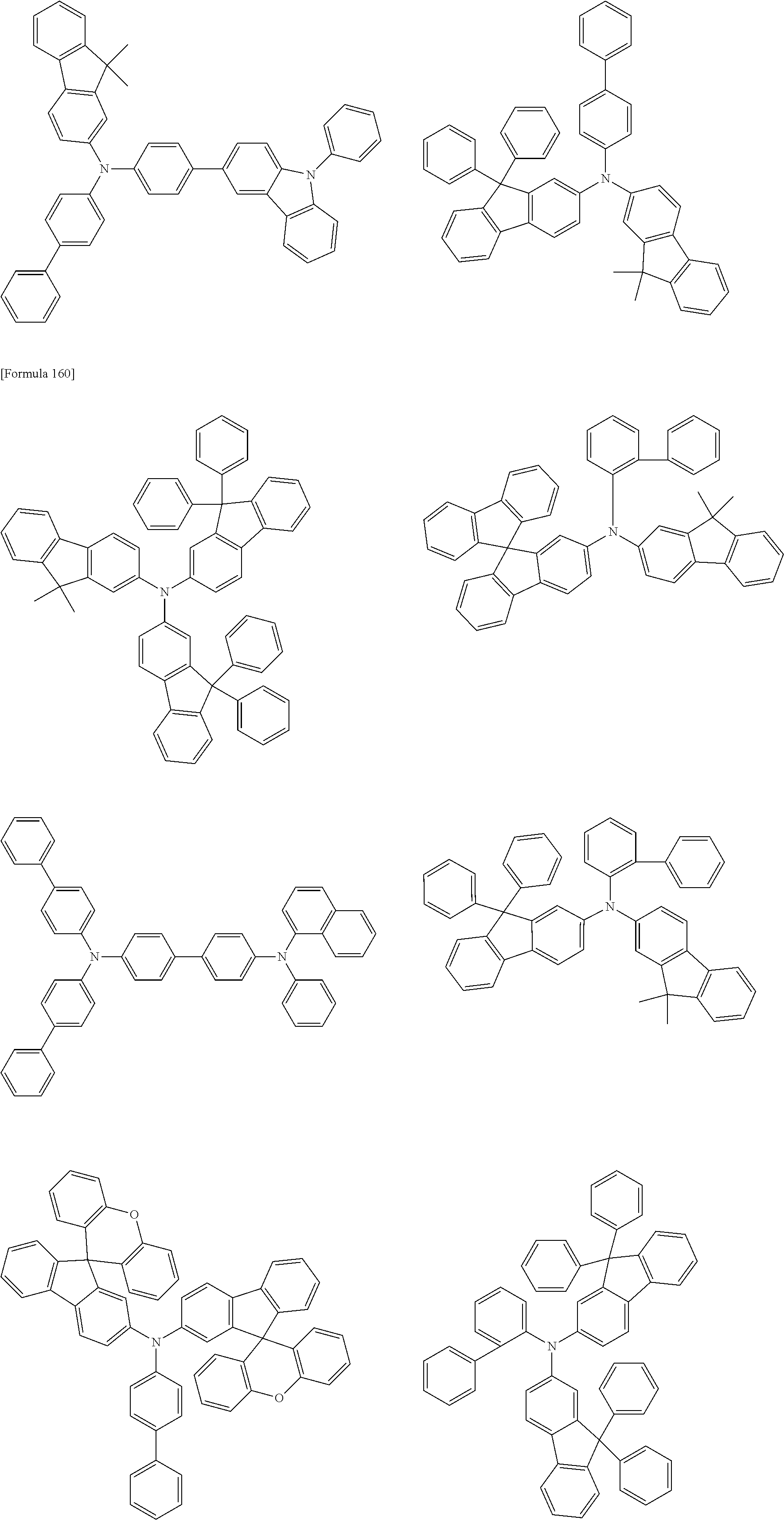

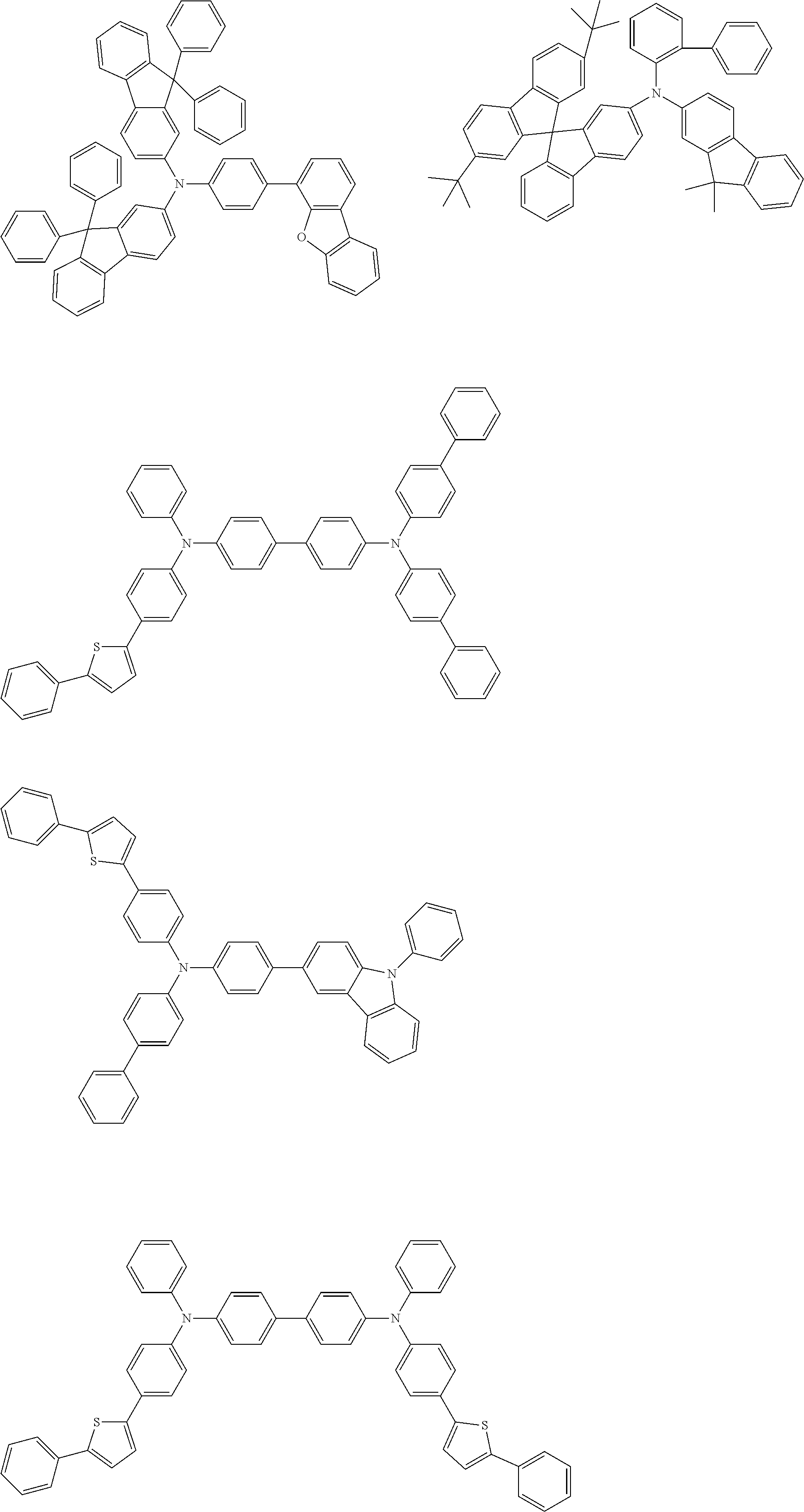

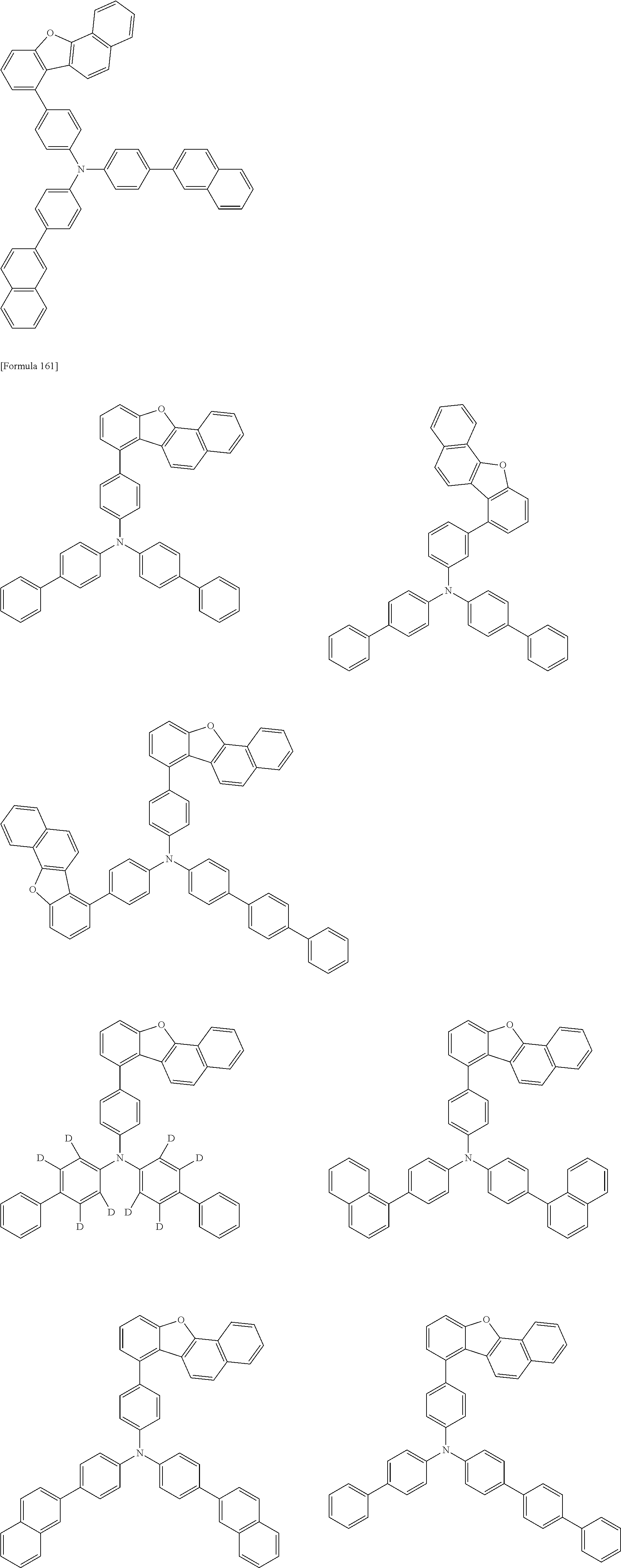

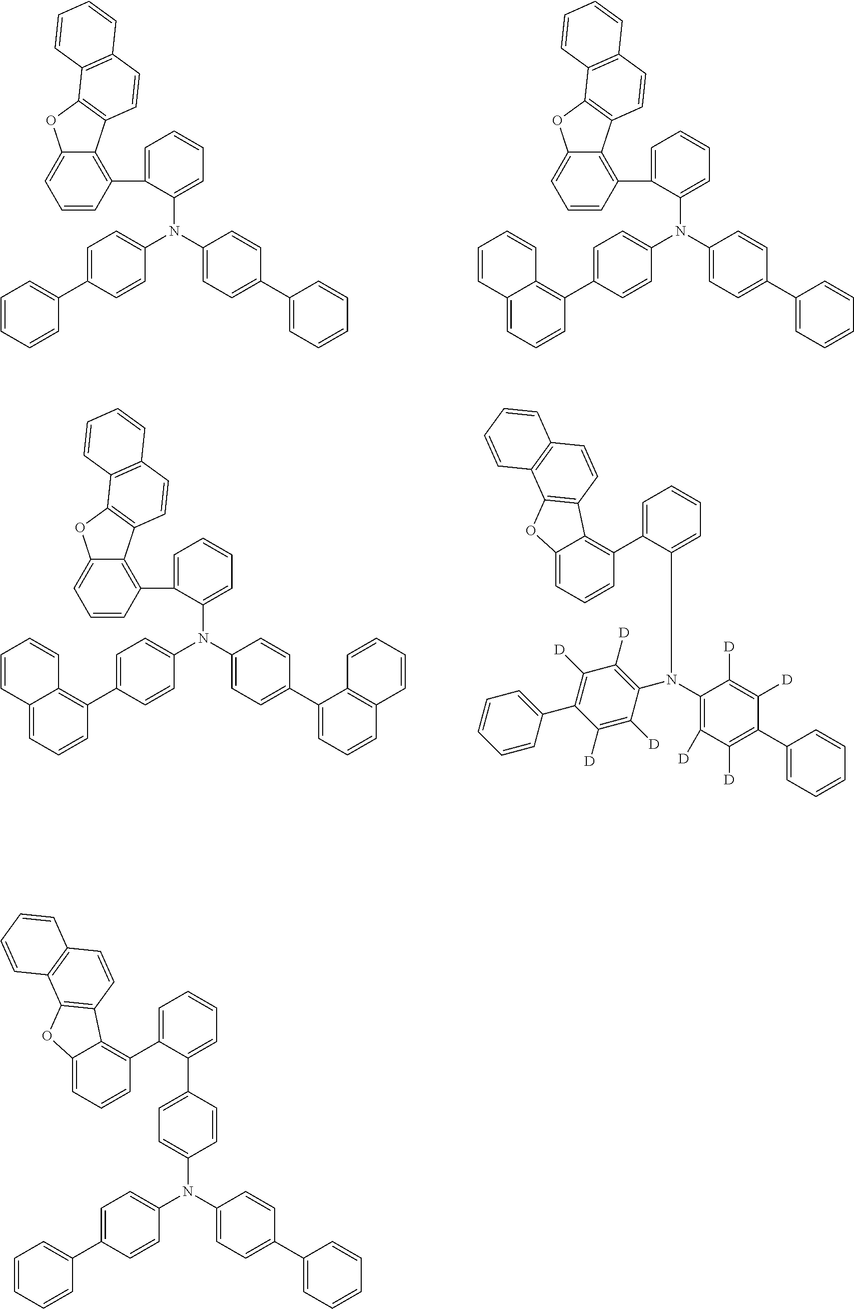 [SMILES: c1ccc(-c2ccc(N(c3ccc(-c4ccccc4)cc3)c3ccccc3-c3cccc4oc5c6ccccc6ccc5c34)cc2)cc1 ; c1ccc(-c2ccc(N(c3ccc(-c4cccc5ccccc45)cc3)c3ccccc3-c3cccc4oc5c6ccccc6ccc5c34)cc2)cc1 ; c1ccc(N(c2ccc(-c3cccc4ccccc34)cc2)c2ccc(-c3cccc4ccccc34)cc2)c(-c2cccc3oc4c5ccccc5ccc4c23)c1 ; [2H]c1c([2H])c(N(c2ccccc2-c2cccc3oc4c5ccccc5ccc4c23)c2c([2H])c([2H])c(-c3ccccc3)c([2H])c2[2H])c([2H])c([2H])c1-c1ccccc1 ; c1ccc(-c2ccc(N(c3ccc(-c4ccccc4)cc3)c3ccc(-c4ccccc4-c4cccc5oc6c7ccccc7ccc6c45)cc3)cc2)cc1]

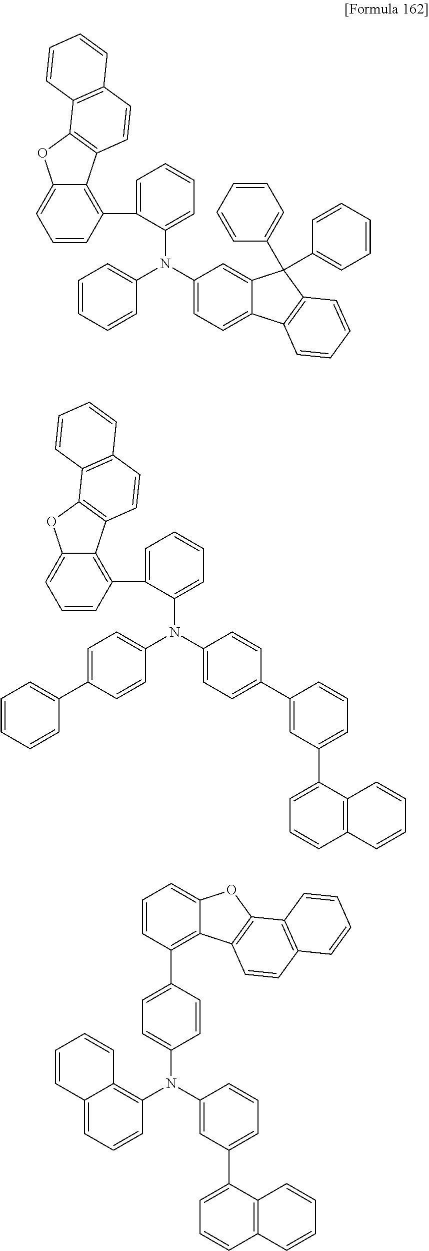 [SMILES: c1ccc(N(c2ccc3c(c2)C(c2ccccc2)(c2ccccc2)c2ccccc2-3)c2ccccc2-c2cccc3oc4c5ccccc5ccc4c23)cc1 ; c1ccc(-c2ccc(N(c3ccc(-c4cccc(-c5cccc6ccccc56)c4)cc3)c3ccccc3-c3cccc4oc5c6ccccc6ccc5c34)cc2)cc1 ; c1cc(-c2cccc3ccccc23)cc(N(c2ccc(-c3cccc4oc5c6ccccc6ccc5c34)cc2)c2cccc3ccccc23)c1]

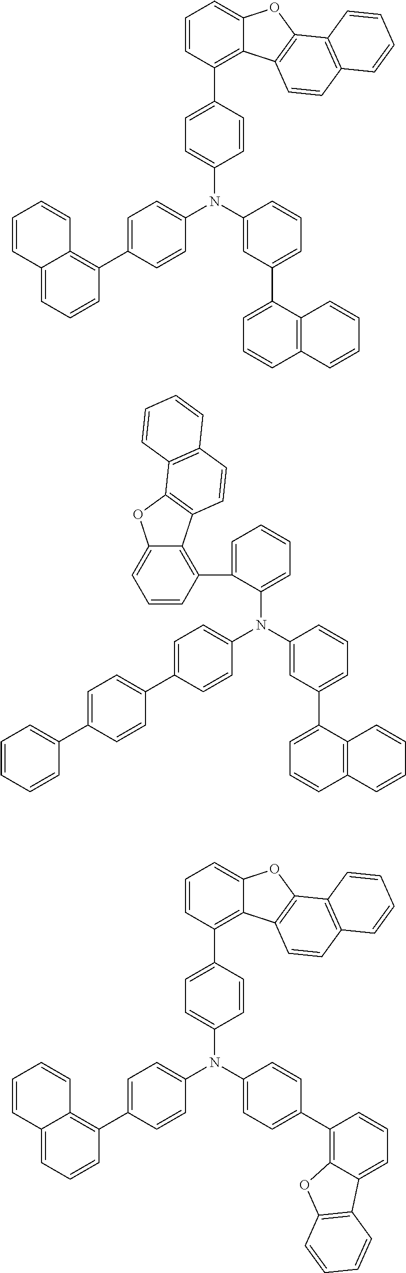 [SMILES: c1cc(-c2cccc3ccccc23)cc(N(c2ccc(-c3cccc4ccccc34)cc2)c2ccc(-c3cccc4oc5c6ccccc6ccc5c34)cc2)c1 ; c1ccc(-c2ccc(-c3ccc(N(c4cccc(-c5cccc6ccccc56)c4)c4ccccc4-c4cccc5oc6c7ccccc7ccc6c45)cc3)cc2)cc1 ; c1ccc2c(-c3ccc(N(c4ccc(-c5cccc6c5oc5ccccc56)cc4)c4ccc(-c5cccc6oc7c8ccccc8ccc7c56)cc4)cc3)cccc2c1]

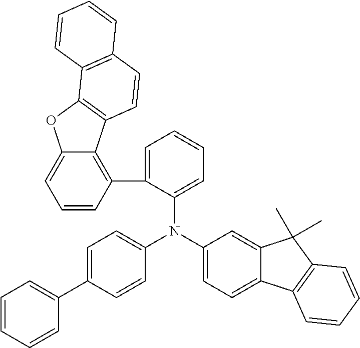 [SMILES: CC1(C)c2ccccc2-c2ccc(N(c3ccc(-c4ccccc4)cc3)c3ccccc3-c3cccc4oc5c6ccccc6ccc5c34)cc21]

### Hole Injecting Layer

In an exemplary arrangement of the organic EL device according to the exemplary embodiment, the anode and the hole injecting layer are in direct contact with each other.

In an exemplary arrangement of the organic EL device according to the exemplary embodiment, the hole injecting layer and a first hole transporting layer are in direct contact with each other.

In an exemplary arrangement of the organic EL device according to the exemplary embodiment, the hole injecting layer and a third hole transporting layer are in direct contact with each other.

In an exemplary arrangement of the organic EL device according to the exemplary embodiment, the hole injecting layer contains an acceptor material.

### Acceptor Material

An acceptor material has at least one of a first cyclic structure represented by a formula (11) below or a second cyclic structure represented by a formula (12).

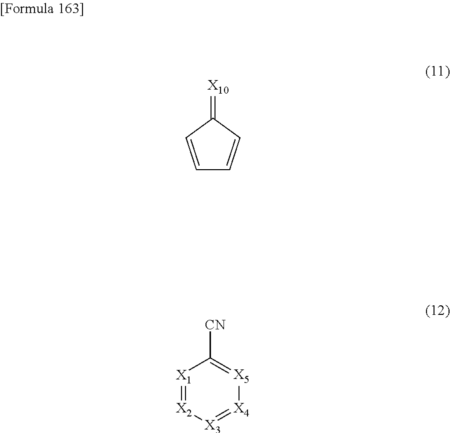

The first cyclic structure represented by the formula (11) is fused, in a molecule of the acceptor material, to at least one cyclic structure of a substituted or unsubstituted aromatic hydrocarbon ring having 6 to 50 ring carbon atoms or a substituted or unsubstituted heterocycle having 5 to 50 ring atoms, and a structure represented by ═X₁₀ is represented by a formula (11a), (11 b), (11c), (11d), (11e), (11f), (11 g), (11 h), (11i), (11j), (11k), or (11 m) below.

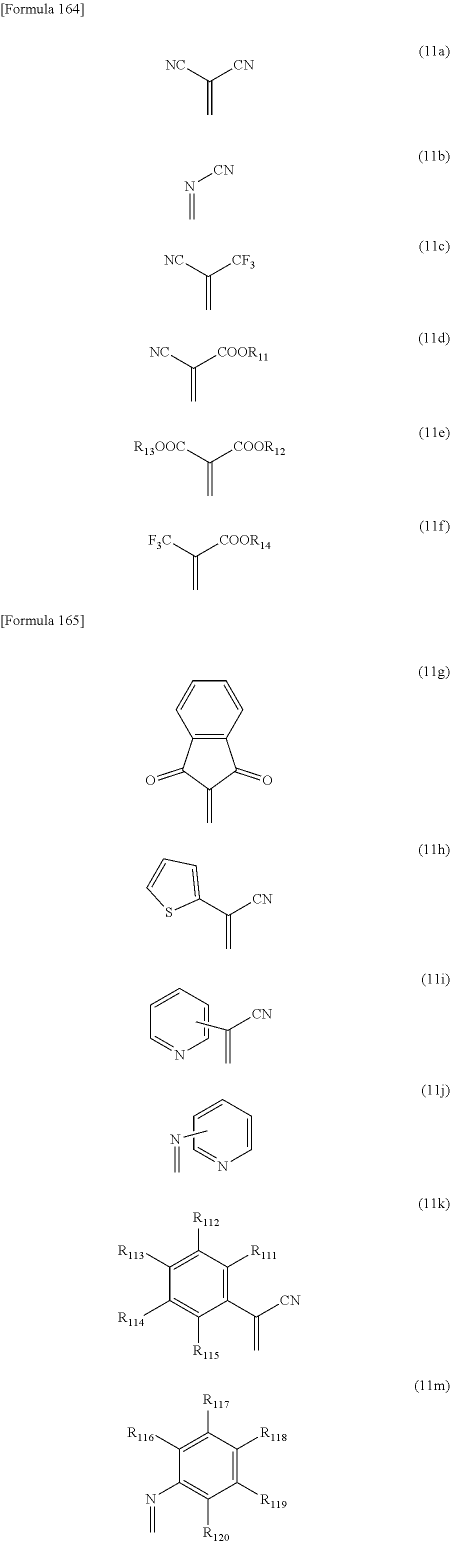

In the formula (11a), (11 b), (11c), (11 d), (11e), (11f), (11 g), (11 h), (11 i), (11j), (11k) or (11 m):
R₁₀₁ to R₁₄ and R₁₁₁ to R₁₂₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the formula (12):
X₁ to X₅ are each independently a nitrogen atom, a carbon atom bonded to R₁₅, or a carbon atom bonded to another atom in a molecule of the acceptor material;
at least one of X₁ to X₅ is a carbon atom bonded to another atom in the molecule of the acceptor material;
R₁₅ is selected from the group consisting of a hydrogen atom, a halogen atom, a cyano group, a substituted or unsubstituted alkyl group having 1 to 50 carbon atoms a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the acceptor material, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of In the organic EL device according to the exemplary embodiment, the acceptor material has at least one cyano group.

In an exemplary arrangement of the organic EL device according to the exemplary embodiment, the hole injecting layer contains a first organic material, the acceptor material and the first organic material are mutually different, and a content of the acceptor material in the hole injecting layer is less than 50 mass %.

In an exemplary arrangement of the organic EL device according to the exemplary embodiment, the content of the acceptor material in the hole injecting layer is 10 mass % or less or 5 mass % or less.

In an exemplary arrangement of the organic EL device according to the exemplary embodiment, the content of the acceptor material in the hole injecting layer is 1 mass % or more or 3 mass % or less.

In an exemplary arrangement of the organic EL device according to the exemplary embodiment, the first organic material is preferably a compound selected from the group consisting of the above-described hole transporting zone materials.

In an exemplary arrangement of the organic EL device according to the exemplary embodiment, the first organic material is a monoamine compound having one substituted or unsubstituted amino group in a molecule, or a diamine compound having two substituted or unsubstituted amino groups in a molecule.

In an exemplary arrangement of the organic EL device according to the exemplary embodiment, the first organic material is a monoamine compound having one substituted or unsubstituted amino group in a molecule.

In an exemplary arrangement of the organic EL device according to the exemplary embodiment, in a case where the hole injecting layer contains the acceptor material and the first organic material, a content of the first organic material in the hole injecting layer is preferably 40 mass % or more, more preferably 45 mass % or more, and still more preferably 50 mass % or more. The content of the first organic material in the hole injecting layer is preferably 99.5 mass % or less. The total of the content of the acceptor material and the content of the first organic material in the hole injecting layer is 100 mass % or less.

An ester group herein is at least one group selected from the group consisting of an alkyl ester group and an aryl ester group.

An alkyl ester group herein is represented, for instance, by —C(═O)OR^{E}. R_{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R_{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂.

A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having 5 to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms.

R^{C} is exemplified by a substituted or unsubstituted alkyl group having 1 to 50 carbon atoms (preferably 1 to 6 carbon atoms).

In the acceptor material, the groups specified to be “substituted or unsubstituted” are each preferably an “unsubstituted” group.

### Specific Examples of Acceptor Material

Specific examples of the acceptor material include the following compounds. However, the invention is by no means limited to the specific examples.

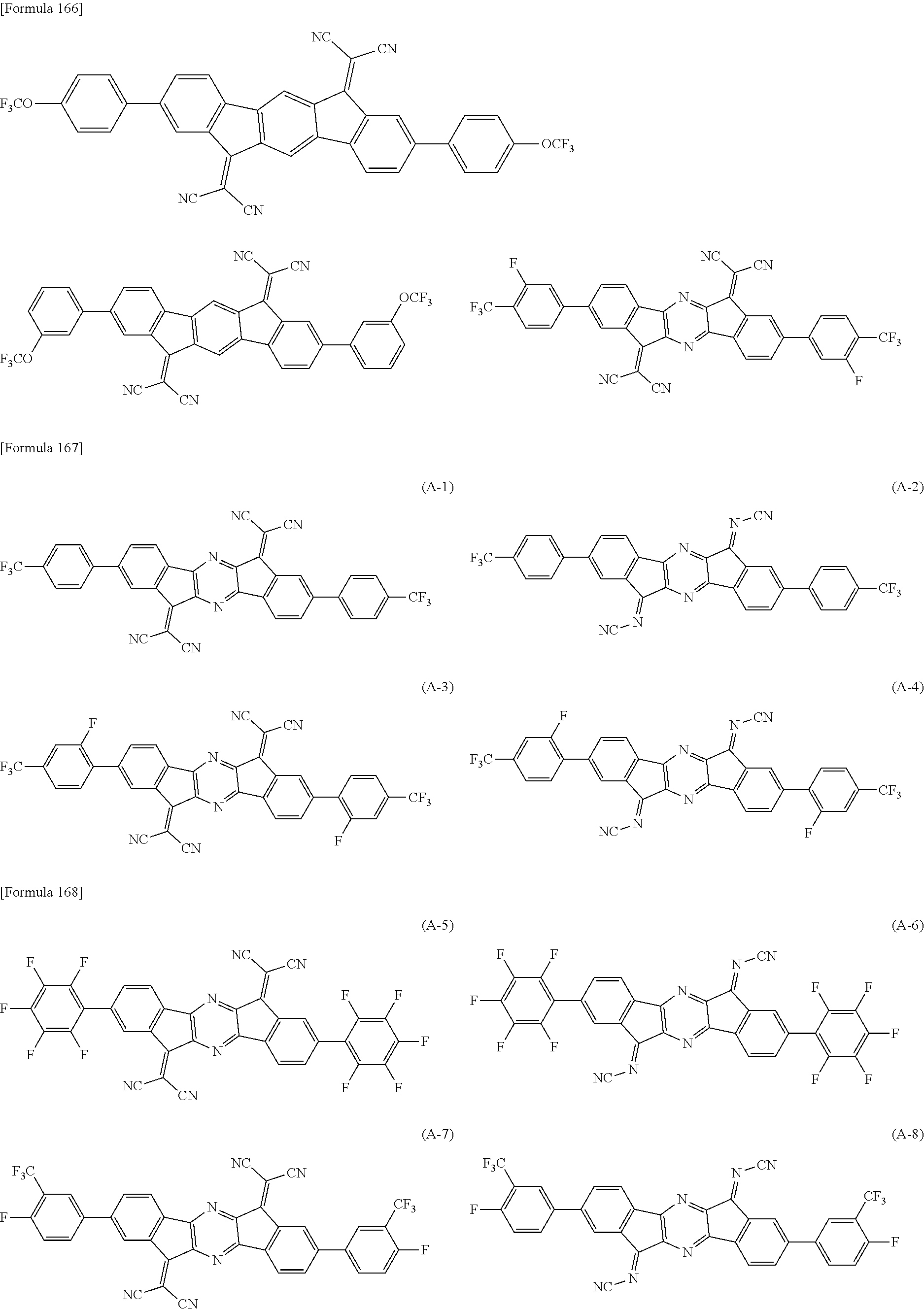

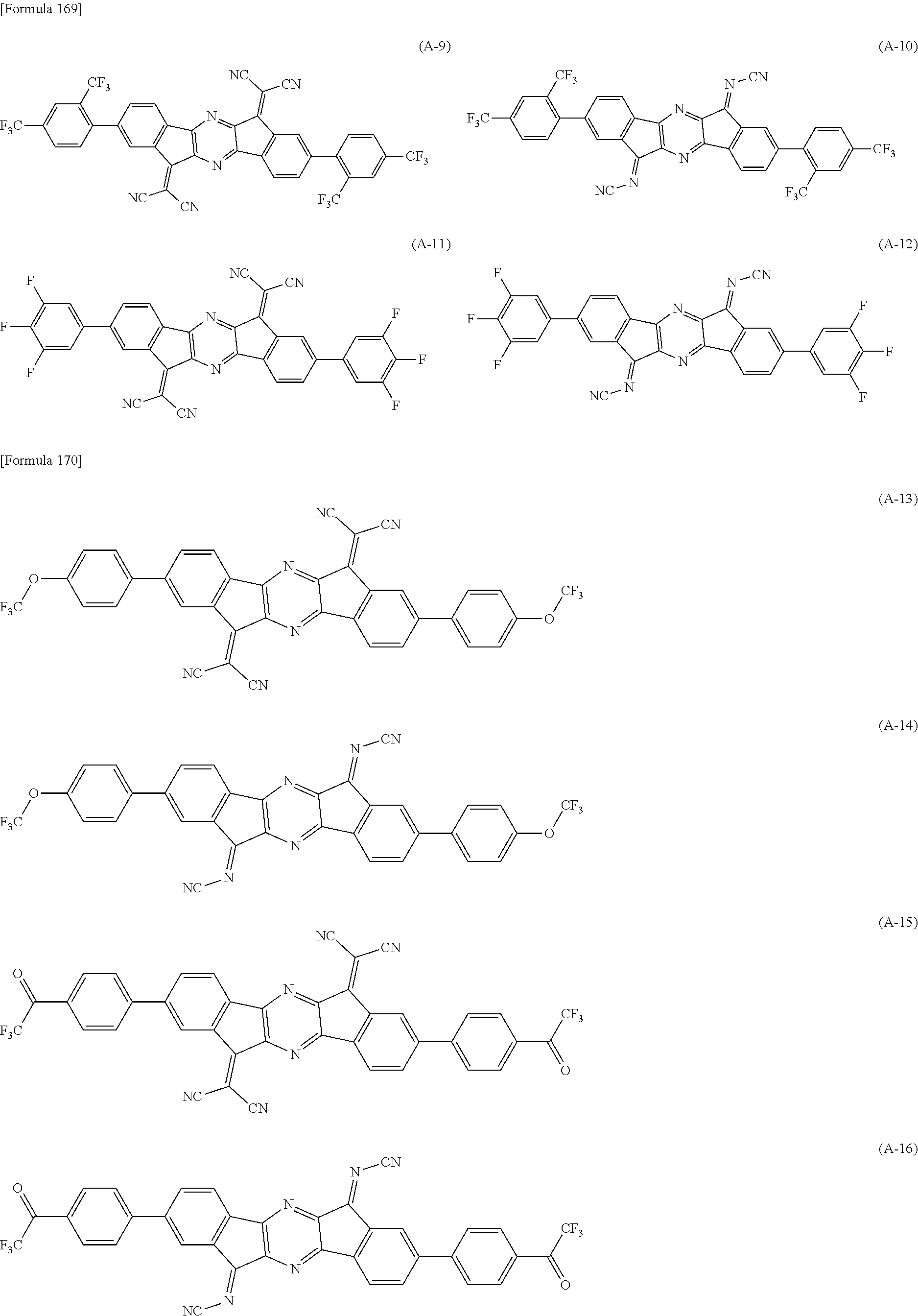

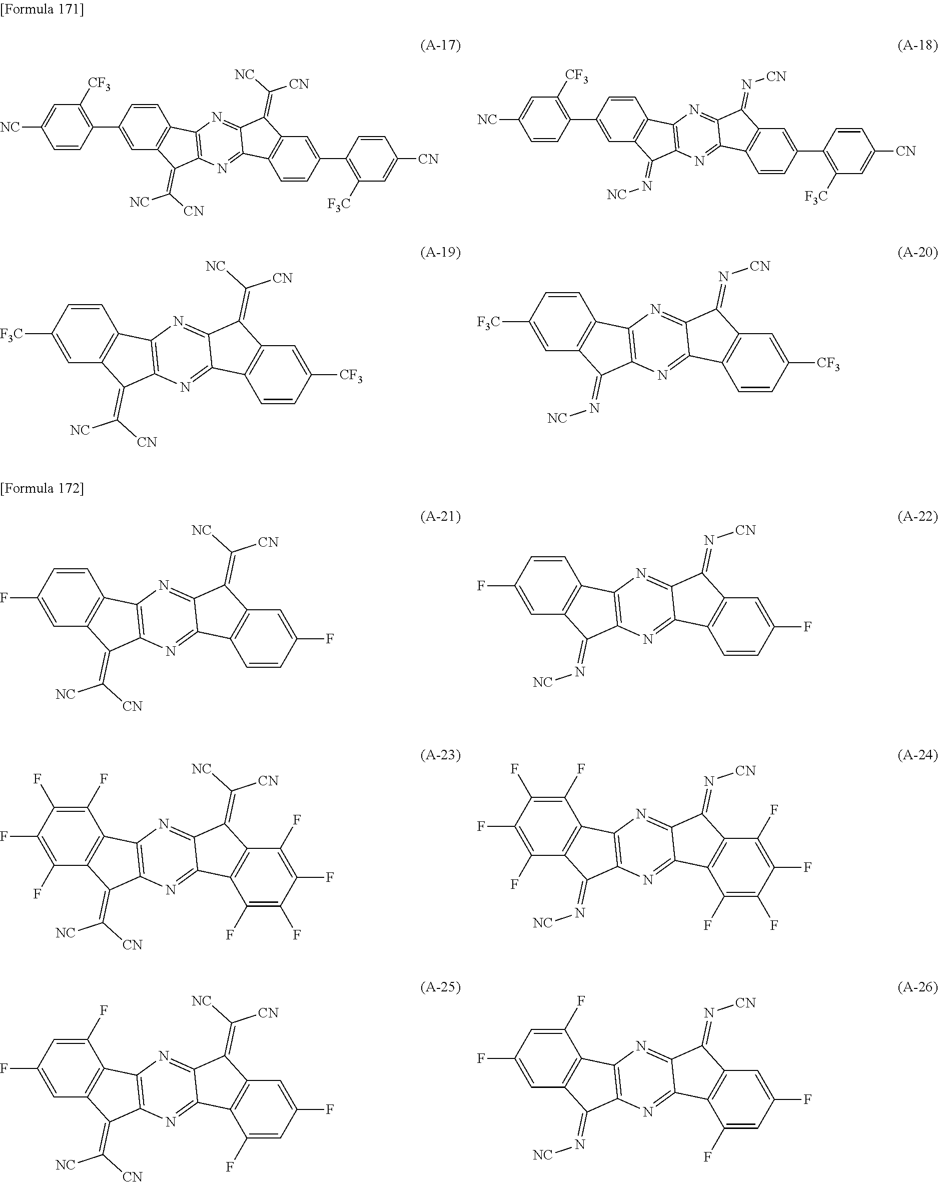

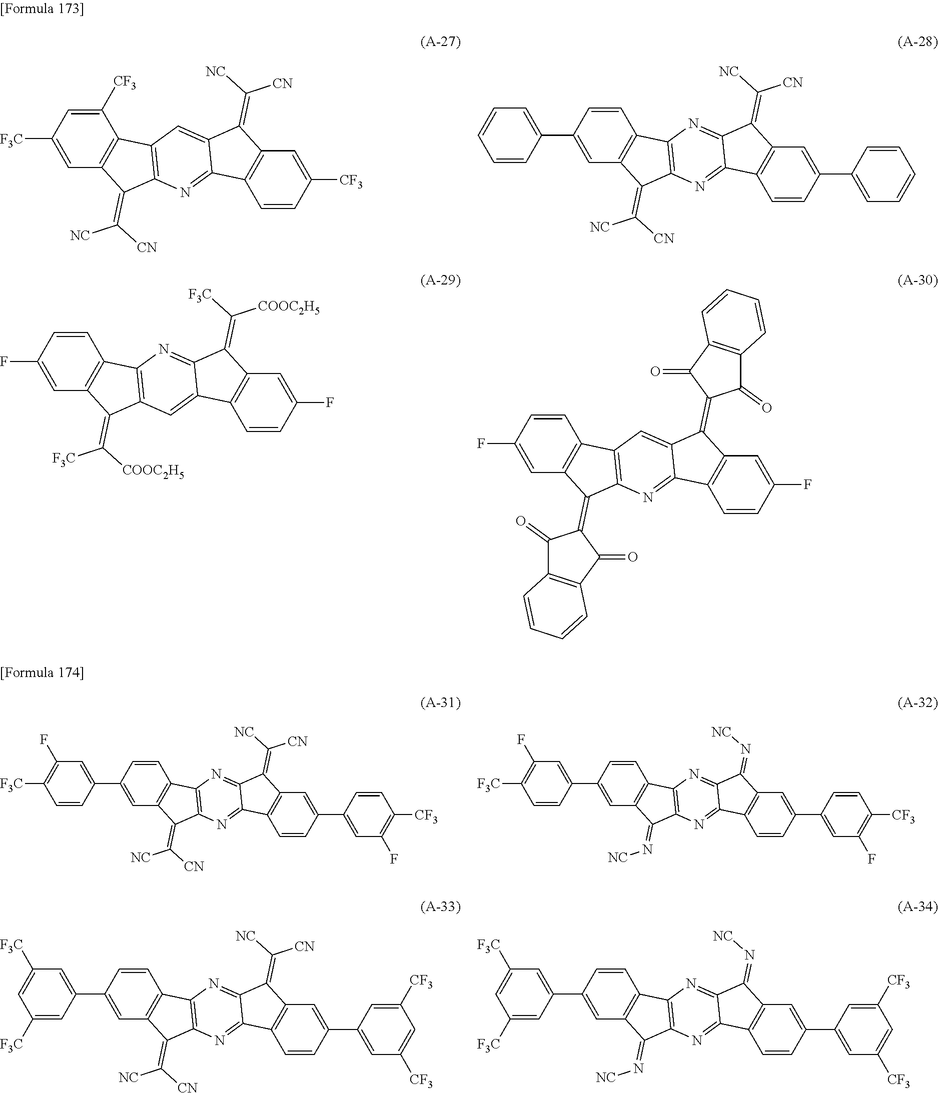

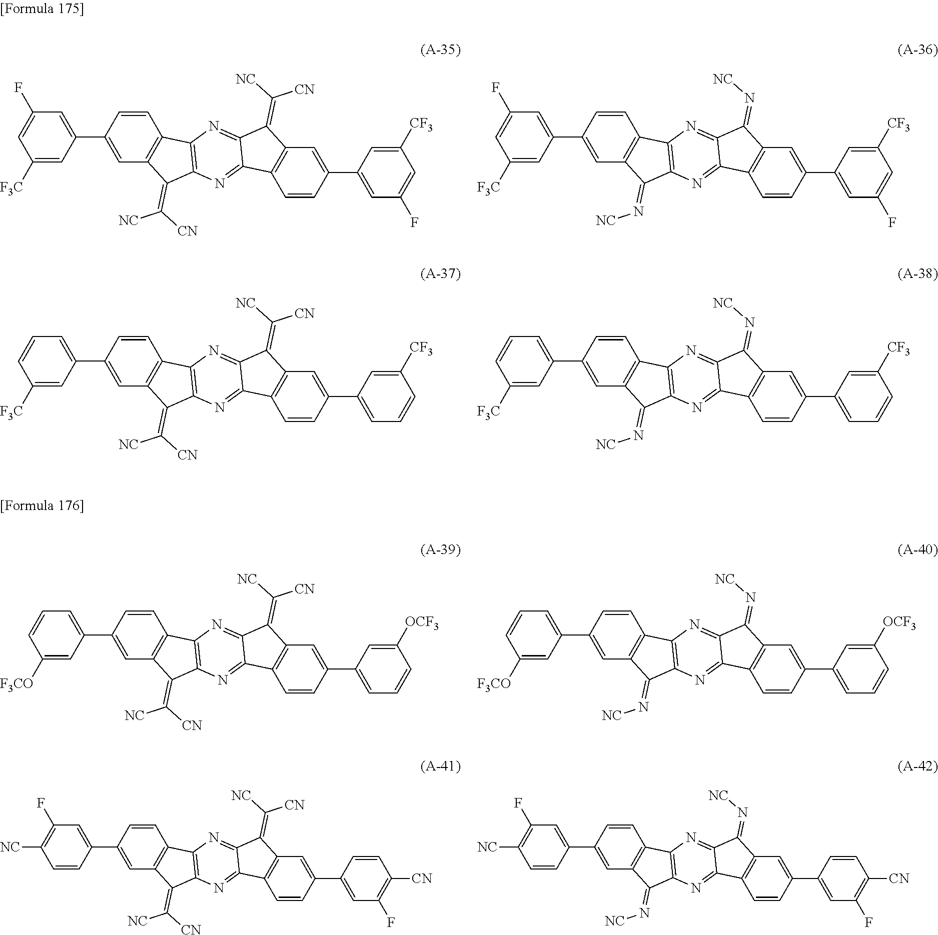

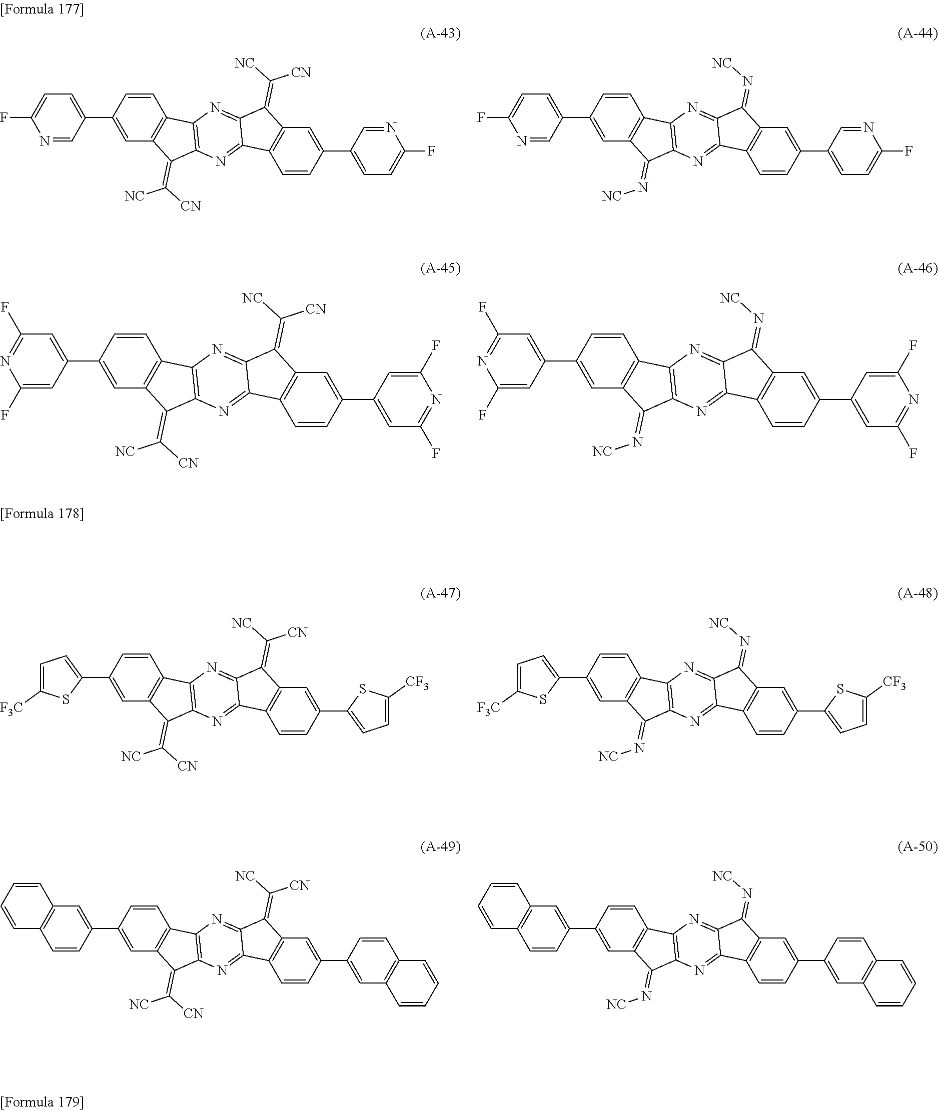

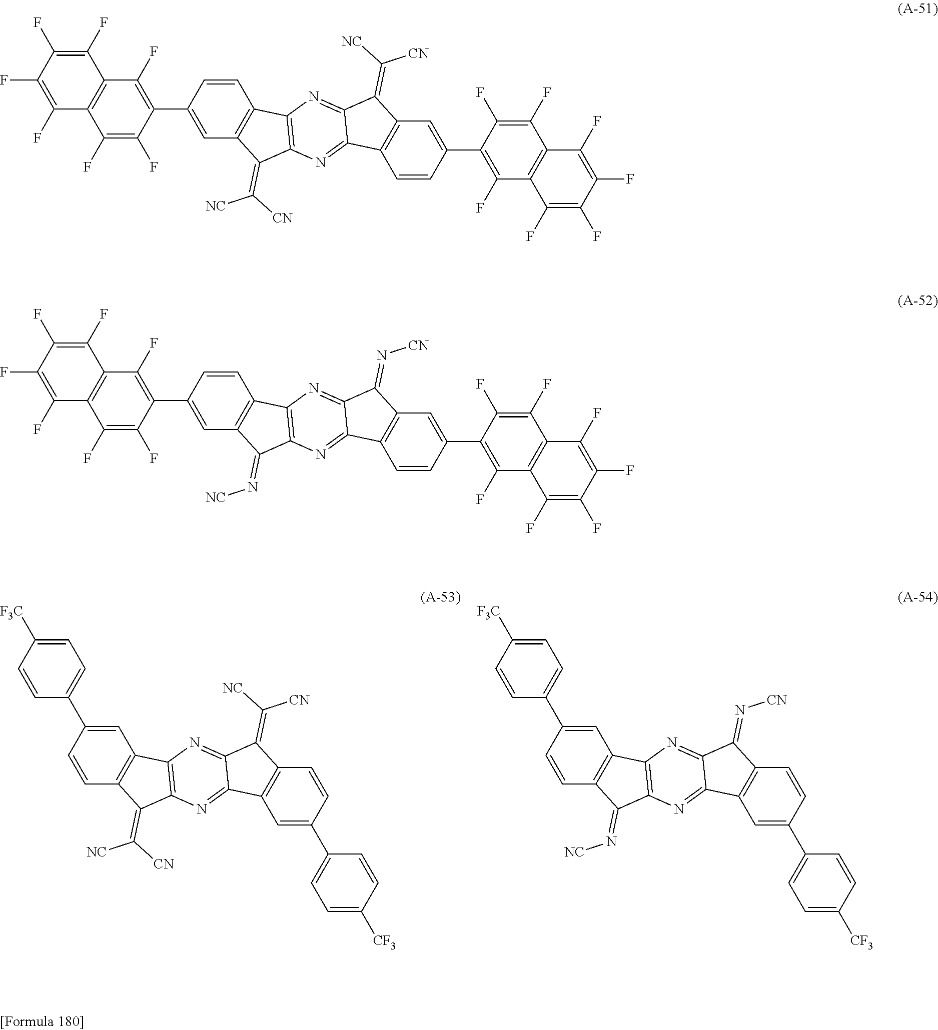 [SMILES: N#CC(C#N)=C1c2cc(-c3c(F)c(F)c4c(F)c(F)c(F)c(F)c4c3F)ccc2-c2nc3c(nc21)-c1ccc(-c2c(F)c(F)c4c(F)c(F)c(F)c(F)c4c2F)cc1C3=C(C#N)C#N ; N#C/N=c1\c2cc(-c3c(F)c(F)c4c(F)c(F)c(F)c(F)c4c3F)ccc2c2nc3/c(=N/C#N)c4cc(-c5c(F)c(F)c6c(F)c(F)c(F)c(F)c6c5F)ccc4c3nc12 ; N#CC(C#N)=C1c2ccc(-c3ccc(C(F)(F)F)cc3)cc2-c2nc3c(nc21)-c1cc(-c2ccc(C(F)(F)F)cc2)ccc1C3=C(C#N)C#N ; N#C/N=c1\c2ccc(-c3ccc(C(F)(F)F)cc3)cc2c2nc3/c(=N/C#N)c4ccc(-c5ccc(C(F)(F)F)cc5)cc4c3nc12]

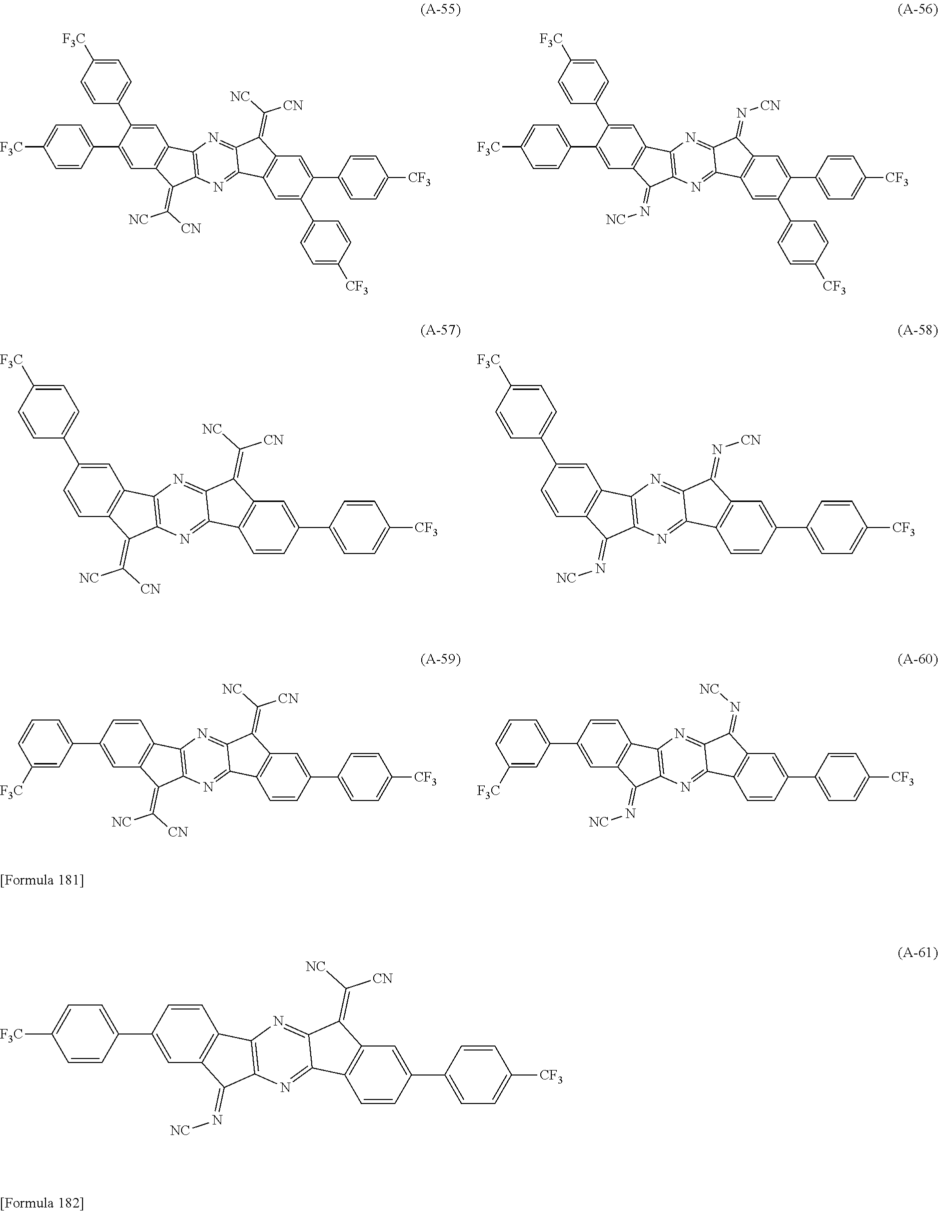

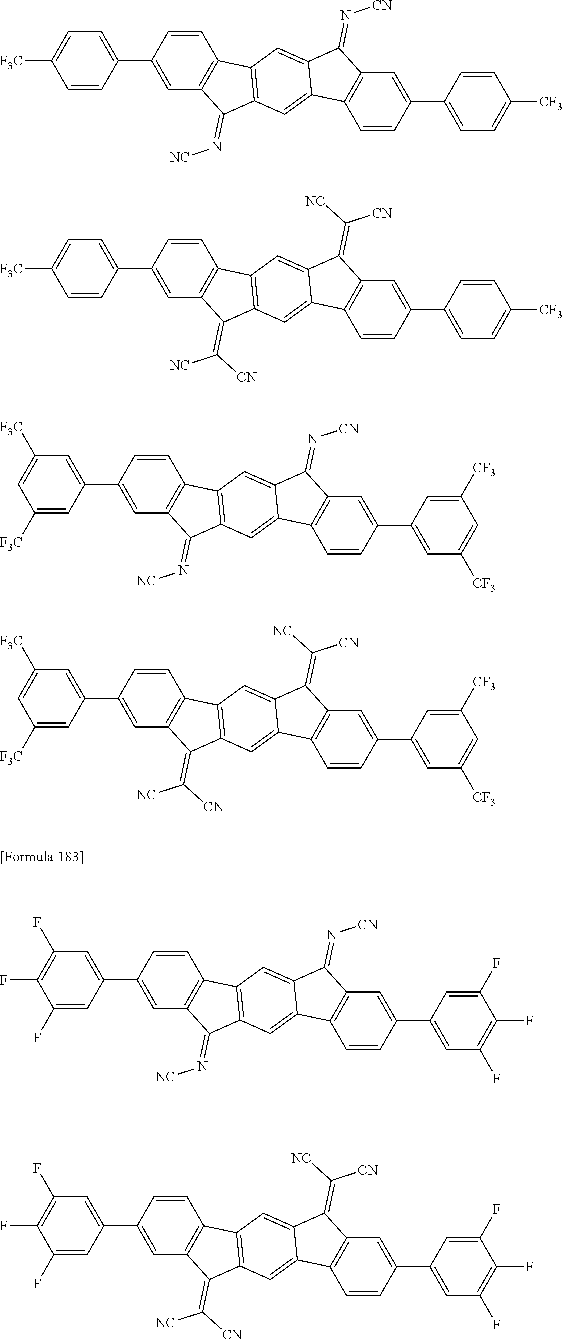

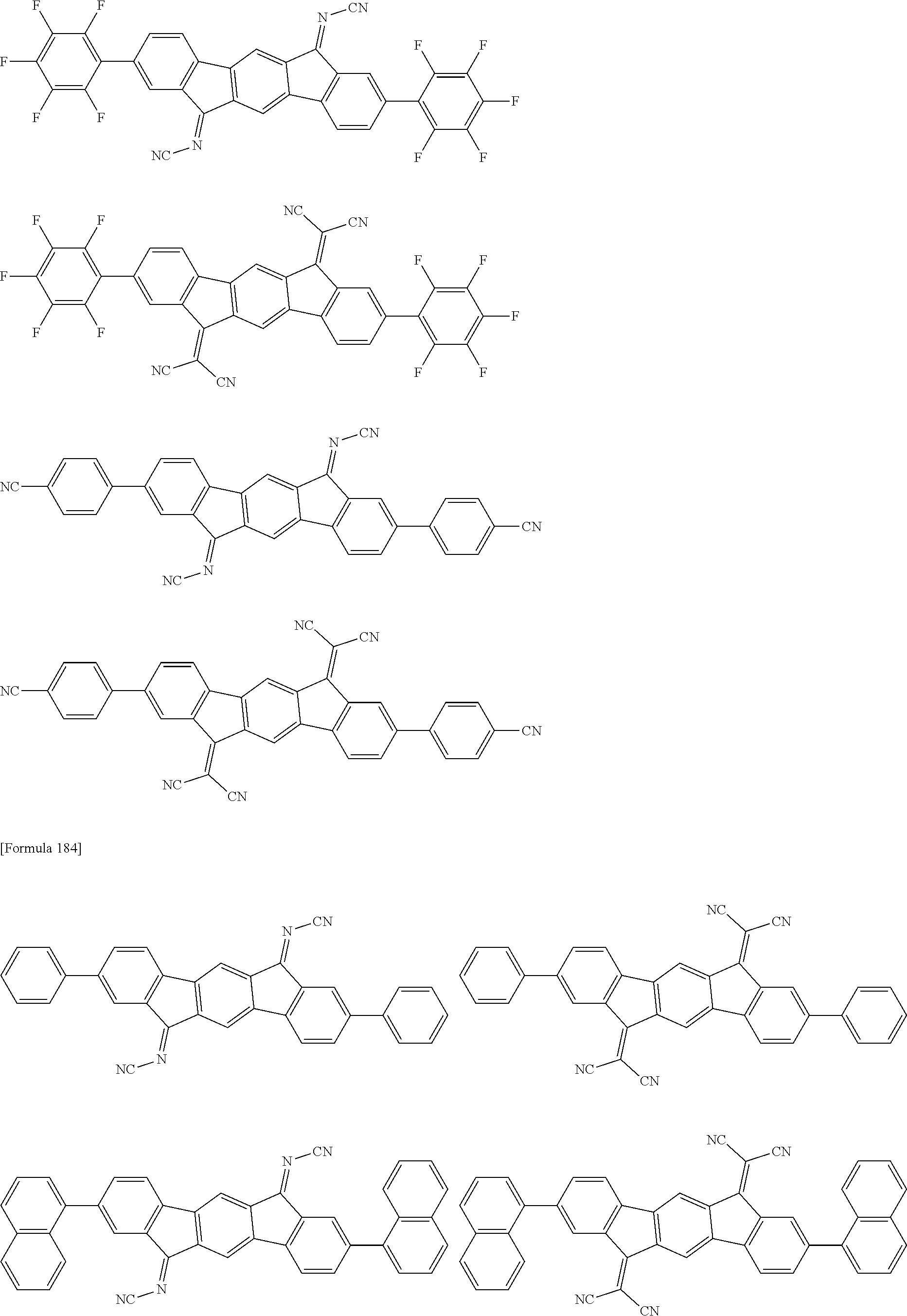

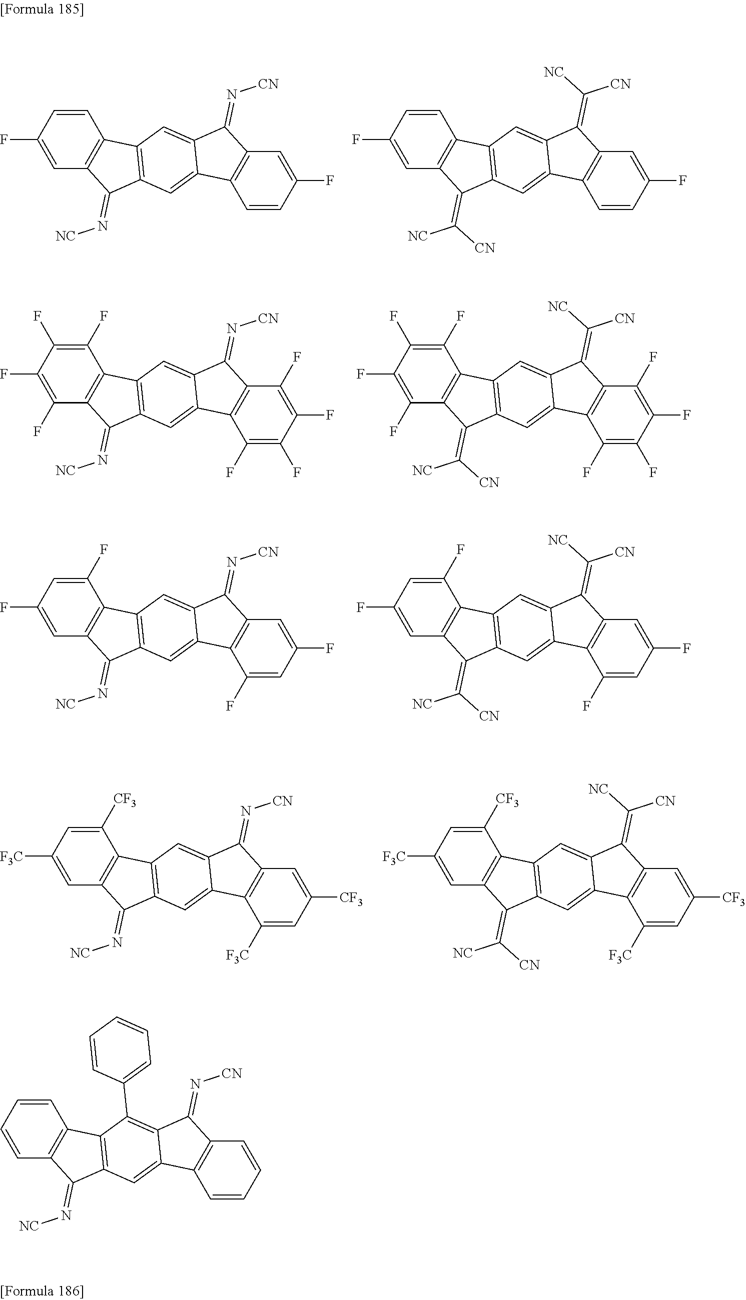

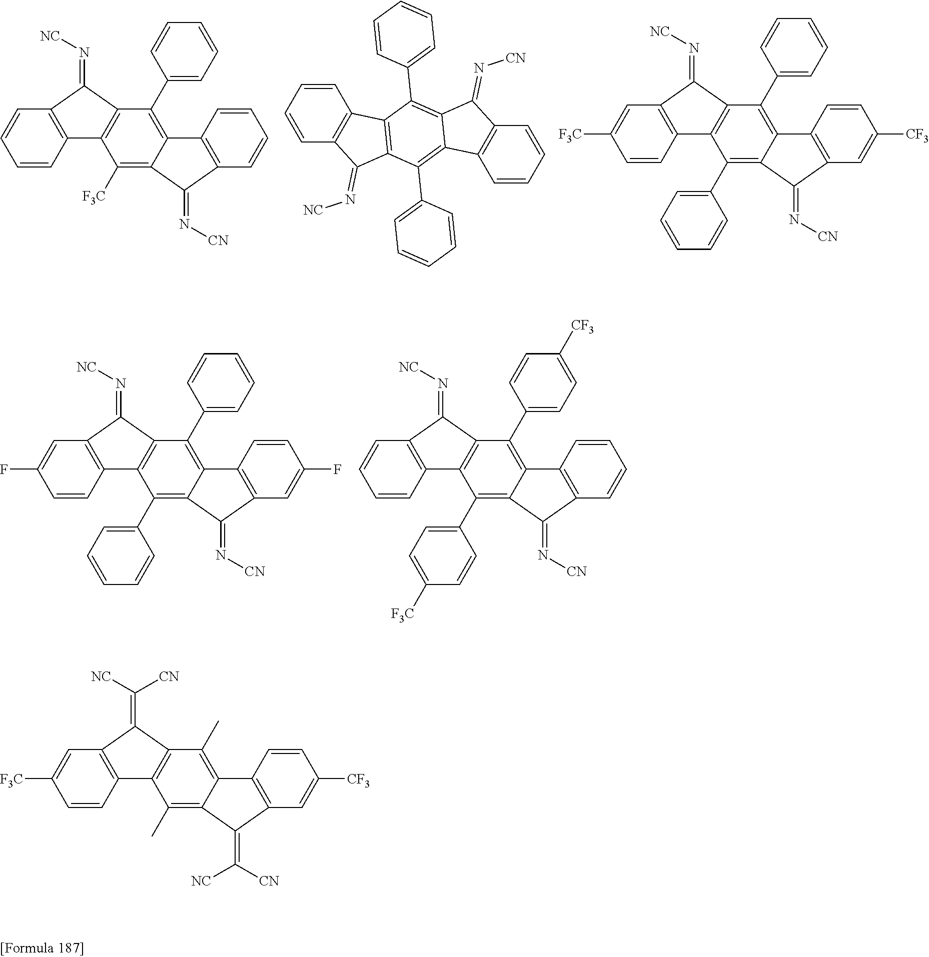

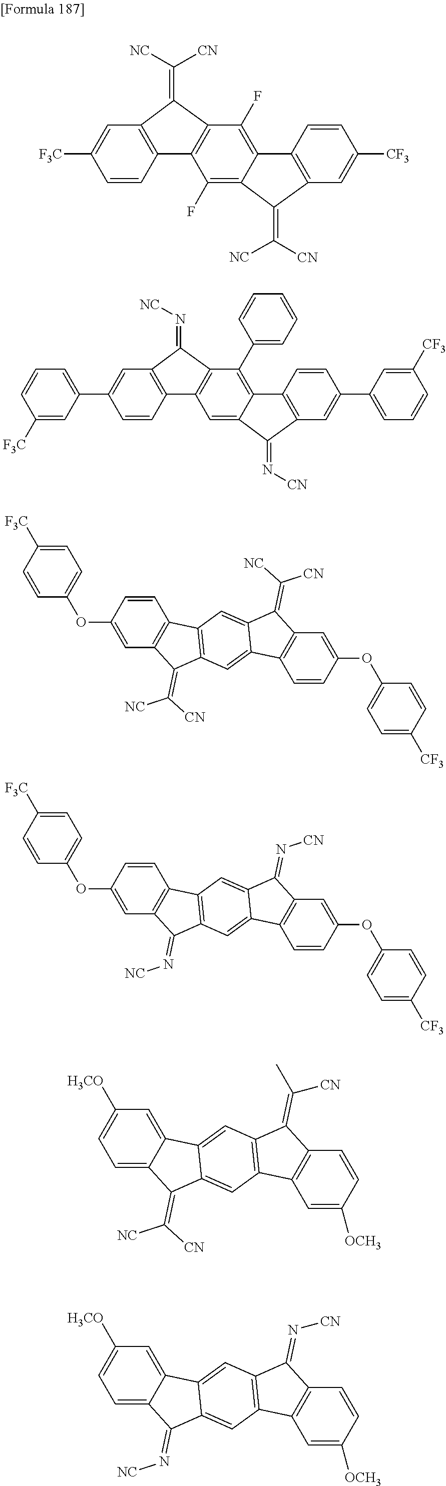

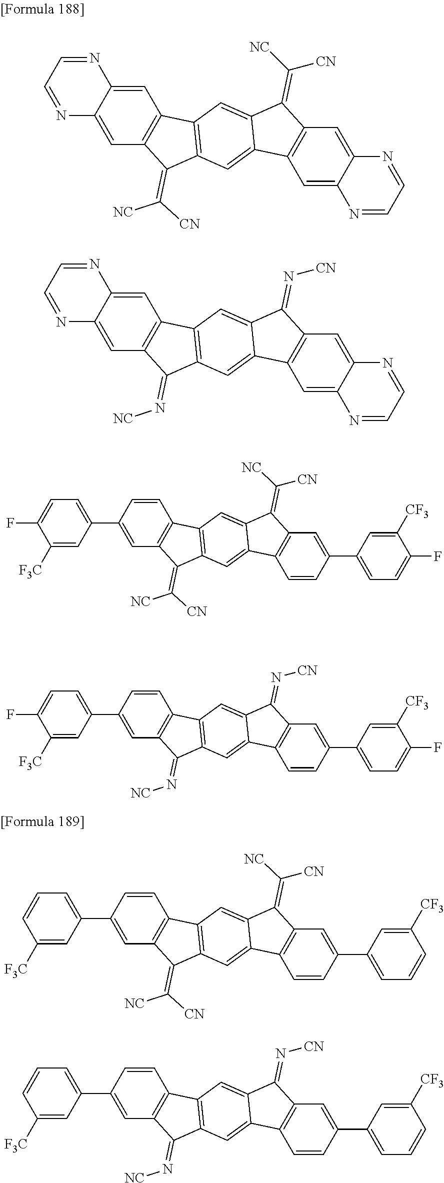

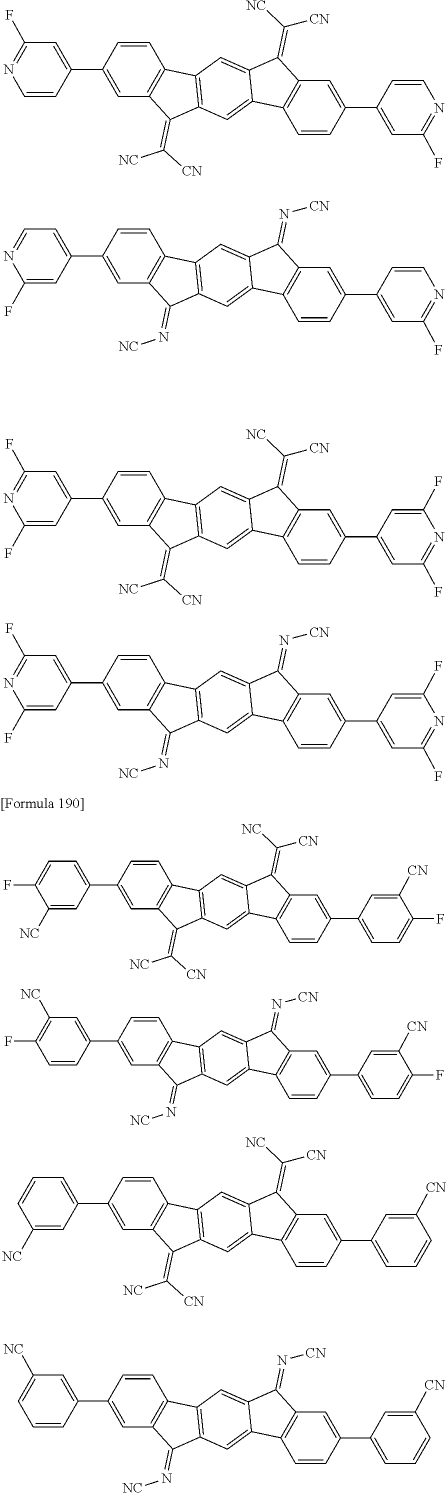

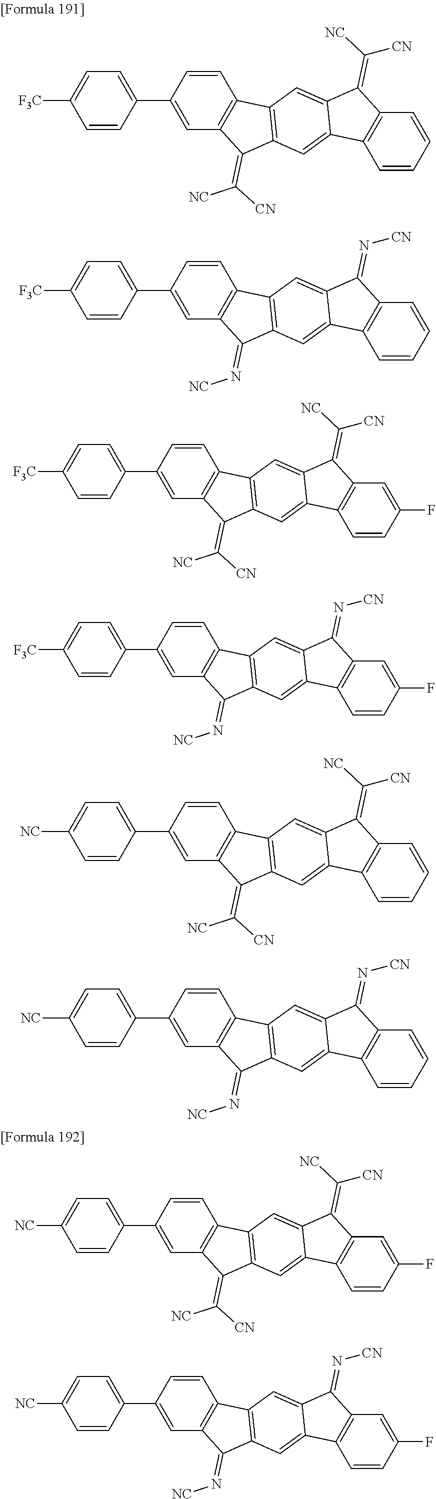

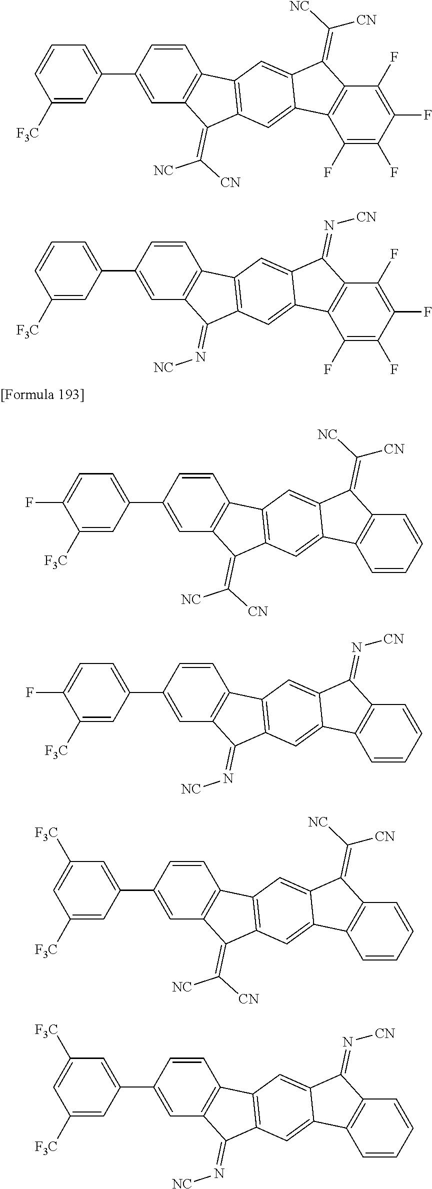 [SMILES: N#CC(C#N)=C1c2cc(-c3cccc(C(F)(F)F)c3)ccc2-c2cc3c(cc21)-c1c(F)c(F)c(F)c(F)c1C3=C(C#N)C#N ; N#C/N=c1/c2cc3c(cc2c2c(F)c(F)c(F)c(F)c12)/c(=N/C#N)c1cc(-c2cccc(C(F)(F)F)c2)ccc13 ; N#CC(C#N)=C1c2ccccc2-c2cc3c(cc21)-c1ccc(-c2ccc(F)c(C(F)(F)F)c2)cc1C3=C(C#N)C#N ; N#C/N=c1\c2ccccc2c2cc3/c(=N/C#N)c4cc(-c5ccc(F)c(C(F)(F)F)c5)ccc4c3cc12 ; N#CC(C#N)=C1c2ccccc2-c2cc3c(cc21)-c1ccc(-c2cc(C(F)(F)F)cc(C(F)(F)F)c2)cc1C3=C(C#N)C#N ; N#C/N=c1\c2ccccc2c2cc3/c(=N/C#N)c4cc(-c5cc(C(F)(F)F)cc(C(F)(F)F)c5)ccc4c3cc12]

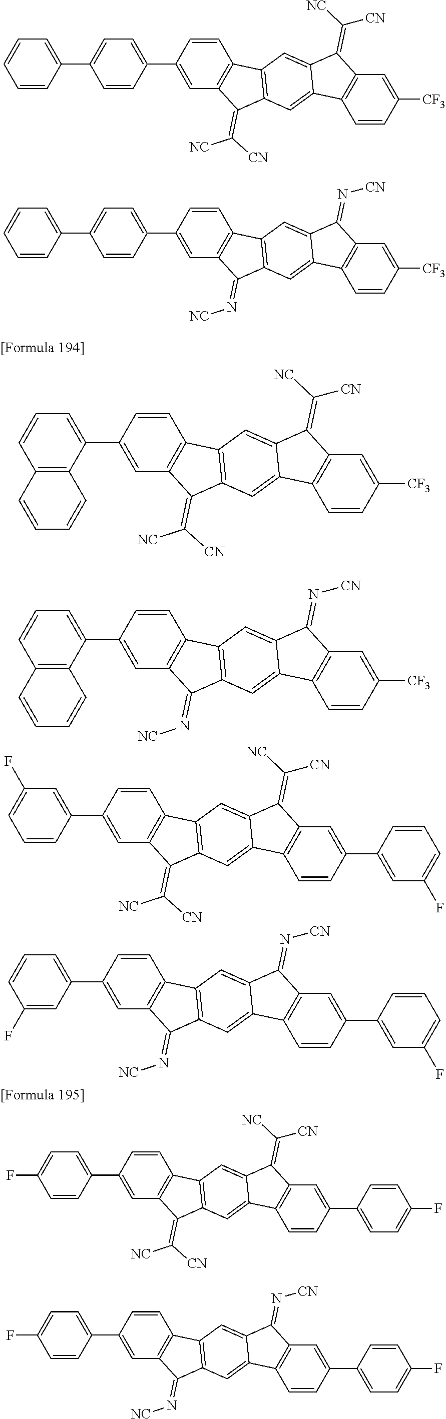

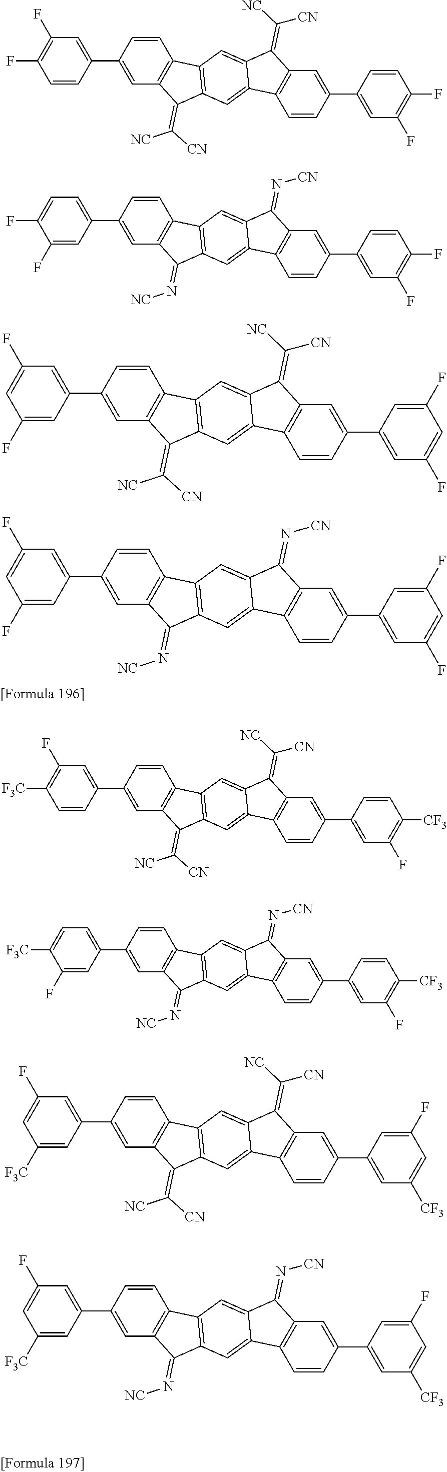

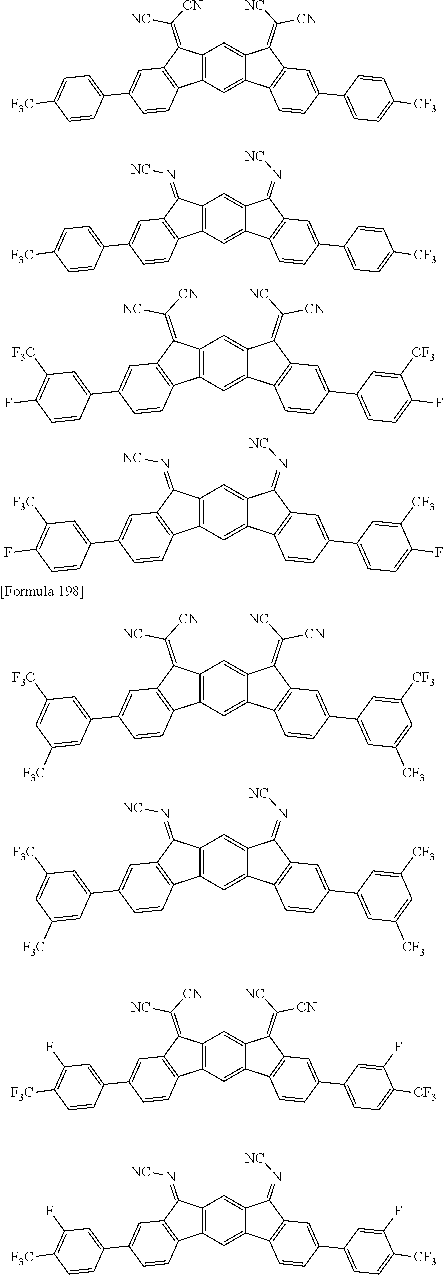

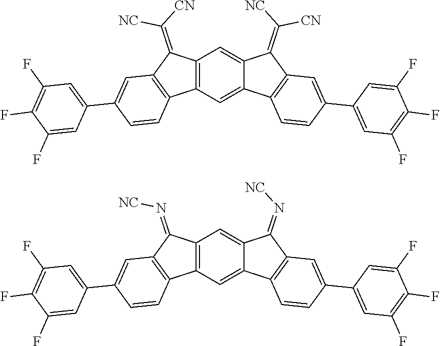 [SMILES: N#CC(C#N)=C1c2cc(-c3cc(F)c(F)c(F)c3)ccc2-c2cc3c(cc21)C(=C(C#N)C#N)c1cc(-c2cc(F)c(F)c(F)c2)ccc1-3 ; N#C/N=c1/c2cc(-c3cc(F)c(F)c(F)c3)ccc2c2cc3c(cc12)/c(=N/C#N)c1cc(-c2cc(F)c(F)c(F)c2)ccc13]

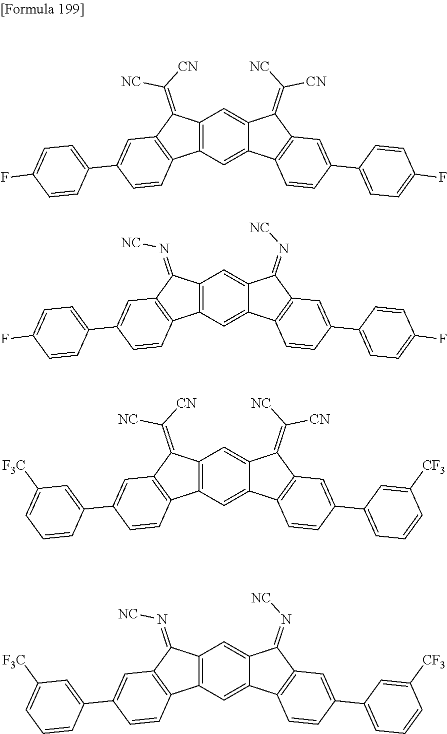 [SMILES: N#CC(C#N)=C1c2cc(-c3ccc(F)cc3)ccc2-c2cc3c(cc21)C(=C(C#N)C#N)c1cc(-c2ccc(F)cc2)ccc1-3 ; N#C/N=c1/c2cc(-c3ccc(F)cc3)ccc2c2cc3c(cc12)/c(=N/C#N)c1cc(-c2ccc(F)cc2)ccc13 ; N#CC(C#N)=C1c2cc(-c3cccc(C(F)(F)F)c3)ccc2-c2cc3c(cc21)C(=C(C#N)C#N)c1cc(-c2cccc(C(F)(F)F)c2)ccc1-3 ; N#C/N=c1/c2cc(-c3cccc(C(F)(F)F)c3)ccc2c2cc3c(cc12)/c(=N/C#N)c1cc(-c2cccc(C(F)(F)F)c2)ccc13]

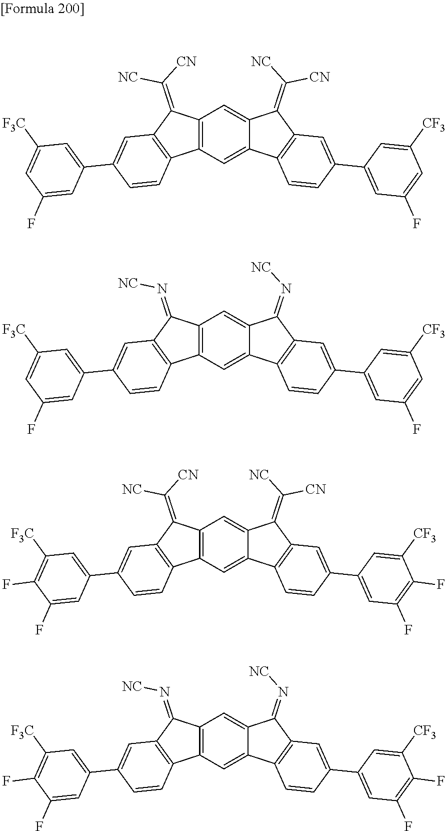 [SMILES: N#CC(C#N)=C1c2cc(-c3cc(F)cc(C(F)(F)F)c3)ccc2-c2cc3c(cc21)C(=C(C#N)C#N)c1cc(-c2cc(F)cc(C(F)(F)F)c2)ccc1-3 ; N#C/N=c1/c2cc(-c3cc(F)cc(C(F)(F)F)c3)ccc2c2cc3c(cc12)/c(=N/C#N)c1cc(-c2cc(F)cc(C(F)(F)F)c2)ccc13 ; N#CC(C#N)=C1c2cc(-c3cc(F)c(F)c(C(F)(F)F)c3)ccc2-c2cc3c(cc21)C(=C(C#N)C#N)c1cc(-c2cc(F)c(F)c(C(F)(F)F)c2)ccc1-3 ; N#C/N=c1/c2cc(-c3cc(F)c(F)c(C(F)(F)F)c3)ccc2c2cc3c(cc12)/c(=N/C#N)c1cc(-c2cc(F)c(F)c(C(F)(F)F)c2)ccc13]

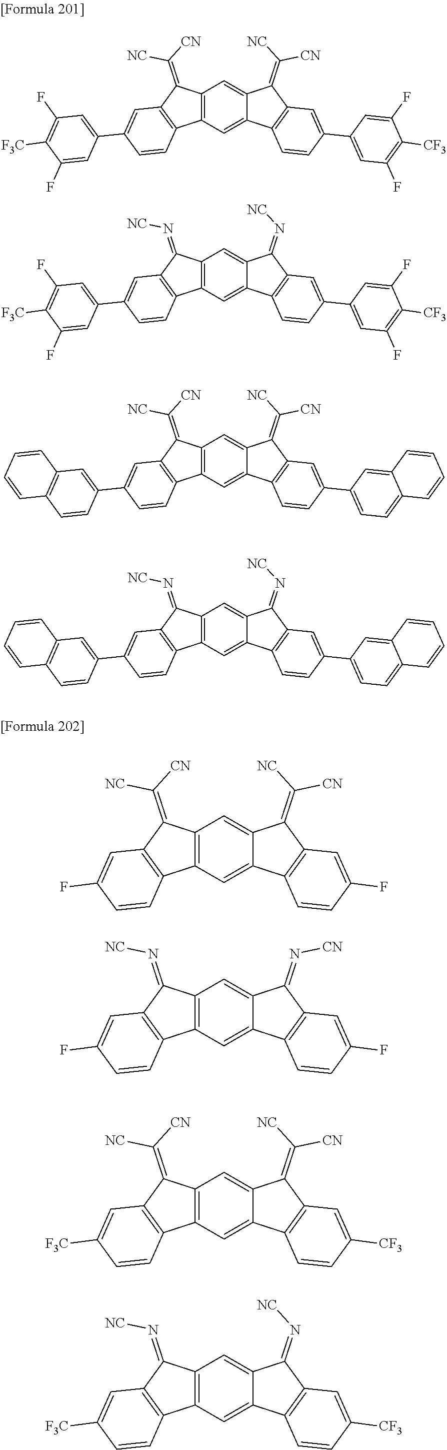

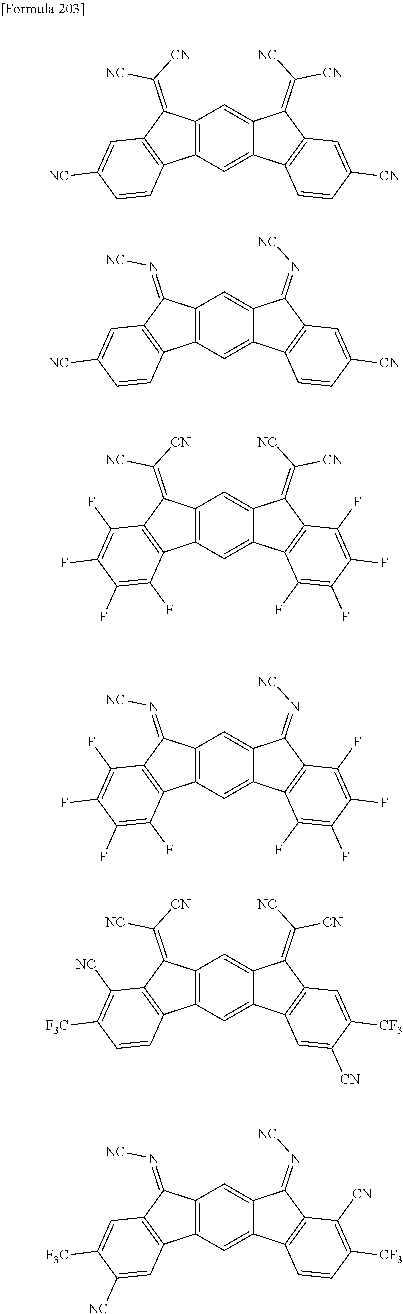 [SMILES: N#CC(C#N)=C1c2cc(C#N)ccc2-c2cc3c(cc21)C(=C(C#N)C#N)c1cc(C#N)ccc1-3 ; N#C/N=c1/c2cc(C#N)ccc2c2cc3c(cc12)/c(=N/C#N)c1cc(C#N)ccc13 ; N#CC(C#N)=C1c2cc3c(cc2-c2c(F)c(F)c(F)c(F)c21)-c1c(F)c(F)c(F)c(F)c1C3=C(C#N)C#N ; N#C/N=c1/c2cc3/c(=N\C#N)c4c(F)c(F)c(F)c(F)c4c3cc2c2c(F)c(F)c(F)c(F)c12 ; N#CC(C#N)=C1c2cc(C(F)(F)F)c(C#N)cc2-c2cc3c(cc21)C(=C(C#N)C#N)c1c-3ccc(C(F)(F)F)c1C#N ; N#C/N=c1\c2cc(C(F)(F)F)c(C#N)cc2c2cc3c(cc12)/c(=N\C#N)c1c(C#N)c(C(F)(F)F)ccc13]

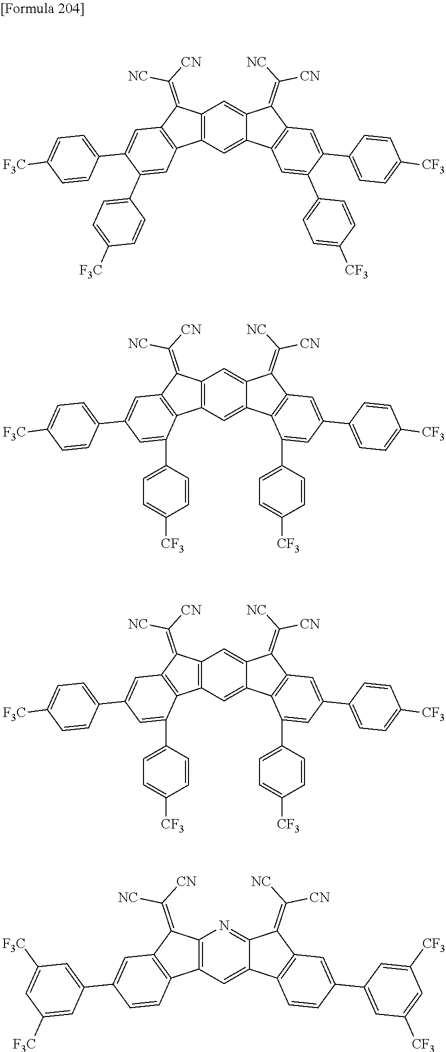

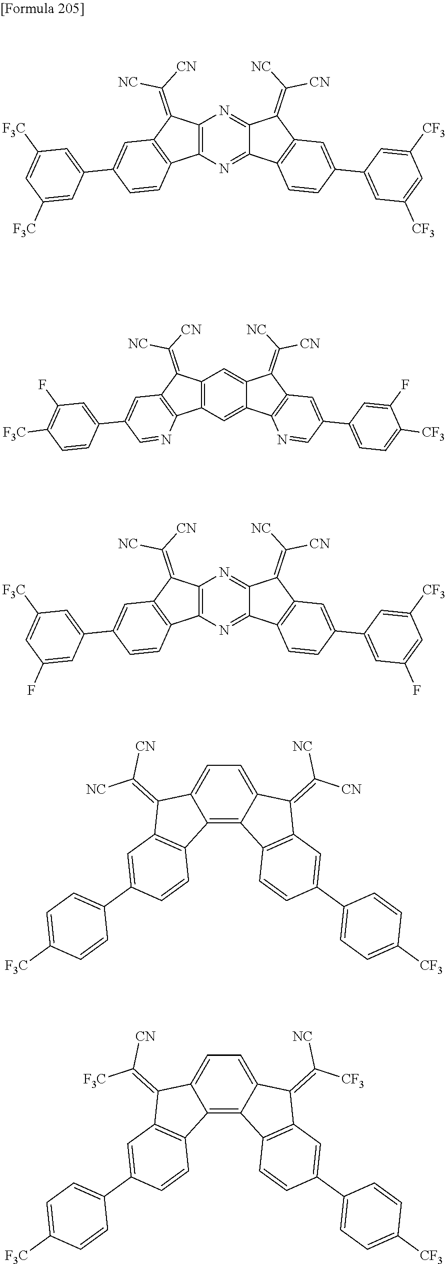

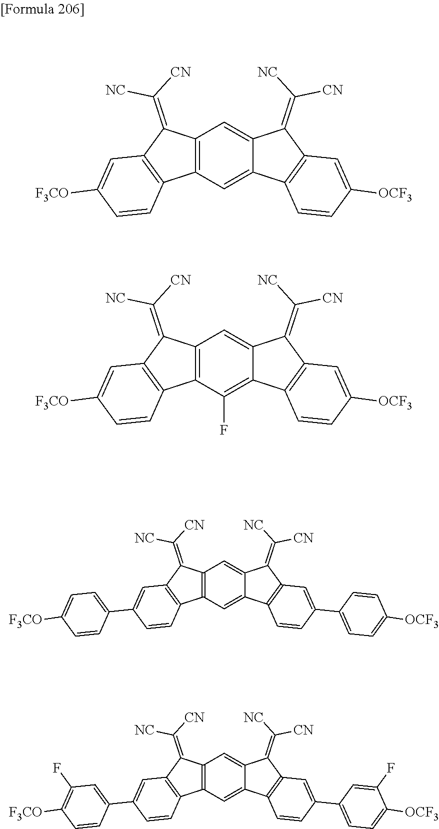 [SMILES: N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(OC(F)(F)F)ccc2-c2c1cc1c(c2F)-c2ccc(OC(F)(F)F)cc2C1=C(C#N)C#N ; N#CC(C#N)=C1c2cc(-c3ccc(OC(F)(F)F)cc3)ccc2-c2cc3c(cc21)C(=C(C#N)C#N)c1cc(-c2ccc(OC(F)(F)F)cc2)ccc1-3 ; N#CC(C#N)=C1c2cc(-c3ccc(OC(F)(F)F)c(F)c3)ccc2-c2cc3c(cc21)C(=C(C#N)C#N)c1cc(-c2ccc(OC(F)(F)F)c(F)c2)ccc1-3]

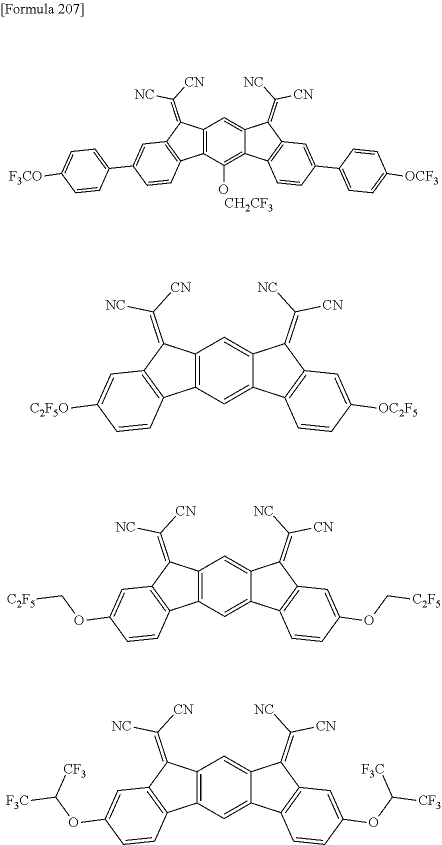

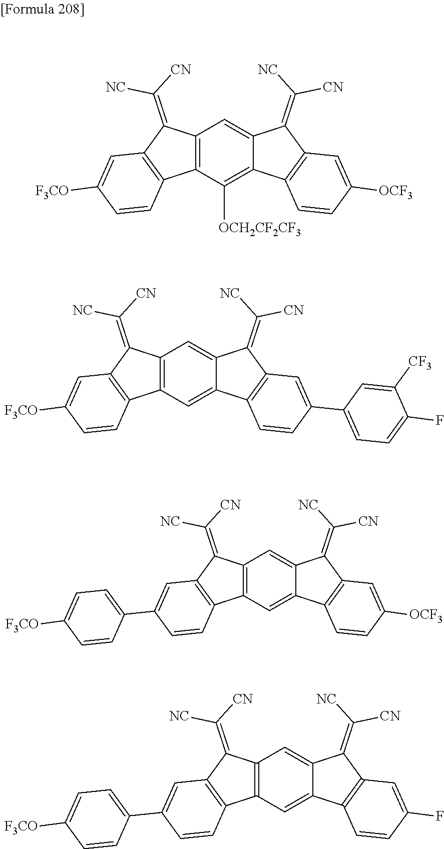

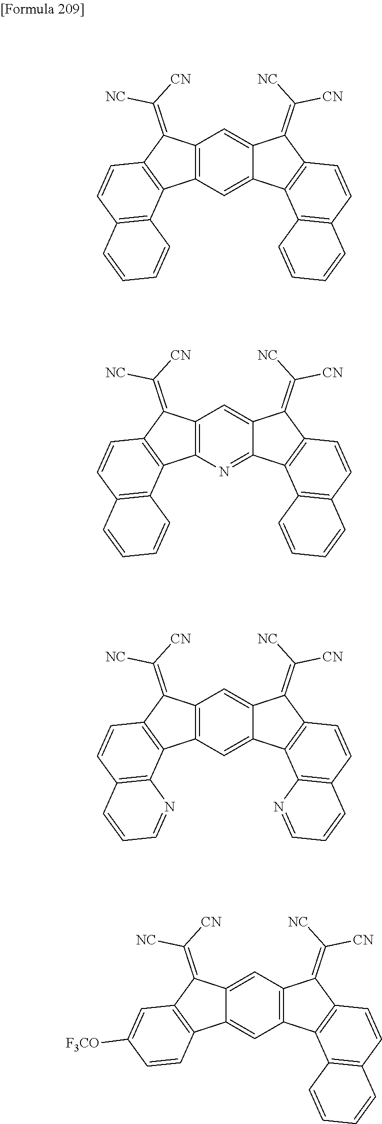 [SMILES: N#CC(C#N)=C1c2cc3c(cc2-c2c1ccc1ccccc21)-c1c(ccc2ccccc12)C3=C(C#N)C#N ; N#CC(C#N)=C1c2cc3c(nc2-c2c1ccc1ccccc21)-c1c(ccc2ccccc12)C3=C(C#N)C#N ; N#CC(C#N)=C1c2cc3c(cc2-c2c1ccc1cccnc21)-c1c(ccc2cccnc12)C3=C(C#N)C#N ; N#CC(C#N)=C1c2cc(OC(F)(F)F)ccc2-c2cc3c(cc21)C(=C(C#N)C#N)c1ccc2ccccc2c1-3]

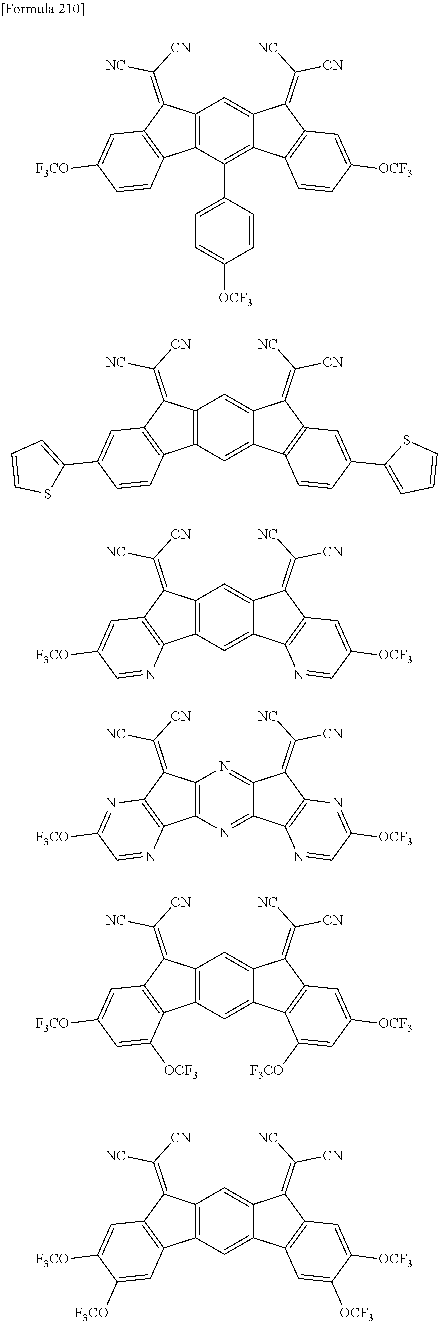

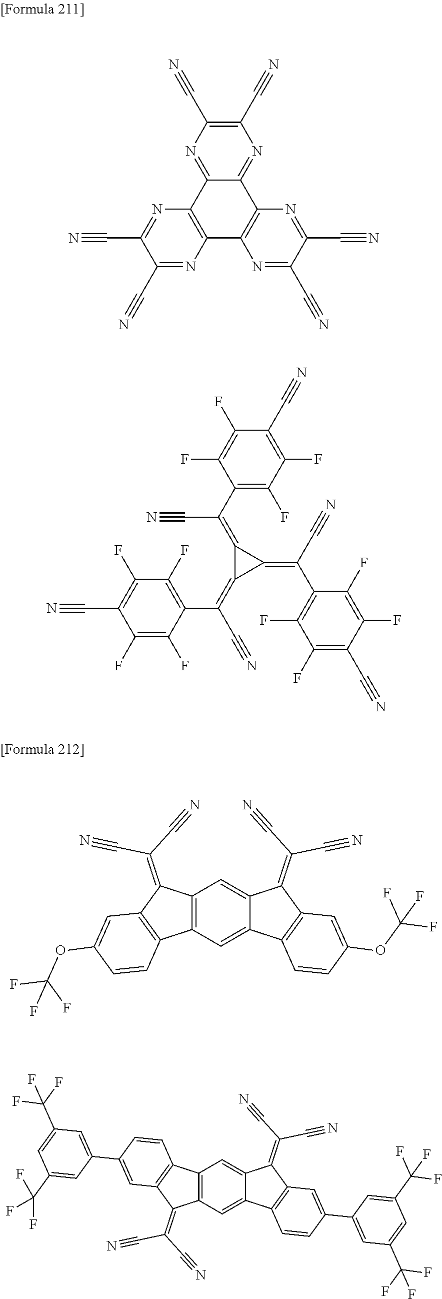 [SMILES: N#Cc1nc2c3nc(C#N)c(C#N)nc3c3nc(C#N)c(C#N)nc3c2nc1C#N ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

### Emitting Zone

The emitting zone is disposed between the hole transporting zone and an electron transporting zone. The emitting zone includes at least one emitting layer.

In an exemplary arrangement of the organic EL device according to the exemplary embodiment, the emitting zone includes an emitting layer containing a host material and a luminescent compound that emits light having the maximum peak wavelength of 500 nm or less.

In an exemplary arrangement of the organic EL device according to the exemplary embodiment, the luminescent compound has a full width at half maximum in a range from 1 nm to 30 nm at the maximum peak.

In an exemplary arrangement of the organic EL device according to the exemplary embodiment, the emitting zone includes two or more emitting layers and at least two of the emitting layers are layered.

### First Emitting Layer

In an exemplary arrangement of the organic EL device according to the exemplary embodiment, the emitting zone includes a first emitting layer as the at least one emitting layer.

In an exemplary arrangement of the organic EL device according to the exemplary embodiment, the first emitting layer contains a first host material. The first host material, which is not particularly limited, may be, for instance, a compound represented by a formula (H1) described later.

In an exemplary arrangement of the organic EL device according to the exemplary embodiment, the first emitting layer contains a first luminescent compound. The first luminescent compound is not particularly limited.

In an exemplary arrangement of the organic EL device according to the exemplary embodiment, the first emitting layer contains the first host material and the first luminescent compound.

The first luminescent compound preferably emits light having the maximum peak wavelength of 500 nm or less, more preferably emits light having the maximum peak wavelength in a range from 430 nm to 480 nm. The first luminescent compound is preferably a fluorescent compound that emits fluorescence having the maximum peak wavelength of 500 nm or less, and more preferably a fluorescent compound that emits fluorescence having the maximum peak wavelength in a range from 430 nm to 480 nm.

In an exemplary arrangement of the organic EL device according to the exemplary embodiment, the first emitting layer contains the first host material and the first luminescent compound that emits light having the maximum peak wavelength of 500 nm or less.

In an exemplary arrangement of the organic EL device according to the exemplary embodiment, the first luminescent compound has a full width at half maximum in a range from 1 nm to 30 nm at the maximum peak.

In an exemplary arrangement of the organic EL device according to the exemplary embodiment, the first luminescent compound is a compound containing no azine ring structure in a molecule.

In an exemplary arrangement of the organic EL device according to the exemplary embodiment, the first luminescent compound is preferably not a boron-containing complex, and more preferably not a complex.

Examples of a fluorescent compound that emits blue fluorescence and is usable in the first emitting layer include a pyrene derivative, styrylamine derivative, chrysene derivative, fluoranthene derivative, fluorene derivative, diamine derivative, and triarylamine derivative.

Herein, the blue light emission refers to light emission in which the maximum peak wavelength of emission spectrum is in a range from 430 nm to 500 nm.

In an exemplary arrangement of the organic EL device according to the exemplary embodiment, the emitting zone includes two or more emitting layers.

In an exemplary arrangement of the organic EL device according to the exemplary embodiment, in a case where the emitting zone includes two or more emitting layers, the two or more emitting layers are each a fluorescent emitting layer.

In other words, in an exemplary arrangement of the organic EL device according to the exemplary embodiment, the emitting layers included in the emitting zone are each a fluorescent emitting layer.

In an exemplary arrangement of the organic EL device according to the exemplary embodiment, the first emitting layer does not contain a metal complex. Moreover, in an exemplary arrangement of the organic EL device according to the exemplary embodiment, the first emitting layer does not contain a boron-containing complex.

In an exemplary arrangement of the organic EL device according to the exemplary embodiment, the first emitting layer does not contain a phosphorescent material (dopant material).

In an exemplary arrangement of the organic EL device according to the exemplary embodiment, the first emitting layer does not contain a heavy metal complex and a phosphorescent rare-earth metal complex. Here, examples of the heavy-metal complex include an iridium complex, osmium complex, and platinum complex.

A measurement method of the maximum peak wavelength of a compound is as follows. A toluene solution of a measurement target compound at a concentration of 5 μmol/L is prepared and put in a quartz cell. An emission spectrum (ordinate axis: luminous intensity, abscissa axis: wavelength) of each of the samples is measured at a normal temperature (300K). The emission spectrum can be measured using a spectrophotometer (machine name: F-7000) produced by Hitachi High-Tech Science Corporation. It should be noted that the apparatus for measuring the emission spectrum is not limited to the apparatus used herein.

A peak wavelength of the emission spectrum exhibiting the maximum luminous intensity is defined as the maximum peak wavelength. Herein, the maximum peak wavelength of fluorescence is occasionally referred to as a maximum fluorescence peak wavelength (FL-peak).

In an emission spectrum of the first luminescent compound, where a peak exhibiting a maximum luminous intensity is defined as a maximum peak and a height of the maximum peak is defined as 1, heights of other peaks appearing in the emission spectrum are preferably less than 0.6. It should be noted that the peaks in the emission spectrum are defined as local maximum values.

Moreover, in the emission spectrum of the first luminescent compound, the number of peaks is preferably less than three.

In an exemplary arrangement of the organic EL device according to the exemplary embodiment, the first emitting layer contains 0.5 mass % or more of the first luminescent compound with respect to the total mass of the first emitting layer.

The first emitting layer contains the first luminescent compound preferably at 10 mass % or less, more preferably at 7 mass % or less, and still more preferably at 5 mass % less with respect to the total mass of the first emitting layer.

Herein, the “host material” refers to, for instance, a material that accounts for “50 mass % or more of the layer”.

In an exemplary arrangement of the organic EL device according to the exemplary embodiment, the first emitting layer preferably contains the first host material at 60 mass % or more, more preferably at 70 mass % or more, still more preferably at 80 mass % or more, still further more preferably at 90 mass % or more, and yet still further more preferably at 95 mass % or more, with respect to the total mass of the first emitting layer.

The first emitting layer preferably contains the first host material at 99.5 mass % or less with respect to the total mass of the first emitting layer.

When the first emitting layer contains the first host material and the first luminescent compound, the upper limit of a total of the content ratios of the first host material and the first luminescent compound is 100 mass %.

In the organic EL device according to the exemplary embodiment, the first emitting layer may further contain any other material than the first host material and the first luminescent compound.

The first emitting layer may contain a single type of the first host material or may contain two or more types of the first host material. The first emitting layer may contain a single type of the first luminescent compound or may contain two or more types of the first luminescent compound.

### First Host Material

In an exemplary arrangement of the organic EL device according to the exemplary embodiment, the first host material has at least one deuterium atom.

In an exemplary arrangement of the organic EL device according to the exemplary embodiment, the first host material has no deuterium atom.

### Compound Represented by Formula (H1)

In an exemplary arrangement of the organic EL device according to the exemplary embodiment, the first host material is a compound represented by a formula (H1) below.

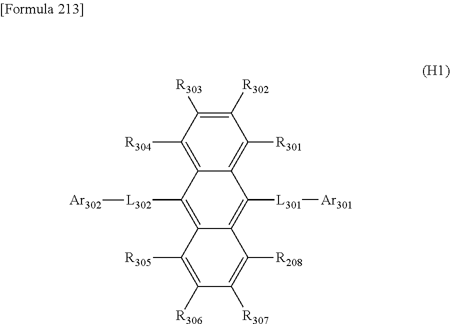

In the formula (H1):
R³⁰¹ to R³⁰⁸ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, or a substituted or unsubstituted heterocyclic group having 5 to 50 ring atoms,
L₃₀₁ and L₃₀₂ are each independently a single bond, a substituted or unsubstituted arylene group having 6 to 50 ring carbon atoms, or a substituted or unsubstituted divalent heterocyclic group having 5 to 50 ring atoms; and
Ar₃₀₁ and Ar₃₀₂ are each independently a substituted or unsubstituted aryl group having 6 to 50 ring carbon atoms, or a substituted or unsubstituted heterocyclic group having 5 to 50 ring atoms.

In the compound represented by the formula (H1), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the exemplary embodiment, Ar₃₀₁ and Ar₃₀₂ are each independently a phenyl group, naphthyl group, phenanthryl group, biphenyl group, terphenyl group, diphenylfluorenyl group, dimethylfluorenyl group, benzodiphenylfluorenyl group, benzodimethylfluorenyl group, dibenzofuranyl group, dibenzothienyl group, naphthobenzofuranyl group, or naphthobenzothienyl group.

In an exemplary arrangement of the organic EL device according to the exemplary embodiments, L₃₀₁ is a single bond or an unsubstituted arylene group having 6 to 22 ring carbon atoms; and Ar₃₀₁ is a substituted or unsubstituted aryl group having 6 to 22 ring carbon atoms.

In an exemplary arrangement of the organic EL device according to the exemplary embodiment, R₃₀₁ to R₃₀₈ are each independently a hydrogen atom, a substituted or unsubstituted alkyl group having 1 to 50 carbon atoms, a substituted or unsubstituted cycloalkyl group having 3 to 50 ring carbon atoms, or a group represented by —Si(R₉₀₁)(R₉₀₂)(R₉₀₃).

In an exemplary arrangement of the organic EL device according to the exemplary embodiment, R₃₀₁ to R₃₀₈ are each a hydrogen atom.

In an exemplary arrangement of the organic EL device according to the exemplary embodiment, L₃₀₂ is a single bond and Ar₃₀₂ is an unsubstituted phenyl group.

In an exemplary arrangement of the organic EL device according to the exemplary embodiment, L₃₀₂ is a single bond and Ar₃₀₂ is an unsubstituted 2-naphthyl group.

In an exemplary arrangement of the organic EL device according to the exemplary embodiment, L₃₀₂ is a single bond and Ar₃₀₂ is an unsubstituted 1-naphthyl group.

In an exemplary arrangement of the organic EL device according to the exemplary embodiment, L₃₀₂ is an unsubstituted p-phenylene group and Ar₃₀₂ is an unsubstituted phenyl group.

In an exemplary arrangement of the organic EL device according to the exemplary embodiment, L₃₀₂ is an unsubstituted m-phenylene group and Ar₃₀₂ is an unsubstituted phenyl group.

In an exemplary arrangement of the organic EL device according to the exemplary embodiment, L₃₀₂ is an unsubstituted o-phenylene group and Ar₃₀₂ is an unsubstituted phenyl group.

In an exemplary arrangement of the organic EL device according to the exemplary embodiment, L₃₀₂ is an unsubstituted p-phenylene group and Ar₃₀₂ is an unsubstituted 1-naphthyl group.

In an exemplary arrangement of the organic EL device according to the exemplary embodiment, L₃₀₂ is an unsubstituted p-phenylene group and Ar₃₀₂ is an unsubstituted 2-naphthyl group.

In an exemplary arrangement of the organic EL device according to the exemplary embodiment, L₃₀₂ is an unsubstituted 1,4-naphthalenediyl group and Ar₃₀₂ is an unsubstituted phenyl group.

In an exemplary arrangement of the organic EL device according to the exemplary embodiment, L₃₀₂ is an unsubstituted m-phenylene group and Ar₃₀₂ is an unsubstituted 2-naphthyl group.

In the first host material, the groups specified to be “substituted or unsubstituted” are each preferably an “unsubstituted” group.

### Production Method of First Host Material

The first host material is producible by a known method. The first host material is also producible based on a known method through a known alternative reaction using a known material(s) tailored for the target compound.

### Specific Examples of First Host Material

Specific examples of the first host material include the following compounds. It should however be noted that the invention is not limited to the specific examples of the first host material.

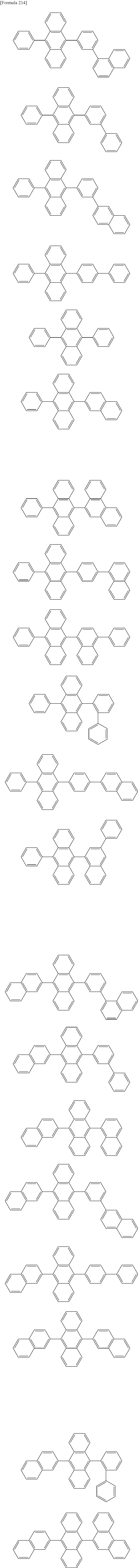

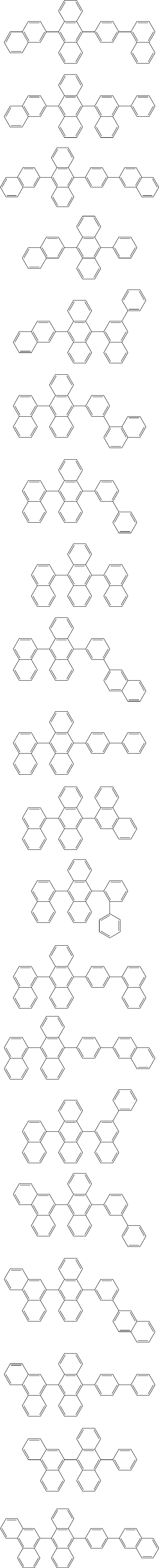

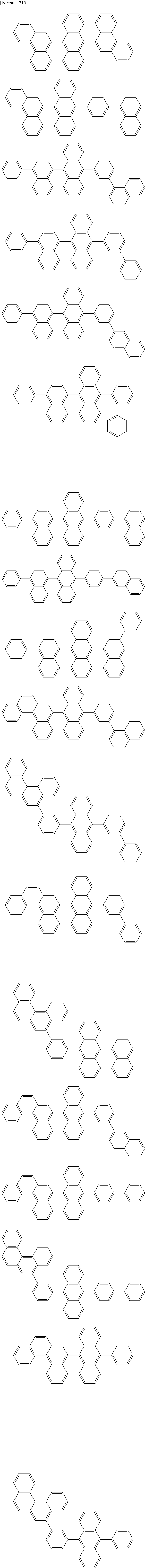

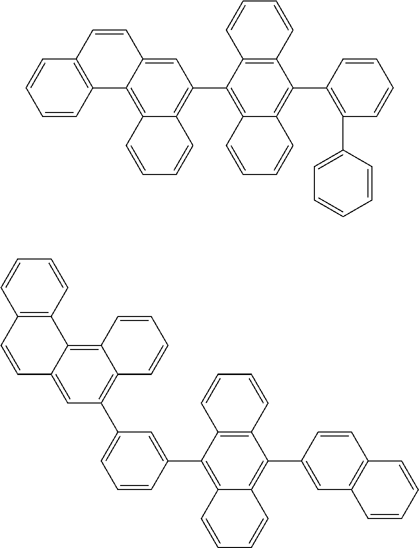

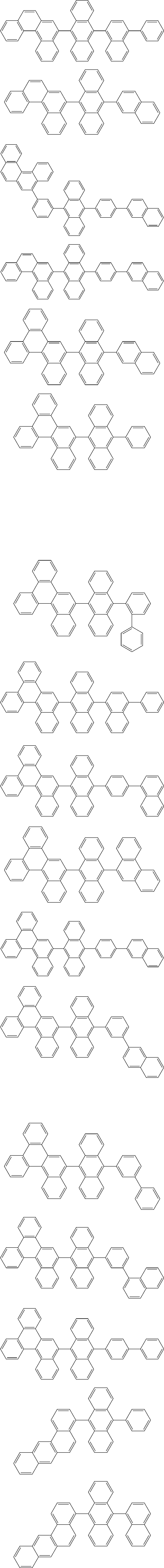

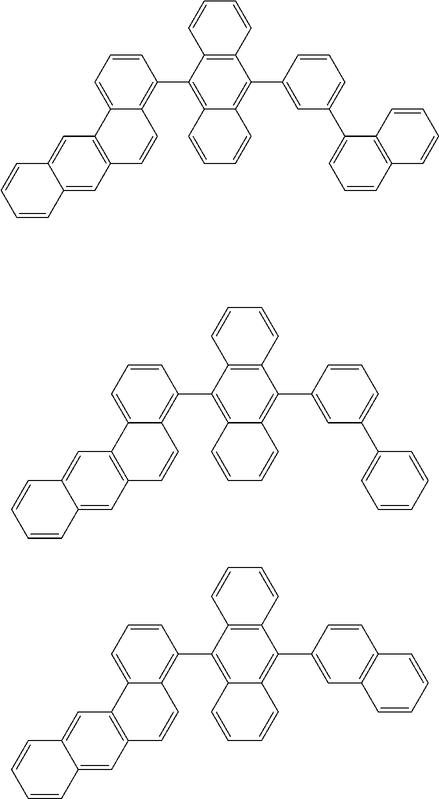

[chemical structure]

[chemical structure]

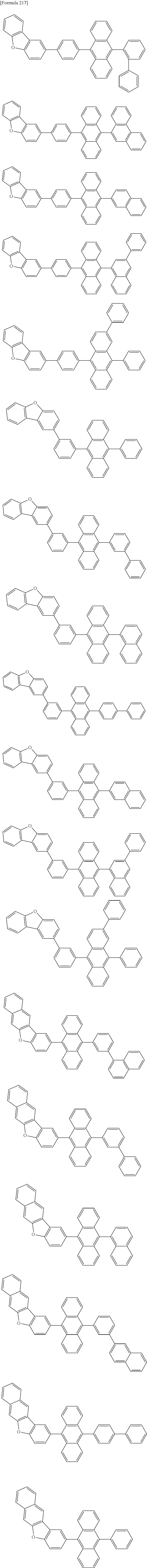

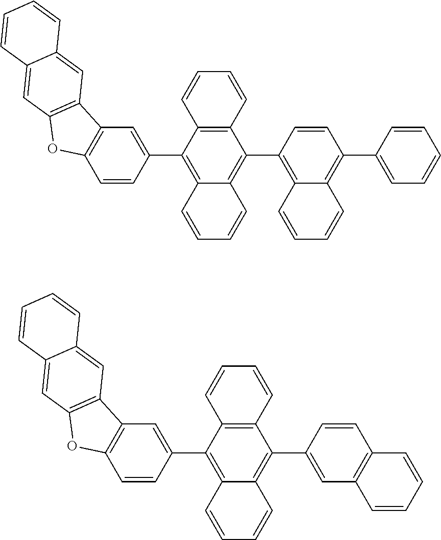 [SMILES: c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1]

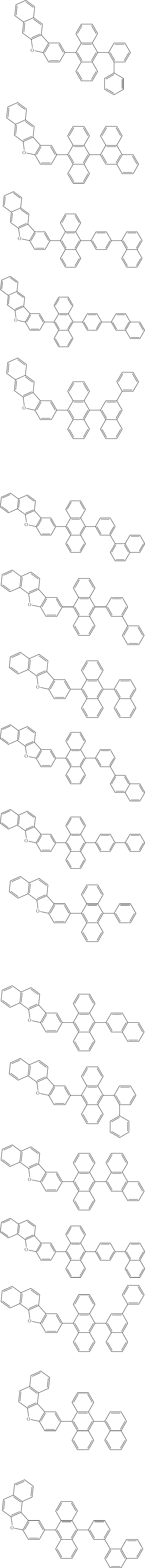

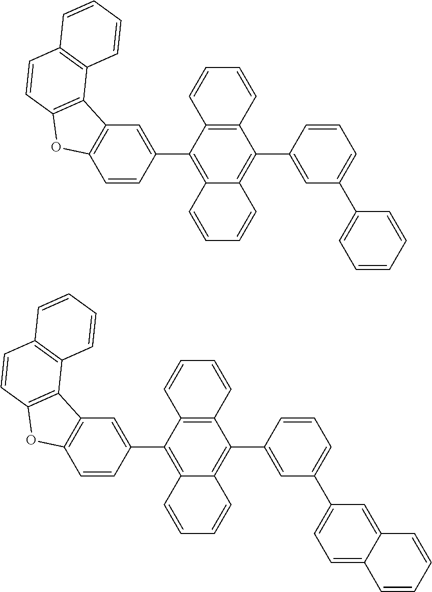 [SMILES: c1ccc(-c2cccc(-c3c4ccccc4c(-c4ccc5oc6ccc7ccccc7c6c5c4)c4ccccc34)c2)cc1 ; c1cc(-c2ccc3ccccc3c2)cc(-c2c3ccccc3c(-c3ccc4oc5ccc6ccccc6c5c4c3)c3ccccc23)c1]

[chemical structure]

[chemical structure]

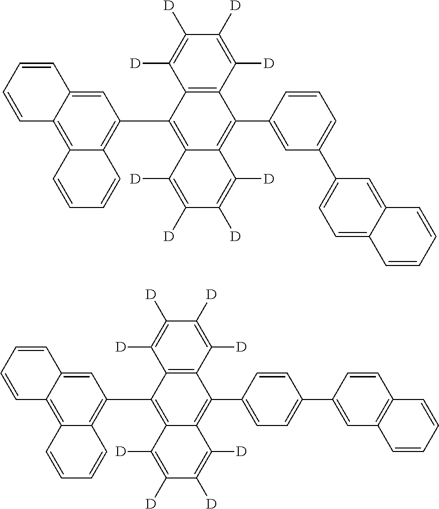 [SMILES: [2H]c1c([2H])c([2H])c2c(-c3cc4ccccc4c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cc4ccccc4c4ccccc34)c3c([2H])c([2H])c([2H])c([2H])c3c(-c3ccc(-c4ccc5ccccc5c4)cc3)c2c1[2H]]

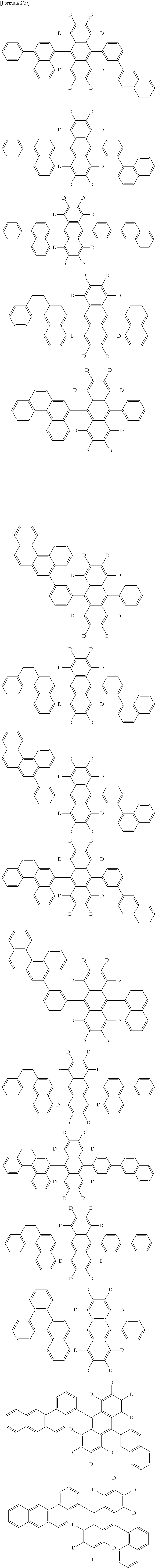

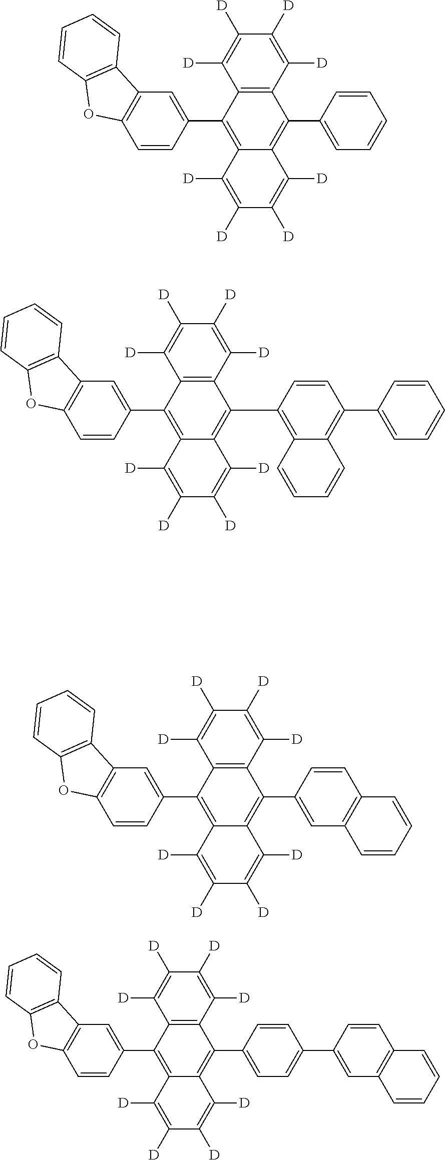

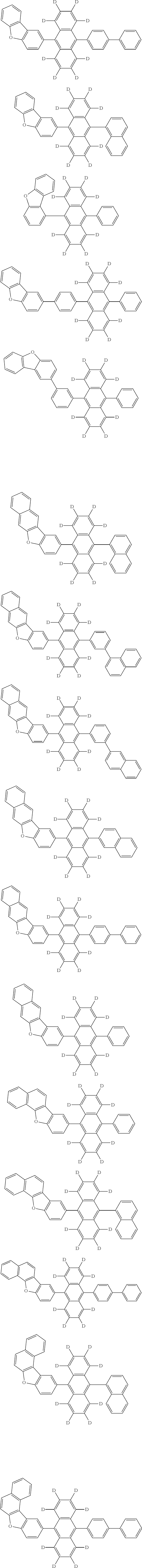

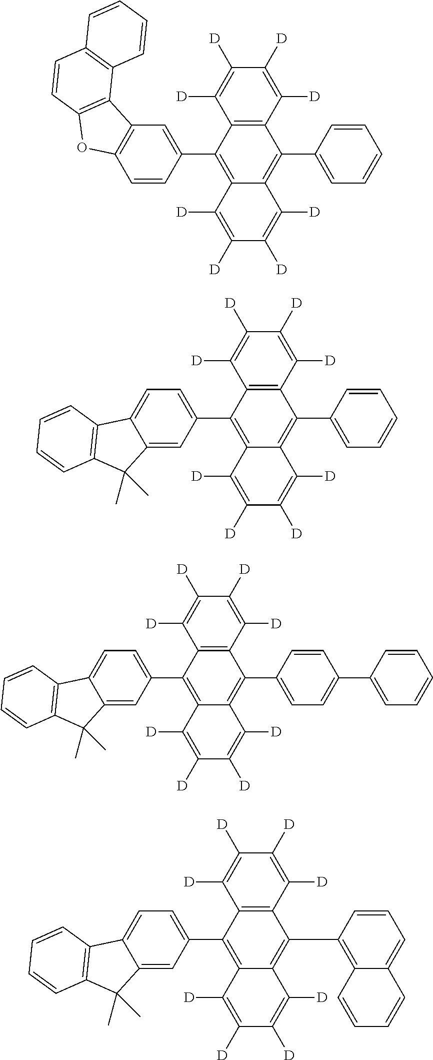

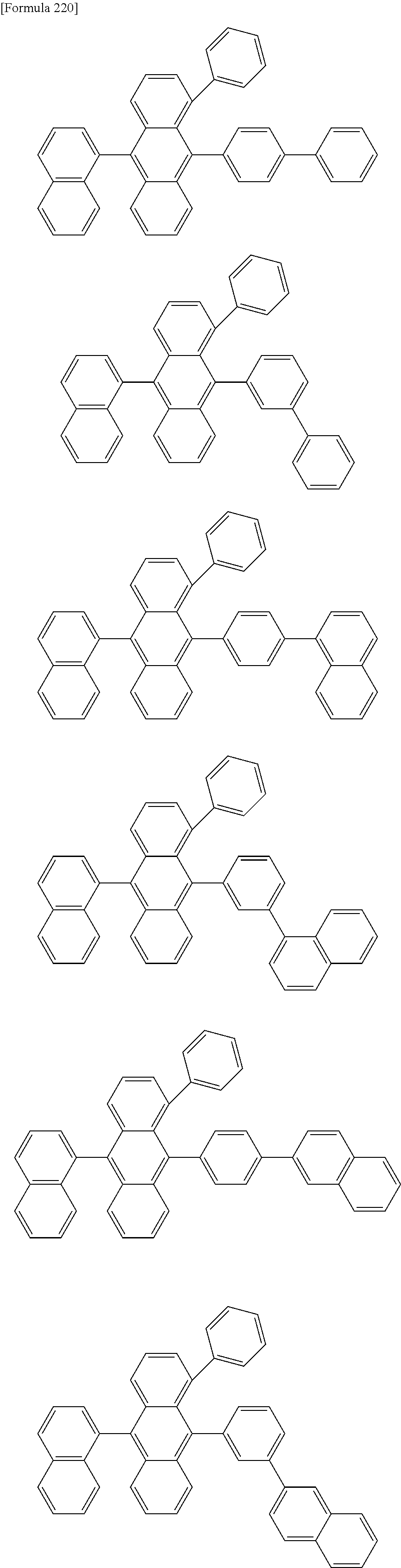

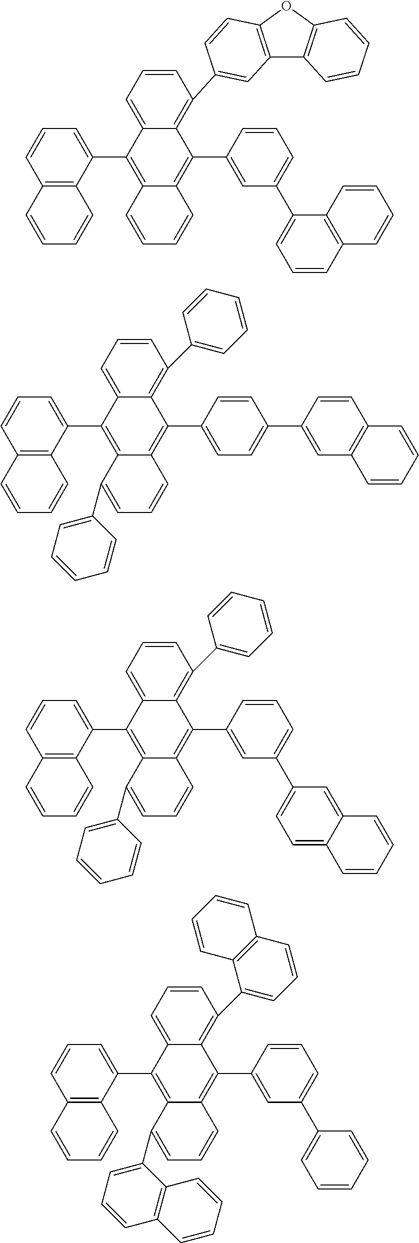

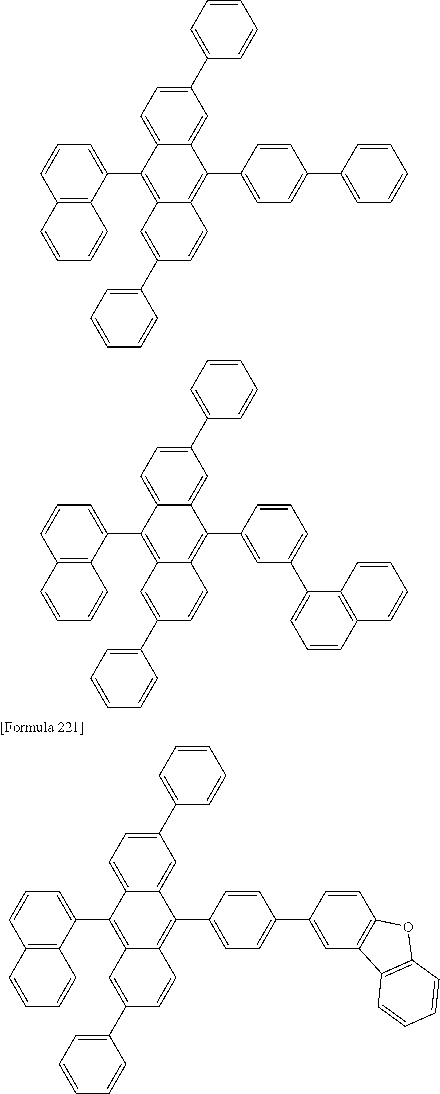

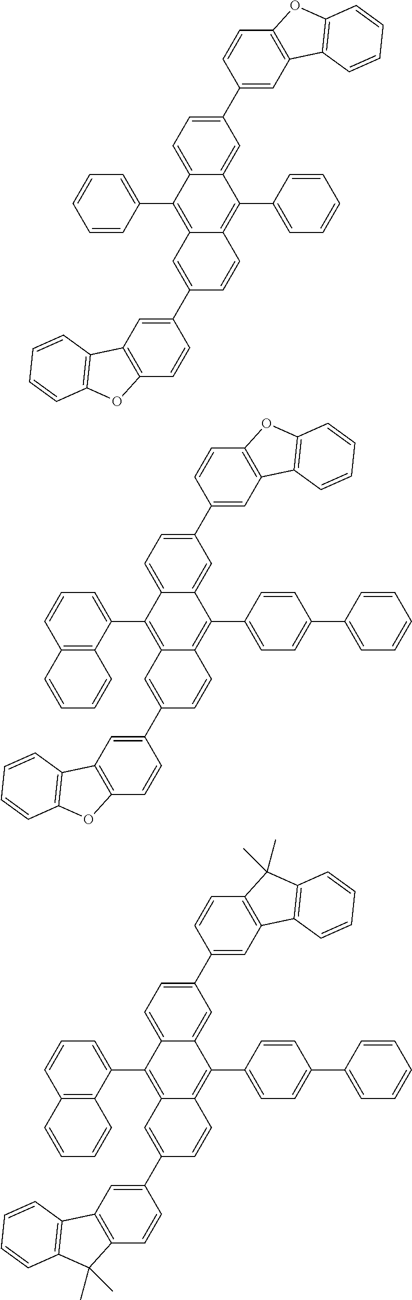

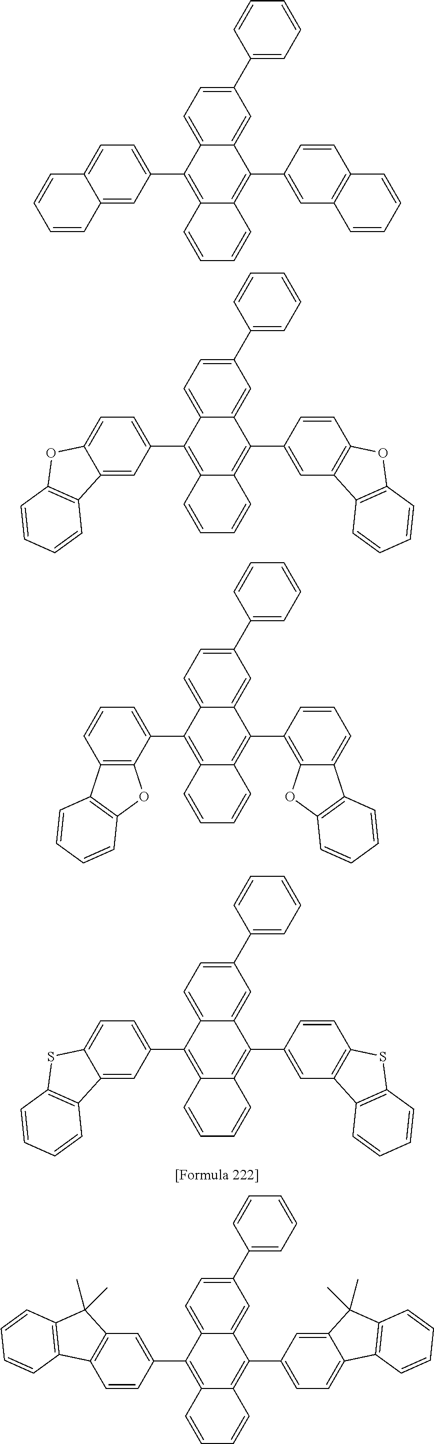

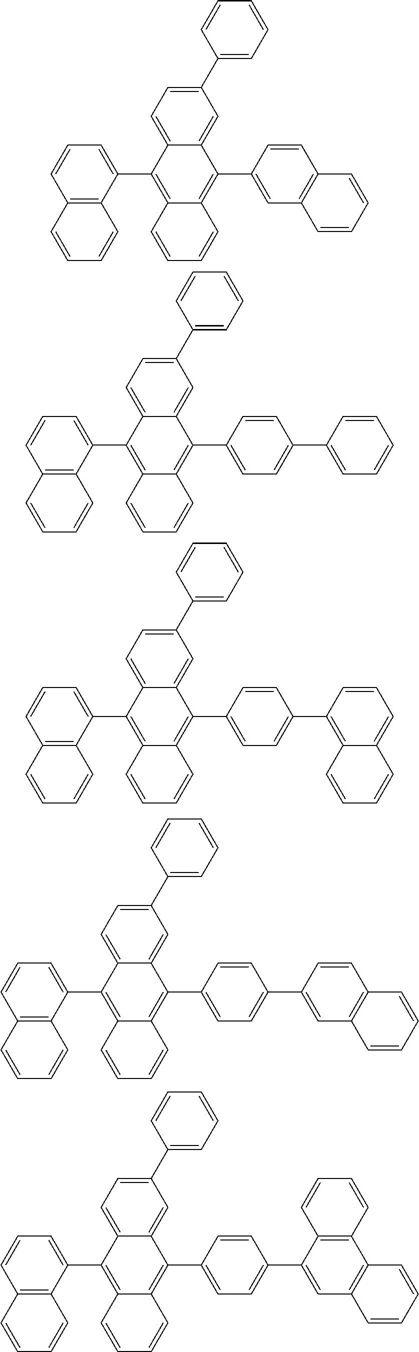

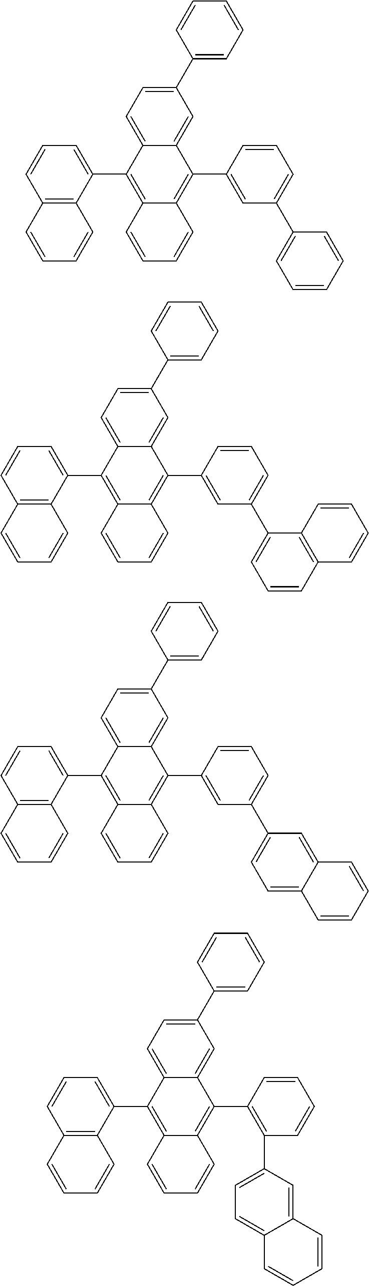

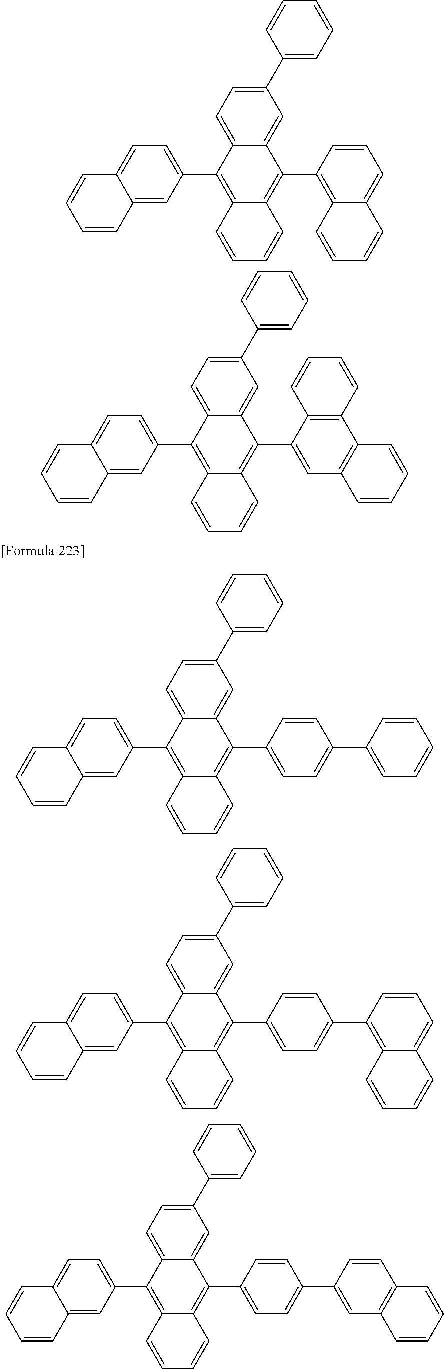

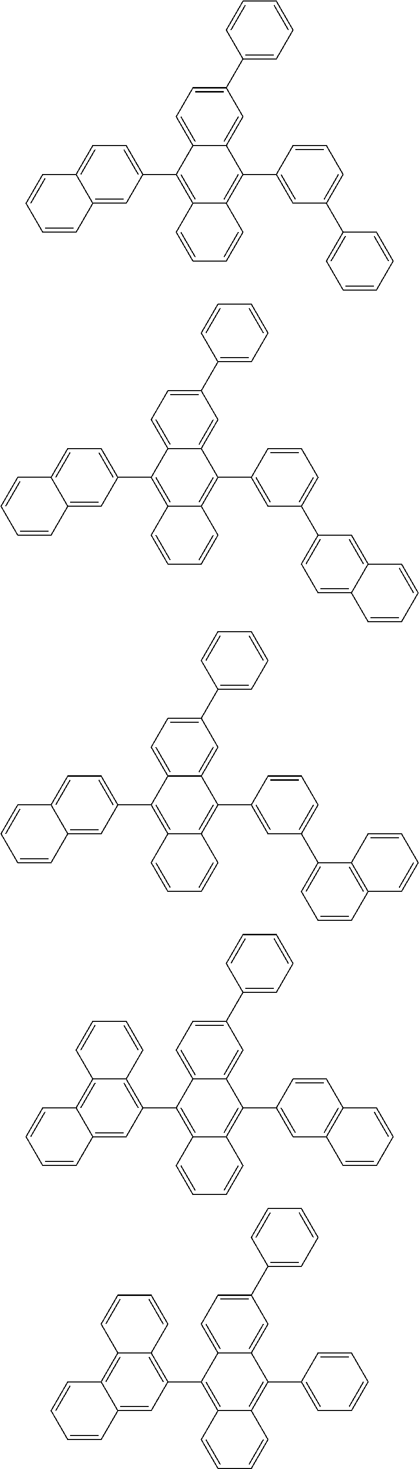

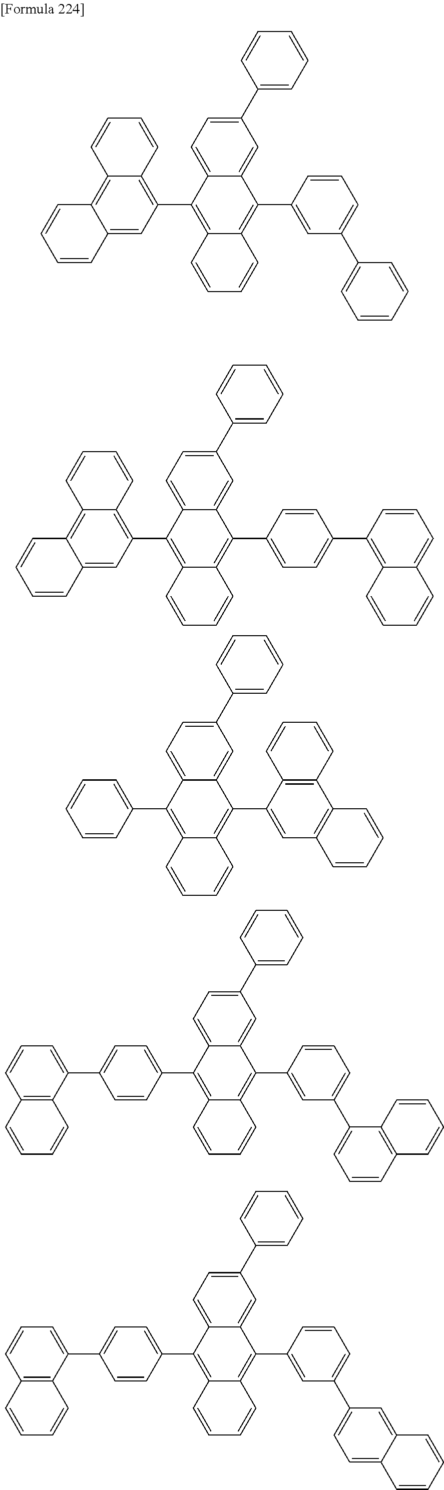

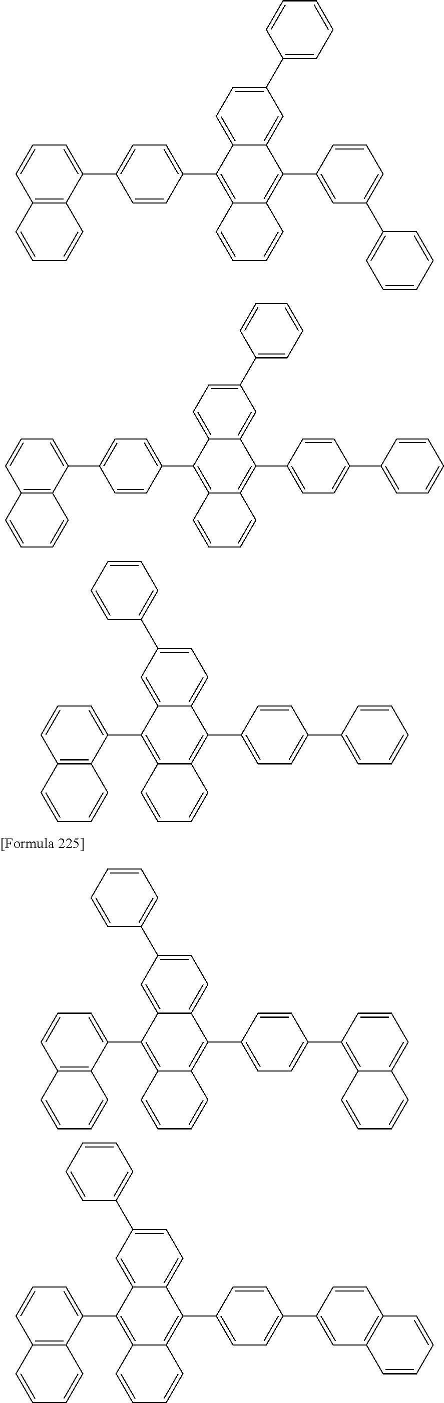

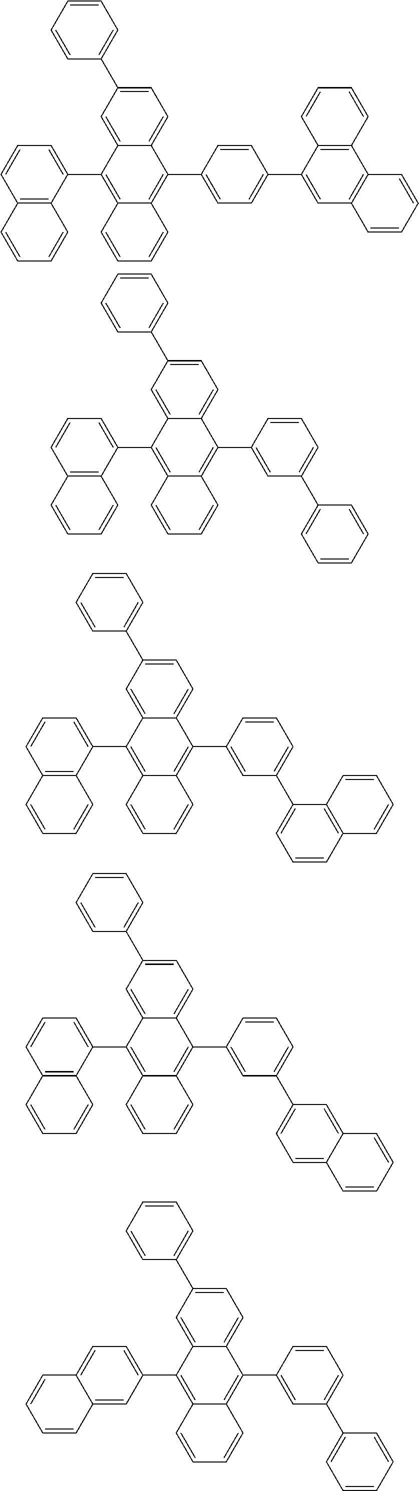

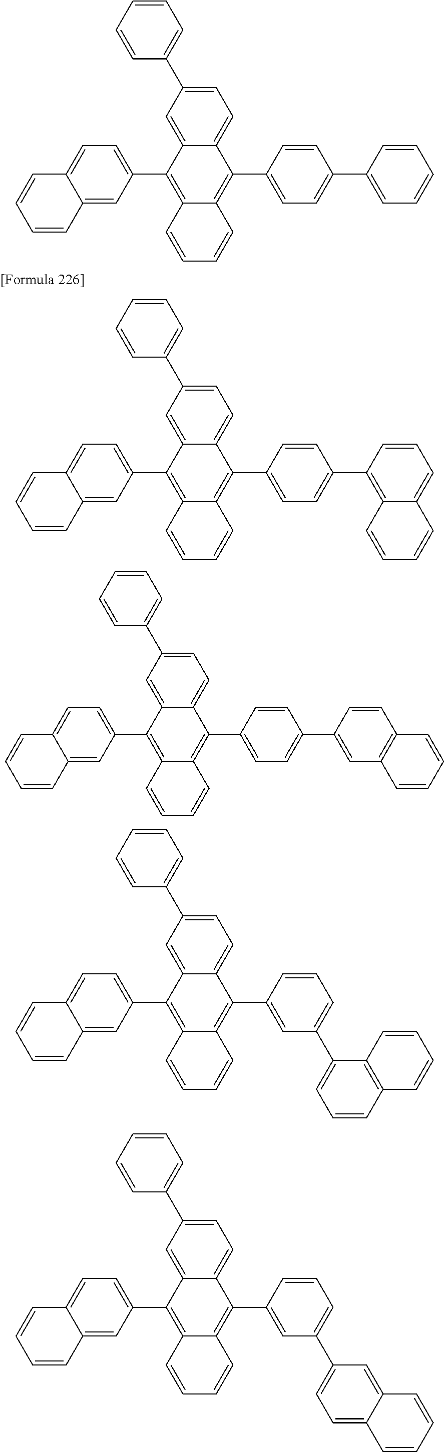

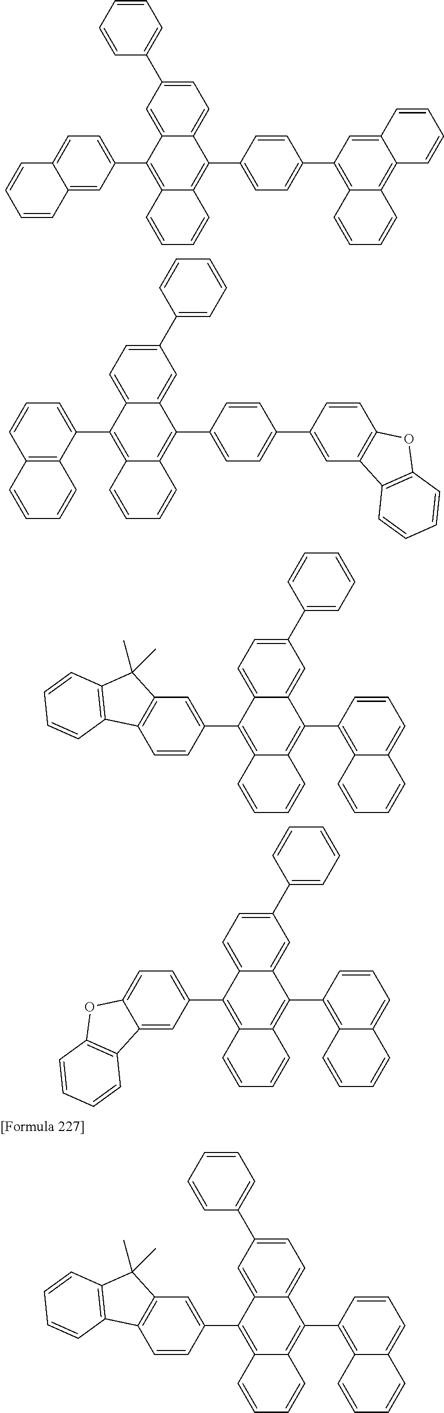

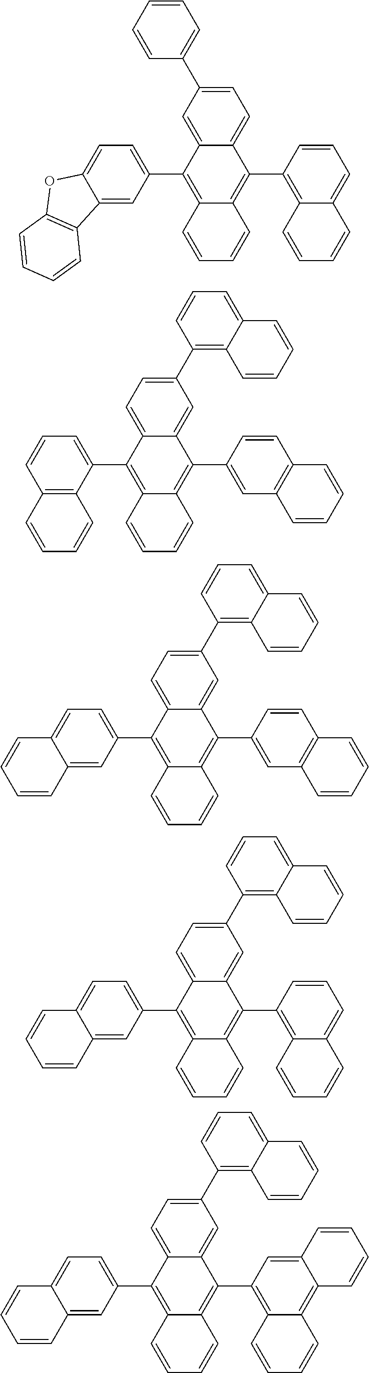

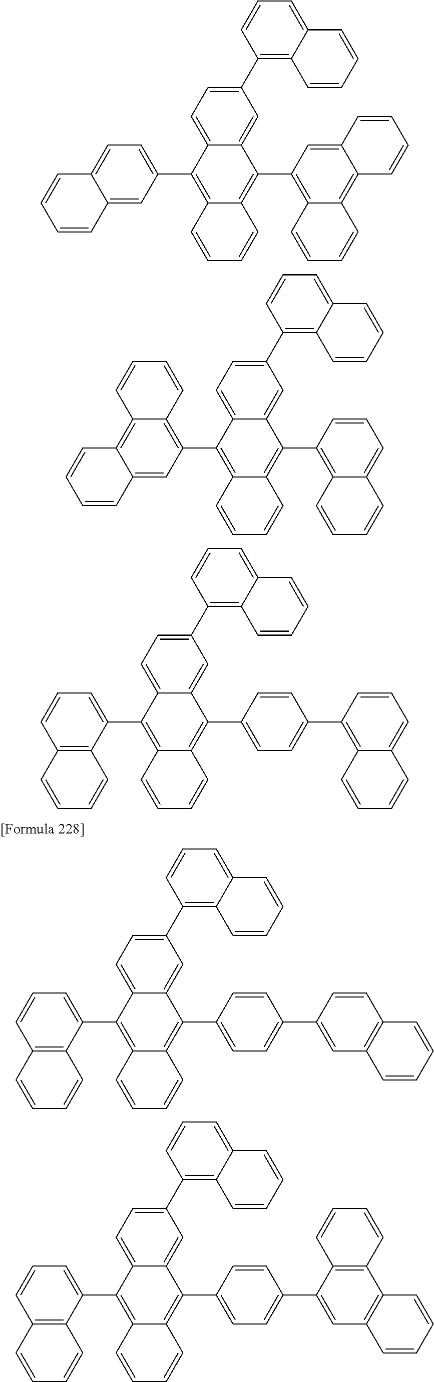

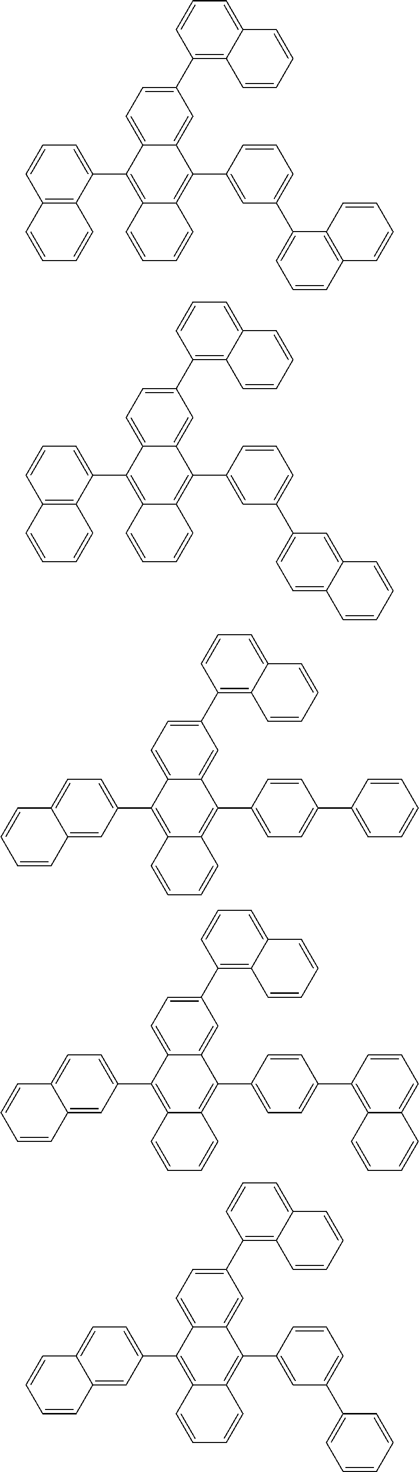

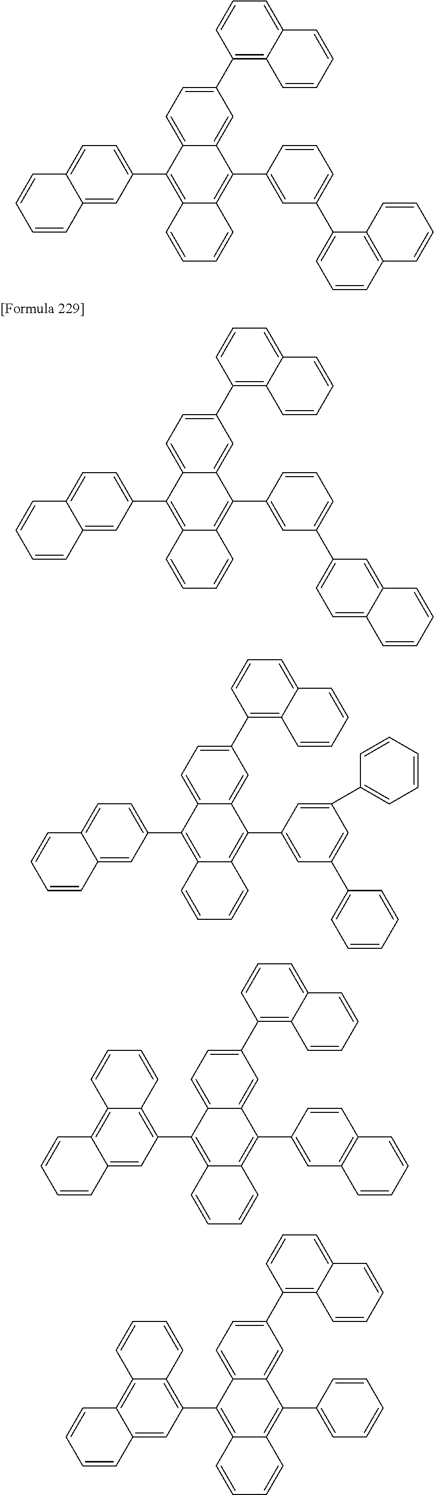

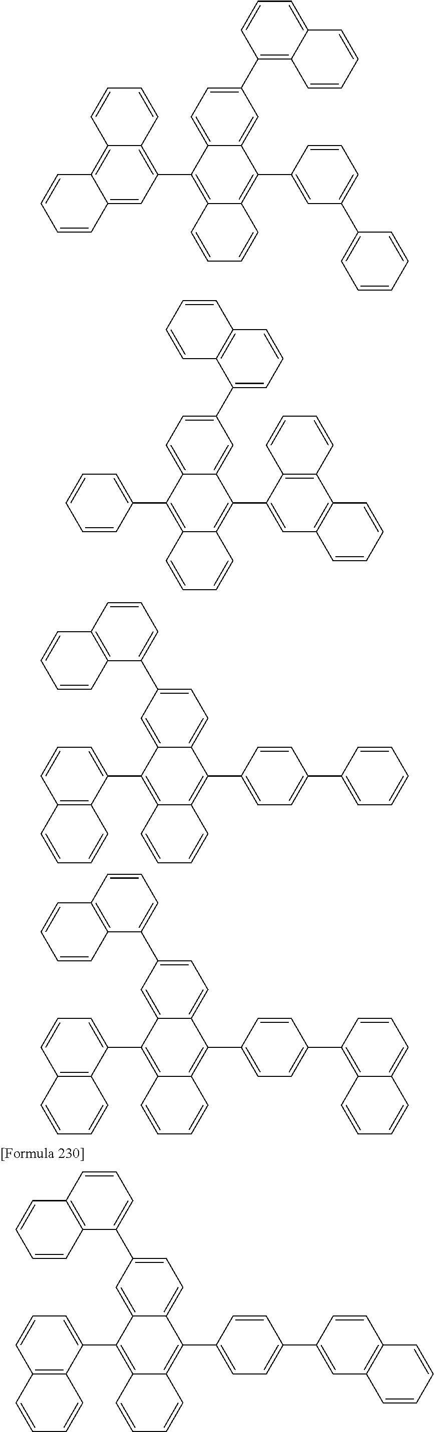

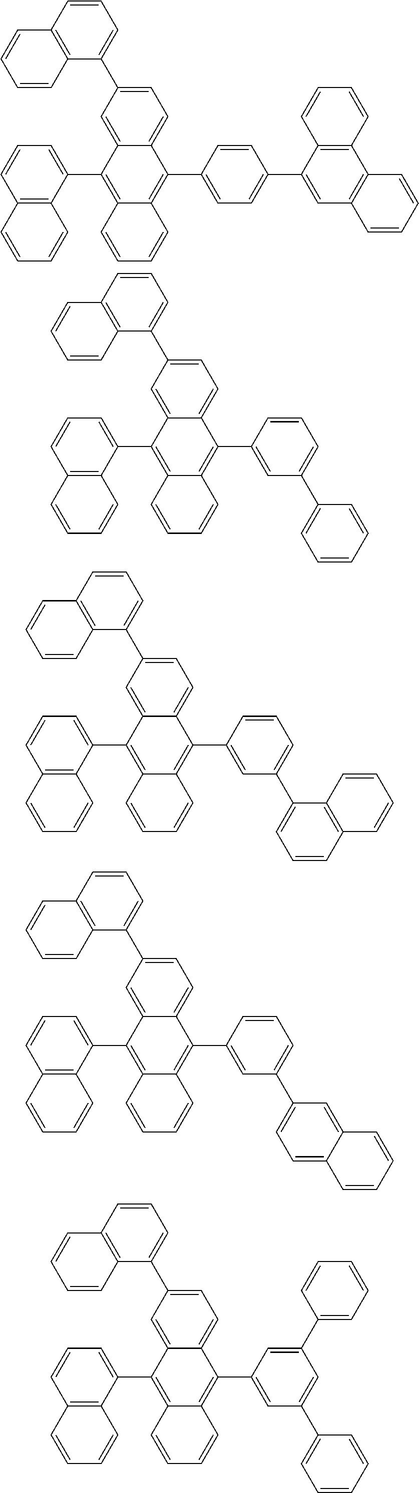

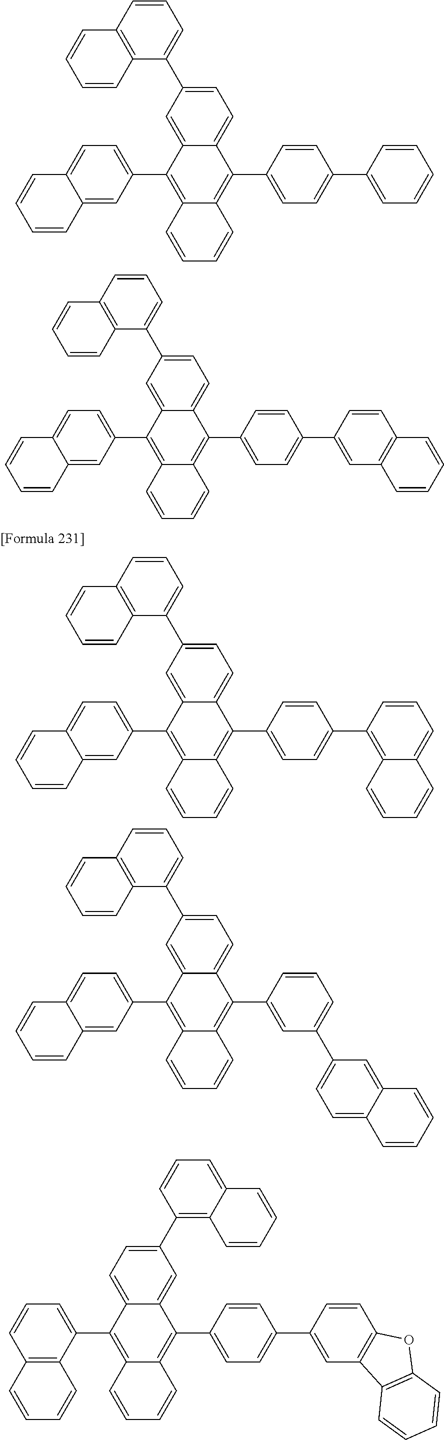

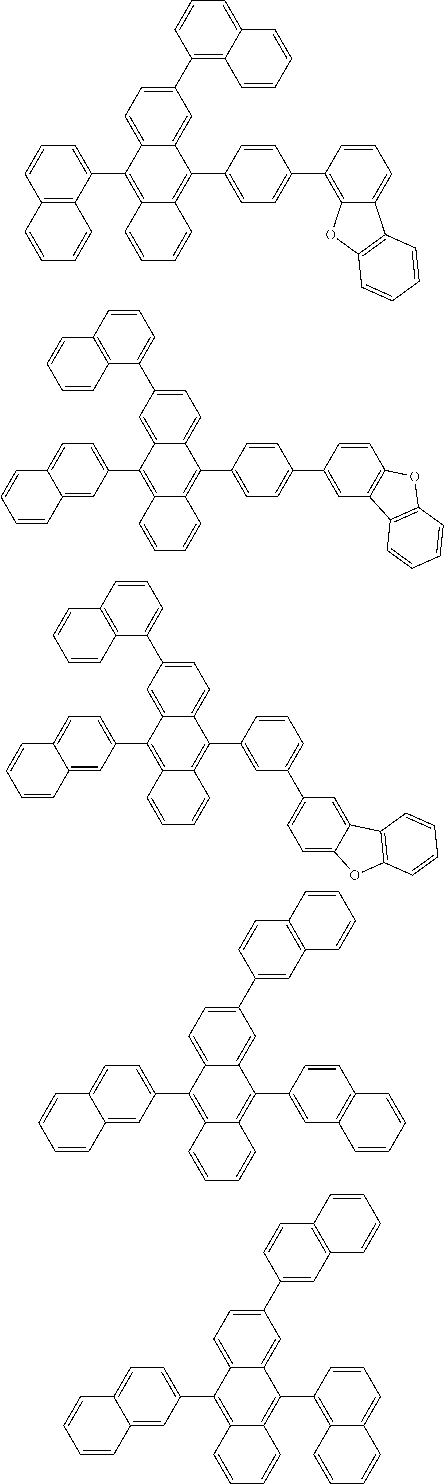

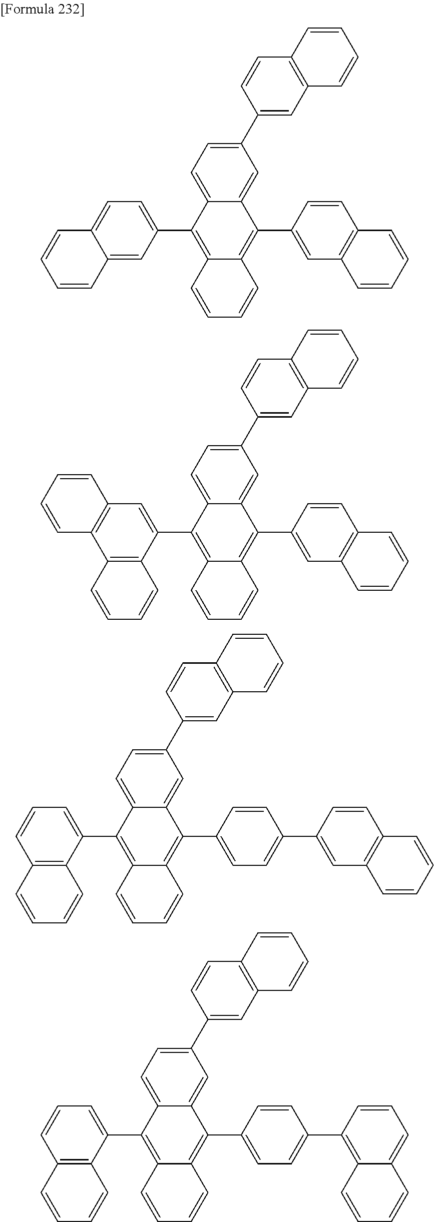

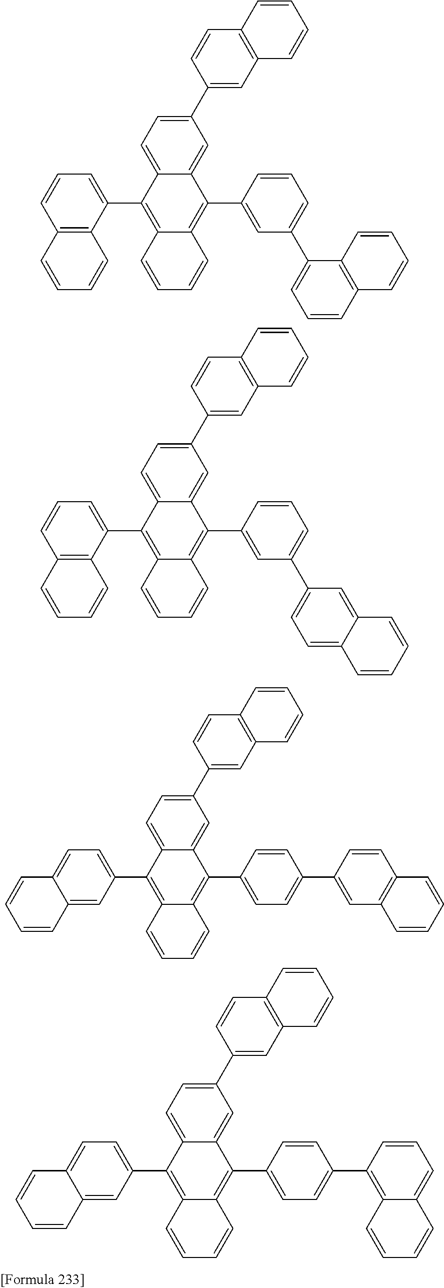

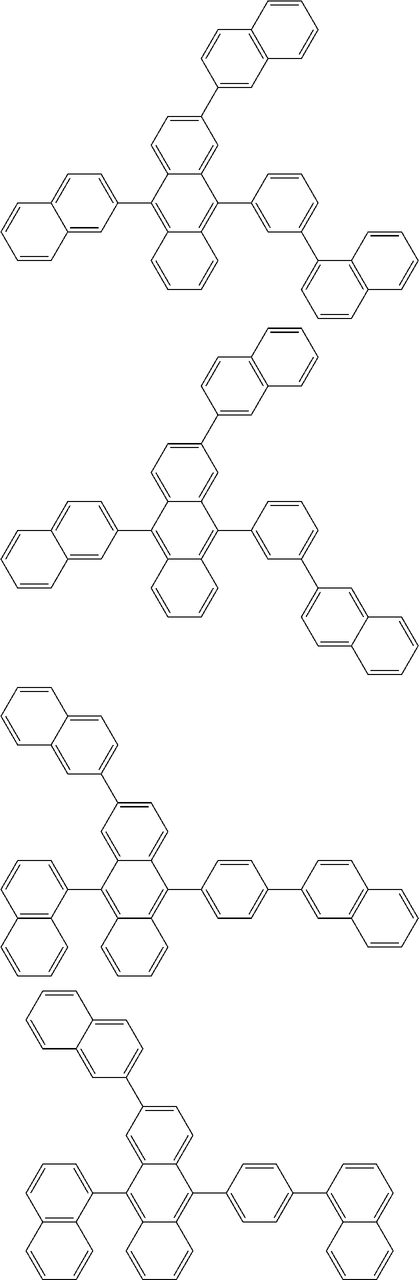

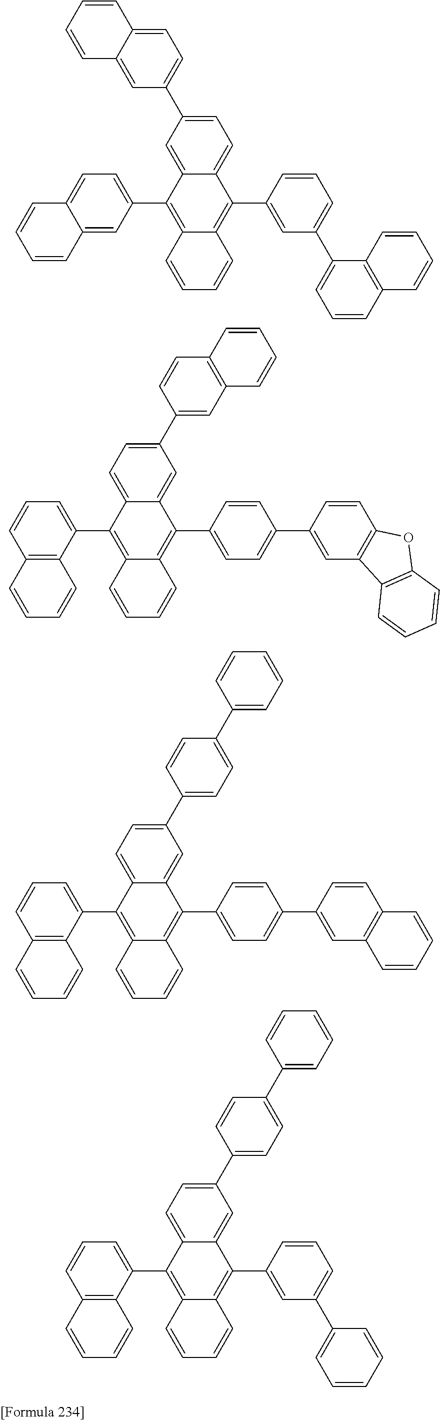

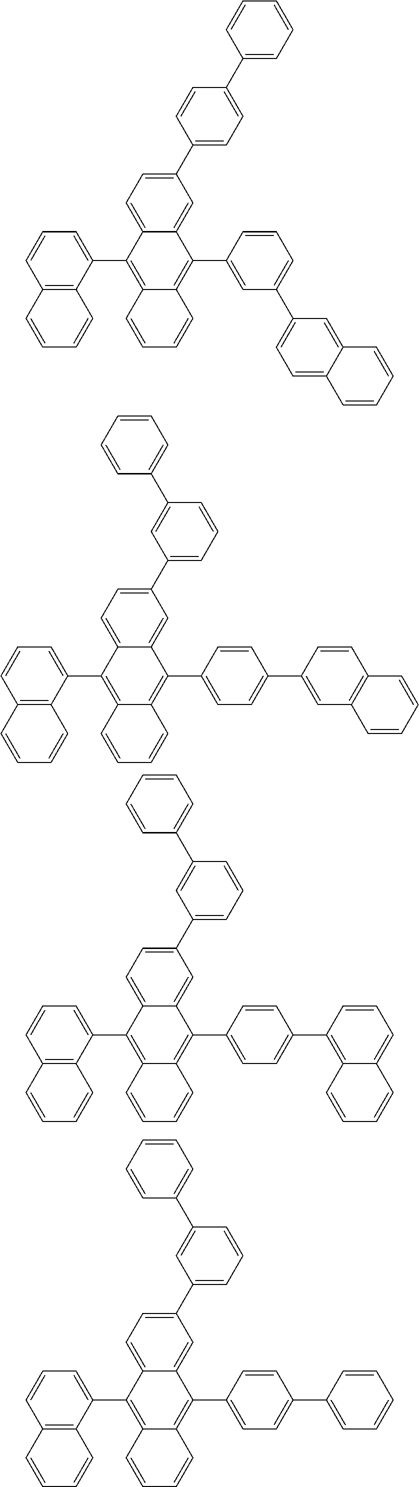

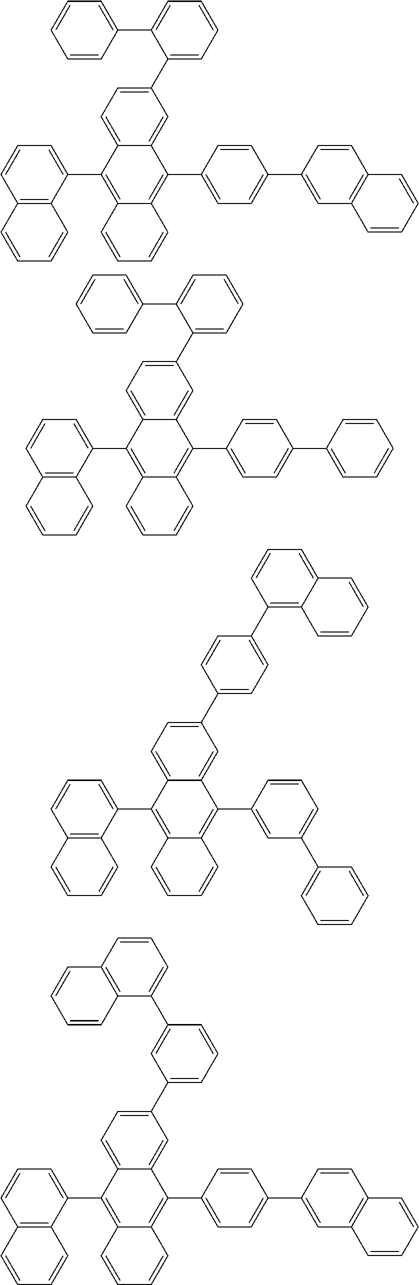

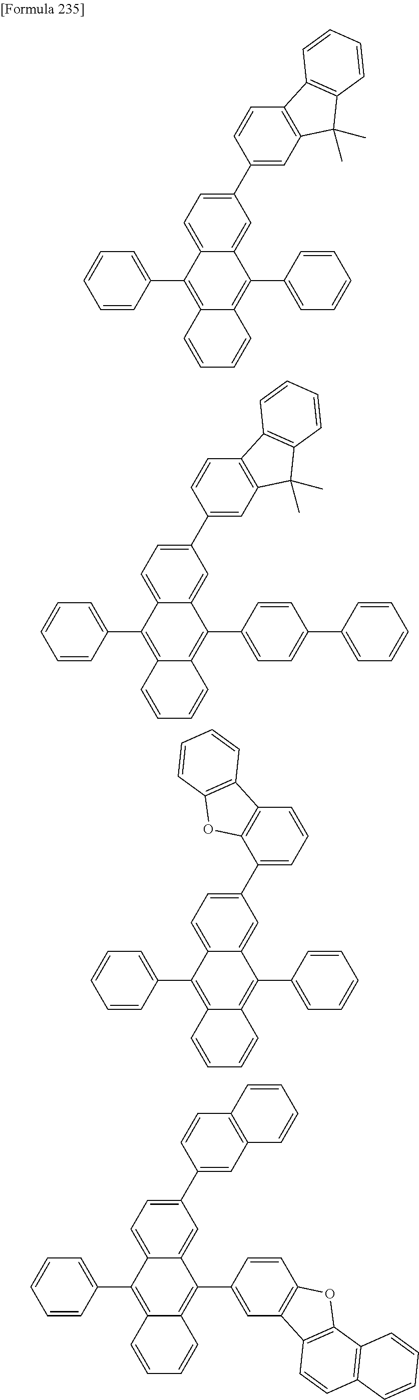

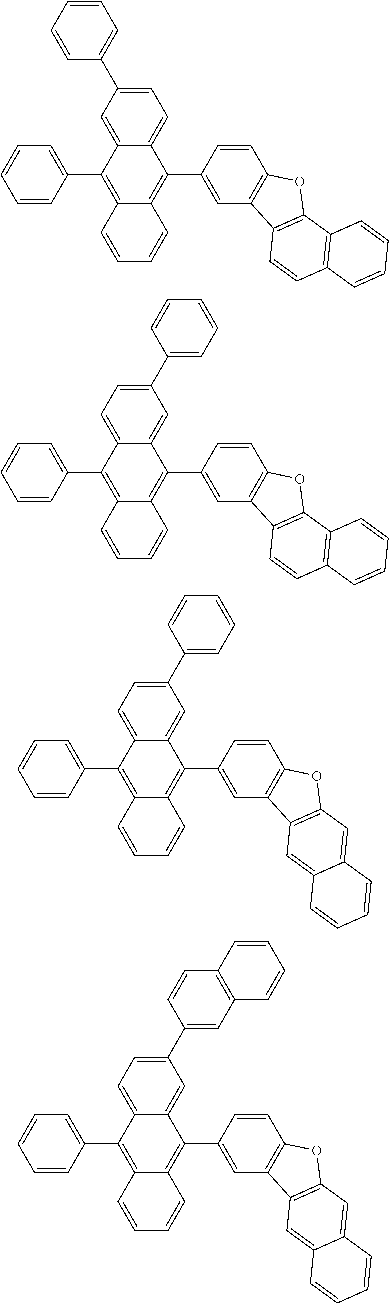

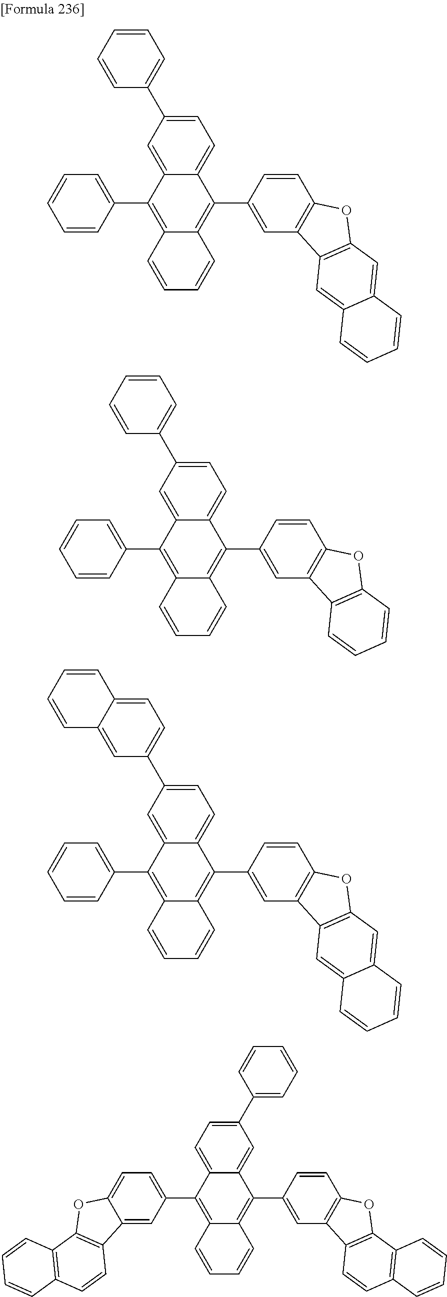 [SMILES: c1ccc(-c2ccc3c(-c4ccc5oc6cc7ccccc7cc6c5c4)c4ccccc4c(-c4ccccc4)c3c2)cc1 ; c1ccc(-c2ccc3c(-c4ccc5oc6ccccc6c5c4)c4ccccc4c(-c4ccccc4)c3c2)cc1 ; c1ccc(-c2c3ccccc3c(-c3ccc4oc5cc6ccccc6cc5c4c3)c3ccc(-c4ccc5ccccc5c4)cc23)cc1 ; c1ccc(-c2ccc3c(-c4ccc5oc6c7ccccc7ccc6c5c4)c4ccccc4c(-c4ccc5oc6c7ccccc7ccc6c5c4)c3c2)cc1]

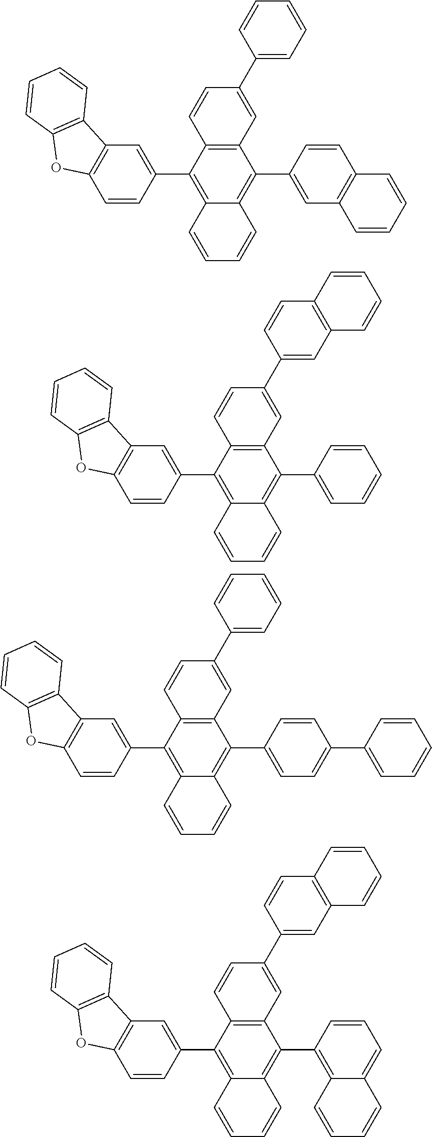

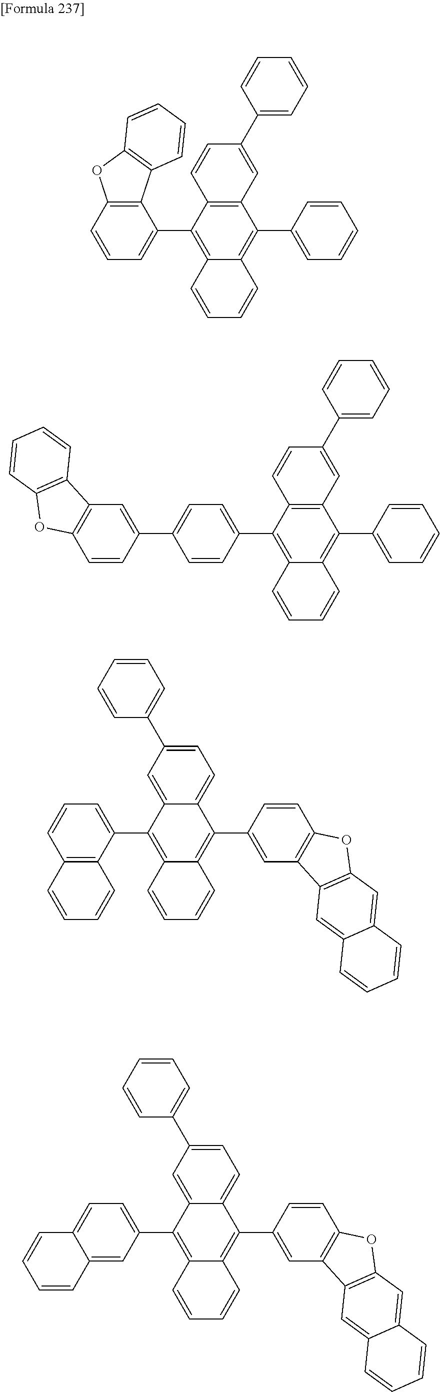 [SMILES: c1ccc(-c2ccc3c(-c4cccc5oc6ccccc6c45)c4ccccc4c(-c4ccccc4)c3c2)cc1 ; c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4ccc5oc6cc7ccccc7cc6c5c4)c4ccccc4c(-c4cccc5ccccc45)c3c2)cc1 ; c1ccc(-c2ccc3c(-c4ccc5oc6cc7ccccc7cc6c5c4)c4ccccc4c(-c4ccc5ccccc5c4)c3c2)cc1]

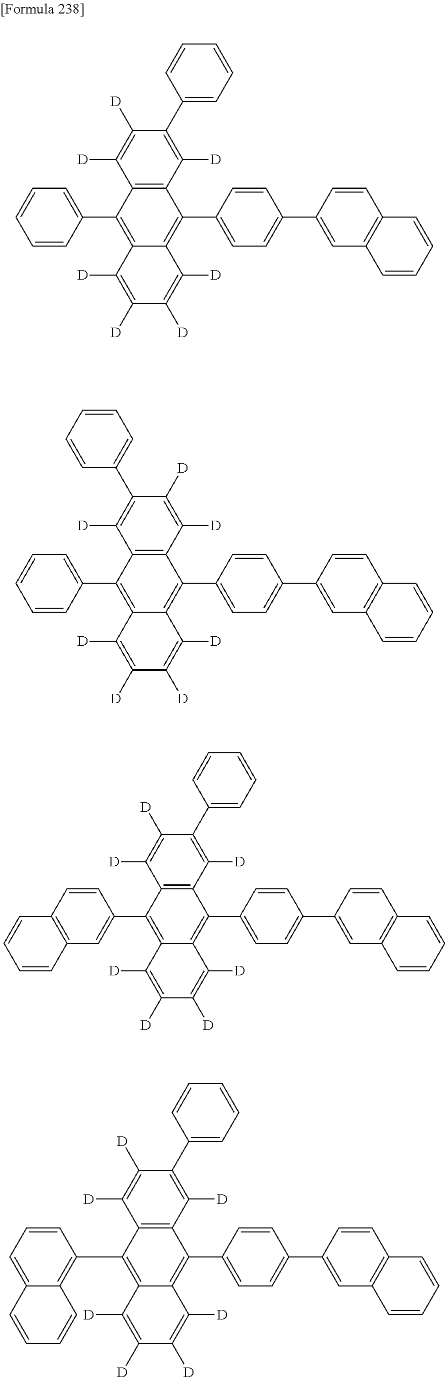 [SMILES: [2H]c1c([2H])c([2H])c2c(-c3ccc(-c4ccc5ccccc5c4)cc3)c3c([2H])c(-c4ccccc4)c([2H])c([2H])c3c(-c3ccccc3)c2c1[2H] ; [2H]c1c([2H])c([2H])c2c(-c3ccccc3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4ccccc4c3)c2c1[2H] ; [2H]c1c([2H])c([2H])c2c(-c3cccc4ccccc34)c3c([2H])c([2H])c(-c4ccccc4)c([2H])c3c(-c3ccc(-c4ccc5ccccc5c4)cc3)c2c1[2H]]

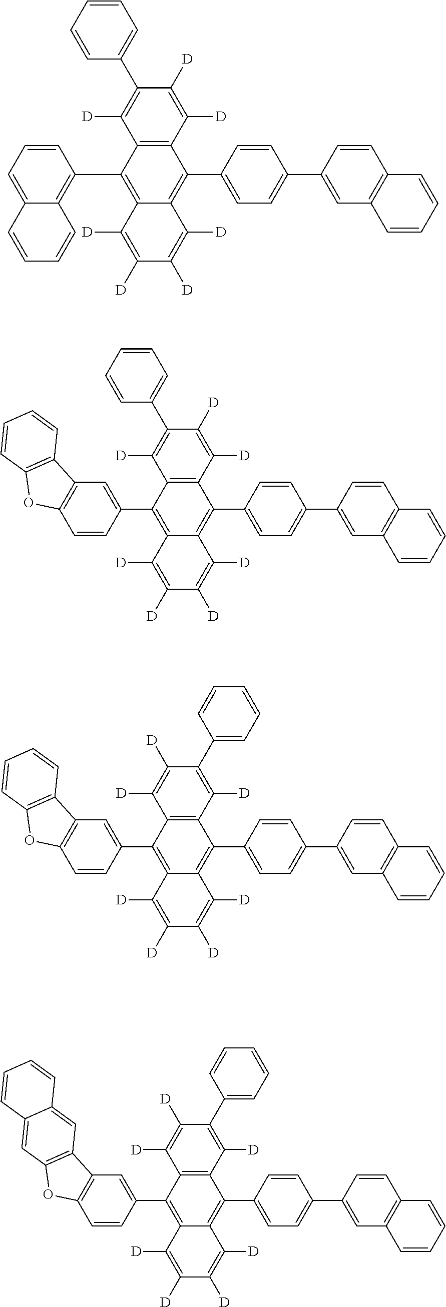 [SMILES: [2H]c1c([2H])c([2H])c2c(-c3cccc4ccccc34)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc4oc5ccccc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5ccccc5c4c3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5cc6ccccc6cc5c4c3)c2c1[2H]]

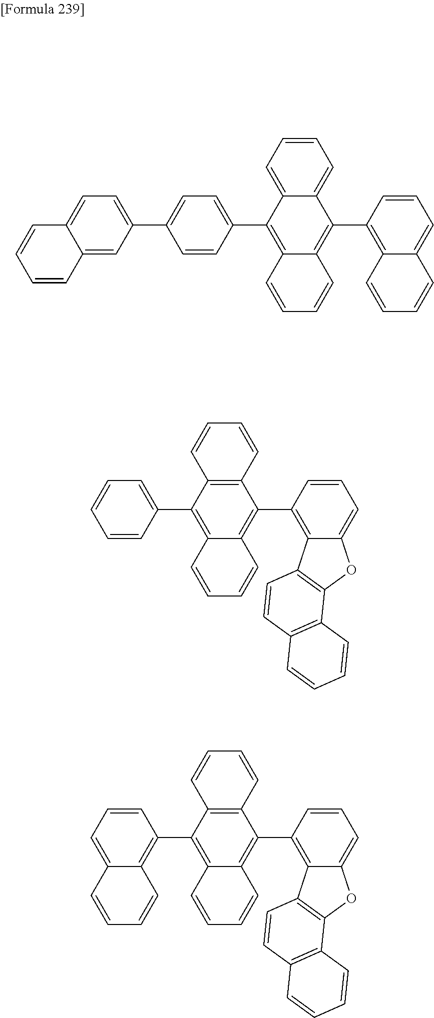

In an exemplary arrangement of the organic EL device according to the exemplary embodiment, the emitting zone consists of the first emitting layer.

In an exemplary arrangement of the organic EL device according to the exemplary embodiment, the emitting zone includes the first emitting layer and further includes a second emitting layer.

In an exemplary arrangement of the organic EL device according to the exemplary embodiment, the emitting zone consists of the first emitting layer and the second emitting layer.

In an exemplary arrangement of the organic EL device according to the exemplary embodiment, the emitting zone at least includes the first emitting layer containing the first host material and the second emitting layer containing a second host material. The first host material and the second host material are mutually different.

When the emitting zone at least includes the first emitting layer and the second emitting layer, the luminous efficiency is improvable by utilizing triplet-triplet-annihilation (occasionally referred to as TTA).

TTA is a mechanism in which triplet excitons collide with one another to generate singlet excitons. The TTA mechanism is occasionally also referred to as a TTF mechanism as described in International Publication No. WO2010/134350.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

$${}^{3} {A}^{*} + {}^{3} {A}^{*} \to ( 4 / 9 ) {}^{1} A + ( 1 / 9 ) {}^{1} {A}^{*} + ( 13 / 9 ) {}^{3} {A}^{*}$$

In other words, 5³A*→4¹A+1A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(1/2)=37.5%) to 25% (the amount ratio of initially generated singlet excitons). At this time, the TTF ratio is 37.5/62.5=60%.

In an exemplary arrangement of the organic EL device according to the exemplary embodiment, in terms of expressing the TTF mechanism, the triplet energy of the first host material T₁(H1) and the triplet energy of the second host material T₁(H2) preferably satisfy a relationship of a numerical formula (Numerical Formula 1) below, more preferably satisfy a relationship of a numerical formula (Numerical Formula 2) below.

$${T}_{1} ( H 2 ) > {T}_{1} ( H 1 ) \qquad ( Numerical Formula 1 )$$

$${T}_{1} ( H 2 ) - {T}_{1} ( H 1 ) > 0.03 eV \qquad ( Numerical Formula 2 )$$

When an exemplary arrangement of the organic EL device according to the exemplary embodiment includes the first emitting layer and the second emitting layer satisfying the relationship of the above numerical formula (Numerical Formula 1), luminous efficiency of the device is improvable.

In an exemplary arrangement of the organic EL device according to the exemplary embodiment, it is considered that since the relationship of the numerical formula (Numerical Formula 1) is satisfied, triplet excitons generated by recombination of holes and electrons in the second emitting layer and present on an interface between the second emitting layer and organic layer(s) in direct contact therewith are not likely to be quenched even under the presence of excessive carriers on the interface between the second emitting layer and the organic layer(s). For instance, the presence of a recombination region locally on an interface between the second emitting layer and the hole transporting layer or the electron blocking layer is considered to cause quenching by excessive electrons. Meanwhile, the presence of a recombination region locally on an interface between the second emitting layer and the electron transporting layer or the hole blocking layer is considered to cause quenching by excessive holes.

In an exemplary arrangement of the organic EL device according to the exemplary embodiment, by including the first emitting layer and the second emitting layer in a manner to satisfy the relationship of the numerical formula (Numerical Formula 1), triplet excitons generated in the second emitting layer can transfer to the first emitting layer without being quenched by excessive carriers and be inhibited from back-transferring from the first emitting layer to the second emitting layer. Consequently, the first emitting layer exhibits the TTF mechanism to effectively generate singlet excitons, thereby improving the luminous efficiency.

Accordingly, the organic EL device includes, as different regions, the second emitting layer mainly generating triplet excitons and the first emitting layer mainly exhibiting the TTF mechanism using triplet excitons having transferred from the second emitting layer, and has a difference in triplet energy provided by using a compound having a smaller triplet energy than that of the second host material in the second emitting layer as the first host material in the first emitting layer. The luminous efficiency is thus improved.

In an exemplary arrangement of the organic EL device according to the exemplary embodiment, the first emitting layer and the second emitting layer are in direct contact with each other.

Herein, a layer arrangement in which “the first emitting layer and the second emitting layer are in direct contact with each other” may include one of embodiments (LS1), (LS2), and (LS3) below.

(LS1) An embodiment in which a region containing both the first host material and the second host material is generated in a process of vapor-depositing the compound of the first emitting layer and vapor-depositing the compound of the second emitting layer, and is present on the interface between the first emitting layer and the second emitting layer.

(LS2) An embodiment in which in a case of containing an luminescent compound in the first emitting layer and the second emitting layer, a region containing the first host material, the second host material and the luminescent compound is generated in a process of vapor-depositing the compound of the first emitting layer and vapor-depositing the compound of the second emitting layer, and is present on the interface between the first emitting layer and the second emitting layer.

(LS3) An embodiment in which in a case of containing an luminescent compound in the first emitting layer and the second emitting layer, a region containing the luminescent compound, a region containing the first host material or a region containing the second host material is generated in a process of vapor-depositing the compound of the first emitting layer and vapor-depositing the compound of the second emitting layer, and is present on the interface between the first emitting layer and the second emitting layer.

### Second Emitting Layer

In an exemplary arrangement of the organic EL device according to the exemplary embodiment, the second emitting layer contains the second host material. The second host material is not particularly limited.

In an exemplary arrangement of the organic EL device according to the exemplary embodiment, the second emitting layer contains a second luminescent compound. The second luminescent compound is not particularly limited.

In an exemplary arrangement of the organic EL device according to the exemplary embodiment, the second emitting layer contains the second host material and the second luminescent compound.

In an exemplary arrangement of the organic EL device according to the exemplary embodiment, the second luminescent compound is a compound that is the same as or different from the first luminescent compound contained in the first emitting layer.

In an exemplary arrangement of the organic EL device according to the exemplary embodiment, the second host material and the first host material contained in the first emitting layer are mutually different compounds.

The second luminescent compound preferably emits light having the maximum peak wavelength of 500 nm or less, more preferably emits light having the maximum peak wavelength in a range from 430 nm to 480 nm. The second luminescent compound is preferably a fluorescent compound that emits fluorescence having the maximum peak wavelength of 500 nm or less, and more preferably a fluorescent compound that emits fluorescence having the maximum peak wavelength in a range from 430 nm to 480 nm.

In an exemplary arrangement of the organic EL device according to the exemplary embodiment, the second emitting layer contains the second host material and the second luminescent compound that emits light having the maximum peak wavelength of 500 nm or less.

In an exemplary arrangement of the organic EL device according to the exemplary embodiment, the first luminescent compound has a full width at half maximum in a range from 2 nm to 30 nm at the maximum peak.

The method of measuring a maximum peak wavelength of a compound is as described above.

In an exemplary arrangement of the organic EL device according to the exemplary embodiment, the second luminescent compound is a compound containing no azine ring structure in a molecule.

In an exemplary arrangement of the organic EL device according to the exemplary embodiment, the second luminescent compound is preferably not a boron-containing complex, and more preferably not a complex.

Examples of a fluorescent compound that emits blue fluorescence and is usable in the second emitting layer include a pyrene derivative, styrylamine derivative, chrysene derivative, fluoranthene derivative, fluorene derivative, diamine derivative, and triarylamine derivative.

In an exemplary arrangement of the organic EL device according to the exemplary embodiment, the second emitting layer does not contain a metal complex. Moreover, in an exemplary arrangement of the organic EL device according to the exemplary embodiment, the second emitting layer does not contain a boron-containing complex.

In an exemplary arrangement of the organic EL device according to the exemplary embodiment, the second emitting layer does not contain a phosphorescent material (dopant material).

In an exemplary arrangement of the organic EL device according to the exemplary embodiment, the second emitting layer does not contain a heavy metal complex and a phosphorescent rare-earth metal complex.

In an exemplary arrangement of the organic EL device according to the exemplary embodiment, the second emitting layer contains 0.5 mass % or more of the luminescent compound with respect to a total mass of the second emitting layer. The second compound contains the luminescent compound preferably at 10 mass % or less, more preferably at 7 mass % or less, and still more preferably at 5 mass % less with respect to the total mass of the second emitting layer.

In an exemplary arrangement of the organic EL device according to the exemplary embodiment, the second emitting layer preferably contains the second host material at 60 mass % or more, more preferably at 70 mass % or more, still more preferably at 80 mass % or more, still further more preferably at 90 mass % or more, and yet still further more preferably at 95 mass % or more, with respect to the total mass of the second emitting layer.

The second emitting layer preferably contains the second host material at 99.5 mass % or less with respect to the total mass of the second emitting layer.

When the second emitting layer contains the second host material and the second luminescent compound, the upper limit of a total of the content ratios of the second host material and the second luminescent compound is 100 mass %.

In the organic EL device according to the exemplary embodiment, the second emitting layer may further contain any other material than the second host material and the second luminescent compound.

The second emitting layer may contain a single type of the second host material or may contain two or more types of the second host material. The second emitting layer may contain a single type of the second luminescent compound or may contain two or more types of the second luminescent compound.

In an exemplary arrangement of the organic EL device according to the exemplary embodiment, a triplet energy of the first luminescent compound T₁(D1) and a triplet energy of the first host material T₁(H1) preferably satisfy a relationship of a numerical formula (Numerical Formula 4A) below.

$${T}_{1} ( D 1 ) > {T}_{1} ( H 1 ) \qquad ( Numerical Formula 4 A )$$

In an exemplary arrangement of the organic EL device according to the exemplary embodiment, when the first luminescent compound and the first host material satisfy the relationship of the numerical formula (Numerical Formula 4A), in transfer of triplet excitons generated in the second emitting layer to the first emitting layer, the triplet excitons energy-transfer not onto the first luminescent compound having higher triplet energy but onto molecules of the first host material. In addition, triplet excitons generated by recombination of holes and electrons on the first host material do not transfer to the first luminescent compound having higher triplet energy. Triplet excitons generated by recombination on molecules of the first luminescent compound quickly energy-transfer to molecules of the first host material.

Triplet excitons in the first host material do not transfer to the first luminescent compound but efficiently collide with one another on the first host material to generate singlet excitons by the TTF phenomenon.

In an exemplary arrangement of the organic EL device according to the exemplary embodiment, a singlet energy of the first host material S₁(H1) and a singlet energy of the first luminescent compound S₁(D1) preferably satisfy a relationship of a numerical formula (Numerical Formula 4) below.

$${S}_{1} ( H 1 ) > {S}_{1} ( D 1 ) . \qquad ( Numerical Formula 4 )$$

In an exemplary arrangement of the organic EL device of each exemplary embodiment, when the first luminescent compound and the first host material satisfy the relationship of the numerical formula (Numerical formula 4), due to the singlet energy of the first luminescent compound being smaller than the singlet energy of the first host material, singlet excitons generated by the TTF phenomenon energy-transfer from the first host material to the first luminescent compound, thereby contributing to emission (preferably fluorescence) of the first luminescent compound.

In an exemplary arrangement of the organic EL device according to the exemplary embodiment, it is preferable that a singlet energy of the second host material Si(H2) and a singlet energy of the second luminescent compound Si(D2) satisfy a relationship of a numerical formula (Numerical Formula 20) below.

$${S}_{1} ( H 2 ) > {S}_{1} ( D 2 ) \qquad ( Numerical Formula 20 )$$

When the second host material and the second luminescent compound satisfy the relationship of the numerical formula (Numerical Formula 20), singlet excitons generated on the second host material easily energy-transfer from the second host material to the second luminescent compound, thereby contributing to emission (preferably fluorescence) of the second compound.

In the organic EL device according to the second exemplary embodiment, the triplet energy of the second host material T₁(H2) and a triplet energy of the second luminescent compound T₁(D2) preferably satisfy a relationship of a numerical formula (Numerical Formula 20A) below.

$${T}_{1} ( D 2 ) > {T}_{1} ( H 2 ) \qquad ( Numerical Formula 20 A )$$

When the second host material and the second luminescent compound satisfy the relationship of the numerical formula (Numerical Formula 20A), triplet excitons generated in the second emitting layer are transferred not onto the second luminescent compound having higher triplet energy but onto the second host material, thereby being easily transferred to the as 1 emitting layer.

In an exemplary arrangement of the organic EL device according to the exemplary embodiment, a film thickness of the first emitting layer is preferably 5 nm or more, more preferably 15 nm or more. In a case where the emitting zone has the second emitting layer, when the film thickness of the first emitting layer is 5 nm or more, it is easy to inhibit triplet excitons having transferred from the second emitting layer to the first emitting layer from returning to the second emitting layer. Further, when the film thickness of the first emitting layer is 5 nm or more, triplet excitons can be sufficiently separated from the recombination portion in the second emitting layer.

In an exemplary arrangement of the organic EL device according to the exemplary embodiment, the film thickness of the first emitting layer is preferably 20 nm or less. When the film thickness of the first emitting layer is 20 nm or less, a density of triplet excitons in the first emitting layer is improvable to further facilitate occurrence of the TTF phenomenon.

In an exemplary arrangement of the organic EL device according to the exemplary embodiment, the film thickness of the first emitting layer is preferably in a range from 5 nm to 20 nm.

In an exemplary arrangement of the organic EL device according to the exemplary embodiment, the film thickness of the first emitting layer is preferably 3 nm or more, more preferably 5 nm or more. When the film thickness of the second emitting layer is 3 nm or more, the film thickness is sufficient to cause recombination of holes and electrons in the second emitting layer.

In an exemplary arrangement of the organic EL device according to the exemplary embodiment, the film thickness of the second emitting layer is preferably 15 nm or less, more preferably 10 nm or less. When the film thickness of the second emitting layer is 15 nm or less, the film thickness is sufficiently thin to allow for transfer of triplet excitons to the first emitting layer.

In an exemplary arrangement of the organic EL device according to the exemplary embodiment, the film thickness of the second emitting layer is more preferably in a range from 3 nm to 15 nm.

### First Host Material and Second Host Material

In an exemplary arrangement of the organic EL device according to the exemplary embodiment, the first host material and the second host material are also each preferably the first compound. The first compound is, for instance, a compound selected from the group consisting of compounds represented by a formula (1), a formula (1X), a formula (12X), a formula (13X), a formula (14X), a formula (15X), a formula (16X), a formula (1000B), a formula (16X), a formula (17X-1), a formula (17X-2), a formula (17X-3), and a formula (18) below.

Moreover, the first compound is also usable as the first host material and the second host material.

### Compound Represented by Formula (1)

In an exemplary arrangement of the organic EL device according to the exemplary embodiment, the first compound is a compound represented by the formula (1) below. The first compound represented by the formula (1) has at least one group represented by a formula (11A) below.

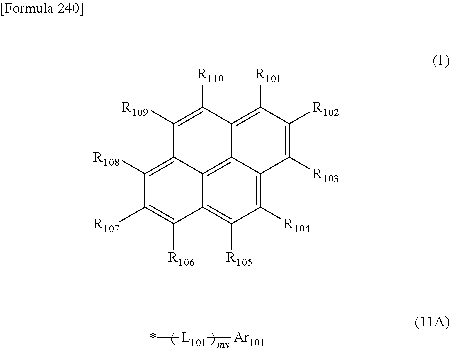

In the formula (1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms a substituted or unsubstituted heterocyclic group having 5 to 50 ring atoms, or a group represented by the formula (11A), and at least one of R₁₀₁ to R₁₁₀ is a group represented by the formula (11A);
when a plurality of groups represented by the formula (11A) are present, the plurality of groups represented by the formula (11A) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (11A) represents a bonding position to a pyrene ring in the formula (1).

In the first compound represented by the formula (1), R₉₀₁, R₉₀₂, R₉₀₃, R₉₀₄, R₉₀₅, R₉₀₆, R₉₀₇, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary embodiment, Ar₁₀₁ is preferably a substituted or unsubstituted aryl group having 6 to 50 carbon atoms.

In an exemplary embodiment, Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted pyrenyl group, a substituted or unsubstituted phenanthryl group, or a substituted or unsubstituted fluorenyl group.

In an exemplary embodiment, the first compound is preferably represented by a formula (101) below.

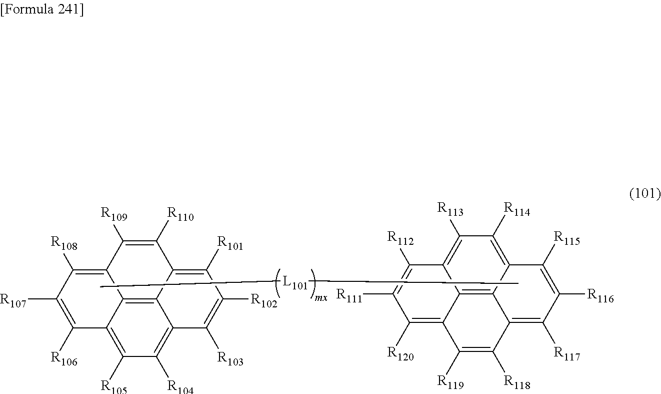

In the formula (101):
R₁₀₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms or a substituted or unsubstituted heterocyclic group having 5 to 50 ring atoms;
one of R₁₀₁ to R₁₁₀ represents a bonding position to L₁₀₁, and one of R₁₁₁ to R₁₂₀ represents a bonding position to L₁₀₁;
L₁₀₁ is a single bond, a substituted or unsubstituted arylene group having 6 to 50 ring carbon atoms, or a substituted or unsubstituted divalent heterocyclic group having 5 to 50 ring atoms;
mx is 0, 1, 2, 3, 4, or 5; and
when two or more L₁₀₁ are present, the two or more L₁₀₁ are mutually the same or different.

In an exemplary embodiment, L₁₀₁ is preferably a single bond or a substituted or unsubstituted arylene group having 6 to 50 ring carbon atoms.

In an exemplary embodiment, two or more of R₁₀₁ to R₁₁₀ are each preferably a group represented by the formula (11A).

In an exemplary embodiment, it is preferable that two or more of R₁₀₁ to R₁₁₀ are each a group represented by the formula (11A) and Ar₁₀₁ is a substituted or unsubstituted aryl group having 6 to 50 ring carbon atoms.

In an exemplary embodiment, it is preferable that Ar₁₀₁ is not a substituted or unsubstituted pyrenyl group, L₁₀₁ is not a substituted or unsubstituted pyrenylene group, and a substituted or unsubstituted aryl group having 6 to 50 ring carbon atoms for R₁₀₁ to R₁₁₀ not being a group represented by the formula (11A) is not a substituted or unsubstituted pyrenyl group.

In an exemplary embodiment, R₁₀₁ to R₁₁₀ not being the group represented by the formula (11A) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary embodiment, R₁₀₁ to R₁₁₀ not being the group represented by the formula (11A) are preferably each independently a hydrogen atom, a substituted or unsubstituted alkyl group having 1 to 50 carbon atoms, or a substituted or unsubstituted cycloalkyl group having 3 to 50 ring carbon atoms.

In an exemplary embodiment, R₁₀₁ to R₁₁₀ not being the group represented by the formula (11A) are each preferably a hydrogen atom.

### Compound Represented by Formula (1X)

In an exemplary arrangement of the organic EL device according to the exemplary embodiment, the first compound is a compound represented by a formula (1X) below.

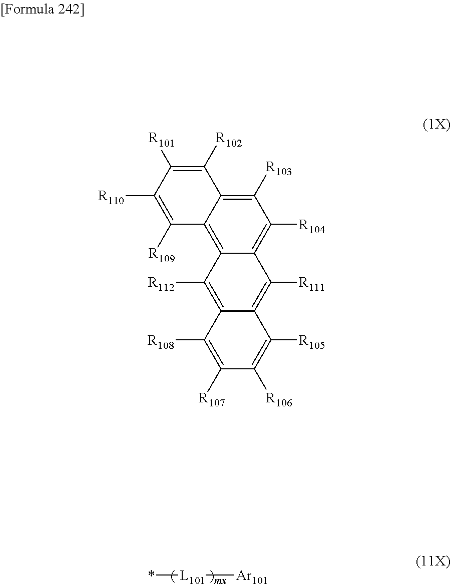

In the formula (1X):
R₁₀₁ to R₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms a substituted or unsubstituted heterocyclic group having 5 to 50 ring atoms, or a group represented by the formula (11X);
at least one of R₁₀₁ to R₁₁₂ is a group represented by the formula (11X);
when a plurality of groups represented by the formula (11X) are present, the plurality of groups represented by the formula (11X) are mutually the same or different;
L₁₀₁ is a single bond, a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 1, 2, 3, 4, or 5;
when two or more L₁₀₁ are present, the two or more L₁₀₁ are mutually the same or different;
when two or more Ar₁₀₁ are present, the two or more Ar₁₀₁ are mutually the same or different; and
* in the formula (11X) represents a bonding position to a benz[a]anthracene ring in the formula (1X).

In an exemplary arrangement of the organic EL device according to the exemplary embodiment, the group represented by the formula (11X) is a group represented by a formula (111X) below.

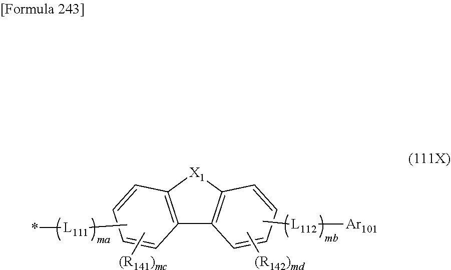

In the formula (111X):
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 1, 2, 3 or 4;
mb is 1, 2, 3 or 4;
ma+mb is 2, 3, or 4;
Ar₁₀₁ represents the same as Ar₁₀₁ in the formula (11X);
R₁₄₁, R₁₄₂, R₁₄₃, R₁₄₄ and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

Among positions *1 to *8 of carbon atoms in a cyclic structure represented by a formula (111aX) below in the group represented by the formula (111X), L₁₁₁ is bonded to one of the positions *1 to *4, R₁₄₁ is bonded to each of three positions of the rest of *1 to *4, L₁₁₂ is bonded to one of the positions *5 to *8, and R₁₄₂ is bonded to each of three positions of the rest of *5 to *8.

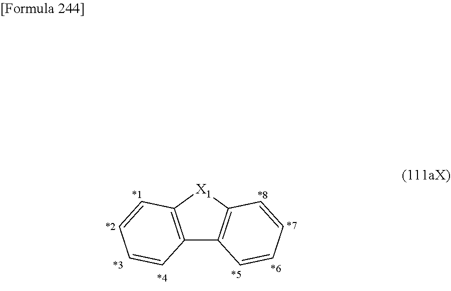

For instance, the group represented by the formula (111X), in which L₁₁₁ is bonded to a carbon atom at *2 in the cyclic structure represented by the formula (111 aX) and L₁₁₂ is bonded to a carbon atom at *7 in the cyclic structure represented by the formula (111aX), is represented by a formula (111 bX) below.

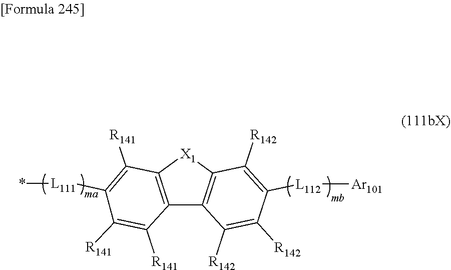

In the formula (111 bX):
X₁, L₁₁₁, L₁₁₂, ma, mb, Ar₁₀₁, R₁₄₁, R₁₄₂, R₁₄₃, R₁₄₄ and R₁₄₅ each independently represent the same as X₁, L₁₁₁, L₁₁₂, ma, mb, Ar₁₀₁, R₁₄₁, R₁₄₂, R₁₄₃, R₁₄₄ and R₁₄₅ in the formula (111X);
a plurality of R₁₄₁ are mutually the same or different; and
a plurality of R₁₄₂ are mutually the same or different.

In the organic EL device according to the exemplary embodiment, the group represented by the formula (111X) is preferably a group represented by the formula (111bX).

In the compound represented by the formula (1X), preferably, ma is 1 or 2 and mb is 1 or 2.

In the compound represented by the formula (1X), preferably, ma is 1 and mb is 1.

In the compound represented by the formula (1X), Ar₁₀₁ is preferably a substituted or unsubstituted aryl group having 6 to 50 ring carbon atoms.

In the compound represented by the formula (1X), Ar₁₀₁ is preferably a substituted or unsubstituted phenyl group, a substituted or unsubstituted naphthyl group, a substituted or unsubstituted biphenyl group, a substituted or unsubstituted terphenyl group, a substituted or unsubstituted benz[a]anthryl group, a substituted or unsubstituted pyrenyl group, a substituted or unsubstituted phenanthryl group, or a substituted or unsubstituted fluorenyl group.

The compound represented by the formula (1X) is also preferably represented by a formula (101X) below.

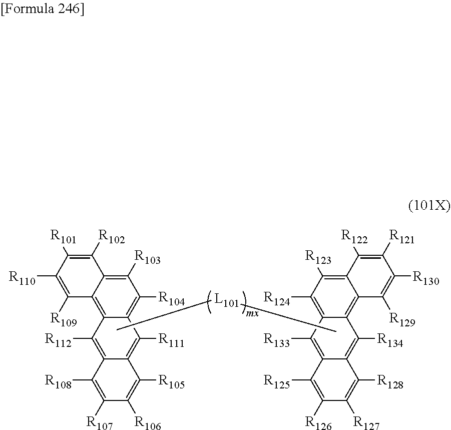

In the formula (101X):
one of R₁₁₁ and R₁₁₂ represents a bonding position to L₁₀₁ and one of R₁₃₃ and R₁₃₄ represents a bonding position to L₁₀₁;
R₁₀₁ to R₁₁₀, R₁₂₁ to R₁₃₀, R₁₁₁ or R₁₁₂ not being the bonding position to L₁₀₁, and R₁₃₃ or R₁₃₄ not being the bonding position to L₁₀₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, or a substituted or unsubstituted heterocyclic group having 5 to 50 ring atoms;
L₁₀₁ is a single bond, a substituted or unsubstituted arylene group having 6 to 50 ring carbon atoms, or a substituted or unsubstituted divalent heterocyclic group having 5 to 50 ring atoms;
mx is 1, 2, 3, 4, or 5; and
when two or more L₁₀₁ are present, the two or more L₁₀₁ are mutually the same or different.

In the compound represented by the formula (1X), L₁₀₁ is preferably a single bond, or a substituted or unsubstituted arylene group having 6 to 50 ring carbon atoms.

The compound represented by the formula (1X) is also preferably represented by a formula (102X) below.

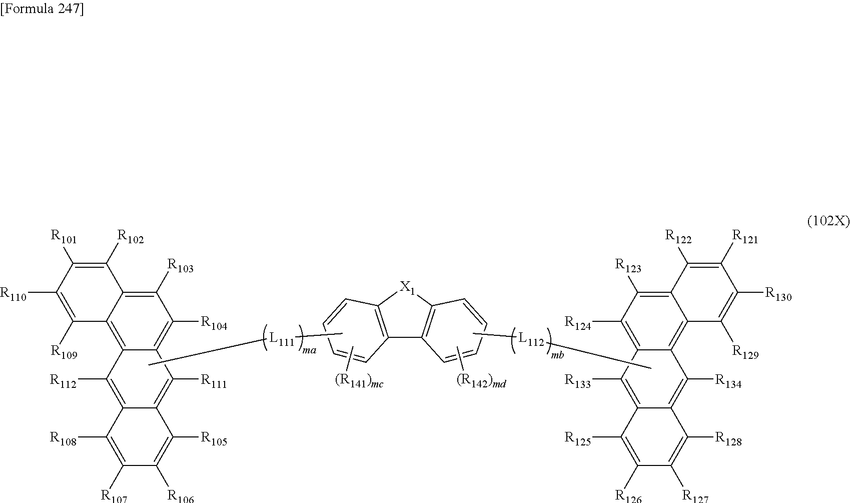

In the formula (102X):
one of R₁₁₁ and R₁₁₂ represents a bonding position to L₁₁₁ and one of R₁₃₃ and R₁₃₄ represents a bonding position to L₁₁₂;
R₁₀₁ to R₁₁₀, R₁₂₁ to R₁₃₀, R₁₁₁ or R₁₁₂ not being the bonding position to L₁₁₁, and R₁₃₃ or R₁₃₄ not being the bonding position to L₁₁₂ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, or a substituted or unsubstituted heterocyclic group having 5 to 50 ring atoms;
X₁ is CR₁₄₃R₁₄₄, an oxygen atom, a sulfur atom, or NR₁₄₅;
L₁₁₁ and L₁₁₂ are each independently a single bond, a substituted or unsubstituted arylene group having 6 to 50 ring carbon atoms, or a substituted or unsubstituted divalent heterocyclic group having 5 to 50 ring atoms;
ma is 1, 2, 3 or 4;
mb is 1, 2, 3 or 4;
ma+mb is 2, 3, 4, or 5;
R₁₄₁, R₁₄₂, R₁₄₃, R₁₄₄ and R₁₄₅ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, or a substituted or unsubstituted heterocyclic group having 5 to 50 ring atoms;
mc is 3;
three R₁₄₁ are mutually the same or different;
md is 3; and
three R₁₄₂ are mutually the same or different.

In the compound represented by the formula (1X), preferably, ma is 1 or 2 and mb is 1 or 2 in the formula (102X).

In the compound represented by the formula (1X), preferably, ma is 1 and mb is 1 in the formula (102X).

In the compound represented by the formula (1X), the group represented by the formula (11X) is also preferably a group represented by a formula (11AX) or a group represented by a formula (11BX) below.

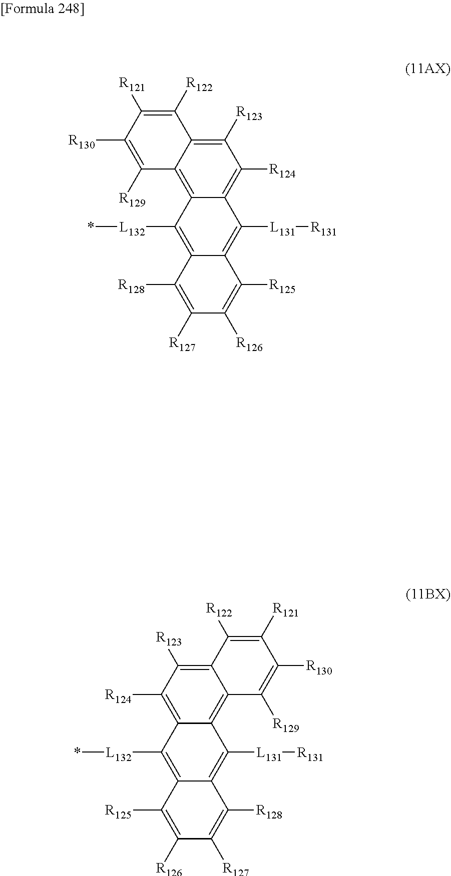

In the formulae (11AX) and (11BX):
R₁₂₁ to R₁₃₁ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms or a substituted or unsubstituted heterocyclic group having 5 to 50 ring atoms,
when a plurality of groups represented by the formula (11AX) are present, the plurality of groups represented by the formula (11AX) are mutually the same or different;
when a plurality of groups represented by the formula (11BX) are present, the plurality of groups represented by the formula (11BX) are mutually the same or different;
L₁₃₁ and L₁₃₂ are each independently a single bond, a substituted or unsubstituted arylene group having 6 to 50 ring carbon atoms, or a substituted or unsubstituted divalent heterocyclic group having 5 to 50 ring atoms; and
* in each of the formulae (11AX) and (11BX) represents a bonding position to a benz[a]anthracene ring in the formula (1X).

The compound represented by the formula (1X) is also preferably represented by a formula (103X) below.

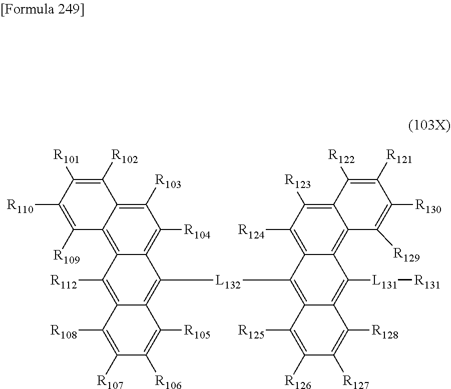

In the formula (103X):
R₁₀₁ to R₁₁₀ and R₁₁₂ respectively represent the same as R₁₀₁ to R₁₁₀ and R₁₁₂ in the formula (1X); and
R₁₂₁ to R₁₃₁, L₁₃₁, and L₁₃₂ respectively represent the same as R₁₂₁ to R₁₃₁, L₁₃₁, and L₁₃₂ in the formula (11BX).

In the compound represented by the formula (1X), L₁₃₁ is also preferably a substituted or unsubstituted arylene group having 6 to 50 ring carbon atoms.

In the compound represented by the formula (1X), L₁₃₂ is also preferably a substituted or unsubstituted arylene group having 6 to 50 ring carbon atoms.

In the compound represented by the formula (1X), also preferably, two or more of R₁₀₁ to R₁₁₂ are each a group represented by the formula (11).

In the compound represented by the formula (1X), it is preferable that two or more of R₁₀₁ to R₁₁₂ are each a group represented by the formula (11X) and Ar₁₀₁ in the formula (11X) is a substituted or unsubstituted aryl group having 6 to 50 ring carbon atoms.

In the compound represented by the formula (1X), it is also preferable that Ar₁₀₁ is not a substituted or unsubstituted benz[a]anthryl group, L₁₀₁ is not a substituted or unsubstituted benz[a]anthrylene group, and the substituted or unsubstituted aryl group having 6 to 50 ring carbon atoms for R₁₀₁ to R₁₁₀ not being the group represented by the formula (11X) is not a substituted or unsubstituted benz[a]anthryl group.

In the compound represented by the formula (1X), R₁₀₁ to R₁₁₂ not being the group represented by the formula (11X) are preferably each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In the compound represented by the formula (1X), R₁₀₁ to R₁₁₂ not being the group represented by the formula (11X) are each preferably a hydrogen atom, a substituted or unsubstituted alkyl group having 1 to 50 carbon atoms, or a substituted or unsubstituted cycloalkyl group having 3 to 50 ring carbon atoms.

In the compound represented by the formula (1X), R₁₀₁ to R₁₁₂ not being the group represented by the formula (11X) are each preferably a hydrogen atom.

### Compound Represented by Formula (12X)

In an exemplary arrangement of the organic EL device according to the exemplary embodiment, the first compound is a compound represented by a formula (12X) below.

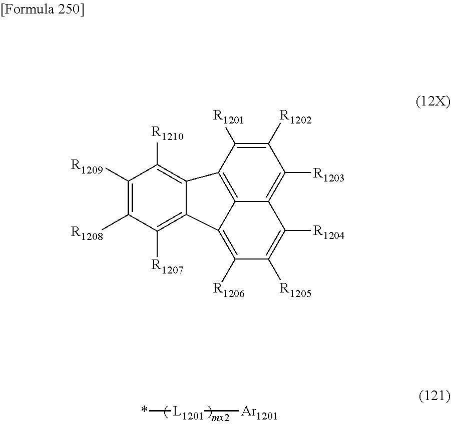

In the formula (12X):

at least one combination of adjacent two or more of R₁₂₀₁ to R₁₂₁₀ are mutually bonded to form a substituted or unsubstituted monocyclic ring, or mutually bonded to form a substituted or unsubstituted fused ring;
R₁₂₀₁ to R₁₂₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (121);
at least one of a substituent, if present, for the substituted or unsubstituted monocyclic ring, a substituent, if present, for the substituted or unsubstituted fused ring, or R₁₂₀₁ to R₁₂₁₀ is a group represented by the formula (121);
when a plurality of groups represented by the formula (121) are present, the plurality of groups represented by the formula (121) are mutually the same or different;
L₁₂₀₁ is a single bond, a substituted or unsubstituted arylene group having 6 to 50 ring carbon atoms, or a substituted or unsubstituted divalent heterocyclic group having 5 to 50 ring atoms;
Ar₁₂₀₁ is a substituted or unsubstituted aryl group having 6 to 50 ring carbon atoms, or a substituted or unsubstituted heterocyclic group having 5 to 50 ring atoms;
mx2 is 0, 1, 2, 3, 4, or 5;
when two or more L₁₂₀₁ are present, the two or more L₁₂₀₁ are mutually the same or different;
when two or more Ar₁₂₀₁ are present, the two or more Ar₁₂₀₁ are mutually the same or different; and
* in the formula (121) represents a bonding position to a ring represented by the formula (12X).

In the formula (12X), combinations of adjacent two of R₁₂₀₁ to R₁₂₁₀ refer to a combination of R₁₂₀₁ and R₁₂₀₂, a combination of R₁₂₀₂ and R₁₂₀₃, a combination of R₁₂₀₃ and R₁₂₀₄, a combination of R₁₂₀₄ and R₁₂₀₅, a combination of R₁₂₀₅ and R₁₂₀₆, a combination of R₁₂₀₇ and R₁₂₀₈, a combination of R₁₂₀₈ and R₁₂₀₉, and a combination of R₁₂₀₉ and R₁₂₁₀.

### Compound Represented by Formula (13X)

In an exemplary arrangement of the organic EL device according to the exemplary embodiment, the first compound is a compound represented by a formula (13X) below.

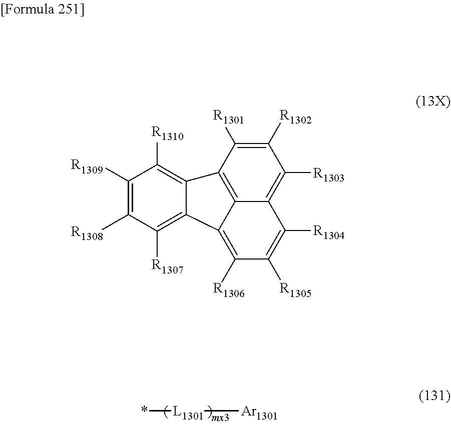

In the formula (13X):
R₁₃₀₁ to R₁₃₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms a substituted or unsubstituted heterocyclic group having 5 to 50 ring atoms, or a group represented by the formula (131);
at least one of R₁₃₀₁ to R₁₃₁₀ is a group represented by the formula (131);
when a plurality of groups represented by the formula (131) are present, the plurality of groups represented by the formula (131) are mutually the same or different;
L₁₃₀₁ is a single bond, a substituted or unsubstituted arylene group having 6 to 50 ring carbon atoms, or a substituted or unsubstituted divalent heterocyclic group having 5 to 50 ring atoms;
Ar₁₃₀₁ is a substituted or unsubstituted aryl group having 6 to 50 ring carbon atoms, or a substituted or unsubstituted heterocyclic group having 5 to 50 ring atoms; mx3 is 0, 1, 2, 3, 4, or 5;
when two or more L₁₃₀₁ are present, the two or more L₁₃₀₁ are mutually the same or different;
when two or more Ar₁₃₀₁ are present, the two or more Ar₁₃₀₁ are mutually the same or different; and
* in the formula (131) represents a bonding position to a fluoranthene ring represented by the formula (13X).

In the organic EL device according to the exemplary embodiment, none of combinations of adjacent two or more of R₁₃₀₁ to R₁₃₁₀ not being the group represented by the formula (131) are bonded to each other. Combinations of adjacent two of R₁₃₀₁ to R₁₃₁₀ in the formula (13X) refer to a combination of R₁₃₀₁ and R₁₃₀₂, a combination of R₁₃₀₂ and R₁₃₀₃, a combination of R₁₃₀₃ and R₁₃₀₄, a combination of R₁₃₀₄ and R₁₃₀₅, a combination of R₁₃₀₅ and R₁₃₀₆, a combination of R₁₃₀₇ and R₁₃₀₈, a combination of R₁₃₀₈ and R₁₃₀₉, and a combination of R₁₃₀₉ and R₁₃₁₀.

### Compound Represented by Formula (14X)

In an exemplary arrangement of the organic EL device according to the exemplary embodiment, the first compound is a compound represented by a formula (14X) below.

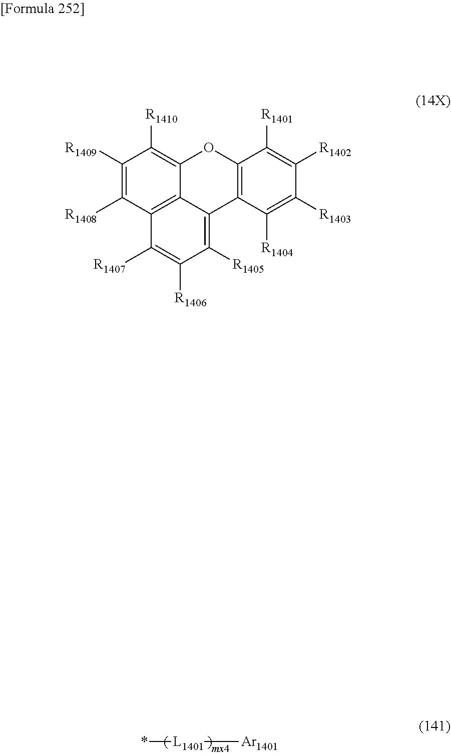

In the formula (14X):
R₁₄₀₁ to R₁₄₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms a substituted or unsubstituted heterocyclic group having 5 to 50 ring atoms, or a group represented by the formula (141);
at least one of R₁₄₀₁ to R₁₄₁₀ is a group represented by the formula (141);
when a plurality of groups represented by the formula (141) are present, the plurality of groups represented by the formula (141) are mutually the same or different;
L₁₄₀₁ is a single bond, a substituted or unsubstituted arylene group having 6 to 50 ring carbon atoms, or a substituted or unsubstituted divalent heterocyclic group having 5 to 50 ring atoms;
Ar₁₄₀₁ is a substituted or unsubstituted aryl group having 6 to 50 ring carbon atoms, or a substituted or unsubstituted heterocyclic group having 5 to 50 ring atoms;
mx4 is 0, 1, 2, 3, 4, or 5;
when two or more L₁₄₀₁ are present, the two or more L₁₄₀₁ are mutually the same or different;
when two or more Ar₁₄₀₁ are present, the two or more Ar₁₄₀₁ are mutually the same or different; and
* in the formula (141) represents a bonding position to a ring represented by the formula (14X).

### Compound Represented by Formula (15X)

In an exemplary arrangement of the organic EL device according to the exemplary embodiment, the first compound is a compound represented by a formula (15X) below.

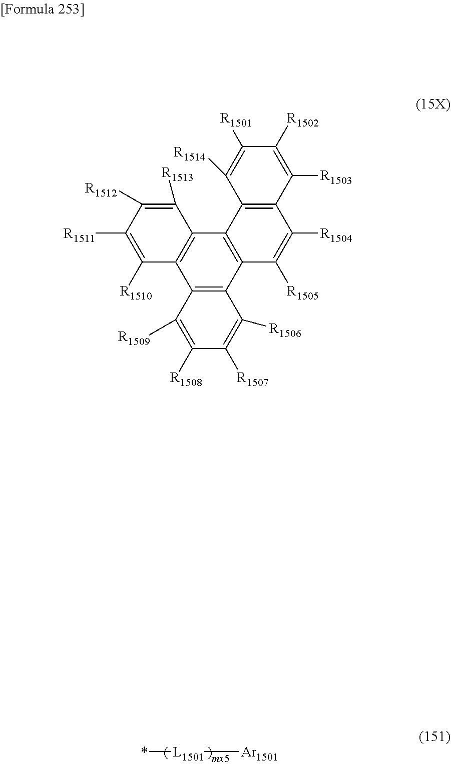

In the formula (15X):
R₁₅₀₁ to R₁₅₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms a substituted or unsubstituted heterocyclic group having 5 to 50 ring atoms, or a group represented by the formula (151);
at least one of R₁₅₀₁ to R₁₅₁₄ is a group represented by the formula (151);
when a plurality of groups represented by the formula (151) are present, the plurality of groups represented by the formula (151) are mutually the same or different;
L₁₅₀₁ is a single bond, a substituted or unsubstituted arylene group having 6 to 50 ring carbon atoms, or a substituted or unsubstituted divalent heterocyclic group having 5 to 50 ring atoms;
Ar₁₅₀₁ is a substituted or unsubstituted aryl group having 6 to 50 ring carbon atoms, or a substituted or unsubstituted heterocyclic group having 5 to 50 ring atoms; mx5 is 0, 1, 2, 3, 4, or 5;
when two or more L₁₅₀₁ are present, the two or more L₁₅₀₁ are mutually the same or different;
when two or more Ar₁₅₀₁ are present, the two or more Ar₁₅₀₁ are mutually the same or different; and
* in the formula (151) represents a bonding position to a ring represented by the formula (15X).

### Compound Represented by Formula (16X)

In an exemplary arrangement of the organic EL device according to the exemplary embodiment, the first compound is a compound represented by a formula (16X) below.

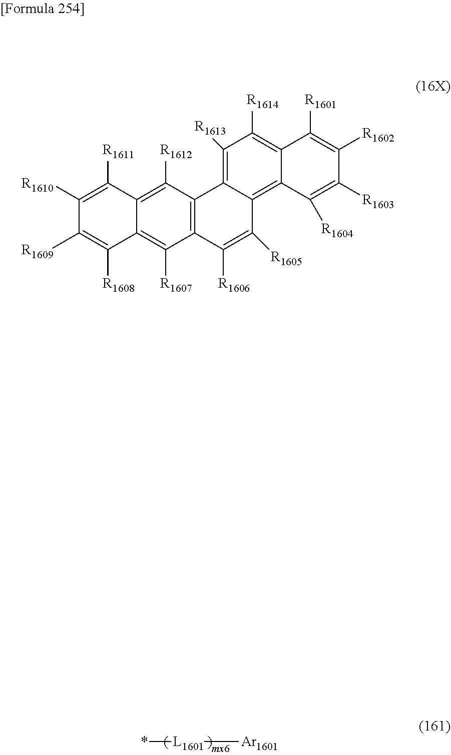

In the formula (16X):
R₁₆₀₁ to R₁₆₁₄ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms a substituted or unsubstituted heterocyclic group having 5 to 50 ring atoms, or a group represented by the formula (161);
at least one of R₁₆₀₁ to R₁₆₁₄ is a group represented by the formula (161);
when a plurality of groups represented by the formula (161) are present, the plurality of groups represented by the formula (161) are mutually the same or different;
L₁₆₀₁ is a single bond, a substituted or unsubstituted arylene group having 6 to 50 ring carbon atoms, or a substituted or unsubstituted divalent heterocyclic group having 5 to 50 ring atoms;
Ar₁₆₀₁ is a substituted or unsubstituted aryl group having 6 to 50 ring carbon atoms, or a substituted or unsubstituted heterocyclic group having 5 to 50 ring atoms;
mx6 is 0, 1, 2, 3, 4, or 5;
when two or more L₁₆₀₁ are present, the two or more L₁₆₀₁ are mutually the same or different;
when two or more Ar₁₆₀₁ are present, the two or more Ar₁₆₀₁ are mutually the same or different; and
* in the formula (161) represents a bonding position to a ring represented by the formula (16X).

### Compound Represented by Formula (1000B)

In an exemplary arrangement of the organic EL device according to the exemplary embodiment, the first compound is a compound represented by a formula (1000B) below.

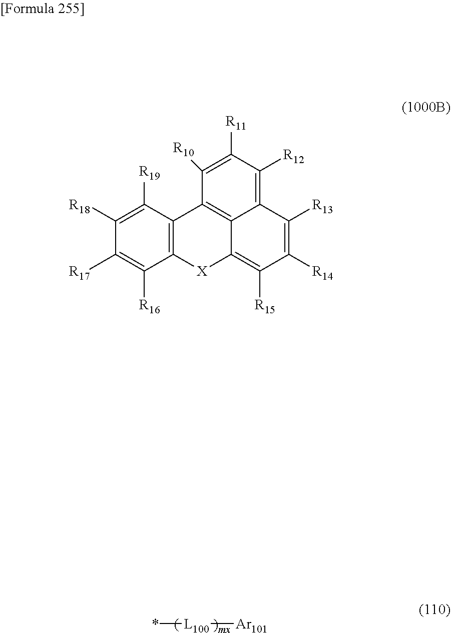

In the formula (1000B):
X is an oxygen atom or a sulfur atom;
at least one combination of adjacent two or more of R₁₀ to R₁₉ are mutually bonded to form a substituted or unsubstituted monocyclic ring, mutually bonded to form a substituted or unsubstituted fused ring, or not mutually bonded; R₁₀ to R₁₉ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR802, a halogen atom, a nitro group, a substituted or unsubstituted aryl group having 6 to 50 ring carbon atoms, a substituted or unsubstituted heterocyclic group having 5 to 50 ring atoms, or a group represented by the formula (110);
at least one of R₁₀ to R₁₉ is a group represented by the formula (110);
when a plurality of groups represented by the formula (110) are present, the plurality of groups represented by the formula (110) are mutually the same or different;
L₁₀₀ is a single bond, a substituted or unsubstituted arylene group having 6 to 50 ring carbon atoms, or a substituted or unsubstituted divalent heterocyclic group having 5 to 50 ring atoms;
mx is 1, 2, or 3;
when two or more L₁₀₀ are present, the two or more L₁₀₀ are mutually the same or different;
Ar₁₀₀ is a substituted or unsubstituted aryl group having three or more rings, or a substituted or unsubstituted heterocyclic group having two or more aromatic rings and one or more heterocycles;
Ar₁₀₀ contains no anthracene ring;
when two or more Ar₁₀₀ are present, the two or more Ar₁₀₀ are mutually the same or different; and
* in the formula (110) represents a bonding position.
R₉₀₁, R₉₀₂, R₉₀₃, R₉₀₄, R₉₀₅, R₉₀₆, R₉₀₇, R₈₀₁ and R₈₀₂ in the first compound represented by the formula (1000B) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In the formula (1000B), X is preferably an oxygen atom.

The compound represented by the formula (1000B) is preferably a compound that has at least one group represented by the formula (110) and is represented by a formula (100) below.

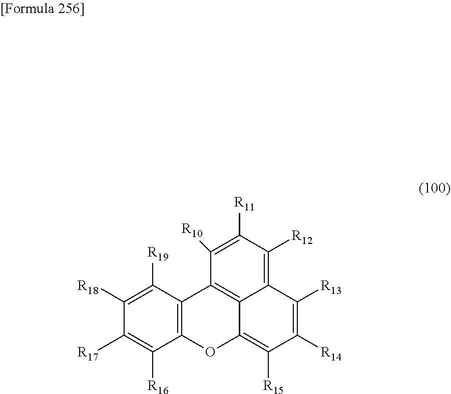

In the formula (100): R₁₀ to R₁₉ each independently represent the same as R₁₀ to R₁₉ in the formula (1000B); and Ar₁₀₀, L₁₀₀ and mx respectively represent the same as Ar₁₀₀, L₁₀₀ and mx in the formula (110).

The compound represented by the formula (1000B) is also preferably a compound represented by a formula (101) or (102) below.

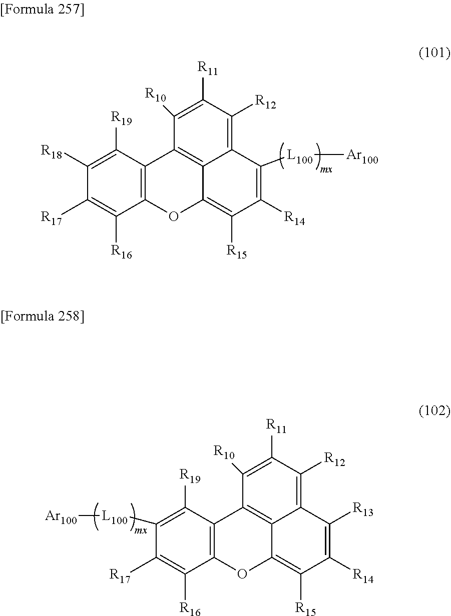

In the formulae (101) and (102): R₁₀ to R₁₉ each independently represent the same as R₁₀ to R₁₉ in the formula (1000B); and Ar₁₀₀, L₁₀₀ and mx respectively represent the same as Ar₁₀₀, L₁₀₀ and mx in the formula (110).

In the formula (1000B), R₁₀ to R₁₉ not being the group represented by the formula (110) are preferably each independently a hydrogen atom, a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formula (1000B), R₁₀ to R₁₉ not being the group represented by the formula (110) are each preferably a hydrogen atom.

In the formula (1000B), L₁₀₀ is preferably a single bond or an arylene group having three or less substituted or unsubstituted benzene rings.

In the formula (1000B), L₁₀₀ is preferably not a substituted or unsubstituted anthrylene group.

In the formula (1000B), L₁₀₀ is also preferably a single bond.

In the formula (1000B), the group represented by -(L₁₀₀)ₘₓ- in the formula (110) is also preferably a group represented by any one of formulae (111) to (120) below.

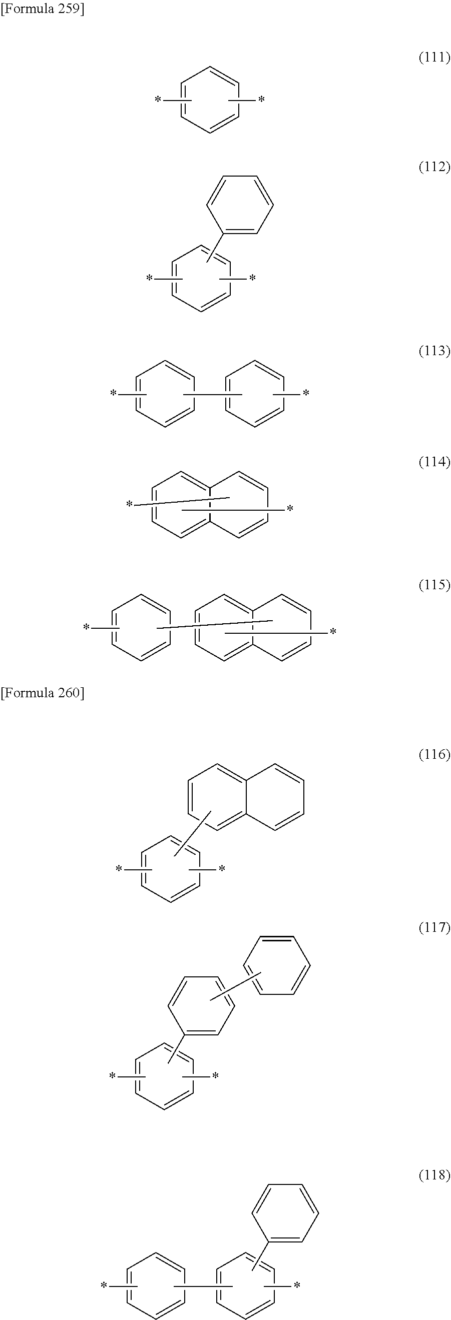

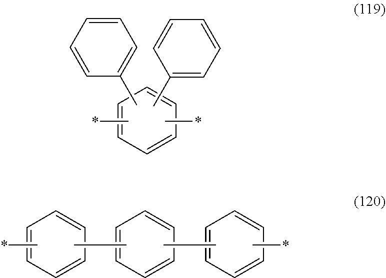

In the formulae (111) to (120), * each represent a bonding position.

The group represented by -(L₁₀₀)ₘₓ- in the formula (110) is preferably a group represented by the formula (111) or (112).

In the formula (1000B), Ar₁₀₀ is preferably an aryl group in which at least four substituted or unsubstituted benzene rings are fused.

In the formula (1000B), Ar₁₀₀ is preferably an aryl group in which four substituted or unsubstituted benzene rings are fused or an aryl group in which five substituted or unsubstituted benzene rings are fused.

In the formula (1000B): Ar₁₀₀ is preferably a group represented by a formula (1100), a formula (1200), a formula (1300), a formula (1400), a formula (1500), a formula (1600), a formula (1700) or a formula (1800) below.

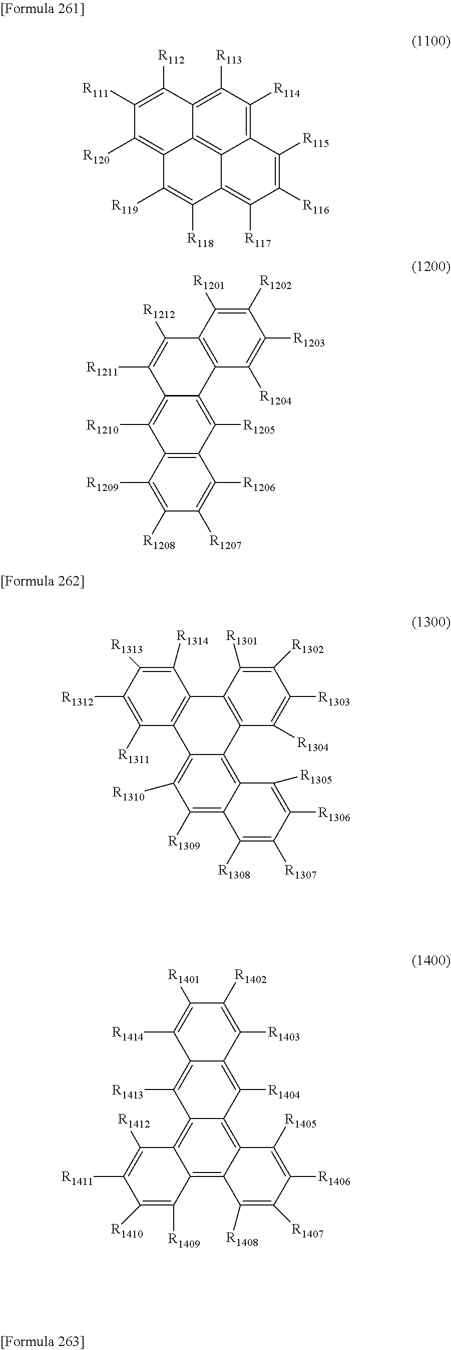

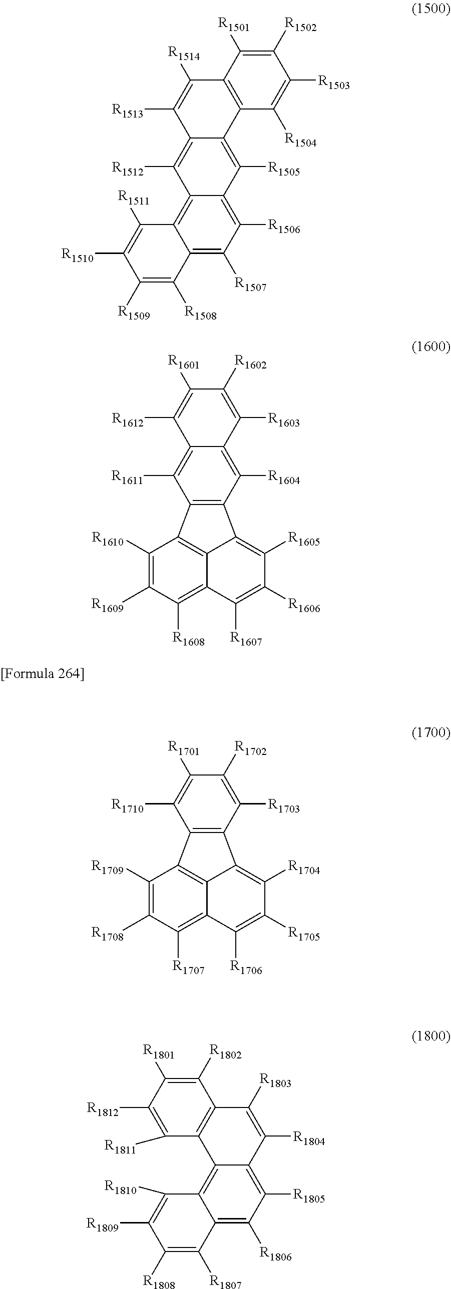

In the formula (1100), one of R₁₁₁ to R₁₂₀ is a bond;
in the formula (1200), one of R₁₂₀₁ to R₁₂₁₂ is a bond;
in the formula (1300), one of R₁₃₀₁ to R₁₃₁₄ is a bond;
in the formula (1400), one of R₁₄₀₁ to R₁₄₁₄ is a bond;
in the formula (1500), one of R₁₅₀₁ to R₁₅₁₄ is a bond;
in the formula (1600), one of R₁₆₀₁ to R₁₆₁₂ is a bond;
in the formula (1700), one of R₁₇₀₁ to R₁₇₁₀ is a bond;
in the formula (1800), one of R₁₈₀₁ to R₁₈₁₂ is a bond; and
R₁₁₁ to R₁₂₀ not being the bond, R₁₂₀₁ to R₁₂₁₂ not being the bond, R₁₃₀₁ to R₁₃₁₄ not being the bond, R₁₄₀₁ to R₁₄₁₄ not being the bond, R₁₅₀₁ to R₁₅₁₄ not being the bond, R₁₆₀₁ to R₁₆₁₂ not being the bond, R₁₇₀₁ to R₁₇₁₀ not being the bond, and R₁₈₀₁ to R₁₈₁₂ not being the bond are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR802, a halogen atom, a nitro group, a substituted or unsubstituted aryl group having 6 to 50 ring carbon atoms, or a substituted or unsubstituted heterocyclic group having 5 to 50 ring atoms.

The group represented by the formula (1100) in which R₁₁₁ is the bond is represented by a formula (1112) below. The group represented by the formula (1100) in which R₁₂₀ is the bond is represented by a formula (1113) below. The group represented by the formula (1100) in which R₁₁₉ is the bond is represented by a formula (1114) below.

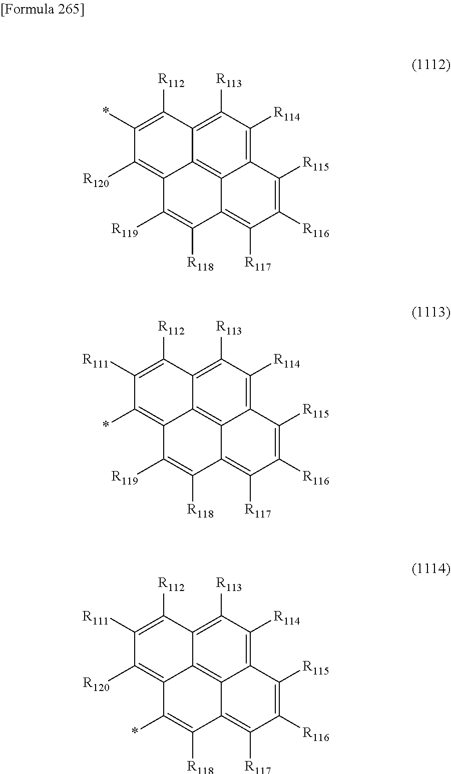

In the formulae (1112), (1113), and (1114):
R₁₁₁ to R₁₂₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR802, a halogen atom, a nitro group, a substituted or unsubstituted aryl group having 6 to 50 ring carbon atoms, or a substituted or unsubstituted heterocyclic group having 5 to 50 ring atoms; and
* in the formulae (1112) to (1114) each represent a bonding position.

In the formulae (1100), (1200), (1300), (1400), (1500), (1600), (1700) and (1800), R₁₁₁ to R₁₂₀ not being the bond, R₁₂₀₁ to R₁₂₁₂ not being the bond, R₁₃₀₁ to R₁₃₁₄ not being the bond, R₁₄₀₁ to R₁₄₁₄ not being the bond, R₁₅₀₁ to R₁₅₁₄ not being the bond, R₁₆₀₁ to R₁₆₁₂ not being the bond, R₁₇₀₁ to R₁₇₁₀ not being the bond, and R₁₈₀₁ to R₁₈₁₂ not being the bond are preferably each independently a hydrogen atom, a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formulae (1100), (1200), (1300), (1400), (1500), (1600), (1700) and (1800), R₁₁₁ to R₁₂₀ not being the bond, R₁₂₀₁ to R₁₂₁₂ not being the bond, R₁₃₀₁ to R₁₃₁₄ not being the bond, R₁₄₀₁ to R₁₄₁₄ not being the bond, R₁₅₀₁ to R₁₅₁₄ not being the bond, R₁₆₀₁ to R₁₆₁₂ not being the bond, R₁₇₀₁ to R₁₇₁₀ not being the bond, and
R₁₈₀₁ to R₁₈₁₂ not being the bond are preferably each a hydrogen atom.

The compound represented by the formula (1000B) preferably includes only one benzoxanthene ring in a molecule.

The first compound is also preferably a compound obtained by substituting a benzoxanthene ring with a benzothioxanthene ring in a compound represented by each of the formulae (100), (101), and (102).

### Compound Represented by Formula (17X-1)

In an exemplary arrangement of the organic EL device according to the exemplary embodiment, the first compound is a compound represented by a formula (17X-1) below.

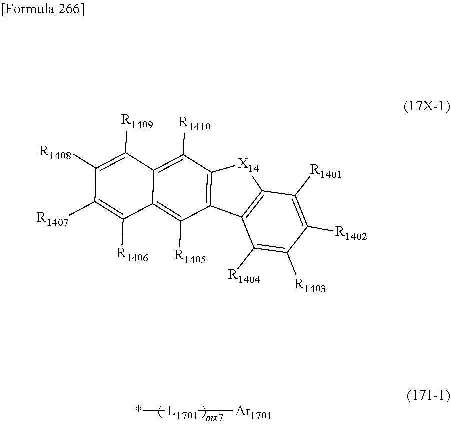

In the formula (17X-1):
X₁₄ is an oxygen atom or a sulfur atom;
at least one combination of adjacent two or more of R₁₄₀₁ to R₁₄₀₄ are mutually bonded to form a substituted or unsubstituted monocyclic ring, mutually bonded to form a substituted or unsubstituted fused ring, or not mutually bonded;
at least one combination of adjacent two or more of R₁₄₀₅ to R₁₄₁₀ are mutually bonded to form a substituted or unsubstituted monocyclic ring, mutually bonded to form a substituted or unsubstituted fused ring, or not mutually bonded;
R₁₄₀₁ to R₁₄₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (171-1);
at least one of R₁₄₀₁ to R₁₄₁₀ is a group represented by the formula (171-1);
when a plurality of groups represented by the formula (171-1) are present, the plurality of groups represented by the formula (171-1) are mutually the same or different;
L₁₇₀₁ is a single bond, a substituted or unsubstituted arylene group having 6 to 50 ring carbon atoms, or a substituted or unsubstituted divalent heterocyclic group having 5 to 50 ring atoms;
Ar₁₇₀₁ is a substituted or unsubstituted aryl group having 6 to 50 ring carbon atoms, or a substituted or unsubstituted heterocyclic group having 5 to 50 ring atoms;
mx7 is 0, 1, 2, 3, 4, or 5;
when two or more L₁₇₀₁ are present, the two or more L₁₇₀₁ are mutually the same or different;
when two or more Ar₁₇₀₁ are present, the two or more Ar₁₇₀₁ are mutually the same or different;
R₉₀₁ to R₉₀₅, R₈₀₁ and R₈₀₂ each independently represent the same as R₉₀₁ to R₉₀₅, R₈₀₁ and R₈₀₂ in the formula (1000B); and
* in the formula (171-1) represents a bonding position to a ring represented by the formula (17X-1).

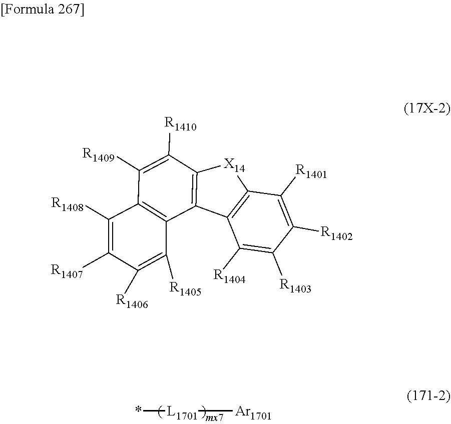

In the formula (17X-2): R₁₄₀₁ to R₁₄₁₀ and X₁₄ each independently represent the same as R₁₄₀₁ to R₁₄₁₀ and X₁₄ in the formula (17X-1);
the group represented by the formula (171-2) represents the same as a group represented by the formula (171-1); and L₁₇₀₁, Ar₁₇₀₁ and mx7 in the formula (171-2) each independently represent the same as L₁₇₀₁, Ar₁₇₀₁ and mx7 in the formula (171-1);
when a plurality of groups represented by the formula (171-2) are present, the plurality of groups represented by the formula (171-2) are mutually the same or different; and
* in the formula (171-2) represents a bonding position to a ring represented by the formula (17X-2).

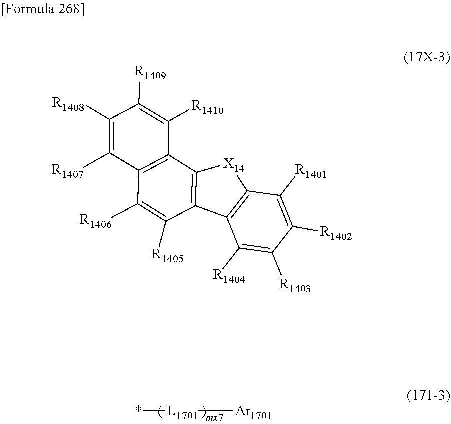

In the formula (17X-3): R₁₄₀₁ to R₁₄₁₀ and X₁₄ each independently represent the same as R₁₄₀₁ to R₁₄₁₀ and X₁₄ in the formula (17X-1);
the group represented by the formula (171-3) represents the same as a group represented by the formula (171-1); and L₁₇₀₁, Ar₁₇₀₁ and mx7 in the formula (171-3) each independently represent the same as L₁₇₀₁, Ar₁₇₀₁ and mx7 in the formula (171-1);
when a plurality of groups represented by the formula (171-3) are present, the plurality of groups represented by the formula (171-3) are mutually the same or different; and
* in the formula (171-3) represents a bonding position to a ring represented by the formula (17X-3).

In the formulae (17X-1), (17X-2) and (17X-3), X₁₄ is preferably an oxygen atom.

### Compound Represented by Formula (18)

In an exemplary arrangement of the organic EL device according to the exemplary embodiment, the first compound is a compound represented by a formula (18) below.

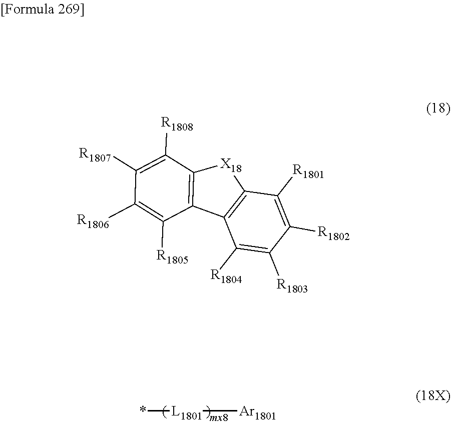

In the formula (18):
X₁₈ is an oxygen atom or a sulfur atom;
at least one combination of adjacent two or more of R₁₈₀₁ to R₁₈₀₄ are mutually bonded to form a substituted or unsubstituted monocyclic ring, mutually bonded to form a substituted or unsubstituted fused ring, or not mutually bonded;
at least one combination of adjacent two or more of R₁₈₀₅ to R₁₈₀₈ are mutually bonded to form a substituted or unsubstituted monocyclic ring, mutually bonded to form a substituted or unsubstituted fused ring, or not mutually bonded;
R₁₈₀₁ to R₁₈₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR802, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (18X);
at least one of R₁₈₀₁ to R₁₈₀₈ is a group represented by the formula (18X);
when a plurality of groups represented by the formula (18X) are present, the plurality of groups represented by the formula (18X) are mutually the same or different;
L₁₈₀₁ is a single bond, a substituted or unsubstituted arylene group having 6 to 50 ring carbon atoms, or a substituted or unsubstituted divalent heterocyclic group having 5 to 50 ring atoms;
Ar₁₈₀₁ is a substituted or unsubstituted aryl group having 6 to 50 ring carbon atoms, or a substituted or unsubstituted heterocyclic group having 5 to 50 ring atoms;
mx8 is 0, 1, 2, 3, 4, or 5;
when two or more L₁₈₀₁ are present, the two or more L₁₈₀₁ are mutually the same or different;
when two or more Ar₁₈₀₁ are present, the two or more Ar₁₈₀₁ are mutually the same or different;
R₉₀₁ to R₉₀₅, R₈₀₁ and R₈₀₂ each independently represent the same as R₉₀₁ to R₉₀₅, R₈₀₁ and R₈₀₂ in the formula (1000B); and
* in the formula (18X) represents a bonding position to a ring represented by the formula (18).

In the formula (18), X₁₈ is preferably an oxygen atom.

In the first compound, the groups specified to be “substituted or unsubstituted” are each preferably an “unsubstituted” group.

In the organic EL device of each exemplary embodiment, also preferably, the second host material has, in a molecule, a linking structure including a benzene ring and a naphthalene ring linked to each other with a single bond, in which the benzene ring and the naphthalene ring in the linking structure are each independently fused or not fused with a further monocyclic ring or fused ring, and the benzene ring and the naphthalene ring in the linking structure are further linked to each other by cross-linking at at least one site other than the single bond.

When the second host material has the linking structure including such cross-linking, deterioration in chromaticity of the organic EL device is expected to be inhibited.

The second host material in the above case is only required to have a linking structure as the minimum unit in a molecule, the linking structure including a benzene ring and a naphthalene ring linked to each other with a single bond (occasionally referred to as a benzene-naphthalene linking structure), the linking structure being as represented by a formula (X1) or a formula (X2) below. Further, the benzene ring may be fused with a monocyclic ring or fused ring, and the naphthalene ring may be fused with a monocyclic ring or fused ring. For instance, also in a case where the second host material has, in a molecule, a linking structure including a naphthalene ring and a naphthalene ring linked to each other with a single bond (occasionally referred to as a naphthalene-naphthalene linking structure) and being as represented by a formula (X3), a formula (X4), or a formula (X5) below, the naphthalene-naphthalene linking structure is regarded as including the benzene-naphthalene linking structure since one of the naphthalene rings includes a benzene ring.

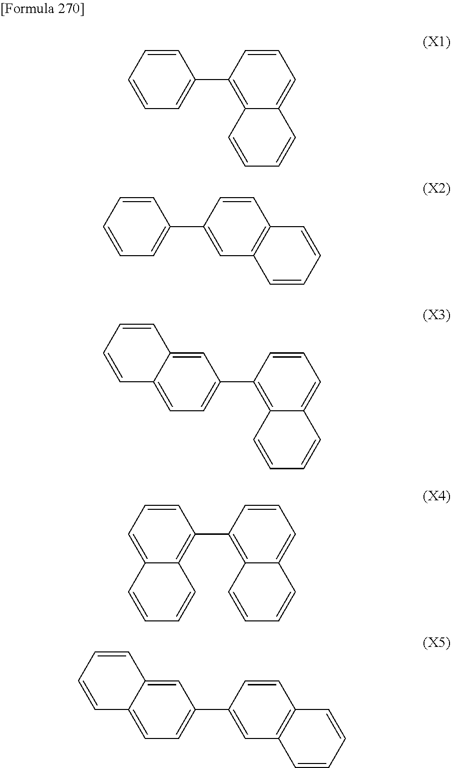

In the organic EL device according to the exemplary embodiment, the cross-linking also preferably includes a double bond. Specifically, the second host material also preferably has a structure in which the benzene ring and the naphthalene ring are further linked to each other at any other site than the single bond by the cross-linking structure including a double bond.

Assuming that the benzene ring and the naphthalene ring in the benzene-naphthalene linking structure are further linked to each other at at least one site other than the single bond by cross-linking, for instance, a linking structure (fused ring) represented by a formula (X11) below is obtained in a case of the formula (X1), and a linking structure (fused ring) represented by a formula (X31) below is obtained in a case of the formula (X3).

Assuming that the benzene ring and the naphthalene ring in the benzene-naphthalene linking structure are further linked to each other at any other site than the single bond by cross-linking including a double bond, for instance, a linking structure (fused ring) represented by a formula (X12) below is obtained in a case of the formula (X1), a linking structure (fused ring) represented by a formula (X21) or formula (X22) below is obtained in a case of the formula (X2), a linking structure (fused ring) represented by a formula (X41) below is obtained in a case of the formula (X4), and a linking structure (fused ring) represented by a formula (X51) below is obtained in a case of the formula (X5).

Assuming that the benzene ring and the naphthalene ring in the benzene-naphthalene linking structure are further linked to each other at at least one site other than the single bond by cross-linking including a hetero atom (e.g., an oxygen atom), for instance, a linking structure (fused ring) represented by a formula (X13) below is obtained in a case of the formula (X1).

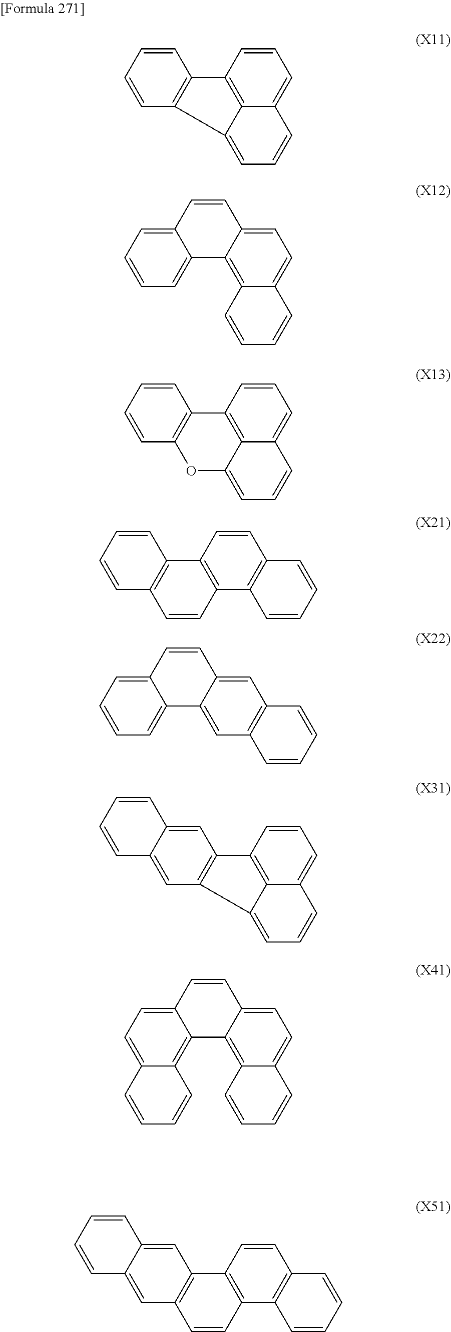

In the organic EL device according to the exemplary embodiment, also preferably, the second host material has, in a molecule, a biphenyl structure including a first benzene ring and a second benzene ring linked to each other with a single bond, and the first benzene ring and the second benzene ring in the biphenyl structure are further linked to each other by cross-linking at at least one site other than the single bond.

In the organic EL device according to the above exemplary embodiment, also preferably, the first benzene ring and the second benzene ring in the biphenyl structure are further linked to each other by the cross-linking at one site other than the single bond. When the second host material has the biphenyl structure including such cross-linking, deterioration in chromaticity of the organic EL device is expected to be inhibited.

In the organic EL device according to the exemplary embodiment, the cross-linking also preferably includes a double bond.

In the organic EL device according to the above exemplary embodiment, the cross-linking also preferably includes no double bond.

Also preferably, the first benzene ring and the second benzene ring in the biphenyl structure are further linked to each other by the cross-linking at two sites other than the single bond.

In the organic EL device according to the exemplary embodiment, also preferably, the first benzene ring and the second benzene ring in the biphenyl structure are further linked to each other by the cross-linking at two sites other than the single bond, and the cross-linking includes no double bond. When the second host material has the biphenyl structure including such cross-linking, deterioration in chromaticity of the organic EL device is expected to be inhibited.

For instance, assuming that the first benzene ring and the second benzene ring in the biphenyl structure represented by a formula (BP1) below are further linked to each other by cross-linking at at least one site other than the single bond, the biphenyl structure is exemplified by linking structures (fused rings) represented by formulae (BP11) to (BP15) below.

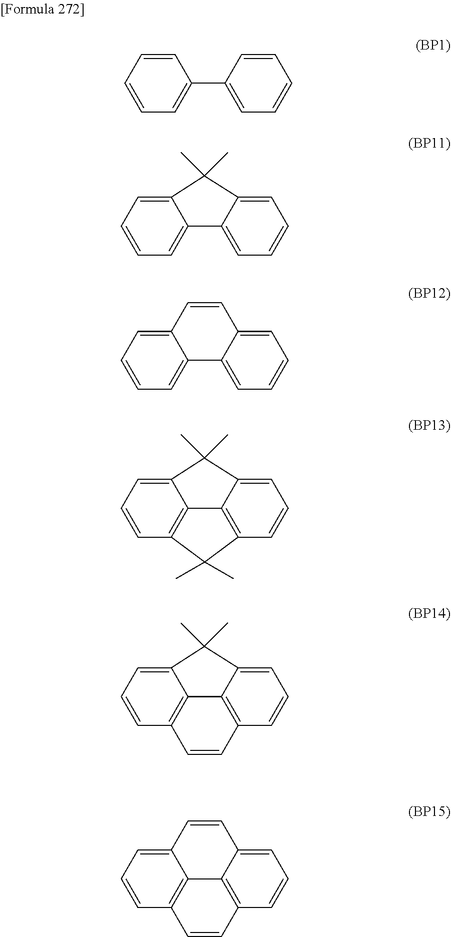

The formula (BP11) represents a linking structure in which the first benzene ring and the second benzene ring are linked to each other at one site other than the single bond by cross-linking including no double bond.

The formula (BP12) represents a linking structure in which the first benzene ring and the second benzene ring are linked to each other at one site other than the single bond by cross-linking including a double bond.

The formula (BP13) represents a linking structure in which the first benzene ring and the second benzene ring are linked to each other at two sites other than the single bond by cross-linking including no double bond.

The formula (BP14) represents a linking structure in which the first benzene ring and the second benzene ring are linked to each other by cross-linking including no double bond at one of two sites other than the single bond, and the first benzene ring and the second benzene ring are linked to each other by cross-linking including a double bond at the other of the two sites other than the single bond.

The formula (BP15) represents a linking structure in which the first benzene ring and the second benzene ring are linked to each other at two sites other than the single bond by cross-linking including a double bond.

In the first compound, the groups specified to be “substituted or unsubstituted” are each preferably an “unsubstituted” group.

### Method of Producing First Compound

The first compound usable for the organic EL device according to the exemplary embodiment can be produced by a known method. Further, the first compound can be produced based on a known method through a known alternative reaction using a known material(s) tailored for the target compound.

### Specific Examples of First Compound

Specific examples of the first compound usable for the organic EL device according to the exemplary embodiment include compounds below. However, the invention is not limited to the specific examples of the first compound.

In the specific examples of the compounds herein, D represents a deuterium atom, Me represents a methyl group, and tBu represents a tert-butyl group.

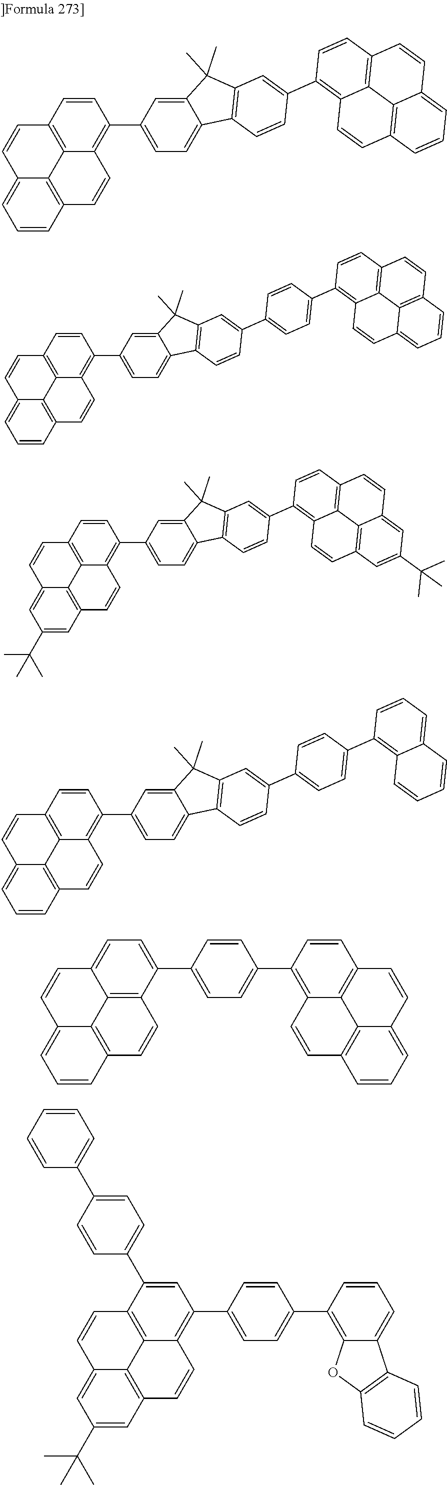

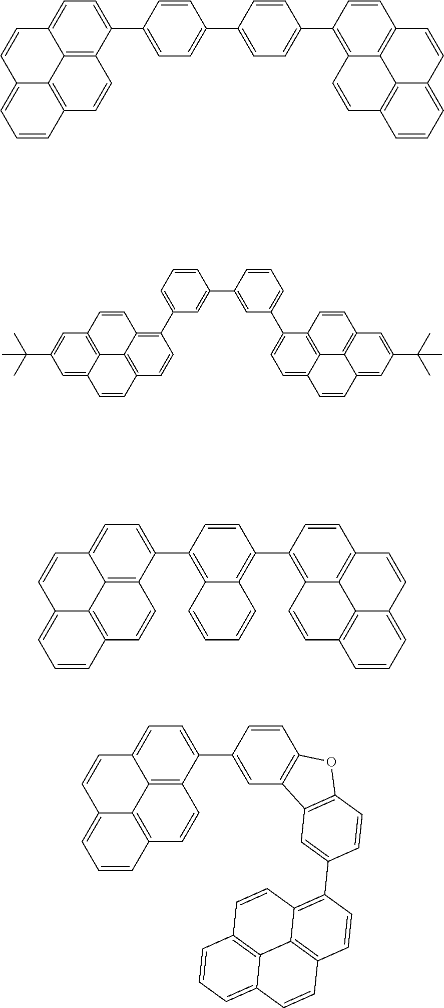

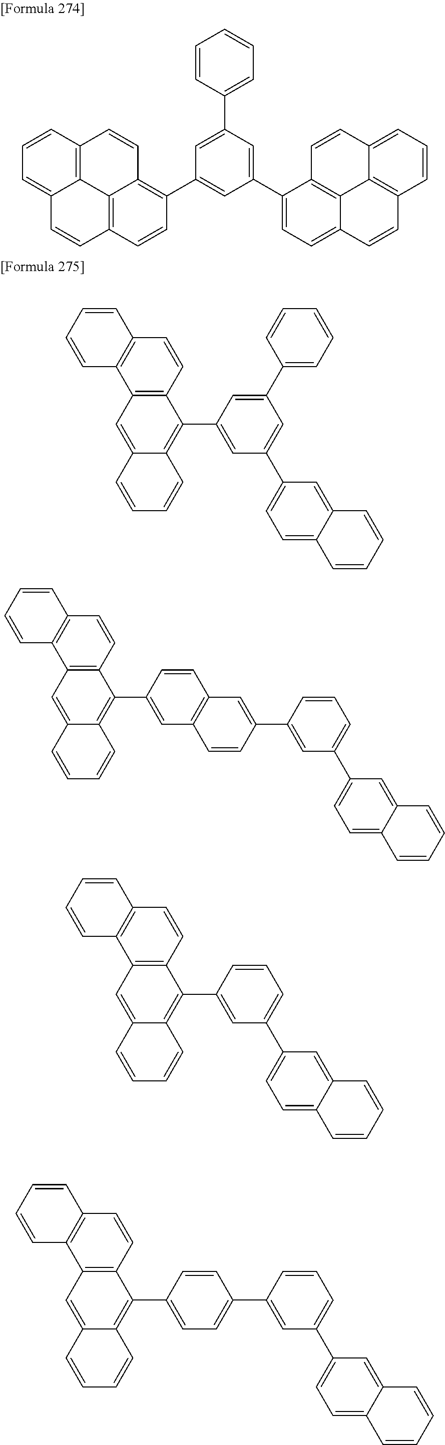

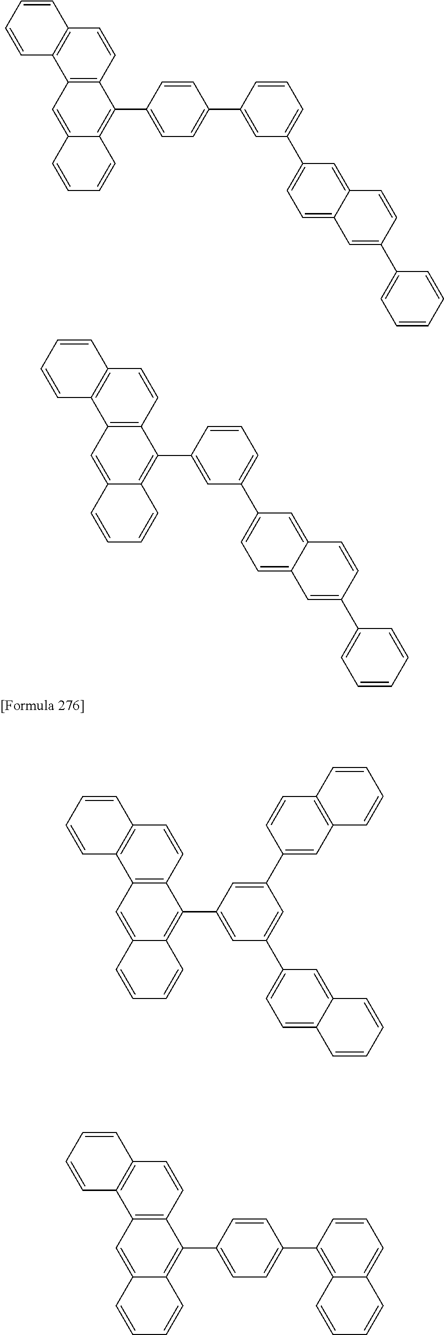

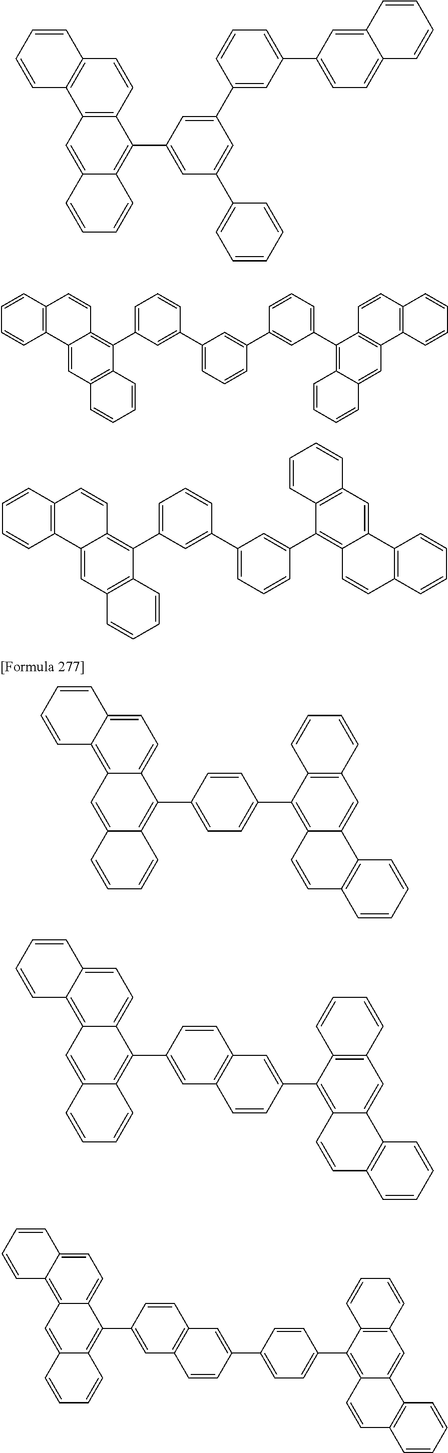

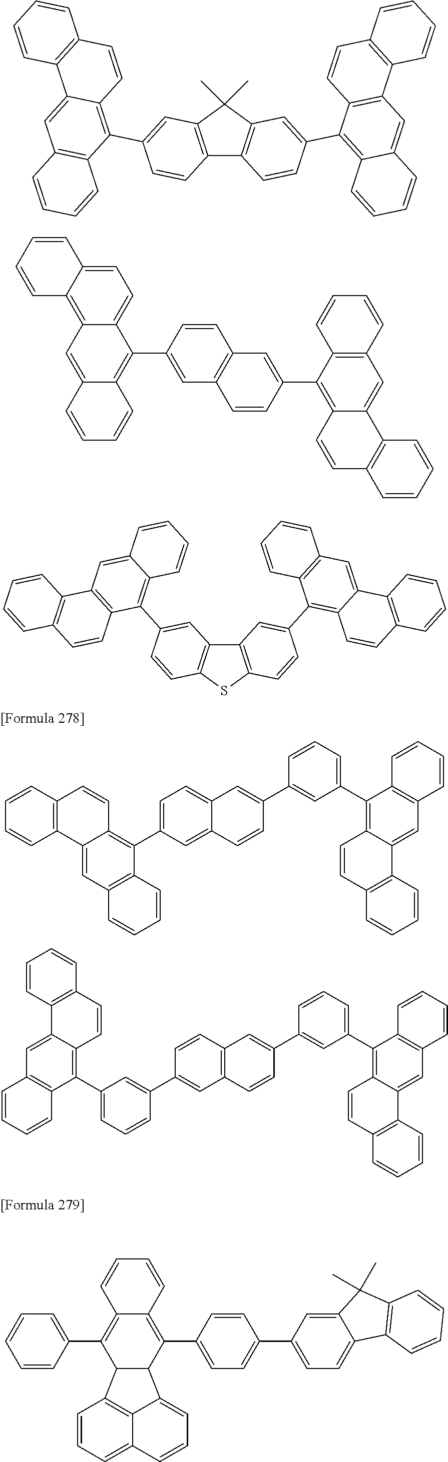

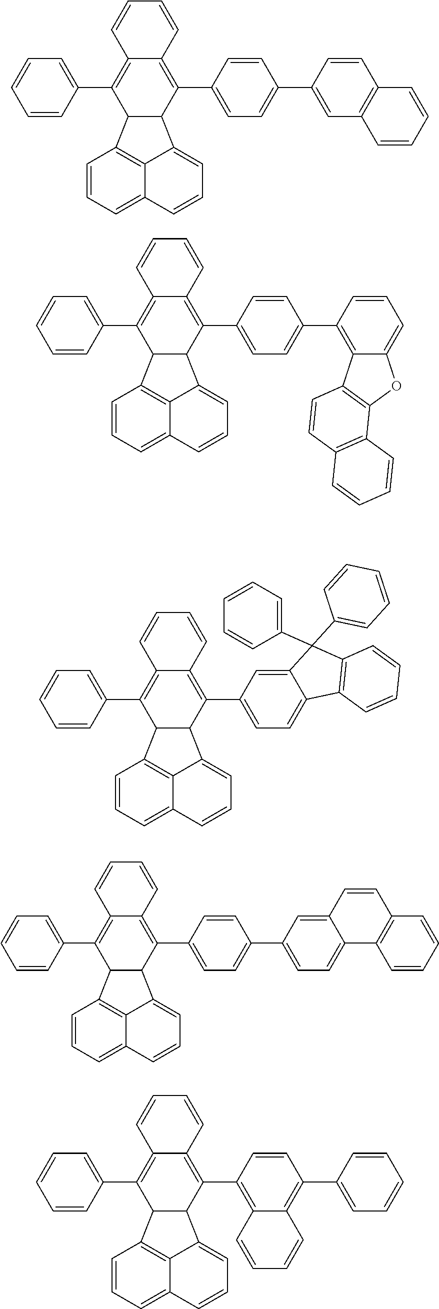

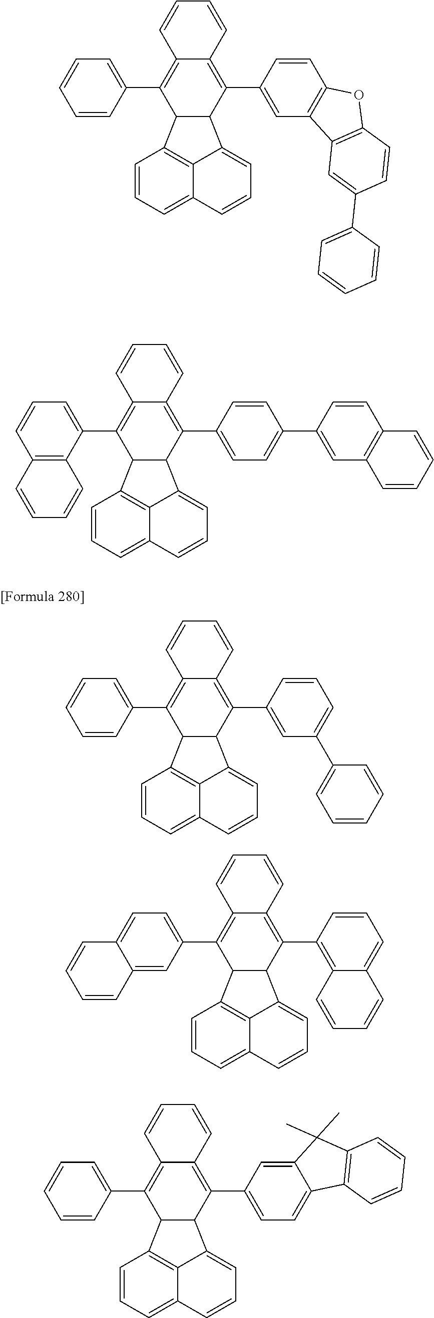

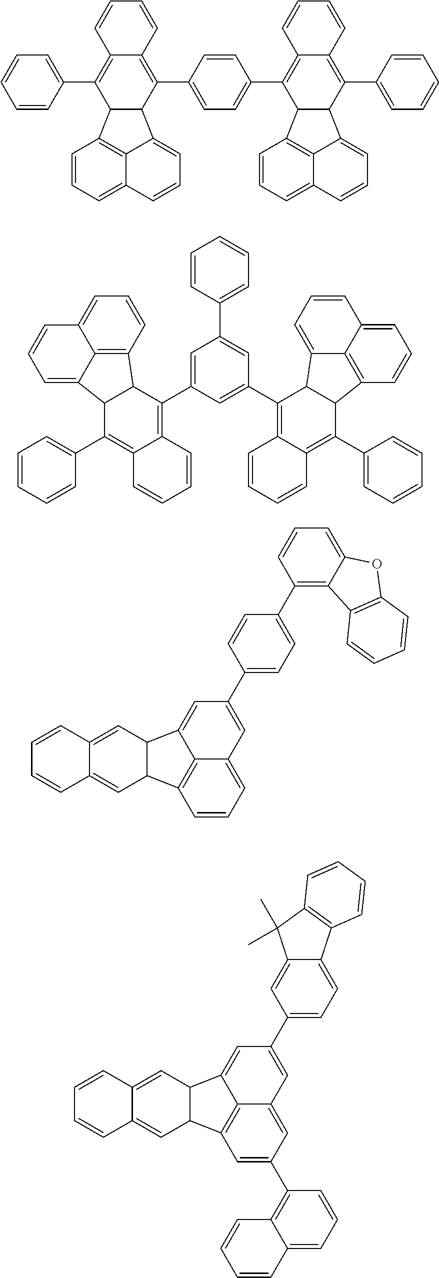

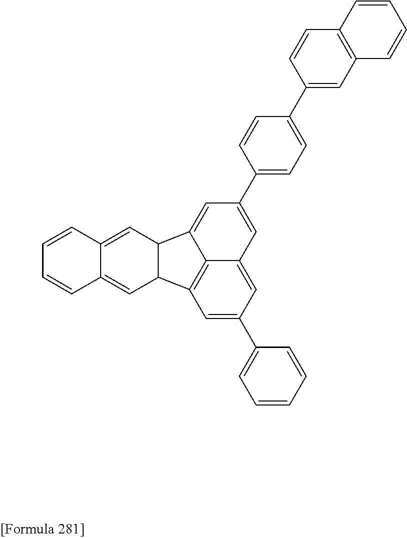 [SMILES: C1=c2ccccc2=CC2c3cc(-c4ccc(-c5ccc6ccccc6c5)cc4)cc4cc(-c5ccccc5)cc(c34)C12]

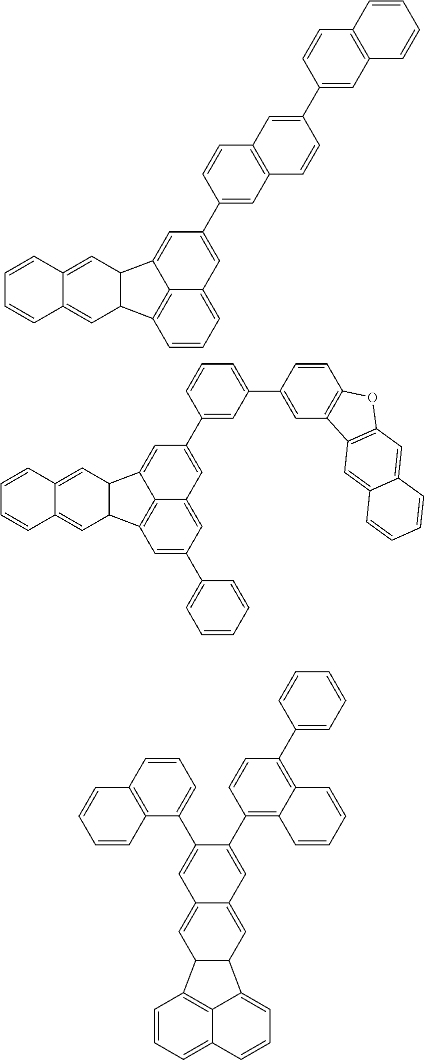

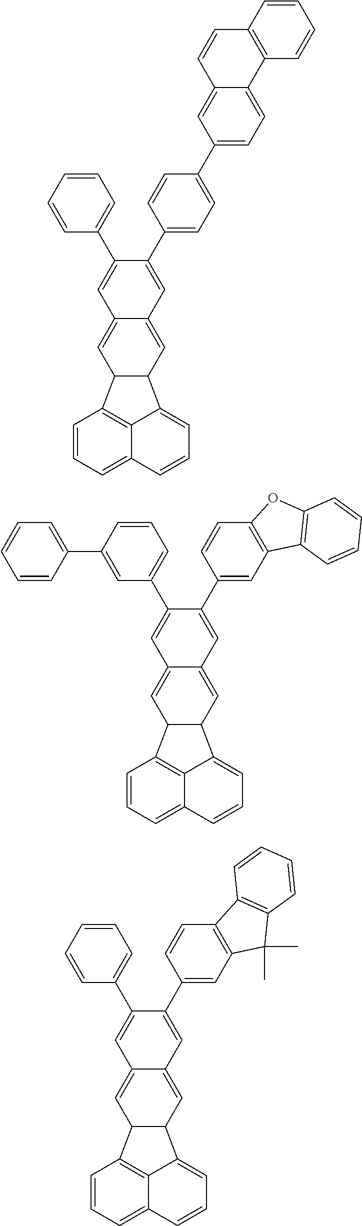

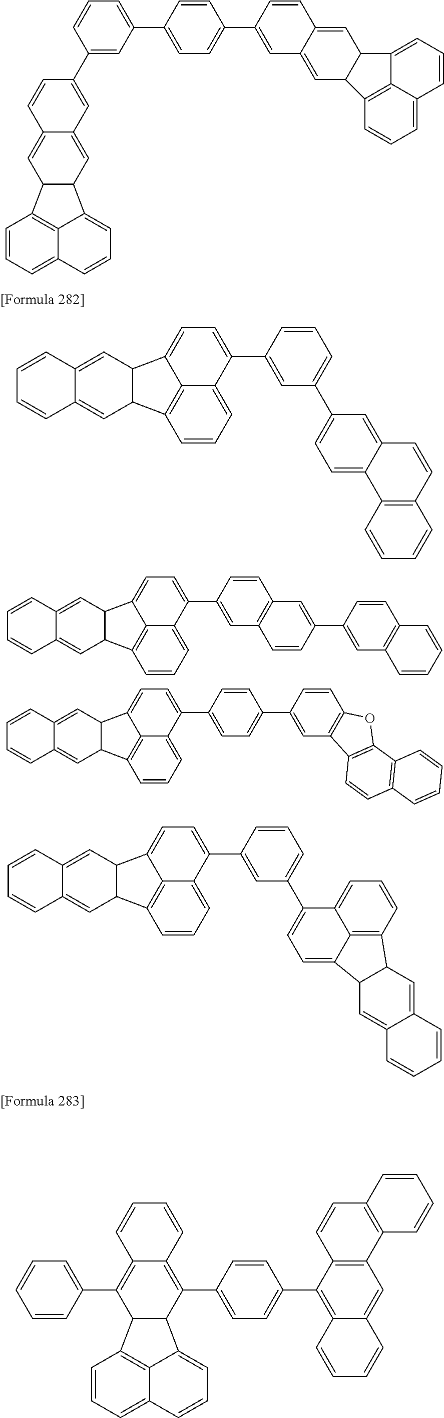

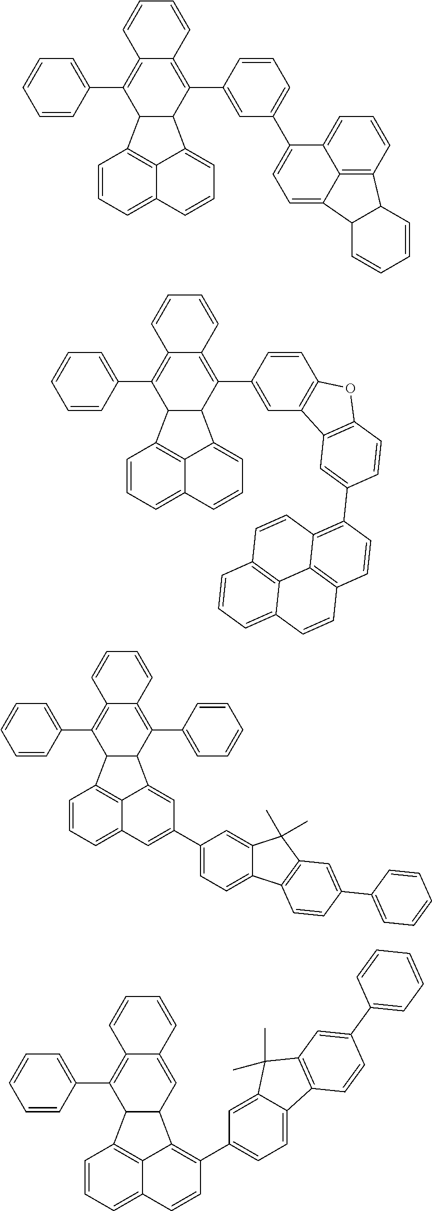

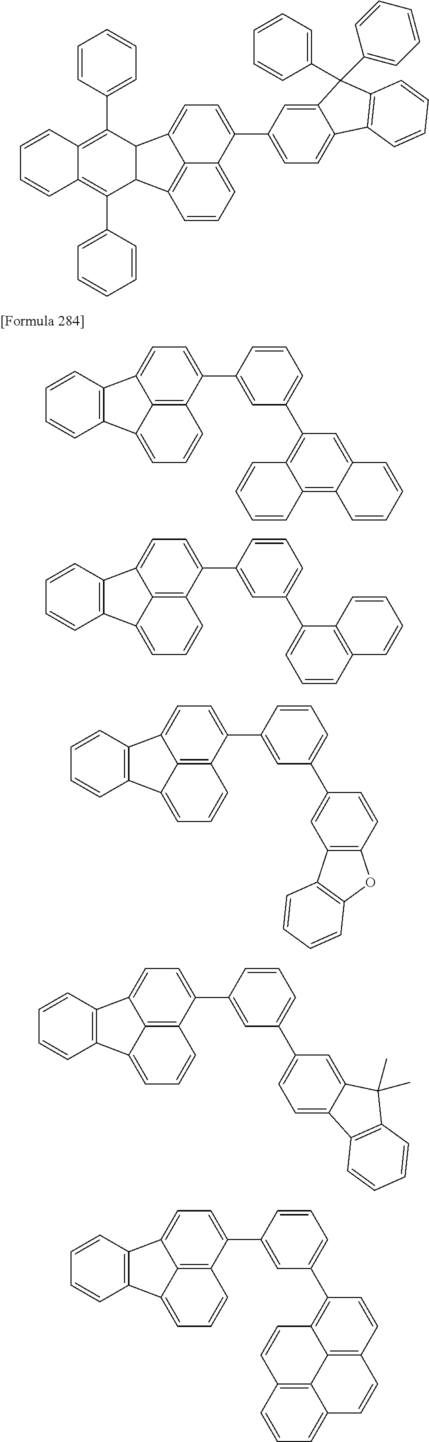

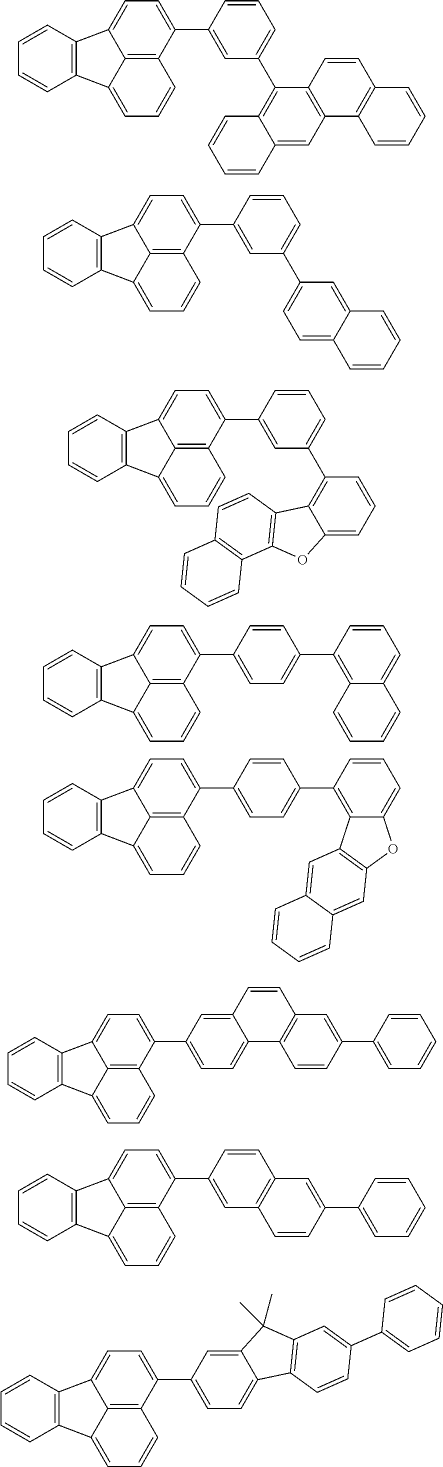

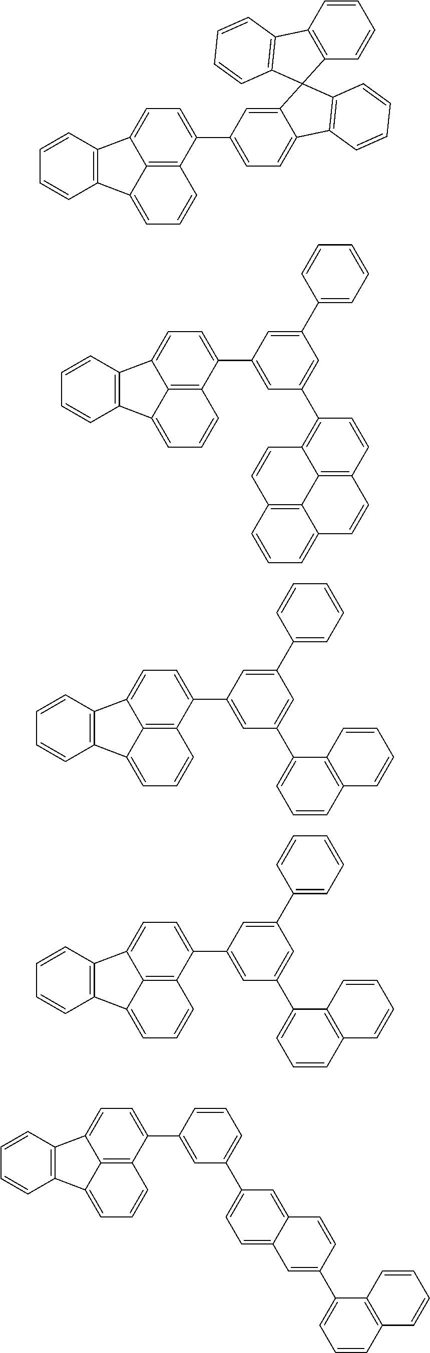

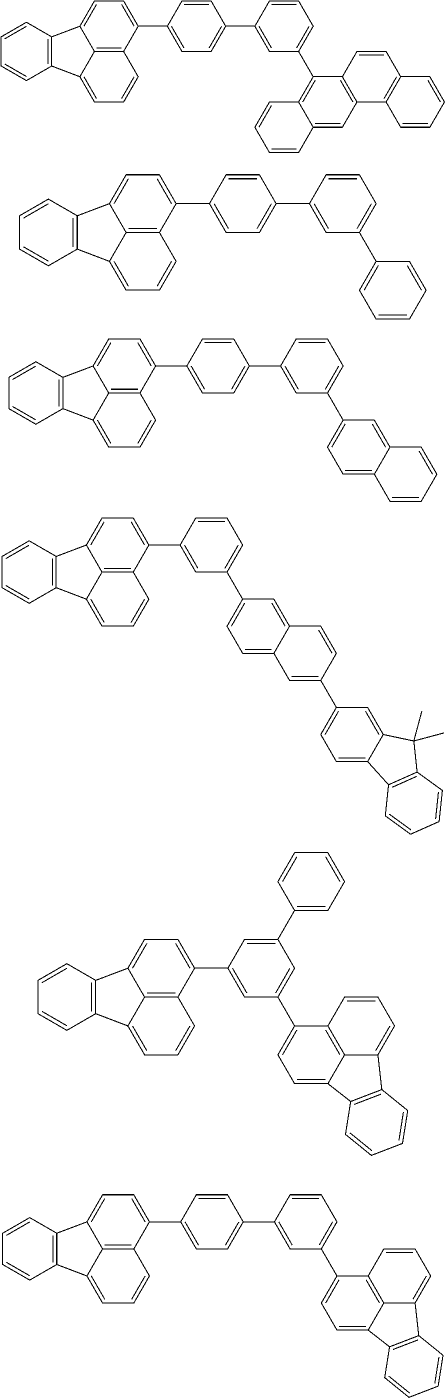

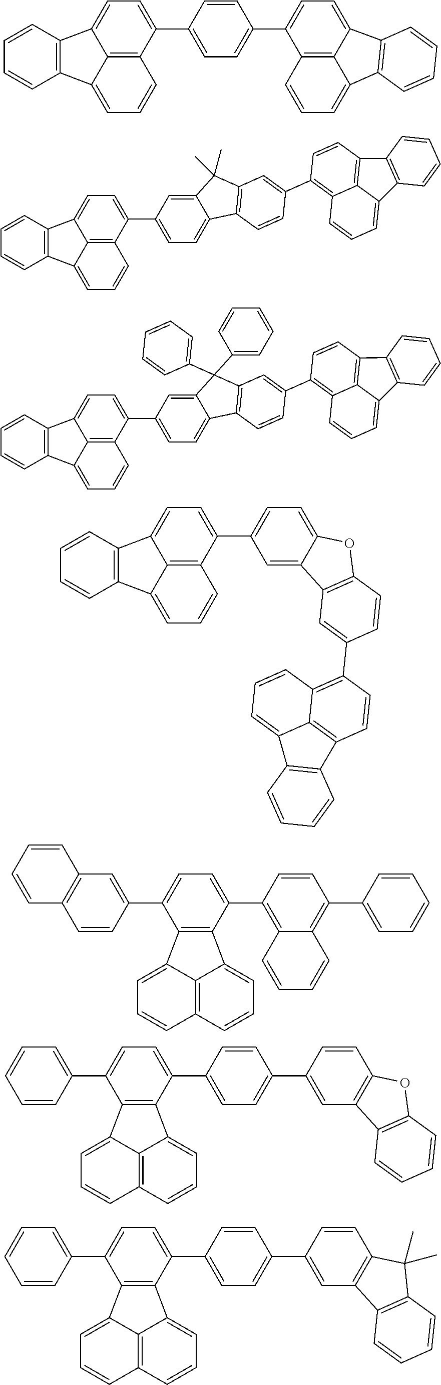

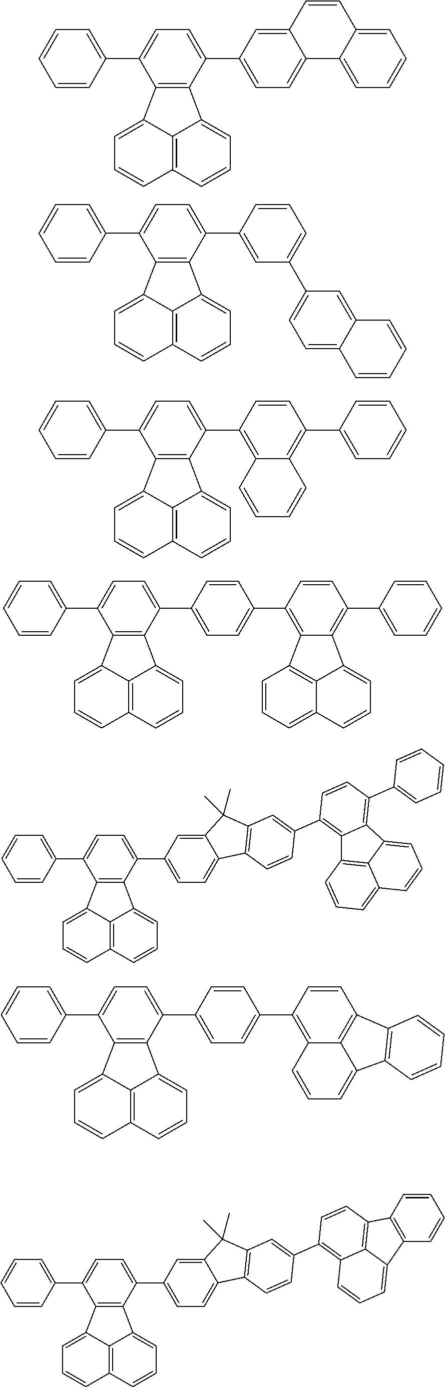

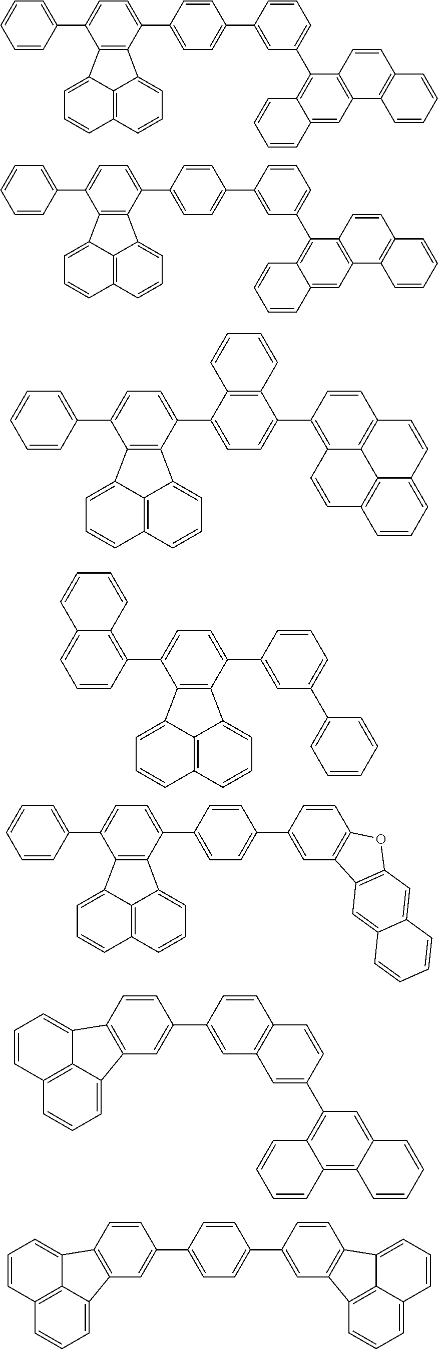

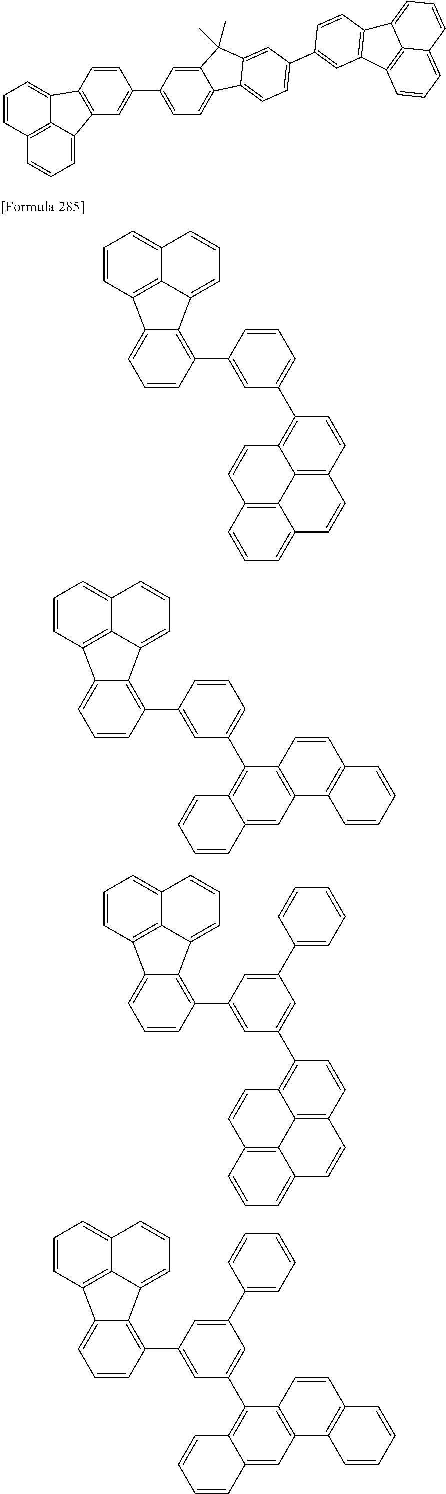

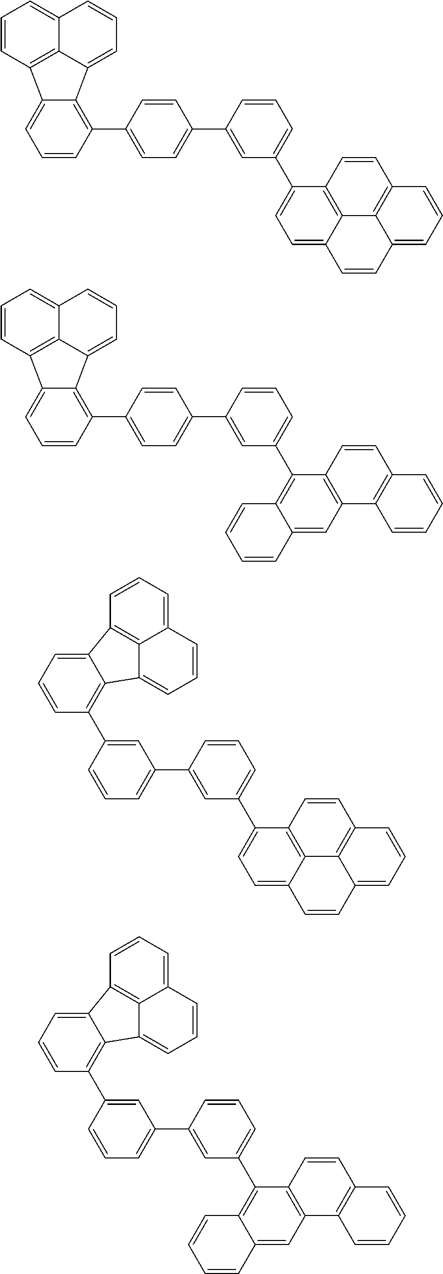

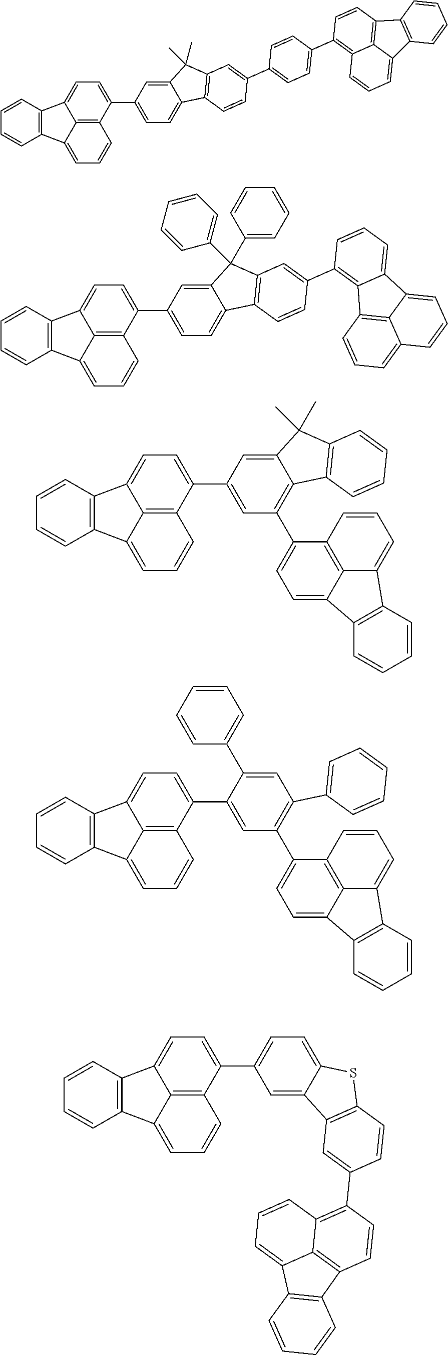

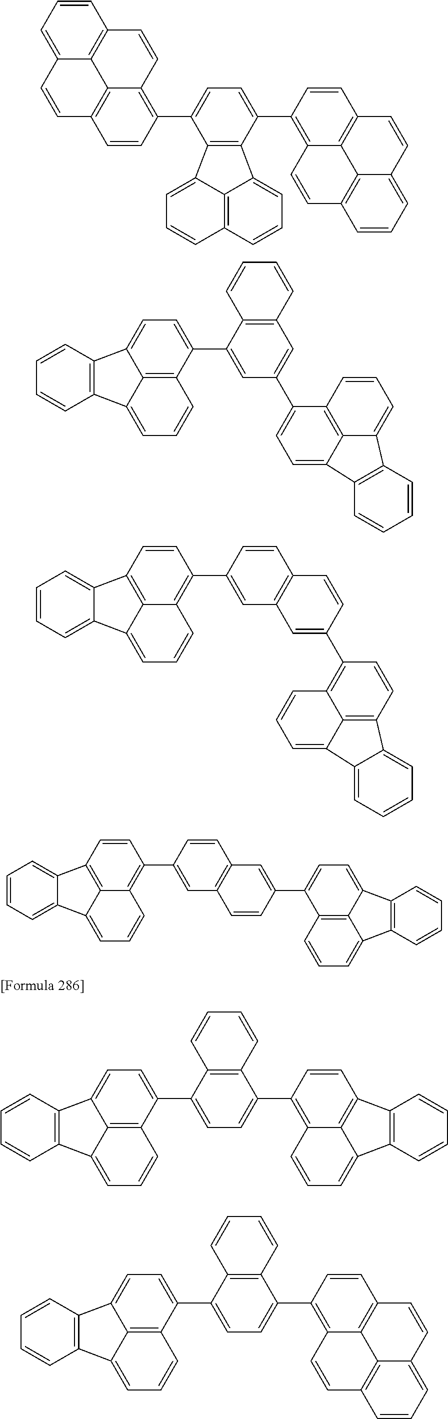

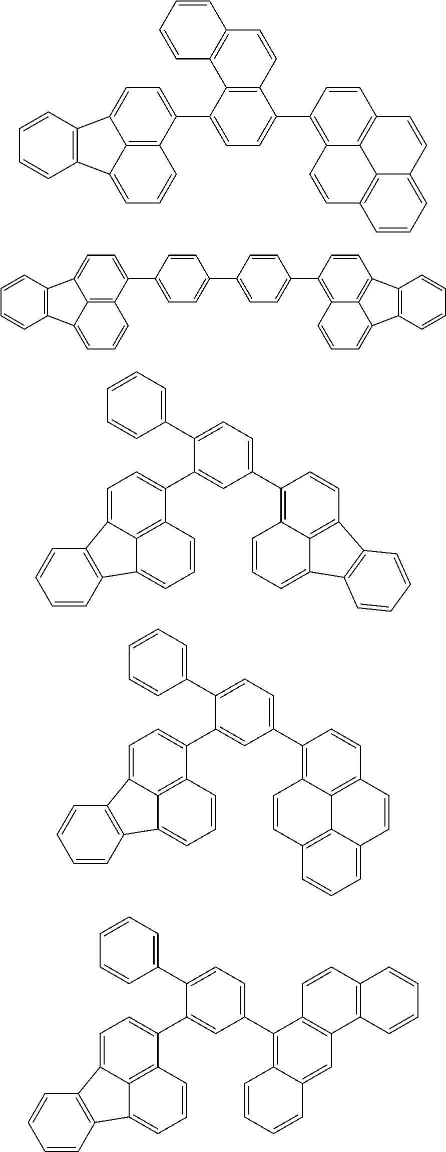

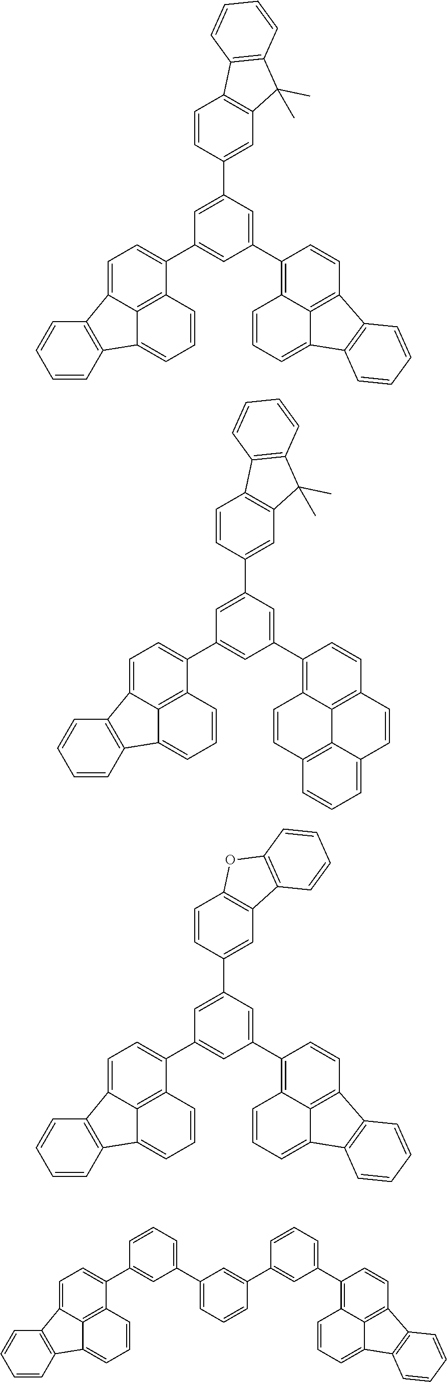

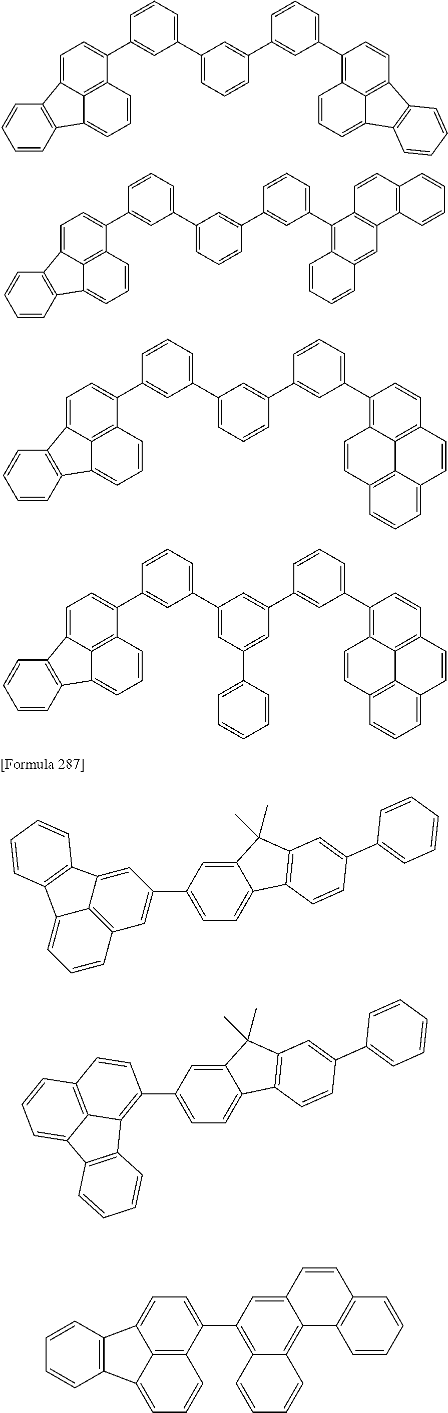

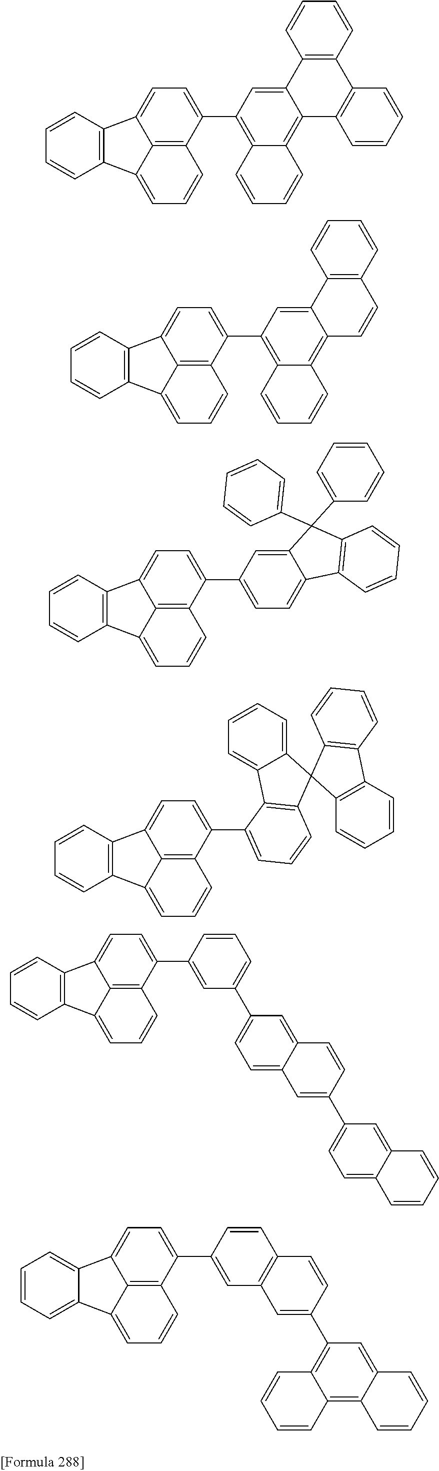

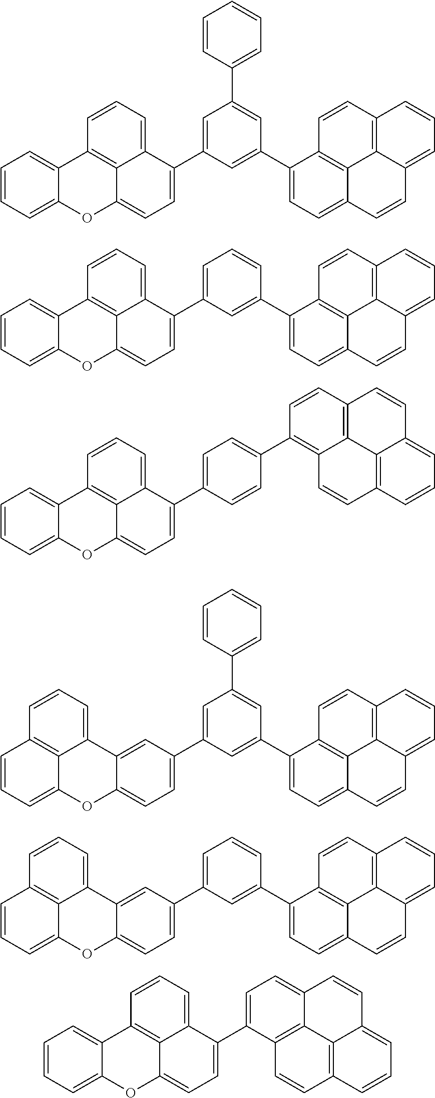

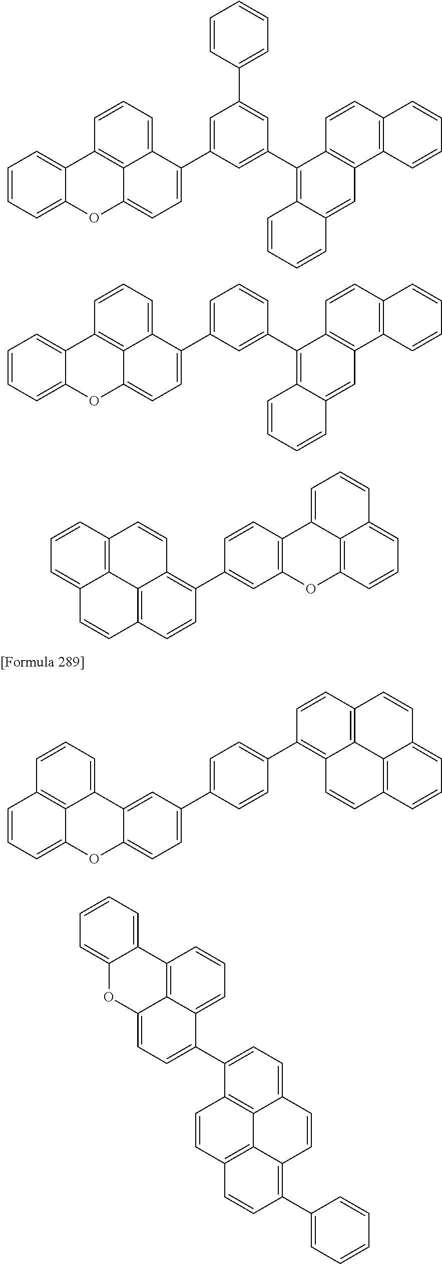

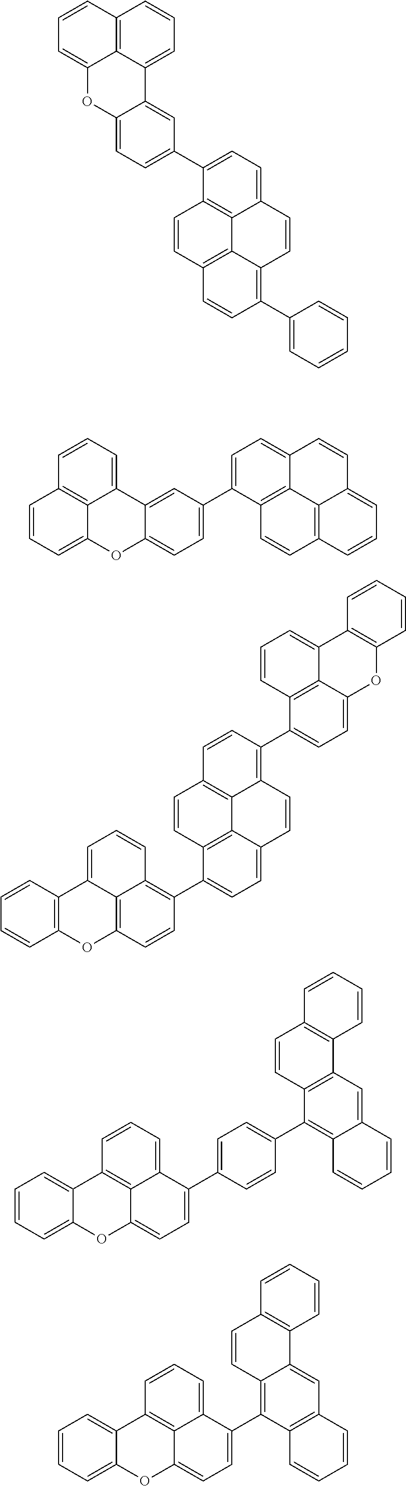

### Luminescent Compound

In an exemplary arrangement of the organic EL device according to the exemplary embodiment, a luminescent compound contained in the first emitting layer is a first luminescent compound and a luminescent compound contained in the second emitting layer is a second luminescent compound.

### Compound Represented by Formula (5)

In an exemplary arrangement of the organic EL device according to the exemplary embodiment, the luminescent compound is a compound represented by a formula (5) below.

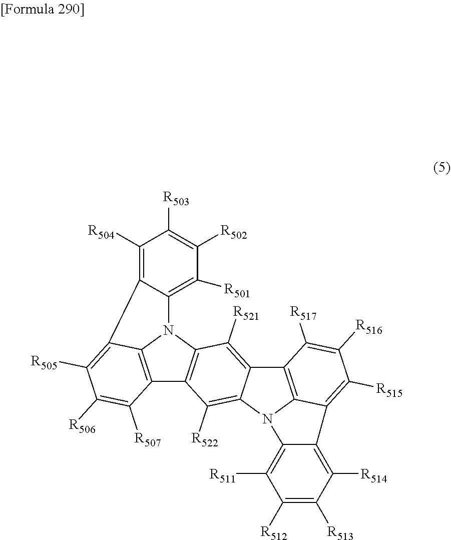

In the formula (5):
at least one combination of adjacent two or more of R₅₀₁ to R₅₀₇ and R₅₁₁ to R₅₁₇ are mutually bonded to form a substituted or unsubstituted monocyclic ring, mutually bonded to form a substituted or unsubstituted fused ring, or not mutually bonded,
R₅₀₁ to R₅₀₇ and R₅₁₁ to R₅₁₇ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms; and
R₅₂₁ and R₅₂₂ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the luminescent compound, R₉₀₁, R₉₀₂, R₉₀₃, R₉₀₄, R₉₀₅, R₉₀₆ and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
preferably, a substituted or unsubstituted alkyl group having 1 to 50 carbon atoms, or a substituted or unsubstituted aryl group having 6 to 50 ring carbon atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₅₀₆, a combination of R₅₀₆ and R₅₀₇, and a combination of R₅₀₁, R₅₀₂, and R_{503.}

In an exemplary embodiment, the compound represented by the formula (5) is a compound represented by a formula (52) below.

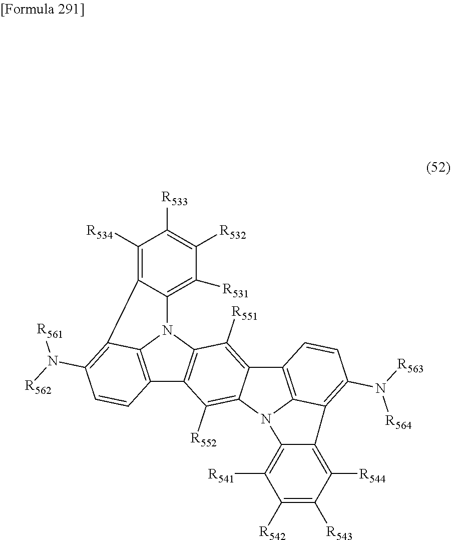

In the formula (52):
at least one combination of adjacent two or more of R₅₃₁ to R₅₃₄ and R₅₄₁ to R₅₄₄ are mutually bonded to form a substituted or unsubstituted monocyclic ring, mutually bonded to form a substituted or unsubstituted fused ring, or not mutually bonded;
R₅₃₁ to R₅₃₄, R₅₄₁ to R₅₄₄, R₅₅₁, and R₅₅₂ forming neither the substituted or unsubstituted monocyclic ring nor the substituted or unsubstituted fused ring are each independently a hydrogen atom, a substituted or unsubstituted aryl group having 6 to 50 ring carbon atoms, or a substituted or unsubstituted heterocyclic group having 5 to 50 ring atoms;
R₅₆₁ to R₅₆₄ are each independently a substituted or unsubstituted aryl group having 6 to 50 ring carbon atoms, or a substituted or unsubstituted heterocyclic group having 5 to 50 ring atoms.

### Compound Represented by Formula (6)

In an exemplary arrangement of the organic EL device according to the exemplary embodiment, the luminescent compound is a compound represented by a formula (6) below.

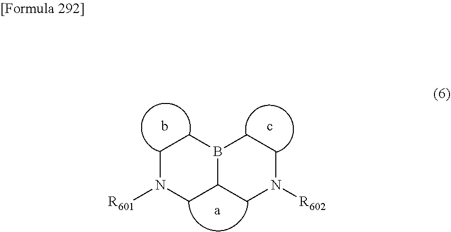

In the formula (6):
a ring a, a ring b and a ring c are each independently a substituted or unsubstituted aromatic hydrocarbon ring having 6 to 50 ring carbon atoms, or a substituted or unsubstituted heterocycle having 5 to 50 ring atoms;
R₆₀₁ and R₆₀₂ are each independently bonded to the ring a, ring b or ring c to form a substituted or unsubstituted heterocycle, or not bonded thereto to form no substituted or unsubstituted heterocycle; and
R₆₀₁ and R₆₀₂ not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

In an exemplary arrangement of the organic EL device according to the exemplary embodiment, the ring a, ring b and ring c are each a ring (a substituted or unsubstituted aromatic hydrocarbon ring having 6 to 50 ring carbon atoms, or a substituted or unsubstituted heterocycle having 5 to 50 ring atoms) fused with a fused bicyclic structure formed of a boron atom and two nitrogen atoms at the center of the formula (6).

The “aromatic hydrocarbon ring” for the rings a, b, and c has the same structure as a compound formed by introducing a hydrogen atom to an “aryl group”.

Ring atoms of the “aromatic hydrocarbon ring” for the ring a include three carbon atoms on the fused bicyclic structure at the center of the formula (6).

Ring atoms of the “aromatic hydrocarbon ring” for the rings b and c include two carbon atoms on the fused bicyclic structure at the center of the formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

The “heterocycle” for the rings a, b, and c has the same structure as a compound formed by introducing a hydrogen atom to the “heterocyclic group” described above.

Ring atoms of the “heterocycle” for the ring a include three carbon atoms on the fused bicyclic structure at the center of the formula (6). Ring atoms of the “heterocycle” for the rings b and c include two carbon atoms on the fused bicyclic structure at the center of the formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ may be each independently bonded with the ring a, ring b, or ring c to form a substituted or unsubstituted heterocycle. The “heterocycle” in this arrangement includes a nitrogen atom on the fused bicyclic structure at the center of the formula (6). The heterocycle in the above arrangement optionally includes a hetero atom other than the nitrogen atom. R₆₀₁ and R₆₀₂ being bonded with the ring a, ring b, or ring c specifically means that atoms forming R₆₀₁ and R₆₀₂ are bonded with atoms forming the ring a, ring b, or ring c. For instance, R₆₀₁ may be bonded with the ring a to form a bicyclic (or tri-or-more cyclic) fused nitrogen-containing heterocycle, in which the ring including R₆₀₁ and the ring a are fused. Specific examples of the nitrogen-containing heterocycle include a compound corresponding to the nitrogen-containing bi(or-more)cyclic fused heterocyclic group in the specific example group G2.

The same applies to R₆₀₁ bonded with the ring b, R₆₀₂ bonded with the ring a, and R₆₀₂ bonded with the ring c.

R₆₀₁ and R₆₀₂ may be each independently not bonded with the ring a, ring b, or ring c.

In an exemplary embodiment, the ring a, ring b and ring c in the formula (6) are each independently a substituted or unsubstituted aromatic hydrocarbon ring having 6 to 50 ring carbon atoms.

In an exemplary embodiment, the ring a, ring b and ring c in the formula (6) are each independently a substituted or unsubstituted benzene ring or a substituted or unsubstituted naphthalene ring.

In an exemplary embodiment, R₆₀₁ and R₆₀₂ in the formula (6) are each independently a substituted or unsubstituted aryl group having 6 to 50 ring carbon atoms, or a substituted or unsubstituted heterocyclic group having 5 to 50 ring atoms, preferably a substituted or unsubstituted aryl group having 6 to 50 ring carbon atoms.

In an exemplary embodiment, the compound represented by the formula (6) is a compound represented by a formula (62) below.

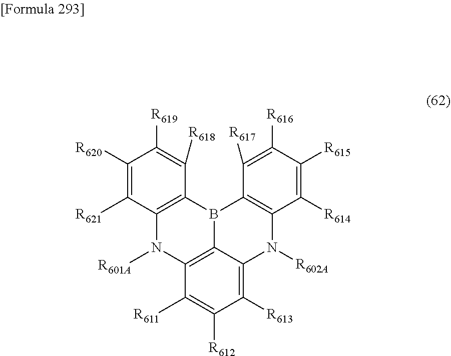

In the formula (62):
R_{601A} is bonded with at least one of R₆₁₁ or R₆₂₁ to form a substituted or unsubstituted heterocycle, or not bonded therewith to form no substituted or unsubstituted heterocycle;
R_{602A} is bonded with at least one of R₆₁₃ or R₆₁₄ to form a substituted or unsubstituted heterocycle, or not bonded therewith to form no substituted or unsubstituted heterocycle;
R_{601A} and R_{602A} not forming the substituted or unsubstituted heterocycle are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
at least one combination of adjacent two or more of R₆₁₁ to R₆₂₁ are mutually bonded to form a substituted or unsubstituted monocyclic ring, mutually bonded to form a substituted or unsubstituted fused ring, or not mutually bonded; and
R₆₁₁ to R₆₂₁ not forming the substituted or unsubstituted heterocycle, not forming the monocyclic ring, and not forming the fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (62), R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

R_{601A} and R_{602A} in the formula (62) are groups corresponding to R₆₀₁ and R₆₀₂ in the formula (6), respectively.

For instance, R_{601A} and R₆₁₁ are optionally bonded with each other to form a bicyclic (or tri-or-more cyclic) fused nitrogen-containing heterocycle, in which the ring including R_{601A} and R₆₁₁ and a benzene ring corresponding to the ring a are fused. Specific examples of the nitrogen-containing heterocycle include a compound corresponding to the nitrogen-containing bi(or-more)cyclic fused heterocyclic group in the specific example group G2. The same applies to R_{601A} bonded with R₆₂₁, R_{602A} bonded with R₆₁₃, and R_{602A} bonded with R₆₁₄.

At least one combination of adjacent two or more of R₆₁₁ to R₆₂₁ may be mutually bonded to form a substituted or unsubstituted monocyclic ring, or mutually bonded to form a substituted or unsubstituted fused ring.

For instance, R₆₁₁ and R₆₁₂ are mutually bonded to form a structure in which a benzene ring, indole ring, pyrrole ring, benzofuran ring, benzothiophene ring or the like is fused to the six-membered ring bonded with R₆₁₁ and R₆₁₂, the resultant fused ring forming a naphthalene ring, carbazole ring, indole ring, dibenzofuran ring, or dibenzothiophene ring, respectively.

In an exemplary embodiment, the compound represented by the formula (6) is a compound represented by a formula (42-2) below.

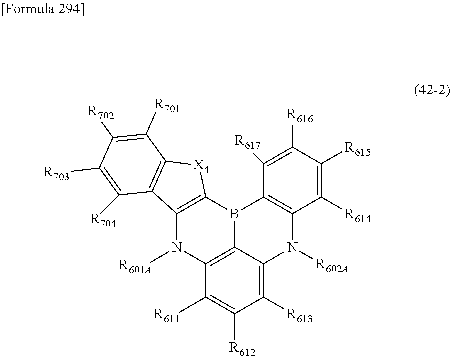

In the formula (42-2): R₆₁₁ to R₆₁₇, R_{601A} and R_{602A} each independently represent the same as R₆₁₁ to R₆₁₇, R_{601A} and R_{602A} in the formula (62);
X₄ is an oxygen atom or a sulfur atom;
at least one combination of adjacent two or more of R₇₀₁ to R₇₀₄ are mutually bonded to form a substituted or unsubstituted monocyclic ring, mutually bonded to form a substituted or unsubstituted fused ring, or not mutually bonded;
R₇₀₁ to R₇₀₄ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms or a substituted or unsubstituted heterocyclic group having 5 to 50 ring atoms; and
R₉₀₁, R₉₀₂, R₉₀₃, R₉₀₄, R₉₀₅, R₉₀₆, and R₉₀₇ in the formula (42-2) each independently represent the same as R₉₀₁, R₉₀₂, R₉₀₃, R₉₀₄, R₉₀₅, R₉₀₆, and R₉₀₇ in the formula (62).

### Specific Example of Luminescent Compound

Specific examples of the luminescent compound are given below. It should however be noted that these specific examples are merely exemplary and the luminescent compound is not limited thereto.

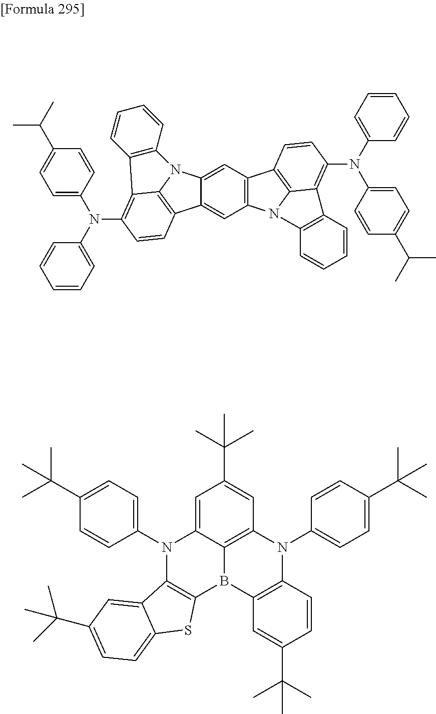

### Electron Transporting Zone

In an exemplary arrangement of the organic EL device according to the exemplary embodiment, an electron transporting layer is provided between the emitting zone and the cathode.

### Electron Transporting Layer

In an exemplary arrangement of the organic EL device according to the exemplary embodiment, the electron transporting zone includes at least one electron transporting layer. At least one electron transporting layer in the electron transporting zone contains a nitrogen-containing compound.

In an exemplary arrangement of the organic EL device according to the exemplary embodiment, the nitrogen-containing compound has at least one of a five-membered ring having a nitrogen atom or a six-membered ring having a nitrogen.

In an exemplary arrangement of the organic EL device according to the exemplary embodiment, at least one electron transporting layer in the electron transporting zone contains, as a nitrogen-containing compound, at least one compound selected from the group consisting of an imidazole derivative, benzimidazole derivative, azine derivative, carbazole derivative, and phenanthroline derivative.

### Phenanthroline Derivative

In an exemplary arrangement of the organic EL device according to the exemplary embodiment, at least one electron transporting layer in the electron transporting zone contains a phenanthroline derivative as a nitrogen-containing compound.

In an exemplary arrangement of the organic EL device of the exemplary embodiment, the phenanthroline derivative (phenanthroline compound) contained in the electron transporting layer is a compound represented by a formula (20) below and having at least one group represented by a formula (21) below.

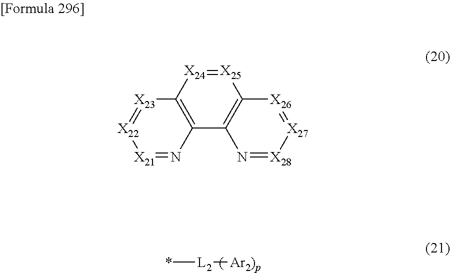

In the formula (20):
X₂₁ to X₂₈ are each independently a nitrogen atom, CR₂₁, or a carbon atom bonded to a group represented by the formula (21);
at least one of X₂₁ to X₂₈ is a carbon atom bonded to a group represented by the formula (21);
when a plurality of groups represented by the formula (21) are present, the plurality of groups represented by the formula (21) are mutually the same or different;
at least one combination of adjacent two or more of a plurality of R₂₁ are mutually bonded to form a substituted or unsubstituted monocyclic ring, mutually bonded to form a substituted or unsubstituted fused ring, or not mutually bonded; and
R₂₁ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₉₃₁, a group represented by —COOR932, a group represented by —S(═O)₂R₉₃₃, a group represented by —B(R₉₃₄)(R₉₃₅), a group represented by —P(═O)(R₉₃₆)(R₉₃₇), a halogen atom, a cyano group, a nitro group, a substituted or unsubstituted aryl group having 6 to 50 ring carbon atoms, or a substituted or unsubstituted heterocyclic group having 5 to 50 ring atoms.

In the formula (21):
Ar₂ is a substituted or unsubstituted aryl group having 6 to 50 ring carbon atoms, or a substituted or unsubstituted heterocyclic group having 5 to 50 ring atoms;
p is 1, 2, 3, 4, or 5;
when two or more Ar₂ are present, the two or more Ar₂ are mutually the same or different;
L₂ is a single bond or a linking group;
L₂ as a linking group is a substituted or unsubstituted polyvalent linear, branched or cyclic aliphatic hydrocarbon group having 1 to 50 carbon atoms, a substituted or unsubstituted polyvalent aromatic hydrocarbon ring group having 6 to 50 ring carbon atoms, a substituted or unsubstituted polyvalent heterocyclic group having 5 to 50 ring atoms, or a polyvalent multiple linking group provided by bonding two or three groups selected from the polyvalent aromatic hydrocarbon ring group and the polyvalent heterocyclic group;
the aromatic hydrocarbon ring group and the heterocyclic group forming L₂ as the multiple linking group are mutually the same or different, and adjacent ones thereof are mutually bonded to form a ring, or not mutually bonded;
Ar₂ and L₂ as the linking group are mutually bonded to form a ring, or not mutually bonded;
L₂ as the linking group, and a carbon atom in one of X₂₁ to X₂₈ adjacent to a carbon atom bonded to L₂, or R₂₁ in CR₂₁ are mutually bonded to form a ring, or not mutually bonded; and
* in the formula (21) represents a bonding position to a ring represented by the formula (20);
in the phenanthroline compound, R₉₀₁, R₉₀₂, R₉₀₃, R₉₀₄, R₉₀₅, R₉₀₆, R₉₀₇, R₉₃₁,
R₉₃₂, R₉₃₃, R₉₃₄, R₉₃₅, R₉₃₆, and R₉₃₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different;
when a plurality of R₉₀₇ are present, the plurality of R₉₀₇ are mutually the same or different;
when a plurality of R₉₃₁ are present, the plurality of R₉₃₁ are mutually the same or different;
when a plurality of R₉₃₂ are present, the plurality of R₉₃₂ are mutually the same or different;
when a plurality of R₉₃₃ are present, the plurality of R₉₃₃ are mutually the same or different;
when a plurality of R₉₃₄ are present, the plurality of R₉₃₄ are mutually the same or different;
when a plurality of R₉₃₅ are present, the plurality of R₉₃₅ are mutually the same or different;
when a plurality of R₉₃₆ are present, the plurality of R₉₃₆ are mutually the same or different; and
when a plurality of R₉₃₇ are present, the plurality of R₉₃₇ are mutually the same or different.

A group represented by —O—(R₉₀₄) herein in which R₉₀₄ is a hydrogen atom is a hydroxy group.

A group represented by —S—(R₉₀₅) herein in which R₉₀₅ is a hydrogen atom is a thiol group.

A group represented by —S(═O)₂R₉₃₃ herein in which R₉₃₃ is a substituent is a substituted sulfo group.

A group represented by —B(R₉₃₄)(R₉₃₅) herein in which R₉₃₄ and R₉₃₅ are each a substituent is a substituted boryl group.

A group represented by —P(═O)(R₉₃₆)(R₉₃₇) herein in which R₉₃₆ and R₉₃₇ are each a substituent is a substituted phosphine oxide group, and a group represented by —P(═O)(R₉₃₆)(R₉₃₇) herein in which R₉₃₆ and R₉₃₇ are each an aryl group is an aryl phosphoryl group.

An “unsubstituted polyvalent linear, branched or cyclic aliphatic hydrocarbon group” mentioned herein has, unless otherwise specified herein, 1 to 50, preferably 1 to 20, more preferably 1 to 6 carbon atoms.

An “unsubstituted polyvalent aromatic hydrocarbon group” mentioned herein has, unless otherwise specified herein, 6 to 50, preferably 6 to 30, more preferably 6 to 18 ring carbon atoms.

An “unsubstituted polyvalent heterocyclic group” mentioned herein has, unless otherwise specified, 5 to 50, preferably 5 to 30, more preferably 5 to 18 ring atoms.

In an exemplary embodiment, a heterocyclic group having 5 to 50 ring atoms in Ar₂ of the formula (21) contains a substituted or unsubstituted group derived from a cyclic structure represented by the formula (20).

In an exemplary embodiment, X₂₁ and X₂₈ in the formula (20) are each a carbon atom bonded to a group represented by the formula (21).

In an exemplary embodiment, one of X₂₁ and X₂₈ in the formula (20) is a carbon atom bonded to a group represented by the formula (21), and the other of X₂₁ and X₂₈ in the formula (20) is a carbon atom bonded to a hydrogen atom.

In an exemplary embodiment, X₂₁ to X₂₈ in the formula (20) are each independently CR₂₁ or a carbon atom bonded to a group represented by the formula (21).

In an exemplary embodiment, X₂₁ to X₂₈ in the formula (20) not being the carbon atom bonded to the group represented by the formula (21) are each CR₂₁. In other words, in an exemplary embodiment, the compound represented by the formula (20) is a 1,10-phenanthroline derivative.

In an exemplary embodiment, Ar₂ in the formula (21) is a substituted or unsubstituted fused aromatic hydrocarbon group having 8 to 20 ring carbon atoms.

In an exemplary embodiment, a fused aromatic hydrocarbon group having 8 to 20 ring carbon atoms is a group derived from any aromatic hydrocarbon selected from the group consisting of, for instance, naphthalene, anthracene, acephenanthrylene, aceanthrylene, benzanthracene, triphenylene, pyrene, chrysene, naphthacene, fluorene, phenanthrene, fluoranthene, and benzofluoranthene.

In an exemplary embodiment, Ar₂ in the formula (21) is a substituted or unsubstituted anthryl group.

In an exemplary embodiment, Ar₂ in the formula (21) is a substituted or unsubstituted heterocyclic group having 5 to 40 ring carbon atoms.

In an exemplary embodiment, Ar₂ in the formula (21) is a substituted or unsubstituted group derived from the cyclic structure represented by the formula (20).

In an exemplary embodiment, Ar₂ in the formula (21) is a group represented by a formula (23) below.

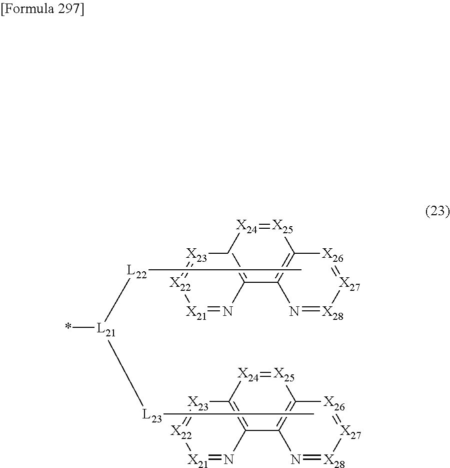

In the formula (23):
X₂₁ to X₂₈ are each independently a nitrogen atom, CR₂₁, a group represented by the formula (21), or a carbon atom bonded to L₂₂ or L₂₃;
L₂₁ is a linking group, and L₂₁ as the linking group is a substituted or unsubstituted trivalent linear, branched or cyclic aliphatic hydrocarbon group having 1 to 50 carbon atoms, a substituted or unsubstituted trivalent aromatic hydrocarbon group having 6 to 50 ring carbon atoms, or a substituted or unsubstituted trivalent heterocyclic group having 5 to 50 ring atoms; and
L₂₂ and L₂₃ are each independently a single bond or a linking group, and L₂₂ and L₂₃ as the linking group are each independently a substituted or unsubstituted divalent linear, branched or cyclic aliphatic hydrocarbon group having 1 to 50 carbon atoms, a substituted or unsubstituted arylene group having 6 to 50 ring carbon atoms, or a substituted or unsubstituted divalent heterocyclic group having 5 to 50 ring atoms.

In a formula representing a phenanthroline compound:
when a plurality of X₂₁ are present, the plurality of X₂₁ are mutually the same or different;
when a plurality of X₂₂ are present, the plurality of X₂₂ are mutually the same or different;
when a plurality of X₂₃ are present, the plurality of X₂₃ are mutually the same or different;
when a plurality of X₂₄ are present, the plurality of X₂₄ are mutually the same or different;
when a plurality of X₂₅ are present, the plurality of X₂₅ are mutually the same or different;
when a plurality of X₂₆ are present, the plurality of X₂₆ are mutually the same or different;
when a plurality of X₂₇ are present, the plurality of X₂₇ are mutually the same or different; and
when a plurality of X₂₈ are present, the plurality of X₂₈ are mutually the same or different.

In an exemplary embodiment, X₂₁ to X₂₈ in the formula (23) are preferably each independently a nitrogen atom, CR₂₁, or a carbon atom bonded to L₂₂ or L₂₃, more preferably CR₂₁, or a carbon atom bonded to L₂₂ or L₂₃.

In an exemplary embodiment, the phenanthroline compound is a compound represented by a formula (24) below.

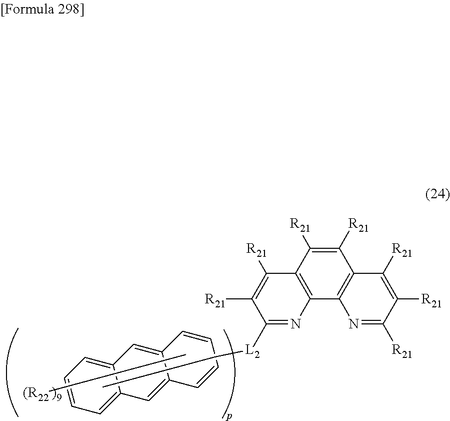

In the formula (24):
a plurality of R₂₁ each independently represent the same as R₂₁ in the formula (20);
a plurality of R₂₂ each independently represent the same as R₂₁ in the formula (20);
L₂ represents the same as L₂ in the formula (21);
p is 1, 2, 3, 4, or 5; and
a plurality of R₂₂ and L₂ are each bonded to a carbon atom at one of positions 1 to 10 of an anthracene ring.

In an exemplary embodiment, the phenanthroline compound is a compound represented by a formula (24A) below.

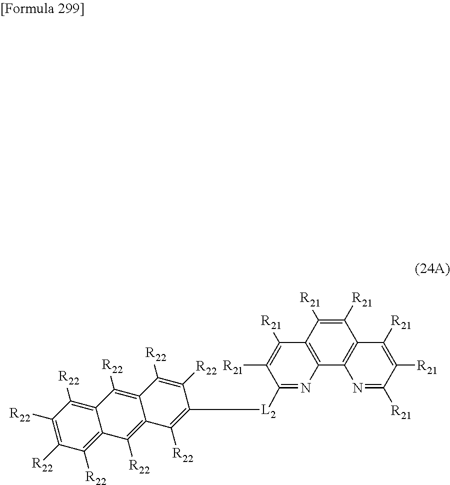

In the formula (24A):
a plurality of R₂₁ each independently represent the same as R₂₁ in the formula (20);
a plurality of R₂₂ each independently represent the same as R₂₁ in the formula (20); and
L₂ represents the same as L₂ in the formula (21).

In an exemplary embodiment, the phenanthroline compound is a compound represented by a formula (24B) below.

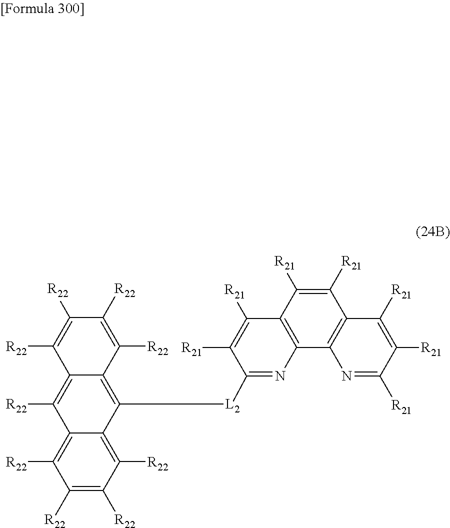

In the formula (24B):
a plurality of R₂₁ each independently represent the same as R₂₁ in the formula (20);
a plurality of R₂₂ each independently represent the same as R₂₁ in the formula (20); and
L₂ represents the same as L₂ in the formula (21).

In an exemplary embodiment, the phenanthroline compound is a compound represented by a formula (25) below.

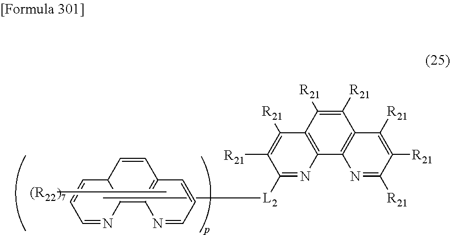

In the formula (25):
a plurality of R₂₁ each independently represent the same as R₂₁ in the formula (20);
a plurality of R₂₂ each independently represent the same as R₂₁ in the formula (20);
L₂ represents the same as L₂ in the formula (21);
p is 1, 2, 3, 4, or 5; and
a plurality of R₂₂ and L₂ are each bonded to a carbon atom at one of positions 2 to 9 of a phenanthroline ring.

In an exemplary embodiment, the phenanthroline compound is a compound represented by a formula (25A) below.

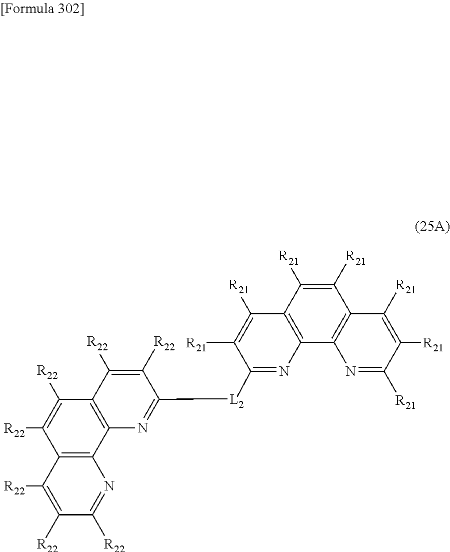

In the formula (25A):
a plurality of R₂₁ each independently represent the same as R₂₁ in the formula (20);
a plurality of R₂₂ each independently represent the same as R₂₁ in the formula (20); and
L₂ represents the same as L₂ in the formula (21).

In an exemplary embodiment, L₂ in the formulae (24), (24A), (24B), (25) and (25A) is a single bond, a substituted or unsubstituted arylene group having 6 to 50 ring carbon atoms, or a substituted or unsubstituted divalent heterocyclic group having 5 to 50 ring atoms.

In an exemplary embodiment, the phenanthroline compound is a compound represented by a formula (25B) below.

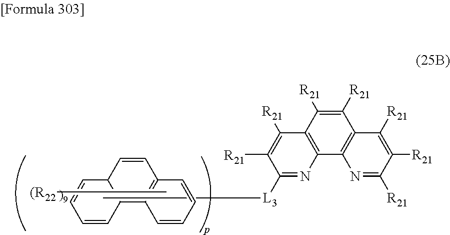

In the formula (25B):
a plurality of R₂₁ each independently represent the same as R₂₁ in the formula (20);
a plurality of R₂₂ each independently represent the same as R₂₁ in the formula (20);
L₃ is a linking group, and L₃ as the linking group is a substituted or unsubstituted polyvalent linear, branched or cyclic aliphatic hydrocarbon group having 1 to 50 carbon atoms, a substituted or unsubstituted polyvalent amino group, a substituted or unsubstituted polyvalent aromatic hydrocarbon ring group having 6 to 50 ring carbon atoms, a substituted or unsubstituted polyvalent heterocyclic group having 5 to 50 ring atoms, or a polyvalent multiple linking group provided by bonding two or three groups selected from the polyvalent aromatic hydrocarbon ring group and the polyvalent heterocyclic group;
the aromatic hydrocarbon ring group and the heterocyclic group forming L₃ as the multiple linking group are mutually the same or different, and adjacent ones thereof are mutually bonded to form a ring, or not mutually bonded;
p is 1, 2, 3, 4, or 5; and
the plurality of R₂₂ and L₃ are bonded to respective ones of carbon atoms at positions 1 to 10 of a phenanthrene ring.

In an exemplary embodiment, the phenanthroline compound is a compound represented by a formula (25C) below.

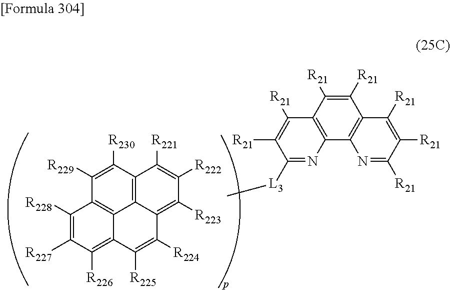

In the formula (25C):
a plurality of R₂₁ each independently represent the same as R₂₁ in the formula (20);
one of R₂₂₁ to R₂₃₀ is a single bond bonded to L₃, and R₂₂₁ to R₂₃₀ not being the single bond bonded to L₃ each independently represent the same as R₂₁ in the formula (20);
L₃ is a linking group, and L₃ as the linking group represents the same as L₃ as the linking group in the formula (25B); and
p is 1, 2, 3, 4, or 5.

In an exemplary embodiment, the phenanthroline compound is a compound represented by a formula (25D) below.

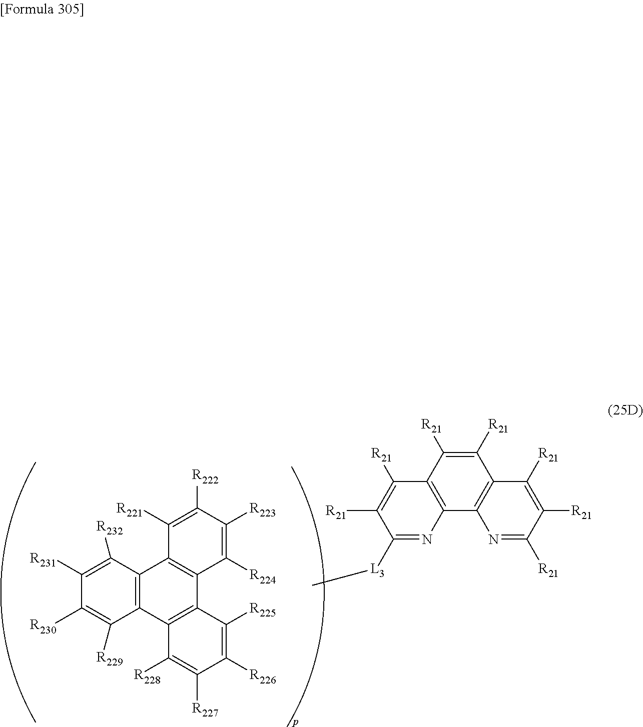

In the formula (25D):
a plurality of R₂₁ each independently represent the same as R₂₁ in the formula (20);
one of R₂₂₁ to R₂₃₂ is a single bond bonded to L₃, and R₂₂₁ to R₂₃₂ not being the single bond bonded to L₃ each independently represent the same as R₂₁ in the formula (20);
L₃ is a linking group, and L₃ as the linking group represents the same as L₃ as the linking group in the formula (25B); and
p is 1, 2, 3, 4, or 5.

In an exemplary embodiment, the phenanthroline compound is a compound represented by a formula (25E) below.

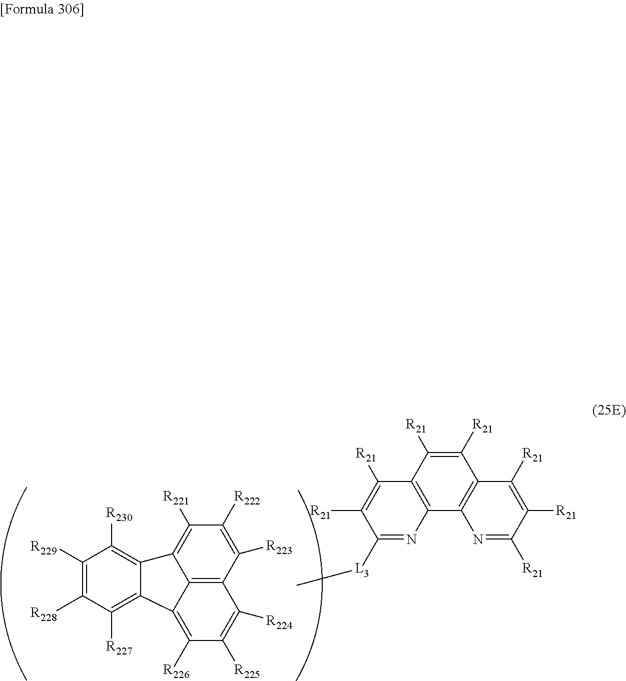

In the formula (25E):
a plurality of R₂₁ each independently represent the same as R₂₁ in the formula (20);
one of R₂₂₁ to R₂₃₀ is a single bond bonded to L₃, and R₂₂₁ to R₂₃₀ not being the single bond bonded to L₃ each independently represent the same as R₂₁ in the formula (20);
L₃ is a linking group, and L₃ as the linking group represents the same as L₃ as the linking group in the formula (25B); and
p is 1, 2, 3, 4, or 5.

Also preferably, L₃ in the formulae (25B), (25C), (25D) and (25E) are each a substituted or unsubstituted arylene group having 6 to 50 ring carbon atoms, or a substituted or unsubstituted divalent heterocyclic group having 5 to 50 ring atoms.

### Producing Method of Phenanthroline Compound

The phenanthroline compound can be produced by a known method. The phenanthroline compound can also be produced based on a known method through a known alternative reaction using a known material(s) tailored for the target compound.

### Azine Derivative

In an exemplary arrangement of the organic EL device according to the exemplary embodiment, at least one electron transporting layer in the electron transporting zone contains an azine derivative as a nitrogen-containing compound.

In an exemplary arrangement of the organic EL device according to the exemplary embodiment, the azine derivative contained in the electron transporting layer is a compound represented by a formula (E42) below.

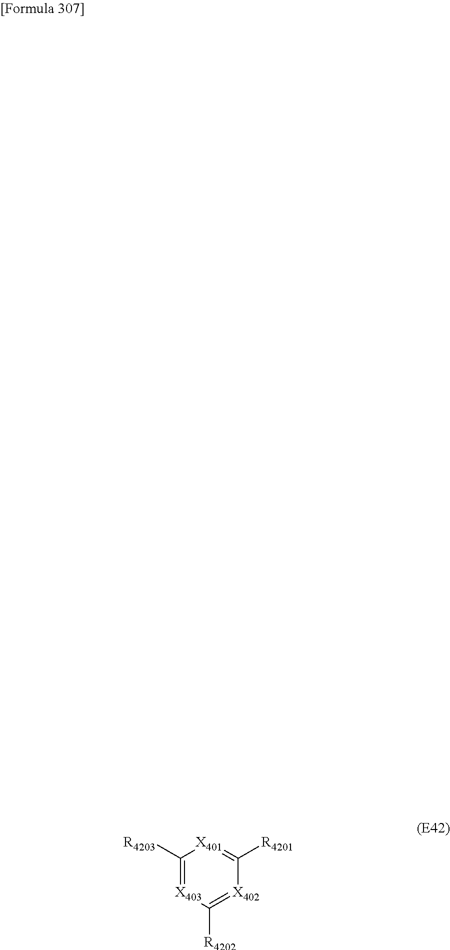

In the formula (E42):
X₄₀₁ to X₄O₃ are each independently CR₄₂₀₄ or a nitrogen atom;
at least one of X₄₀₁ to X₄₀₃ is a nitrogen atom;
when two or more R₄₂₀₄ are present, the two or more R₄₂₀₄ are mutually the same or different; and
R₄₂₀₁ to R₄₂₀₄ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

R₉₀₁ to R₉₀₇ in the azine derivative are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device according to the exemplary embodiment, the azine derivative contained in the electron transporting layer is a compound represented by a formula (E421) below.

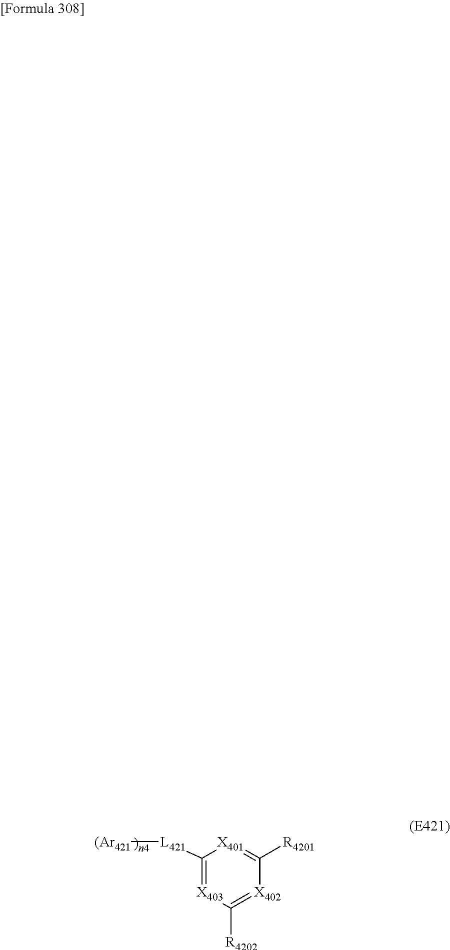

In the formula (E421):
X₄₀₁ to X₄₀₃, R₄₂₀₁, and R₄₂₀₂ each independently represent the same as X₄₀₁ to X₄₀₃, R₄₂₀₁, and R₄₂₀₂ in the formula (E42);
n₄ is 1, 2, or 3;
L₄₂₁ is a single bond, a substituted or unsubstituted arylene group having 6 to 50 ring carbon atoms, a trivalent or tetravalent group derived from the arylene group, a substituted or unsubstituted divalent heterocyclic group having 5 to 50 ring atoms, a trivalent or tetravalent group derived from the divalent heterocyclic group, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms, or a trivalent or tetravalent group derived from the divalent group;
Ar₄₂₁ is a substituted or unsubstituted aryl group having 6 to 50 ring carbon atoms, or a substituted or unsubstituted heterocyclic group having 5 to 50 ring atoms;
when n₄ is 2 or 3, Ar₄₂₁ are mutually the same or different; and
when n₄ is 2 or 3, L₄₂₁ is not a single bond.

In an exemplary arrangement of the organic EL device according to the exemplary embodiment, the azine derivative contained in the electron transporting layer is a compound represented by each of a formula (E422) and a formula (E423) below.

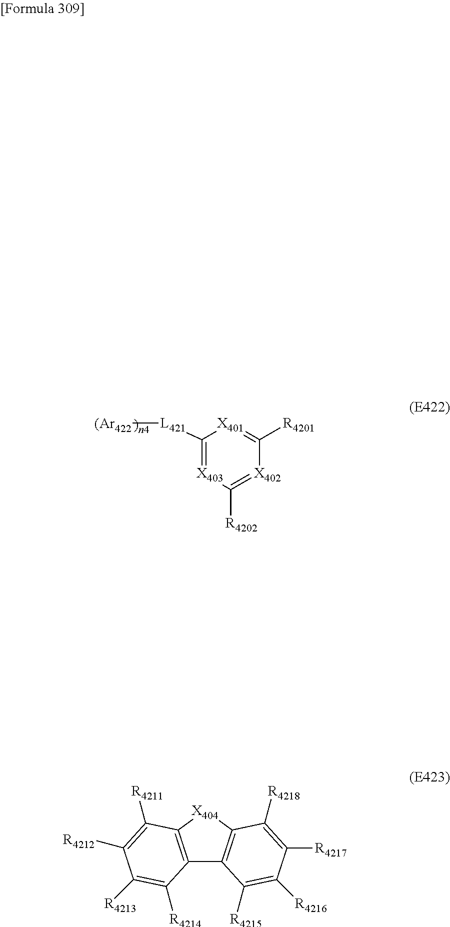

In the formula (E422):
n₄, X₄₀₁ to X₄₀₃, R₄₂₀₁ and R₄₂₀₂ each independently represent the same as n₄, X₄₀₁ to X₄₀₃, R₄₂₀₁ and R₄₂₀₂ in the formula (E42);
L₄₂₁ represents the same as L₄₂₁ in the formula (E421); and
Ar₄₂₂ is a group represented by the formula (E423).

In the formula (E423):
X₄₀₄ is an oxygen atom, a sulfur atom, N(R₄₂₂₁), or C(R₄₂₂₂)(R₄₂₂₃);
one of R₄₂₁₁ to R₄₂₁₈ and R₄₂₂₁ to R₄₂₂₃ is a single bond with L₄₂₁;
at least one combination of adjacent two or more of R₄₂₁₁ to R₄₂₁₈ not being a single bond with L₄₂₁ are mutually bonded to form a substituted or unsubstituted monocyclic ring, mutually bonded to form a substituted or unsubstituted fused ring, or not mutually bonded;
a combination of R₄₂₂₂ and R₄₂₂₃ not being the single bond with L₄₂₁ are mutually bonded to form a substituted or unsubstituted monocyclic ring, mutually bonded to form a substituted or unsubstituted fused ring, or not mutually bonded;
R₄₂₁₁ to R₄₂₁₈ not being the single bond with L₄₂₁ and forming neither the substituted or unsubstituted monocyclic ring nor the substituted or unsubstituted fused ring, R₄₂₂₁, and R₄₂₂₂ and R₄₂₂₃ not being the single bond with L₄₂₁ and forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
when n₄ is 2 or 3,
a plurality of X₄₀₄ are mutually the same or different;
a plurality of R₄₂₁₁ are mutually the same or different;
a plurality of R₄₂₁₂ are mutually the same or different;
a plurality of R₄₂₁₃ are mutually the same or different;
a plurality of R₄₂₁₄ are mutually the same or different;
a plurality of R₄₂₁₅ are mutually the same or different;
a plurality of R₄₂₁₆ are mutually the same or different;
a plurality of R₄₂₁₇ are mutually the same or different; and
a plurality of R₄₂₁₈ are mutually the same or different.

In the formulae (E422) and (E423), R₉₀₁ to R₉₀₇ each independently represent the same as R₉₀₁ to R₉₀₇ in the azine derivative.

When n₄ is 1 in the formula (E421), for instance, the group represented by (Ar₄₂₁)ₙ₄-L₄₂₁-* in the formula (E421) is represented by a formula (E421-1) below. In this arrangement, L₄₂₁ is a divalent linking group. * represents a bonding position to a six-membered ring in the formula (E421).

When n₄ is 2 in the formula (E421), the group represented by (Ar₄₂₁)ₙ₄-L₄₂₁-* in the formula (E421) is represented by a formula (E421-2) below. Ar₄₂₁ are mutually the same or different. In this arrangement, L₄₂₁ is a trivalent linking group.

When n₄ is 3 in the formula (E421), the group represented by (Ar₄₂₁)ₙ₄-L₄₂₁-* in the formula (E421) is represented by a formula (E421-3) below. Ar₄₂₁ are mutually the same or different. In this arrangement, L₄₂₁ is a tetravalent linking group.

The same applies to a group represented by (Ar₄₂₂)ₙ₄-L₄₂₁-* in the formula (E422).

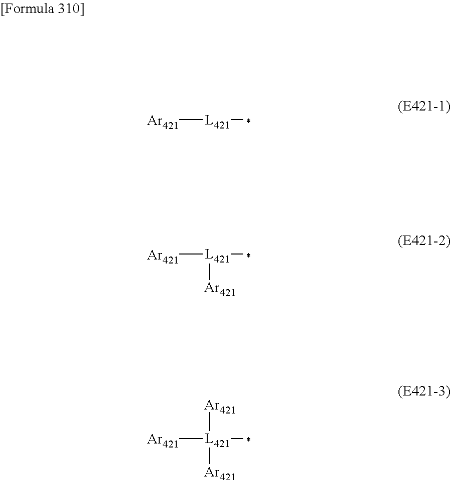

Each * in the formulae (E421-1), (E421-2), and (E421-3) represents a bonding position to a six-membered ring in the formula (E421).

In the formulae (E421) and (E422), L₄₂₁ as the linking group is preferably a divalent or trivalent group derived from any of benzene, biphenyl, terphenyl, naphthalene and phenanthrene.

In an exemplary arrangement of the organic EL device according to the exemplary embodiment, a substituent for “a substituted or unsubstituted” group in the azine derivative is at least one group selected from the group consisting of an alkyl group having 1 to 18 carbon atoms, aryl group having 6 to 18 ring carbon atoms, and heterocyclic group having 5 to 18 ring atoms.

In an exemplary arrangement of the organic EL device according to the exemplary embodiment, a substituent for “the substituted or unsubstituted” group in the azine derivative is an alkyl group having 1 to 5 carbon atoms.

In an exemplary arrangement of the organic EL device according to the exemplary embodiment, the groups specified to be “substituted or unsubstituted” in the azine derivative are each an “unsubstituted” group.

### Benzimidazole Derivative

In an exemplary arrangement of the organic EL device according to the exemplary embodiment, at least one electron transporting layer in the electron transporting zone contains a benzimidazole derivative as a nitrogen-containing compound.

In an exemplary arrangement of the organic EL device according to the exemplary embodiment, the benzimidazole derivative contained in the electron transporting layer is a compound represented by a formula (E41) below.

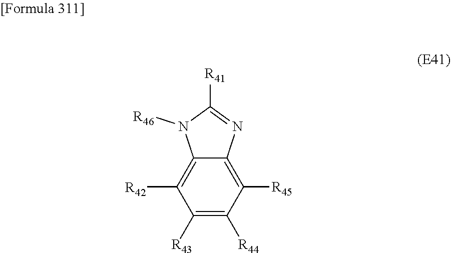

In the formula (E41):
at least one combination of adjacent two or more of R₄₁ to R₄₆ are mutually bonded to form a substituted or unsubstituted monocyclic ring, mutually bonded to form a substituted or unsubstituted fused ring, or not mutually bonded;
R₄₁ to R₄₆ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms or a substituted or unsubstituted heterocyclic group having 5 to 50 ring atoms.

In the formula (E41): R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device according to the exemplary embodiment, the benzimidazole derivative contained in the electron transporting layer is a compound represented by a formula (E41A), (E41B), (E41C), (E41D) or (E41E) below.

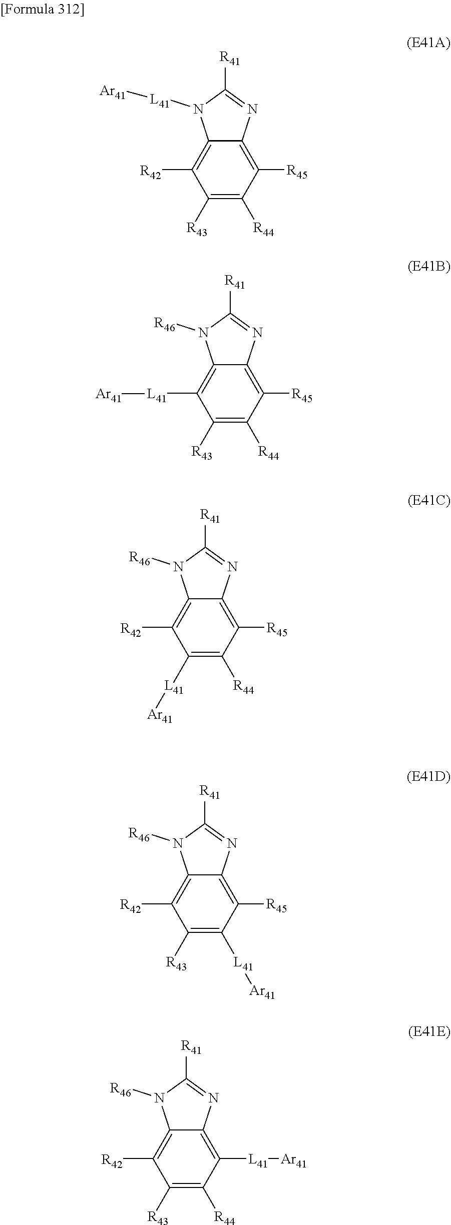

In the formulae (E41A), (E41B), (E41C), (E41D) and (E41E): R₄₁ to R₄₆ each independently represent the same as R₄₁ to R₄₆ in the formula (E41);
L₄₁ is a single bond, a substituted or unsubstituted arylene group having 6 to 50 ring carbon atoms, or a substituted or unsubstituted divalent heterocyclic group having 5 to 50 ring atoms;
Ar₄₁ is a substituted or unsubstituted alkyl group having 1 to 50 carbon atoms, a group represented by —O—(R₉₀₄), a substituted or unsubstituted aryl group having 6 to 50 ring carbon atoms, or a substituted or unsubstituted heterocyclic group having 5 to 50 ring atoms; and
R₉₀₄ represents the same as R₉₀₄ in the benzimidazole derivative.

In an exemplary arrangement of the organic EL device according to the exemplary embodiment, Ar₄₁ in the formulae (E41A), (E41B), (E41C), (E41D), and (E41E) is a group represented by a formula (E412) below.

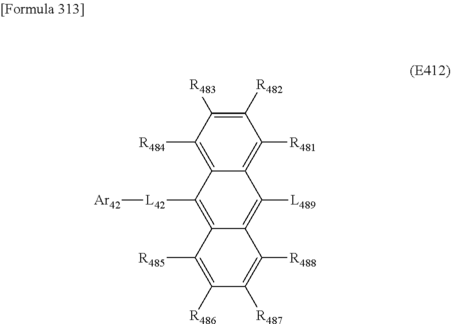

In the formula (E412):
one of R₄₈₁ to R₄₈₉ is a single bond with L₄₁;
at least one combination of adjacent two or more of R₄₈₁ to R₄₈₉ not being a single bond with L₄₁ are mutually bonded to form a substituted or unsubstituted monocyclic ring, mutually bonded to form a substituted or unsubstituted fused ring, or not mutually bonded;
R₄₈₁ to R₄₈₉ not being a single bond with L₄₁ and forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
L₄₂ is each independently a single bond, a substituted or unsubstituted arylene group having 6 to 50 ring carbon atoms, or a substituted or unsubstituted divalent heterocyclic group having 5 to 50 ring atoms; and
Ar₄₂ is each independently a substituted or unsubstituted aryl group having 6 to 50 ring carbon atoms, or a substituted or unsubstituted heterocyclic group having 5 to 50 ring atoms.

In the formula (E412), R₉₀₁ to R₉₀₇ each independently represent the same as R₉₀₁ to R₉₀₇ in the benzimidazole derivative.

In the formulae (E41A), (E41B), (E41C), (E41D) and (E41E): L₄₁ is preferably a substituted or unsubstituted phenylene group, a substituted or unsubstituted biphenylene group, a substituted or unsubstituted naphthylene group, a substituted or unsubstituted pyridinylene group, or a substituted or unsubstituted 9,9′-spirobifluorenylene group.

In the formulae (E41A), (E41B), (E41C), (E41D) and (E41E): L₄₁ is more preferably an unsubstituted phenylene group, an unsubstituted biphenylene group, an unsubstituted naphthylene group, an unsubstituted pyridinylene group, or an unsubstituted 9,9′-spirobifluorenylene group.

In the formulae (E41A), (E41B), (E41C), (E41D), and (E41E), Ar₄₁ is preferably a substituted or unsubstituted phenyl group, a substituted or unsubstituted biphenyl group, a substituted or unsubstituted terphenyl group, a substituted or unsubstituted naphthyl group, a substituted or unsubstituted phenanthryl group, a substituted or unsubstituted fluoranthenyl group, a substituted or unsubstituted pyrenyl group, or a substituted or unsubstituted fluorenyl group.

In the formulae (E41A), (E41B), (E41C), (E41D), and (E41E), Ar₄₁ is more preferably an unsubstituted phenyl group, an unsubstituted biphenyl group, an unsubstituted terphenyl group, an unsubstituted naphthyl group, an unsubstituted phenanthryl group, an unsubstituted fluoranthenyl group, an unsubstituted pyrenyl group, or an unsubstituted 9,9-dimethylfluorenyl group.

In an exemplary arrangement of the organic EL device according to the exemplary embodiment, the benzimidazole derivative is a compound represented by a formula (E413) below.

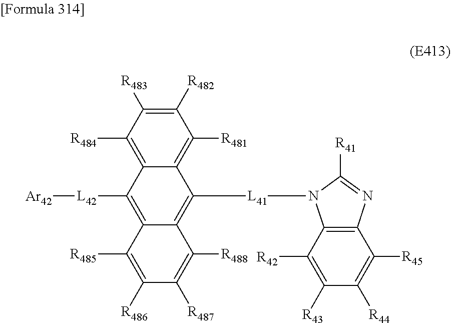

In the formula (E413):
R₄₁ to R₄₅ and L₄₁ each independently represent the same as R₄₁ to R₄₅ and L₄₁ in the formula (E41A); and
R₄₈₁ to R₄₈₈, L₄₂, and Ar₄₂ each independently represent the same as R₄₈₁ to R₄₈₈, L₄₂, and Ar₄₂ in the formula (E412).

In an exemplary arrangement of the organic EL device according to the exemplary embodiment, the groups specified to be “substituted or unsubstituted” in the benzimidazole derivative are each an “unsubstituted” group.

### Specific Examples of Nitrogen-containing Compound

Specific examples of the nitrogen-containing compound include the following compounds. It should however be noted that the invention is not limited to the specific examples of the nitrogen-containing compound.

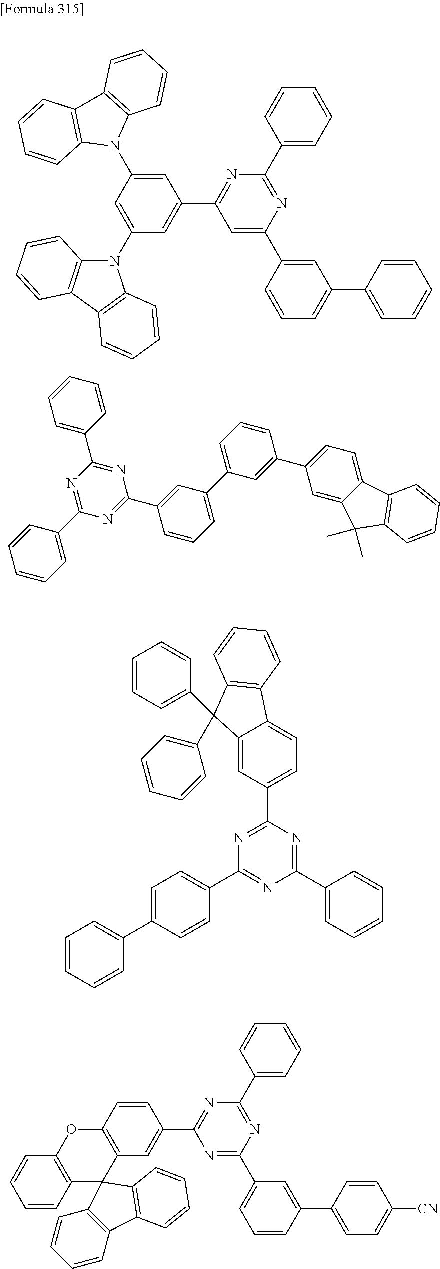

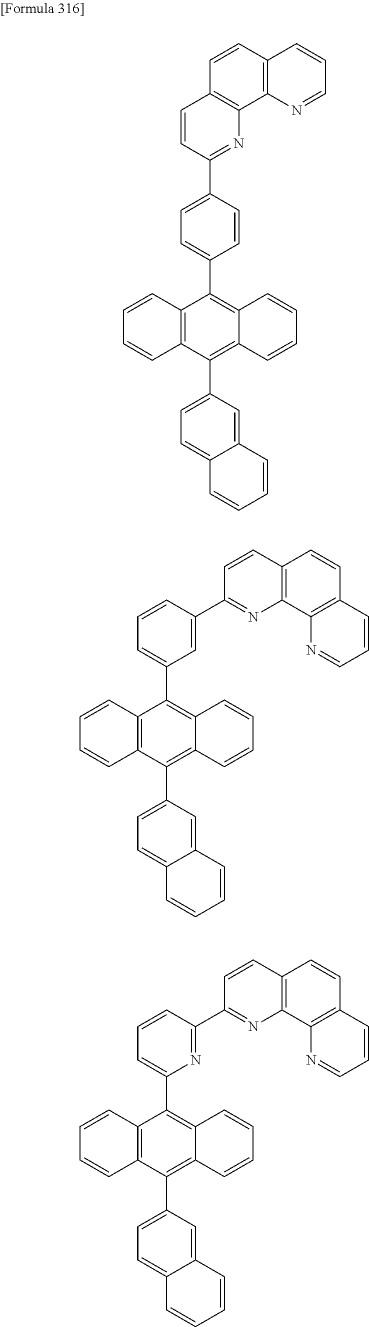

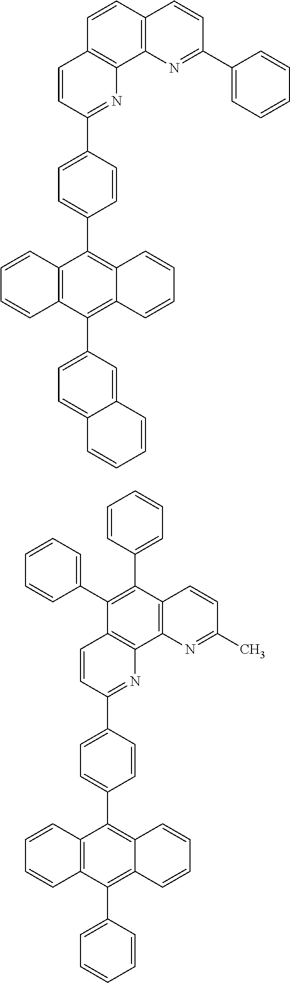

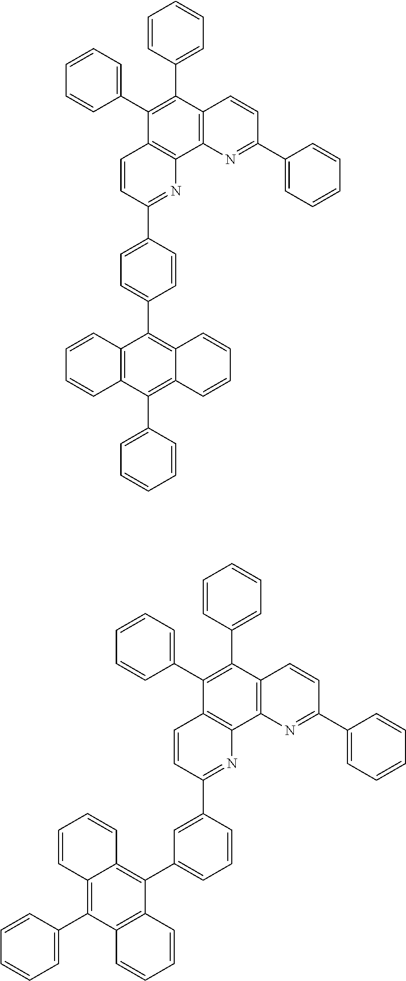 [SMILES: c1ccc(-c2ccc3c(-c4ccccc4)c(-c4ccccc4)c4ccc(-c5ccc(-c6c7ccccc7c(-c7ccccc7)c7ccccc67)cc5)nc4c3n2)cc1 ; c1ccc(-c2ccc3c(-c4ccccc4)c(-c4ccccc4)c4ccc(-c5cccc(-c6c7ccccc7c(-c7ccccc7)c7ccccc67)c5)nc4c3n2)cc1]

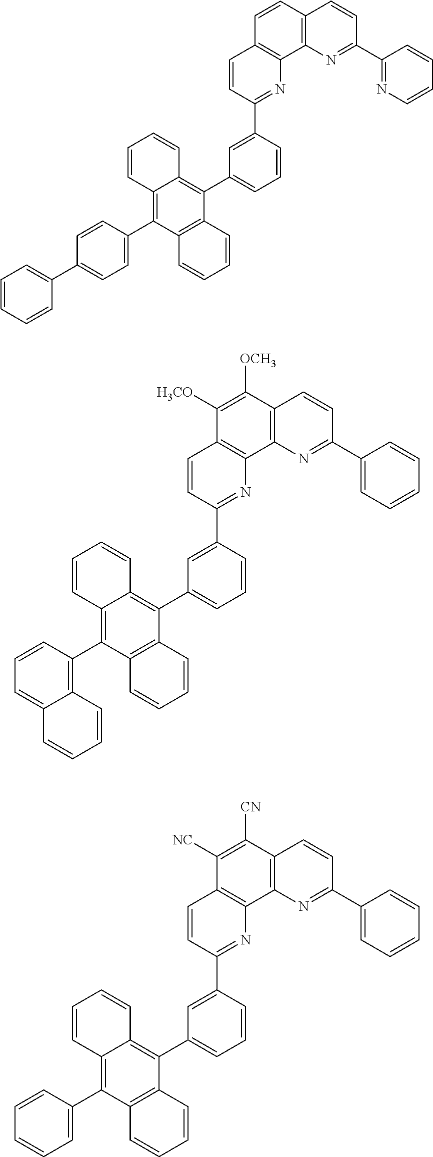 [SMILES: c1ccc(-c2ccc(-c3c4ccccc4c(-c4cccc(-c5ccc6ccc7ccc(-c8ccccn8)nc7c6n5)c4)c4ccccc34)cc2)cc1 ; COc1c(OC)c2ccc(-c3cccc(-c4c5ccccc5c(-c5cccc6ccccc56)c5ccccc45)c3)nc2c2nc(-c3ccccc3)ccc12 ; N#Cc1c(C#N)c2ccc(-c3cccc(-c4c5ccccc5c(-c5ccccc5)c5ccccc45)c3)nc2c2nc(-c3ccccc3)ccc12]

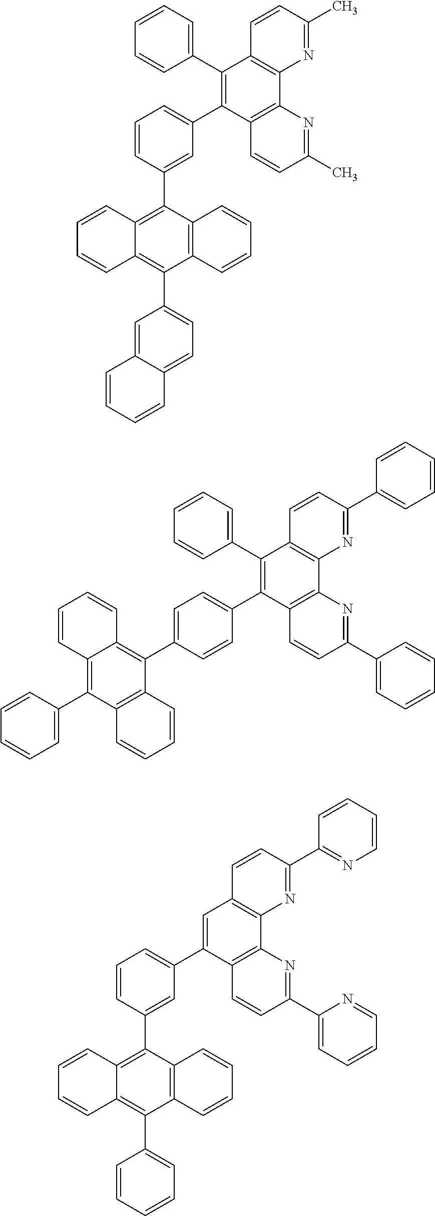 [SMILES: Cc1ccc2c(-c3ccccc3)c(-c3cccc(-c4c5ccccc5c(-c5ccc6ccccc6c5)c5ccccc45)c3)c3ccc(C)nc3c2n1 ; c1ccc(-c2ccc3c(-c4ccccc4)c(-c4ccc(-c5c6ccccc6c(-c6ccccc6)c6ccccc56)cc4)c4ccc(-c5ccccc5)nc4c3n2)cc1 ; c1ccc(-c2c3ccccc3c(-c3cccc(-c4cc5ccc(-c6ccccn6)nc5c5nc(-c6ccccn6)ccc45)c3)c3ccccc23)cc1]

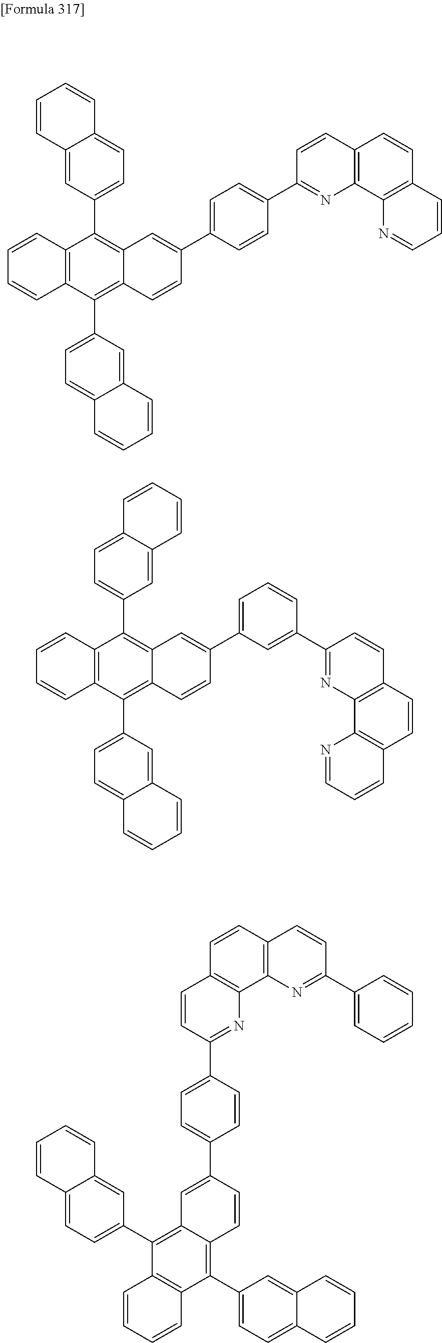

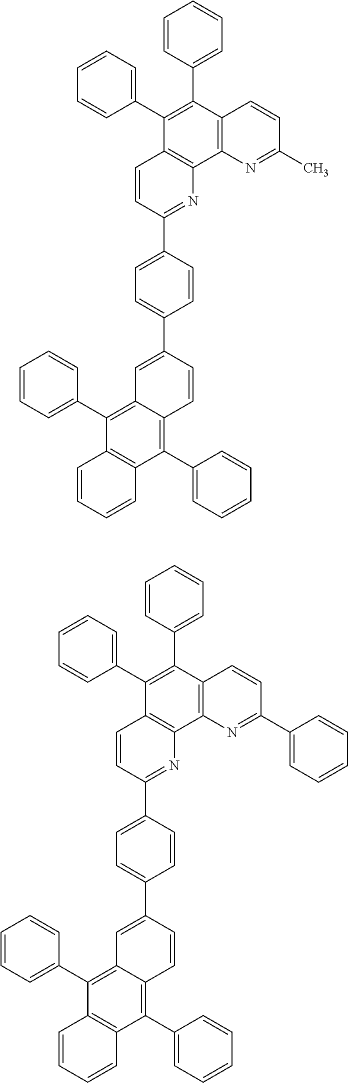 [SMILES: Cc1ccc2c(-c3ccccc3)c(-c3ccccc3)c3ccc(-c4ccc(-c5ccc6c(-c7ccccc7)c7ccccc7c(-c7ccccc7)c6c5)cc4)nc3c2n1 ; c1ccc(-c2ccc3c(-c4ccccc4)c(-c4ccccc4)c4ccc(-c5ccc(-c6ccc7c(-c8ccccc8)c8ccccc8c(-c8ccccc8)c7c6)cc5)nc4c3n2)cc1]

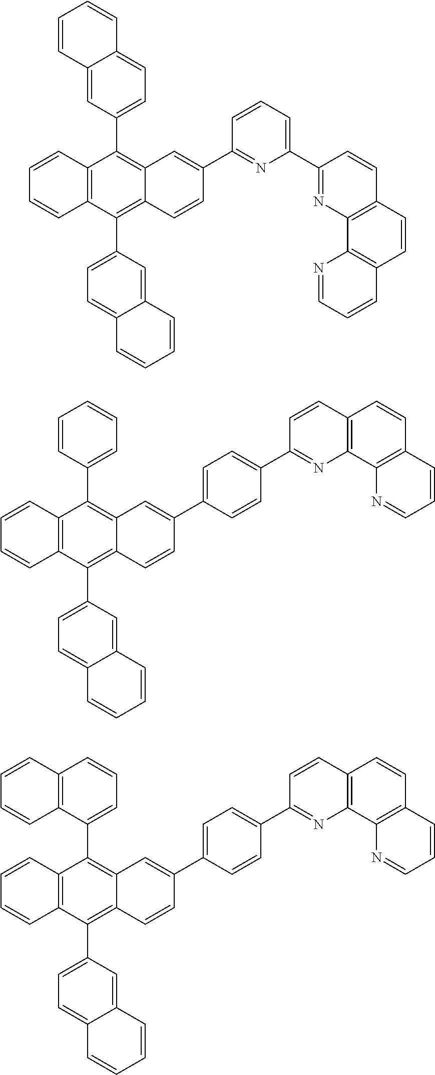 [SMILES: c1cc(-c2ccc3c(-c4ccc5ccccc5c4)c4ccccc4c(-c4ccc5ccccc5c4)c3c2)nc(-c2ccc3ccc4cccnc4c3n2)c1 ; c1ccc(-c2c3ccccc3c(-c3ccc4ccccc4c3)c3ccc(-c4ccc(-c5ccc6ccc7cccnc7c6n5)cc4)cc23)cc1 ; c1ccc2cc(-c3c4ccccc4c(-c4cccc5ccccc45)c4cc(-c5ccc(-c6ccc7ccc8cccnc8c7n6)cc5)ccc34)ccc2c1]

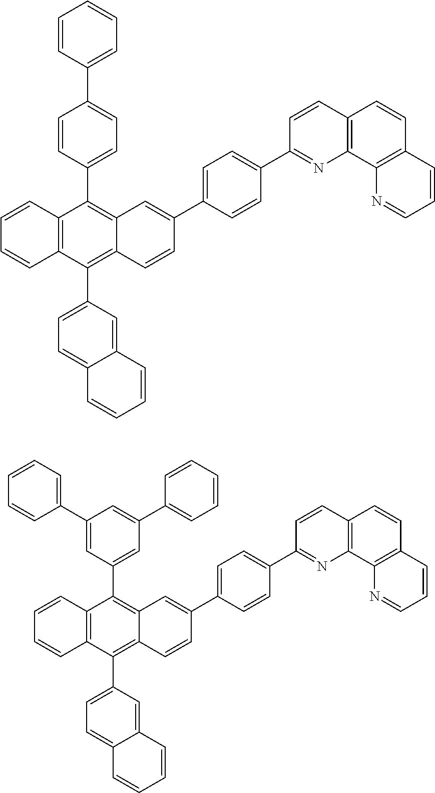 [SMILES: c1ccc(-c2ccc(-c3c4ccccc4c(-c4ccc5ccccc5c4)c4ccc(-c5ccc(-c6ccc7ccc8cccnc8c7n6)cc5)cc34)cc2)cc1 ; c1ccc(-c2cc(-c3ccccc3)cc(-c3c4ccccc4c(-c4ccc5ccccc5c4)c4ccc(-c5ccc(-c6ccc7ccc8cccnc8c7n6)cc5)cc34)c2)cc1]

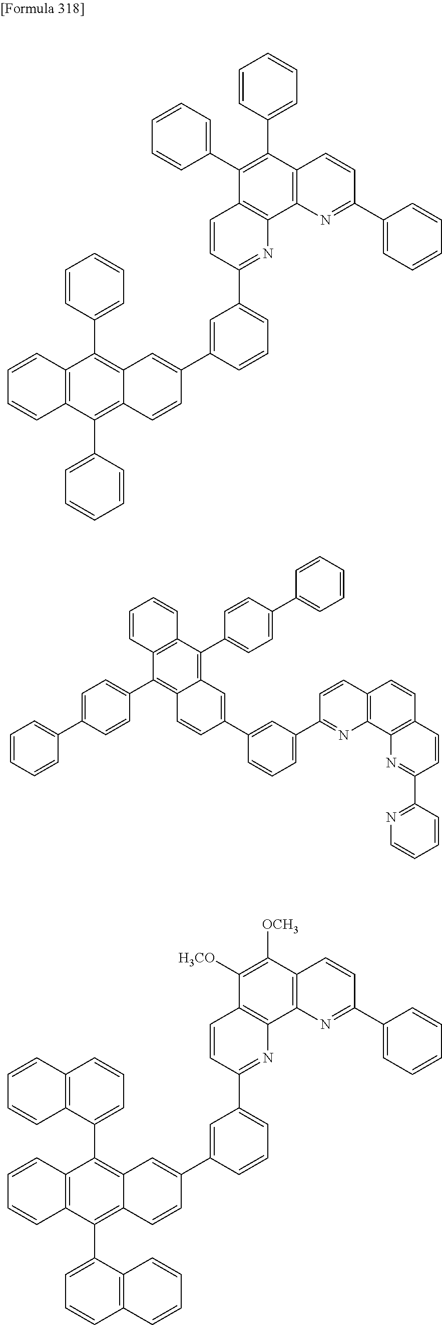 [SMILES: c1ccc(-c2ccc3c(-c4ccccc4)c(-c4ccccc4)c4ccc(-c5cccc(-c6ccc7c(-c8ccccc8)c8ccccc8c(-c8ccccc8)c7c6)c5)nc4c3n2)cc1 ; c1ccc(-c2ccc(-c3c4ccccc4c(-c4ccc(-c5ccccc5)cc4)c4cc(-c5cccc(-c6ccc7ccc8ccc(-c9ccccn9)nc8c7n6)c5)ccc34)cc2)cc1 ; COc1c(OC)c2ccc(-c3cccc(-c4ccc5c(-c6cccc7ccccc67)c6ccccc6c(-c6cccc7ccccc67)c5c4)c3)nc2c2nc(-c3ccccc3)ccc12]

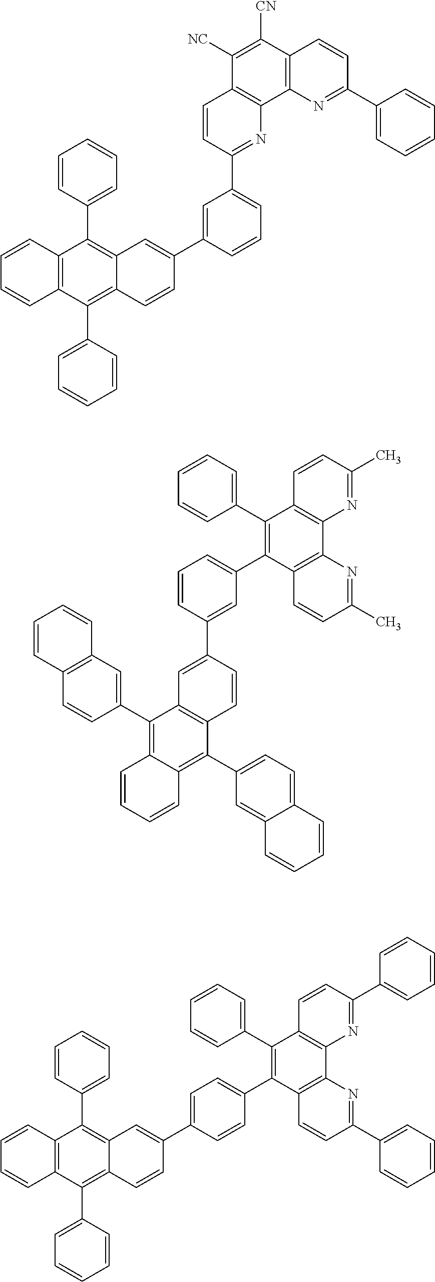 [SMILES: N#Cc1c(C#N)c2ccc(-c3cccc(-c4ccc5c(-c6ccccc6)c6ccccc6c(-c6ccccc6)c5c4)c3)nc2c2nc(-c3ccccc3)ccc12 ; Cc1ccc2c(-c3ccccc3)c(-c3cccc(-c4ccc5c(-c6ccc7ccccc7c6)c6ccccc6c(-c6ccc7ccccc7c6)c5c4)c3)c3ccc(C)nc3c2n1 ; c1ccc(-c2ccc3c(-c4ccccc4)c(-c4ccc(-c5ccc6c(-c7ccccc7)c7ccccc7c(-c7ccccc7)c6c5)cc4)c4ccc(-c5ccccc5)nc4c3n2)cc1]

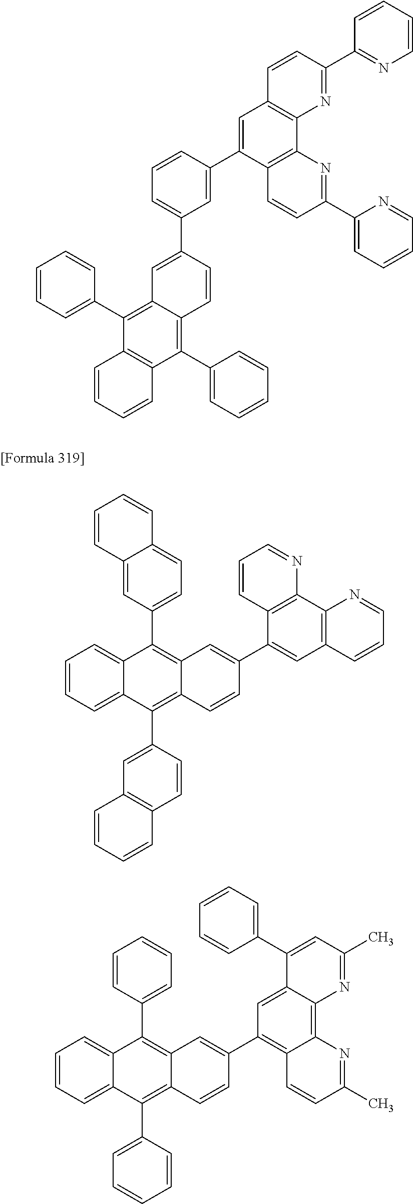 [SMILES: c1ccc(-c2c3ccccc3c(-c3ccccc3)c3cc(-c4cccc(-c5cc6ccc(-c7ccccn7)nc6c6nc(-c7ccccn7)ccc56)c4)ccc23)cc1 ; c1ccc2cc(-c3c4ccccc4c(-c4ccc5ccccc5c4)c4cc(-c5cc6cccnc6c6ncccc56)ccc34)ccc2c1 ; Cc1ccc2c(-c3ccc4c(-c5ccccc5)c5ccccc5c(-c5ccccc5)c4c3)cc3c(-c4ccccc4)cc(C)nc3c2n1]

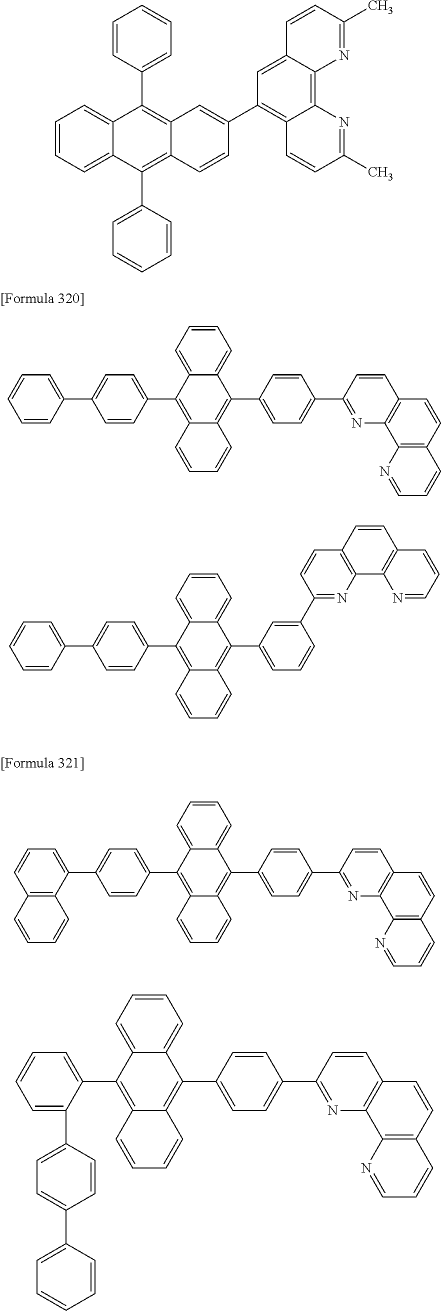

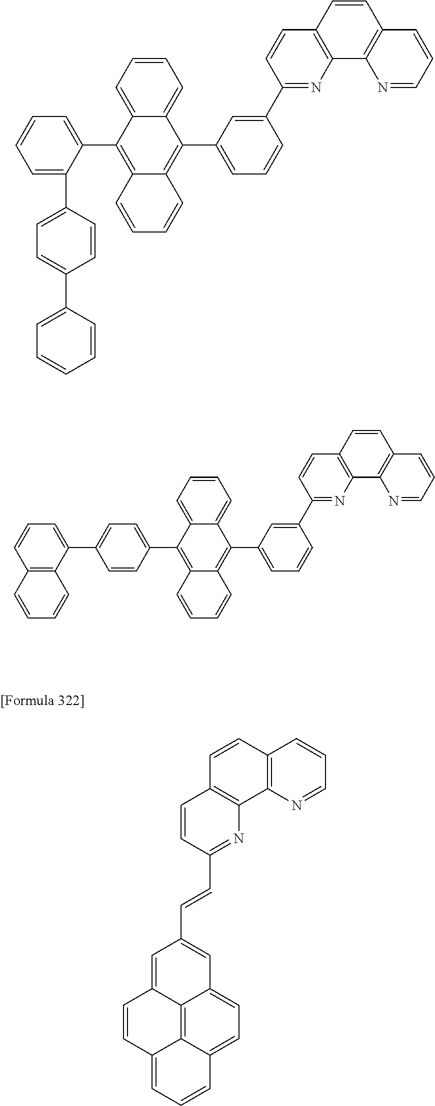 [SMILES: c1ccc(-c2ccc(-c3ccccc3-c3c4ccccc4c(-c4cccc(-c5ccc6ccc7cccnc7c6n5)c4)c4ccccc34)cc2)cc1 ; c1cc(-c2ccc3ccc4cccnc4c3n2)cc(-c2c3ccccc3c(-c3ccc(-c4cccc5ccccc45)cc3)c3ccccc23)c1 ; C(=C\c1ccc2ccc3cccnc3c2n1)/c1cc2ccc3cccc4ccc(c1)c2c34]

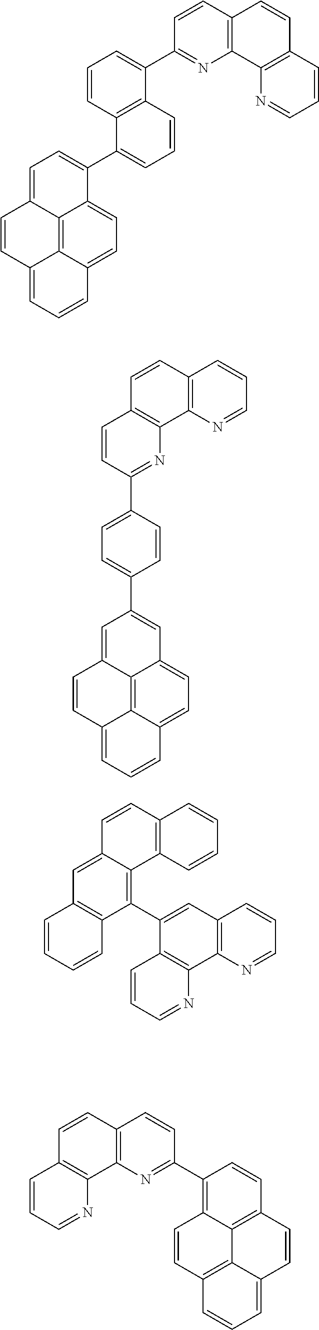

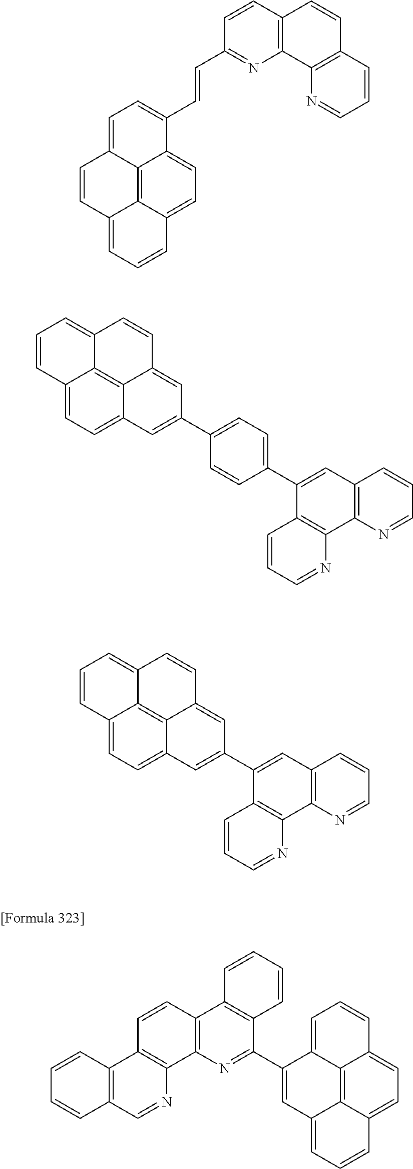 [SMILES: C(=C\c1ccc2ccc3cccc4ccc1c2c34)/c1ccc2ccc3cccnc3c2n1 ; c1cnc2c(c1)cc(-c1ccc(-c3cc4ccc5cccc6ccc(c3)c4c56)cc1)c1cccnc12 ; c1cnc2c(c1)cc(-c1cc3ccc4cccc5ccc(c1)c3c45)c1cccnc12 ; c1ccc2c(c1)cnc1c2ccc2c3ccccc3c(-c3cc4cccc5ccc6cccc3c6c54)nc21]

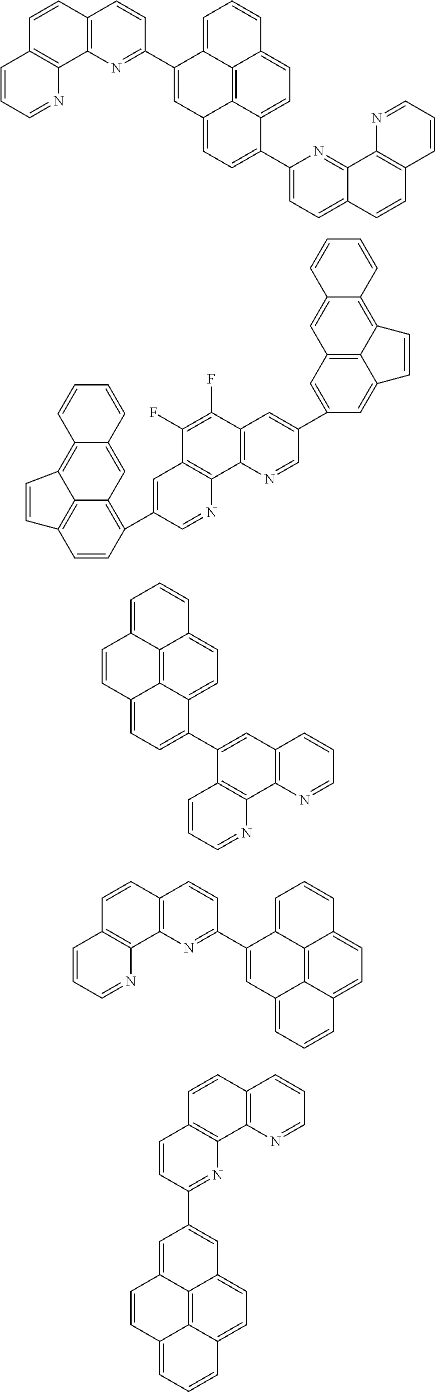

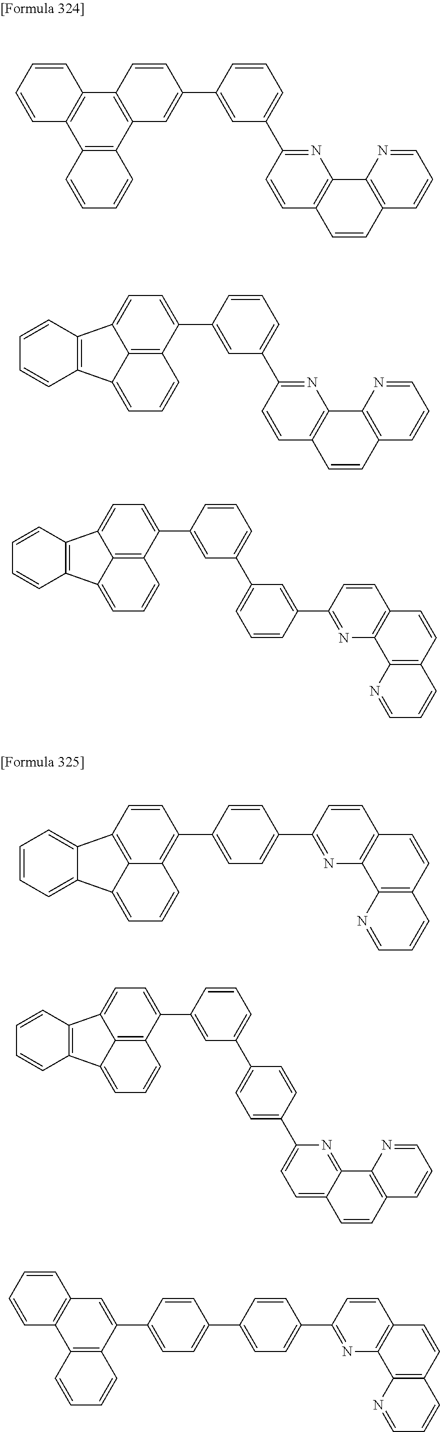 [SMILES: c1cc(-c2ccc3c4ccccc4c4ccccc4c3c2)cc(-c2ccc3ccc4cccnc4c3n2)c1 ; c1cc(-c2ccc3ccc4cccnc4c3n2)cc(-c2ccc3c4c(cccc24)-c2ccccc2-3)c1 ; c1cc(-c2cccc(-c3ccc4c5c(cccc35)-c3ccccc3-4)c2)cc(-c2ccc3ccc4cccnc4c3n2)c1 ; c1ccc2c(c1)-c1cccc3c(-c4ccc(-c5ccc6ccc7cccnc7c6n5)cc4)ccc-2c13 ; c1cc(-c2ccc(-c3ccc4ccc5cccnc5c4n3)cc2)cc(-c2ccc3c4c(cccc24)-c2ccccc2-3)c1 ; c1ccc2c(c1)cc(-c1ccc(-c3ccc(-c4ccc5ccc6cccnc6c5n4)cc3)cc1)c1ccccc12]

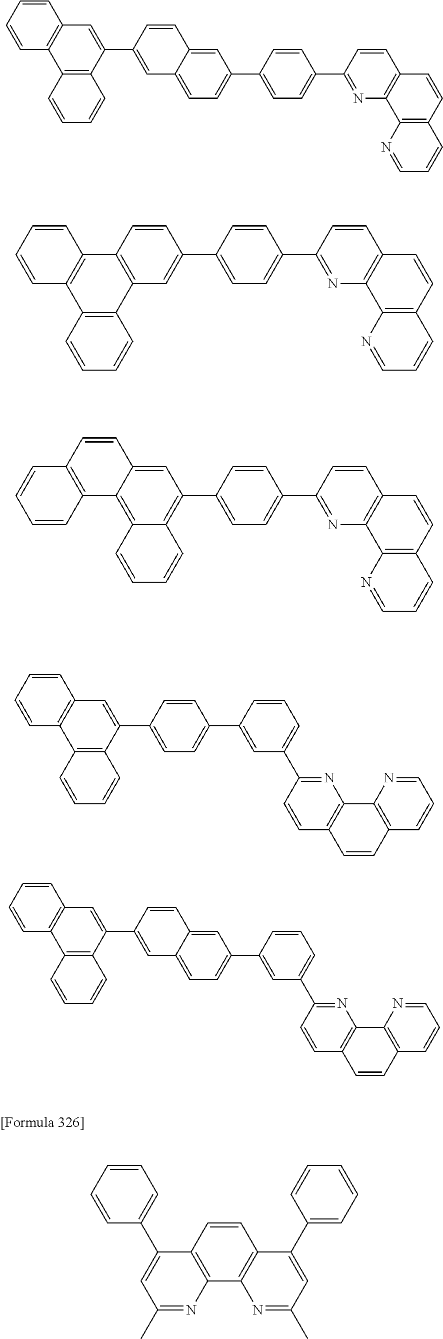 [SMILES: c1ccc2c(c1)cc(-c1ccc3cc(-c4ccc(-c5ccc6ccc7cccnc7c6n5)cc4)ccc3c1)c1ccccc12 ; c1cnc2c(c1)ccc1ccc(-c3ccc(-c4ccc5c6ccccc6c6ccccc6c5c4)cc3)nc12 ; c1ccc2c(c1)ccc1cc(-c3ccc(-c4ccc5ccc6cccnc6c5n4)cc3)c3ccccc3c12 ; c1cc(-c2ccc(-c3cc4ccccc4c4ccccc34)cc2)cc(-c2ccc3ccc4cccnc4c3n2)c1 ; c1cc(-c2ccc3cc(-c4cc5ccccc5c5ccccc45)ccc3c2)cc(-c2ccc3ccc4cccnc4c3n2)c1 ; Cc1cc(-c2ccccc2)c2ccc3c(-c4ccccc4)cc(C)nc3c2n1]

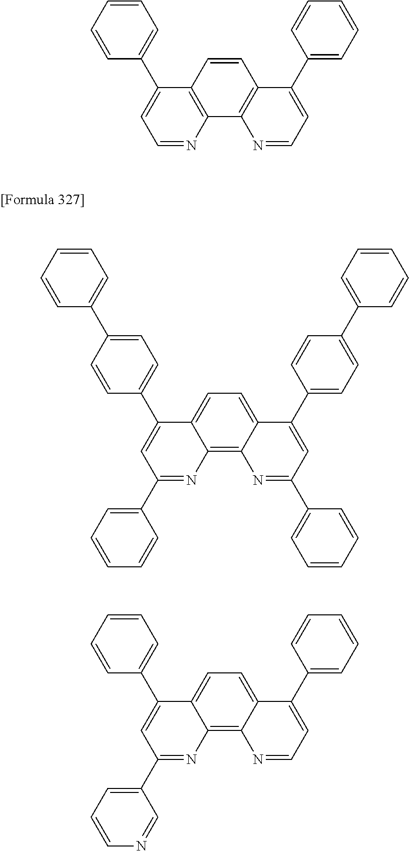 [SMILES: c1ccc(-c2ccnc3c2ccc2c(-c4ccccc4)ccnc23)cc1 ; c1ccc(-c2ccc(-c3cc(-c4ccccc4)nc4c3ccc3c(-c5ccc(-c6ccccc6)cc5)cc(-c5ccccc5)nc34)cc2)cc1 ; c1ccc(-c2ccnc3c2ccc2c(-c4ccccc4)cc(-c4cccnc4)nc23)cc1]

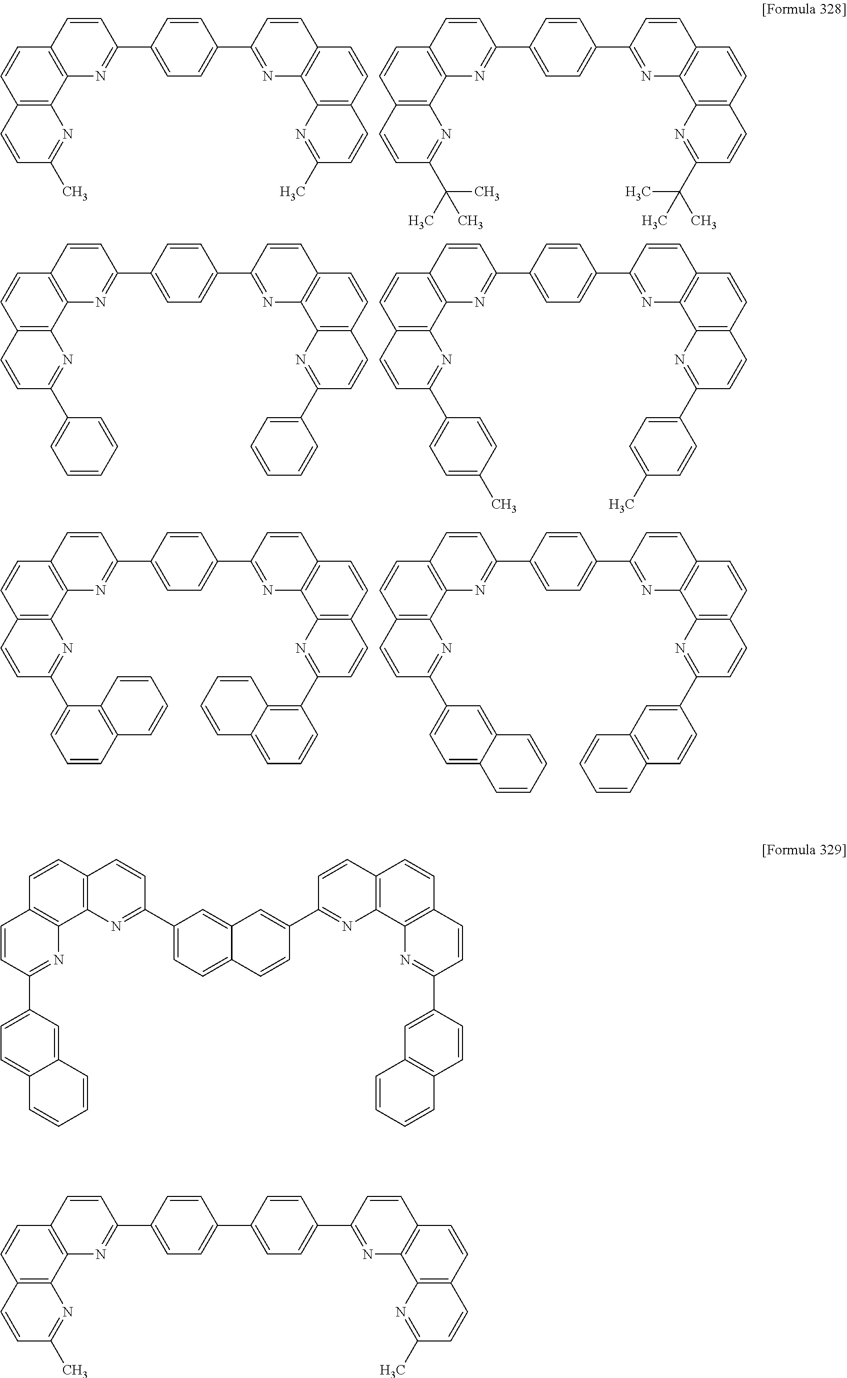

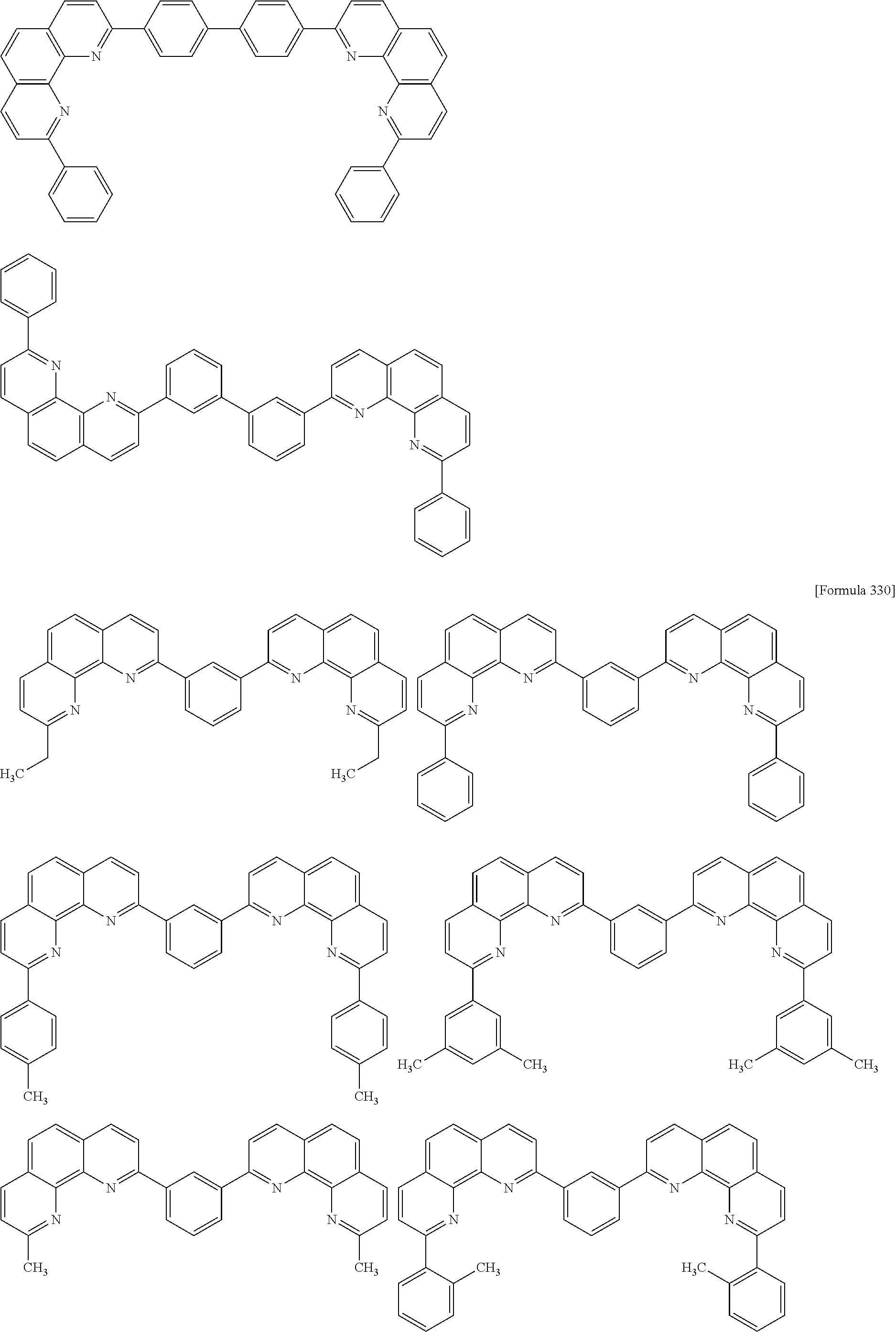

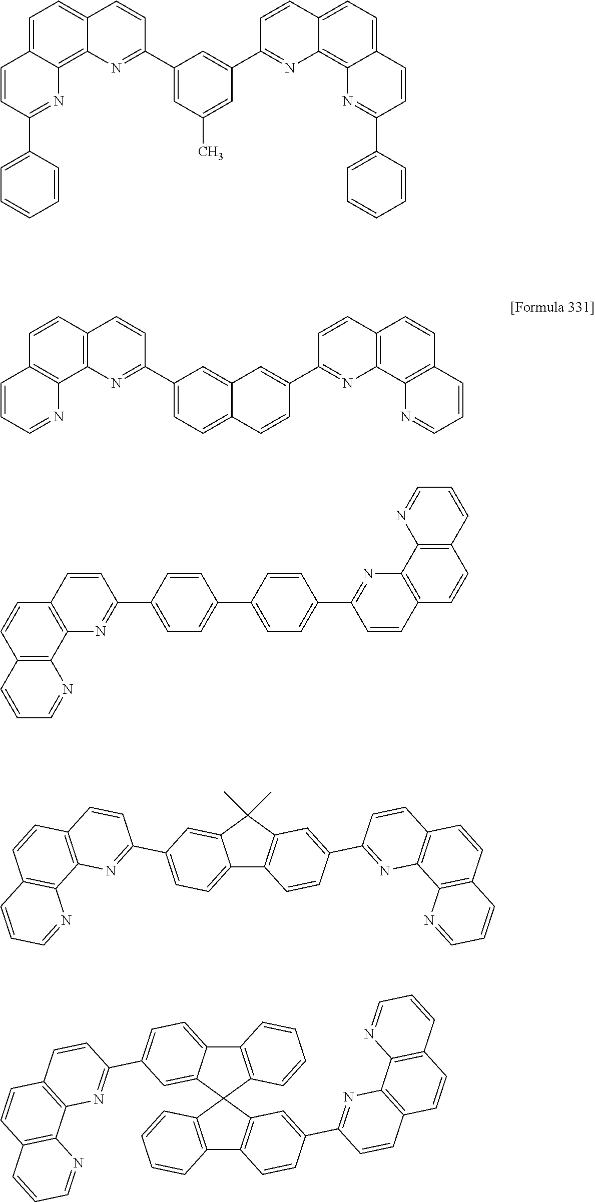 [SMILES: Cc1cc(-c2ccc3ccc4ccc(-c5ccccc5)nc4c3n2)cc(-c2ccc3ccc4ccc(-c5ccccc5)nc4c3n2)c1 ; c1cnc2c(c1)ccc1ccc(-c3ccc4ccc(-c5ccc6ccc7cccnc7c6n5)cc4c3)nc12 ; c1cnc2c(c1)ccc1ccc(-c3ccc(-c4ccc(-c5ccc6ccc7cccnc7c6n5)cc4)cc3)nc12 ; CC1(C)c2cc(-c3ccc4ccc5cccnc5c4n3)ccc2-c2ccc(-c3ccc4ccc5cccnc5c4n3)cc21 ; c1ccc2c(c1)-c1ccc(-c3ccc4ccc5cccnc5c4n3)cc1C21c2ccccc2-c2ccc(-c3ccc4ccc5cccnc5c4n3)cc21]

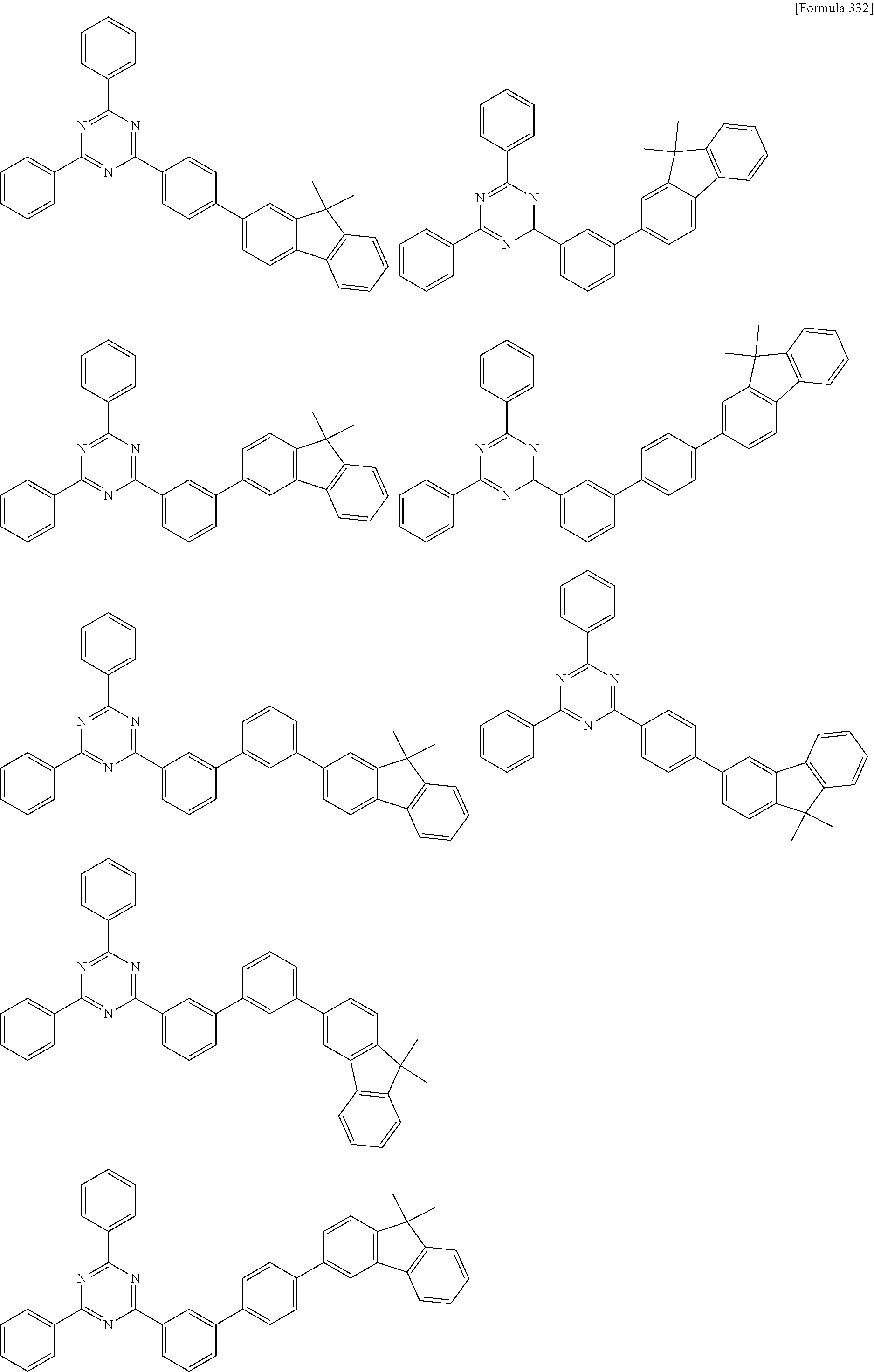

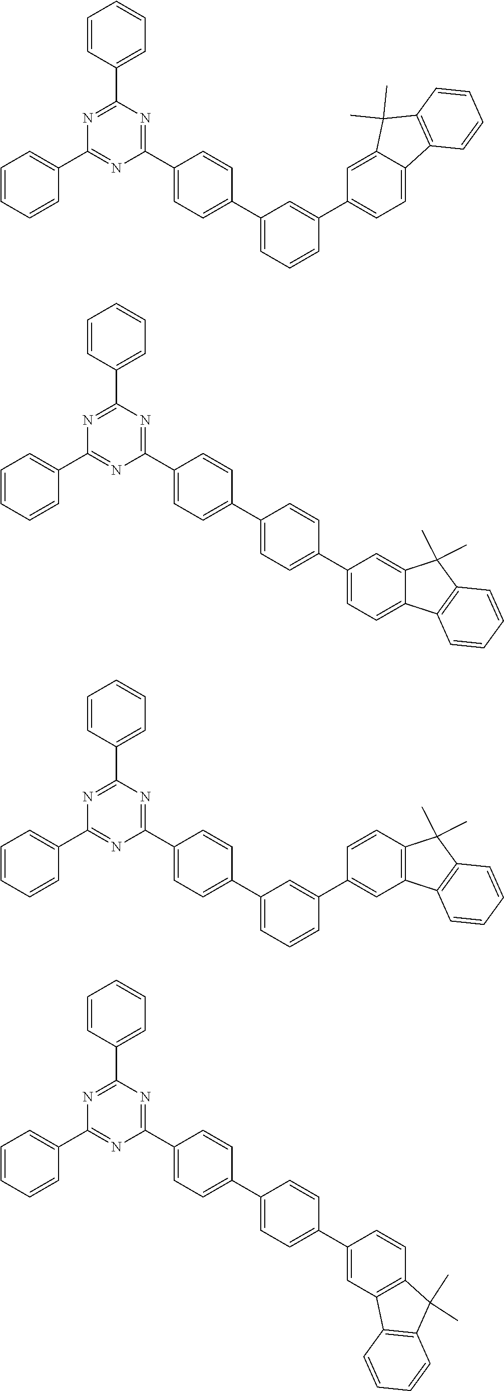 [SMILES: CC1(C)c2ccccc2-c2ccc(-c3cccc(-c4ccc(-c5nc(-c6ccccc6)nc(-c6ccccc6)n5)cc4)c3)cc21 ; CC1(C)c2ccccc2-c2ccc(-c3ccc(-c4ccc(-c5nc(-c6ccccc6)nc(-c6ccccc6)n5)cc4)cc3)cc21 ; CC1(C)c2ccccc2-c2cc(-c3cccc(-c4ccc(-c5nc(-c6ccccc6)nc(-c6ccccc6)n5)cc4)c3)ccc21 ; CC1(C)c2ccccc2-c2cc(-c3ccc(-c4ccc(-c5nc(-c6ccccc6)nc(-c6ccccc6)n5)cc4)cc3)ccc21]

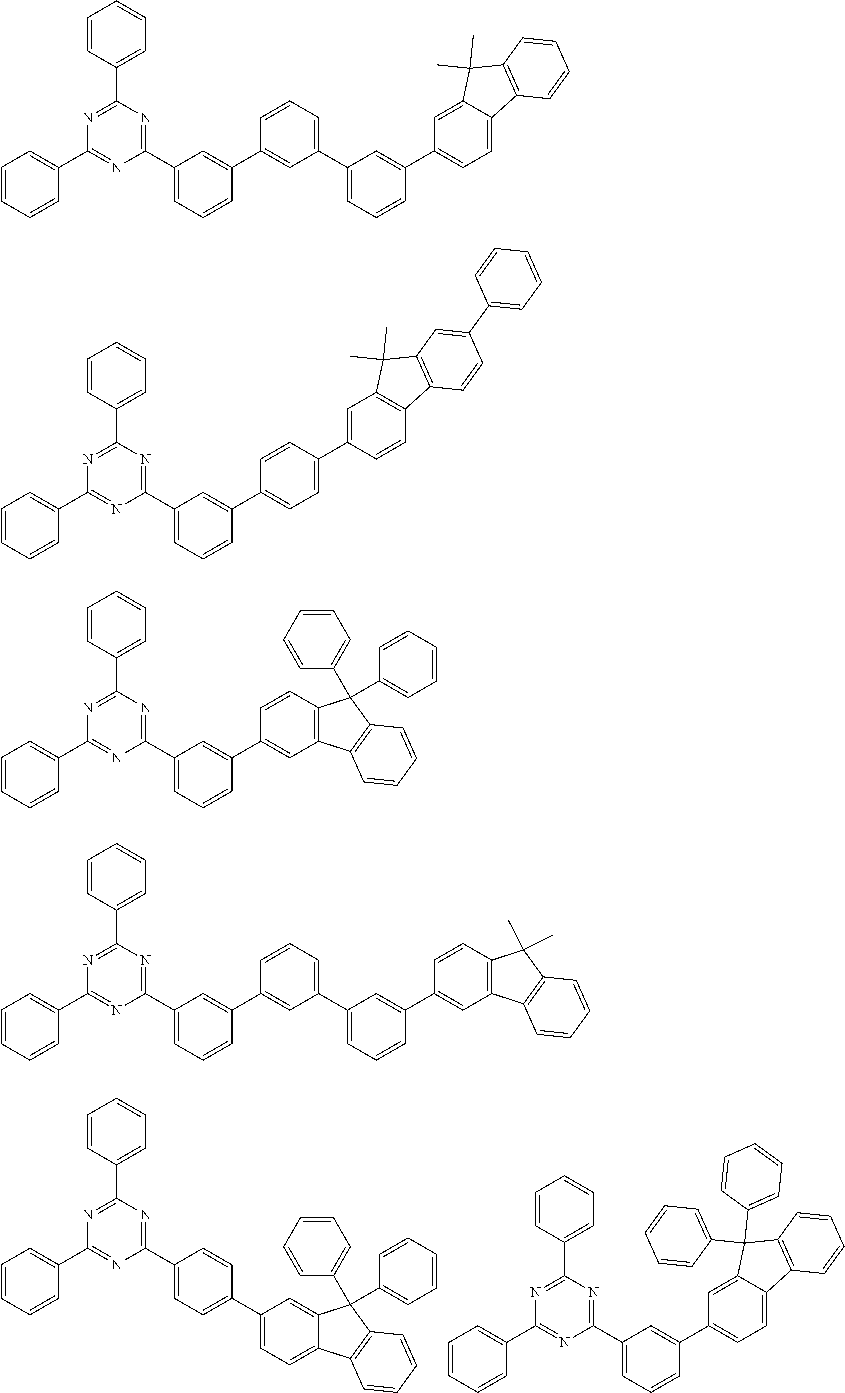

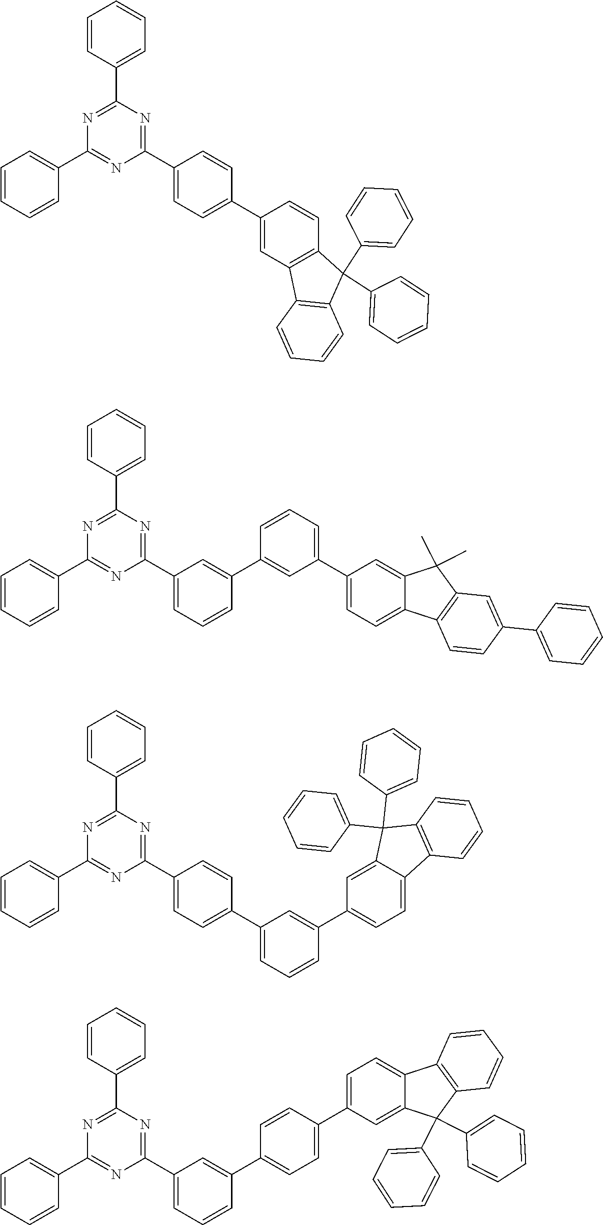 [SMILES: c1ccc(-c2nc(-c3ccccc3)nc(-c3ccc(-c4ccc5c(c4)-c4ccccc4C5(c4ccccc4)c4ccccc4)cc3)n2)cc1 ; CC1(C)c2cc(-c3ccccc3)ccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3ccc(-c4cccc(-c5ccc6c(c5)C(c5ccccc5)(c5ccccc5)c5ccccc5-6)c4)cc3)n2)cc1 ; c1ccc(-c2nc(-c3ccccc3)nc(-c3cccc(-c4ccc(-c5ccc6c(c5)C(c5ccccc5)(c5ccccc5)c5ccccc5-6)cc4)c3)n2)cc1]

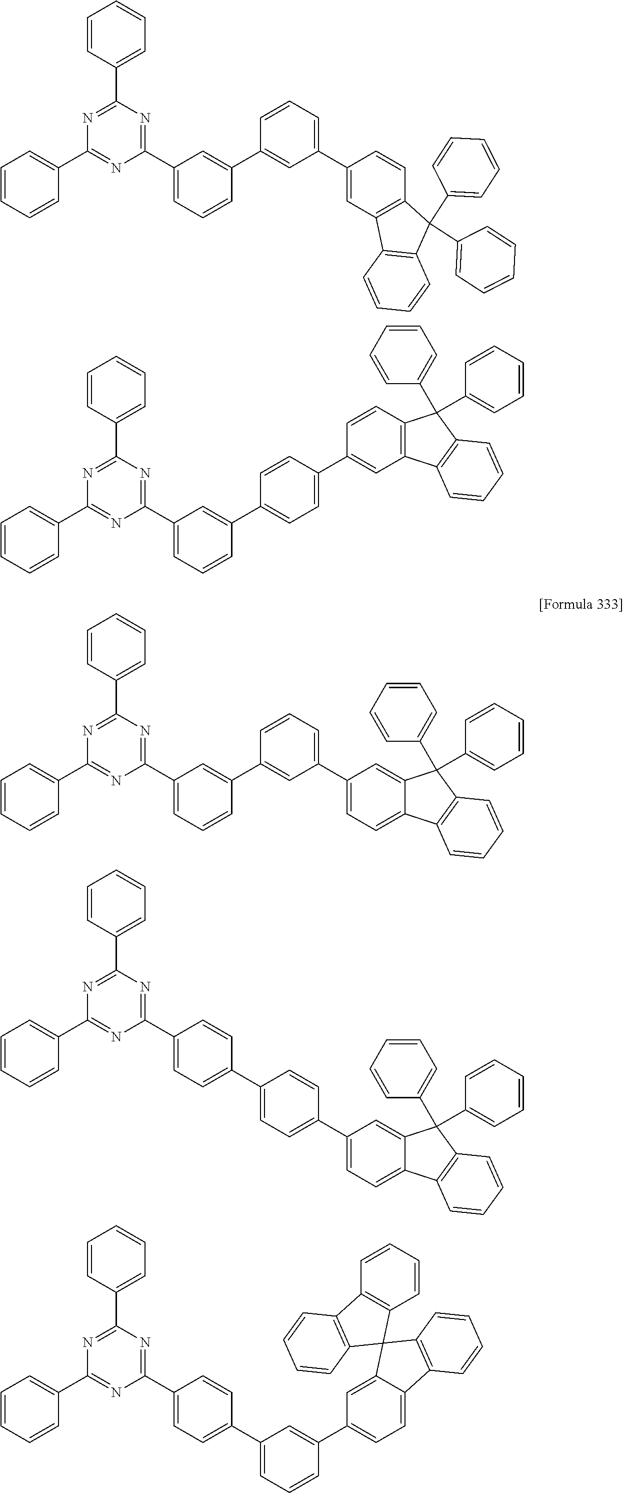

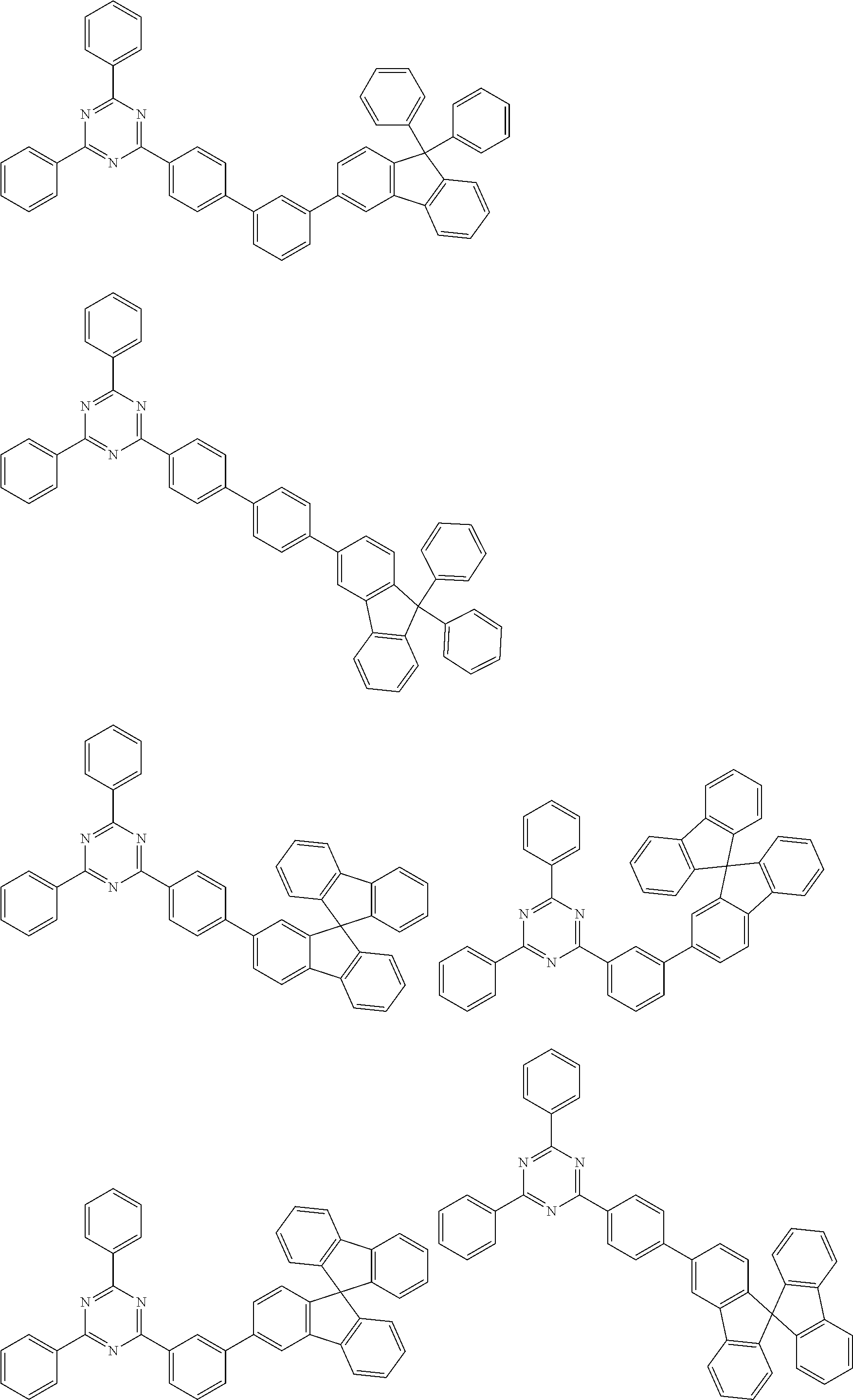

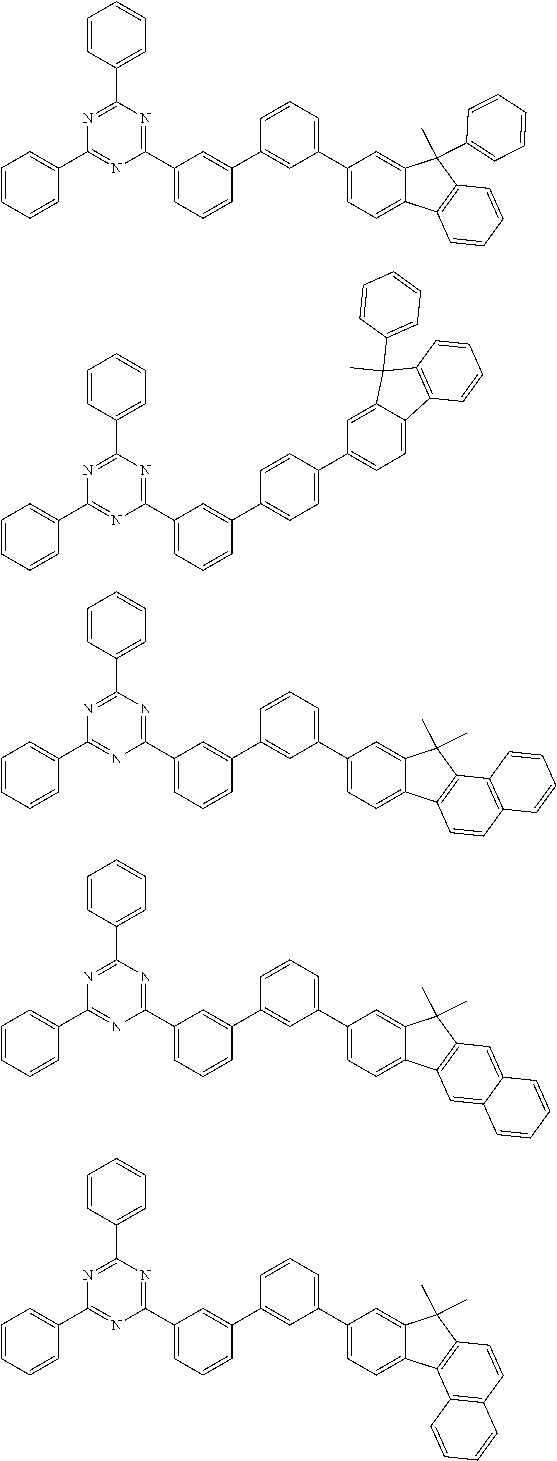 [SMILES: CC1(c2ccccc2)c2ccccc2-c2ccc(-c3cccc(-c4cccc(-c5nc(-c6ccccc6)nc(-c6ccccc6)n5)c4)c3)cc21 ; CC1(c2ccccc2)c2ccccc2-c2ccc(-c3ccc(-c4cccc(-c5nc(-c6ccccc6)nc(-c6ccccc6)n5)c4)cc3)cc21 ; CC1(C)c2cc(-c3cccc(-c4cccc(-c5nc(-c6ccccc6)nc(-c6ccccc6)n5)c4)c3)ccc2-c2ccc3ccccc3c21 ; CC1(C)c2cc(-c3cccc(-c4cccc(-c5nc(-c6ccccc6)nc(-c6ccccc6)n5)c4)c3)ccc2-c2cc3ccccc3cc21 ; CC1(C)c2cc(-c3cccc(-c4cccc(-c5nc(-c6ccccc6)nc(-c6ccccc6)n5)c4)c3)ccc2-c2c1ccc1ccccc21]

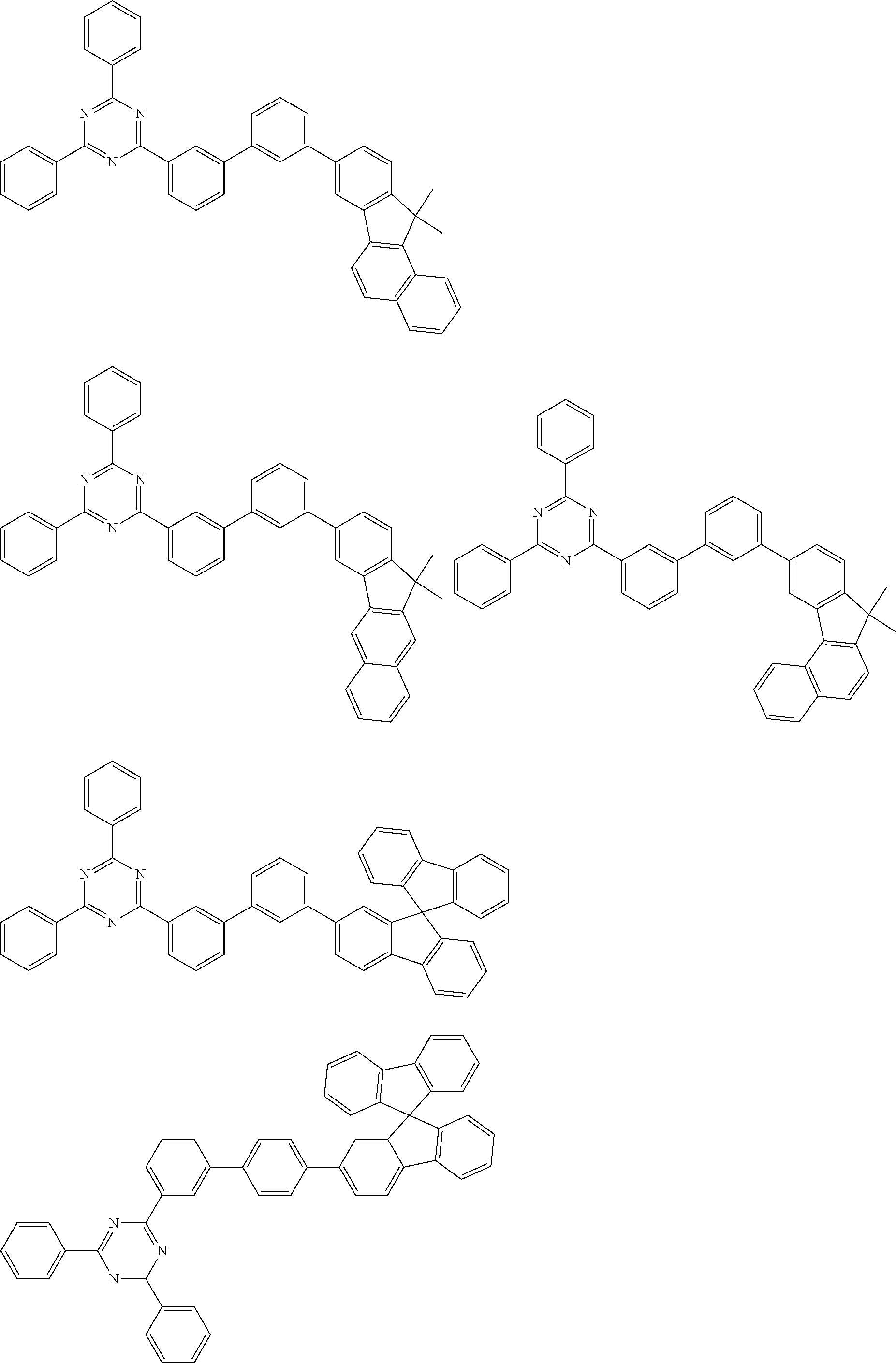

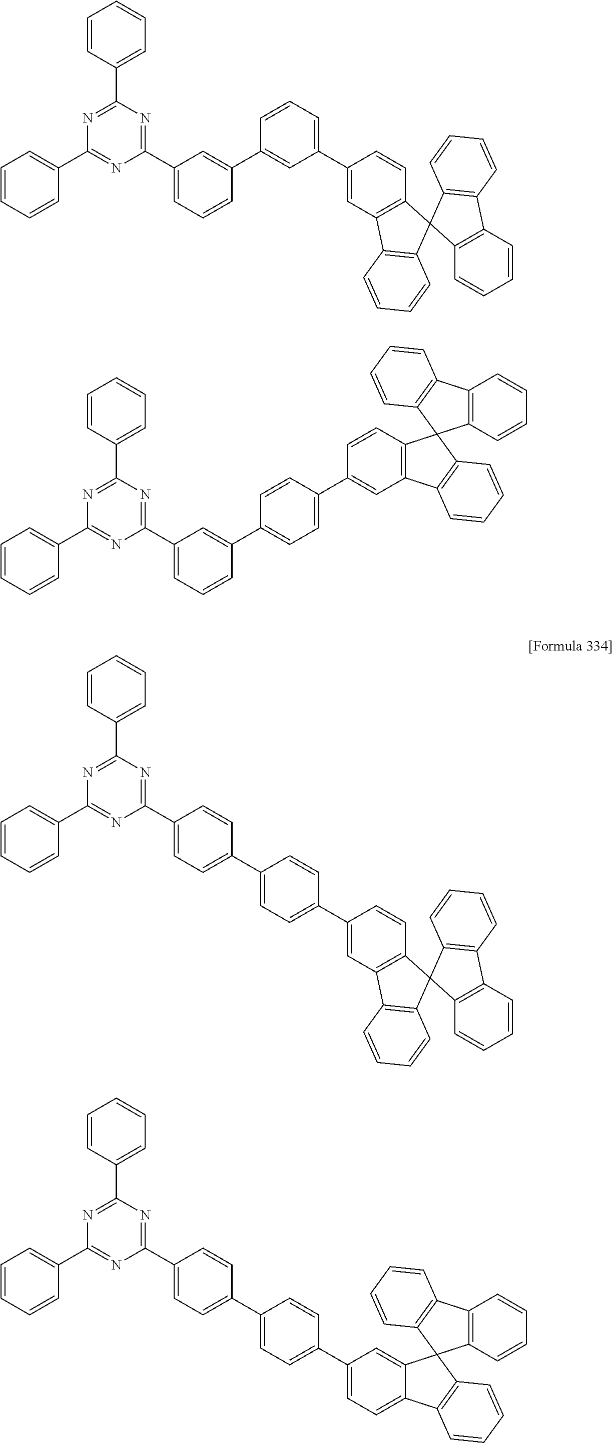

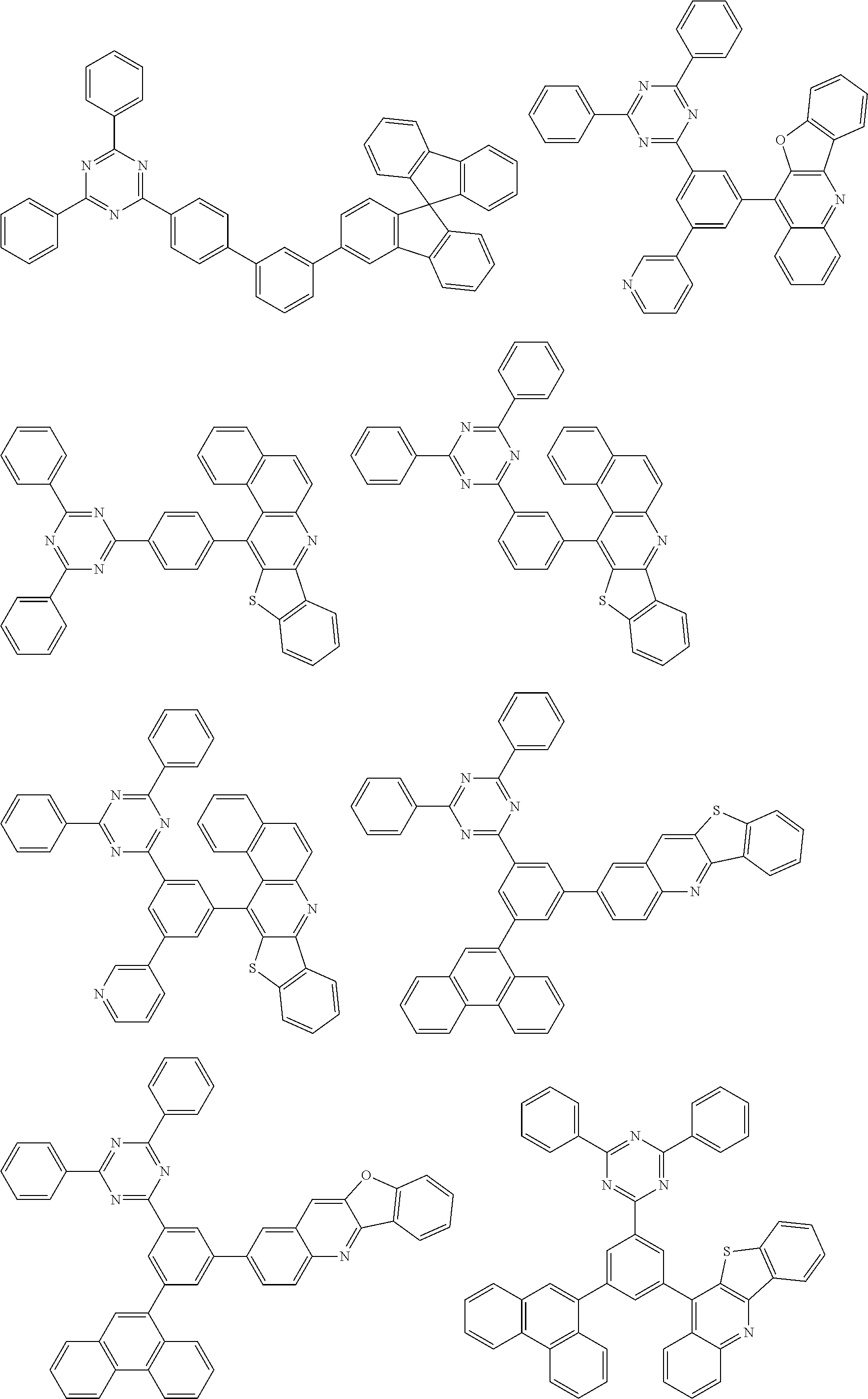

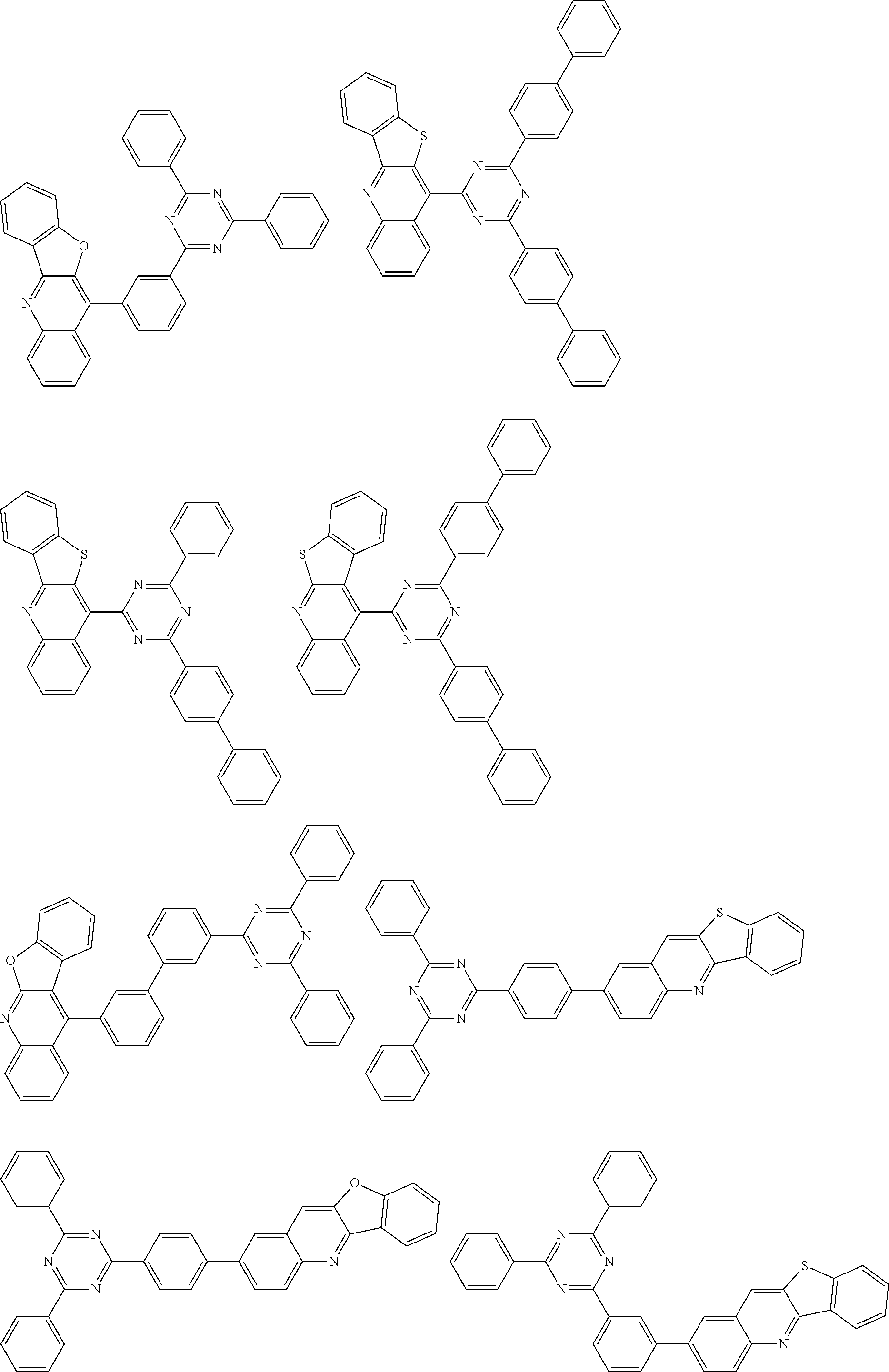

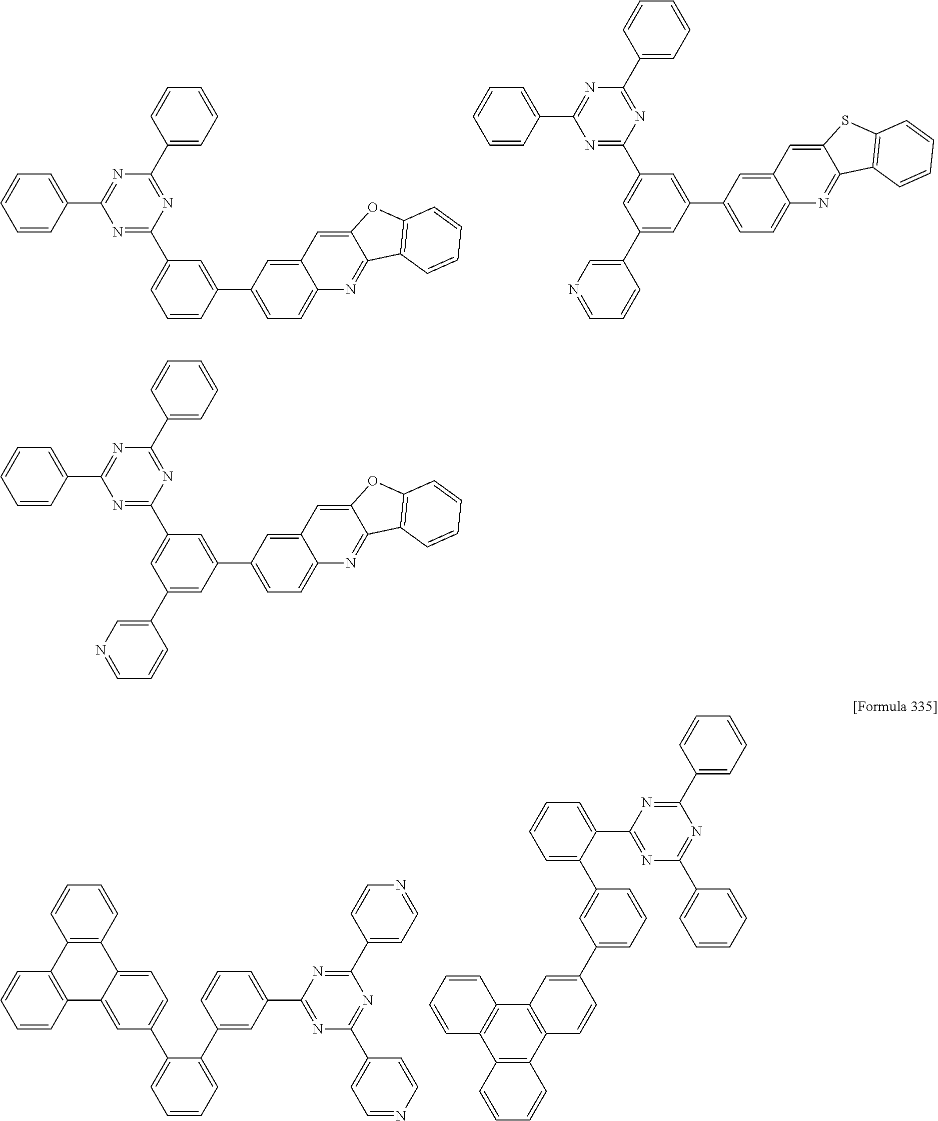

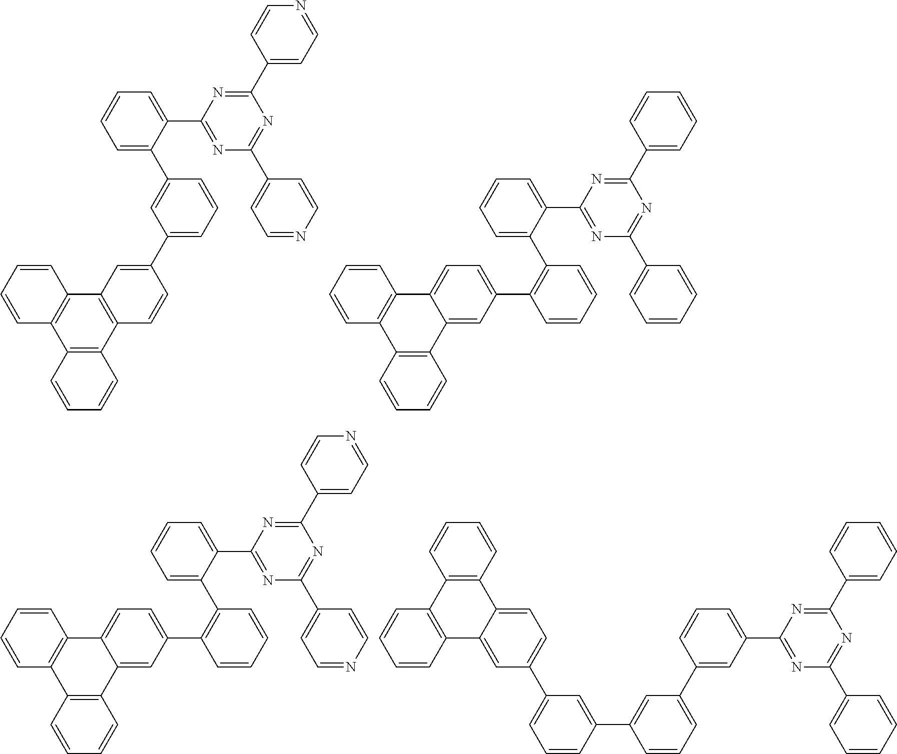

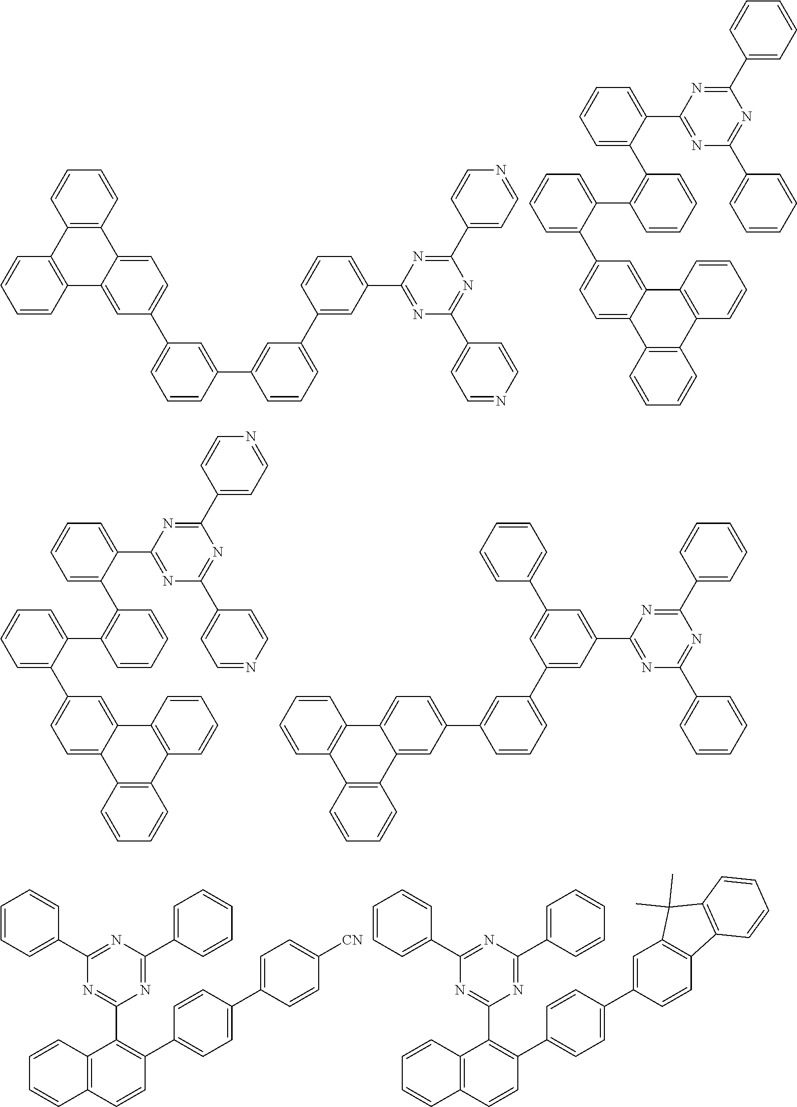

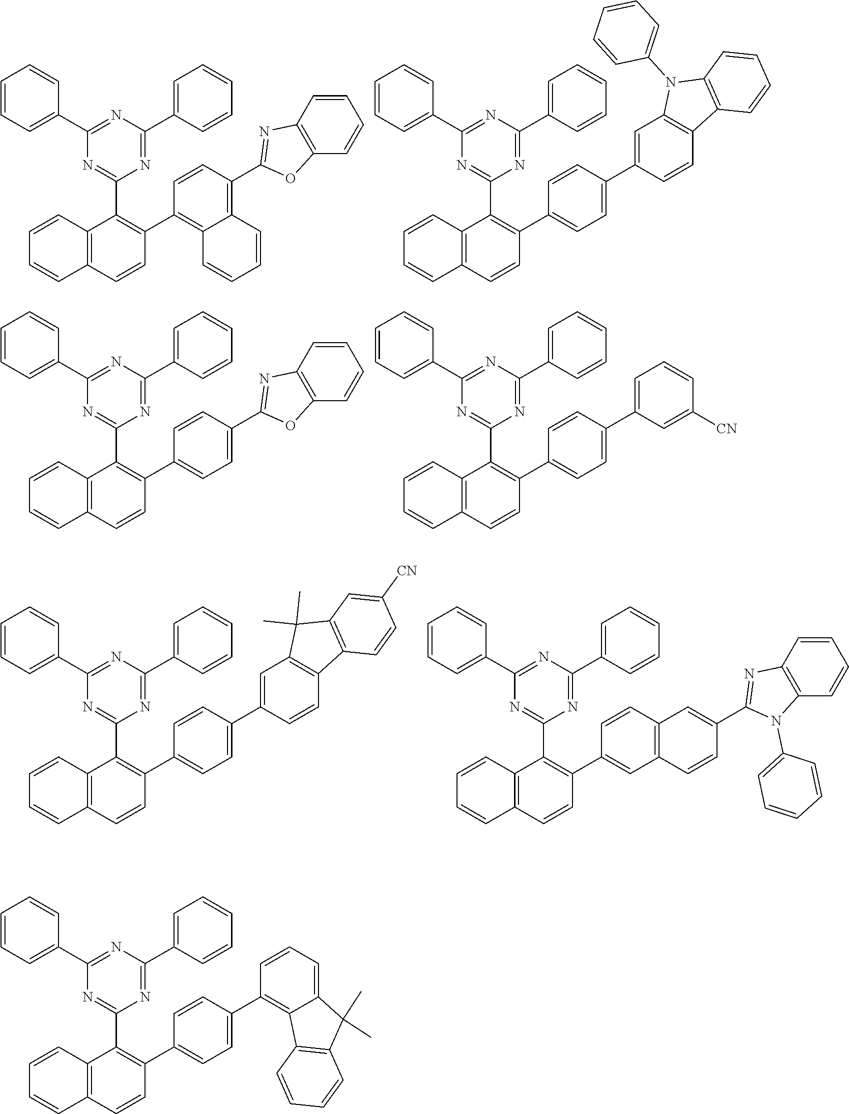

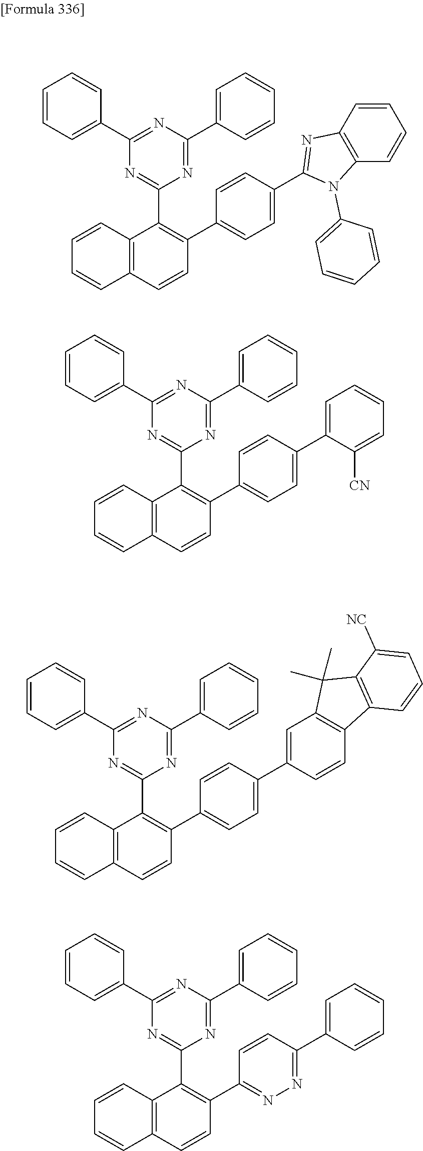

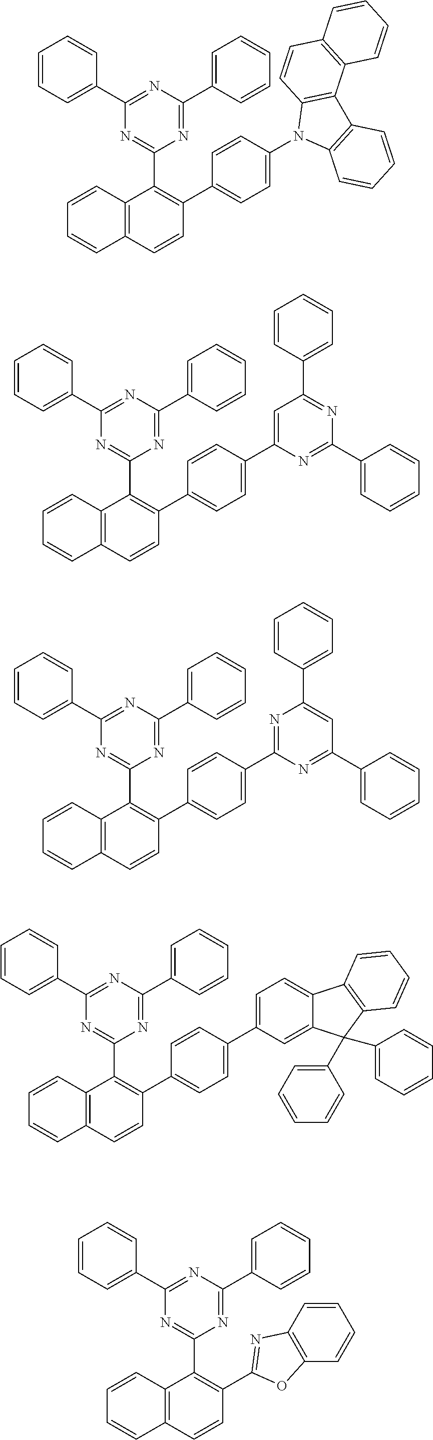 [SMILES: c1ccc(-c2nc(-c3ccccc3)nc(-c3c(-c4ccc(-n5c6ccccc6c6c7ccccc7ccc65)cc4)ccc4ccccc34)n2)cc1 ; c1ccc(-c2cc(-c3ccc(-c4ccc5ccccc5c4-c4nc(-c5ccccc5)nc(-c5ccccc5)n4)cc3)nc(-c3ccccc3)n2)cc1 ; c1ccc(-c2cc(-c3ccccc3)nc(-c3ccc(-c4ccc5ccccc5c4-c4nc(-c5ccccc5)nc(-c5ccccc5)n4)cc3)n2)cc1 ; c1ccc(-c2nc(-c3ccccc3)nc(-c3c(-c4ccc(-c5ccc6c(c5)C(c5ccccc5)(c5ccccc5)c5ccccc5-6)cc4)ccc4ccccc34)n2)cc1 ; c1ccc(-c2nc(-c3ccccc3)nc(-c3c(-c4nc5ccccc5o4)ccc4ccccc34)n2)cc1]

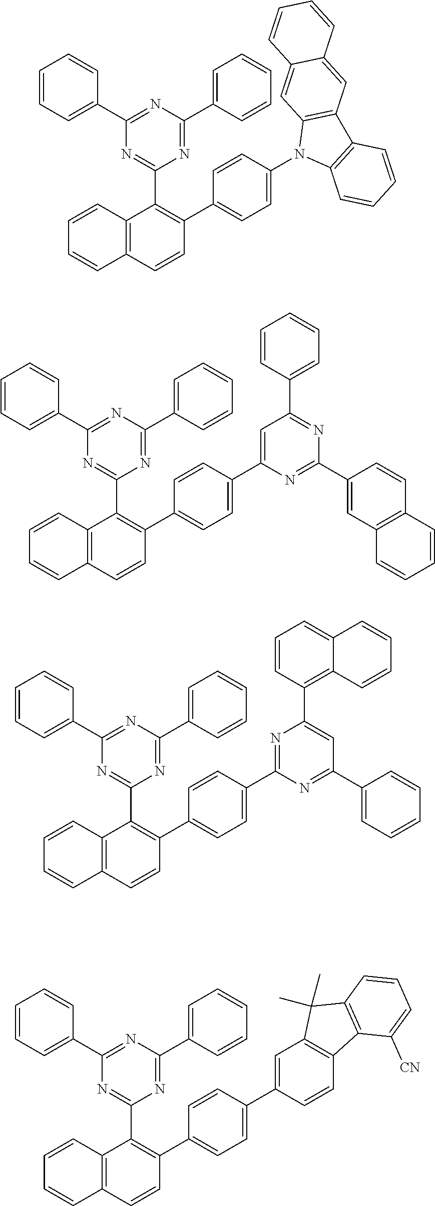 [SMILES: c1ccc(-c2nc(-c3ccccc3)nc(-c3c(-c4ccc(-n5c6ccccc6c6cc7ccccc7cc65)cc4)ccc4ccccc34)n2)cc1 ; c1ccc(-c2cc(-c3ccc(-c4ccc5ccccc5c4-c4nc(-c5ccccc5)nc(-c5ccccc5)n4)cc3)nc(-c3ccc4ccccc4c3)n2)cc1 ; c1ccc(-c2cc(-c3cccc4ccccc34)nc(-c3ccc(-c4ccc5ccccc5c4-c4nc(-c5ccccc5)nc(-c5ccccc5)n4)cc3)n2)cc1 ; CC1(C)c2cc(-c3ccc(-c4ccc5ccccc5c4-c4nc(-c5ccccc5)nc(-c5ccccc5)n4)cc3)ccc2-c2c(C#N)cccc21]

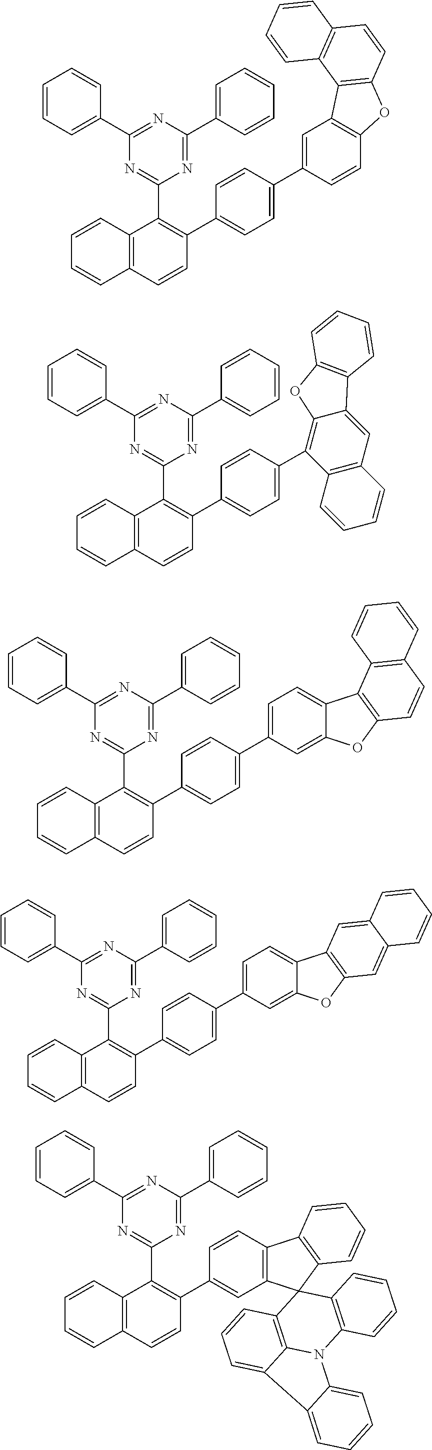

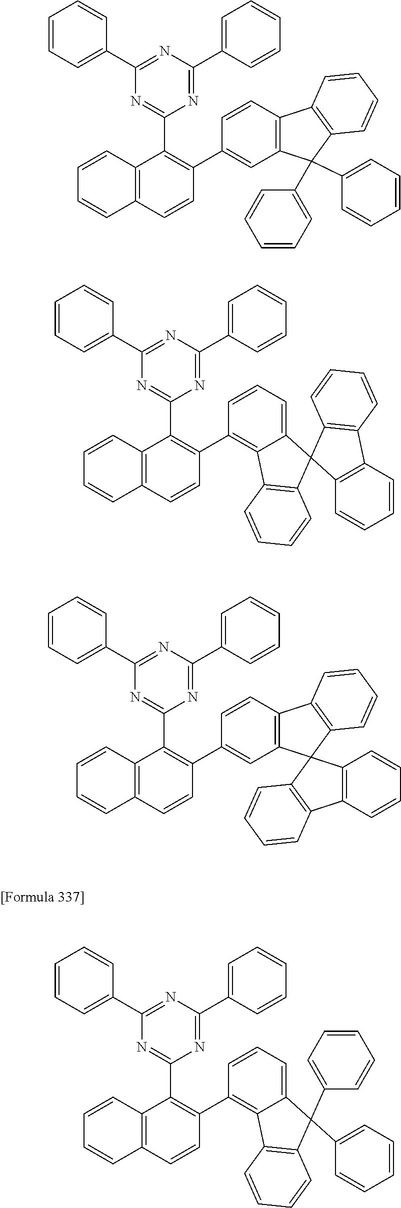

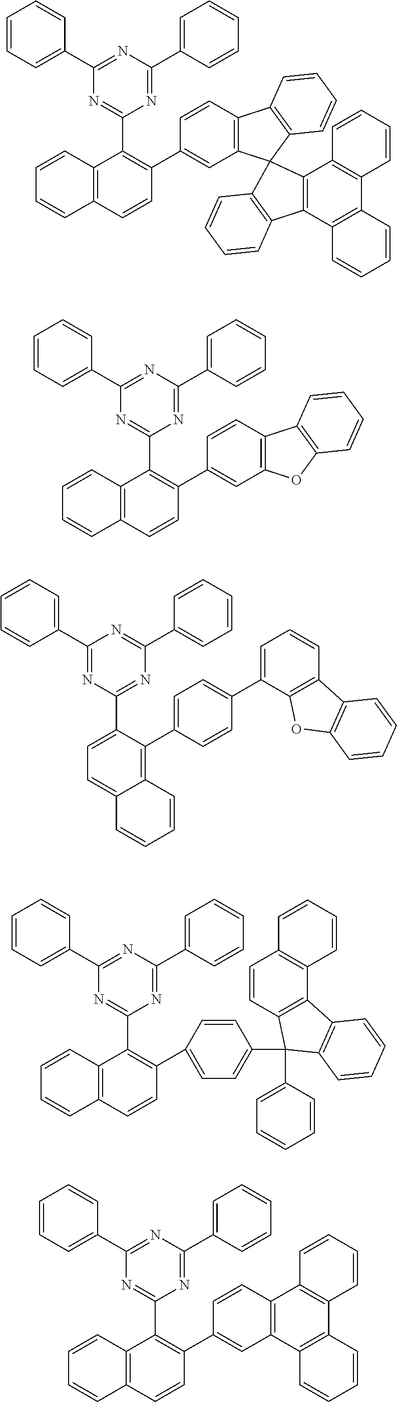 [SMILES: c1ccc(-c2nc(-c3ccccc3)nc(-c3c(-c4ccc5c(c4)C4(c6ccccc6-5)c5ccccc5-c5c4c4ccccc4c4ccccc54)ccc4ccccc34)n2)cc1 ; c1ccc(-c2nc(-c3ccccc3)nc(-c3c(-c4ccc5c(c4)oc4ccccc45)ccc4ccccc34)n2)cc1 ; c1ccc(-c2nc(-c3ccccc3)nc(-c3ccc4ccccc4c3-c3ccc(-c4cccc5c4oc4ccccc45)cc3)n2)cc1 ; c1ccc(-c2nc(-c3ccccc3)nc(-c3c(-c4ccc(C5(c6ccccc6)c6ccccc6-c6c5ccc5ccccc65)cc4)ccc4ccccc34)n2)cc1 ; c1ccc(-c2nc(-c3ccccc3)nc(-c3c(-c4ccc5c6ccccc6c6ccccc6c5c4)ccc4ccccc34)n2)cc1]

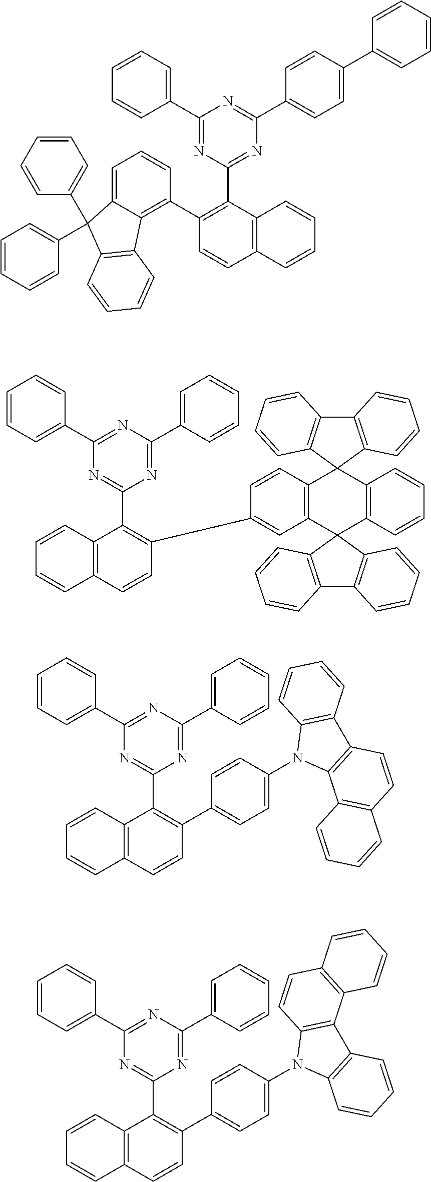 [SMILES: c1ccc(-c2ccc(-c3nc(-c4ccccc4)nc(-c4c(-c5cccc6c5-c5ccccc5C6(c5ccccc5)c5ccccc5)ccc5ccccc45)n3)cc2)cc1 ; c1ccc(-c2nc(-c3ccccc3)nc(-c3c(-c4ccc5c(c4)C4(c6ccccc6-c6ccccc64)c4ccccc4C54c5ccccc5-c5ccccc54)ccc4ccccc34)n2)cc1 ; c1ccc(-c2nc(-c3ccccc3)nc(-c3c(-c4ccc(-n5c6ccccc6c6ccc7ccccc7c65)cc4)ccc4ccccc34)n2)cc1 ; c1ccc(-c2nc(-c3ccccc3)nc(-c3c(-c4ccc(-n5c6ccccc6c6c7ccccc7ccc65)cc4)ccc4ccccc34)n2)cc1]

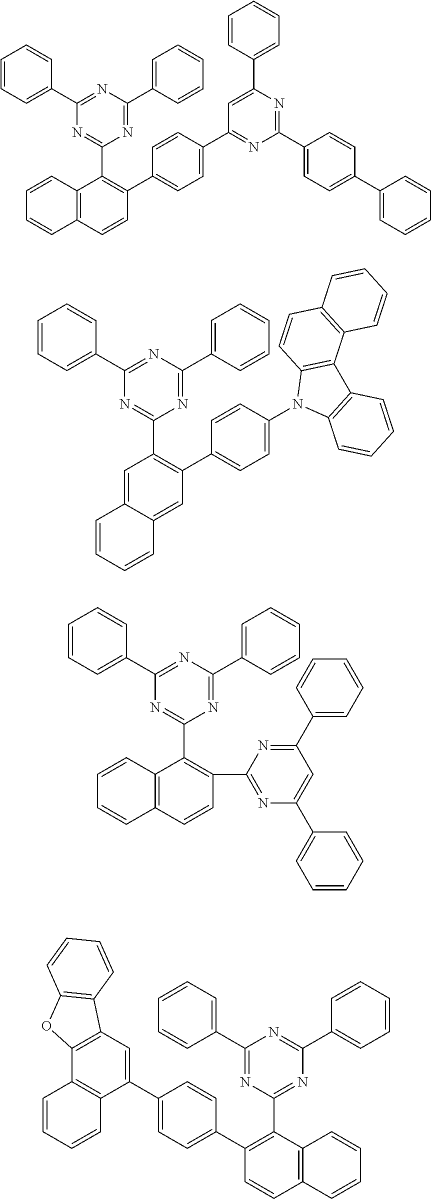

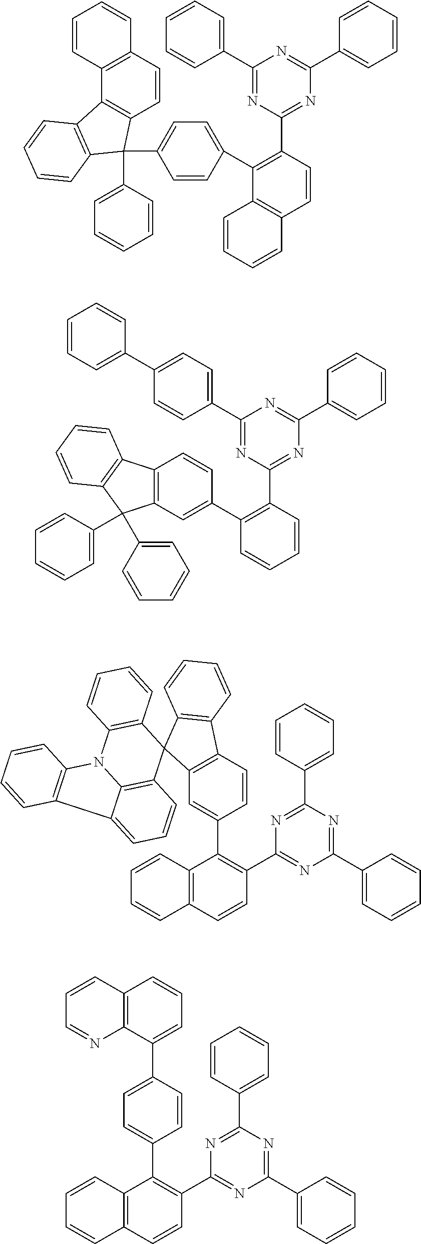 [SMILES: c1ccc(-c2nc(-c3ccccc3)nc(-c3ccc4ccccc4c3-c3ccc(C4(c5ccccc5)c5ccccc5-c5c4ccc4ccccc54)cc3)n2)cc1 ; c1ccc(-c2ccc(-c3nc(-c4ccccc4)nc(-c4ccccc4-c4ccc5c(c4)C(c4ccccc4)(c4ccccc4)c4ccccc4-5)n3)cc2)cc1 ; c1ccc(-c2nc(-c3ccccc3)nc(-c3ccc4ccccc4c3-c3ccc4c(c3)C3(c5ccccc5-4)c4ccccc4-n4c5ccccc5c5cccc3c54)n2)cc1 ; c1ccc(-c2nc(-c3ccccc3)nc(-c3ccc4ccccc4c3-c3ccc(-c4cccc5cccnc45)cc3)n2)cc1]

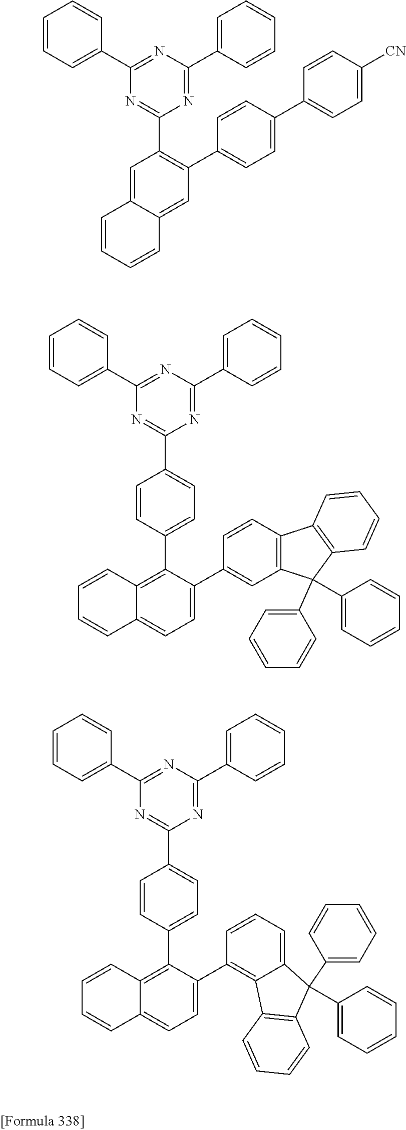 [SMILES: N#Cc1ccc(-c2ccc(-c3cc4ccccc4cc3-c3nc(-c4ccccc4)nc(-c4ccccc4)n3)cc2)cc1 ; c1ccc(-c2nc(-c3ccccc3)nc(-c3ccc(-c4c(-c5ccc6c(c5)C(c5ccccc5)(c5ccccc5)c5ccccc5-6)ccc5ccccc45)cc3)n2)cc1 ; c1ccc(-c2nc(-c3ccccc3)nc(-c3ccc(-c4c(-c5cccc6c5-c5ccccc5C6(c5ccccc5)c5ccccc5)ccc5ccccc45)cc3)n2)cc1]

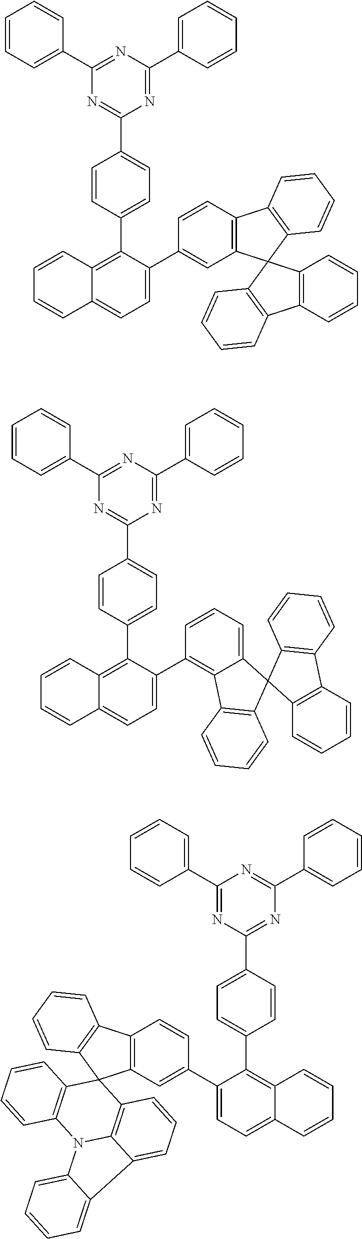 [SMILES: c1ccc(-c2nc(-c3ccccc3)nc(-c3ccc(-c4c(-c5ccc6c(c5)C5(c7ccccc7-c7ccccc75)c5ccccc5-6)ccc5ccccc45)cc3)n2)cc1 ; c1ccc(-c2nc(-c3ccccc3)nc(-c3ccc(-c4c(-c5cccc6c5-c5ccccc5C65c6ccccc6-c6ccccc65)ccc5ccccc45)cc3)n2)cc1 ; c1ccc(-c2nc(-c3ccccc3)nc(-c3ccc(-c4c(-c5ccc6c(c5)C5(c7ccccc7-6)c6ccccc6-n6c7ccccc7c7cccc5c76)ccc5ccccc45)cc3)n2)cc1]

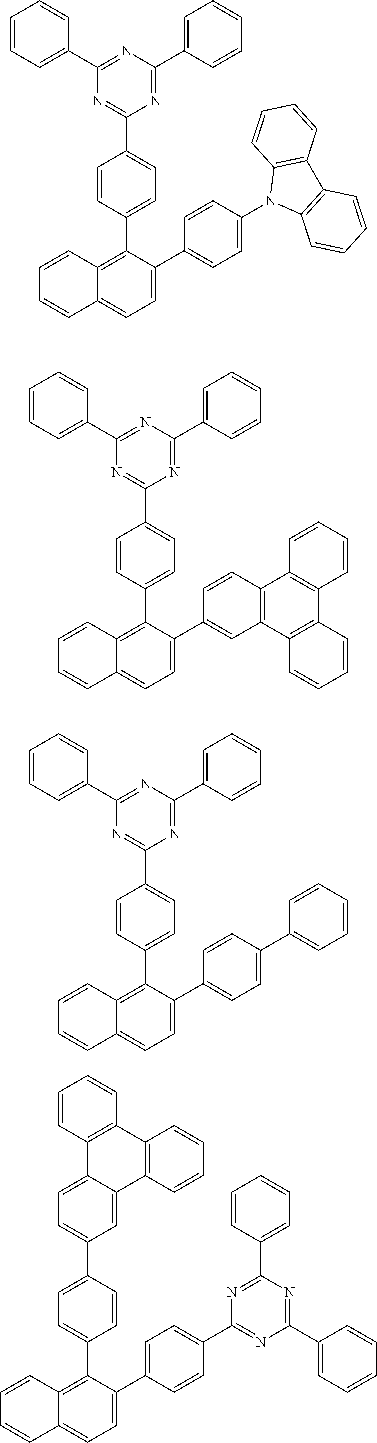

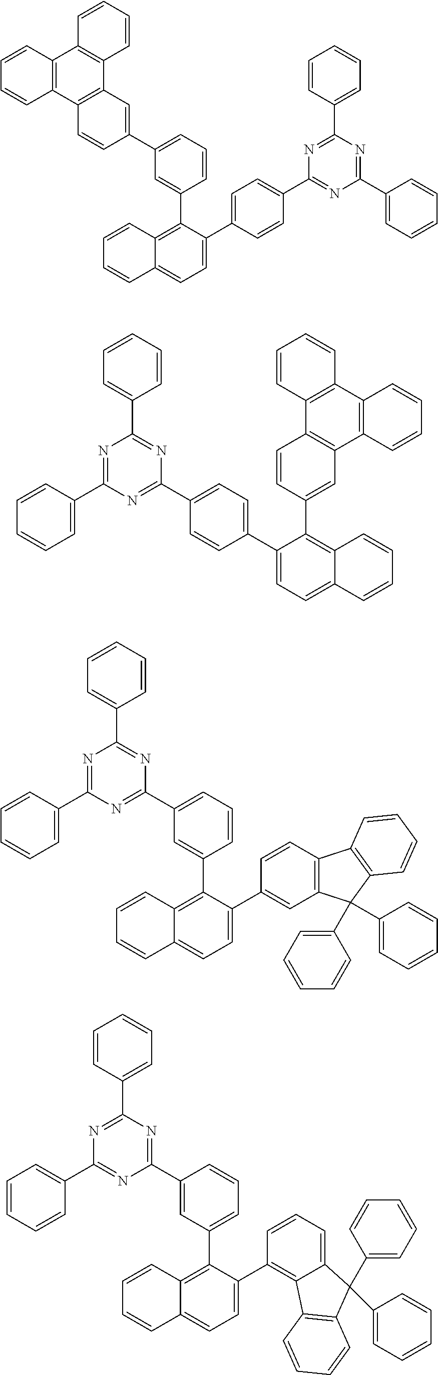 [SMILES: c1ccc(-c2nc(-c3ccccc3)nc(-c3ccc(-c4ccc5ccccc5c4-c4cccc(-c5ccc6c7ccccc7c7ccccc7c6c5)c4)cc3)n2)cc1 ; c1ccc(-c2nc(-c3ccccc3)nc(-c3ccc(-c4ccc5ccccc5c4-c4ccc5c6ccccc6c6ccccc6c5c4)cc3)n2)cc1 ; c1ccc(-c2nc(-c3ccccc3)nc(-c3cccc(-c4c(-c5ccc6c(c5)C(c5ccccc5)(c5ccccc5)c5ccccc5-6)ccc5ccccc45)c3)n2)cc1 ; c1ccc(-c2nc(-c3ccccc3)nc(-c3cccc(-c4c(-c5cccc6c5-c5ccccc5C6(c5ccccc5)c5ccccc5)ccc5ccccc45)c3)n2)cc1]

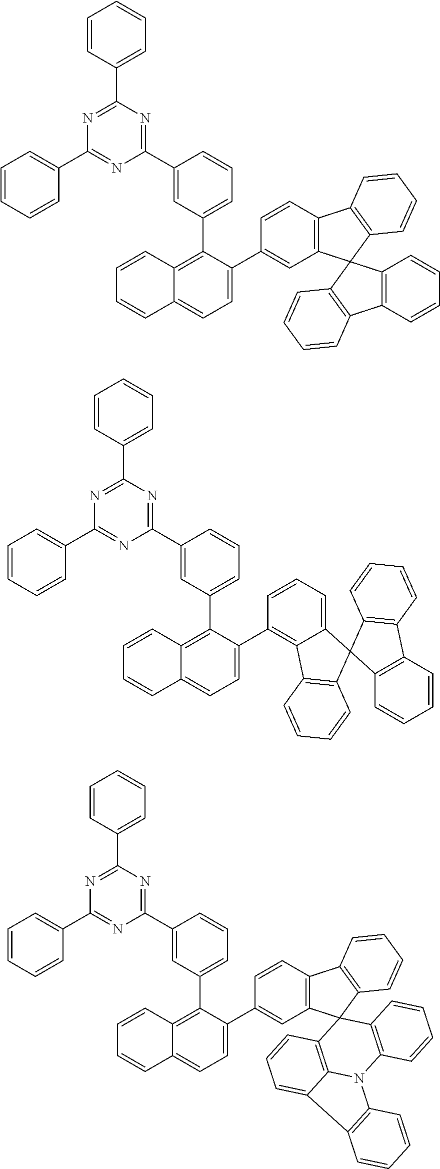 [SMILES: c1ccc(-c2nc(-c3ccccc3)nc(-c3cccc(-c4c(-c5ccc6c(c5)C5(c7ccccc7-c7ccccc75)c5ccccc5-6)ccc5ccccc45)c3)n2)cc1 ; c1ccc(-c2nc(-c3ccccc3)nc(-c3cccc(-c4c(-c5cccc6c5-c5ccccc5C65c6ccccc6-c6ccccc65)ccc5ccccc45)c3)n2)cc1 ; c1ccc(-c2nc(-c3ccccc3)nc(-c3cccc(-c4c(-c5ccc6c(c5)C5(c7ccccc7-6)c6ccccc6-n6c7ccccc7c7cccc5c76)ccc5ccccc45)c3)n2)cc1]

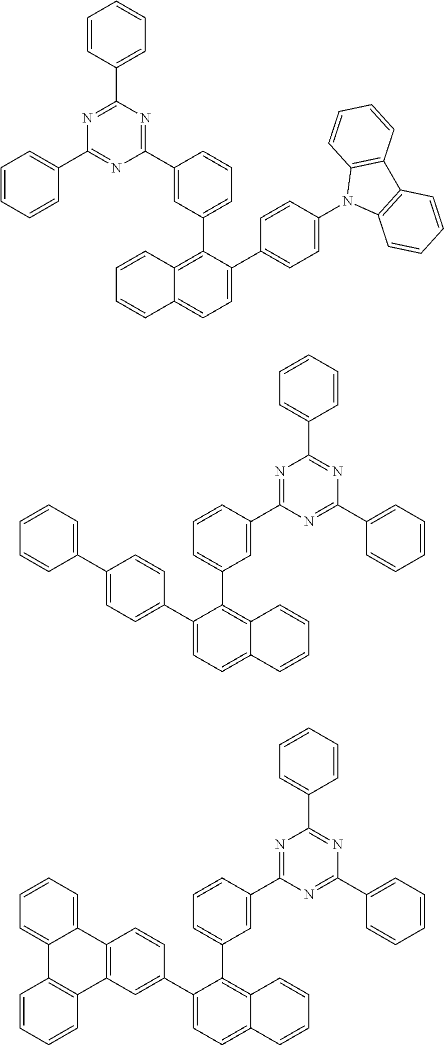 [SMILES: c1ccc(-c2nc(-c3ccccc3)nc(-c3cccc(-c4c(-c5ccc(-n6c7ccccc7c7ccccc76)cc5)ccc5ccccc45)c3)n2)cc1 ; c1ccc(-c2ccc(-c3ccc4ccccc4c3-c3cccc(-c4nc(-c5ccccc5)nc(-c5ccccc5)n4)c3)cc2)cc1 ; c1ccc(-c2nc(-c3ccccc3)nc(-c3cccc(-c4c(-c5ccc6c7ccccc7c7ccccc7c6c5)ccc5ccccc45)c3)n2)cc1]

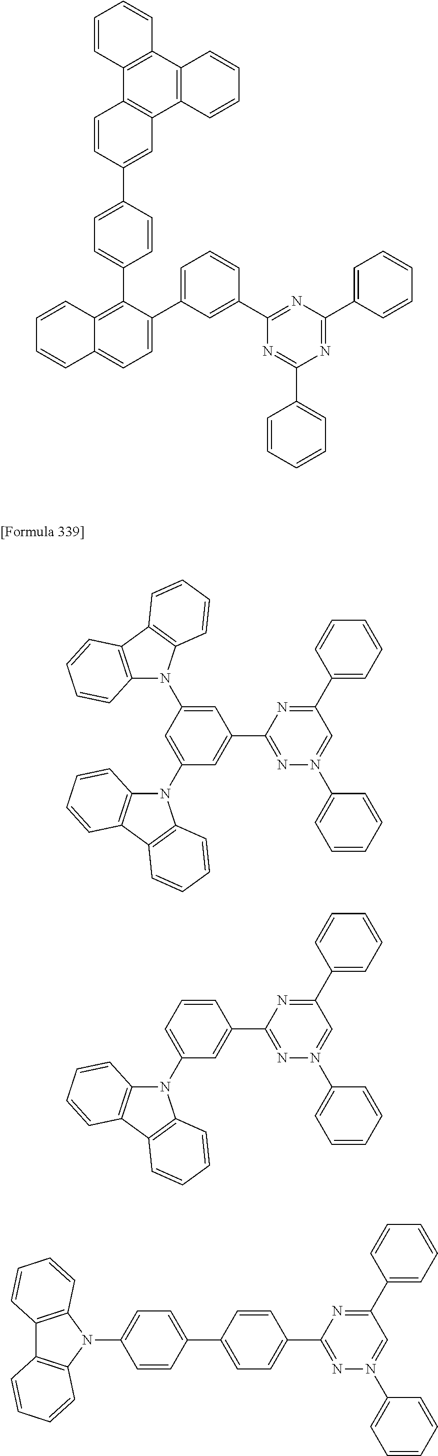

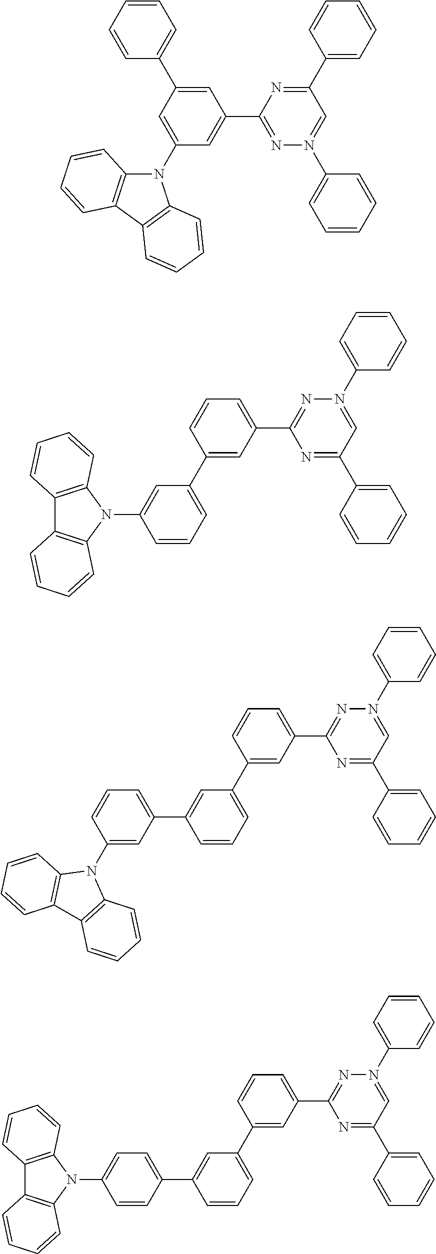

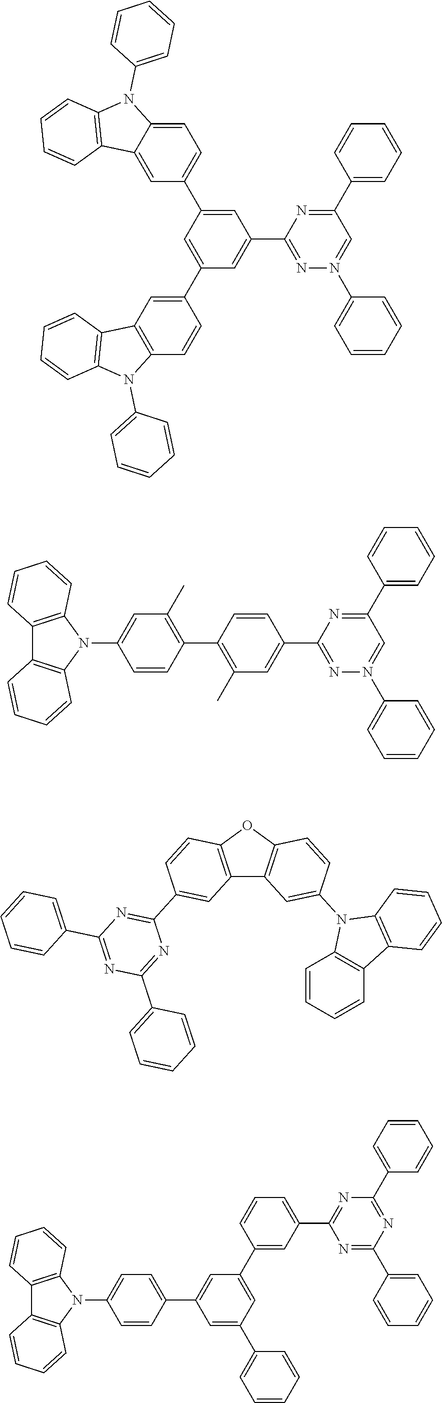

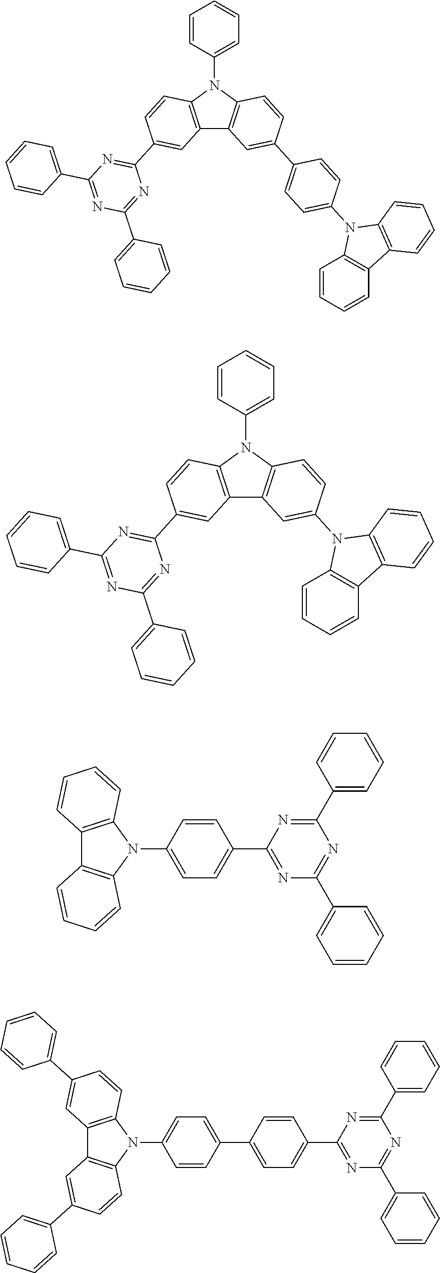 [SMILES: c1ccc(-c2nc(-c3ccccc3)nc(-c3ccc4c(c3)c3cc(-c5ccc(-n6c7ccccc7c7ccccc76)cc5)ccc3n4-c3ccccc3)n2)cc1 ; c1ccc(-c2nc(-c3ccccc3)nc(-c3ccc4c(c3)c3cc(-n5c6ccccc6c6ccccc65)ccc3n4-c3ccccc3)n2)cc1 ; c1ccc(-c2nc(-c3ccccc3)nc(-c3ccc(-n4c5ccccc5c5ccccc54)cc3)n2)cc1 ; c1ccc(-c2ccc3c(c2)c2cc(-c4ccccc4)ccc2n3-c2ccc(-c3ccc(-c4nc(-c5ccccc5)nc(-c5ccccc5)n4)cc3)cc2)cc1]

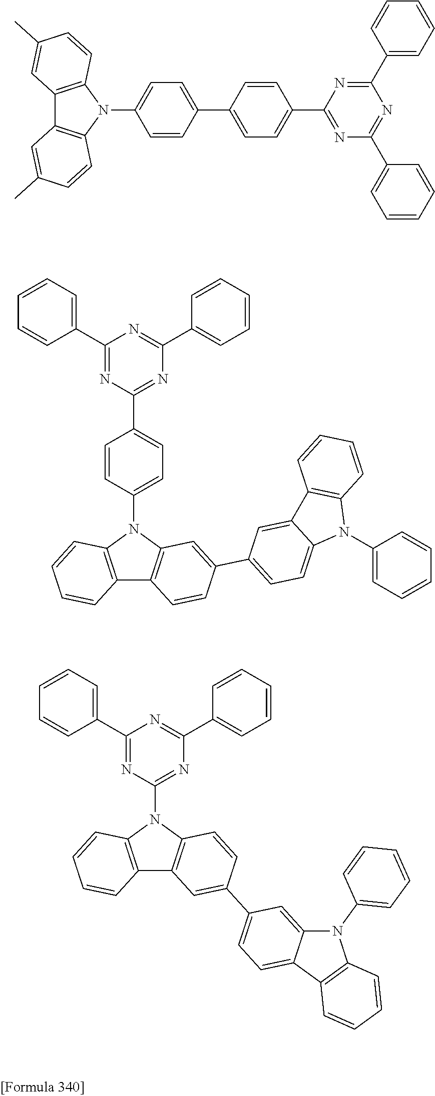 [SMILES: Cc1ccc2c(c1)c1cc(C)ccc1n2-c1ccc(-c2ccc(-c3nc(-c4ccccc4)nc(-c4ccccc4)n3)cc2)cc1 ; c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2nc(-c3ccccc3)nc(-n3c4ccccc4c4cc(-c5ccc6c7ccccc7n(-c7ccccc7)c6c5)ccc43)n2)cc1]

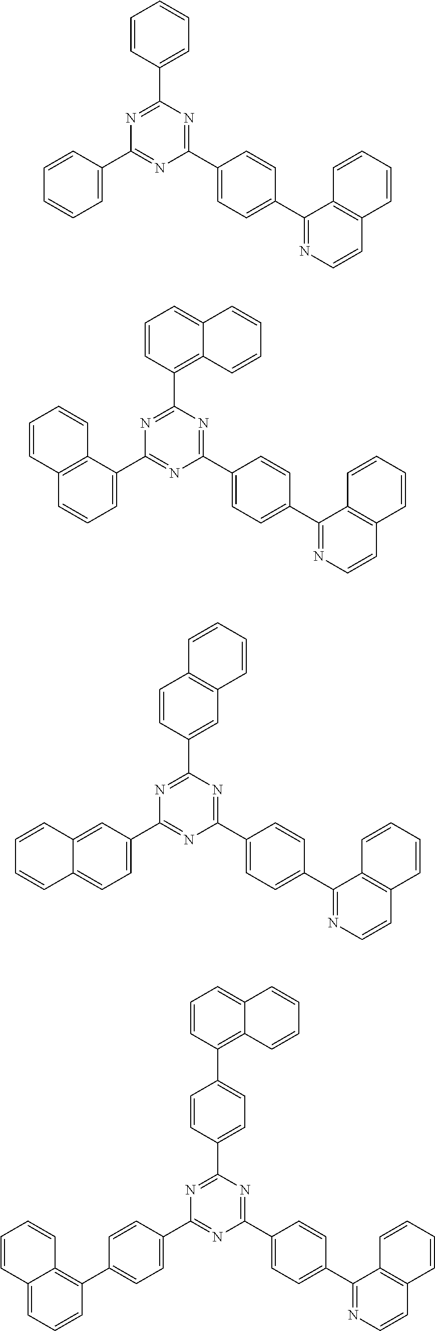 [SMILES: c1ccc(-c2nc(-c3ccccc3)nc(-c3ccc(-c4nccc5ccccc45)cc3)n2)cc1 ; c1ccc2c(-c3nc(-c4ccc(-c5nccc6ccccc56)cc4)nc(-c4cccc5ccccc45)n3)cccc2c1 ; c1ccc2cc(-c3nc(-c4ccc(-c5nccc6ccccc56)cc4)nc(-c4ccc5ccccc5c4)n3)ccc2c1 ; c1ccc2c(-c3ccc(-c4nc(-c5ccc(-c6cccc7ccccc67)cc5)nc(-c5ccc(-c6nccc7ccccc67)cc5)n4)cc3)cccc2c1]

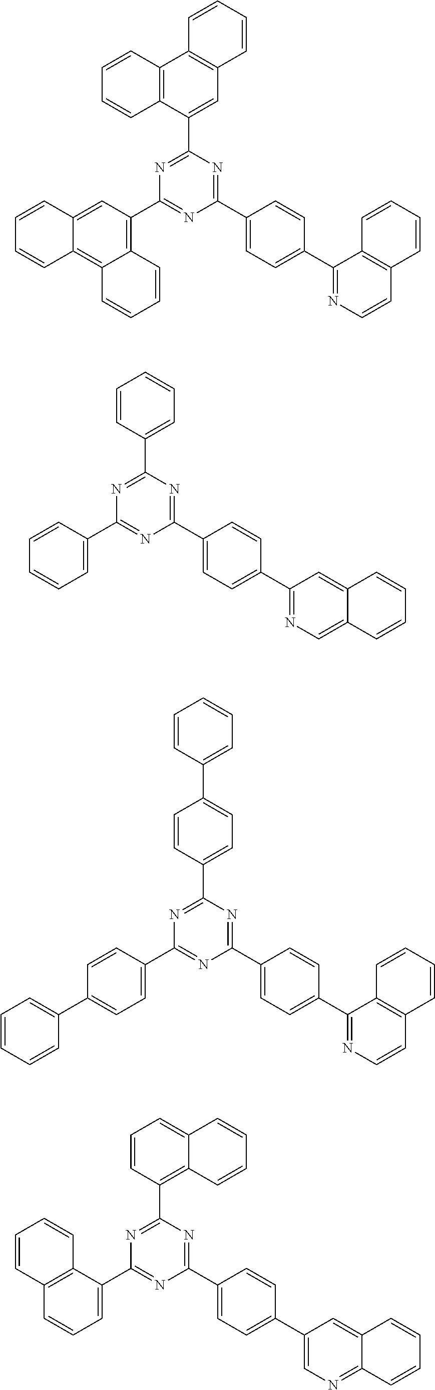 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc(-c2nc(-c3ccccc3)nc(-c3ccc(-c4cc5ccccc5cn4)cc3)n2)cc1 ; c1ccc(-c2ccc(-c3nc(-c4ccc(-c5ccccc5)cc4)nc(-c4ccc(-c5nccc6ccccc56)cc4)n3)cc2)cc1 ; c1ccc2ncc(-c3ccc(-c4nc(-c5cccc6ccccc56)nc(-c5cccc6ccccc56)n4)cc3)cc2c1]

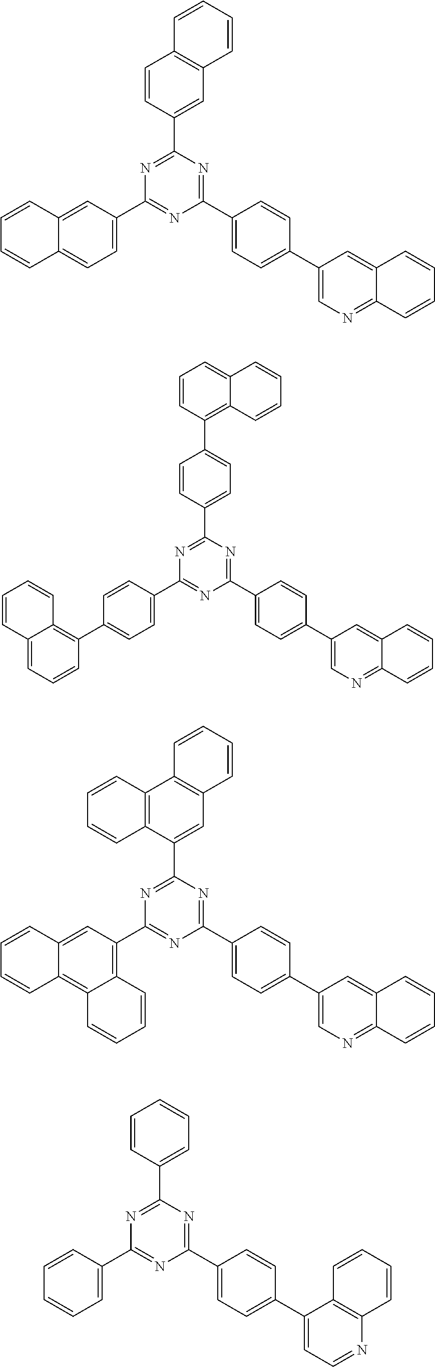 [SMILES: c1ccc2cc(-c3nc(-c4ccc(-c5cnc6ccccc6c5)cc4)nc(-c4ccc5ccccc5c4)n3)ccc2c1 ; c1ccc2ncc(-c3ccc(-c4nc(-c5ccc(-c6cccc7ccccc67)cc5)nc(-c5ccc(-c6cccc7ccccc67)cc5)n4)cc3)cc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2nc(-c3ccccc3)nc(-c3ccc(-c4ccnc5ccccc45)cc3)n2)cc1]

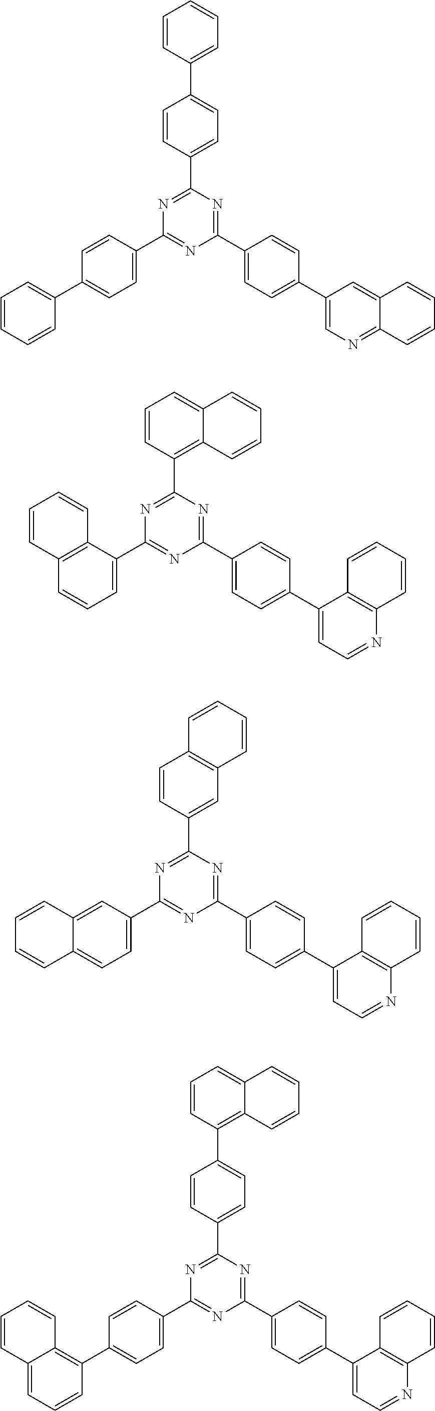 [SMILES: c1ccc(-c2ccc(-c3nc(-c4ccc(-c5ccccc5)cc4)nc(-c4ccc(-c5cnc6ccccc6c5)cc4)n3)cc2)cc1 ; c1ccc2c(-c3nc(-c4ccc(-c5ccnc6ccccc56)cc4)nc(-c4cccc5ccccc45)n3)cccc2c1 ; c1ccc2cc(-c3nc(-c4ccc(-c5ccnc6ccccc56)cc4)nc(-c4ccc5ccccc5c4)n3)ccc2c1 ; c1ccc2c(-c3ccc(-c4nc(-c5ccc(-c6cccc7ccccc67)cc5)nc(-c5ccc(-c6ccnc7ccccc67)cc5)n4)cc3)cccc2c1]

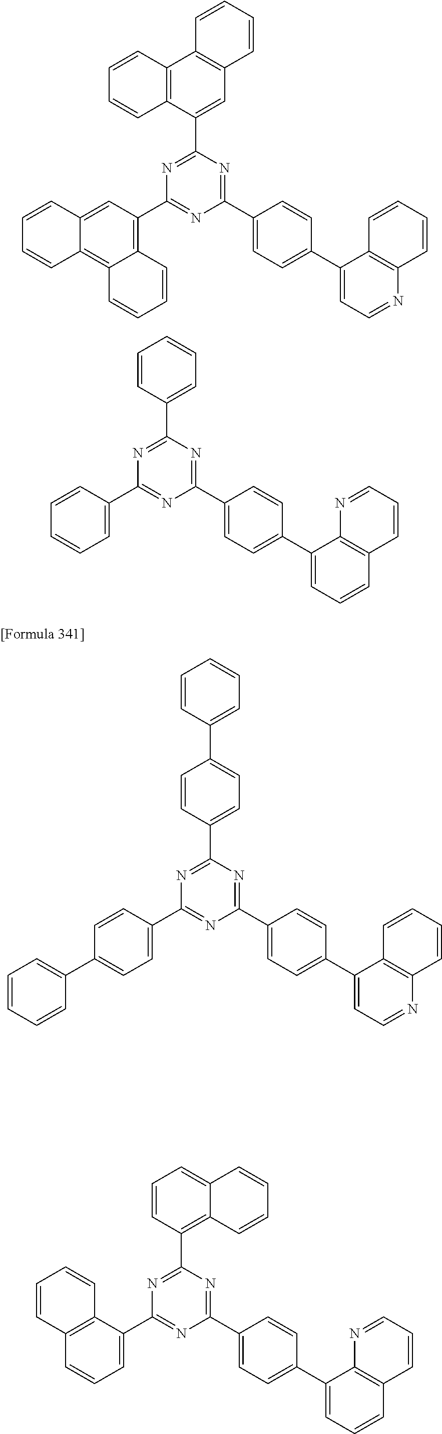

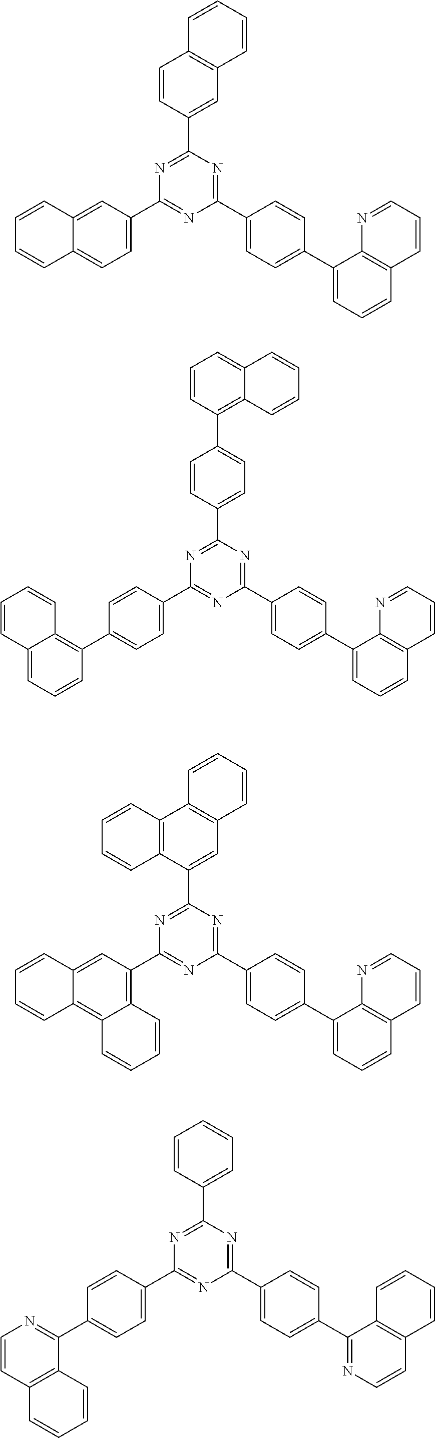 [SMILES: c1ccc2cc(-c3nc(-c4ccc(-c5cccc6cccnc56)cc4)nc(-c4ccc5ccccc5c4)n3)ccc2c1 ; c1ccc2c(-c3ccc(-c4nc(-c5ccc(-c6cccc7ccccc67)cc5)nc(-c5ccc(-c6cccc7cccnc67)cc5)n4)cc3)cccc2c1 ; c1cnc2c(-c3ccc(-c4nc(-c5cc6ccccc6c6ccccc56)nc(-c5cc6ccccc6c6ccccc56)n4)cc3)cccc2c1 ; c1ccc(-c2nc(-c3ccc(-c4nccc5ccccc45)cc3)nc(-c3ccc(-c4nccc5ccccc45)cc3)n2)cc1]

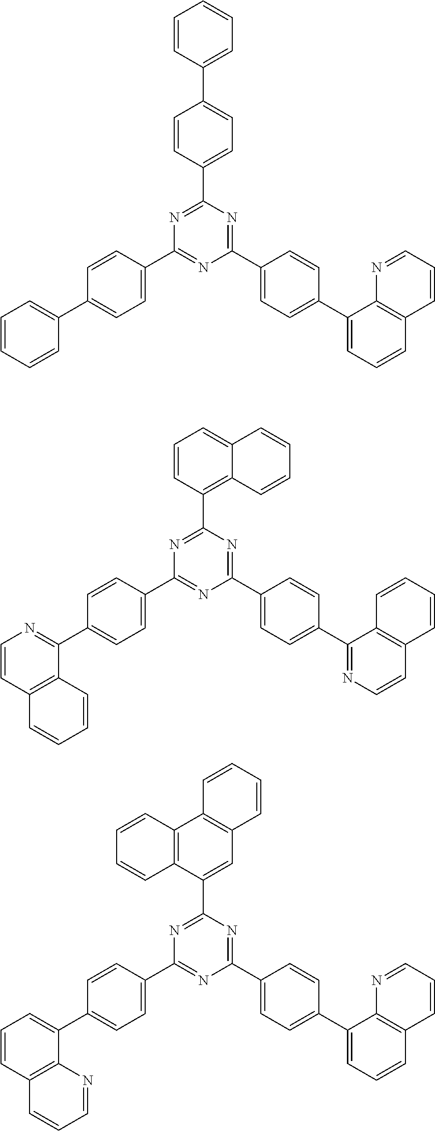 [SMILES: c1ccc(-c2ccc(-c3nc(-c4ccc(-c5ccccc5)cc4)nc(-c4ccc(-c5cccc6cccnc56)cc4)n3)cc2)cc1 ; c1ccc2c(-c3nc(-c4ccc(-c5nccc6ccccc56)cc4)nc(-c4ccc(-c5nccc6ccccc56)cc4)n3)cccc2c1 ; c1cnc2c(-c3ccc(-c4nc(-c5ccc(-c6cccc7cccnc67)cc5)nc(-c5cc6ccccc6c6ccccc56)n4)cc3)cccc2c1]

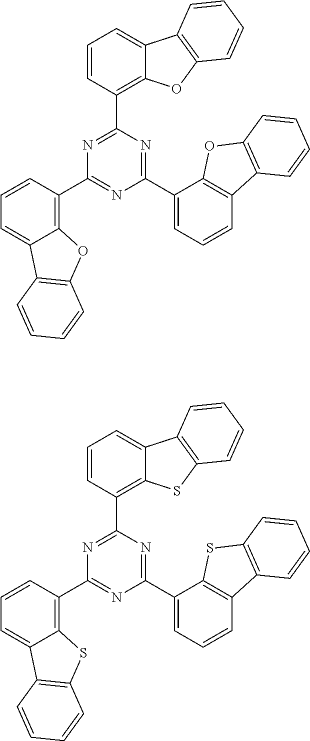 [SMILES: c1ccc2c(c1)oc1c(-c3nc(-c4cccc5c4oc4ccccc45)nc(-c4cccc5c4oc4ccccc45)n3)cccc12 ; c1ccc2c(c1)sc1c(-c3nc(-c4cccc5c4sc4ccccc45)nc(-c4cccc5c4sc4ccccc45)n3)cccc12]

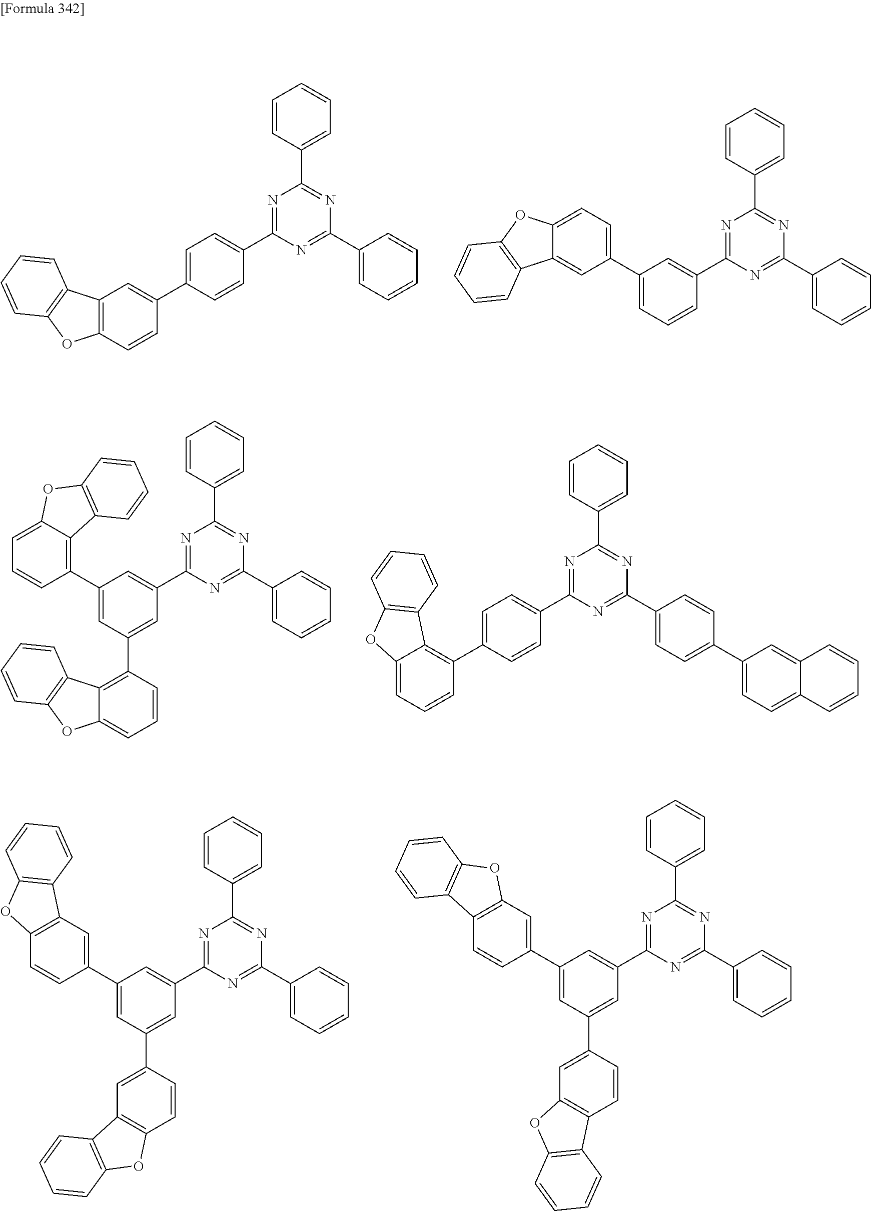

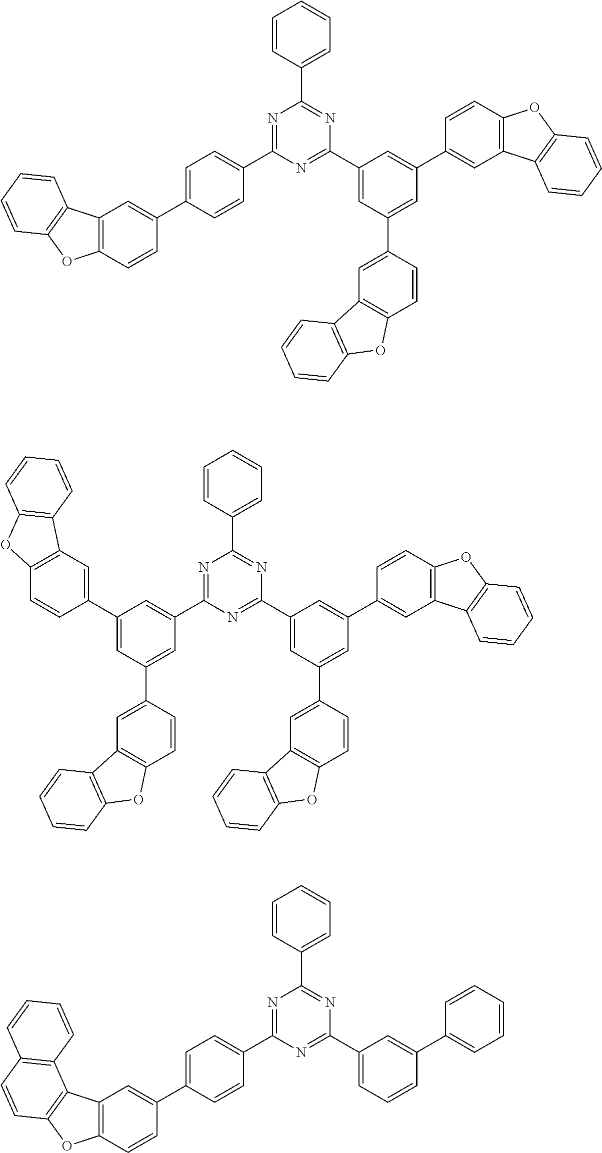 [SMILES: c1ccc(-c2nc(-c3ccc(-c4ccc5oc6ccccc6c5c4)cc3)nc(-c3cc(-c4ccc5oc6ccccc6c5c4)cc(-c4ccc5oc6ccccc6c5c4)c3)n2)cc1 ; c1ccc(-c2nc(-c3cc(-c4ccc5oc6ccccc6c5c4)cc(-c4ccc5oc6ccccc6c5c4)c3)nc(-c3cc(-c4ccc5oc6ccccc6c5c4)cc(-c4ccc5oc6ccccc6c5c4)c3)n2)cc1 ; c1ccc(-c2cccc(-c3nc(-c4ccccc4)nc(-c4ccc(-c5ccc6oc7ccc8ccccc8c7c6c5)cc4)n3)c2)cc1]

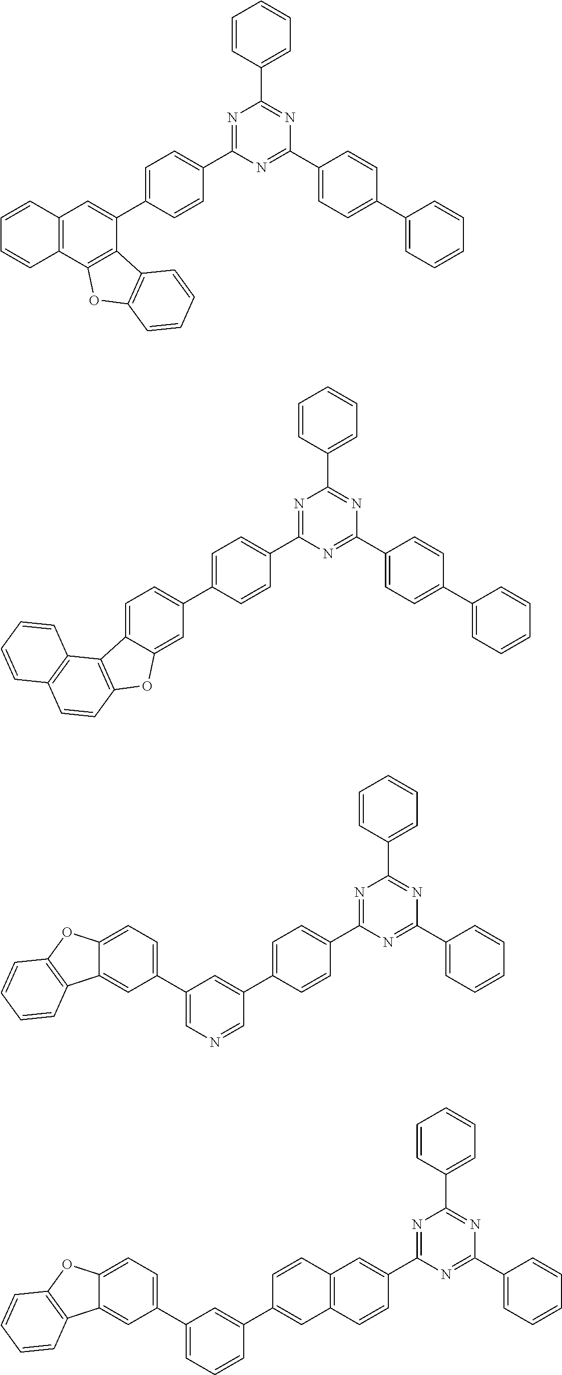 [SMILES: c1ccc(-c2ccc(-c3nc(-c4ccccc4)nc(-c4ccc(-c5cc6ccccc6c6oc7ccccc7c56)cc4)n3)cc2)cc1 ; c1ccc(-c2ccc(-c3nc(-c4ccccc4)nc(-c4ccc(-c5ccc6c(c5)oc5ccc7ccccc7c56)cc4)n3)cc2)cc1 ; c1ccc(-c2nc(-c3ccccc3)nc(-c3ccc(-c4cncc(-c5ccc6oc7ccccc7c6c5)c4)cc3)n2)cc1 ; c1ccc(-c2nc(-c3ccccc3)nc(-c3ccc4cc(-c5cccc(-c6ccc7oc8ccccc8c7c6)c5)ccc4c3)n2)cc1]

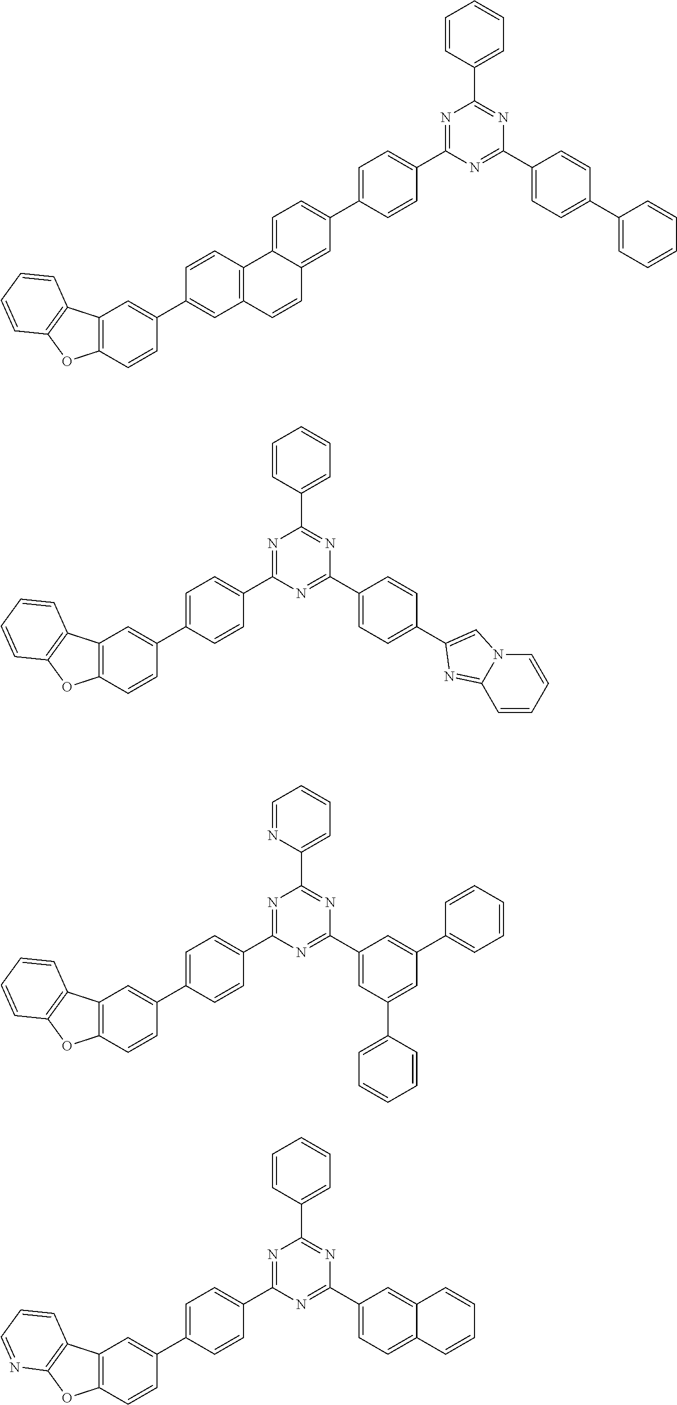 [SMILES: c1ccc(-c2ccc(-c3nc(-c4ccccc4)nc(-c4ccc(-c5ccc6c(ccc7cc(-c8ccc9oc%10ccccc%10c9c8)ccc76)c5)cc4)n3)cc2)cc1 ; c1ccc(-c2nc(-c3ccc(-c4ccc5oc6ccccc6c5c4)cc3)nc(-c3ccc(-c4cn5ccccc5n4)cc3)n2)cc1 ; c1ccc(-c2cc(-c3ccccc3)cc(-c3nc(-c4ccc(-c5ccc6oc7ccccc7c6c5)cc4)nc(-c4ccccn4)n3)c2)cc1 ; c1ccc(-c2nc(-c3ccc(-c4ccc5oc6ncccc6c5c4)cc3)nc(-c3ccc4ccccc4c3)n2)cc1]

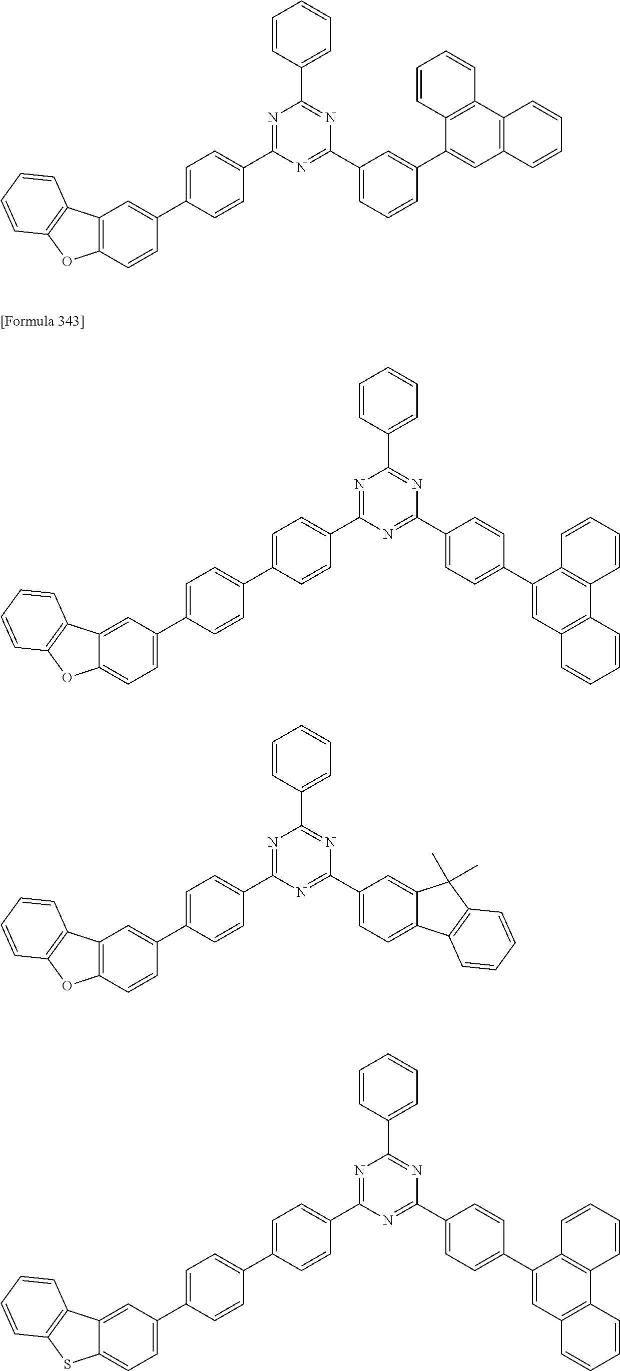 [SMILES: c1ccc(-c2nc(-c3ccc(-c4ccc5oc6ccccc6c5c4)cc3)nc(-c3cccc(-c4cc5ccccc5c5ccccc45)c3)n2)cc1 ; c1ccc(-c2nc(-c3ccc(-c4ccc(-c5ccc6oc7ccccc7c6c5)cc4)cc3)nc(-c3ccc(-c4cc5ccccc5c5ccccc45)cc3)n2)cc1 ; CC1(C)c2ccccc2-c2ccc(-c3nc(-c4ccccc4)nc(-c4ccc(-c5ccc6oc7ccccc7c6c5)cc4)n3)cc21 ; c1ccc(-c2nc(-c3ccc(-c4ccc(-c5ccc6sc7ccccc7c6c5)cc4)cc3)nc(-c3ccc(-c4cc5ccccc5c5ccccc45)cc3)n2)cc1]

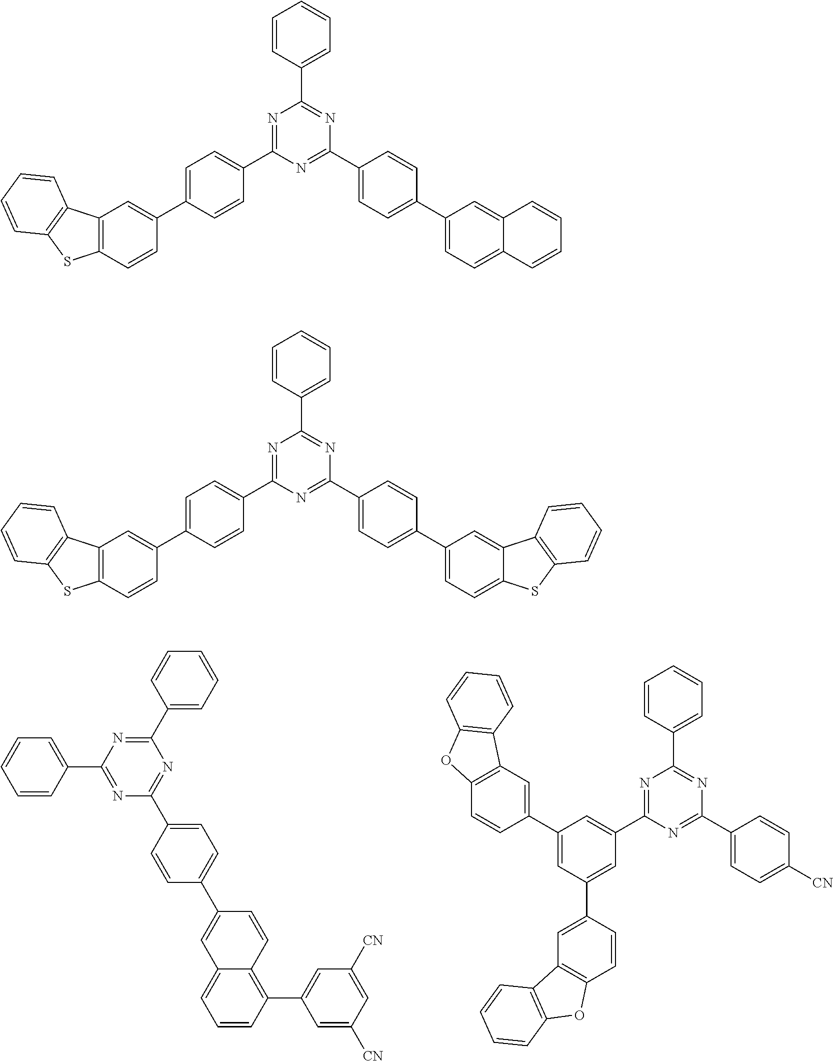 [SMILES: c1ccc(-c2nc(-c3ccc(-c4ccc5ccccc5c4)cc3)nc(-c3ccc(-c4ccc5sc6ccccc6c5c4)cc3)n2)cc1 ; c1ccc(-c2nc(-c3ccc(-c4ccc5sc6ccccc6c5c4)cc3)nc(-c3ccc(-c4ccc5sc6ccccc6c5c4)cc3)n2)cc1 ; N#Cc1cc(C#N)cc(-c2cccc3cc(-c4ccc(-c5nc(-c6ccccc6)nc(-c6ccccc6)n5)cc4)ccc23)c1 ; N#Cc1ccc(-c2nc(-c3ccccc3)nc(-c3cc(-c4ccc5oc6ccccc6c5c4)cc(-c4ccc5oc6ccccc6c5c4)c3)n2)cc1]

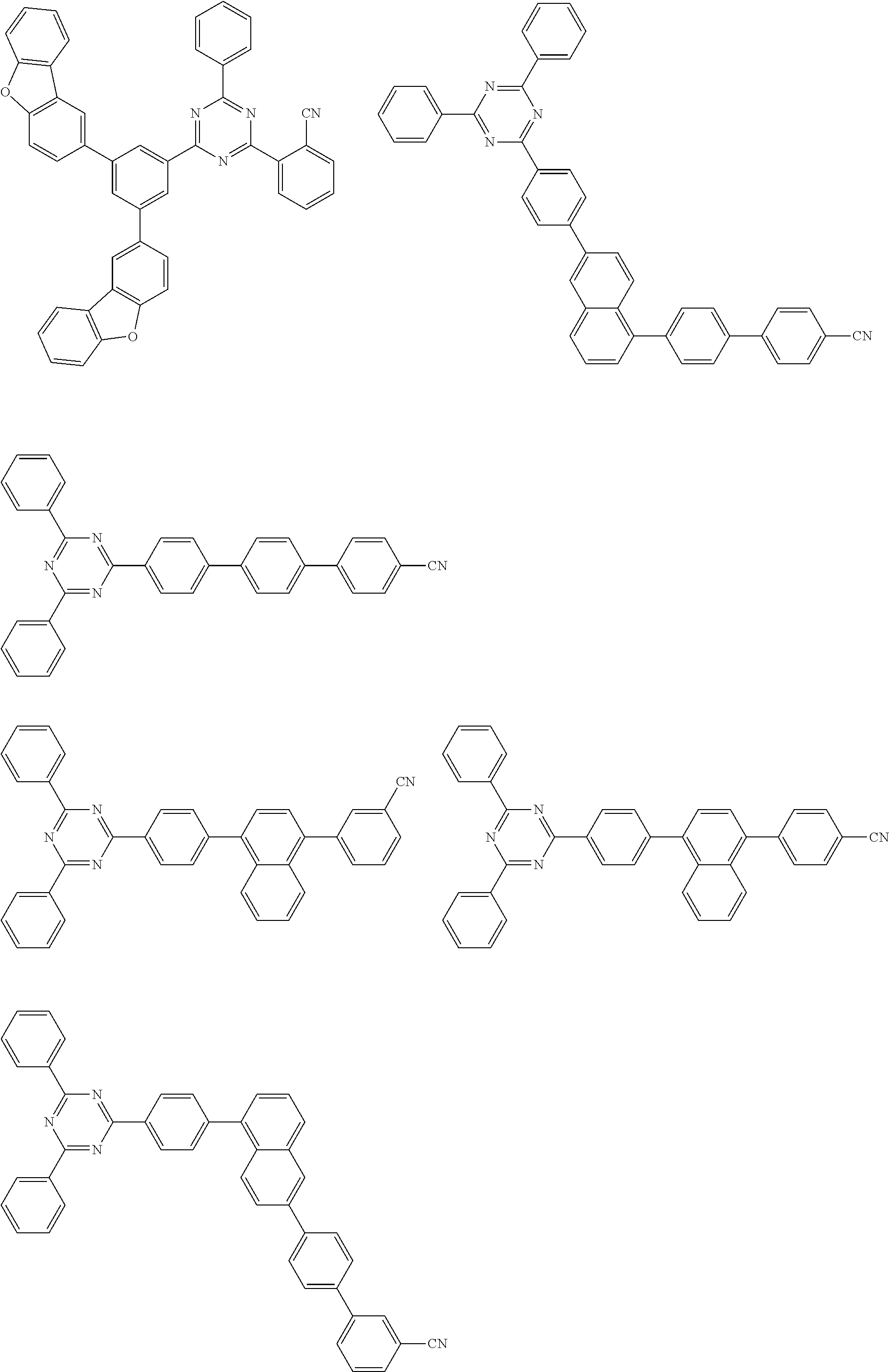 [SMILES: N#Cc1ccccc1-c1nc(-c2ccccc2)nc(-c2cc(-c3ccc4oc5ccccc5c4c3)cc(-c3ccc4oc5ccccc5c4c3)c2)n1 ; N#Cc1ccc(-c2ccc(-c3cccc4cc(-c5ccc(-c6nc(-c7ccccc7)nc(-c7ccccc7)n6)cc5)ccc34)cc2)cc1 ; N#Cc1ccc(-c2ccc(-c3ccc(-c4nc(-c5ccccc5)nc(-c5ccccc5)n4)cc3)cc2)cc1 ; N#Cc1cccc(-c2ccc(-c3ccc(-c4nc(-c5ccccc5)nc(-c5ccccc5)n4)cc3)c3ccccc23)c1 ; N#Cc1ccc(-c2ccc(-c3ccc(-c4nc(-c5ccccc5)nc(-c5ccccc5)n4)cc3)c3ccccc23)cc1 ; N#Cc1cccc(-c2ccc(-c3ccc4c(-c5ccc(-c6nc(-c7ccccc7)nc(-c7ccccc7)n6)cc5)cccc4c3)cc2)c1]

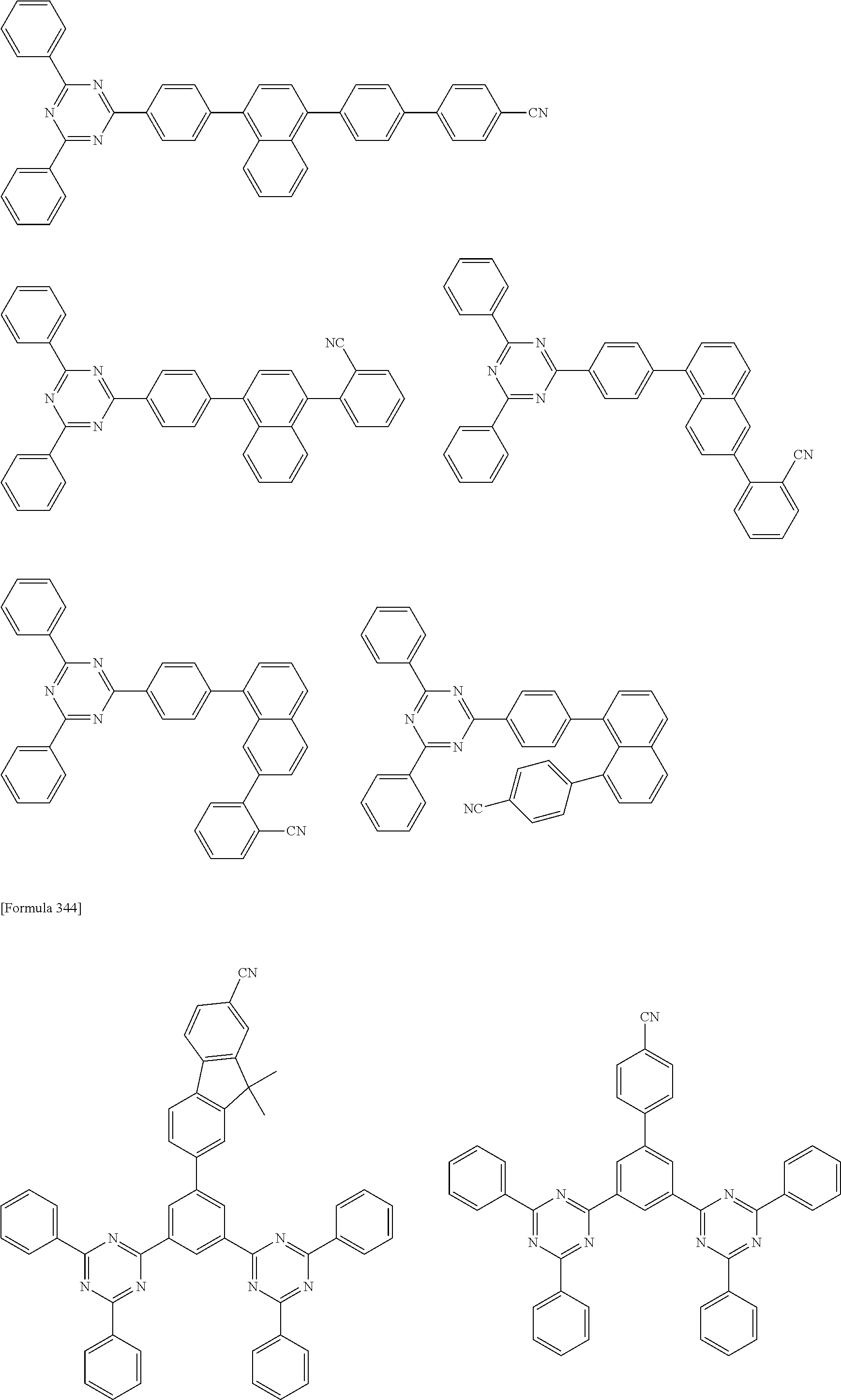

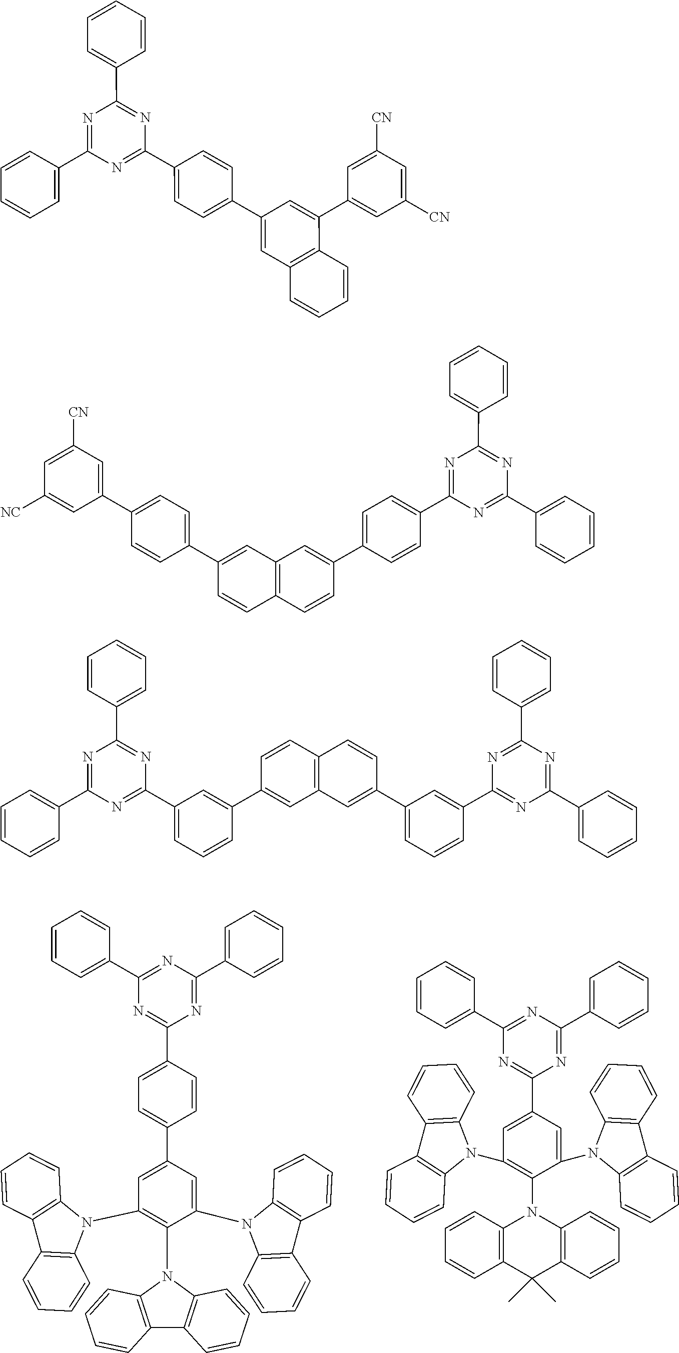

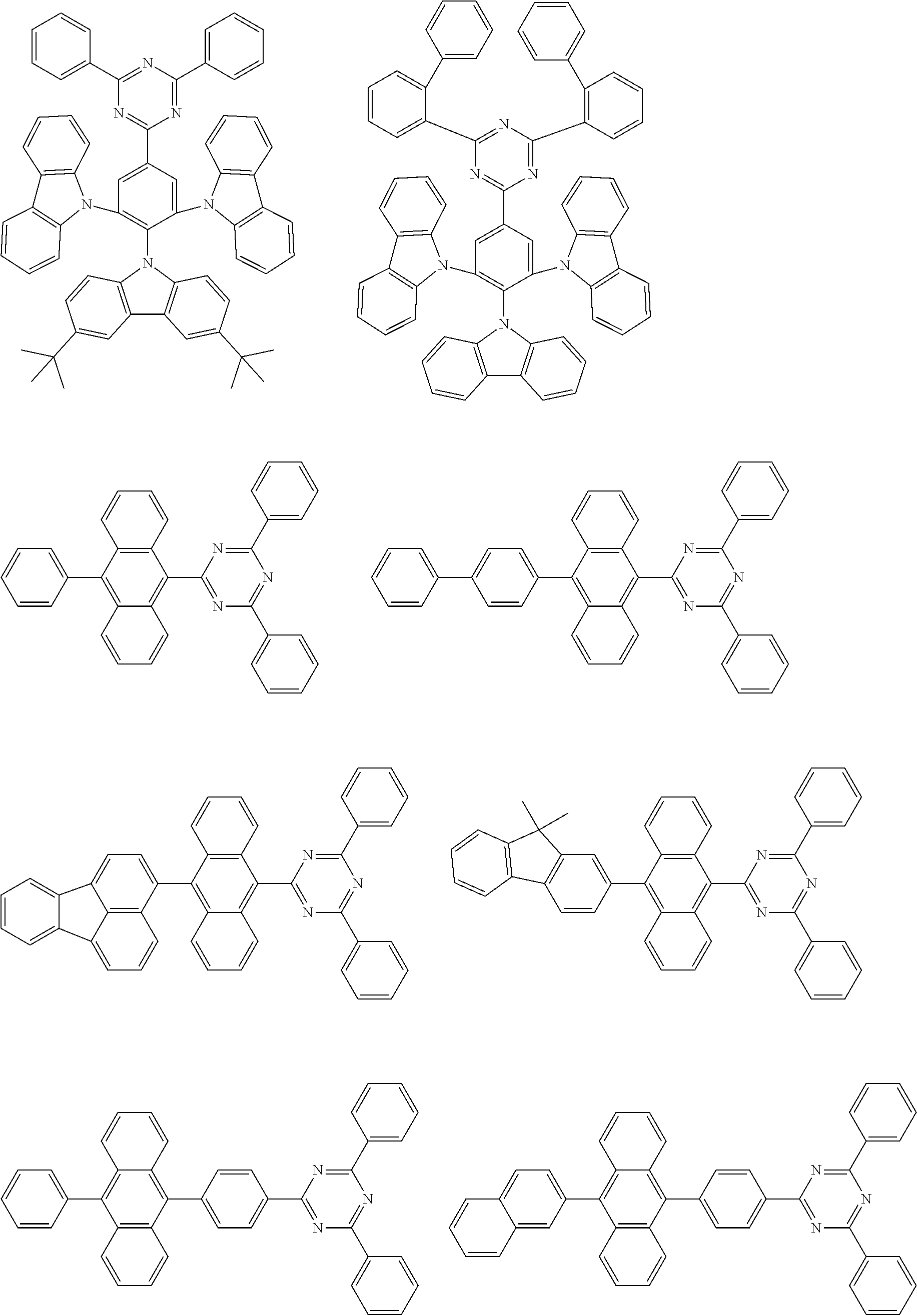

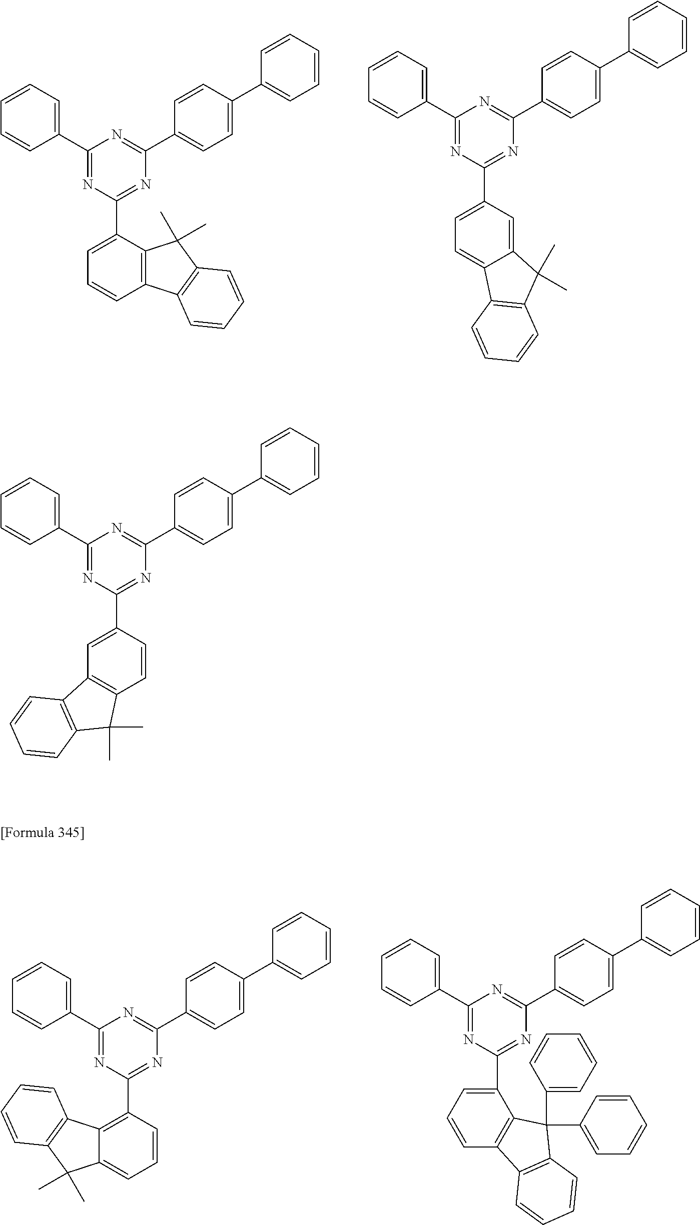 [SMILES: CC1(C)c2ccccc2-c2cccc(-c3nc(-c4ccccc4)nc(-c4ccc(-c5ccccc5)cc4)n3)c21 ; CC1(C)c2ccccc2-c2ccc(-c3nc(-c4ccccc4)nc(-c4ccc(-c5ccccc5)cc4)n3)cc21 ; CC1(C)c2ccccc2-c2cc(-c3nc(-c4ccccc4)nc(-c4ccc(-c5ccccc5)cc4)n3)ccc21 ; CC1(C)c2ccccc2-c2c(-c3nc(-c4ccccc4)nc(-c4ccc(-c5ccccc5)cc4)n3)cccc21 ; c1ccc(-c2ccc(-c3nc(-c4ccccc4)nc(-c4cccc5c4C(c4ccccc4)(c4ccccc4)c4ccccc4-5)n3)cc2)cc1]

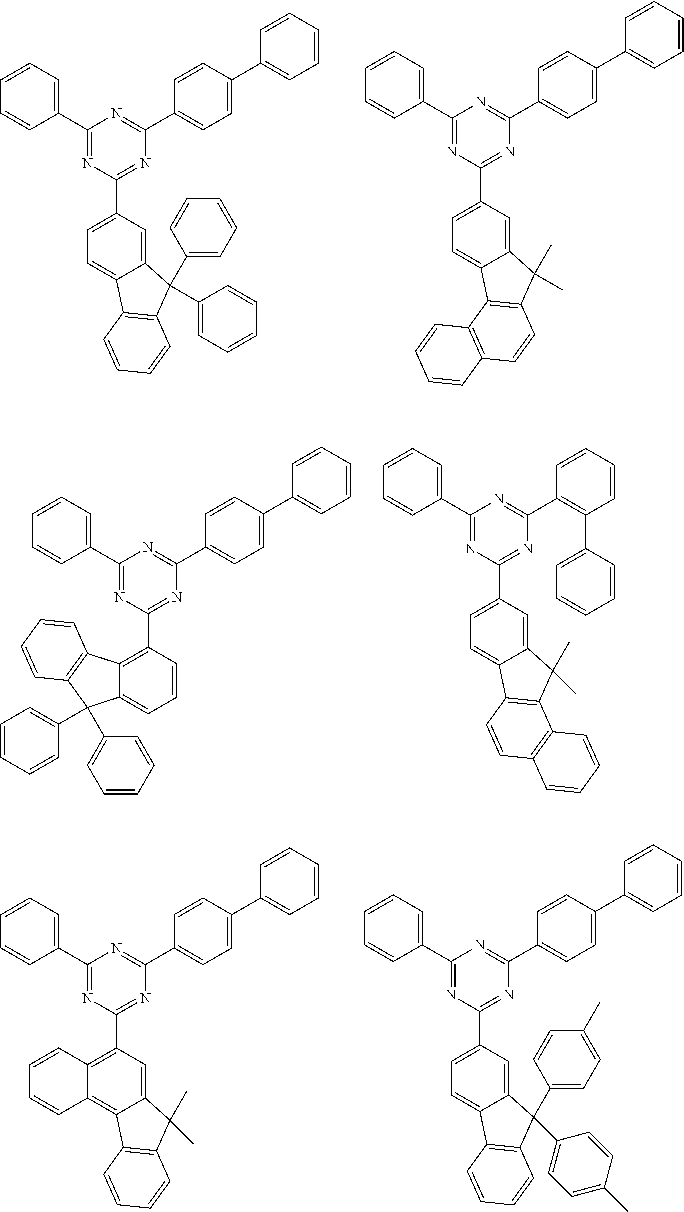

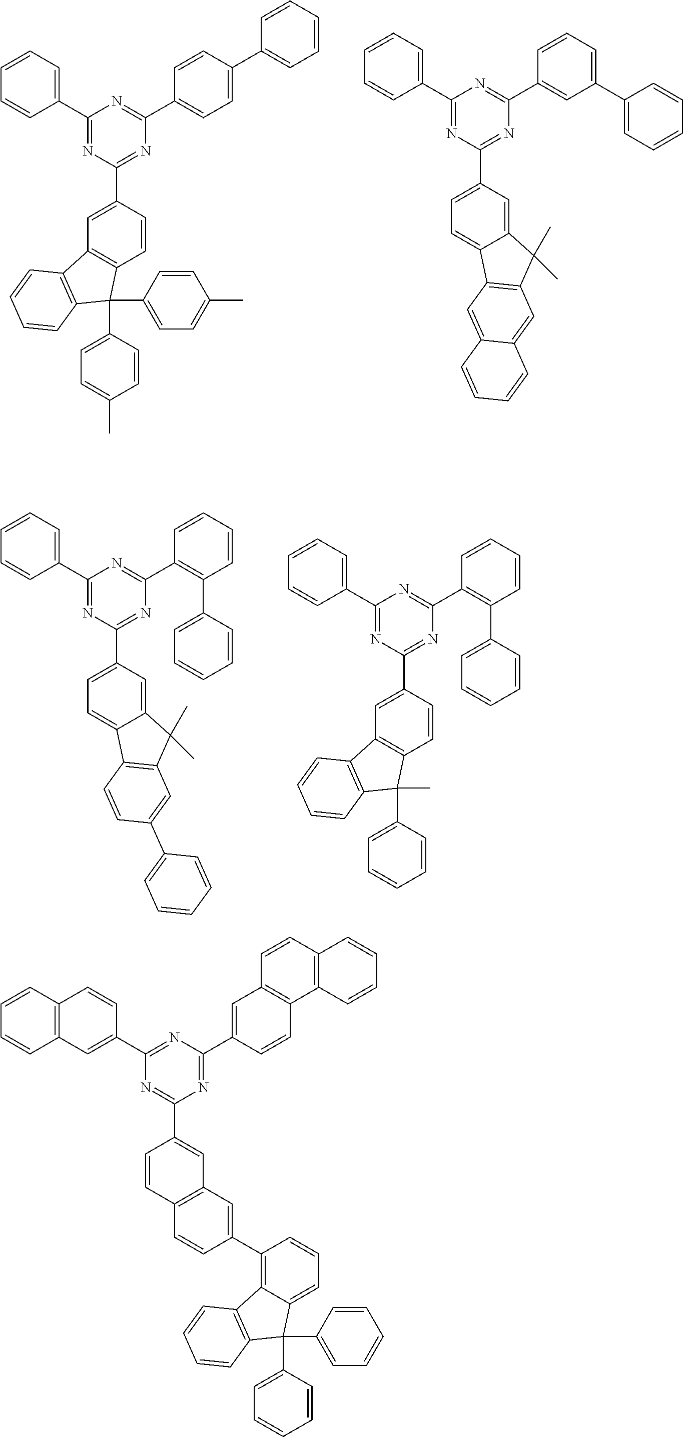

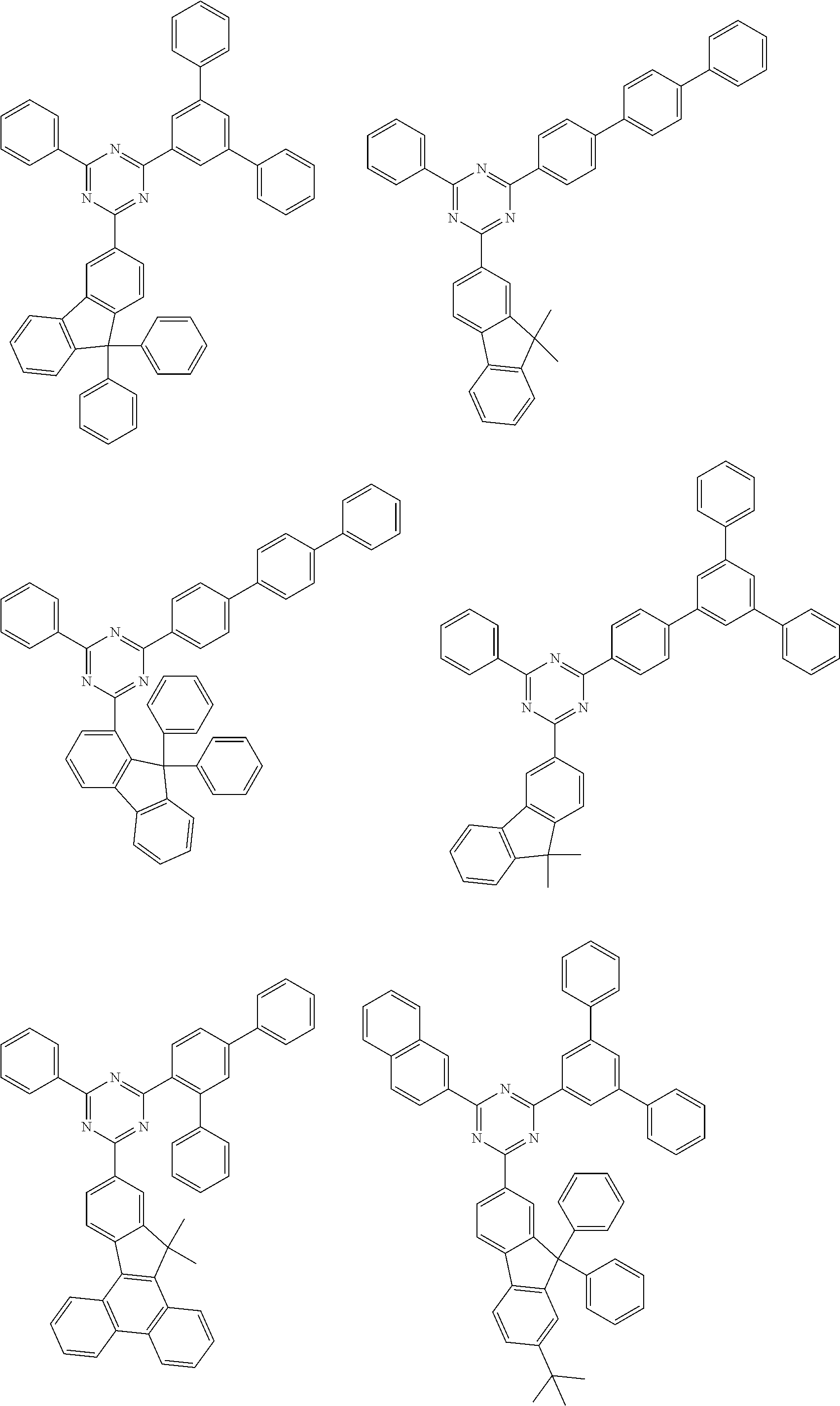

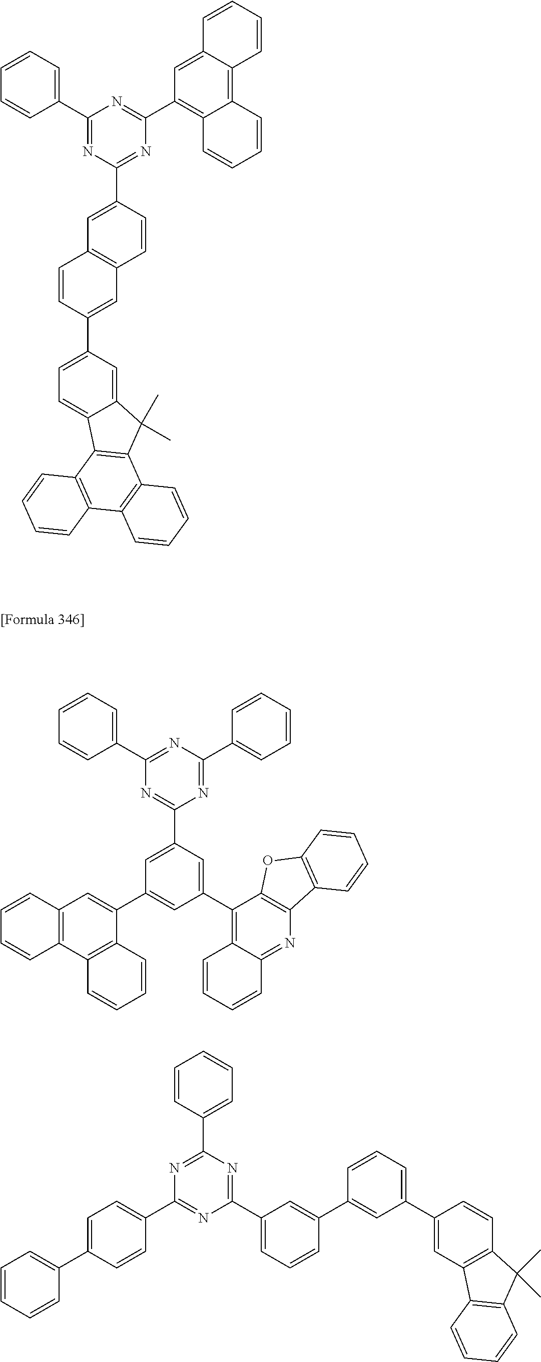 [SMILES: CC1(C)c2cc(-c3ccc4cc(-c5nc(-c6ccccc6)nc(-c6cc7ccccc7c7ccccc67)n5)ccc4c3)ccc2-c2c1c1ccccc1c1ccccc21 ; c1ccc(-c2nc(-c3ccccc3)nc(-c3cc(-c4cc5ccccc5c5ccccc45)cc(-c4c5ccccc5nc5c4oc4ccccc45)c3)n2)cc1 ; CC1(C)c2ccccc2-c2cc(-c3cccc(-c4cccc(-c5nc(-c6ccccc6)nc(-c6ccc(-c7ccccc7)cc6)n5)c4)c3)ccc21]

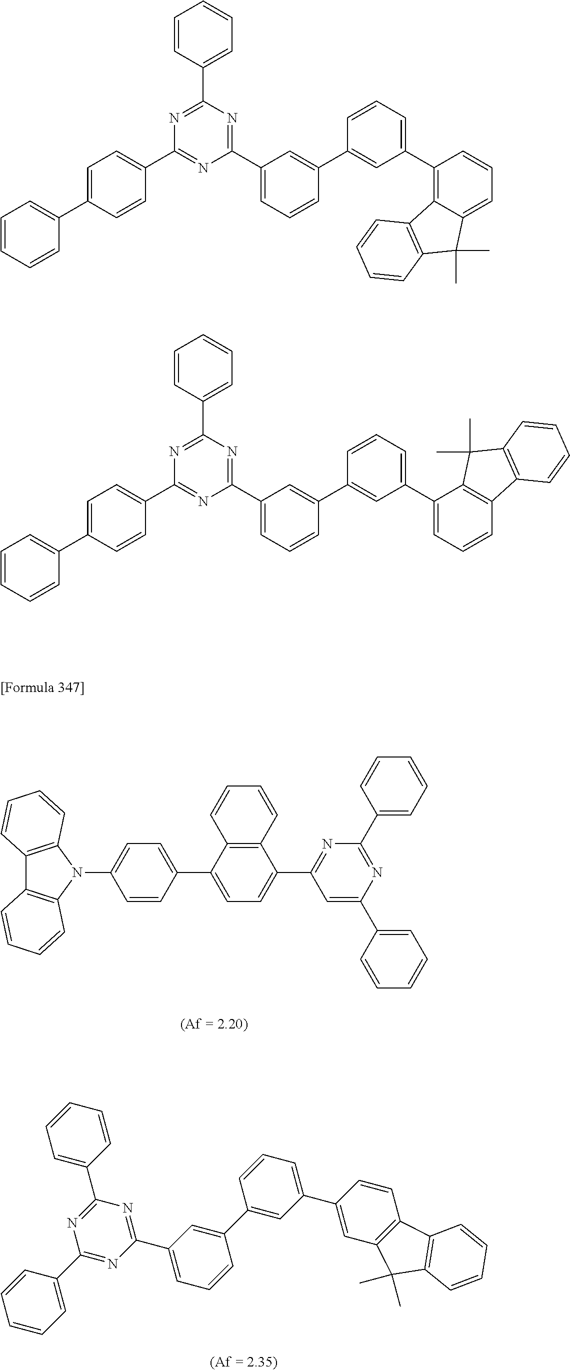 [SMILES: CC1(C)c2ccccc2-c2c(-c3cccc(-c4cccc(-c5nc(-c6ccccc6)nc(-c6ccc(-c7ccccc7)cc6)n5)c4)c3)cccc21 ; CC1(C)c2ccccc2-c2cccc(-c3cccc(-c4cccc(-c5nc(-c6ccccc6)nc(-c6ccc(-c7ccccc7)cc6)n5)c4)c3)c21 ; c1ccc(-c2cc(-c3ccc(-c4ccc(-n5c6ccccc6c6ccccc65)cc4)c4ccccc34)nc(-c3ccccc3)n2)cc1 ; CC1(C)c2ccccc2-c2ccc(-c3cccc(-c4cccc(-c5nc(-c6ccccc6)nc(-c6ccccc6)n5)c4)c3)cc21]

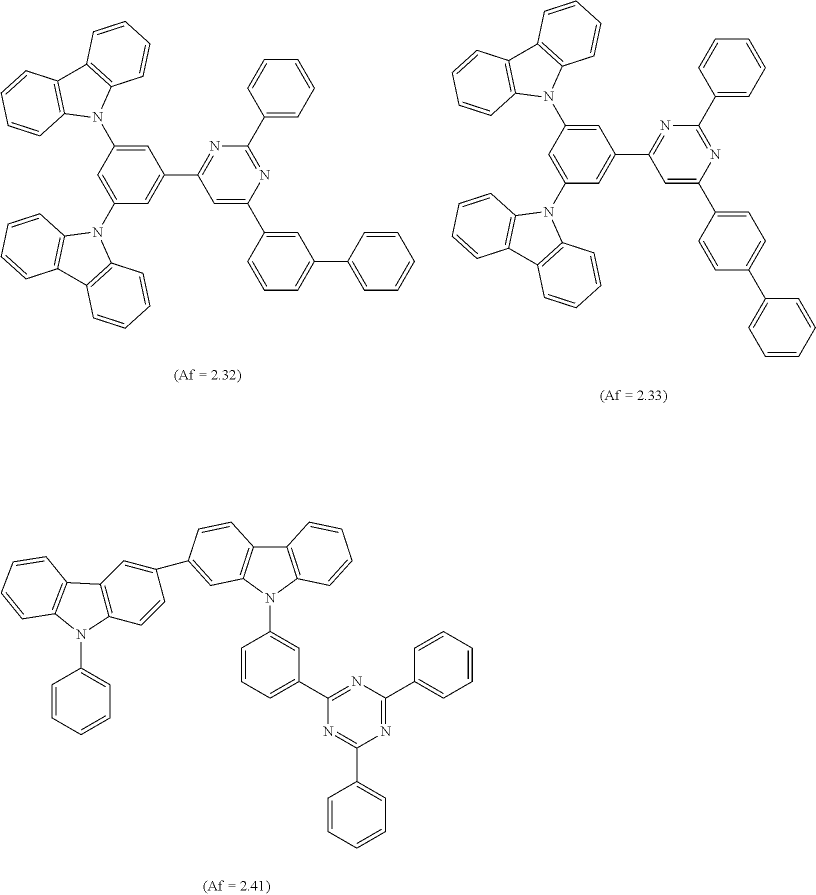

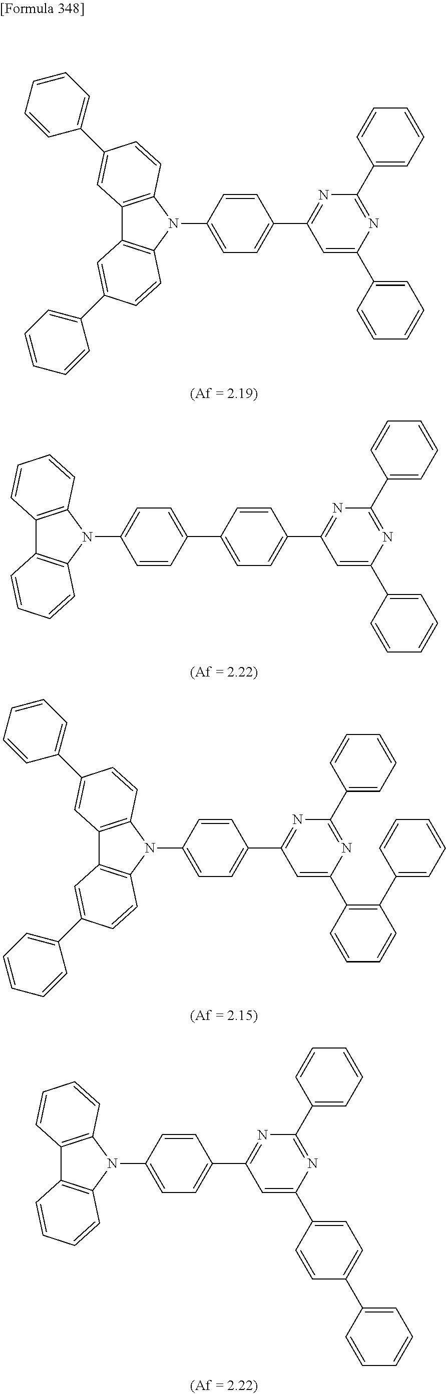 [SMILES: c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2cc(-c3ccc(-c4ccc(-n5c6ccccc6c6ccccc65)cc4)cc3)nc(-c3ccccc3)n2)cc1 ; c1ccc(-c2ccc3c(c2)c2cc(-c4ccccc4)ccc2n3-c2ccc(-c3cc(-c4ccccc4-c4ccccc4)nc(-c4ccccc4)n3)cc2)cc1 ; c1ccc(-c2ccc(-c3cc(-c4ccc(-n5c6ccccc6c6ccccc65)cc4)nc(-c4ccccc4)n3)cc2)cc1]

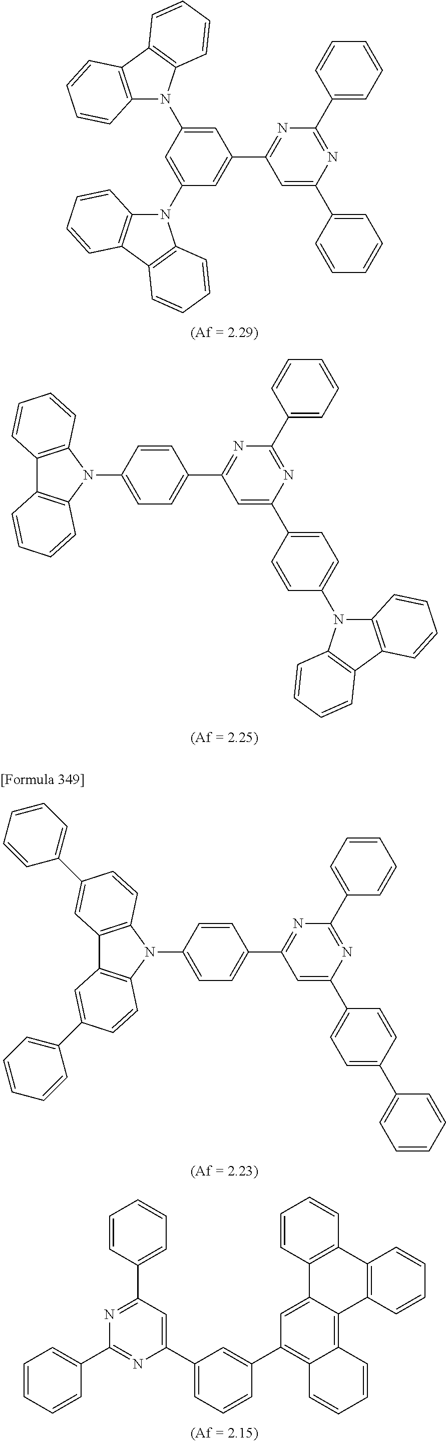 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2nc(-c3ccc(-n4c5ccccc5c5ccccc54)cc3)cc(-c3ccc(-n4c5ccccc5c5ccccc54)cc3)n2)cc1 ; c1ccc(-c2ccc(-c3cc(-c4ccc(-n5c6ccc(-c7ccccc7)cc6c6cc(-c7ccccc7)ccc65)cc4)nc(-c4ccccc4)n3)cc2)cc1 ; c1ccc(-c2cc(-c3cccc(-c4cc5c6ccccc6c6ccccc6c5c5ccccc45)c3)nc(-c3ccccc3)n2)cc1]

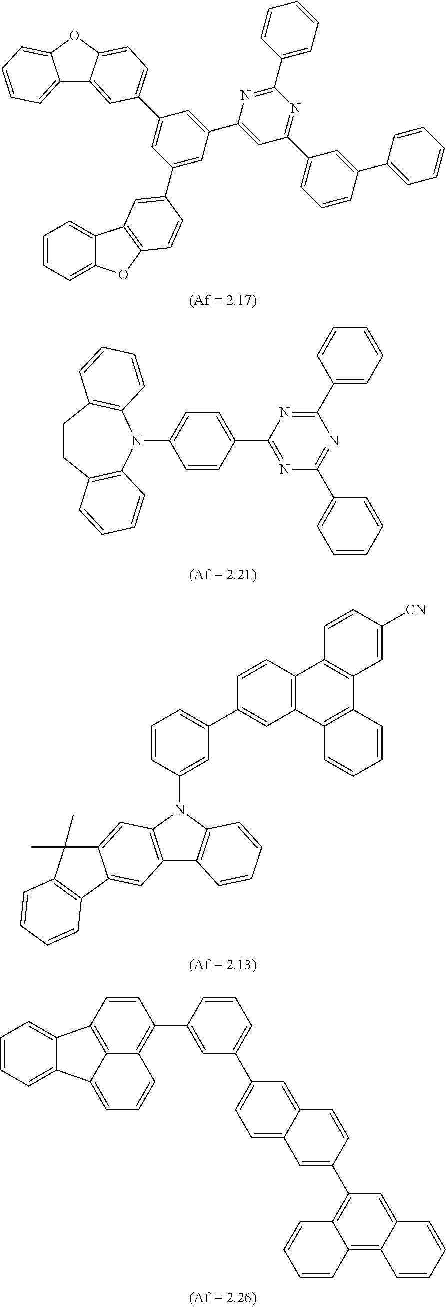

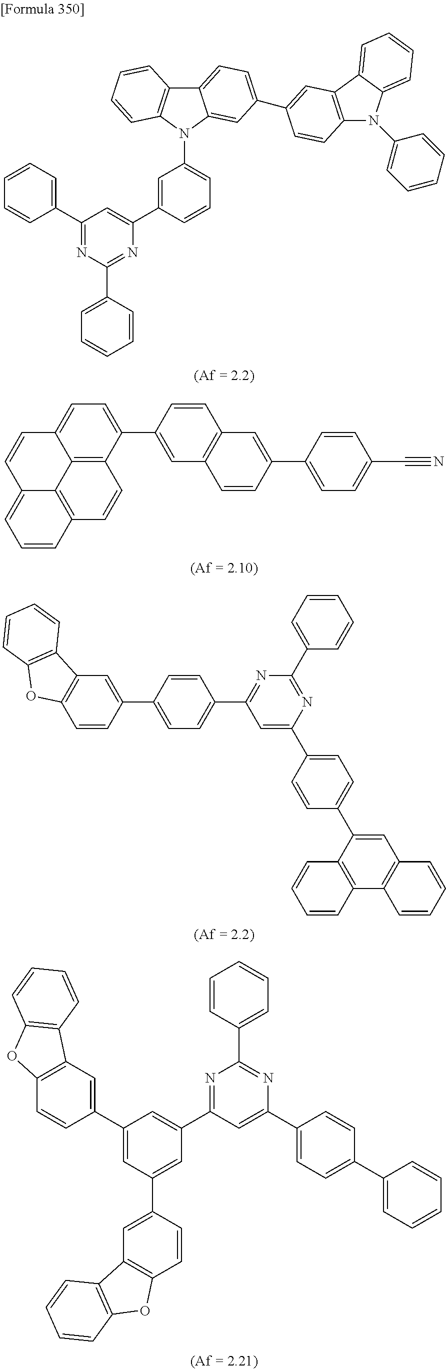 [SMILES: c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1 ; N#Cc1ccc(-c2ccc3cc(-c4ccc5ccc6cccc7ccc4c5c67)ccc3c2)cc1 ; c1ccc(-c2nc(-c3ccc(-c4ccc5oc6ccccc6c5c4)cc3)cc(-c3ccc(-c4cc5ccccc5c5ccccc45)cc3)n2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

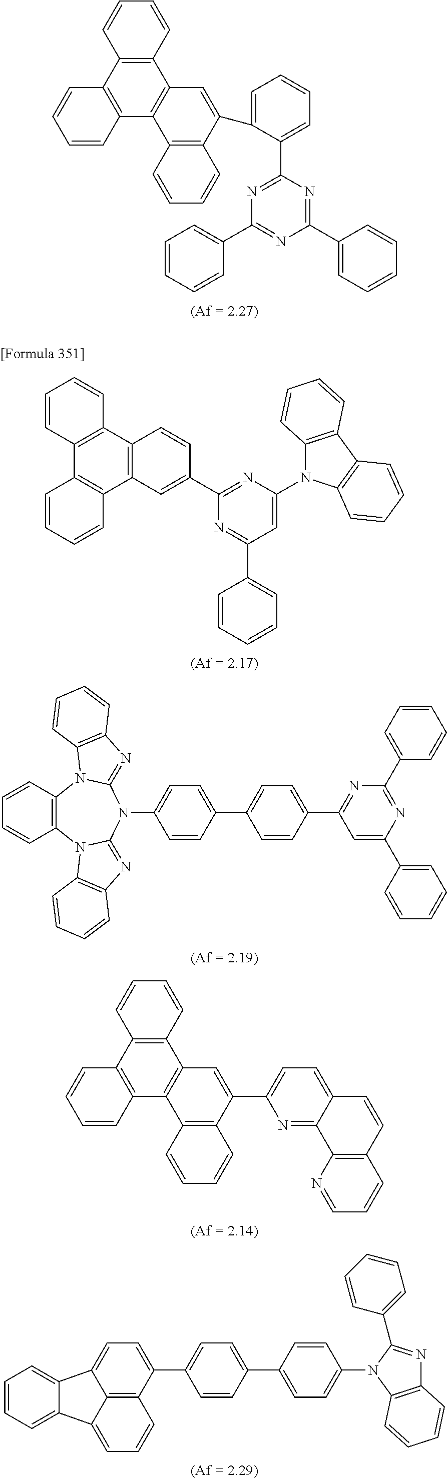

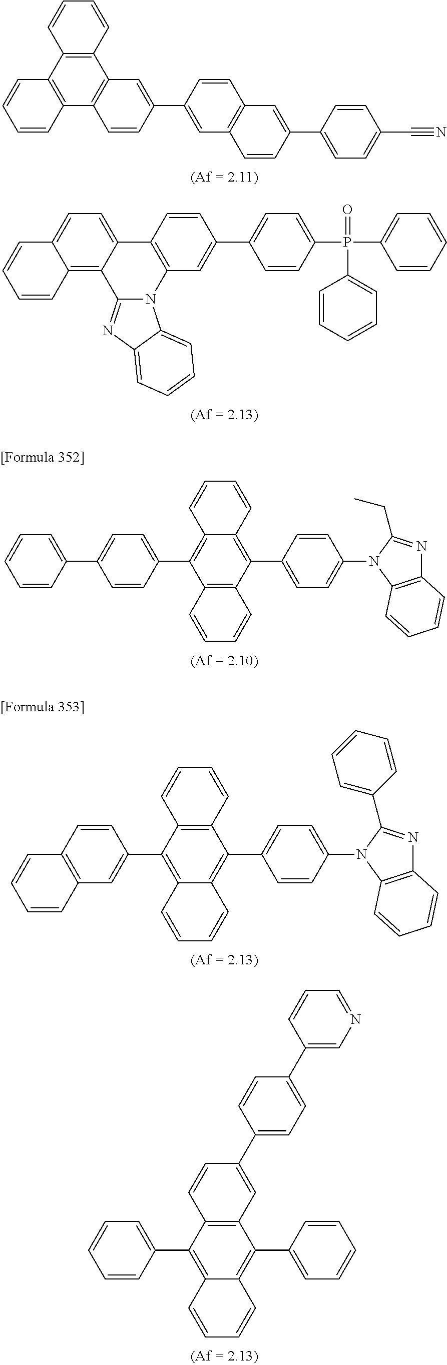 [SMILES: N#Cc1ccc(-c2ccc3cc(-c4ccc5c6ccccc6c6ccccc6c5c4)ccc3c2)cc1 ; O=P(c1ccccc1)(c1ccccc1)c1ccc(-c2ccc3c4ccc5ccccc5c4c4nc5ccccc5n4c3c2)cc1 ; CCc1nc2ccccc2n1-c1ccc(-c2c3ccccc3c(-c3ccc(-c4ccccc4)cc3)c3ccccc23)cc1 ; c1ccc(-c2nc3ccccc3n2-c2ccc(-c3c4ccccc4c(-c4ccc5ccccc5c4)c4ccccc34)cc2)cc1 ; c1ccc(-c2c3ccccc3c(-c3ccccc3)c3cc(-c4ccc(-c5cccnc5)cc4)ccc23)cc1]

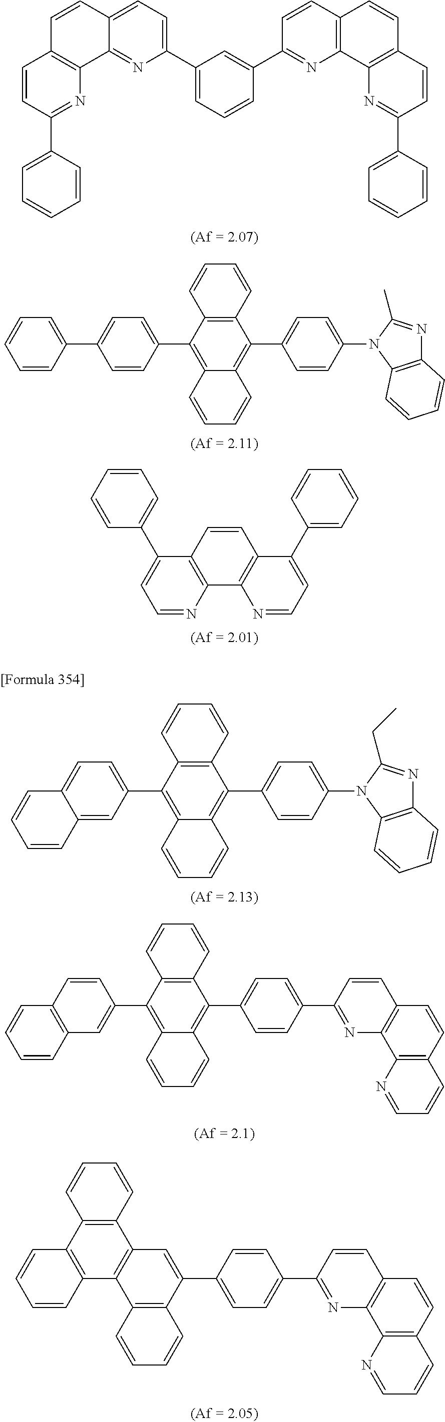 [SMILES: c1ccc(-c2ccc3ccc4ccc(-c5cccc(-c6ccc7ccc8ccc(-c9ccccc9)nc8c7n6)c5)nc4c3n2)cc1 ; Cc1nc2ccccc2n1-c1ccc(-c2c3ccccc3c(-c3ccc(-c4ccccc4)cc3)c3ccccc23)cc1 ; c1ccc(-c2ccnc3c2ccc2c(-c4ccccc4)ccnc23)cc1 ; CCc1nc2ccccc2n1-c1ccc(-c2c3ccccc3c(-c3ccc4ccccc4c3)c3ccccc23)cc1 ; c1ccc2cc(-c3c4ccccc4c(-c4ccc(-c5ccc6ccc7cccnc7c6n5)cc4)c4ccccc34)ccc2c1 ; c1cnc2c(c1)ccc1ccc(-c3ccc(-c4cc5c6ccccc6c6ccccc6c5c5ccccc45)cc3)nc12]

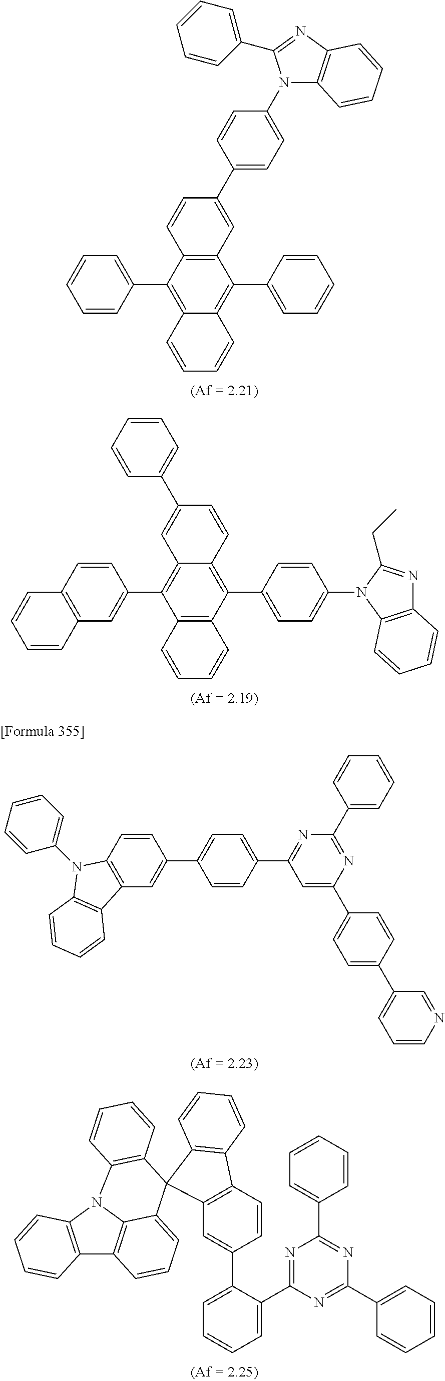 [SMILES: c1ccc(-c2c3ccccc3c(-c3ccccc3)c3cc(-c4ccc(-n5c(-c6ccccc6)nc6ccccc65)cc4)ccc23)cc1 ; CCc1nc2ccccc2n1-c1ccc(-c2c3ccccc3c(-c3ccc4ccccc4c3)c3cc(-c4ccccc4)ccc23)cc1 ; c1ccc(-c2nc(-c3ccc(-c4cccnc4)cc3)cc(-c3ccc(-c4ccc5c(c4)c4ccccc4n5-c4ccccc4)cc3)n2)cc1 ; c1ccc(-c2nc(-c3ccccc3)nc(-c3ccccc3-c3ccc4c(c3)C3(c5ccccc5-4)c4ccccc4-n4c5ccccc5c5cccc3c54)n2)cc1]

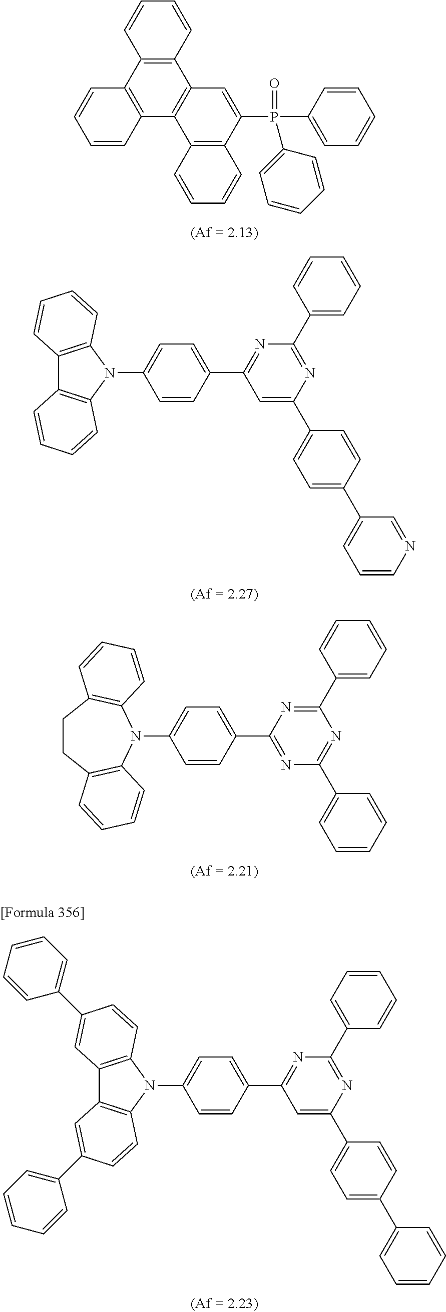

In the organic EL device according to the exemplary embodiment, the electron transporting layer that may be included by the electron transporting zone is not limited to the electron transporting layer containing the nitrogen-containing compound.

The electron transporting layer is a layer containing a highly electron-transportable substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, for instance, a metal complex such as Alq, tris(4-methyl-8-quinolinato)aluminum (abbreviation: Almq3), bis(10-hydroxybenzo[h]quinolinato)beryllium (abbreviation: BeBq2), BAIq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In an exemplary arrangement of the exemplary embodiment, a nitrogen-containing compound (preferably benzimidazole compound) is usable. The above-described substances mostly have an electron mobility of 10⁻⁶ cm²/Vs or more. It should be noted that any other substance than the above substances may be used for the electron transporting layer as long as the substance exhibits a higher electron transportability than the hole transportability. The electron transporting layer may be a single layer or a laminate of two or more layers formed of the above substance.

Further, a high polymer compound is usable for the electron transporting layer. For instance, poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy) are usable.

### Hole Blocking Layer

In an exemplary arrangement of the organic EL device according to the exemplary embodiment, the electron transporting zone may include a hole blocking layer. An electron transporting layer disposed to a side close to the cathode of the emitting layer is occasionally referred to as a hole blocking layer.

The hole blocking layer is preferably a layer transporting electrons and blocking holes from reaching a layer close to the cathode (e.g., electron transporting layer and electron injecting layer) beyond the hole blocking layer. The compound contained in the hole blocking layer is exemplified by a compound used in a known hole blocking layer. The compound contained in the hole blocking layer, which is similar to a compound usable in the electron transporting layer, is preferably at least one compound selected from the group consisting of a metal complex, a heteroaromatic compound, and a high polymer compound. The compound contained in the hole blocking layer may be a nitrogen-containing compound, for instance, at least one compound selected from the group consisting of an imidazole derivative, benzimidazole derivative, azine derivative, carbazole derivative, and phenanthroline derivative.

In order to prevent excitation energy from leaking out from the emitting layer toward neighboring layer(s), the hole blocking layer is also preferably a layer blocking excitons generated in the emitting layer from being transferred to a layer(s) closer to the cathode (e.g., the electron transporting layer and the electron injecting layer) beyond the hole blocking layer.

### Electron Injecting Layer

In an exemplary arrangement of the organic EL device according to the exemplary embodiment, the electron transporting zone may include an electron injecting layer.

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is also usable. Further, the organic compound such as tetrathiafulvalene (abbreviation: TTF) is also usable.

### Schematic Arrangements of Organic EL Devices

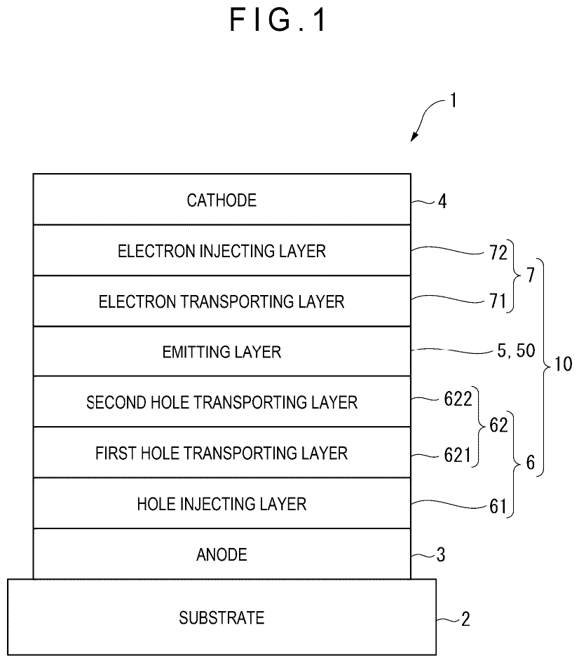

Each of FIGS. 1 to 4 schematically illustrates an exemplary arrangement of the organic EL device according to the exemplary embodiment.

An organic EL device 1 depicted in FIG. 1 includes a substrate 2, an anode 3, a cathode 4, and an organic layer 10 provided between the anode 3 and the cathode 4. The organic layer 10 includes a hole transporting zone 6, an emitting zone 5, and an electron transporting zone 7 in this order from a side close to the anode 3. The hole transporting zone 6 includes a hole injecting layer 61 and a hole transporting layer 62 in this order from the side close to the anode 3. The hole transporting layer 62 includes a first hole transporting layer 621 and a second hole transporting layer 622. The emitting zone 5 includes a single emitting layer 50. The electron transporting zone 7 includes an electron transporting layer 71 and an electron injecting layer 72 in this order from a side close to the emitting zone 5.

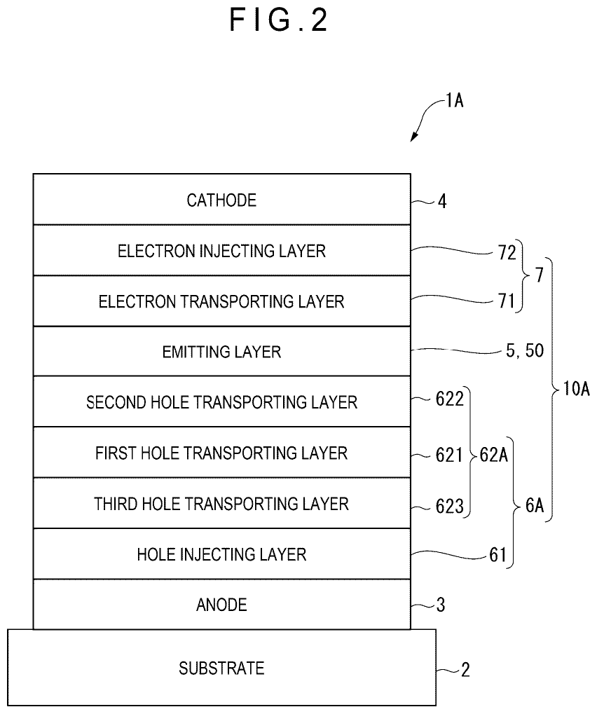

An organic EL device 1A depicted in FIG. 2 is different from the organic EL device 1 in that an organic layer 10A includes a hole transporting zone 6A, and the rest of components and arrangement of the organic EL device 1A are the same as those of the organic EL device 1. The hole transporting zone 6A includes the hole injecting layer 61, a third hole transporting layer 623, the first hole transporting layer 621, and the second hole transporting layer 622 in this order from a side close to the anode 3. A hole transporting layer 62A includes the third hole transporting layer 623, the first hole transporting layer 621, and the second hole transporting layer 622.

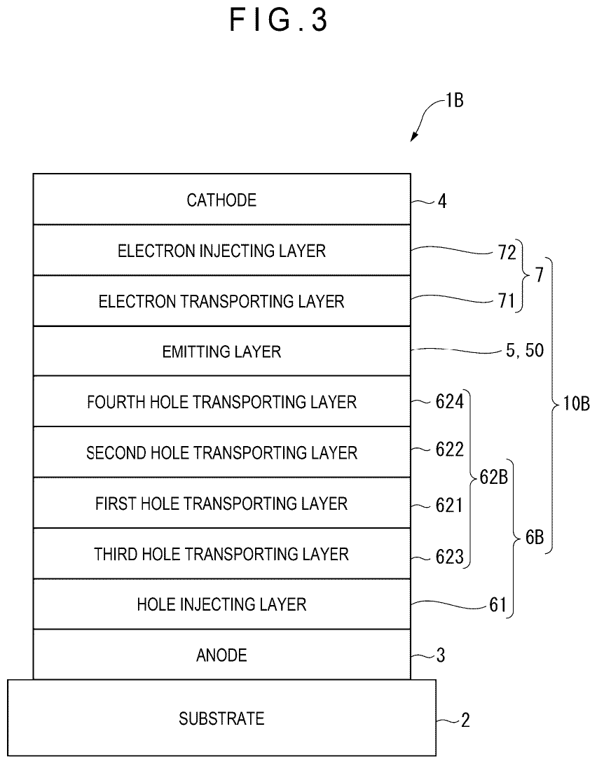

An organic EL device 1B depicted in FIG. 3 is different from the organic EL device 1 in that an organic layer 10B includes a hole transporting zone 6B, and the rest of components and arrangement of the organic EL device 1B are the same as those of the organic EL device 1. The hole transporting zone 6B includes the hole injecting layer 61, the third hole transporting layer 623, the first hole transporting layer 621, the second hole transporting layer 622, and a fourth hole transporting layer 624 in this order from a side close to the anode 3. A hole transporting layer 62B includes the third hole transporting layer 623, the first hole transporting layer 621, the second hole transporting layer 622, and the fourth hole transporting layer 624.

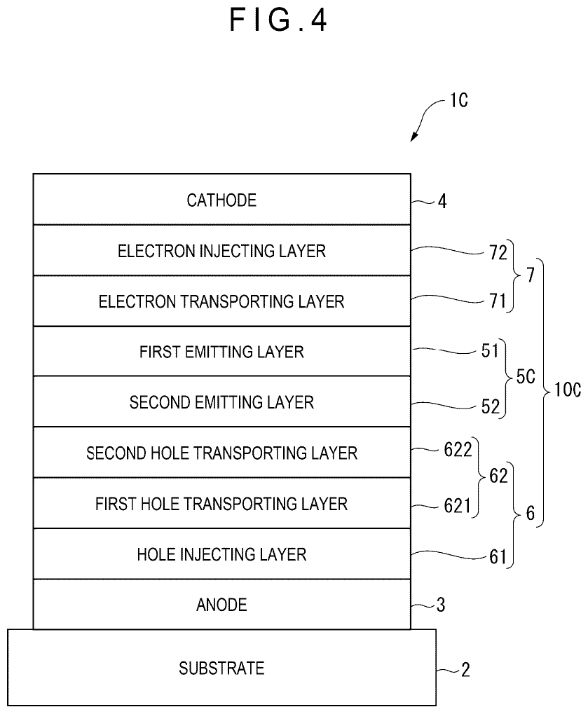

An organic EL device 1C depicted in FIG. 4 is different from the organic EL device 1 in that an organic layer 10C includes an emitting zone 5C, and the rest of components and arrangement of the organic EL device 1C are the same as those of the organic EL device 1. The emitting zone 5C includes a second emitting layer 52 and a first emitting layer 51 in this order from a side close to the anode 3.

The invention is not limited to the exemplary arrangements of the organic EL devices depicted in FIGS. 1 to 4.

An organic EL device with another exemplary arrangement is exemplified by an organic EL device including the emitting zone 5C in place of the emitting zone 5 of the organic EL devices 1, 1A, and 1B.

Moreover, an organic EL device with still another exemplary arrangement is exemplified by an organic EL device in which the order of the emitting layers layered in the emitting zone 5C may be changed: the first emitting layer 51 and the second emitting layer 52 are layered in the emitting zone 5C in this order from a side close to the anode. Regardless of the order of the first emitting layer and the second emitting layer layered, the effect obtained by layering the first and second emitting layers in the emitting zone can be expected by selecting a combination of materials satisfying the relationship of the numerical formula (Numerical Formula 1).

Further, an organic EL device with a further exemplary arrangement may include, for instance, a first mixture layer between the first hole transporting layer 621 and the second hole transporting layer 622.

Further, an organic EL device with a still further exemplary arrangement may include, for instance, a second mixture layer between the first hole transporting layer 621 and the third hole transporting layer 623.

Arrangements of the organic EL devices will be further described below.

### Substrate

The substrate is used as a support for the organic EL device. For instance, glass, quartz, plastics and the like are usable for the substrate. A flexible substrate is also usable. The flexible substrate, which is a bendable substrate, is exemplified by a plastic substrate. Examples of a material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

The organic EL device according to the exemplary embodiment may be a bottom emission type organic EL device. The organic EL device according to the exemplary embodiment may be a top emission type organic EL device.

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

In a case of a bottom emission type organic EL device, the anode is preferably made of a light-transmissive or semi-transmissive metallic material that transmits light emitted from the emitting layer. Herein, the light-transmissive or semi-transmissive property means the property of allowing transmissivity of 50% or more (preferably 80% or more) of the light emitted from the emitting layer. The light-transmissive or semi-transmissive metallic material can be selected in use as needed from the above materials listed in the description regarding the anode.

In a case of a top emission type organic EL device, the anode is a reflective electrode having a reflective layer. The reflective layer is preferably made of a metallic material having light reflectivity. Herein, the light reflectivity means the property of reflecting 50% or more (preferably 80% or more) of the light emitted from the emitting layer. The metallic material having light reflectivity can be selected in use as needed from the above materials listed in the description about the anode.

The anode may consist of the reflective layer, but may have a multilayer structure having the reflective layer and a conductive layer (preferably a transparent conductive layer). In a case where the anode has the reflective layer and the conductive layer, the conductive layer is preferably disposed between the reflective layer and the hole transporting zone. A material of the conductive layer can be selected in use as needed from the above materials listed in the description regarding the anode.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method, and the like.

In a case of a bottom emission type organic EL device, the cathode is a reflective electrode. The reflective electrode is preferably made of a metallic material having light reflectivity. The metallic material having light reflectivity can be selected in use as needed from the above materials listed in the description regarding the cathode.

In a case of a top emission type organic EL device, the cathode is preferably made of a light-transmissive or semi-transmissive metallic material that transmits light emitted from the emitting layer. The light-transmissive or semi-transmissive metallic material can be selected in use as needed from the above materials listed in the description regarding the cathode.

### Capping Layer

In a case of a top emission type organic EL device, the organic EL device usually includes a capping layer on the top of the cathode.

The capping layer may contain, for instance, at least one compound selected from the group consisting of a high polymer compound, metal oxide, metal fluoride, metal boride, silicon nitride, and silicon compound (silicon oxide or the like).

The capping layer may contain, for instance, at least one compound selected from the group consisting of an aromatic amine derivative, an anthracene derivative, a pyrene derivative, a fluorene derivative, and a dibenzofuran derivative.

In addition, a laminate in which layers containing these substances are layered can also be used as the capping layer.

### Layer Formation Method(s)

A method for forming each layer of the organic EL device according to any of the above exemplary embodiments is subject to no limitation except for the above particular description. However, known methods of dry film-forming such as vacuum deposition, sputtering, plasma or ion plating and wet film-forming such as spin coating, dipping, flow coating or ink-jet are applicable.

In an exemplary arrangement of the organic EL device of the exemplary embodiment, each layer of the organic EL device (e.g., each layer of the organic layer included by the first hole transporting zone and the emitting layer included by the emitting zone) may be formed, for instance, by co-deposition using a plurality of types of compounds, by vapor-deposition using a mixture of a plurality of types of compounds prepared in advance, or by coating using a mixture of a plurality of types of compounds prepared in advance. The composition according to the first exemplary embodiment is usable as the mixture.

The mixture prepared by mixing a plurality of types of compounds in advance may be a powder. The mixture prepared by mixing a plurality of types of compounds in advance may be a solution. A method of mixing a plurality of types of compounds in advance is occasionally referred to as premix. A premix method, which is not particularly limited, enables adjustment of molecular weights of compounds forming a mixture by adjusting substituents or the like of the compounds or enables adjustment of a vapor-deposition ratio of compounds forming a mixture premixed.

The premixed mixture powder may contain a first organic compound and a second organic compound in one particle or may be a mixture of particles of the first organic compound and particles of the second organic compound. When the composition according to the first exemplary embodiment is used as the mixture, the first compound and the second compound correspond to the first organic compound and the second organic organic compound, respectively.

As a method of producing the mixture powder, for instance, the first organic compound and the second organic compound may be pulverized and mixed using a mortar or the like, or the first organic compound and the second organic compound may be put into a container or the like and heated to be melted in a chemically inert environment, cooled to ambient temperature, and the resulting mixture is pulverized with a mixer or the like to form powder. According to the latter method, the first organic compound and the second organic compound can be mixed at a molecular level, whereby a ratio in term of a sublimation area between the first organic compound and the second organic compound can be easily controlled to fall within a desired range, which enables more uniform vapor-deposition. Moreover, it is possible to prevent disadvantages such as uneven mixing of mixture powder that may occur during delivery of the mixture powder.

Mixture powder may be compressed into pellets.

### Film Thickness

A film thickness of each layer of the organic layer of the organic EL device of the exemplary embodiment is not limited unless otherwise specified in the above. The film thickness of each layer of the organic layer of the organic EL device usually preferably ranges from several nanometers to 1 μm because in general an excessively small film thickness is likely to cause defects (e.g. pin holes) and an excessively large film thickness leads to the necessity of applying high voltage and consequent reduction in efficiency.

### Emission Wavelength of Organic EL Device

The organic EL device with an exemplary arrangement of the exemplary embodiment emits light whose maximum peak wavelength is 500 nm or less when the device is driven.

The organic EL device with an exemplary arrangement of the exemplary embodiment emits light whose maximum peak wavelength is in a range from 430 nm to 480 nm when the device is driven.

The maximum peak wavelength of the light emitted from the organic EL device when being driven is measured as follows.

Voltage is applied to the organic EL device such that a current density is 10 mA/cm², where spectral radiance spectrum is measured by a spectroradiometer CS-2000 (produced by Konica Minolta, Inc.). A peak wavelength of an emission spectrum, a luminous intensity of which is the maximum in the obtained spectral radiance spectrum, is measured and defined as the maximum peak wavelength (unit: nm).

### Triplet Energy T₁

A method of measuring a triplet energy T₁ is exemplified by a method below.

A measurement target compound is dissolved in EPA (diethylether:isopentane:ethanol=5:5:2 in volume ratio) so as to fall within a range from 10⁻⁵ mol/L to 10⁻⁴ mol/L to prepare a solution, and the obtained solution is encapsulated in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value Δ_{edge} [nm] at an intersection of the tangent and the abscissa axis. The calculated energy amount is defined as triplet energy T₁.

$${T}_{1} [ eV ] = 1239.85 / {λ}_{edge} \qquad Conversion Equation ( F 1 )$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (produced by Hitachi High-Technologies Corporation) is usable. The measurement apparatus is not limited thereto. A combination of a cooling unit, a low temperature container, an excitation light source and a light-receiving unit may be used for measurement.

### Singlet Energy S₁

A method of measuring a singlet energy S₁ with use of a solution (occasionally referred to as a solution method) is exemplified by a method below.

A toluene solution of a measurement target compound at a concentration ranging from 10⁻⁵ mol/L to 10⁻⁴ mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value λ_{edge} (nm) at an intersection of the tangent and the abscissa axis is assigned to a conversion equation (F2) below to calculate singlet energy.

$${S}_{1} [ eV ] = 1239.85 / {λ}_{edge} \qquad Conversion Equation ( F 2 )$$

Any apparatus for measuring absorption spectrum is usable. For instance, a spectrophotometer (U3310 manufactured by Hitachi, Ltd.) is usable.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Third Exemplary Embodiment

### Composition

A composition according to the exemplary embodiment includes the first compound and the second compound. The first compound and the second compound are mutually different and are each independently an amine compound having a refractive index of 1.85 or less.

In an exemplary arrangement of the composition according to the exemplary embodiment, at least one of the first compound or the second compound is an amine compound having a refractive index of 1.83 or less.

In an exemplary arrangement of the organic EL device according to the exemplary embodiment, an absolute value |n₁−n₂| of a difference between a refractive index of the first compound n₁ and a refractive index of the second compound n₂ is 0.05 or less.

In an exemplary arrangement of the organic EL device according to the exemplary embodiment, the absolute value |n₁−n₂| of the difference between the refractive index of the first compound n₁ and the refractive index of the second compound n₂ is 0.03 or less.

In the composition according to the exemplary embodiment, the molecular structure of each of the first and second compounds is not particularly limited as long as the above refractive index range (refractive index of 1.85 or less) is met. For instance, the first and second compounds are each independently a compound represented by the formula (C1) or a compound represented by the formula (C3).

In an exemplary arrangement of the organic EL device according to the exemplary embodiment, the first and second compounds are each independently a monoamine compound having one substituted or unsubstituted amino group in a molecule, or a diamine compound having two substituted or unsubstituted amino groups in a molecule.

In an exemplary arrangement of the organic EL device according to the exemplary embodiment, the first and second compounds are each independently a monoamine compound.

Specific examples of the first and second compounds contained in the composition according to the exemplary embodiment include the specific examples of the hole transporting zone material described in the second exemplary embodiment. However, the invention is by no means limited to the specific examples.

### Ratio of Compounds in Composition

In an exemplary arrangement of the composition according to the exemplary embodiment, a ratio (mass ratio) of the first and second compounds in the composition is in a range from 1:99 to 99:1, from 10:90 to 90:10, from 30:70 to 70:30, from 40:60 to 60:40, or from 45:55 to 55:45.

In an exemplary arrangement of the composition according to the exemplary embodiment, a mass percentage of a mass of the first compound M_{C1} to the sum M_{C1}+M_{C2} of the mass of the first compound M_{C1} and the mass of the second compound M_{C2} in the composition is in a range from 1 mass % to 99 mass %.

In an exemplary arrangement of the composition of the exemplary embodiment, a mass percentage of a mass of the second compound M_{C2} to the sum M_{C1}+M_{C2} is 10 mass % or more, 30 mass % or more, 40 mass % or more, or 45 mass % or more.

In an exemplary arrangement of the composition of the exemplary embodiment, the mass percentage of the mass of the first compound M_{C1} to the sum M_{C1}+M_{C2} is 90 mass % or less, 70 mass % or less, 60 mass % or less, or 55 mass % or less.

In an exemplary arrangement of the composition of the exemplary embodiment, the composition is in a form of mixed powder.

In an exemplary arrangement of the composition of the exemplary embodiment, the composition is not in a form of a film or layer.

In an exemplary arrangement of the composition of the exemplary embodiment, the composition may be in a form of a film or layer as described later in a fourth exemplary embodiment.

### Fourth Exemplary Embodiment

### Organic Electroluminescence Device

An organic electroluminescence device according to the exemplary embodiment is different from the organic electroluminescence device according to the second exemplary embodiment in that at least one layer of the organic layer contains the composition according to the third exemplary embodiment, and otherwise is the same as the organic electroluminescence device according to the second exemplary embodiment. Accordingly, the description on the second exemplary embodiment except for the above difference is also applied to the fourth exemplary embodiment.

An organic electroluminescence device according to the exemplary embodiment includes the anode, the cathode, and the organic layer disposed between the anode and the cathode, in which at least one layer of the organic layer contains the first compound and the second compound, the first compound and the second compound are mutually different compounds and are each independently an amine compound having a refractive index of 1.85 or less.

Also in an exemplary arrangement of the organic EL device according to the exemplary embodiment, the first and second compounds are contained in the same layer.

In an exemplary arrangement of the organic EL device of the exemplary embodiment, a layer containing the first and second compounds has a film thickness of 25 nm or more.

In an exemplary arrangement of the organic EL device of the exemplary embodiment, also when the first and second compounds are each independently an amine compound having a refractive index of 1.85 or less and a layer containing the first and second compounds has a film thickness of 25 nm or more, a luminous efficiency of the organic EL device is improved.

### Fifth Exemplary Embodiment

### Electronic Device

An electronic device according to a fifth exemplary embodiment is installed with the organic EL device according to the above exemplary embodiments. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light. The light-emitting apparatus also can be used for a display device, for instance, as a backlight of the display device.

### Modification of Embodiments

The scope of the invention is not limited by the above exemplary embodiments but includes any modification and improvement as long as such modification and improvement are compatible with the invention.

For instance, the number of emitting layers is not limited to one or two, and more than two emitting layers may be layered. For instance, the rest of the emitting layers may be a fluorescent emitting layer or a phosphorescent emitting layer with use of emission caused by electron transfer from the triplet excited state directly to the ground state.

The specific structure, shape, and the like of the components in the invention may be designed in any manner as long as an object of the invention can be achieved.

### EXAMPLES

The invention will be described in further detail with reference to Examples. The scope of the invention is by no means limited to Examples.

### Compounds

Structures of compounds used for producing organic EL devices in Examples 1-1, 2-1, 3-1, 4-1, 5-1, 6-1, 7-1, and 8-1, and Comparatives 1-1 to 1-3, 2-1 to 2-3, 3-1 to 3-2, 4-1 to 4-3, 5-1 to 5-3, 6-1 to 6-3, 7-1 to 7-3 and 8-1 to 8-3 are shown below.

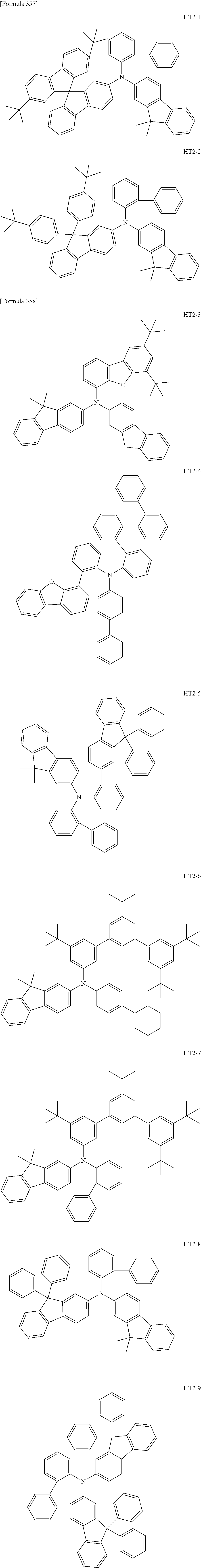

Structures of other compounds used for producing the organic EL devices in Examples 1-1, 2-1, 3-1, 4-1, 5-1, 6-1, 7-1, and 8-1, and Comparatives 1-1 to 1-3, 2-1 to 2-3, 3-1 to 3-2, 4-1 to 4-3, 5-1 to 5-3, 6-1 to 6-3, 7-1 to 7-3 and 8-1 to 8-3 are shown below.

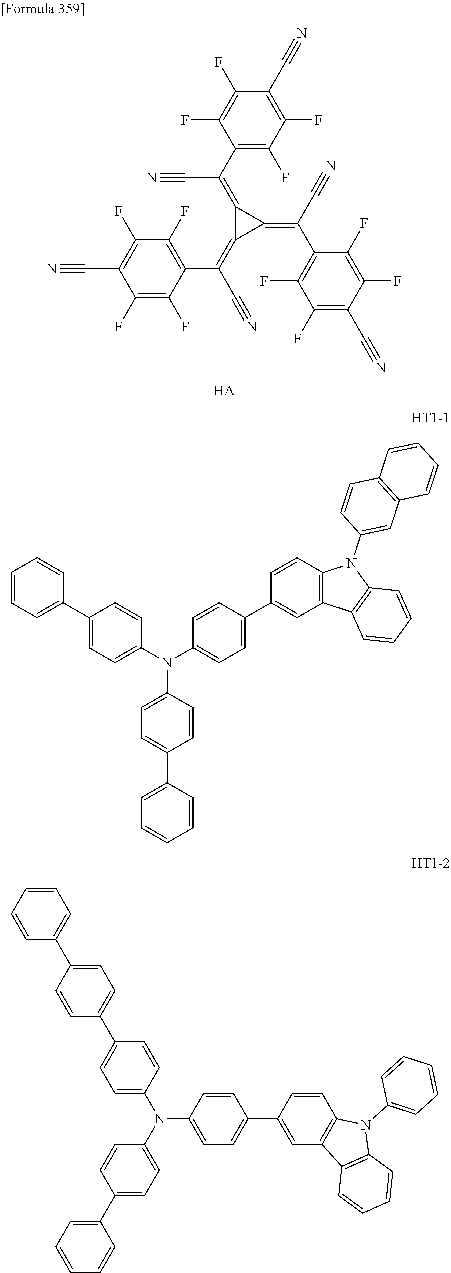 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; "HA" ; c1ccc(-c2ccc(N(c3ccc(-c4ccccc4)cc3)c3ccc(-c4ccc5c(c4)c4ccccc4n5-c4ccc5ccccc5c4)cc3)cc2)cc1 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1]

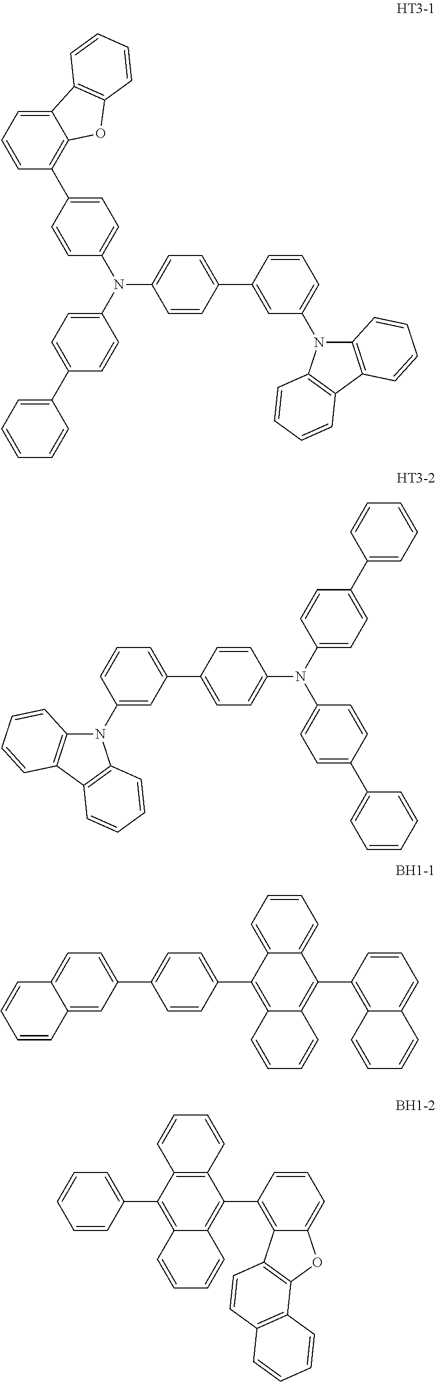

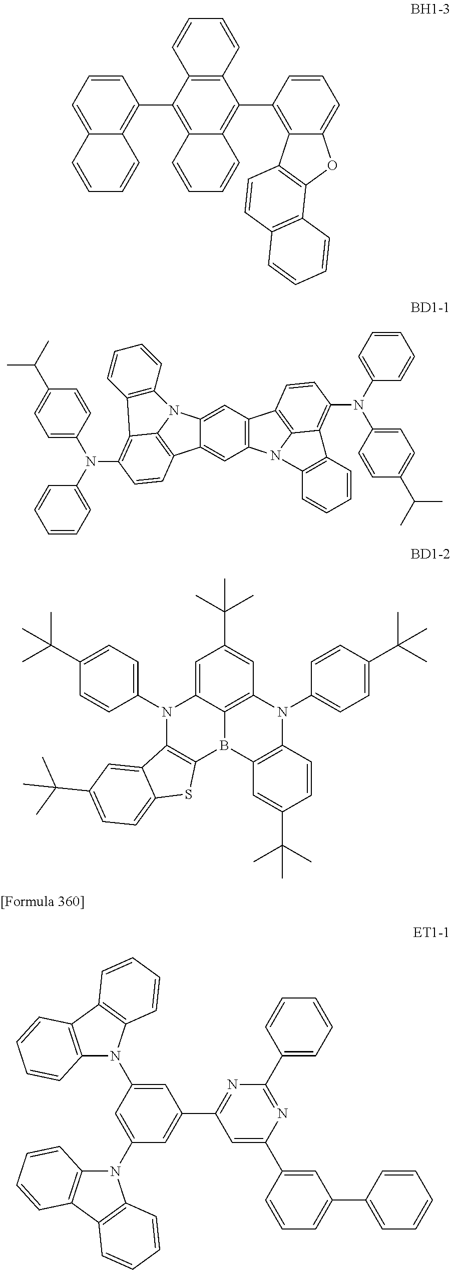

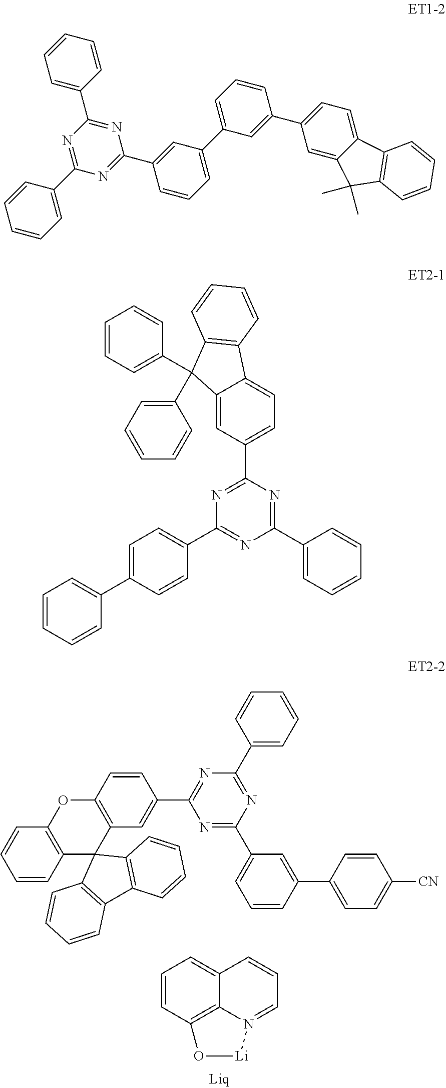

### Production (1) of Organic EL Devices

Organic EL devices were produced as described below.

### Example 1-1

A glass substrate (size: 25 mm×75 mm×1.1 mm thick, produced by Geomatec Co., Ltd.) having an ITO (indium tin oxide) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, a compound HT1-1 and a compound HA were co-deposited on a surface of the glass substrate where the transparent electrode line was provided in a manner to cover the transparent electrode, thereby forming a 10-nm-thick hole injecting layer. Ratios of the compound HT1-1 and the compound HA in the hole injecting layer were 97 mass % and 3 mass %, respectively.

The compound HT1-1 was then vapor-deposited on the hole injecting layer to form a 35-nm-thick first hole transporting layer.

Next, using a composition containing a compound HT2-1 and a compound HT2-2 in a mass ratio of 1:1, the compound HT2-1 and the compound HT2-2 were co-deposited on the first hole transporting layer to form a 45-nm-thick second hole transporting layer. The ratios of the compound HT2-1 and the compound HT2-2 in the second hole transporting layer were both 50 mass %.

A compound HT3-1 was vapor-deposited on the second hole transporting layer to form a 5-nm-thick fourth hole transporting layer. The fourth hole transporting layer is occasionally referred to as an electron blocking layer.

A compound BH1-1 (first host material) and a compound BD1-1 (first luminescent compound) were co-deposited on the fourth hole transporting layer to form a 20-nm-thick emitting layer. The ratios of the compound BH1-1 and the compound BD1-1 in the emitting layer were 99 mass % and 1 mass %, respectively.

A compound ET1-1 was vapor-deposited on the emitting layer to form a 5-nm-thick first electron transporting layer. The first electron transporting layer is occasionally referred to as an hole blocking layer.

A compound ET2-1 and a compound Liq were co-deposited on the first electron transporting layer to form a 25-nm-thick second electron transporting layer. The ratios of the compound ET2-1 and the compound Liq in the second electron transporting layer were both 50 mass %.

Next, ytterbium (Yb) was vapor-deposited on the second electron transporting layer to form a 1-nm-thick electron injecting layer.

Metal Al was vapor-deposited on the electron injecting layer to form an 80-nm-thick cathode.

A device arrangement of the organic EL device in Example 1-1 is roughly shown as follows.

$$ITO ( 130 ) / HT 1 - 1 : HA ( 10 , 97 \% : 3 \% ) / HT 1 - 1 ( 35 ) / HT 2 - 1 : HT 2 - 2 ( 45 , 50 \% : 50 \% ) / HT 3 - 1 ( 5 ) / BH 1 - 1 : BD 1 - 1 ( 20 , 99 \% : 1 \% ) / ET 1 - 1 ( 5 ) / ET 2 - 1 : Liq ( 25 , 50 \% : 50 \% ) / Yb ( 1 ) / Al ( 80 )$$

Numerals in parentheses represent a film thickness (unit: nm).

In the device arrangement of Example 1-1: the numerals (97%:3%) represented by percentage in the same parentheses indicate a ratio (mass %) between the compound HT1-1 and the compound HA in the hole injecting layer; the numerals (50%:50%) represented by percentage in the same parentheses indicate a ratio (mass %) between the compound HT2-1 and the compound HT2-2 in the second hole transporting layer, or the compound ET2-1 and the compound Liq in the second electron transporting layer; and the numerals (99%:1%) represented by percentage in the same parentheses indicate a ratio (mass %) between the compound BH1-1 and the compound BD1-1 in the emitting layer. Similar notations apply to the description below.

### Comparatives 1-1, 1-2, and 1-3

Organic EL devices of Comparatives 1-1, 1-2, and 1-3 were each produced in the same manner as the organic EL device of Example 1-1 except that the second hole transporting layer was formed using only one of the first compound and the second compound as shown in Table 1 without using a composition.

### Evaluation (1) of Organic EL Devices

The organic EL devices produced were evaluated as follows. Table 1 shows the evaluation results.

### External Quantum Efficiency EQE

Voltage was applied to each of the organic EL devices produced in Example 1-1 and Comparatives 1-1 to 1-3 such that a current density was 10 mA/cm², where spectral radiance spectrum was measured by a spectroradiometer CS-2000 (produced by Konica Minolta, Inc.). The external quantum efficiency EQE was calculated based on the obtained spectral radiance spectra, assuming that the spectra was provided under a Lambertian radiation. A unit of EQE is %.

Table 1 shows relative values of EQE, which were calculated according to a numerical formula (Numerical Formula X1) below. A unit of the relative value of EQE is %.

$$EQE ( relative value ) = ( EQE of each Example / EQE of Example 1 - 1 ) \times 100 \qquad ( Numerical Formula X1 )$$

TABLE 1

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 1-1 | HT2-2 | 1.75 | 50 | HT2-1 | 1.77 | 50 | 100% |
| Comp. 1-1 | HT2-2 | 1.75 | 100 | — | — | — | 65% |
| Comp. 1-2 | — | — | — | HT2-1 | 1.77 | 100 | 92% |
| Comp. 1-3 | HT1-1 | 1.97 | 100 | — | — | — | 81% |

The second hole transporting layer of the organic EL device in Example 1-1 contained the first compound and the second compound that were each an amine compound having a refractive index of 1.80 or less. The organic EL device of Example 1-1 exhibited an improved luminous efficiency as compared with the organic EL devices of Comparatives 1-1 to 1-3, as shown in Table 1.

In Table 1, for convenience of explanation, the compounds used to form the second hole transporting layer are listed in columns of the first compound and the second compound. Also, the compound HT1-1, which is a compound with a refractive index exceeding 1.80, is listed in the column of the first compound for convenience of explanation. The same applies to Tables below.

### Production (2) of Organic EL Devices

Organic EL devices were produced as described below.

### Example 2-1

A glass substrate (size: 25 mm×75 mm×1.1 mm thick, produced by Geomatec Co., Ltd.) having an ITO (indium tin oxide) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, a compound HT1-1 and a compound HA were co-deposited on a surface of the glass substrate where the transparent electrode line was provided in a manner to cover the transparent electrode, thereby forming a 10-nm-thick hole injecting layer. Ratios of the compound HT1-1 and the compound HA in the hole injecting layer were 97 mass % and 3 mass %, respectively.

The compound HT1-1 was then vapor-deposited on the hole injecting layer to form a 35-nm-thick first hole transporting layer.

Next, using a composition containing the compound HT2-1 and the compound HT2-2 in a mass ratio of 1:1, the compound HT2-1 and the compound HT2-2 were co-deposited on the first hole transporting layer to form a 45-nm-thick second hole transporting layer. The ratios of the compound HT2-1 and the compound HT2-2 in the second hole transporting layer were both 50 mass %.

A compound HT3-1 was vapor-deposited on the second hole transporting layer to form a 5-nm-thick fourth hole transporting layer. The fourth hole transporting layer is occasionally referred to as an electron blocking layer.

A compound BH1-2 (first host material) and a compound BD1-1 (first luminescent compound) were co-deposited on the fourth hole transporting layer to form a 20-nm-thick emitting layer. The ratios of the compound BH1-2 and the compound BD1-1 in the emitting layer were 99 mass % and 1 mass %, respectively.

A compound ET1-2 was vapor-deposited on the emitting layer to form a 5-nm-thick first electron transporting layer. The first electron transporting layer is occasionally referred to as an hole blocking layer.

A compound ET2-1 and a compound Liq were co-deposited on the first electron transporting layer to form a 25-nm-thick second electron transporting layer. The ratios of the compound ET2-1 and the compound Liq in the second electron transporting layer were both 50 mass %.

Next, ytterbium (Yb) was vapor-deposited on the second electron transporting layer to form a 1-nm-thick electron injecting layer.

Metal Al was vapor-deposited on the electron injecting layer to form an 80-nm-thick cathode.

A device arrangement of the organic EL device in Example 2-1 is roughly shown as follows.

$$ITO ( 130 ) / HT 1 - 1 : HA ( 10 , 97 \% : 3 \% ) / HT 1 - 1 ( 35 ) / HT 2 - 1 : HT 2 - 2 ( 45 , 50 \% : 50 \% ) / HT 3 - 1 ( 5 ) / BH 1 - 2 : BD 1 - 1 ( 20 , 99 \% : 1 \% ) / ET 1 - 2 ( 5 ) / ET 2 - 1 : Liq ( 25 , 50 \% : 50 \% ) / Yb ( 1 ) / Al ( 80 )$$

### Comparatives 2-1, 2-2, and 2-3

Organic EL devices of Comparatives 1-1, 1-2, and 1-3 were each produced in the same manner as the organic EL device of Example 1-1 except that the second hole transporting layer was formed using only one of the first compound and the second compound as shown in Table 2 without using a composition.

### Evaluation (2) of Organic EL Devices

The organic EL devices produced in Example 2-1 and Comparatives 2-1 to 2-3 were evaluated in terms of external quantum efficiency EQE in the same manner as in Evaluation (1) of Organic EL Devices. Table 2 shows the evaluation results. Table 2 shows relative values of EQE, which were calculated according to a numerical formula (Numerical Formula X2) below. A unit of the relative value of EQE is %.

$$EQE ( relative value ) = ( EQE of each Example / EQE of Example 2 - 1 ) \times 100 \qquad ( Numerical Formula X2 )$$

TABLE 2

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 2-1 | HT2-2 | 1.75 | 50 | HT2-1 | 1.77 | 50 | 100% |
| Comp. 2-1 | HT2-2 | 1.75 | 100 | — | — | — | 75% |
| Comp. 2-2 | — | — | — | HT2-1 | 1.77 | 100 | 87% |
| Comp. 2-3 | HT1-1 | 1.97 | 100 | — | — | — | 77% |

The second hole transporting layer of the organic EL device in Example 2-1 contained the first compound and the second compound that were each an amine compound having a refractive index of 1.80 or less. The organic EL device of Example 2-1 exhibited an improved luminous efficiency as compared with the organic EL devices of Comparatives 2-1 to 2-3, as shown in Table 2.

### Production (3) of Organic EL Devices

Organic EL devices were produced as described below.

### Example 3-1

A glass substrate (size: 25 mm×75 mm×1.1 mm thick, produced by Geomatec Co., Ltd.) having an ITO (indium tin oxide) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, a compound HT1-2 and a compound HA were co-deposited on a surface of the glass substrate where the transparent electrode line was provided in a manner to cover the transparent electrode, thereby forming a 10-nm-thick hole injecting layer. Ratios of the compound HT1-2 and the compound HA in the hole injecting layer were 97 mass % and 3 mass %, respectively.

The compound HT1-2 was vapor-deposited on the hole injecting layer to form a 45-nm-thick first hole transporting layer.

Next, using a composition containing the compound HT2-1 and the compound HT2-2 in a mass ratio of 1:1, the compound HT2-1 and the compound HT2-2 were co-deposited on the first hole transporting layer to form a 40-nm-thick second hole transporting layer. The ratios of the compound HT2-1 and the compound HT2-2 in the second hole transporting layer were both 50 mass %.

A compound HT3-2 was vapor-deposited on the second hole transporting layer to form a 5-nm-thick fourth hole transporting layer. The fourth hole transporting layer is occasionally referred to as an electron blocking layer.

A compound BH1-3 (first host material) and a compound BD1-2 (first luminescent compound) were co-deposited on the fourth hole transporting layer to form a 20-nm-thick emitting layer. The ratios of the compound BH1-3 and the compound BD1-2 in the emitting layer were 99 mass % and 1 mass %, respectively.

A compound ET1-1 was vapor-deposited on the emitting layer to form a 5-nm-thick first electron transporting layer. The first electron transporting layer is occasionally referred to as an hole blocking layer.

A compound ET2-2 and a compound Liq were co-deposited on the first electron transporting layer to form a 31-nm-thick second electron transporting layer. The ratios of the compound ET2-2 and the compound Liq in the second electron transporting layer were both 50 mass %.

The compound Liq was vapor-deposited on the second electron transporting layer to form a 1-nm-thick electron injecting layer.

Metal Al was vapor-deposited on the electron injecting layer to form an 80-nm-thick cathode.

A device arrangement of the organic EL device in Example 3-1 is roughly shown as follows.

$$ITO ( 130 ) / HT 1 - 2 : HA ( 10 , 97 \% : 3 \% ) / HT 1 - 2 ( 45 ) / HT 2 - 1 : HT 2 - 2 ( 40 , 50 \% : 50 \% ) / HT 3 - 2 ( 5 ) / BH 1 - 3 : BD 1 - 2 ( 20 , 99 \% : 1 \% ) / ET 1 - 1 ( 5 ) / ET 2 - 2 : Liq ( 31 , 50 \% : 50 \% ) / Liq ( 1 ) / Al ( 80 )$$

### Comparatives 3-1 and 3-2

Organic EL devices of Comparatives 3-1 and 3-2 were each produced in the same manner as the organic EL device of Example 3-1 except that the second hole transporting layer was formed using only one of the first compound and the second compound as shown in Table 3 without using a composition.

### Evaluation (3) of Organic EL Devices

The organic EL devices produced in Example 3-1 and Comparatives 3-1 to 3-2 were evaluated in terms of external quantum efficiency EQE in the same manner as in Evaluation (1) of Organic EL Devices. Table 3 shows the evaluation results. Table 3 shows relative values of EQE, which were calculated according to a numerical formula (Numerical Formula X3) below. A unit of the relative value of EQE is %.

$$( Numerical Formula X 3 )$$

$$EQE ( relative value ) = ( EQE of each Example / EQE of Example 3 - 1 ) \times 100$$

TABLE 3

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 3-1 | HT2-2 | 1.75 | 50 | HT2-1 | 1.77 | 50 | 100% |
| Comp. 3-1 | — | — | — | HT2-1 | 1.77 | 100 | 94% |
| Comp. 3-2 | HT1-2 | 1.99 | 100 | — | — | — | 81% |

The second hole transporting layer of the organic EL device in Example 3-1 contained the first compound and the second compound that were each an amine compound having a refractive index of 1.80 or less. The organic EL device of Example 3-1 exhibited an improved luminous efficiency as compared with the organic EL devices of Comparatives 3-1 to 3-2, as shown in Table 3.

### Production (4) of Organic EL Devices

Organic EL devices were produced as described below.

### Example 4-1

A glass substrate (size: 25 mm×75 mm×1.1 mm thick, produced by Geomatec Co., Ltd.) having an ITO (indium tin oxide) transparent electrode (anode) was ultrasonic-cleaned in isopropyl alcohol for five minutes, and then UV-ozone-cleaned for 30 minutes. The film thickness of the ITO transparent electrode was 130 nm.

After the glass substrate having the transparent electrode line was cleaned, the glass substrate was mounted on a substrate holder of a vacuum deposition apparatus. Firstly, a compound HT1-2 and a compound HA were co-deposited on a surface of the glass substrate where the transparent electrode line was provided in a manner to cover the transparent electrode, thereby forming a 10-nm-thick hole injecting layer. Ratios of the compound HT1-2 and the compound HA in the hole injecting layer were 97 mass % and 3 mass %, respectively.

Next, using a composition containing the compound HT2-1 and the compound HT2-2 in a mass ratio of 1:1, the compound HT2-1 and the compound HT2-2 were co-deposited on the hole injecting layer to form a 20-nm-thick first hole transporting layer. The ratios of the compound HT2-1 and the compound HT2-2 in the first hole transporting layer were both 50 mass %.

The compound HT3-2 was vapor-deposited on the first hole transporting layer to form a 5-nm-thick second hole transporting layer. The second hole transporting layer is occasionally referred to as an electron blocking layer.

The compound BH1-3 (first host material) and the compound BD1-2 (first luminescent compound) were co-deposited on the second hole transporting layer to form a 20-nm-thick emitting layer. The ratios of the compound BH1-3 and the compound BD1-2 in the emitting layer were 99 mass % and 1 mass %, respectively.

A compound ET1-2 was vapor-deposited on the emitting layer to form a 5-nm-thick first electron transporting layer. The first electron transporting layer is occasionally referred to as an hole blocking layer.

A compound ET2-2 and a compound Liq were co-deposited on the first electron transporting layer to form a 31-nm-thick second electron transporting layer. The ratios of the compound ET2-2 and the compound Liq in the second electron transporting layer were both 50 mass %.

The compound Liq was vapor-deposited on the second electron transporting layer to form a 1-nm-thick electron injecting layer.

Metal Al was vapor-deposited on the electron injecting layer to form an 80-nm-thick cathode.

A device arrangement of the organic EL device in Example 4-1 is roughly shown as follows.

$$ITO ( 130 ) / HT 1 - 2 : HA ( 10 , 97 \% : 3 \% ) / HT 2 - 2 ( 20 , 50 \% : 50 \% ) / HT 3 - 2 ( 5 ) / BH 1 - 3 : BD 1 - 2 ( 20 , 99 \% : 1 \% ) / ET 1 - 2 ( 5 / ET 2 - 2 : Liq ( 31 , 50 \% : 50 \% ) / Liq ( 1 ) / AI ( 80 )$$

### Comparatives 4-1, 4-2, and 4-3

Organic EL devices of Comparatives 4-1, 4-2, and 4-3 were each produced in the same manner as the organic EL device of Example 4-1 except that the second hole transporting layer was formed using only one of the first compound and the second compound as shown in Table 4 without using a composition.

### Evaluation (4) of Organic EL Devices

The organic EL devices produced in Example 4-1 and Comparatives 4-1 to 4-3 were evaluated in terms of external quantum efficiency EQE in the same manner as in Evaluation (1) of Organic EL Devices. Table 4 shows the evaluation results. Table 4 shows relative values of EQE, which were calculated according to a numerical formula (Numerical Formula X4) below. A unit of the relative value of EQE is %.

$$( Numerical Formula X 4 )$$

$$EQE ( relative value ) = ( EQE of each Example / EQE of Example 4 - 1 ) \times 100$$

TABLE 4

| | First hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 4-1 | HT2-2 | 1.75 | 50 | HT2-1 | 1.77 | 50 | 100% |
| Comp. 4-1 | HT2-2 | 1.75 | 100 | — | — | — | 54% |
| Comp. 4-2 | — | — | — | HT2-1 | 1.77 | 100 | 89% |
| Comp. 4-3 | HT1-2 | 1.99 | 100 | — | — | — | 88% |

The first hole transporting layer of the organic EL device in Example 4-1 contained the first compound and the second compound that were each an amine compound having a refractive index of 1.80 or less. The organic EL device of Example 4-1 exhibited an improved luminous efficiency as compared with the organic EL devices of Comparatives 4-1 to 4-3, as shown in Table 4.

### Production (5) of Organic EL Devices

Organic EL devices were produced as described below.

### Example 5-1

An organic EL device in Example 5-1 was produced as in Example 1-1 except that the first compound and the second compound used for forming the second hole transporting layer were replaced with the compounds HT2-3 and HT2-4 shown in Table 5 and the first host material used for forming the emitting layer was replaced with the compound BH1-3.

A device arrangement of the organic EL device in Example 5-1 is roughly shown as follows.

$$ITO ( 130 ) / HT 1 - 1 : HA ( 10 , 97 \% : 3 \% ) / HT 1 - 1 ( 35 ) / HT 2 - 3 : HT 2 - 4 ( 45 / BH 1 - 3 : BD 1 - 2 ( 20 , 99 \% : 1 \% ) / ET 1 - 2 ( 5 / ET 2 - 2 : Liq ( 31 , 50 \% : 50 \% ) / Liq ( 1 ) / AI ( 80 )$$

### Comparatives 5-1, 5-2, and 5-3

Organic EL devices of Comparatives 5-1, 5-2, and 5-3 were each produced in the same manner as the organic EL device of Example 1-1 except that the second hole transporting layer was formed using only one of the first compound and the second compound as shown in Table 5 without using a composition.

### Evaluation (5) of Organic EL Devices

The organic EL devices produced in Example 5-1 and Comparatives 5-1 to 5-3 were evaluated in terms of external quantum efficiency EQE in the same manner as in Evaluation (1) of Organic EL Devices. Table 5 shows the evaluation results. Table 5 shows relative values of EQE, which were calculated according to a numerical formula (Numerical Formula X5) below. A unit of the relative value of EQE is %.

$$( Numerical Formula X 5 )$$

$$EQE ( relative value ) = ( EQE of each Example / EQE of Example 5 - 1 ) \times 100$$

TABLE 5

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 5-1 | HT2-3 | 1.76 | 50 | HT2-4 | 1.77 | 50 | 100% |
| Comp. 5-1 | HT2-3 | 1.76 | 100 | — | — | — | 85% |
| Comp. 5-2 | — | — | — | HT2-4 | 1.77 | 100 | 93% |
| Comp. 5-3 | HT1-1 | 1.97 | 100 | — | — | — | 85% |

The second hole transporting layer of the organic EL device in Example 5-1 contained the first compound and the second compound that were each an amine compound having a refractive index of 1.80 or less. The organic EL device of Example 5-1 exhibited an improved luminous efficiency as compared with the organic EL devices of Comparatives 5-1 to 5-3, as shown in Table 5.

### Production (6) of Organic EL Devices

Organic EL devices were produced as described below.

### Example 6-1

An organic EL device in Example 6-1 was produced as in Example 1-1 except that the first compound and the second compound used for forming the second hole transporting layer were replaced with the compounds HT2-5 and HT2-1 shown in Table 6 and the first host material used for forming the emitting layer was replaced with the compound BH1-3.

A device arrangement of the organic EL device in Example 6-1 is roughly shown as follows.

$$ITO ( 130 ) / HT 1 - 1 : HA ( 10 , 97 \% : 3 \% ) / HT 1 - 1 ( 35 ) / HT 2 - 5 : HT 2 - 1 ( 45 , 50 \% : 50 \% ) / HT 3 - 1 : BD 1 - 1 ( 20 , 99 \% : 1 \% ) / ET 1 - 1 ( 5 ) / ET 2 - 1 : Liq ( 25 , 50 \% : 50 \% ) / Yb ( 1 ) / AI ( 80 )$$

### Comparatives 6-1, 6-2, and 6-3

Organic EL devices of Comparatives 6-1, 6-2, and 6-3 were each produced in the same manner as the organic EL device of Example 1-1 except that the second hole transporting layer was formed using only one of the first compound and the second compound as shown in Table 6 without using a composition.

### Evaluation (6) of Organic EL Devices

The organic EL devices produced in Example 6-1 and Comparatives 6-1 to 6-3 were evaluated in terms of external quantum efficiency EQE in the same manner as in Evaluation (1) of Organic EL Devices. Table 6 shows the evaluation results. Table 6 shows relative values of EQE, which were calculated according to a numerical formula (Numerical Formula X6) below. A unit of the relative value of EQE is %.

$$( Numerical Formula X 6 )$$

$$EQE ( relative value ) = ( EQE of each Example / EQE of Example 6 - 1 ) \times 100$$

TABLE 6

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 6-1 | HT2-5 | 1.78 | 50 | HT2-1 | 1.77 | 50 | 100% |
| Comp. 6-1 | — | — | — | HT2-1 | 1.77 | 100 | 92% |
| Comp. 6-2 | HT2-5 | 1.78 | 100 | — | — | — | 91% |
| Comp. 6-3 | HT1-1 | 1.97 | 100 | — | — | — | 90% |

The second hole transporting layer of the organic EL device in Example 6-1 contained the first compound and the second compound that were each an amine compound having a refractive index of 1.80 or less. The organic EL device of Example 6-1 exhibited an improved luminous efficiency as compared with the organic EL devices of Comparatives 6-1 to 6-3, as shown in Table 6.

### Production (7) of Organic EL Devices

Organic EL devices were produced as described below.

### Example 7-1

An organic EL device in Example 7-1 was produced as in Example 1-1 except that the first compound and the second compound used for forming the second hole transporting layer were replaced with the compounds HT2-6 and HT2-7 shown in Table 7 and the first host material used for forming the emitting layer was replaced with the compound BH1-3.

A device arrangement of the organic EL device in Example 7-1 is roughly shown as follows.

$$ITO ( 130 ) / HT 1 - 1 : HA ( 10 , 97 \% : 3 \% ) / HT 1 - 1 ( 35 ) / HT 2 - 6 : HT 2 - 7 ( 45 , 50 \% : 50 \% ) / HT 3 - 1 ( 5 ) / BD 1 - 1 ( 20 , 99 \% : 1 \% ) / ET 1 - 1 ( 5 ) / ET 2 - 1 : Liq ( 25 , 50 \% : 50 \% ) / Yb ( 1 ) / AI ( 80 )$$

### Comparatives 7-1, 7-2, and 7-3

Organic EL devices of Comparatives 7-1, 7-2, and 7-3 were each produced in the same manner as the organic EL device of Example 1-1 except that the second hole transporting layer was formed using only one of the first compound and the second compound as shown in Table 7 without using a composition.

### Evaluation (7) of Organic EL Devices

The organic EL devices produced in Example 7-1 and Comparatives 7-1 to 7-3 were evaluated in terms of external quantum efficiency EQE in the same manner as in Evaluation (1) of Organic EL Devices. Table 7 shows the evaluation results. Table 7 shows relative values of EQE, which were calculated according to a numerical formula (Numerical Formula X7) below. A unit of the relative value of EQE is %.

$$( Numerical Formula X 7 )$$

$$EQE ( relative value ) = ( EQE of each Example / EQE of Example 7 - 1 ) \times 100$$

TABLE 7

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 7-1 | HT2-6 | 1.67 | 50 | HT2-7 | 1.70 | 50 | 100% |
| Comp. 7-1 | HT2-6 | 1.67 | 100 | — | — | — | 87% |
| Comp. 7-2 | — | — | — | HT2-7 | 1.70 | 100 | 85% |
| Comp. 7-3 | HT1-1 | 1.97 | 100 | — | — | — | 74% |

The second hole transporting layer of the organic EL device in Example 7-1 contained the first compound and the second compound that were each an amine compound having a refractive index of 1.80 or less. The organic EL device of Example 7-1 exhibited an improved luminous efficiency as compared with the organic EL devices of Comparatives 7-1 to 7-3, as shown in Table 7.

### Production (8) of Organic EL Devices

Organic EL devices were produced as described below.

### Example 8-1

An organic EL device in Example 8-1 was produced as in Example 1-1 except that the first compound and the second compound used for forming the second hole transporting layer were replaced with the compounds HT2-8 and HT2-9 shown in Table 8 and the first host material used for forming the emitting layer was replaced with the compound BH1-3.

A device arrangement of the organic EL device in Example 8-1 is roughly shown as follows.

$$ITO ( 130 ) / HT 1 - 1 : HA ( 10 , 97 \% : 3 \% ) / HT 1 - 1 ( 35 ) / HT 2 - 8 : HT 2 - 9 ( 45 , 50 \% : 50 \% ) / HT 3 - 1 ( 5 ) / BD 1 - 3 : ( 20 , 99 \% : 1 \% ) / ET 1 - 1 ( 5 ) / ET 2 - 1 : Liq ( 25 , 50 \% : 50 \% ) / Yb ( 1 ) / AI ( 80 )$$

### Comparatives 8-1, 8-2, and 8-3

Organic EL devices of Comparatives 8-1, 8-2, and 8-3 were each produced in the same manner as the organic EL device of Example 1-1 except that the second hole transporting layer was formed using only one of the first compound and the second compound as shown in Table 8 without using a composition.

### Evaluation (8) of Organic EL Devices

The organic EL devices produced in Example 8-1 and Comparatives 8-1 to 8-3 were evaluated in terms of external quantum efficiency EQE in the same manner as in Evaluation (1) of Organic EL Devices. Table 8 shows the evaluation results. Table 8 shows relative values of EQE, which were calculated according to a numerical formula (Numerical Formula X8) below. A unit of the relative value of EQE is %.

$$( Numerical Formula X 8 )$$

$$EQE ( relative value ) = ( EQE of each Example / EQE of Example 8 - 1 ) \times 100$$

TABLE 8

| | Second hole transporting layer | | | | | | Device |
|---|---|---|---|---|---|---|---|
| | | | | | | | evaluation |
| | First compound | | | Second compound | | | EQE |
| | | Refractive | Ratio | | Refractive | Ratio | (relative |
| | Name | index | [mass %] | Name | index | [mass %] | value) |
| Ex. 8-1 | HT2-8 | 1.83 | 50 | HT2-9 | 1.83 | 50 | 100% |
| Comp. 8-1 | HT2-8 | 1.83 | 100 | — | — | — | 93% |
| Comp. 8-2 | — | — | — | HT2-9 | 1.83 | 100 | 93% |
| Comp. 8-3 | HT1-1 | 1.97 | 100 | — | — | — | 92% |

The second hole transporting layer of the organic EL device in Example 8-1 had a 45-nm film thickness and contained the first compound and the second compound that were each an amine compound having a refractive index of 1.85 or less. The organic EL device of Example 8-1 exhibited an improved luminous efficiency as compared with the organic EL devices of Comparatives 8-1 to 8-3, as shown in Table 8.

### Evaluation on Compounds

### Refractive Index

The refractive index of the constituent material (compound or composition) forming the organic layer was measured as follows.

A measurement target material was vacuum-deposited on a glass substrate to form a film having an approximately 50 nm thickness. Using a spectroscopic ellipsometer (M-2000U1, produced by J. A. Woollam Co., Inc. (US)), the obtained sample film was irradiated with incident light (from ultraviolet light through visible light to near-infrared light) every 5 degrees in a measurement angle range of 45 degrees to 75 degrees to measure change in a deflection state of the light reflected on the sample surface. In order to improve the measurement accuracy of the extinction coefficient, a transmission spectrum in a substrate normal direction (direction perpendicular to a surface of the substrate of the organic EL device) was also measured by M-2000U1. Similarly, the same measurement was performed also on the glass substrate on which no measurement target material was vapor-deposited. The obtained measurement information was fitted using analysis software (Complete EASE) produced by J. A. Woollam Co., Inc.

Refractive indices in an in-plane direction and a normal direction, extinction coefficients in the in-plane direction and the normal direction, and an order parameter of an organic film formed on the substrate were calculated under fitting conditions of using an anisotropic model rotationally symmetric about one axis and setting a parameter MSE indicating a mean square error in said analysis software to be 3.0 or less. A peak close to the long-wavelength region of the extinction coefficient (in-plane direction) was defined as S1, and the order parameter was calculated by a peak wavelength of S1. As fitting conditions for the glass substrate, an isotropic model was used.

Typically, a film formed by vacuum-depositing a low molecular material on the substrate is rotationally symmetric about one axis extending along the substrate normal direction. When an angle formed by the substrate normal direction and a molecular axis in a thin film formed on the substrate is defined as 6 and the extinction coefficients in a substrate parallel direction (Ordinary direction) and a substrate perpendicular direction (Extra-Ordinary direction) obtained by performing the variable-angle spectroscopic ellipsometry measurement on the thin film are respectively defined as ko and ke, S′ represented by a formula below is the order parameter.

$$\begin{matrix}{S}^{′} = 1 - < cos 2 θ >= 2 ko / ( ke + 2 ko ) = 2 / 3 ( 1 - S ) \\ S = ( 1 / 2 ) < 3 cos 2 θ - 1 >= ( ke - ko ) / ( ke + 2 ko )\end{matrix}$$

An evaluation method of the molecular orientation is a publicly known method, and details thereof are described in Organic Electronics, volume 10, page 127 (2009). Further, the method for forming the thin film is a vacuum deposition method.

The order parameter S′ obtained by the variable-angle spectroscopic ellipsometry measurement is 1.0 when all the molecules are oriented in parallel with the substrate. When molecules are random without being oriented, the order parameter S′ is 0.66.

Herein, a value at 2.7 eV in the substrate parallel direction (Ordinary direction), from among the values measured above, is defined as a refractive index of the measurement target material. The refractive index at 2.7 eV corresponds to a refractive index at 460 nm. Herein, the refractive index at 2.7 eV in the substrate parallel direction (Ordinary direction) may be represented by n_{ORD} and the refractive index at 2.7 eV (460 nm) in the substrate perpendicular direction (Extra-Ordinary direction) may be represented by n_{EXT}.

When a layer was formed using a constituent material containing a plurality of compounds, a refractive index of the constituent material of the layer, the layer being a film formed by co-depositing the plurality of compounds as the measurement target material on the glass substrate or a film formed by vapor-depositing a composition containing the plurality of compounds as the measurement target material, may be measured using a spectroscopic ellipsometer in the same manner as above.

The refractive indices of the compounds used in the hole transporting zone are shown in Tables 1 to 4 and below.
Compound HT3-1: 1.94
Compound HT3-2: 1.90

In Examples, since the layer formed by depositing a composition is formed of a mixture (composition) containing two compounds of the first compound and the second compound, a refractive index NM of the layer formed by depositing the composition corresponds to the refractive index of the mixture (composition).

The refractive index of the mixture (composition) can be calculated by totalizing values, each of which is a product of a refractive index of each material and a volume fraction of each material, as described in Reference Literature 1 (J. Mater. Chem., 2009, 19,8907) and Reference Literature 2 (J. Chem. Eng. Data 1992, 37, 310-313). Herein, the refractive index of the mixture (composition) is calculated by replacing a volume fraction (p with a mass ratio assuming that the density of the film formed from the mixture (composition) is substantially constant. For instance, the refractive index NM of the layer containing the first compound and the second compound can be calculated using a numerical formula (Numerical Formula N1) below.

$$NM = {n}_{1} \times {M}_{1} + {n}_{2} \times {M}_{2} \qquad ( Numerical Formula N 1 )$$

In the numerical formula (Numerical Formula N1), n₁ represents the refractive index of the first compound, n₂ represents the refractive index of the second compound, M₁ represents a mass ratio of the first compound in the mixture (composition), and M₂ represents a mass ratio of the second compound in the mixture (composition). A compound whose mass ratio in the mixture (composition) is 0.15 or less is not counted for calculation of the refractive index of the mixture. A compound whose mass ratio in the mixture exceeds 0.15 is counted for calculation of the refractive index of the mixture.

For instance, a refractive index NM(HT2) of the second hole transporting layer of the organic EL device in Example 1-1 is calculated as follows: NM(HT2)=1.75×0.50+1.77×0.50=1.76

### Measurement of Maximum Fluorescence Peak Wavelength (FL-peak) and Full Width at Half Maximum

A measurement target compound was dissolved in toluene at a concentration of 4.9×10⁻⁶ mol/L to prepare a toluene solution thereof. Using a fluorescence spectrometer (spectrophotofluorometer F-7000 manufactured by Hitachi High-Tech Science Corporation), the toluene solution of the measurement target compound was excited at 390 nm, where a maximum fluorescence peak wavelength A (unit: nm) was measured. A full width at half maximum FWHM (unit: nm) at the maximum peak obtained based on the measured fluorescence spectrum was determined as a full width at half maximum of the measurement target compound. FWHM is an abbreviation of full width at half maximum.

The maximum fluorescence peak wavelength A of the compound BD1-1 was 452 nm.

The full width at half maximum at the maximum peak of the compound BD1-1 was 20 nm.

The maximum fluorescence peak wavelength A of the compound BD1-2 was 457 nm.

A full width at half maximum at the maximum peak of the compound BD1-2 was 22 nm.

### EXPLANATION OF CODES

1, 1A, 1B, 1C . . . organic EL device, 10, 10A, 10B, 10C . . . organic layer, 3 . . . anode, 4 . . . cathode, 5, 5C . . . emitting zone, 50 . . . emitting layer, 51 . . . first emitting layer, 52 . . . second emitting layer, 6, 6A, 6B . . . hole transporting zone, 61 . . . hole injecting layer, 62, 62A, 62B . . . hole transporting layer, 621 . . . first hole transporting layer, 622 . . . second hole transporting layer, 623 . . . third hole transporting layer, 624 . . . fourth hole transporting layer, 7 . . . electron transporting zone, 71 . . . electron transporting zone, 72 . . . electron injecting layer

1: A composition comprising: a first compound; and a second compound, wherein
the first compound and the second compound are mutually different compounds, and
the first compound and the second compound are each independently an amine compound having a refractive index of 1.80 or less.

2: The composition according to claim 1, wherein at least one of the first compound or the second compound is an amine compound having a refractive index of 1.78 or less.

3: The composition according to claim 1, wherein an absolute value |n₁-n₂| of a difference between a refractive index of the first compound n₁ and a refractive index of the second compound n₂ is 0.05 or less.

4: The composition according to claim 1, wherein
the first compound and the second compound are each independently a compound represented by a formula (C1) below or a compound represented by a formula (C3) below, 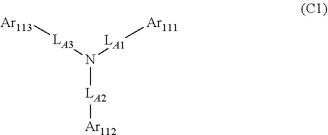
where, in the formula (C1):
L_{A1}, L_{A2}, and L_{A3} are each independently a single bond, a substituted or unsubstituted arylene group having 6 to 50 ring carbon atoms, or a substituted or unsubstituted divalent heterocyclic group having 5 to 50 ring atoms;
Ar₁₁₁, Ar₁₁₂, and Ar₁₁₃ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different, 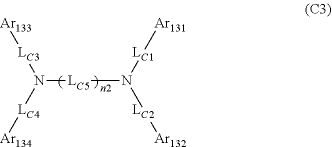
where, in the formula (C3):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n₂ is 1, 2, 3, or 4;
when n₂ is 1, L_{C5} is a substituted or unsubstituted arylene group having 6 to 50 ring carbon atoms, or a substituted or unsubstituted divalent heterocyclic group having 5 to 50 ring atoms;
when n₂ is 2, 3, or 4, a plurality of L_{C5} are mutually the same or different;
when n₂ is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃ and Ar₁₃₄ are each independently a substituted or unsubstituted aryl group having 6 to 50 ring carbon atoms, a substituted or unsubstituted heterocyclic group having 5 to 50 ring atoms, or —Si(R_{C1})(R_{C2})(R_{C3});
R_{C1}, R_{C2}, and R_{C3} are each independently a substituted or unsubstituted aryl group having 6 to 50 ring carbon atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

5: The composition according to claim 4, wherein the first compound and the second compound are each independently a compound represented by the formula (C1).

6: The composition according to claim 4, wherein at least one of an aryl group or a heterocyclic group comprised by a compound represented by the formula (C1) and a compound represented by the formula (C3) is substituted by a substituted or unsubstituted alkyl group having 1 to 50 carbon atoms.

7: The composition according to claim 4, wherein two or more of an aryl group and a heterocyclic group comprised by a compound represented by the formula (C) and a compound represented by the formula (C3) are each substituted by a substituted or unsubstituted alkyl group having 1 to 30 carbon atoms.

8: The composition according to claim 4, wherein
at least one of Ar₁₁₁, Ar₁₁₂, or Ar₁₁₃ in a compound represented by the formula (C1) is a group represented by a formula (C4) below, or at least one of A₁₃₁, Ar₁₃₂, A₁₃₃, or Ar₁₃₄ in a compound represented by the formula (C3) is a group represented by the formula ((C4) below, 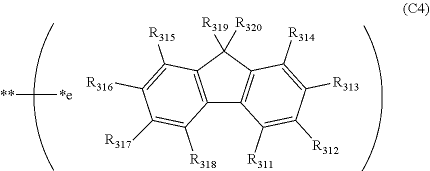
where, in the formula (C4):
one of R₃₁₁ to R₃₁₈ is a single bond with *e;
a combination of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, a substituted or unsubstituted alkyl group having 1 to 30 carbon atoms, a substituted or unsubstituted aryl group having 6 to 30 ring carbon atoms, or a substituted or unsubstituted heterocyclic group having 5 to 30 ring atoms;
a combination of R₃₁₉ and R₃₂₀ are mutually bonded to form a substituted or unsubstituted monocyclic ring, mutually bonded to form a substituted or unsubstituted fused ring, or not mutually bonded;
R₃₁₉ and R₃₂₀ forming neither the substituted or unsubstituted monocyclic ring nor the substituted or unsubstituted fused ring are each independently a hydrogen atom, a substituted or unsubstituted alkyl group having 1 to 30 carbon atoms, or a substituted or unsubstituted aryl group having 6 to 12 ring carbon atoms; and
** represents a bonding position to L_{A1}, L_{A2}, L_{A3}, L_{C1}, L_{C2}, L_{C3}, or L_{C4}.

9: The composition according to claim 8, wherein two or more of A₁₁₁, Ar₁₁₂, and Ar₁₁₃ in a compound represented by the formula (C1) are each a group represented by the formula (C4), or two or more of A₁₃₁, Ar₁₃₂, Ar₁₃₃, and Ar₁₃₄ in a compound represented by the formula (C3) are each a group represented by the formula (C4).

10: The composition according to claim 8, wherein R₃₁₉ and R₃₂₀ are each independently a substituted or unsubstituted alkyl group having 1 to 30 carbon atoms.

11: The composition according to claim 8, wherein at least one of R₃₁₉ or R₃₂₀ is a substituted or unsubstituted aryl group having 6 to 12 ring carbon atoms.

12-13. (canceled)

14: The composition according to claim 8, wherein a combination of R₃₁₉ and R₃₂₀ are mutually bonded to form a substituted or unsubstituted monocyclic ring or a substituted or unsubstituted fused ring.

15. (canceled)

16: The composition according to claim 8, wherein one of R₃₁₃ to R₃₁₆ is a single bond with *e.

17: The composition according to claim 4, wherein
Ar₁₁₁, Ar₁₁₂, and Ar₁₁₃ in a compound represented by the formula (C1) and Ar₁₃₁, Ar₁₃₂, Ar₁₃₃, and Ar₁₃₄ in a compound represented by the formula (C3) are each independently a group represented by a formula (2-a), (2-b), (2-c), (2-d), (2-e), or (2-f), 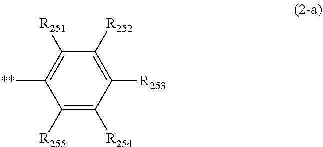
where, in the formula (2-a):
none of combinations of adjacent two or more of R₂₅₁ to R₂₅₅, are bonded to each other;
R₂₅₁ to R₂₅₅ are each independently a hydrogen atom, a substituted or unsubstituted alkyl group having 1 to 30 carbon atoms, or a substituted or unsubstituted cycloalkyl group having 3 to 30 ring atoms; and
** represents a bonding position, 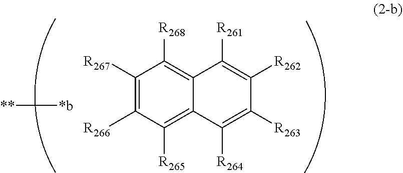
where, in the formula (2-b):
one of R₂₆₁ to R₂₆₈ is a single bond with *b;
none of combinations of adjacent two or more of R₂₆₁ to R₂₆₈ not being the single bond with *b are bonded to each other;
R₂₆₁ to R₂₆₈ not being the single bond with *b are each independently a hydrogen atom, a substituted or unsubstituted alkyl group having 1 to 30 carbon atoms, a substituted or unsubstituted cycloalkyl group having 3 to 30 ring atoms, or a substituted or unsubstituted aryl group having 6 to 12 ring carbon atoms; and
** represents a bonding position, 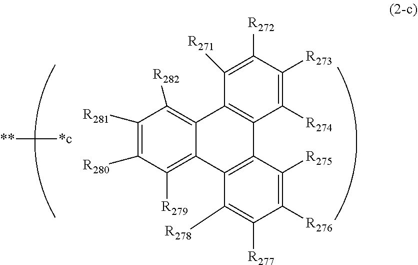
where, in the formula (2-c):
one of R₂₇₁ to R₂₈₂ is a single bond with *c;
none of combinations of adjacent two or more of R₂₇ to R₂₈₂ not being the single bond with *c are bonded to each other;
R₂₇₁ to R₂₈₂ not being the single bond with *c are each independently a hydrogen atom, a substituted or unsubstituted alkyl group having 1 to 30 carbon atoms, a substituted or unsubstituted cycloalkyl group having 3 to 30 ring atoms, or a substituted or unsubstituted aryl group having 6 to 12 ring carbon atoms; and
** represents a bonding position, 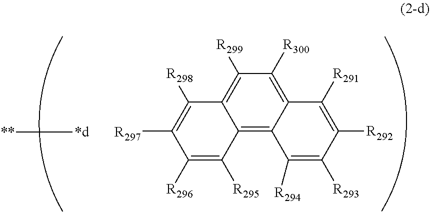
where, in the formula (2-d):
one of R₂₉₁ to R₃₀₀ is a single bond with *d;
none of combinations of adjacent two or more of R₂₉₁ to R₃₀₀ not being the single bond with *d are bonded to each other;
R₂₉₁ to R₃₀₀ not being the single bond with *d are each independently a hydrogen atom, a substituted or unsubstituted alkyl group having 1 to 30 carbon atoms, a substituted or unsubstituted cycloalkyl group having 3 to 30 ring atoms, or a substituted or unsubstituted aryl group having 6 to 12 ring carbon atoms; and
** represents a bonding position, 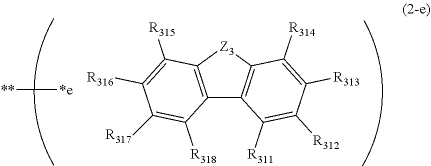
where, in the formula (2-e):
Z₃ is an oxygen atom, a sulfur atom NR₃₁₉, or C(R₃₂₁))(R₃₂₁);
one of R₃₁₁ to R₃₂₁ is a single bond with *e, or one of carbon atoms of a substituted or unsubstituted benzene ring, described below, formed by mutually bonding a combination of adjacent two or more of R₃₁₁ to R₃₁₈ is bonded to *e by a single bond;
combinations of adjacent two or more of R₃₁₁ to R₃₁₈ not being the single bond with *e are mutually bonded to form a substituted or unsubstituted benzene ring, or not mutually bonded;
R₃₁₁ to R₃₁₈ not being the single bond with *e and not forming the substituted or unsubstituted benzene ring are each independently a hydrogen atom, a substituted or unsubstituted alkyl group having 1 to 30 carbon atoms, a substituted or unsubstituted cycloalkyl group having 3 to 30 ring atoms, a substituted or unsubstituted aryl group having 6 to 12 ring carbon atoms, or a substituted or unsubstituted heterocyclic group having 5 to 10 ring atoms;
R₃₁₉ not being the single bond with *e is a hydrogen atom, a substituted or unsubstituted alkyl group having 1 to 6 carbon atoms, or a substituted or unsubstituted aryl group having 6 to 12 ring carbon atoms;
a combination of R₃₂₀ and R₃₂₁ not being the single bond with *e is mutually bonded to form a substituted or unsubstituted monocyclic ring, mutually bonded to form a substituted or unsubstituted fused ring, or not mutually bonded;
R₃₂₀ and R₃₂₁ not being the single bond with *e, not forming the substituted or unsubstituted monocyclic ring, and not forming the substituted or unsubstituted fused ring are each independently a hydrogen atom, a substituted or unsubstituted alkyl group having 1 to 6 carbon atoms, or a substituted or unsubstituted aryl group having 6 to 12 ring carbon atoms; and
** represents a bonding position, 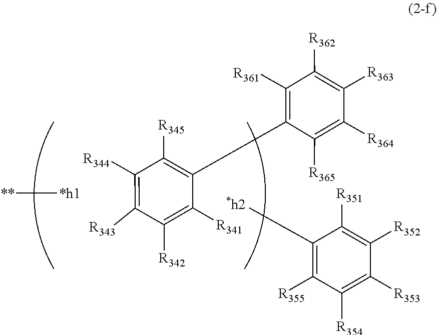
where, in the formula (2-f):
one of R₃₄₁ to R₃₄₅ is a single bond with *h1, and another one of R₃₄₁ to R₃₄₅ is a single bond with *h2;
none of combinations of adjacent two or more of R₃₄₁ to R₃₄₅ not being the single bond with *h1 and not being the single bond with *h2 are bonded to each other;
at least one combination of adjacent two or more of R₃₅₁ to R₃₅₅ is mutually bonded to form a substituted or unsubstituted monocyclic ring, mutually bonded to form a substituted or unsubstituted fused ring, or not mutually bonded;
at least one combination of adjacent two or more of R₃₆₁ to R₃₁₅ f mutually bonded to form a substituted or unsubstituted monocyclic ring, mutually bonded to form a substituted or unsubstituted fused ring, or not mutually bonded;
R₃₄₁ to R₃₄₅ not being the single bond with *h1 and not being the single bond with *h2 as well as R₃₅₁ to R₃₅₅ and R₃₆₁ to R₃₆₅ forming neither the substituted or unsubstituted monocyclic ring nor the substituted or unsubstituted fused ring are each independently a hydrogen atom, a substituted or unsubstituted alkyl group having 1 to 30 carbon atoms, a substituted or unsubstituted cycloalkyl group having 3 to 30 ring atoms, or a substituted or unsubstituted aryl group having 6 to 12 ring carbon atoms; and
** represents a bonding position.

18. (canceled)

19: An organic electroluminescence device comprising:
an anode;
a cathode; and
an organic layer disposed between the anode and the cathode, wherein
at least one layer comprised by the organic layer comprises the composition according to claim 1.

20: The organic electroluminescence device according to claim 19, wherein the first compound and the second compound are comprised by the same layer.

21: An organic electroluminescence device comprising:
an anode;
a cathode; and
an organic layer disposed between the anode and the cathode, wherein
at least one layer comprised by the organic laver comprising a first compound and a second compound, wherein
the first compound and the second compound are mutually different compounds,
the first compound and the second compound are each independently an amine compound having a refractive index of 1.85 or less,
the first compound and the second compound are comprised by the same layer, and
the layer comprising the first compound and the second compound has a film thickness of 25 nm or more.

22: The organic electroluminescence device according to claim 19, wherein
the organic layer comprises an emitting zone and a hole transporting zone,
the emitting zone comprises at least one emitting layer,
the hole transporting zone is disposed between the anode and the emitting zone, and
at least one layer comprised by the hole transporting zone comprises the first compound and the second compound.

23: The organic electroluminescence device according to claim 22, wherein the hole transporting zone comprises a hole injecting layer and a hole transporting layer.

24-25. (canceled)

26: The organic electroluminescence device according to claim 23, wherein
the hole transporting layer comprises a first hole transporting layer and a second hole transporting layer, and
the second hole transporting layer is disposed between the first hole transporting layer and the emitting zone.

27: The organic electroluminescence device according to claim 26, wherein a refractive index of the first hole injecting layer n_{HT1} is larger than a refractive index of the second hole transporting layer n_{HT2}.

28-37. (canceled)

38: The organic electroluminescence device according to claim 22, wherein
the emitting zone comprises two or more emitting layers, and
at least two of the emitting layers are layered.

39-40. (canceled)

41: The organic electroluminescence device according to claim 22, further comprising: an electron transporting zone disposed between the cathode and emitting zone, wherein
the electron transporting zone comprises at least one electron transporting layer,
the at least one electron transporting layer in the electron transporting zone comprises a nitrogen-containing compound, and
the at least one electron transporting layer in the electron transporting zone comprises, as the nitrogen-containing compound, at least one compound selected from the group consisting of an imidazole derivative, a benzimidazole derivative, an azine derivative, a carbazole derivative, and a phenanthroline derivative.

42: An electronic device comprising the organic electroluminescence device according to claim 19.
